(19) United States
(12) Patent Application Publication
(10) Pub. No.: US 2026/0029713 A1
(43) Pub. Date: Jan. 29, 2026

(54) ONIUM SALT, CHEMICALLY AMPLIFIED RESIST COMPOSITION, AND PATTERN FORMING PROCESS

(71) Applicant: Shin-Etsu Chemical Co., Ltd., Tokyo (JP)

(72) Inventor: Masahiro Fukushima, Joetsu-shi (JP)

(73) Assignee: Shin-Etsu Chemical Co., Ltd., Tokyo (JP)

(21) Appl. No.: 19/272,171

(22) Filed: Jul. 17, 2025

(30) Foreign Application Priority Data
Jul. 25, 2024 (JP) 2024-119652

(51) Int. Cl. G03F 7/029; G03F 7/00; G03F 7/039

(52) U.S. Cl. CPC G03F 7/029; G03F 7/0397; G03F 7/70025; G03F 7/70033

(57) ABSTRACT

The onium salt has the formula (1). The chemically amplified resist composition comprising the onium salt as a photoacid generator. The chemically amplified resist composition has a high solvent solubility, a high sensitivity, and a high contrast, and being improved in lithography properties such as LWR, CDU, MEF, EL, and DOF, particularly when processed by photolithography using high-energy radiation such as KrF or ArF excimer laser radiation, an electron beam (EB) or EUV.

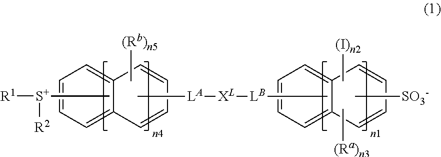

### CROSS-REFERENCE TO RELATED APPLICATION

This non-provisional application claims priority under 35 U.S.C. § 119(a) on Patent Application No. 2024-119652 filed in Japan on Jul. 25, 2024, the entire contents of which are hereby incorporated by reference.

### TECHNICAL FIELD

The present invention relates to an onium salt, a chemically amplified resist composition, and a pattern forming process.

### BACKGROUND ART

While a number of recent efforts are being made to achieve a finer pattern rule in the drive for higher integration and operating speeds in LSIs, deep ultraviolet lithography and extreme ultraviolet (EUV) lithography processes are thought to hold particular promise as the next generation in microfabrication technology.

Photolithography using an ArF excimer laser (ArF lithography) started partial use from the fabrication of 130-nm node devices and became the main lithography since 90-nm node devices. Although lithography using F₂ laser of wavelength 157 nm was initially thought promising as the next lithography for 45-nm node devices, its development was retarded by several problems. A highlight was suddenly placed on the ArF immersion lithography that introduces a liquid having a higher refractive index than air (e.g., water, ethylene glycol, glycerol) between the projection lens and the wafer, allowing the projection lens to be designed to a numerical aperture (NA) of 1.0 or higher and achieving a higher resolution (Non-Patent Document 1). The ArF immersion lithography is now implemented on the commercial stage. This immersion lithography requires a resist composition which is substantially insoluble in water.

In ArF lithography, a highly sensitive resist composition capable of exhibiting sufficient resolution at a small dose of exposure is required to prevent the degradation of precise and expensive optical system materials. As a method for realizing the highly sensitive resist composition, the most common is to select its component which is highly transparent at the wavelength of 193 nm. For example, polyacrylic acid and derivatives thereof, norbornene-maleic anhydride alternating polymers, polynorbornene, ring-opening metathesis polymers, hydrogenated ring-opening metathesis polymers, and the like have been proposed as the base polymer. This choice is effective to some extent in that the transparency of a resin alone is increased.

Recently a highlight is put on the negative tone resist adapted for organic solvent development as well as the positive tone resist adapted for aqueous alkaline development. It would be desirable if a very fine hole pattern, which is not achievable with the positive tone, is resolvable through negative tone exposure. To this end, a positive resist composition featuring a high resolution is subjected to organic solvent development to form a negative pattern. An attempt to double a resolution by combining two developments, aqueous alkaline development and organic solvent development is under study. As the ArF resist composition for negative tone development with organic solvent, positive ArF resist compositions of the prior art design may be used. Such pattern forming processes are described in Patent Documents 1 to 3.

To meet the current rapid progress of microfabrication, development efforts are put on not only the process technology, but also the resist composition. Studies have also been made on photoacid generators. Commonly used are sulfonium salts of triphenylsulfonium cations with perfluoroalkanesulfonic acid anions. These salts generate perfluoroalkanesulfonic acids, especially perfluorooctanesulfonic acid (PFOS), which are considered problematic with respect to their non-degradability, biological concentration and toxicity. It is rather restricted to apply these salts to the resist composition. Instead, photoacid generators capable of generating perfluorobutanesulfonic acid are currently used, but are awkward to achieve a high resolution because of substantial diffusion of the generated acid in the resist composition. To address the problem, partially fluorinated alkane sulfonic acids and salts thereof are developed. For instance, Patent Document 1 describes the prior art photoacid generators capable of generating α,α-difluoroalkanesulfonic acid, such as di(4-tert-butylphenyl)iodonium 1,1-difluoro-2-(1-naphthyl)ethanesulfonate and photoacid generators capable of generating α,α,β,β-tetrafluoroalkanesulfonic acid by exposure. Despite a reduced degree of fluorine substitution, these photoacid generators still have the following problems. Since they do not have a decomposable substituent such as ester structure, they are unsatisfactory from the aspect of environmental safety or ease of decomposition. The molecular design to change the size of alkanesulfonic acid is limited. Fluorine-containing starting reactants are expensive.

As the circuit line width is reduced, the degradation of contrast by acid diffusion becomes more serious for the resist composition. The reason is that the pattern feature size is approaching the diffusion length of acid. This invites a lowering of mask fidelity and a degradation of pattern rectangularity because a dimensional shift on wafer (known as mask error factor (MEF)) relative to a dimensional shift on mask is exaggerated. Accordingly, to gain more benefits from a reduction of exposure light wavelength and an increase of lens NA, the resist composition is required to increase a dissolution contrast or restrain acid diffusion, as compared with the prior art materials. One approach is to lower the bake temperature for suppressing acid diffusion and hence, improving MEF. A low bake temperature, however, inevitably leads to a low sensitivity.

Incorporating a bulky substituent or polar group into a photoacid generator is effective for suppressing acid diffusion. Patent Document 4 discloses a photoacid generator capable of generating 2-acyloxy-1,1,3,3,3-pentafluoropropane-1-sulfonic acid which is fully soluble and stable in resist solvents and allows for a wide span of molecular design. In particular, a photoacid generator having a bulky substituent incorporated therein or capable of generating 2-(1-adamantyloxy)-1,1,3,3,3-pentafluoropropane-1-sulfonic acid is characterized by slow acid diffusion. Patent Documents 5 to 7 describe photoacid generators having fused ring lactone, sultone or thiolactone incorporated as the polar group. Although some improvement in properties is observed due to the acid diffusion suppressing effect of the polar group incorporated, they are still insufficient in precise control of acid diffusion. Their lithography properties are unsatisfactory when evaluated totally in terms of MEF, pattern profile and sensitivity.

In order to suppress acid diffusion of the acid generated from a photoacid generator, an onium salt having a betaine structure having an onium cation site and anion sites in a common molecule has also been proposed. Patent Documents 8 to 10 describe betaine onium salts having a fluoroalkanesulfonic acid anion site and a sulfonium cation site, which have been used in ArF lithography and EUV lithography. In addition, in Patent Documents 11 and 12, polarity conversion type betaine onium salts obtained by introducing an acetal protecting group into these betaine onium salts have been proposed. As a result, although the lithography properties have been improved by these techniques, there is still room for improvement.

It is known that iodine atoms are highly absorptive to EUV of wavelength 13.5 nm, and thus generate secondary electrons upon light exposure. This phenomenon is attractive in the EUV lithography. Patent Documents 13 and 14 describe a photoacid generator containing an anion having iodine introduced therein, and Patent Document 15 describes a polymerizable group-containing photoacid generator containing an anion having iodine introduced therein. Patent Document 16 describes a photoacid generator containing both a cation and an anion having iodine introduced therein. As a result, although the lithography properties are improved to some extent, iodine atoms are not so high in organic solvent solubility, and there is concern for precipitation in the solvent. To meet the demand for further microfabrication, it is crucial to develop a novel photoacid generator. There is the desire to have a photoacid generator capable of fully suppressing acid diffusion, achieving high solvent solubility, and effectively suppressing pattern collapse.

### CITATION LIST

Patent Document 1: JP-A 2008-281974
Patent Document 2: JP-A 2008-281975
Patent Document 3: JP 4554665
Patent Document 4: JP-A 2007-145797
Patent Document 5: JP 5061484
Patent Document 6: JP-A 2016-147879
Patent Document 7: JP-A 2015-063472
Patent Document 8: JP 5387181
Patent Document 9: JP 5865725
Patent Document 10: JP 6237428
Patent Document 11: JP 6950357
Patent Document 12: JP 7111047
Patent Document 13: JP 6720926
Patent Document 14: WO 2024/057701
Patent Document 15: JP 6973274
Patent Document 16: JP 7041204
Non-Patent Document 1: Journal of Photopolymer Science and Technology, Vol. 17, No. 4, p. 587-601 (2004)

### SUMMARY OF THE INVENTION

In conjunction with the demand for higher resolution of resist patterns, a prior art resist composition comprising a photoacid generator of onium salt type fails to fully suppress acid diffusion. As a result, lithography properties including contrast, LWR, CDU, MEF, exposure latitude (EL), and depth of focus (DOF) are degraded. Another problem arising upon formation of small-size patterns is pattern collapse by swell.

An object of the invention is to provide an onium salt and a chemically amplified resist composition comprising the onium salt as a photoacid generator, the chemically amplified resist composition having a high solvent solubility, a high sensitivity, and a high contrast, and being improved in lithography properties such as LWR, CDU, MEF, EL, and DOF, particularly when processed by photolithography using high-energy radiation such as KrF or ArF excimer laser radiation, an electron beam (EB) or EUV; and a pattern forming process using the chemically amplified resist composition.

The inventor has found that a betaine onium salt having, in a common molecule, aromatic sulfonic acid anion sites having an aromatic ring substituted with iodine and a sulfonium cation site has a high solvent solubility, and that a chemically amplified resist composition comprising the onium salt as a photoacid generator exhibits a high sensitivity, high contrast, and improved lithography properties such as LWR, CDU, MEF, EL, and DOF and is quite effective for pattern collapse resistance upon formation of small-size patterns.

That is, the present invention provides the following onium salt, chemically amplified resist composition, and pattern forming process.

1. An onium salt having the formula (1):

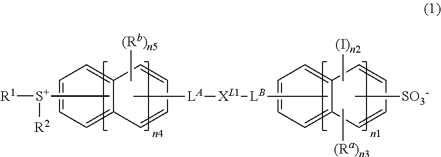

wherein n1 is 0 or 1, n2 is 1, 2, 3, or 4, n3 is 0, 1, or 2, meeting 1≤n2+n3≤4 in case of n1=0, and 1≤n2+n3≤6 in case of n1=1, n4 is 0 or 1, n5 is 0, 1, 2, 3, or 4,
   R^{a} is halogen exclusive of iodine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n3 is 2, two R^{a} may be identical or different and two R^{a} may bond together to form a ring with the carbon atoms to which they are attached,
   R^{b} is halogen, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n5 is 2, 3, or 4, a plurality of R^{b} may be identical or different and a plurality of R^{b} may bond together to form a ring with the carbon atoms to which they are attached,
   R¹ and R² are each independently halogen or a C₁-C₃₀ hydrocarbyl group which may contain a heteroatom, any two of R¹ and R² and the aromatic ring bonded to S⁺ in the formula may bond together to form a ring with the sulfur atoms to which they are attached,
   L^{A} and L^{B} are each independently a single bond, ether bond, ester bond, sulfonate ester bond, amide bond, sulfonamide bond, carbonate bond or carbamate bond, and
   X^{L1} is a single bond or a C₁-C₄₀ hydrocarbylene group which may contain a heteroatom. 2. The onium salt of 1 having the formula (1A):

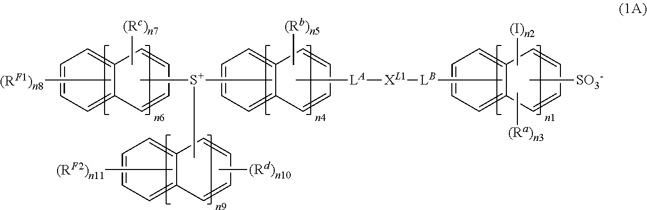

wherein n1 to n5, R^{a}, R^{b}, L^{A}, L^{B}, and X^{L1} are as defined above,
   n6 is 0 or 1, n7 is 0, 1, or 2, n8 is 0, 1, 2, 3, or 4, n9 is 0 or 1, n10 is 0, 1, or 2, n11 is 0, 1, 2, 3, or 4, meeting 0≤n7+n8≤5 in case of n6=0 and 0≤n7+n8≤7 in case of n6=1, 0≤n10+n11≤5 in case of n9-0 and 0≤n10+n11≤7 in case of n9=1,
   R^{c} is halogen exclusive of fluorine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n7 is 2, two R^{c} may be identical or different and two R^{c} may bond together to form a ring with the carbon atoms to which they are attached,
   R^{d} is halogen exclusive of fluorine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n10 is 2, two R^{d} may be identical or different and two R^{d} may bond together to form a ring with the carbon atoms to which they are attached, and
   R^{F1} and R^{F2} are each independently fluorine, pentafluorosulfanyl, a C₁-C₆ fluorinated saturated hydrocarbyl group, a C₁-C₆ fluorinated saturated hydrocarbyloxy group, or a C₁-C₆ fluorinated saturated hydrocarbylthio group, a plurality of R^{F1} may be identical or different when n8 is 2 or more, a plurality of R^{F2} may be identical or different when n11 is 2 or more.

3. The onium salt of 2 having the formula (1B):

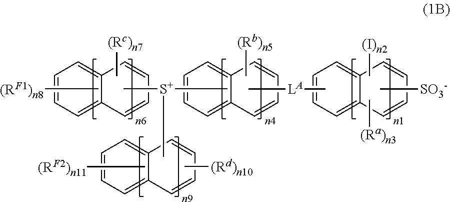

wherein n1 to n11, R^{a}, R^{b}, R^{c}, R^{d}, R^{F1}, R^{F2}, and L^{A} are as defined above.

4. A photoacid generator comprising the onium salt of any one of 1 to 3.

5. A chemically amplified resist composition comprising the photoacid generator of 4.

6. The chemically amplified resist composition of 5, further comprising a base polymer comprising at least one selected from repeat units having the formula (a1), repeat units having the formula (a2), and repeat units having the formula (a3):

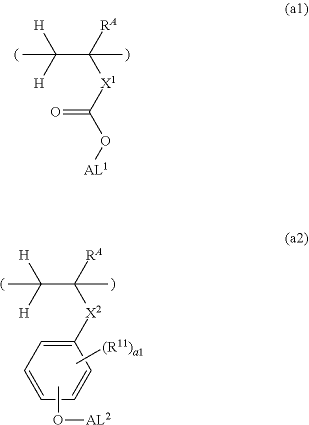

wherein R^{A} is each independently hydrogen, fluorine, methyl or trifluoromethyl,
   X¹ is a single bond, phenylene group, naphthylene group, *—C(═O)—O—X¹¹—, or *—C(═O)—NH—X¹¹—, the phenylene or naphthylene group may be substituted by a hydroxy group, nitro group, cyano group, optionally fluorinated C₁-C₁₀ saturated hydrocarbyl group, optionally fluorinated C₁-C₁₀ saturated hydrocarbyloxy group, or halogen, X¹¹ is a C₁-C₁₀ saturated hydrocarbylene group which may contain a hydroxy moiety, ether bond, ester bond or lactone ring, or phenylene or naphthylene group,
   X² is a single bond, *—C(═O)—O—, or *—C(═O)—NH—,
   * designates a point of attachment to the carbon atom in the backbone,
   R¹¹ is halogen, cyano, hydroxy, nitro, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R¹¹ may be identical or different when a1 is 2, 3, or 4,
   AL¹ and AL² are each independently an acid labile group, and
   a1 is 0, 1, 2, 3, or 4;

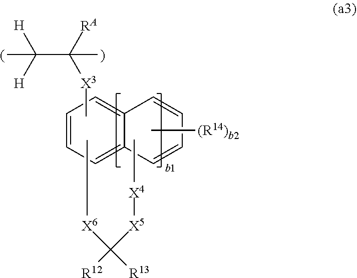

wherein b1 is 0 or 1, b2 is 0, 1, 2, or 3 in case of b1=0, and is 0, 1, 2, 3, 4, or 5 in case of b1=1,
   R^{A} is hydrogen, fluorine, methyl or trifluoromethyl,
   X³ is a single bond, *—C(═O)—O—, or *—C(═O)—NH—, * designates a point of attachment to the carbon atom in the backbone,
   X⁴ is a single bond, a C₁-C₄ aliphatic hydrocarbylene group, carbonyl group, sulfonyl group, or a group obtained by combining the foregoing,
   X⁵ and X⁶ are each independently oxygen or sulfur, X⁴ and X⁶ are bonded to vicinal carbon atoms on the aromatic ring,
   R¹² and R¹³ are each independently hydrogen or a C₁-C₂₀ hydrocarbyl group which may contain a heteroatom, R¹² and R¹³ may bond together to form a ring with the carbon atoms to which they are attached, and
   R¹⁴ is halogen, hydroxy, cyano, nitro, a C₁-C₂₀ hydrocarbyl group which may contain a heteroatom, a C₁-C₂₀ hydrocarbyloxy group which may contain a heteroatom, a C₂-C₂₀ hydrocarbyloxycarbonyl group which may contain a heteroatom, a C₁-C₂₀ hydrocarbylthio group which may contain a heteroatom, or —N(R^{14A})(R^{14B}), R^{14A} and R^{14B} are each independently hydrogen or a C₁-C₆ hydrocarbyl group, when b2 is 2 or more, a plurality of R¹⁴ may be identical or different and a plurality of R¹⁴ may bond together to form a ring with the carbon atoms on the aromatic ring to which they are attached.

7. The chemically amplified resist composition of 6 wherein the base polymer comprises at least one selected from repeat units having the formula (b1) and repeat units having the formula (b2):

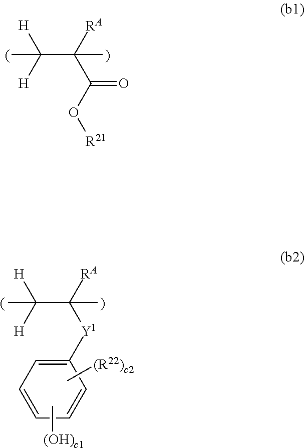

wherein R^{A} is each independently hydrogen, fluorine, methyl or trifluoromethyl,
   Y¹ is a single bond or *—C(═O)—O—, * designates a point of attachment to the carbon atom in the backbone,
   R²¹ is hydrogen or a C₁-C₂₀ group containing at least one structure selected from among hydroxy other than phenolic hydroxy, cyano, carbonyl, carboxy, ether bond, ester bond, sulfonate ester bond, carbonate bond, lactone ring, sultone ring and carboxylic anhydride (—C(═O)—O—C(═O)—),
   R²² is halogen, hydroxy, carboxy, nitro, cyano, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R²² may be identical or different when c2 is 2, 3, or 4, and
   c1 is 1, 2, 3, or 4, c2 is 0, 1, 2, 3, or 4, meeting 1≤c1+c2≤5.

8. The chemically amplified resist composition of 6 or 7 wherein the base polymer comprises at least one selected from repeat units having the formula (c1), repeat units having the formula (c2), repeat units having the formula (c3), repeat units having the formula (c4), and repeat units having the formula (c5):

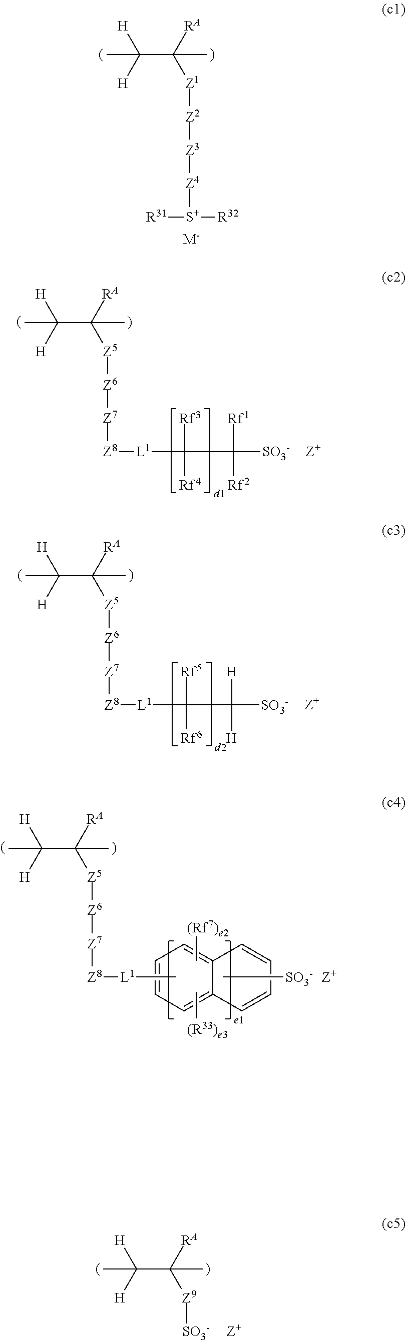

wherein d1 and d2 are each independently 0, 1, 2, or 3, e1 is 0 or 1, e2 is 0, 1, 2, 3, or 4, and e3 is 0, 1, 2, 3, or 4, meeting 0≤e2+e3≤4 in case of e1=0, 0≤e2+e3≤6 in case of e1=1,
   R^{A} is each independently hydrogen, fluorine, methyl or trifluoromethyl,
   Z¹ is a single bond or optionally substituted phenylene group,
   Z² is a single bond, **—C(═O)—O—Z²¹—, **—C(═O)—NH—Z²¹—, or **—O—Z²¹—, Z²¹ is a C₁-C₆ aliphatic hydrocarbylene group, a phenylene group or a divalent group obtained by combining the foregoing, which may contain halogen, a carbonyl moiety, ester bond, ether bond or hydroxy moiety,
   Z³ is a single bond, ether bond, ester bond, amide bond, sulfonate ester bond, sulfonamide bond, carbonate bond or carbamate bond,
   Z⁴ is a single bond, or a C₁-C₆ aliphatic hydrocarbylene group, a phenylene group or a divalent group obtained by combining the foregoing, which may contain halogen, a carbonyl moiety, ester bond, ether bond or hydroxy moiety,
   Z⁵ is each independently a single bond, optionally substituted phenylene group, naphthylene group, or *—C(═O)—O—Z⁵, Z⁵¹ is a C₁-C₁₀ aliphatic hydrocarbylene group, or phenylene or naphthylene group, the aliphatic hydrocarbylene group may contain halogen, a hydroxy moiety, ether bond, ester bond or lactone ring,
   Z⁶ is a single bond, ether bond, ester bond, amide bond, sulfonate ester bond, sulfonamide bond, carbonate bond or carbamate bond,
   Z⁷ is each independently a single bond, ***—Z⁷¹—C(═O)—O—, ***—C(═O)—NH—Z⁷¹—, or ***—O—Z⁷¹—, Z⁷¹ is a C₁-C₂₀ hydrocarbylene group which may contain a heteroatom,
   Z⁸ is each independently a single bond, ****—Z⁷¹—C(═O)—O—, ****—C(═O)—NH—Z⁷¹—, or ****—O—Z⁸¹, Z⁸¹ is a C₁-C₂₀ hydrocarbylene group which may contain a heteroatom,
   Z⁹ is a single bond, methylene, ethylene, phenylene, fluorinated phenylene, trifluoromethyl-substituted phenylene, *—C(═O)—O—Z⁹¹—, *—C(═O)—N(H)—Z⁹¹—, or *—O—Z⁹¹—,
   Z⁹¹ is a C₁-C₆ aliphatic hydrocarbylene group, phenylene group, fluorinated phenylene group or trifluoromethyl-substituted phenylene group, which may contain a carbonyl moiety, ester bond, ether bond or hydroxy moiety,
   * designates a point of attachment to the carbon atom in the backbone, ** designates a point of attachment to Z¹, *** designates a point of attachment to Z⁶, **** designates a point of attachment to Z⁷,
   L¹ is a single bond, ether bond, ester bond, carbonyl group, sulfonate ester bond, sulfonamide bond, carbonate bond or carbamate bond,
   Rf¹ and Rf² are each independently fluorine or a C₁-C₆ fluorinated saturated hydrocarbyl group,
   Rf³ and Rf⁴ are each independently hydrogen, fluorine, or a C₁-C₆ fluorinated saturated hydrocarbyl group,
   Rf⁵ and Rf⁶ are each independently hydrogen, fluorine, or a C₁-C₆ fluorinated saturated hydrocarbyl group, excluding that all Rf⁵ and Rf⁶ are hydrogen at the same time,
   Rf⁷ is fluorine, a C₁-C₆ fluorinated alkyl group, a C₁-C₆ fluorinated alkoxy group, or a C₁-C₆ fluorinated alkylthio group,
   R³¹ and R³² are each independently a C₁-C₂₀ hydrocarbyl group which may contain a heteroatom, R³¹ and R³² may bond together to form a ring with the sulfur atoms to which they are attached,
   R³³ is halogen exclusive of fluorine, or a C₁-C₂₀ hydrocarbyl group which may contain a heteroatom, when e3 is 2, 3, or 4, a plurality of R³³ may be identical or different and a plurality of R³³ may bond together to form a ring with the carbon atoms to which they are attached,
   M⁻ is a non-nucleophilic counter ion, and
   Z⁺ is an onium cation.

9. The chemically amplified resist composition of any one of 5 to 8, further comprising an organic solvent.

10. The chemically amplified resist composition of any one of 5 to 9, further comprising a quencher.

11. The chemically amplified resist composition of any one of 5 to 10, further comprising a photoacid generator other than the photoacid generator of 4.

12. The chemically amplified resist composition of any one of 5 to 11, further comprising a surfactant.

13. A pattern forming process comprising the steps of applying the chemically amplified resist composition of any one of 5 to 12 onto a substrate to form a resist film thereon, exposing the resist film to high-energy radiation, and developing the exposed resist film in a developer.

14. The pattern forming process of 13 wherein the high-energy radiation is KrF excimer laser radiation, ArF excimer laser radiation, EB, or EUV of wavelength 3 to 15 nm.

### Advantageous Effects of the Invention

When pattern formation is performed using a chemically amplified resist composition comprising the onium salt of the invention as a photoacid generator, it is possible to form a resist pattern having a high contrast, a good sensitivity, improved lithography properties such as LWR, CDU, MEF, EL, and DOF, and suppressed pattern collapse.

### DESCRIPTION OF THE PREFERRED EMBODIMENT

### Onium Salt

The invention provides an onium salt having the formula (1).

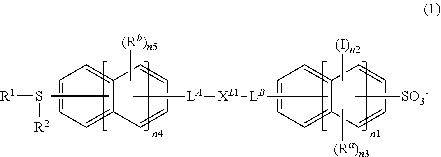

In formula (1), n1 is 0 or 1. The relevant structure is a benzene ring in case of n1=0, and a naphthalene ring in case of n1=1. The benzene corresponding to n1=0 is preferred from the aspect of solvent solubility. n2 is 1, 2, 3, or 4. n2 is preferably 1, 2, or 3 from the aspect of solvent solubility. n3 is 0, 1, or 2. n3 is preferably 0 or 1 from the aspect of availability of reactants. It is noted that 1≤n2+n3≤4 in case of n1=0 and 1≤n2+n3≤6 in case of n1=1. n4 is 0 or 1. The relevant structure is a benzene ring in case of n4=0, and a naphthalene ring in case of n4=1. The benzene corresponding to n4=0 is preferred from the aspect of solvent solubility. n5 is 0, 1, 2, 3, or 4. n5 is preferably 0, 1, 2, or 3, more preferably 0 or 1 from the aspect of availability of reactants.

In formula (1), R^{a} is halogen exclusive of iodine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom. Examples of the halogen exclusive of iodine include fluorine, chlorine, and bromine, with fluorine being preferred. The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl, and icosyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, allyl, propenyl, butenyl, and hexenyl; C₃-C₂₀ cyclic unsaturated hydrocarbyl groups such as cyclohexenyl; C₆-C₂₀ aryl groups such as phenyl and naphthyl; C₇-C₂₀ aralkyl groups such as benzyl, 1-phenylethyl, and 2-phenylethyl; and combinations thereof. Of these, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety. A plurality of R^{a} may be identical or different when n3 is 2. Also, when n3 is 2, two R^{a} may bond together to form a ring with the carbon atoms to which they are attached. The ring is preferably a 5- to 8-membered ring.

In formula (1), R^{b} is halogen, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom. Examples of the halogen include fluorine, chlorine, bromine, and iodine, with fluorine or iodine being preferred. The hydrocarbyl group may be saturated or unsaturated and straight, branched or cyclic. Examples thereof are as exemplified above for the hydrocarbyl group represented by R^{a}. A plurality of R^{b} may be identical or different when n5 is 2, 3, or 4. Also, when n4 is 2, 3, or 4, a plurality of R^{b} may bond together to form a ring with the carbon atoms to which they are attached. The ring is preferably a 5- to 8-membered ring.

In formula (1), R¹ and R² are each independently halogen or a C₁-C₃₀ hydrocarbyl group which may contain a heteroatom.

Examples of the halogen represented by R¹ and R² include fluorine, chlorine, bromine, and iodine.

The hydrocarbyl group represented by R¹ and R² may be saturated or unsaturated and straight, branched or cyclic. Examples thereof include C₁-C₃₀ alkyl groups such as methyl, ethyl, n-propyl, isopropyl, n-butyl, isobutyl, sec-butyl, and tert-butyl; C₃-C₃₀ cyclic saturated hydrocarbyl groups such as cyclopropyl, cyclopentyl, cyclohexyl, cylopropylmethyl, 4-methylcyclohexyl, cyclohexylmethyl, norbornyl, and adamantyl; C₂-C₃₀ alkenyl groups such as vinyl, 1-propenyl, 2-propenyl, butenyl, and hexenyl; C₃-C₃₀ cyclic unsaturated hydrocarbyl groups such as cyclohexenyl; C₆-C₃₀ aryl groups such as phenyl, naphthyl, and thienyl; C₇-C₃₀ aralkyl groups such as benzyl, 1-phenylethyl, and 2-phenylethyl; and combinations thereof. Of these, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

Also, any two of R¹ and R² and the aromatic ring bonded to S⁺ in the formula may bond together to form a ring with the sulfur atoms to which they are attached. Examples of the structure of the ring include those shown below.

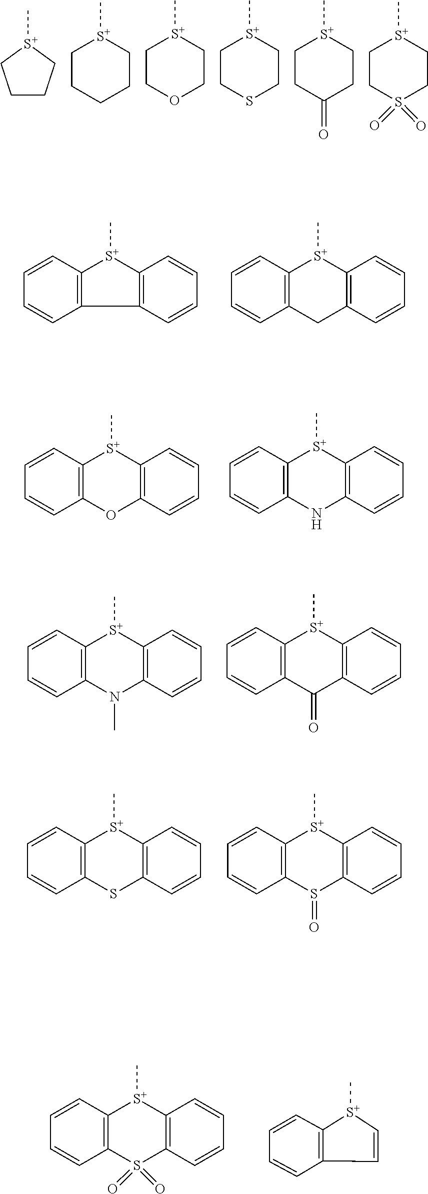

Herein the broken line is a point of attachment to R^{ct3}.

In formula (1), L^{A} and L^{B} are each independently a single bond, ether bond, ester bond, sulfonate ester bond, amide bond, sulfonamide bond, carbonate bond or carbamate bond. Of these, L^{A} and L^{B} are preferably a single bond, ether bond or ester bond.

In formula (1), X^{L1} is a single bond or a C₁-C₄₀ hydrocarbylene group which may contain a heteroatom. The hydrocarbylene group may be straight, branched or cyclic, and examples thereof include alkanediyl, divalent saturated cyclic hydrocarbon and arylene groups. Examples of the heteroatom include oxygen, nitrogen and sulfur atoms.

As the C₁-C₄₀ hydrocarbylene group which may contain a heteroatom represented by X^{L1}, those shown below are preferred. In the formulae, * represents a bond with L^{A} and L^{B}.

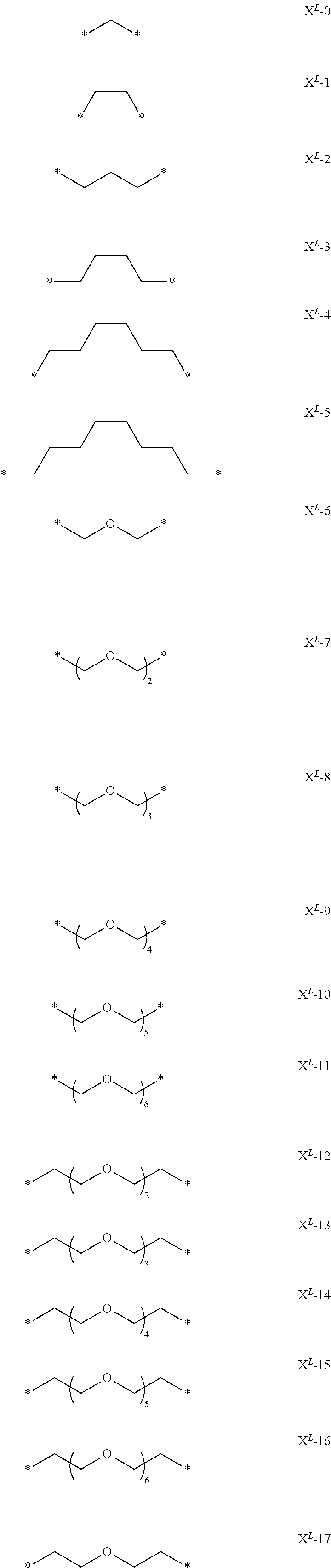

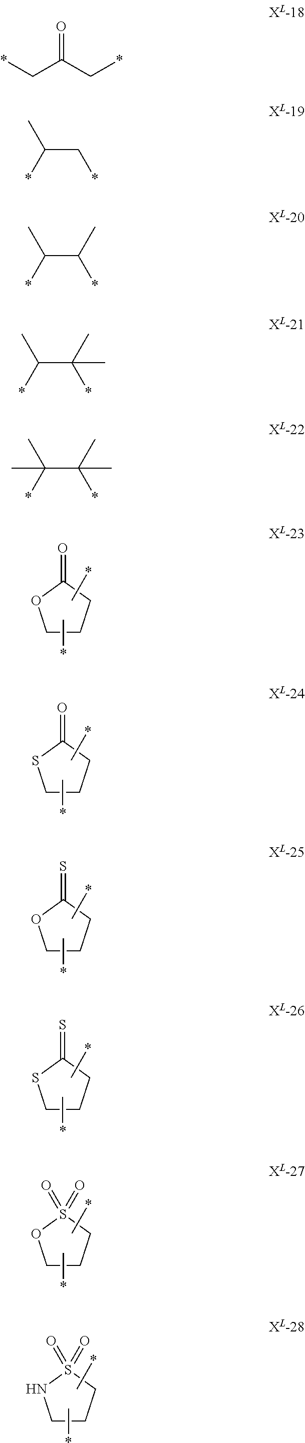

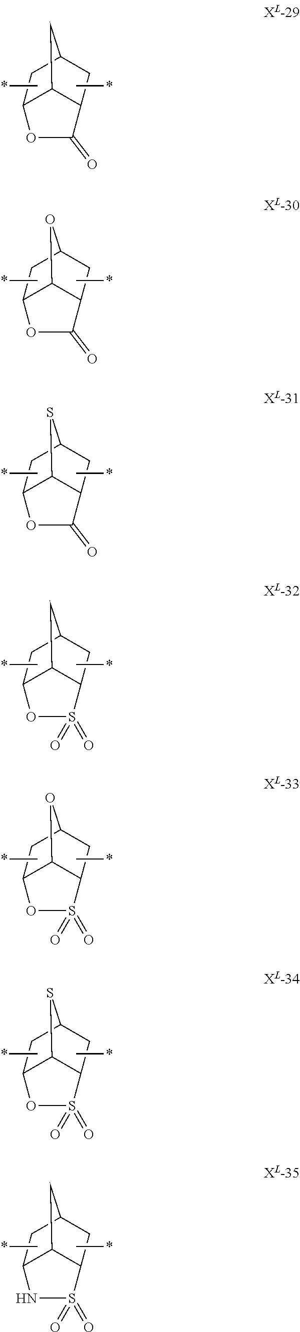

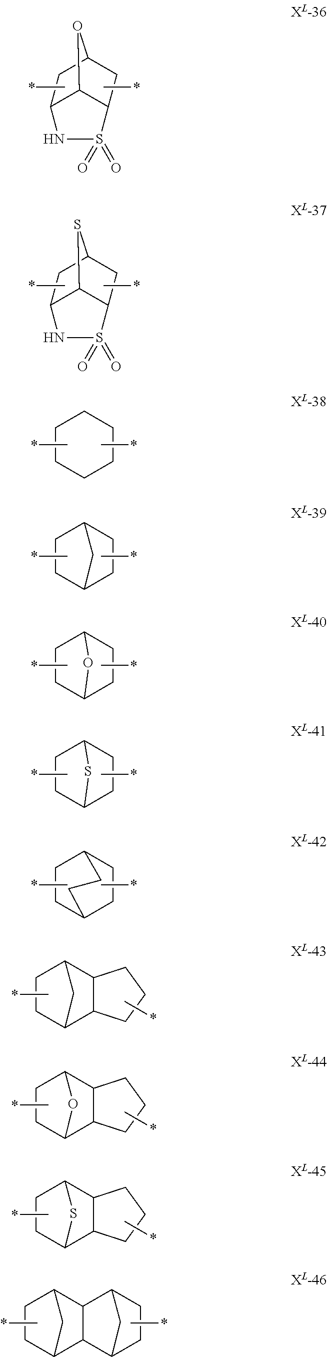

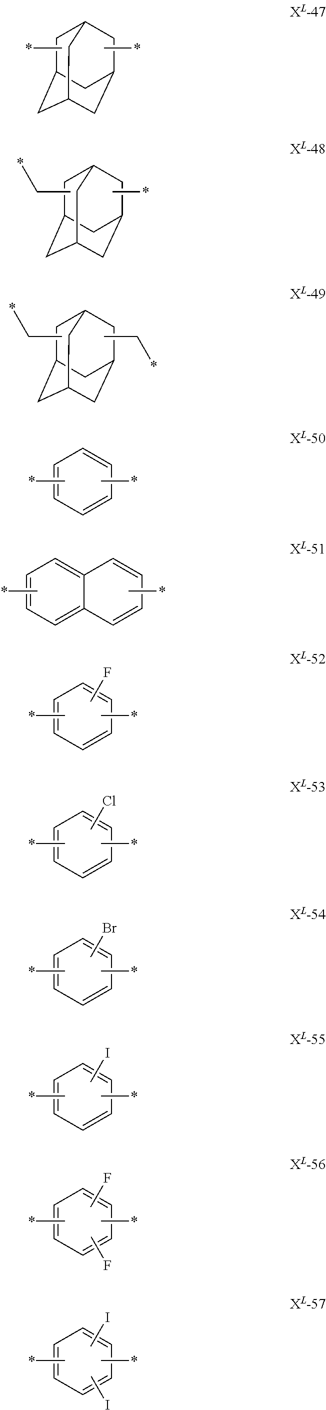

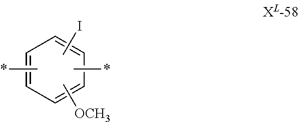

Of these, X^{L}-0 to X^{L}-22, X^{L}-29 to X^{L}-34, and X^{L}-47 to X^{L}-58 are preferred.

As the onium salt having formula (1), an onium salt having the formula (1A) is preferred.

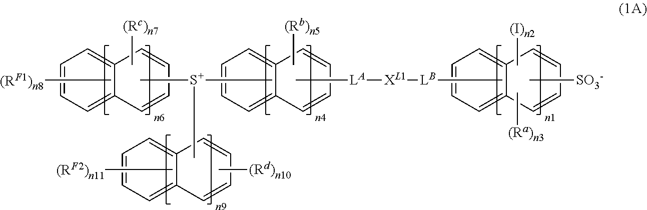

wherein n1 to n5, R^{a}, R^{b}, L^{A}, L^{B}, and X^{L1} are as defined above.

In formula (1A), n6 is 0 or 1. The relevant structure is a benzene ring in case of n6=0, and a naphthalene ring in case of n6=1. The benzene corresponding to n6=0 is preferred from the aspect of solvent solubility. n7 is 0, 1, or 2. n7 is preferably 0 or 1 from the aspect of availability of reactants. n8 is 0, 1, 2, 3, or 4. n8 is preferably 1, 2, or 3 from the aspect of ensuring solvent solubility and reactivity. It is noted that 0≤n7+n8≤5 in case of n6=0 and 0≤n7+n8≤7 in case of n6=1. n9 is 0 or 1. The relevant structure is a benzene ring in case of n9=0, and a naphthalene ring in case of n9=1. The benzene corresponding to n9=0 is preferred from the aspect of solvent solubility. n10 is 0, 1, or 2. n10 is preferably 0 or 1 from the aspect of availability of reactants. n11 is 0, 1, 2, 3, or 4. n11 is preferably 1, 2, or 3 from the aspect of ensuring solvent solubility and reactivity. It is noted that 0≤n10+n11≤5 in case of n9=0 and 0≤n10+n11≤7 in case of n9=1.

In formula (1A), R^{c} is halogen exclusive of fluorine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom. Examples of the halogen exclusive of fluorine include chlorine, bromine, and iodine, with iodine atom being preferred. The hydrocarbyl group may be saturated or unsaturated and straight, branched or cyclic. Examples thereof are as exemplified above for the hydrocarbyl group represented by R^{a} in formula (1). A plurality of R^{c} may be identical or different when n7 is 2. Also, when n7 is 2, two R^{c} may bond together to form a ring with the carbon atoms to which they are attached. The ring is preferably a 5- to 8-membered ring.

In formula (1A), R^{d} is halogen exclusive of fluorine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom. Examples of the halogen exclusive of fluorine include chlorine, bromine, and iodine, with iodine atom being preferred. The hydrocarbyl group may be saturated or unsaturated and straight, branched or cyclic. Examples thereof are as exemplified above for the hydrocarbyl group represented by R^{a} in formula (1). A plurality of R^{d} may be identical or different when n10 is 2. Also, when n10 is 2, two R^{d} may bond together to form a ring with the carbon atoms to which they are attached. The ring is preferably a 5- to 8-membered ring.

In formula (1A), R^{F1} and R^{F2} are each independently fluorine, pentafluorosulfanyl, a C₁-C₆ fluorinated saturated hydrocarbyl group, a C₁-C₆ fluorinated saturated hydrocarbyloxy group, or a C₁-C₆ fluorinated saturated hydrocarbylthio group. As R^{F1} and R^{F2}, fluorine, pentafluorosulfanyl, trifluoromethyl, difluoromethyl, trifluoromethoxy, difluoromethoxy, trifluoromethylthio or difluoromethylthio group is preferred, and fluorine, pentafluorosulfany, trifluoromethyl or trifluoromethoxy group is more preferred. When fluorine or one of these substituents having fluorine is contained, the acid strength of generated acid is improved by electron withdrawing effect, so that the deprotection reaction of an acid labile group such as a tertiary ester or tertiary ether described later smoothly proceeds. A plurality of R^{F1} may be identical or different when n10 is 2, 3, or 4. A plurality of R^{F2} may be identical or different when n11 is 2, 3, or 4.

Also, when n6 or n9 is 0 (that is, the relevant structure is a benzene ring), in a case where R^{F1} and R^{F2} are bonded to each aromatic ring, it is preferable that S⁺ of the sulfonium cation is bonded to the meta position from the carbon atom to which S⁺ is attached. By bonding to the above position, the electron attraction effect derived from the fluorine atom efficiently works, and the LUMO in frontier molecular orbital theory of the sulfonium cation is lowered, whereby the decomposition of the sulfonium cation is promoted, and an acid is effectively generated, so that the sensitivity is increased.

As the onium salt having formula (1A), an onium salt having the formula (1B) is preferred.

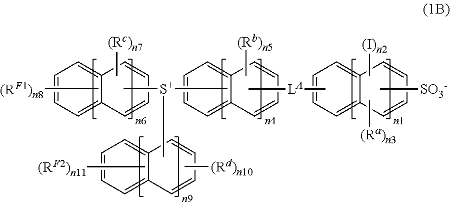

wherein n1 to n11, R^{a}, R^{b}, R^{c}, R^{d}, R^{F1}, R^{F2}, and L^{A} are as defined above.

Examples of the onium salt having formula (1) are shown below, but not limited thereto.

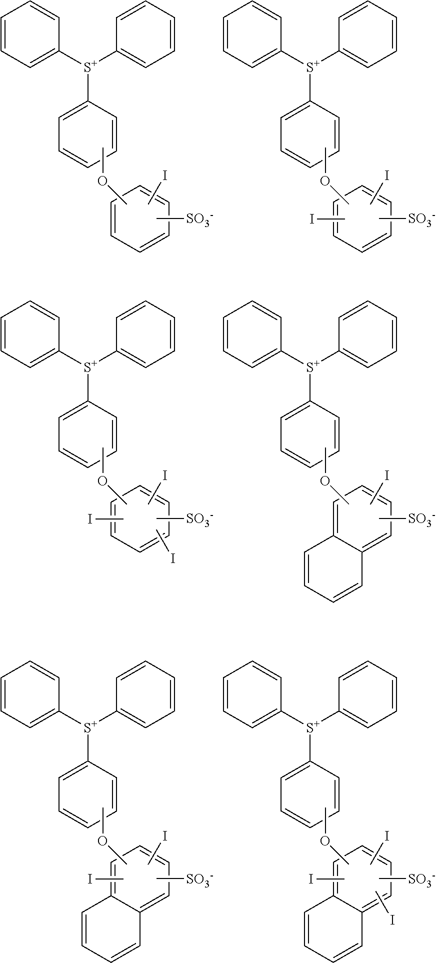

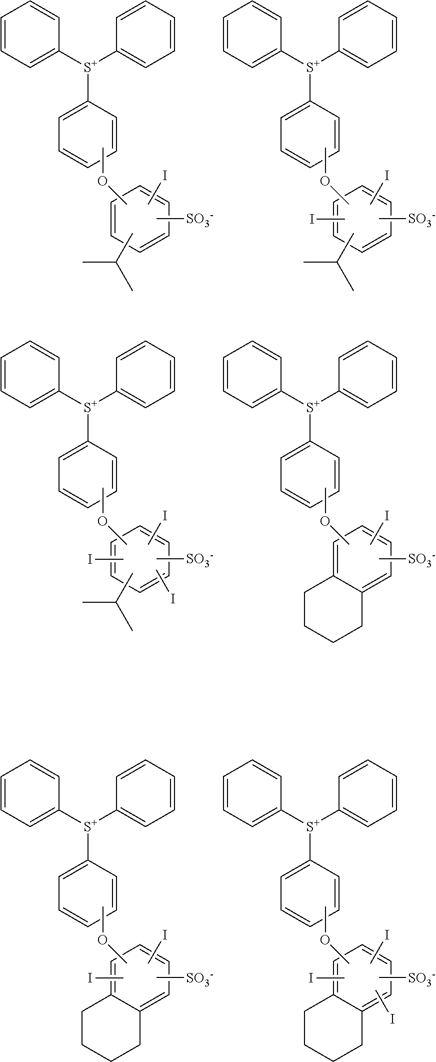

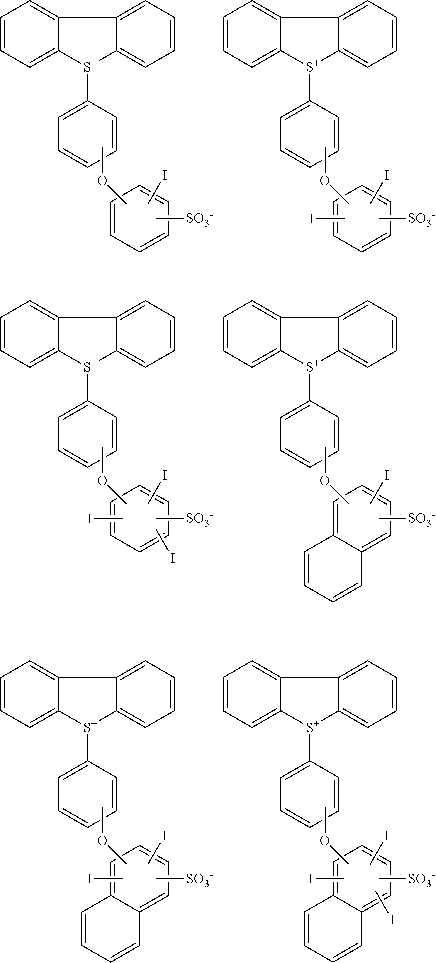

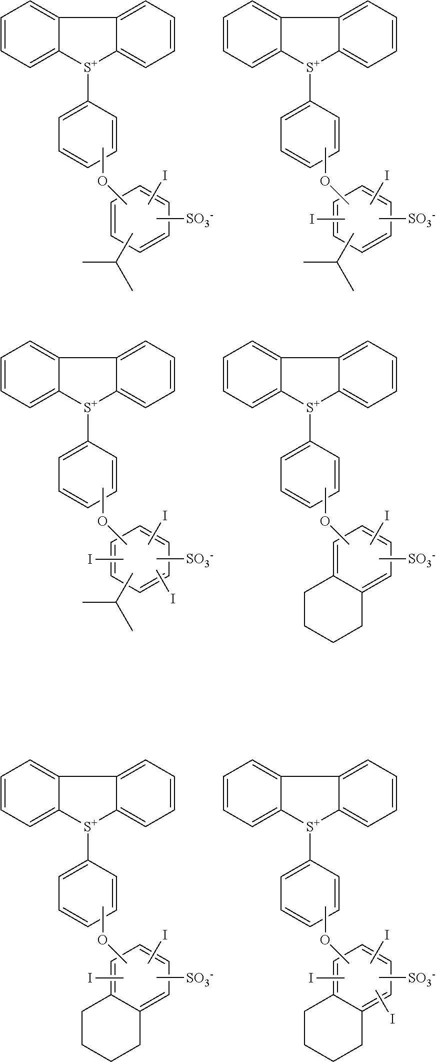

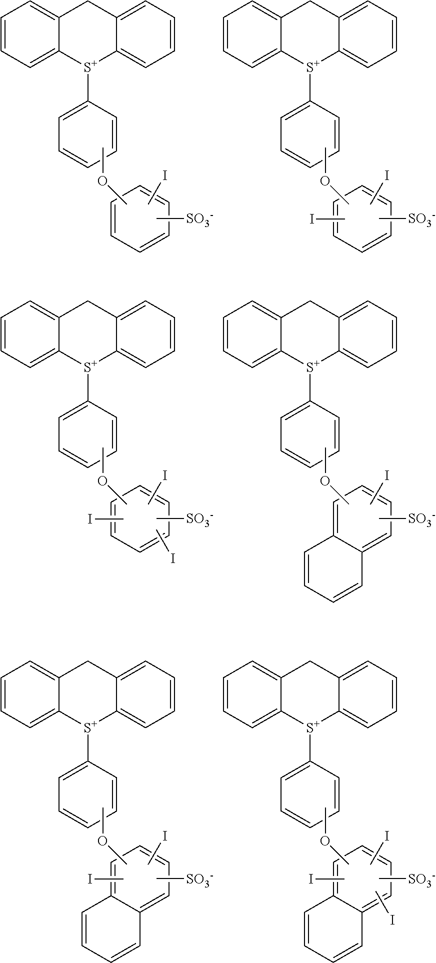

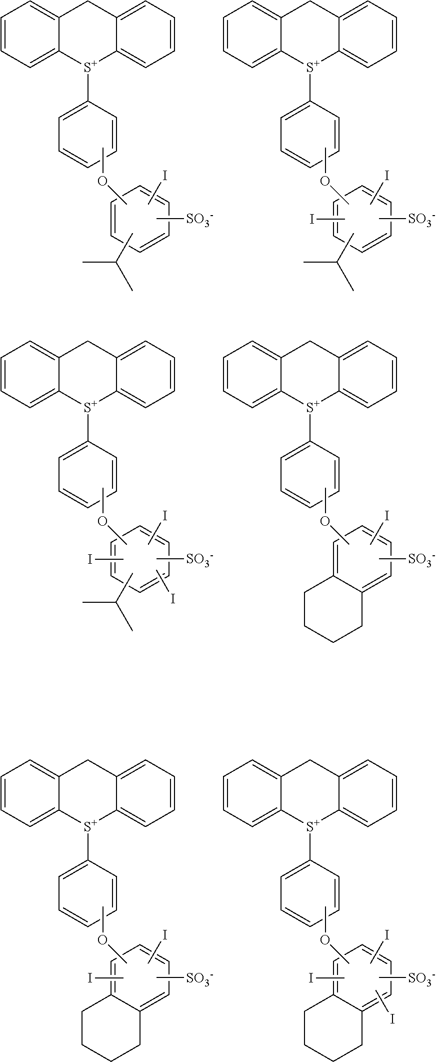

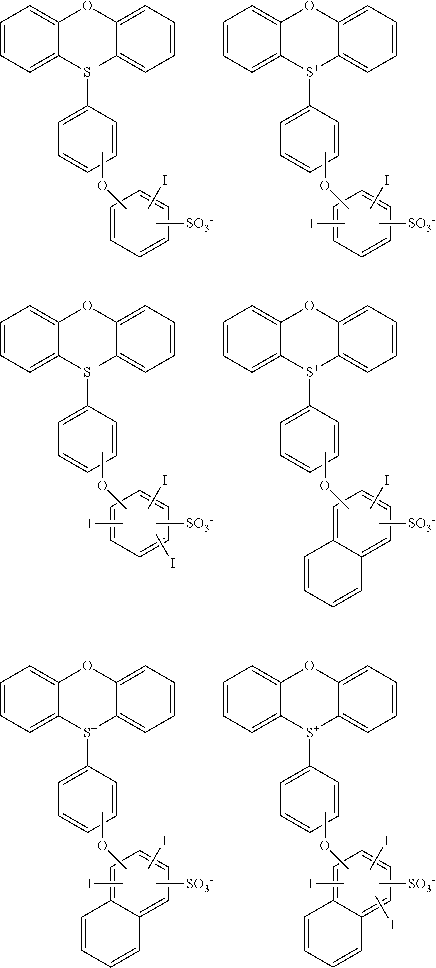

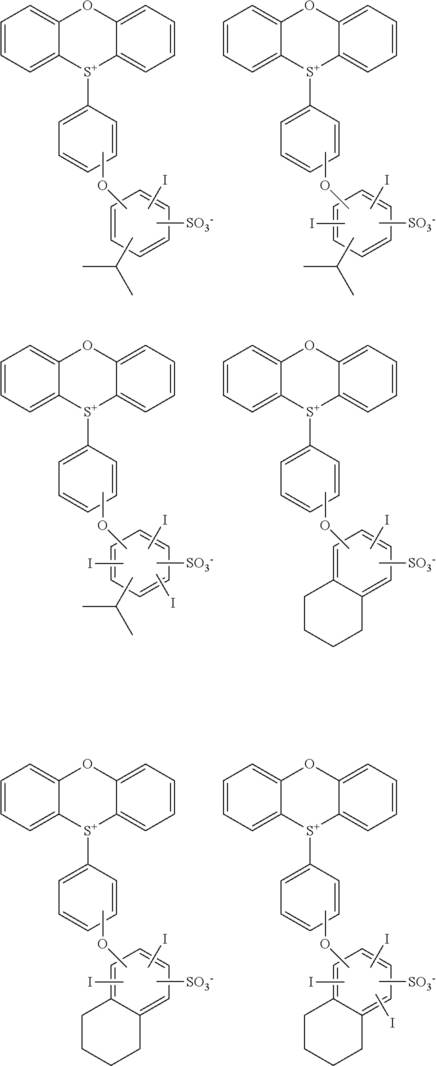

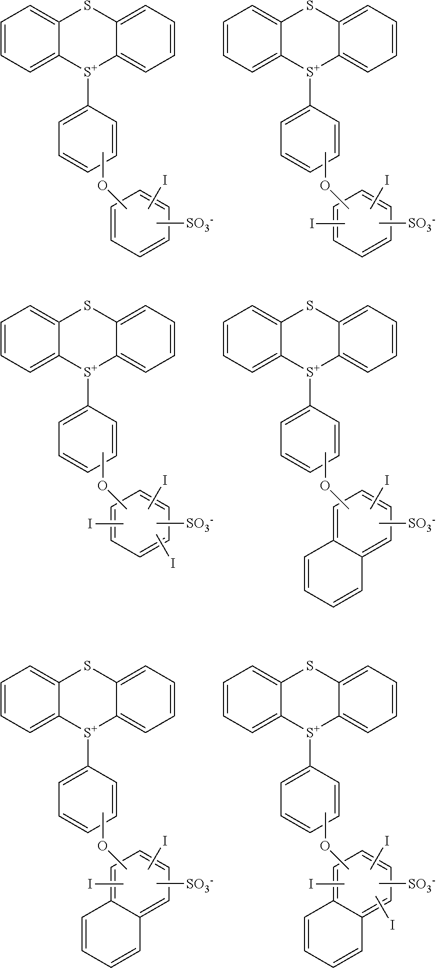

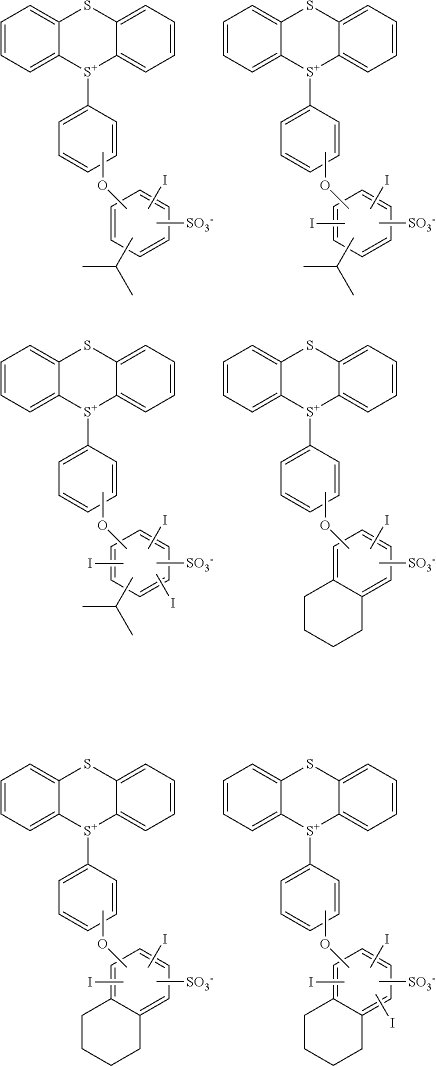

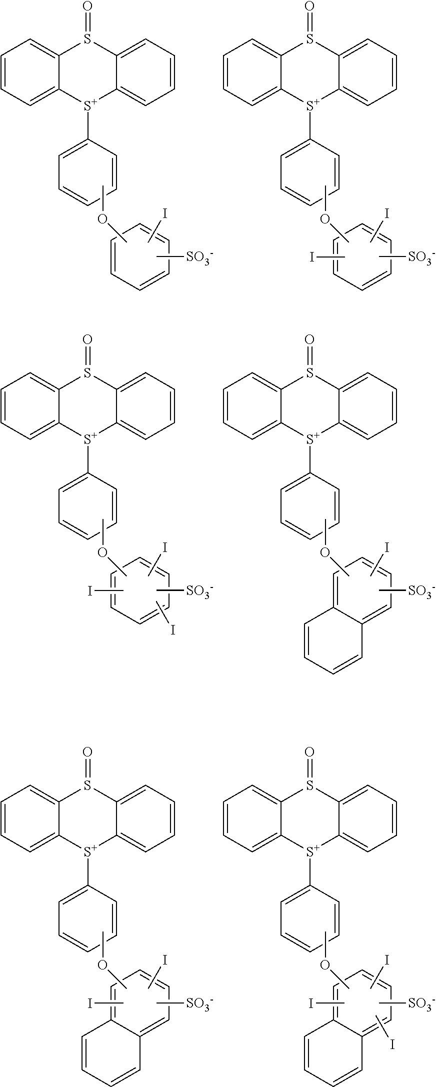

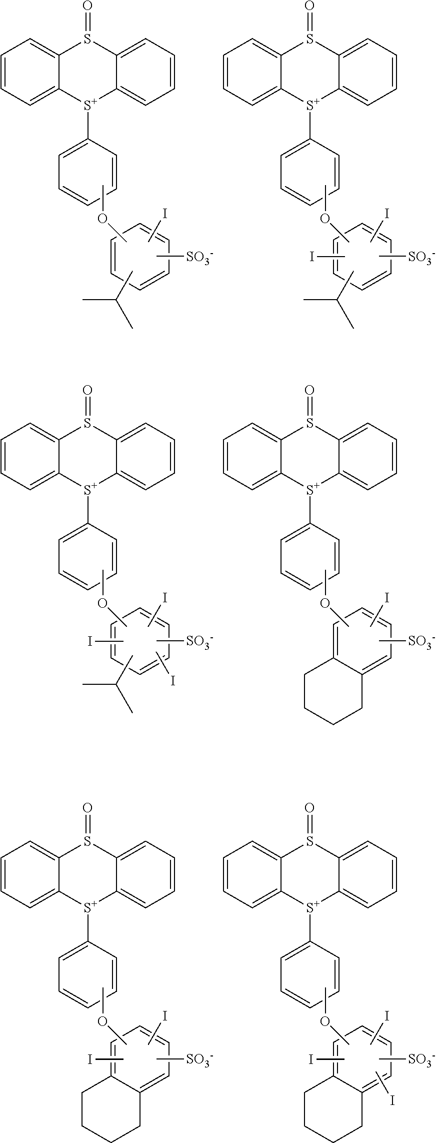

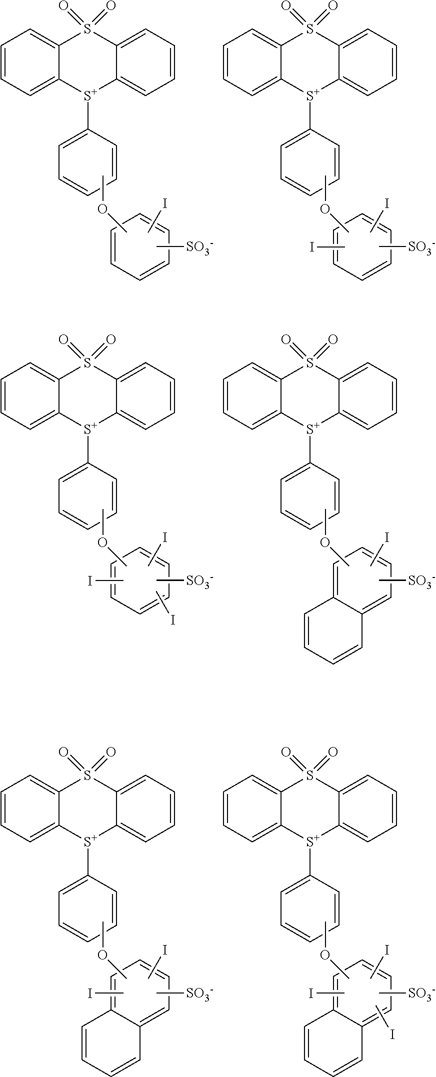

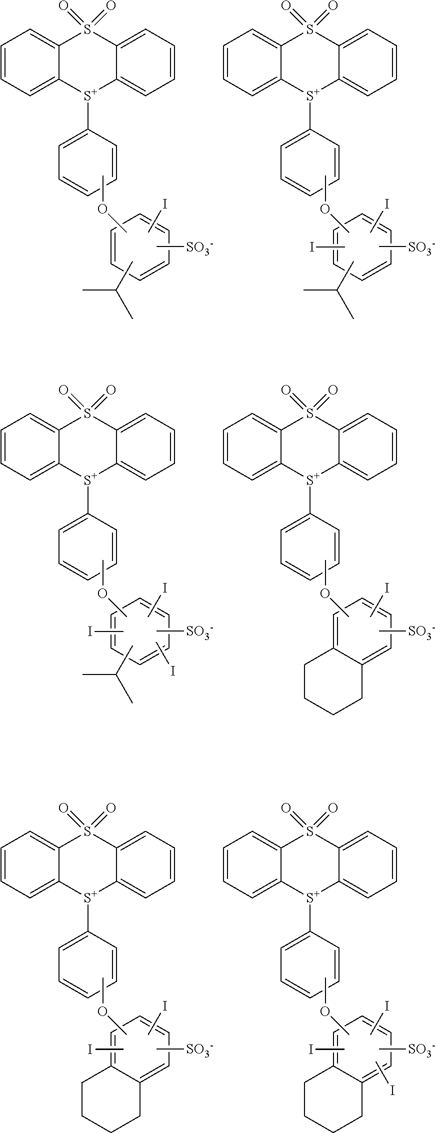

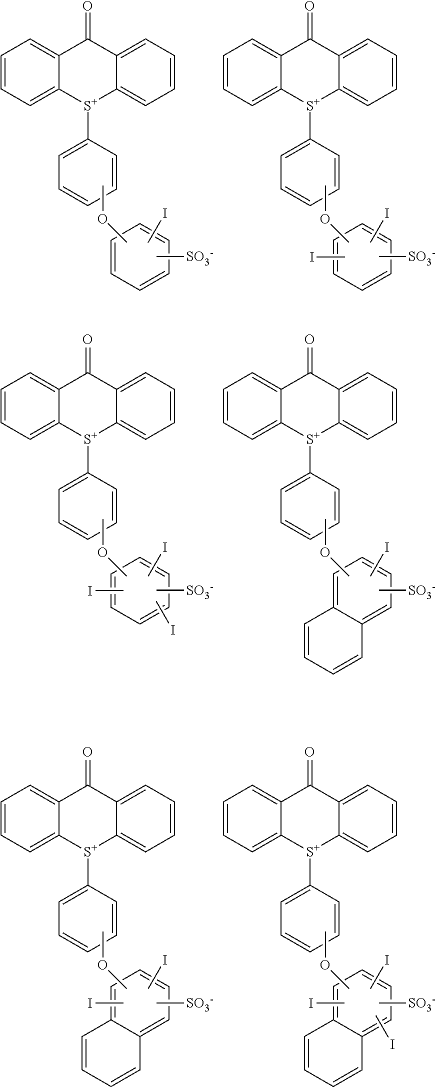

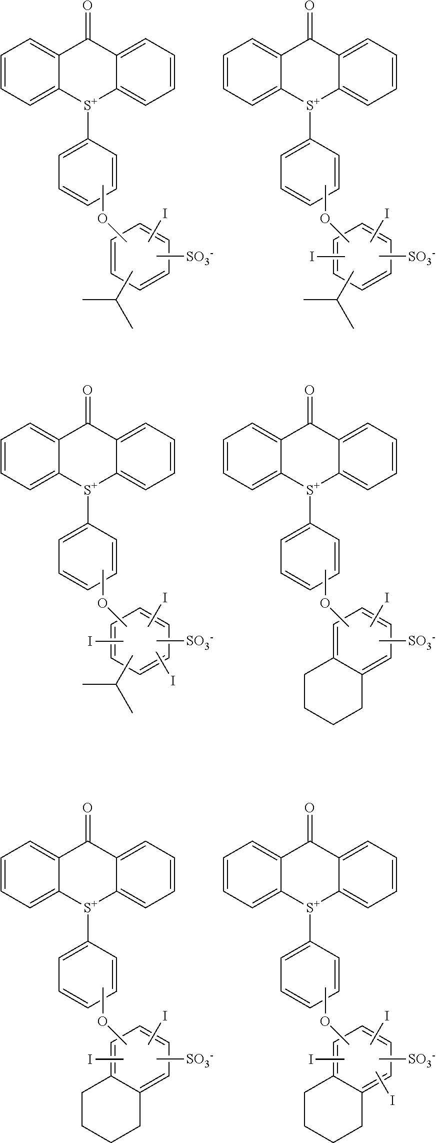

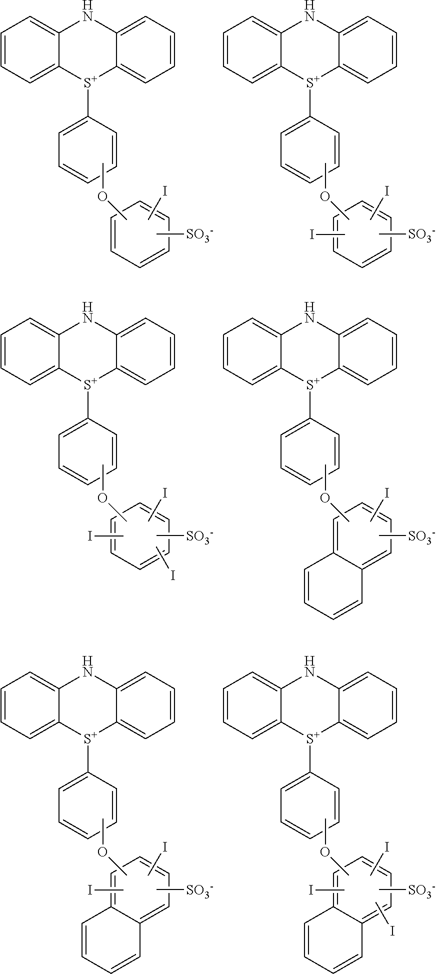

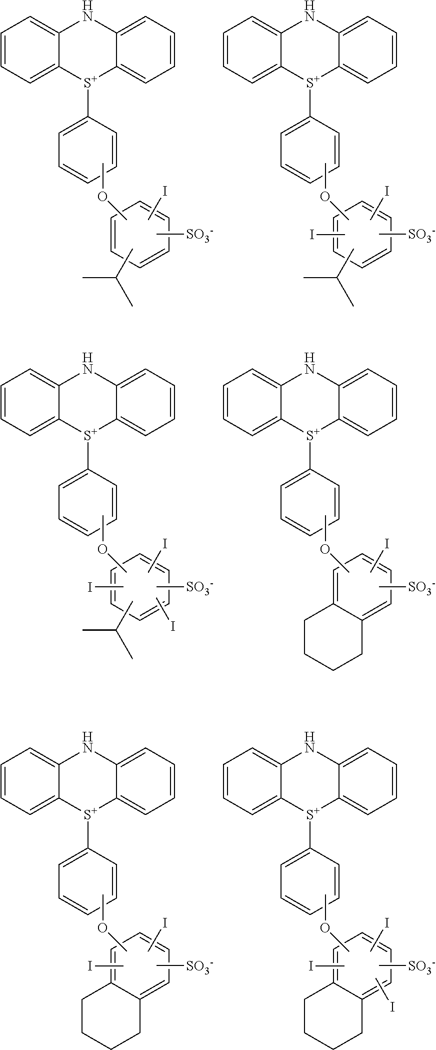

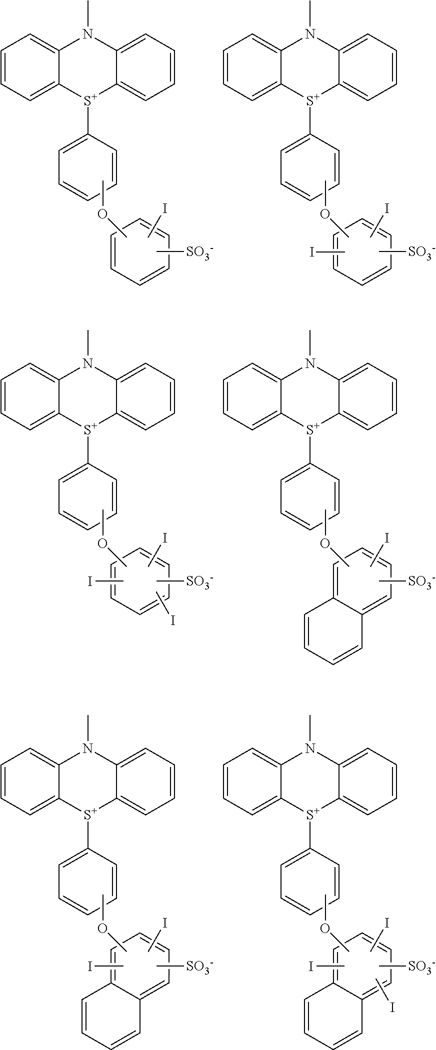

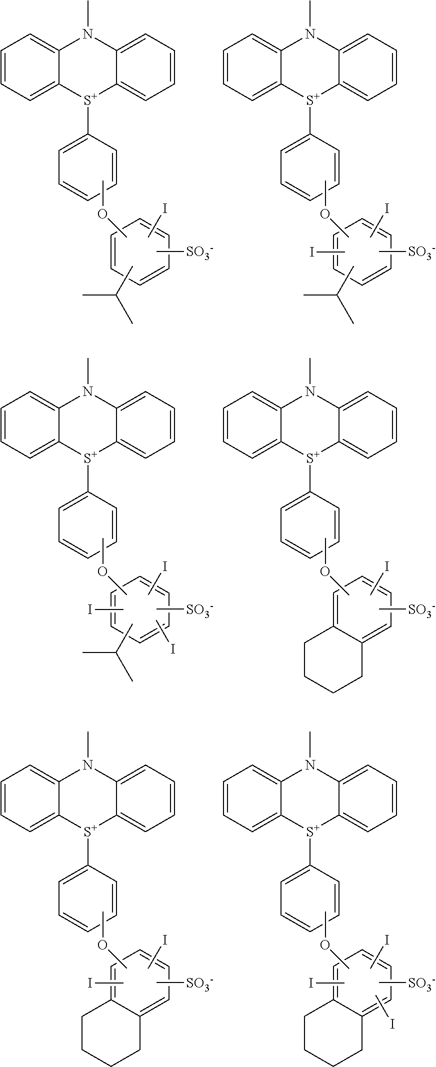

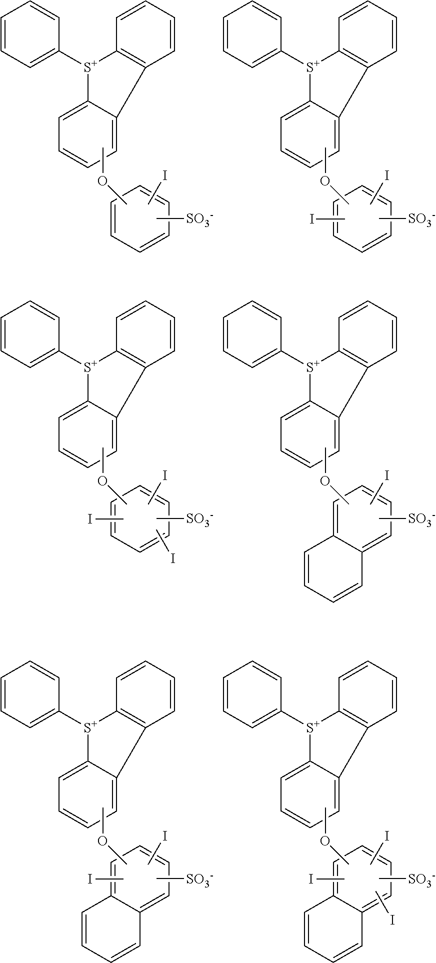

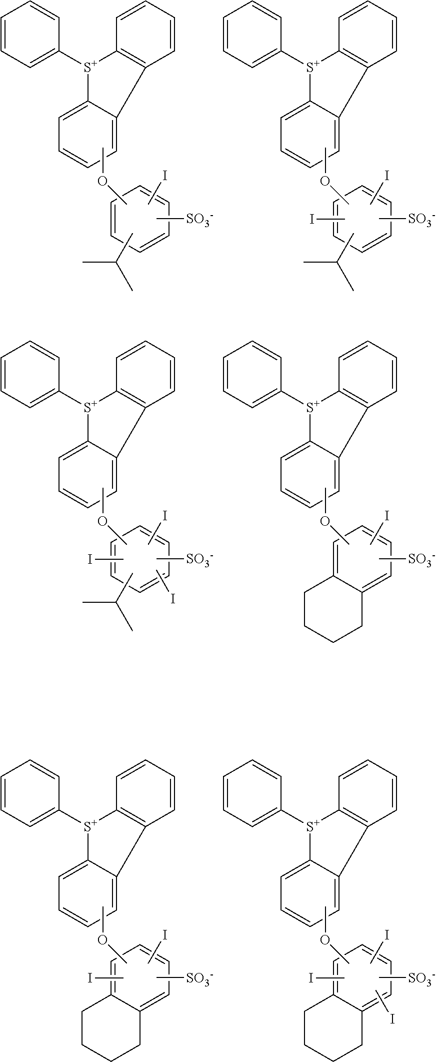

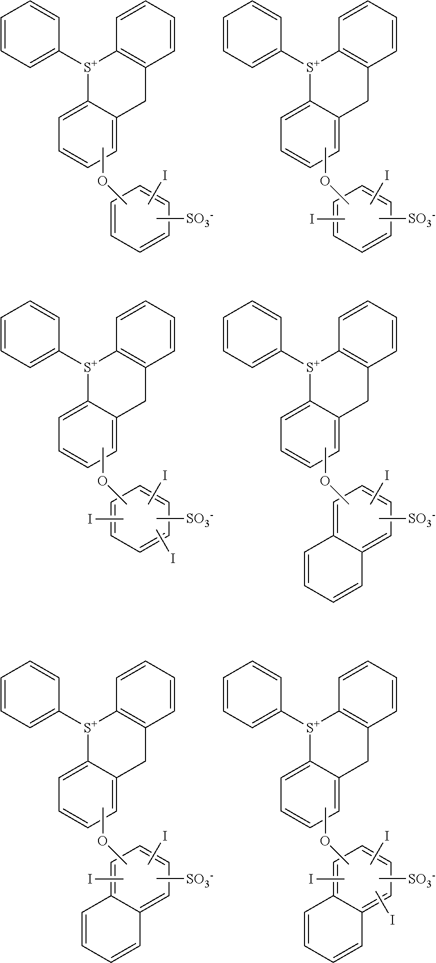

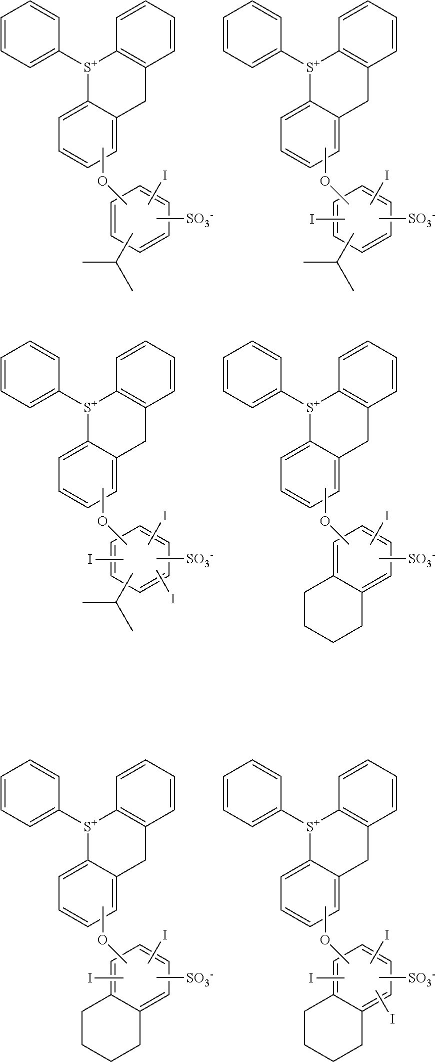

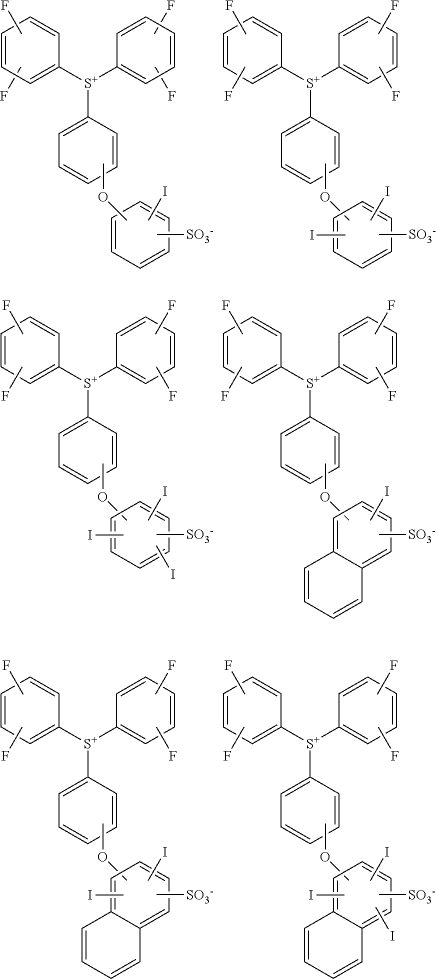

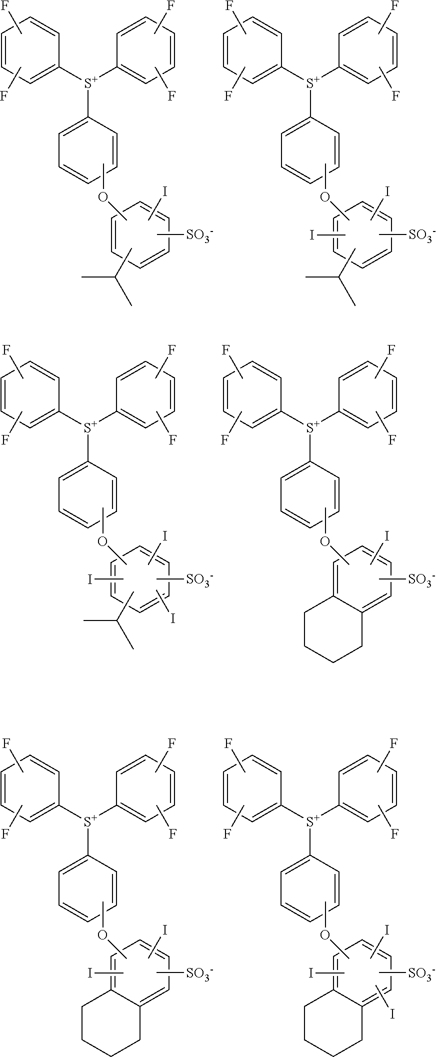

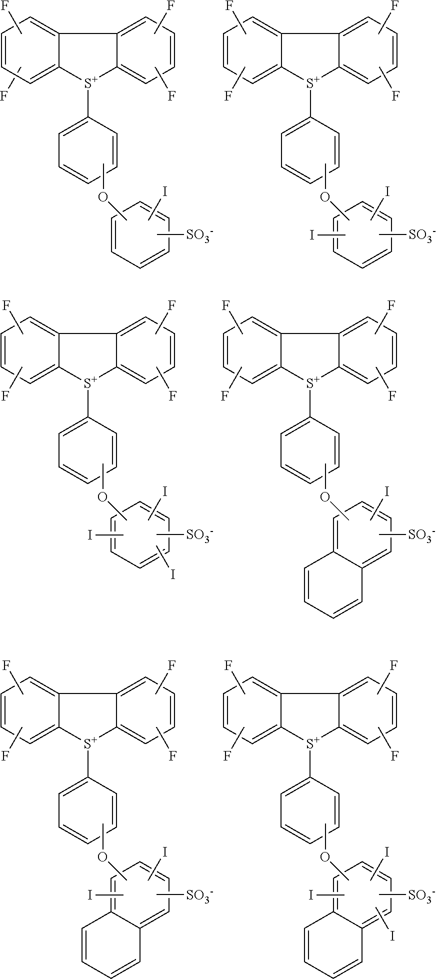

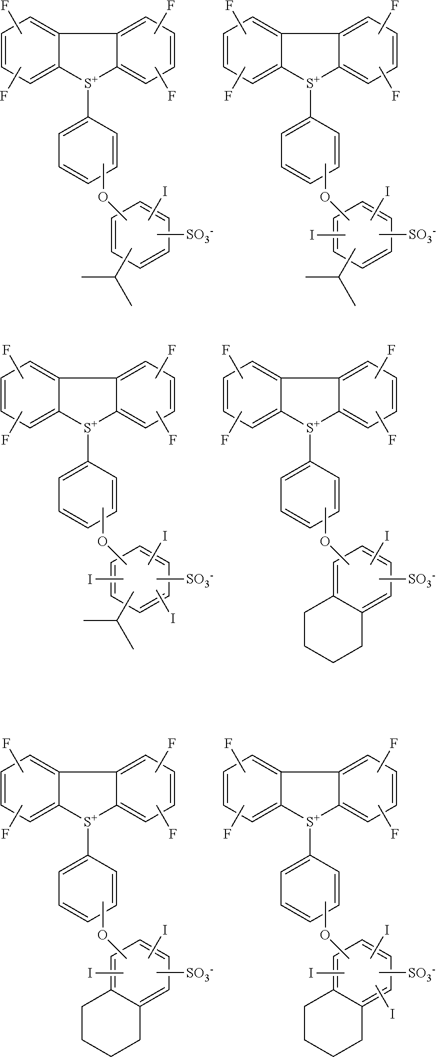

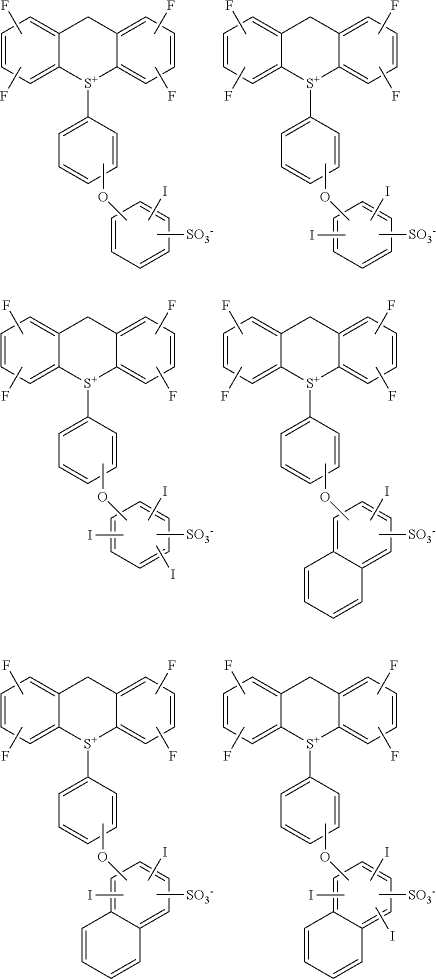

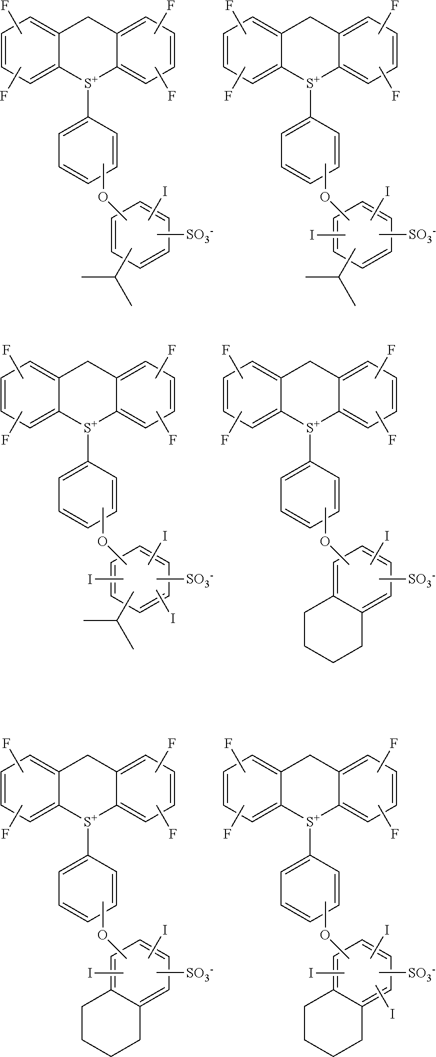

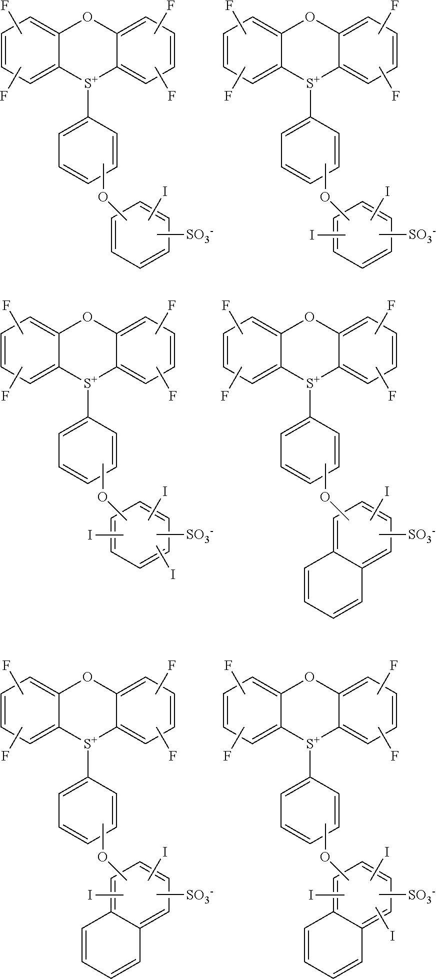

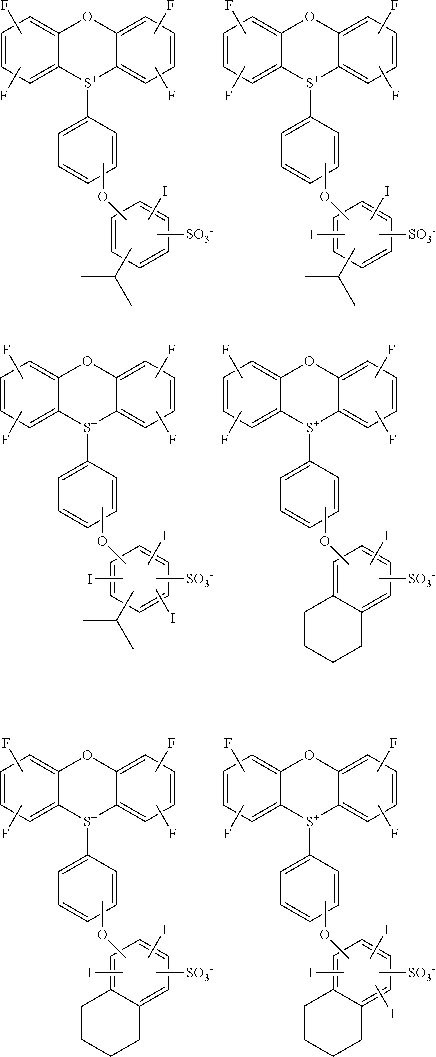

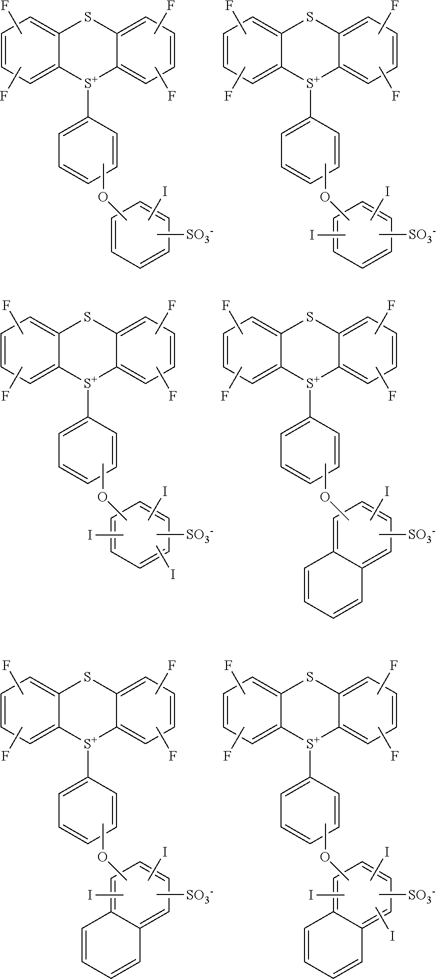

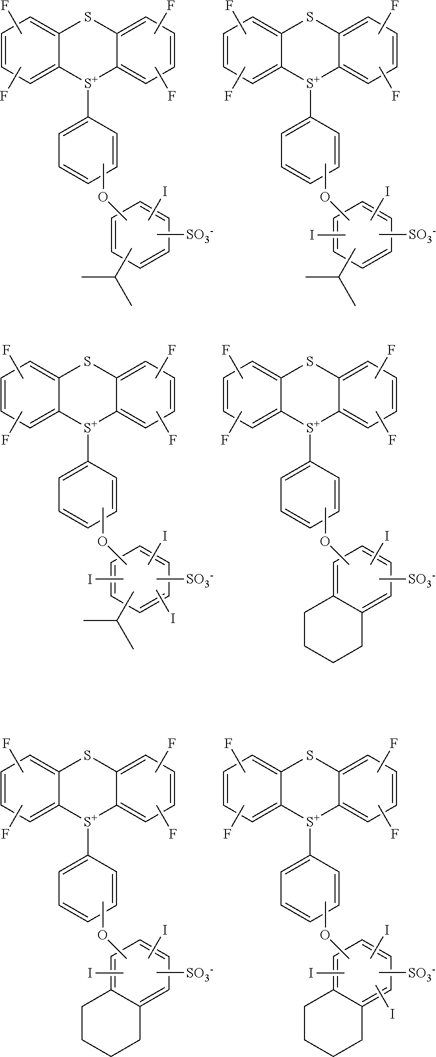

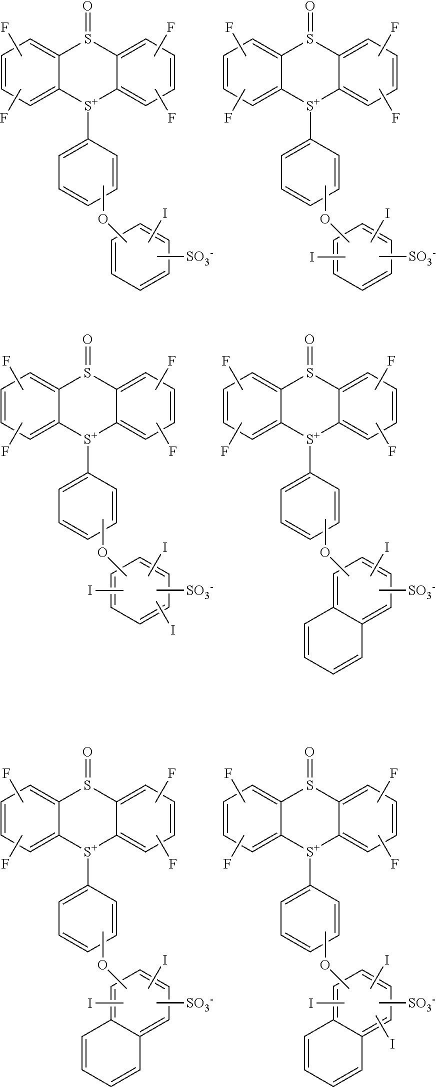

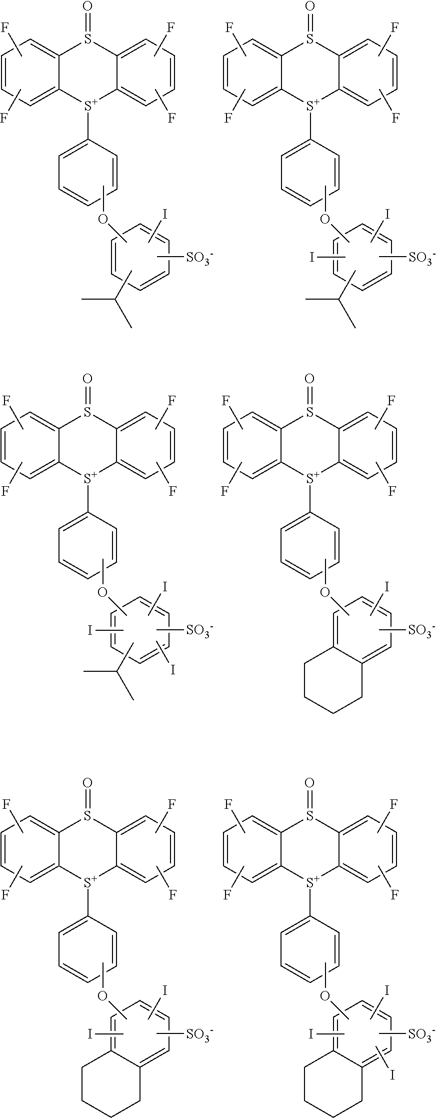

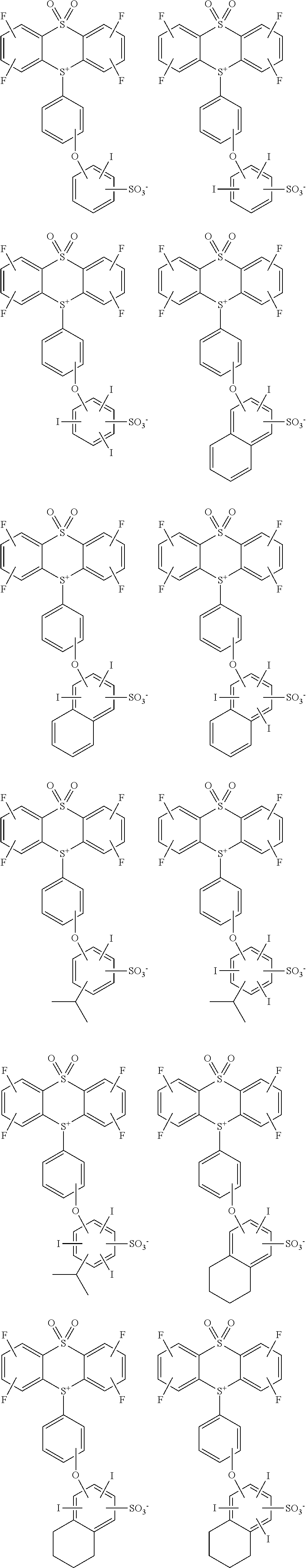

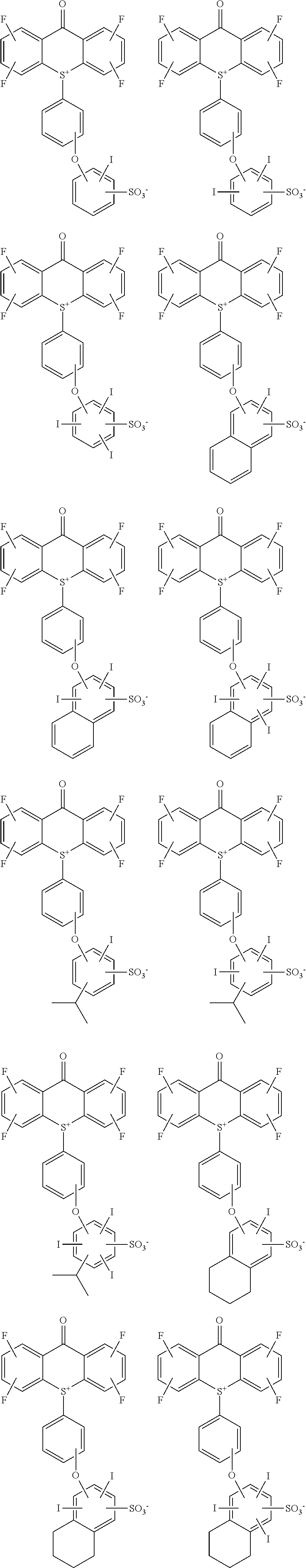

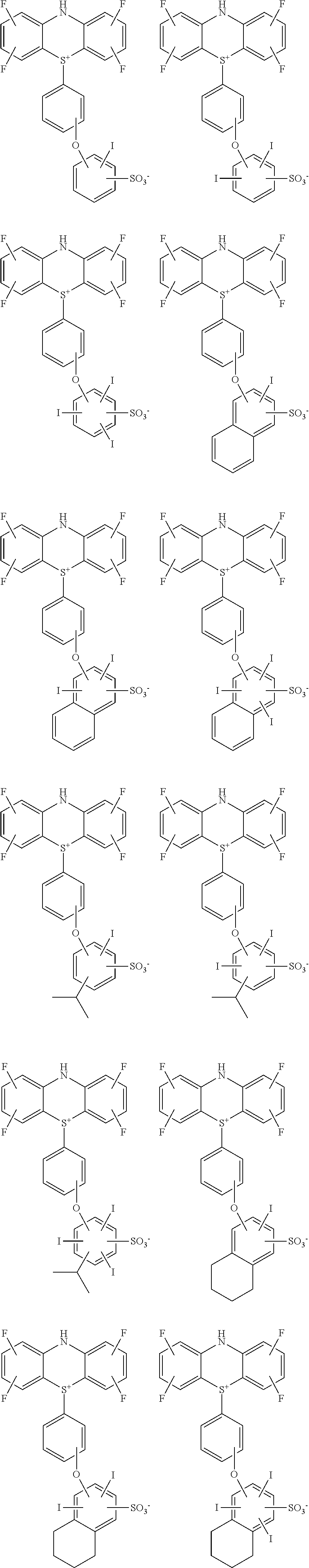

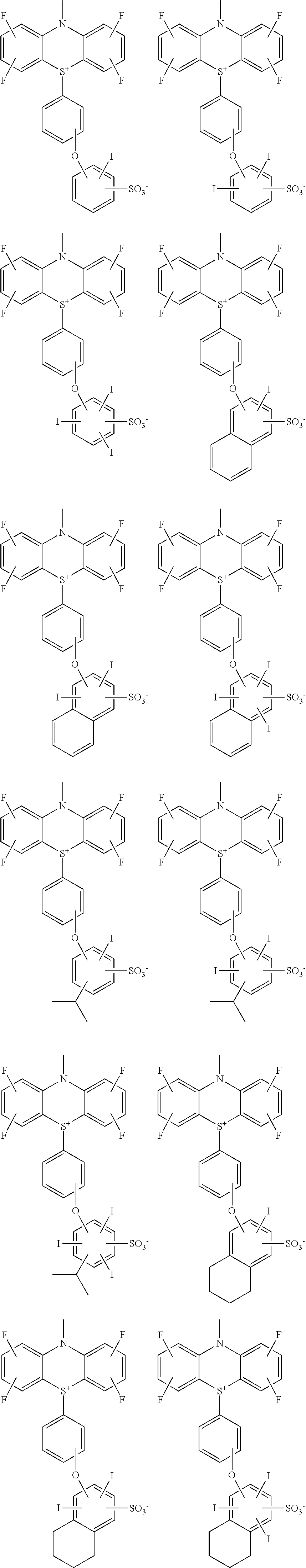

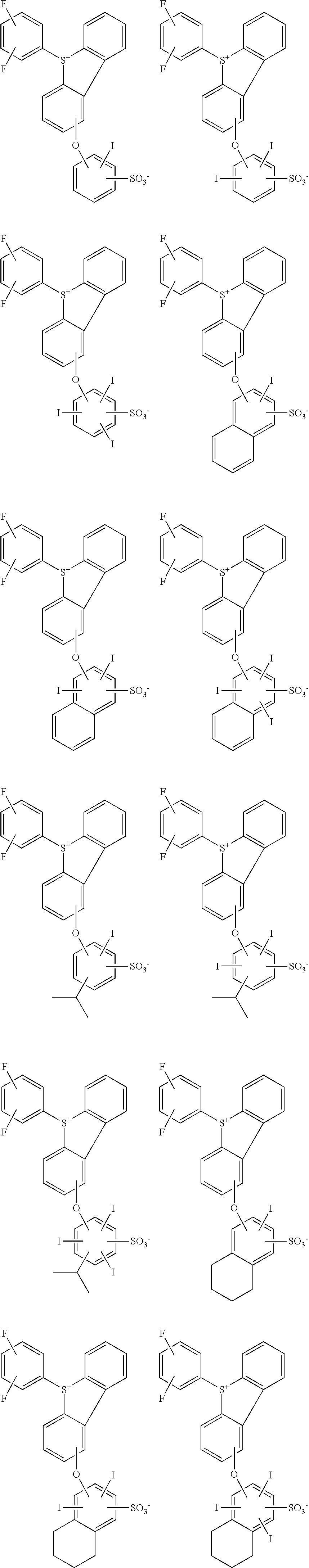

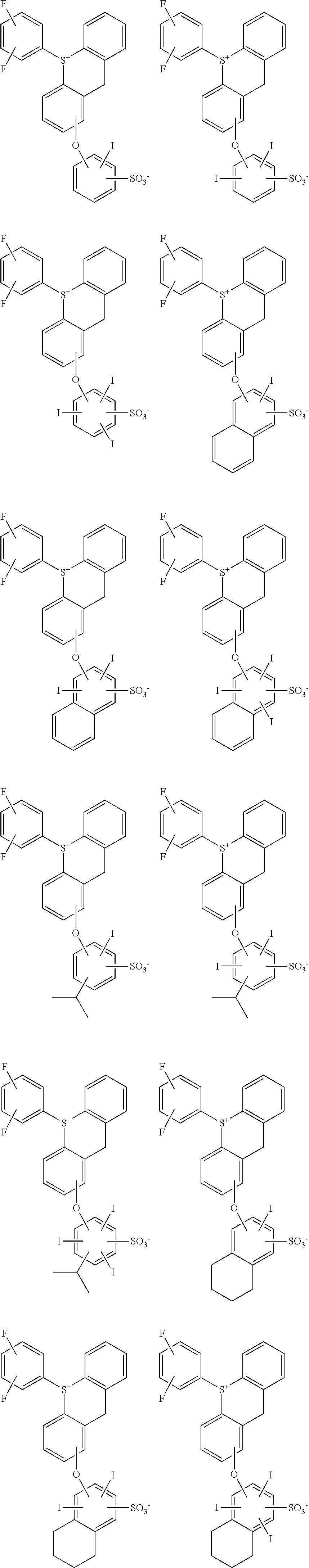

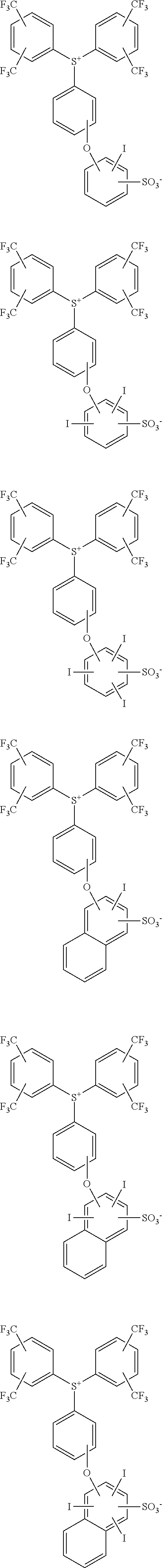

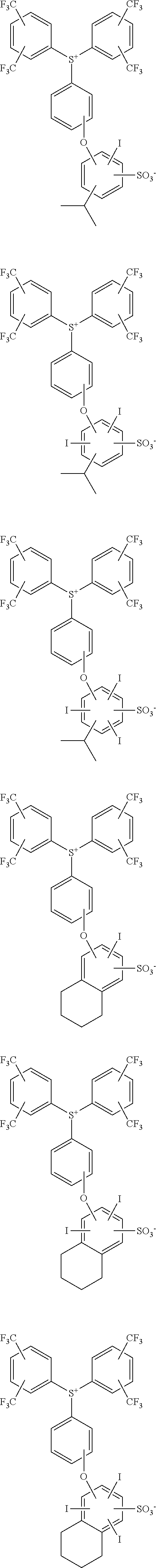

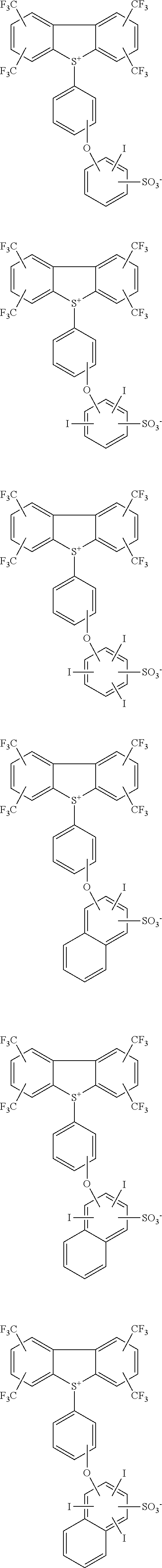

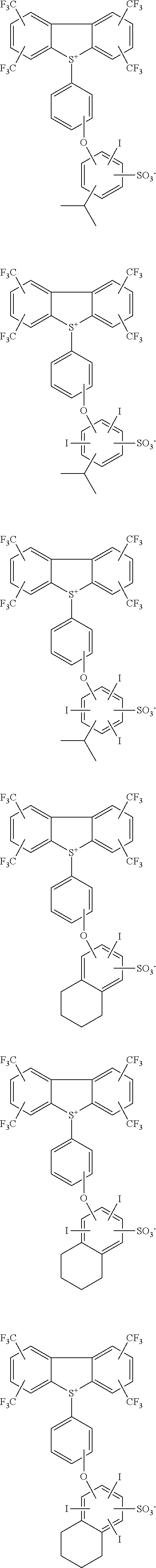

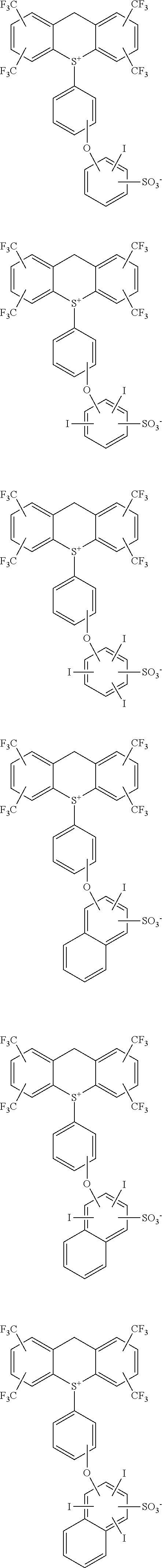

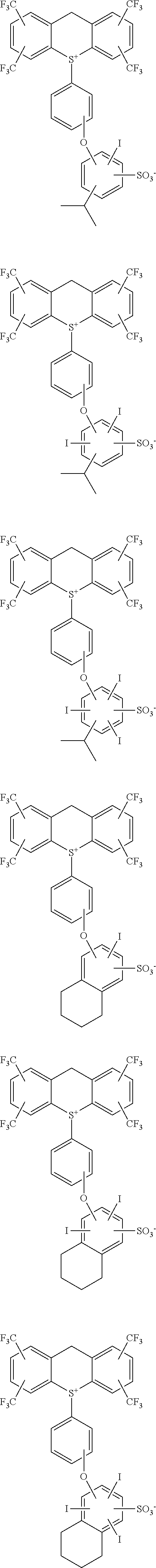

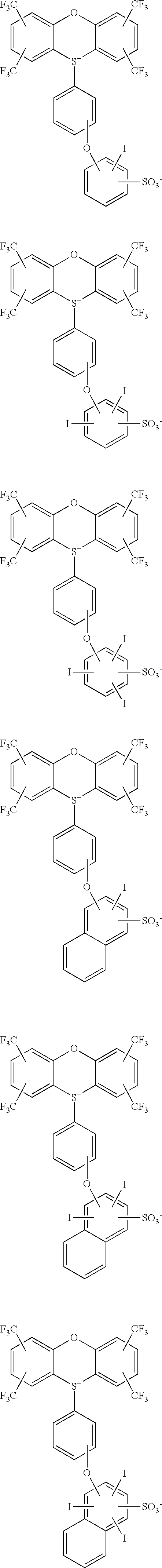

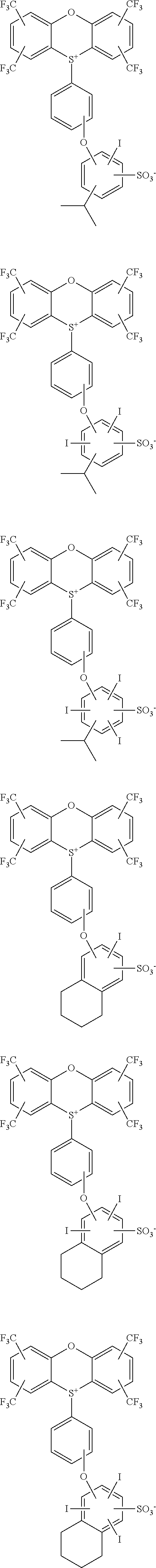

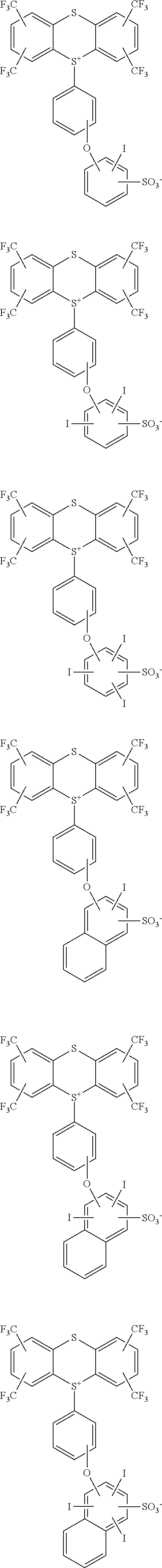

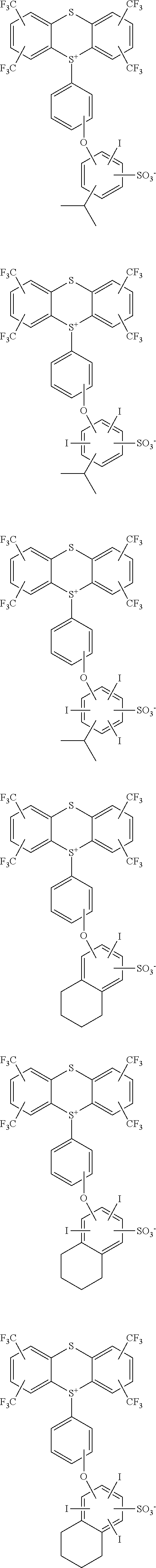

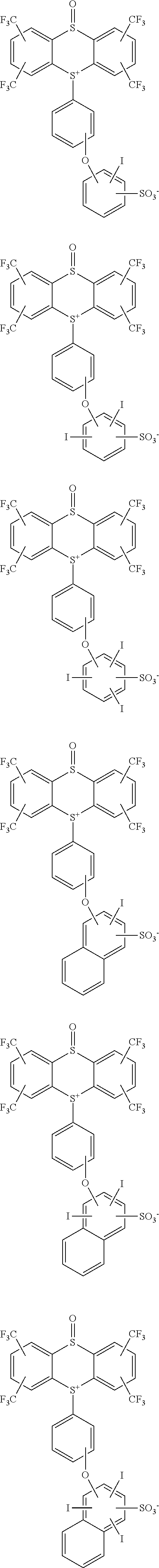

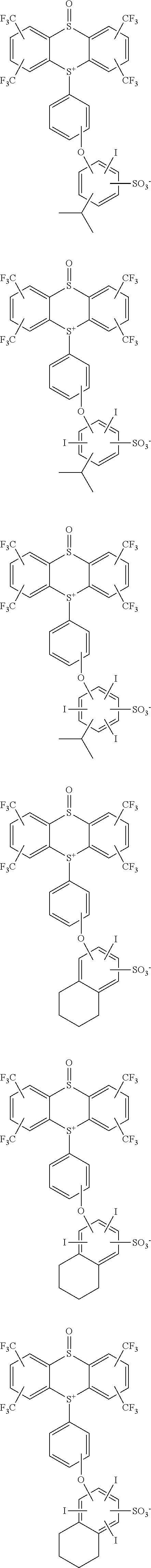

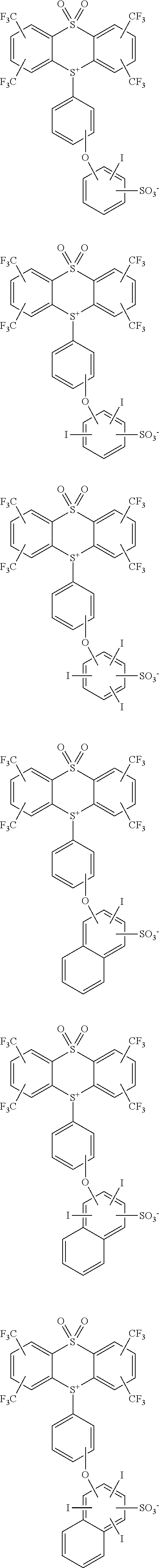

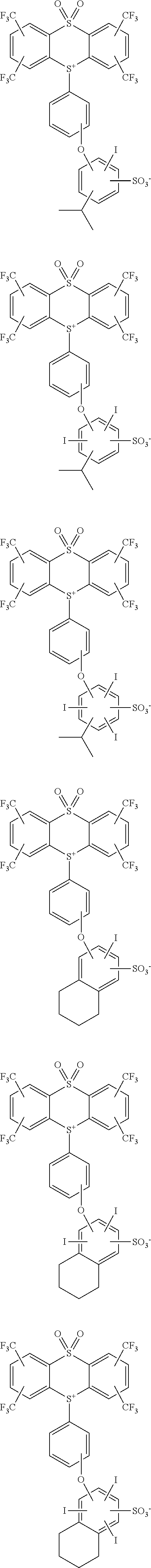

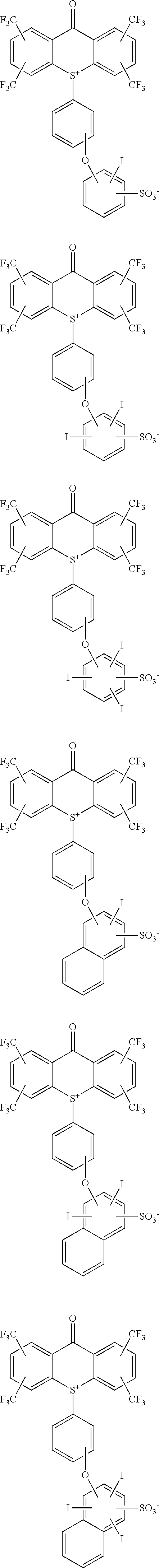

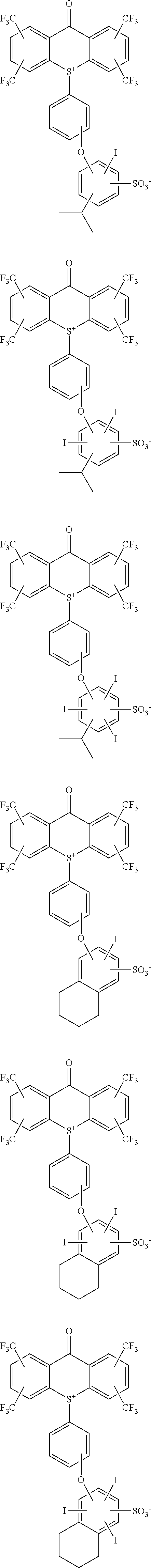

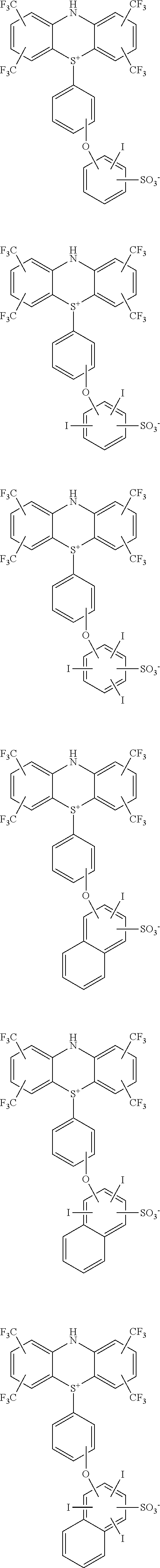

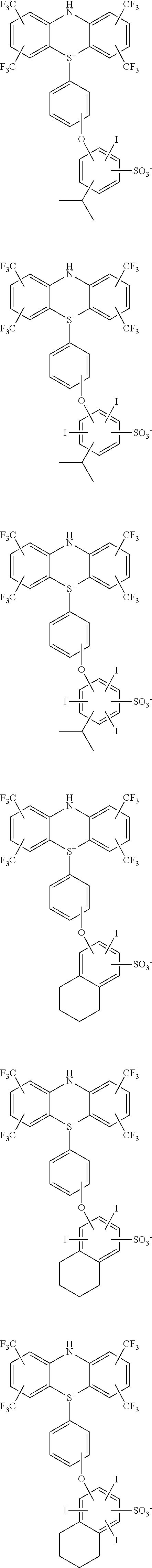

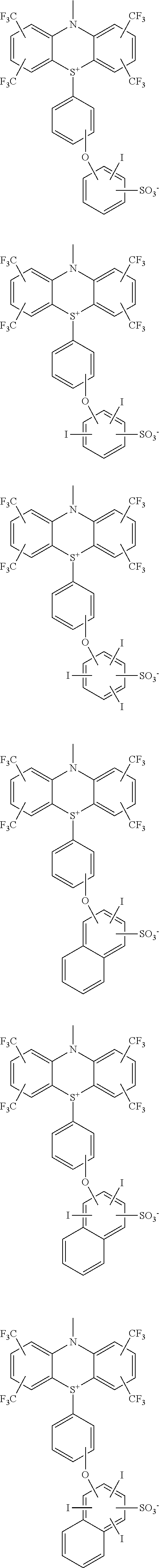

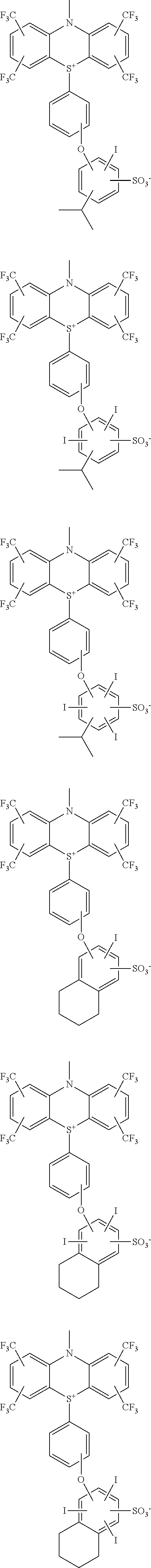

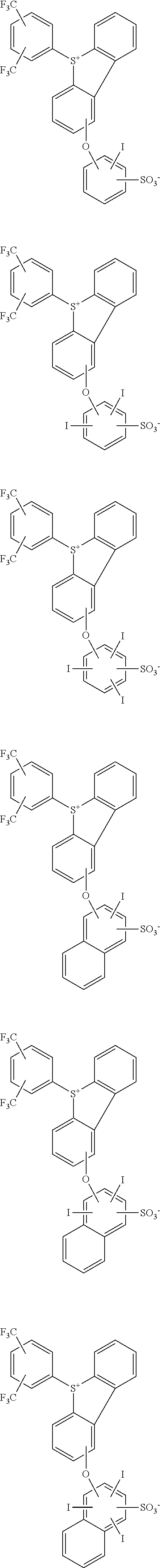

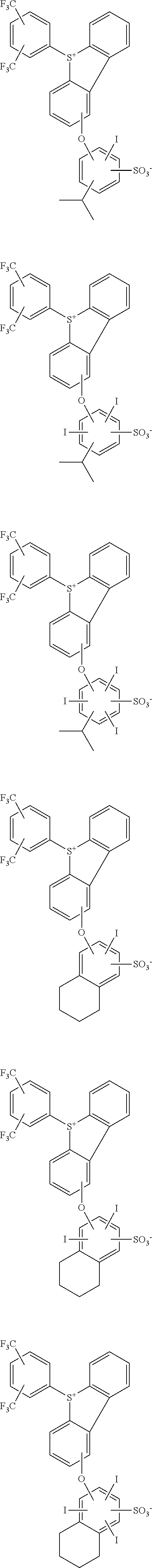

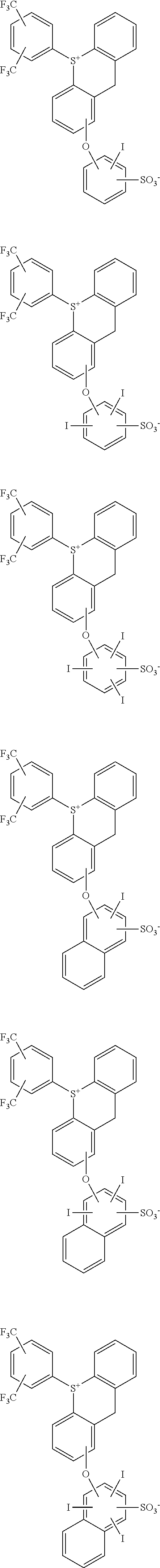

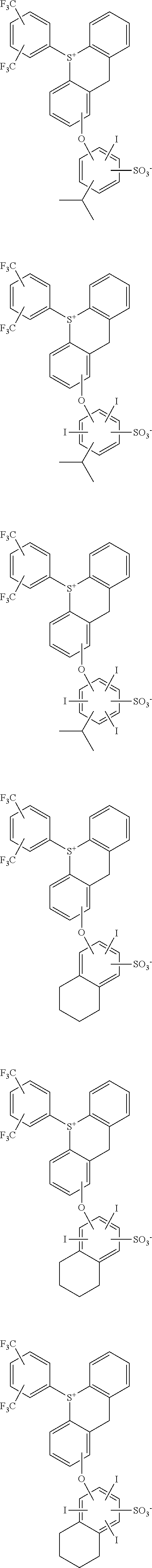

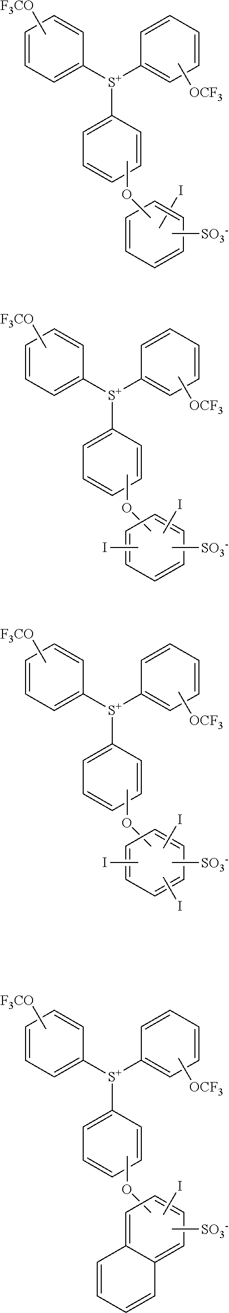

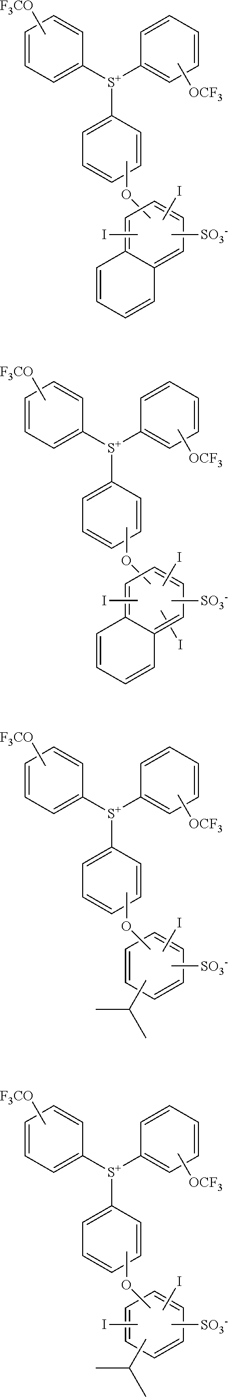

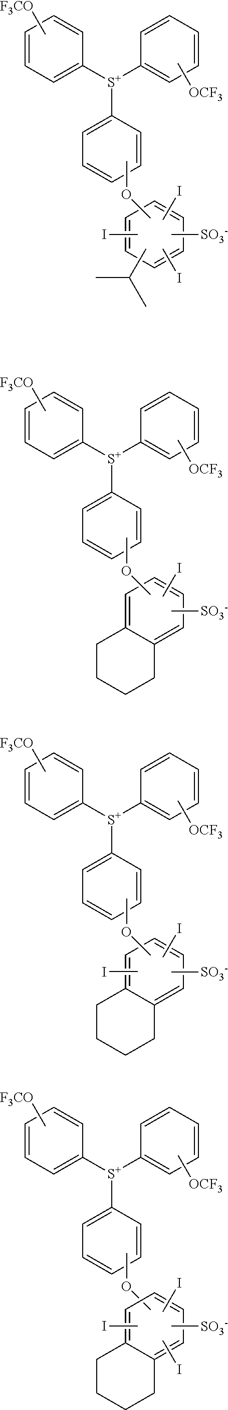

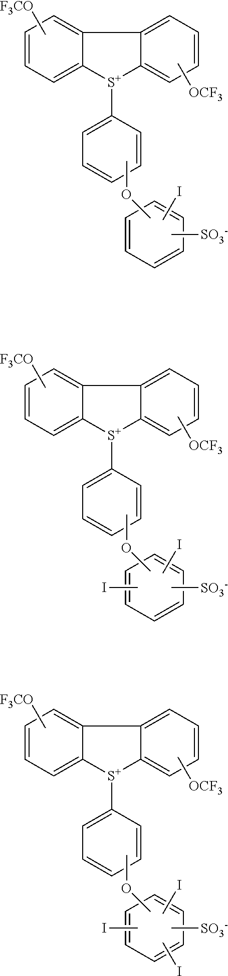

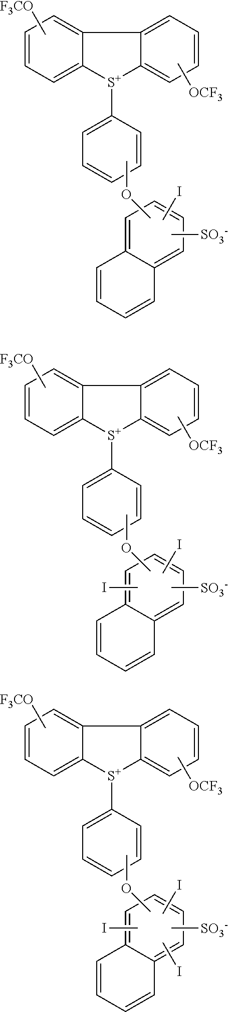

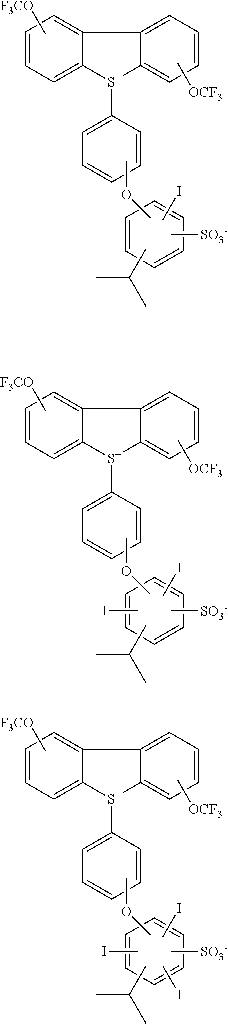

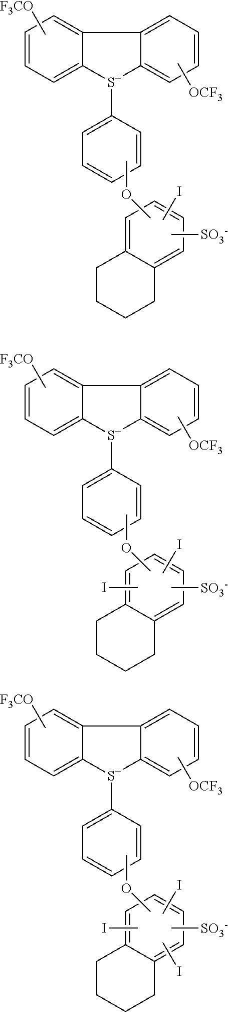

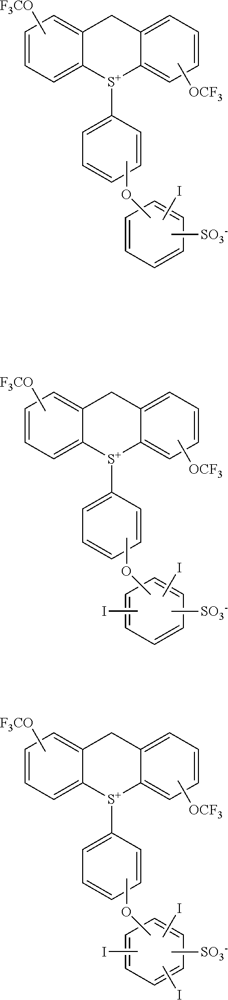

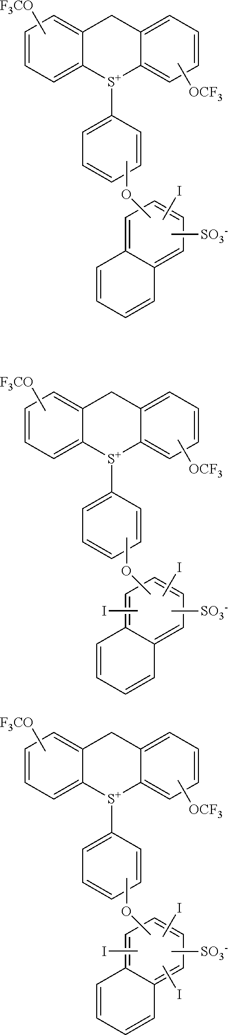

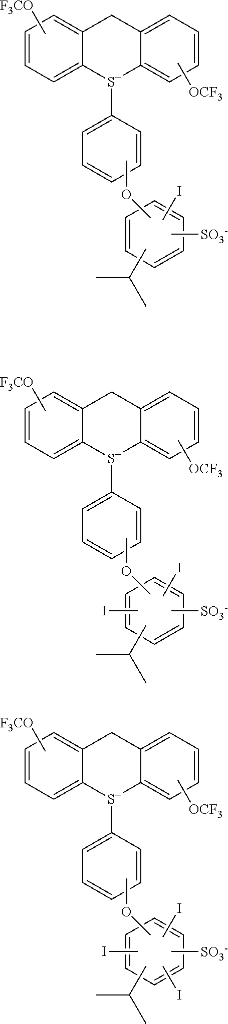

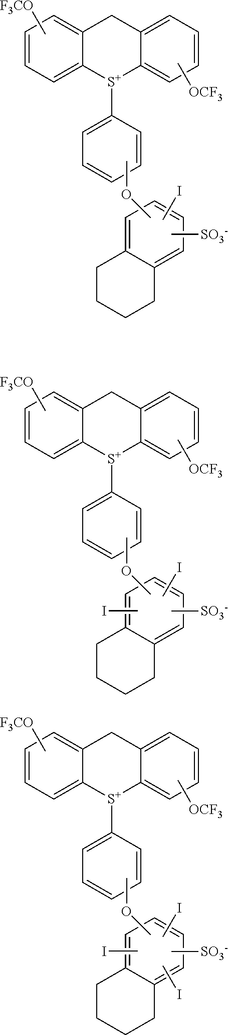

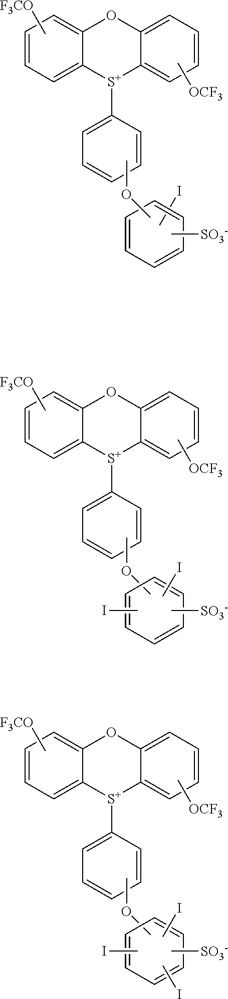

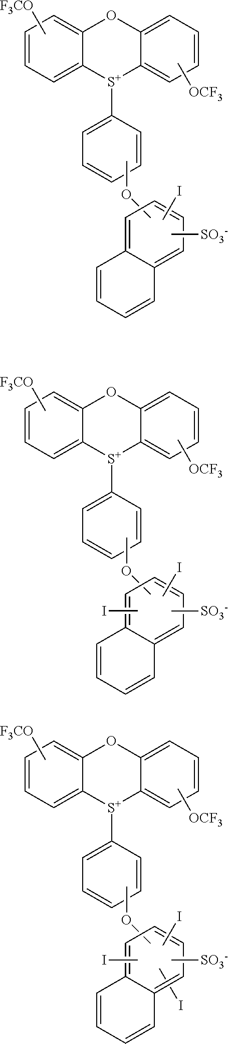

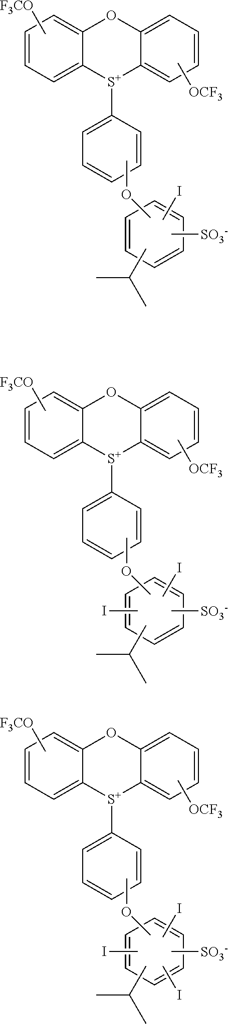

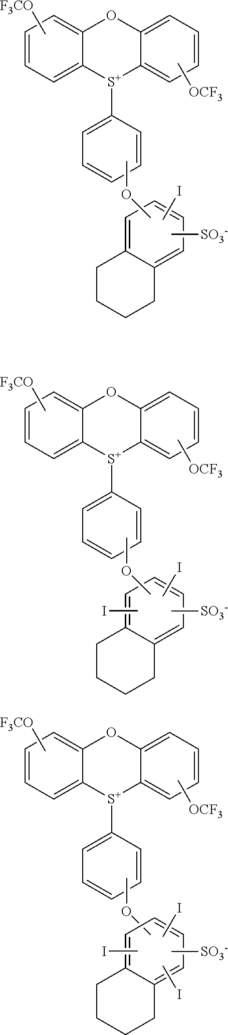

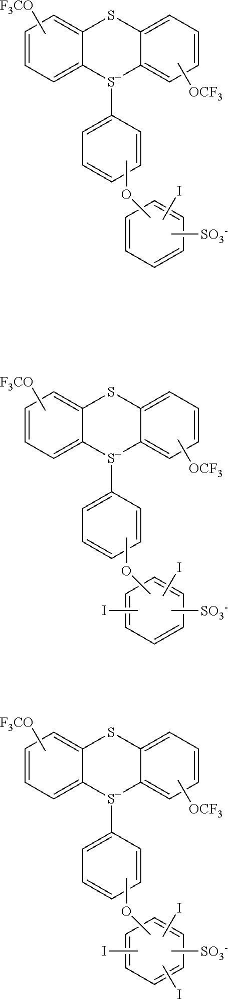

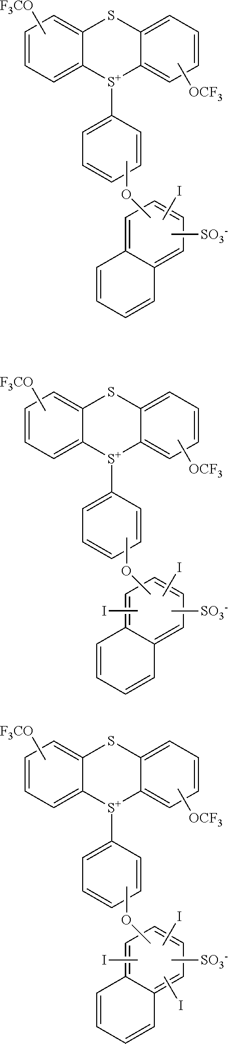

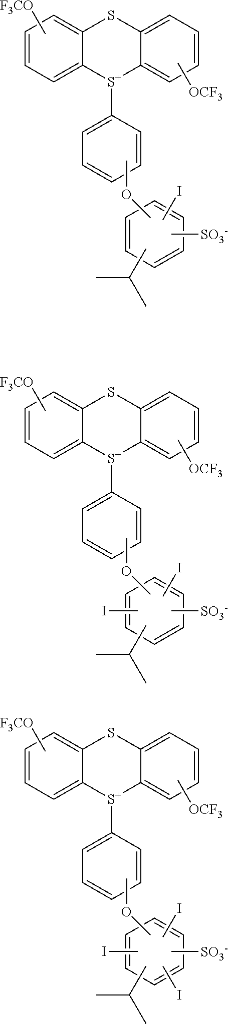

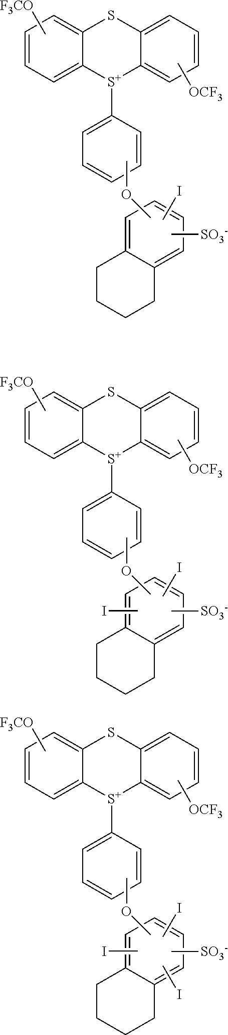

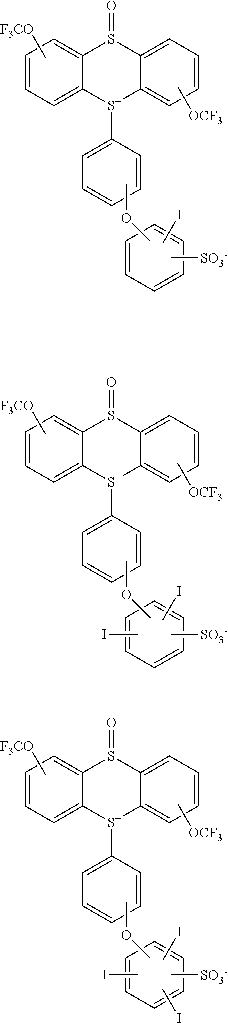

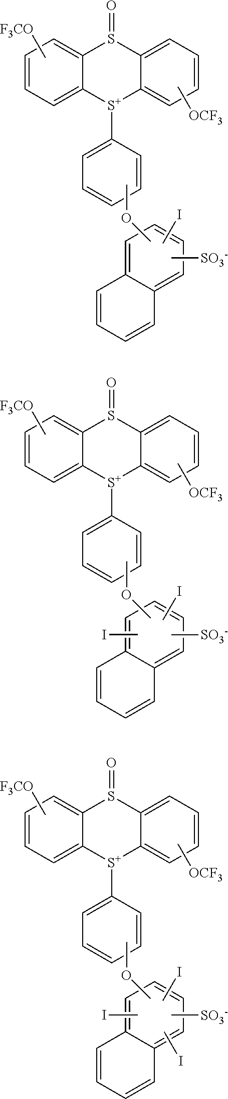

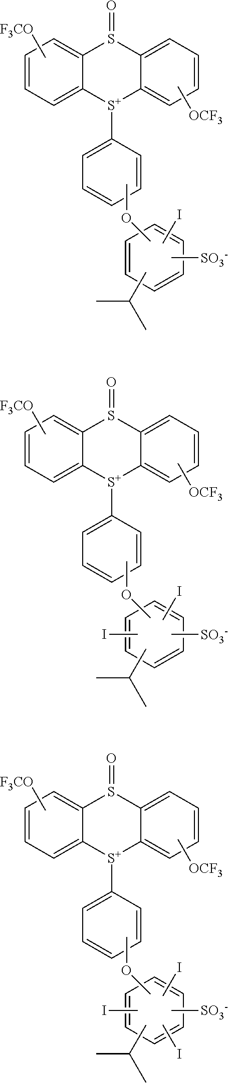

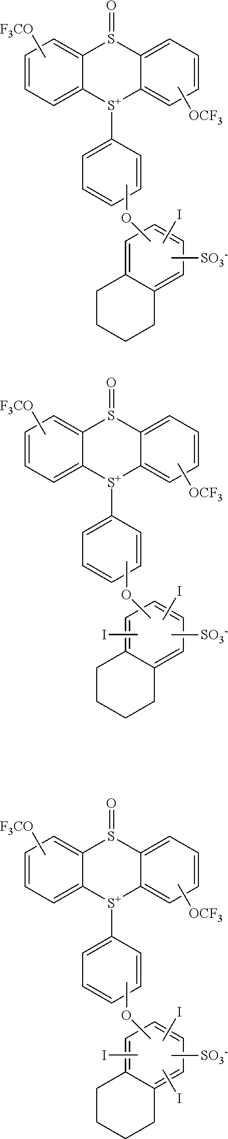

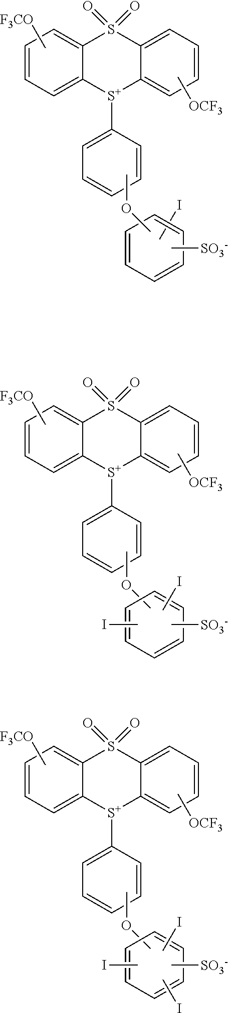

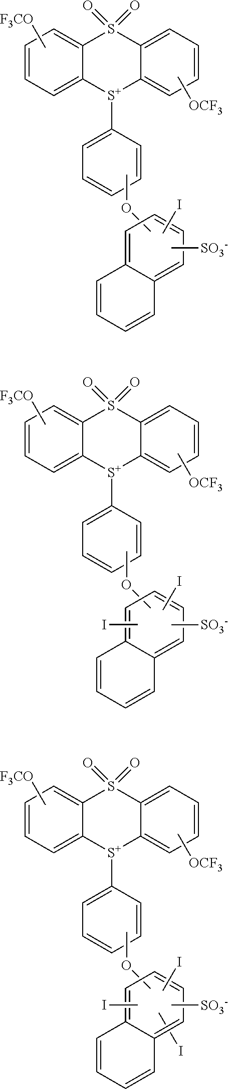

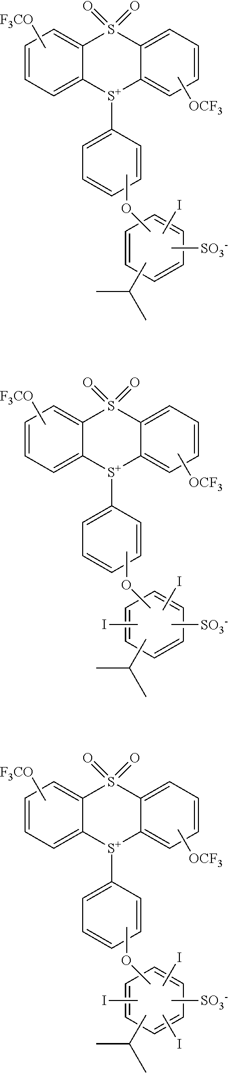

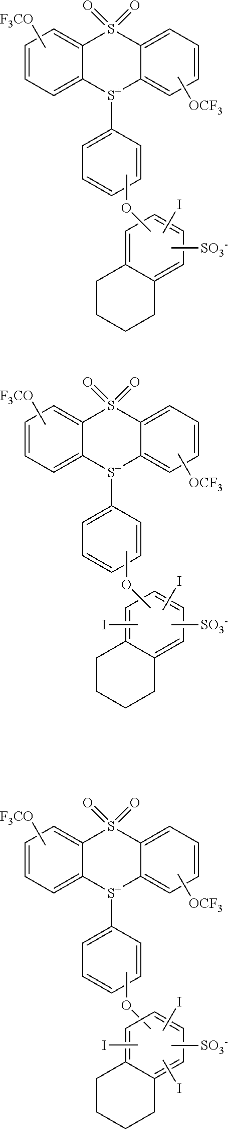

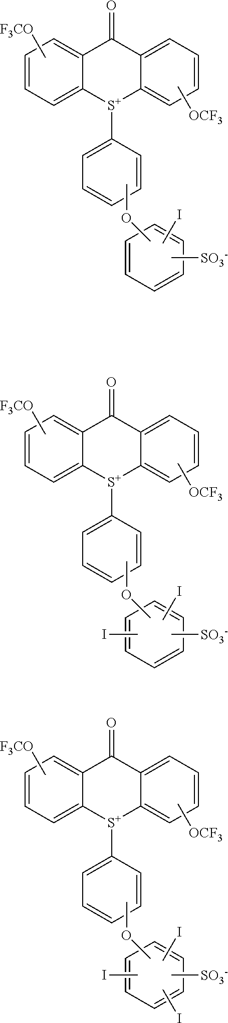

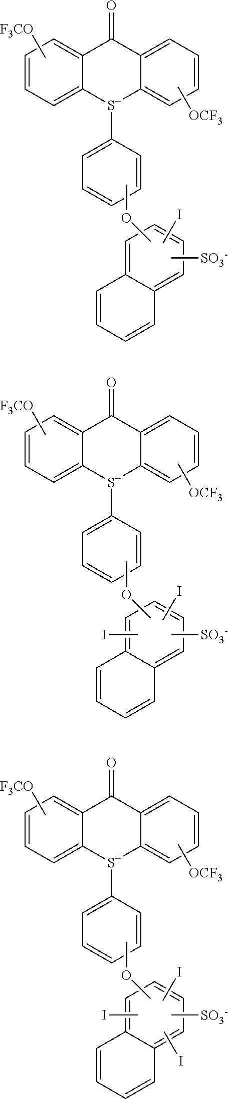

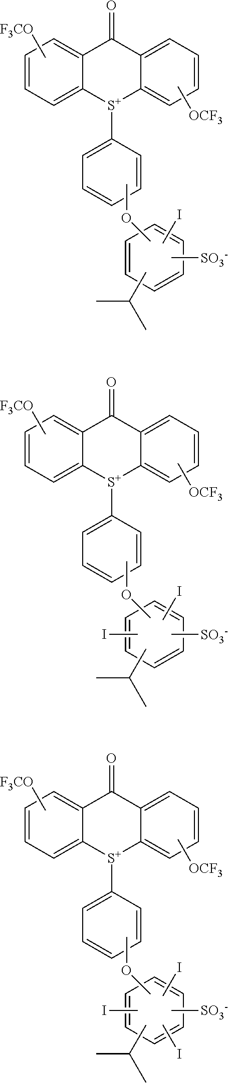

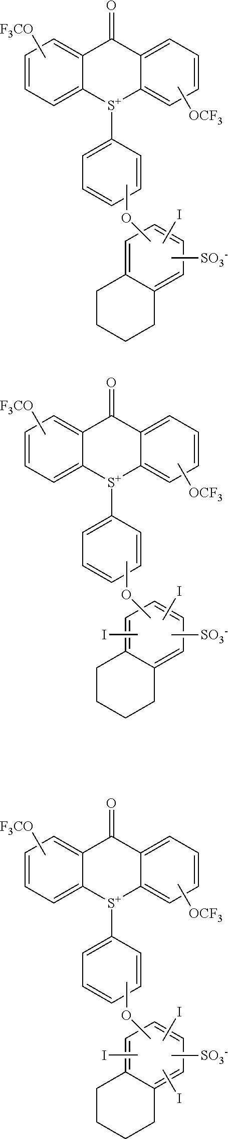

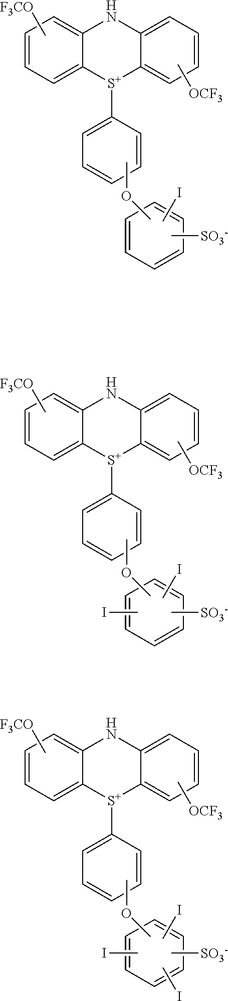

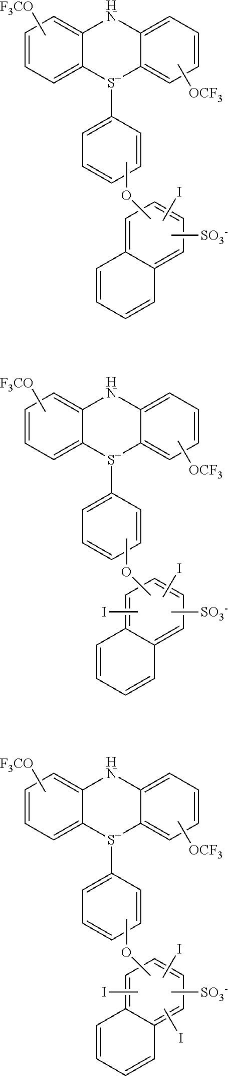

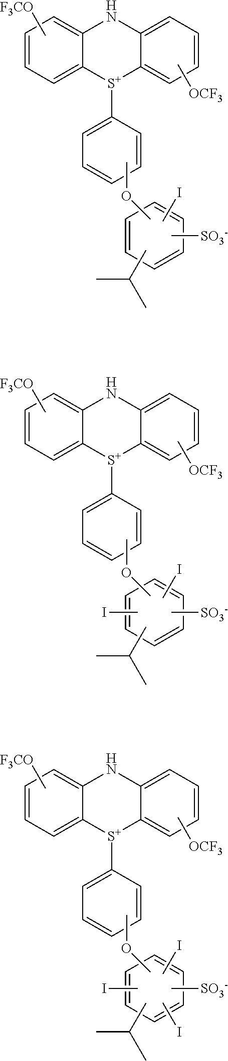

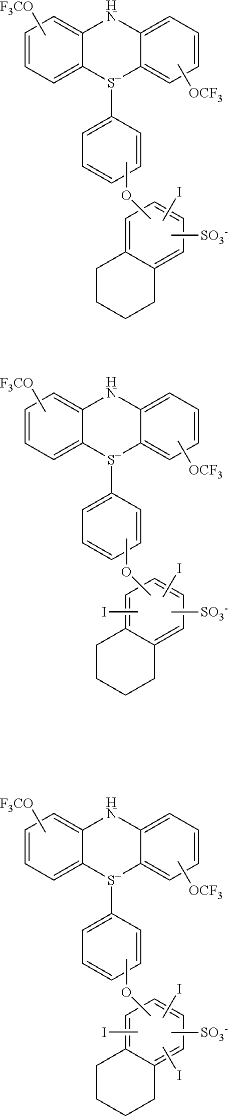

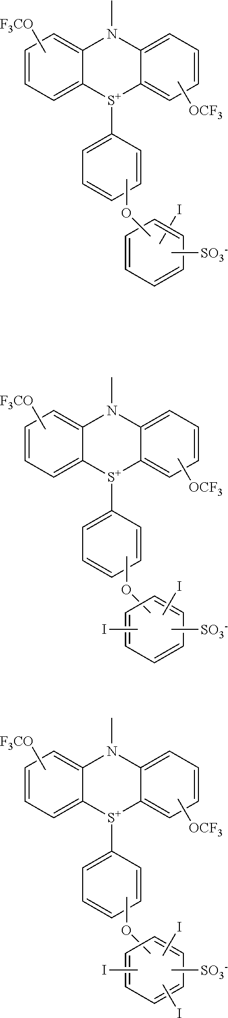

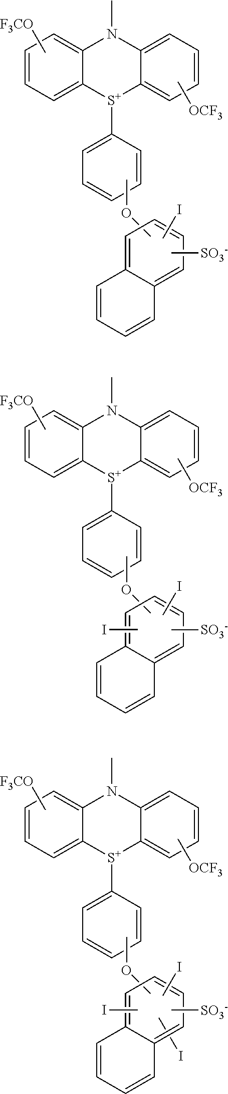

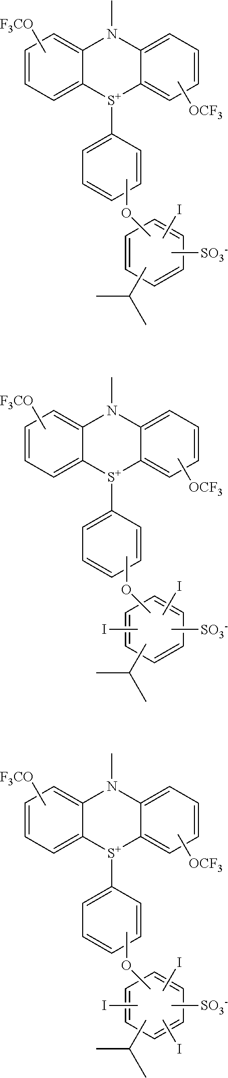

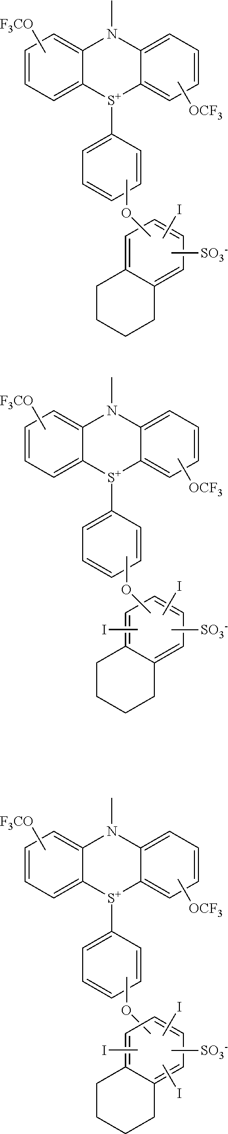

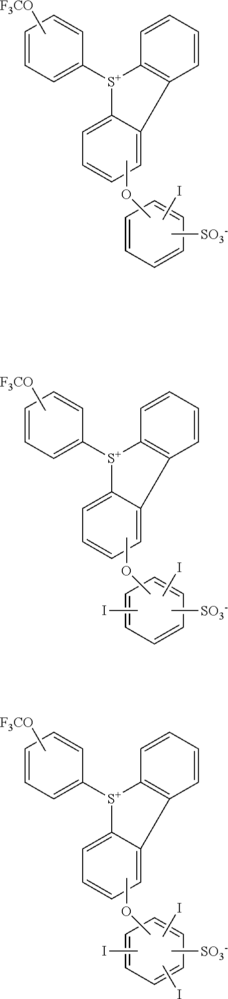

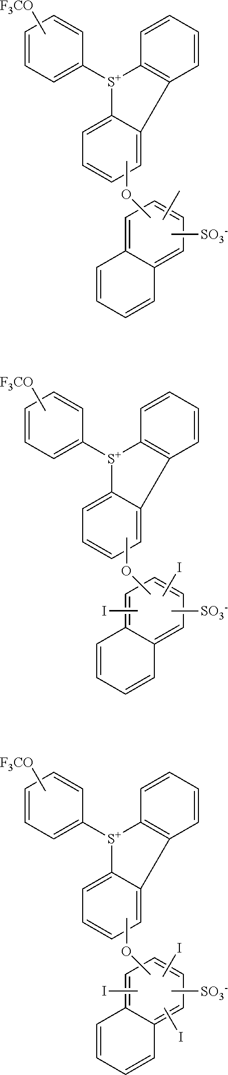

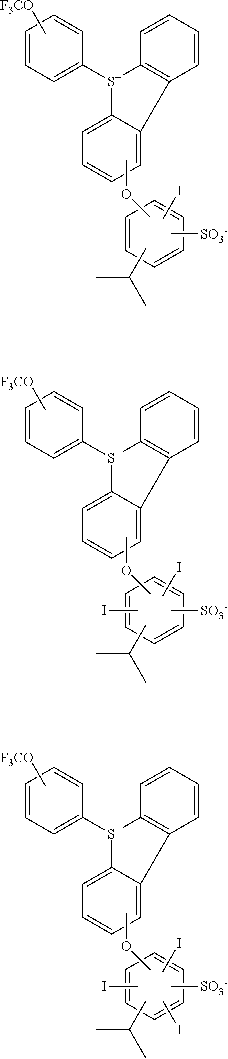

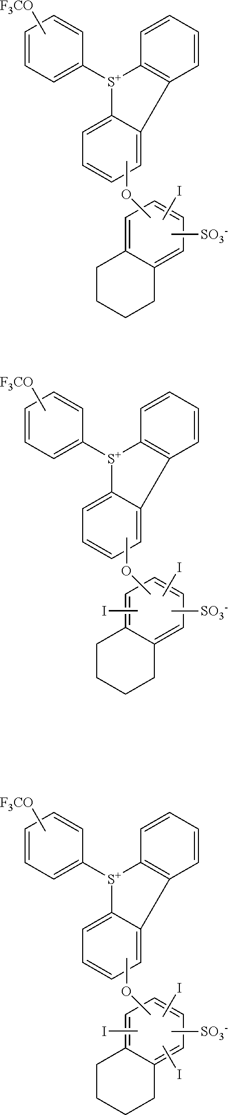

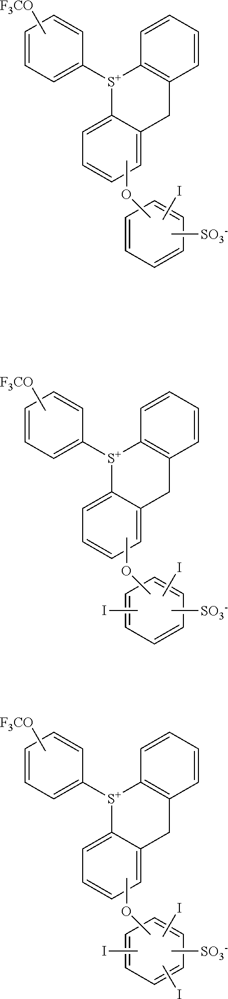

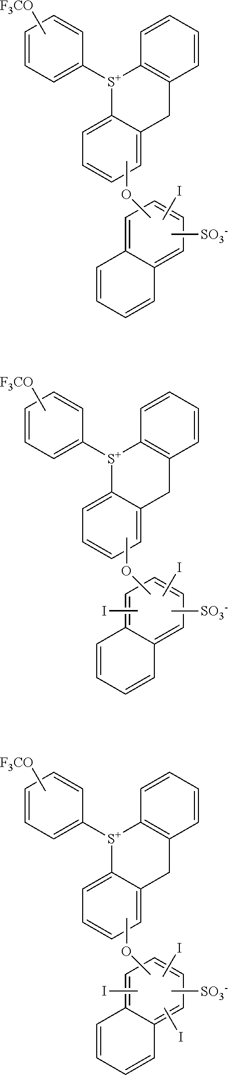

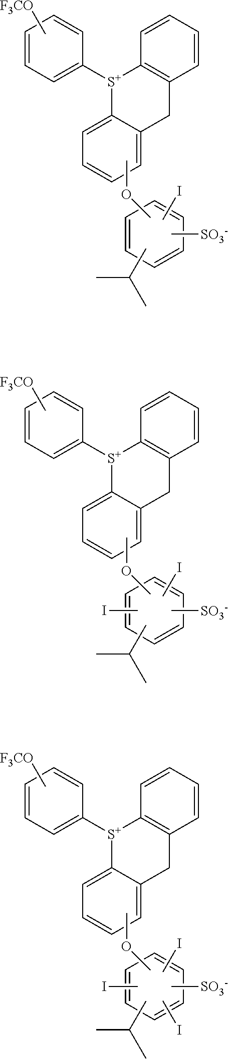

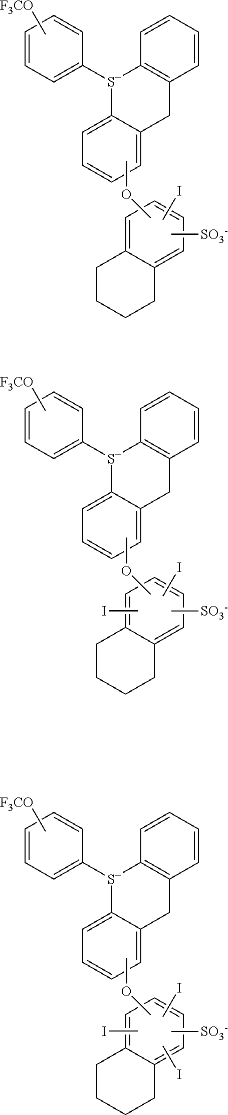

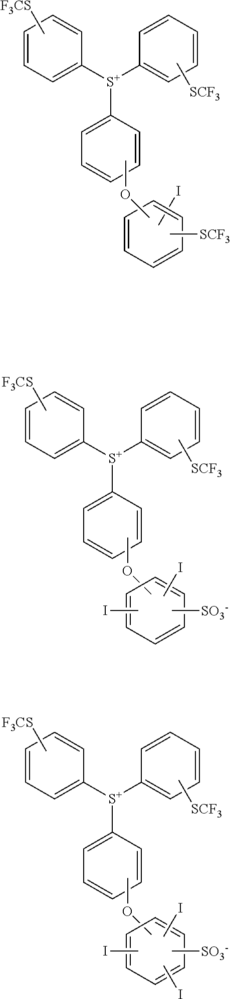

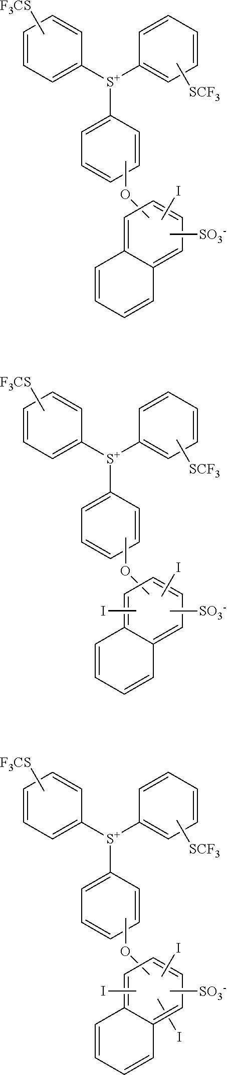

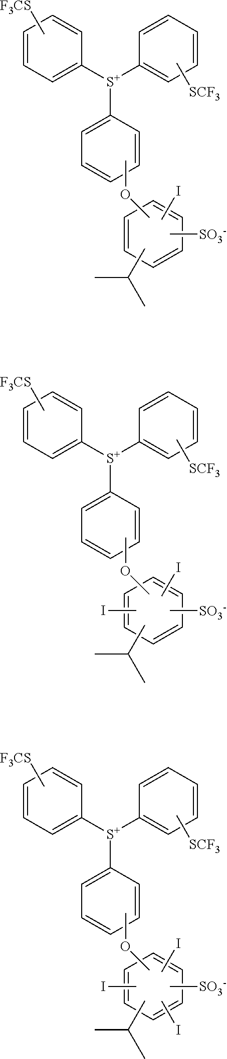

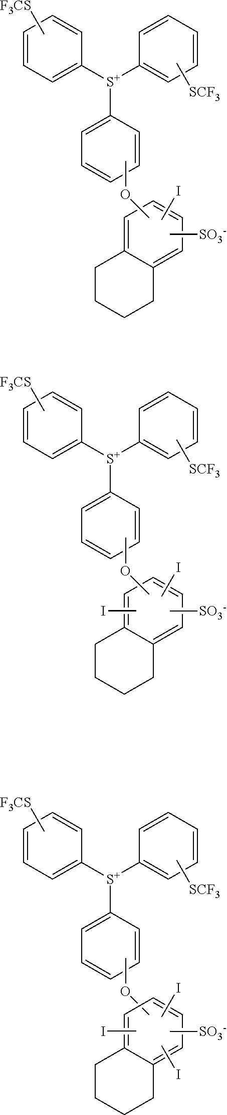

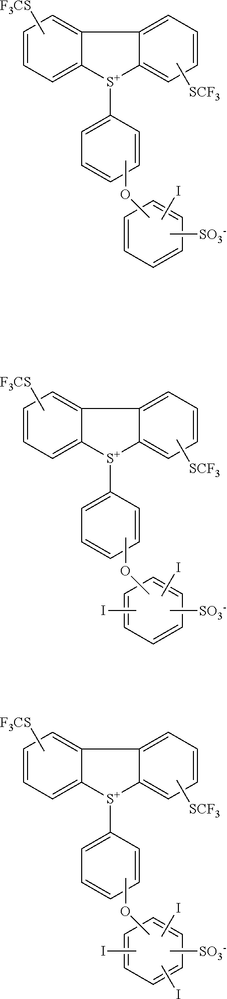

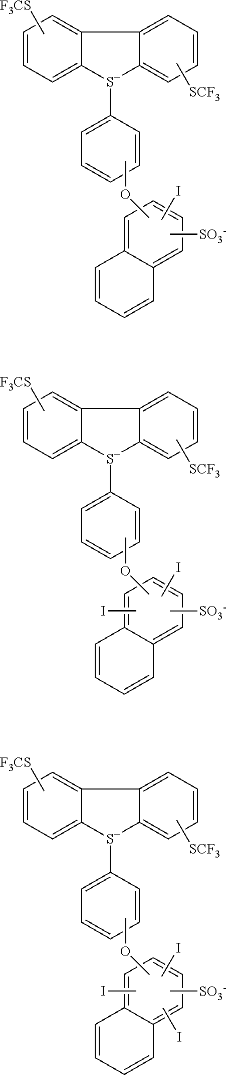

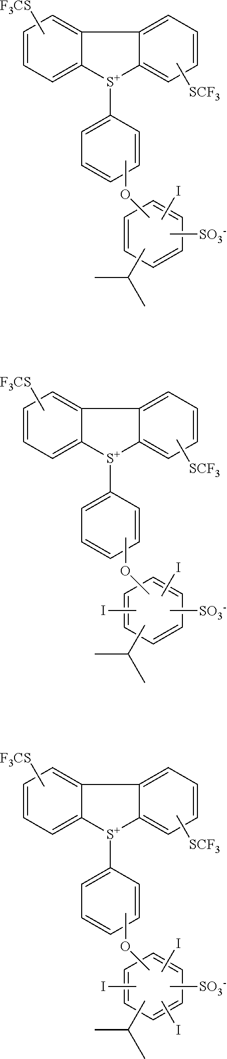

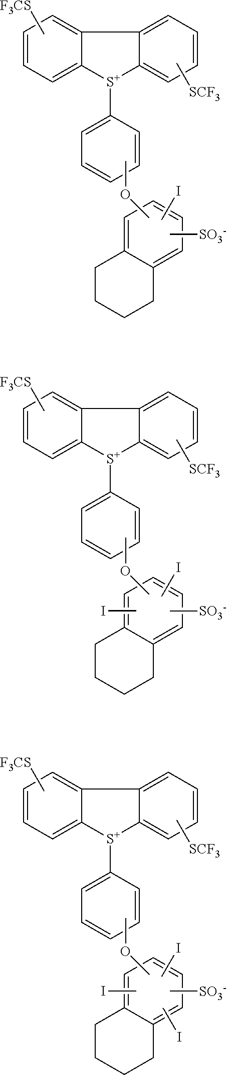

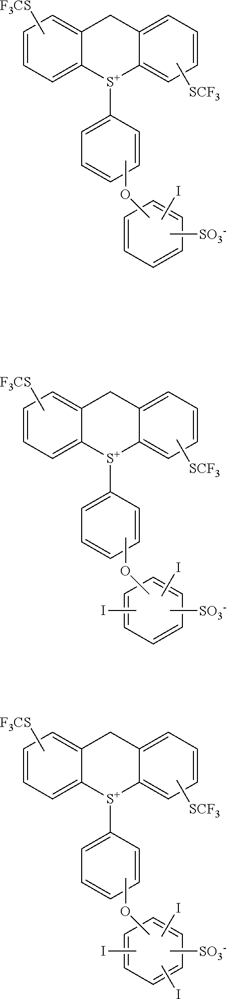

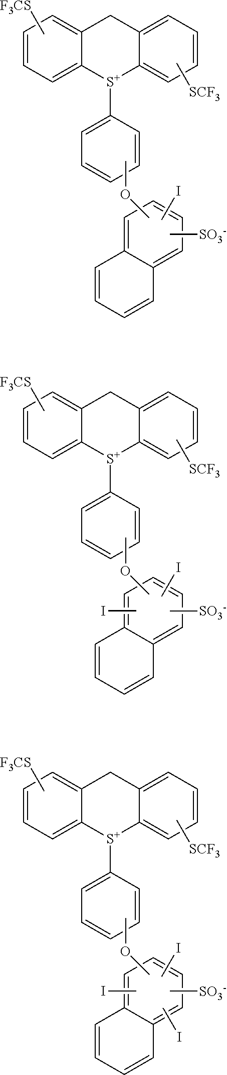

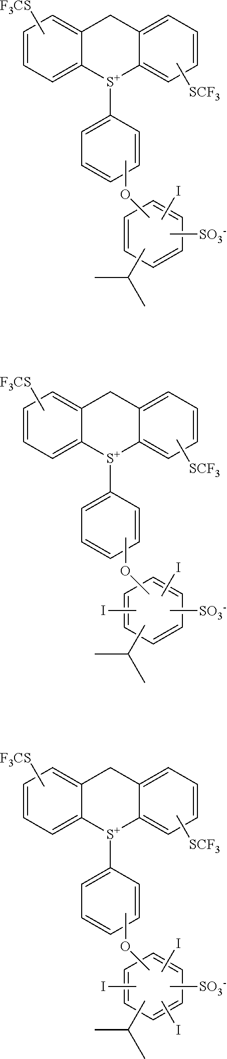

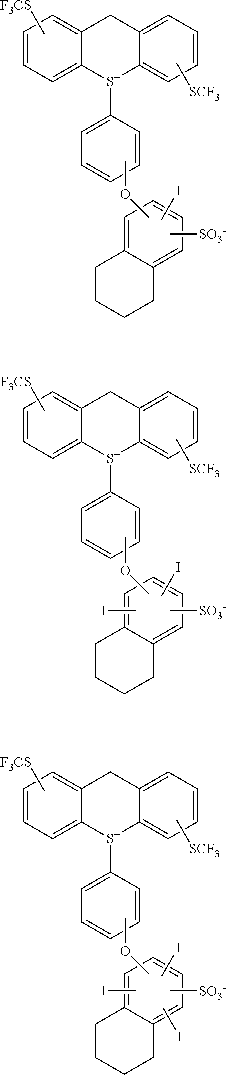

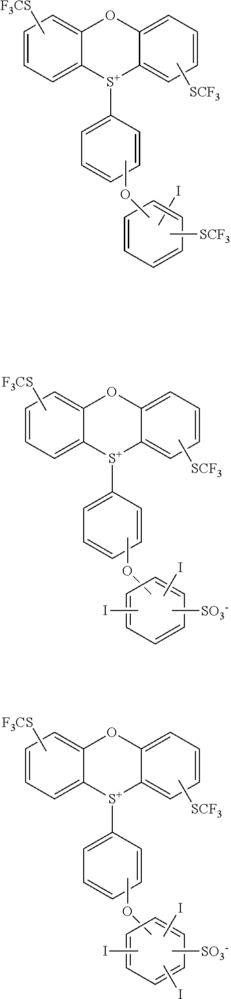

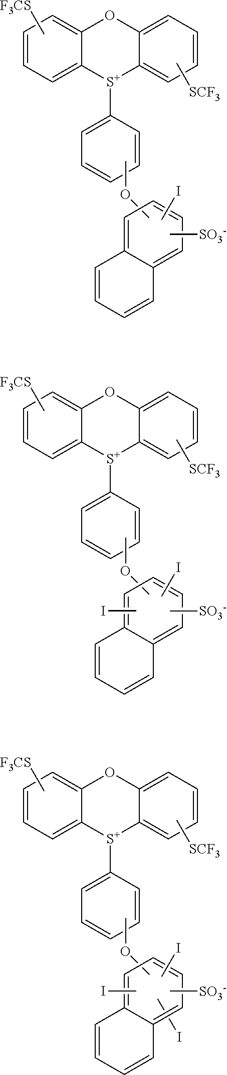

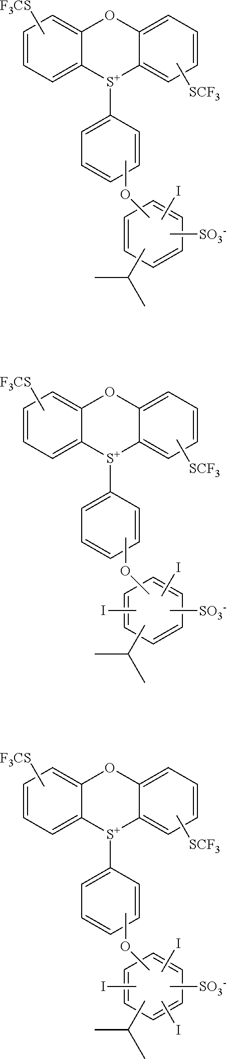

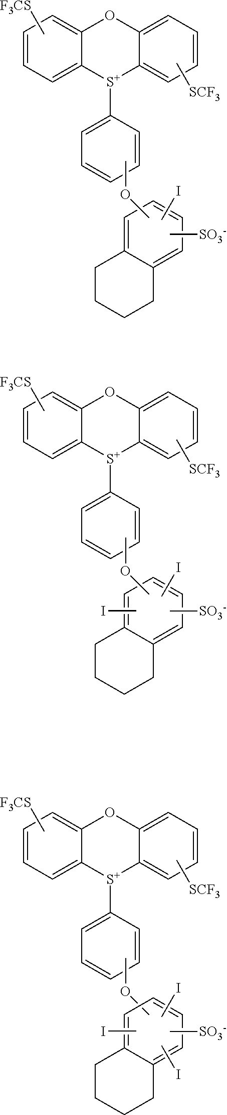

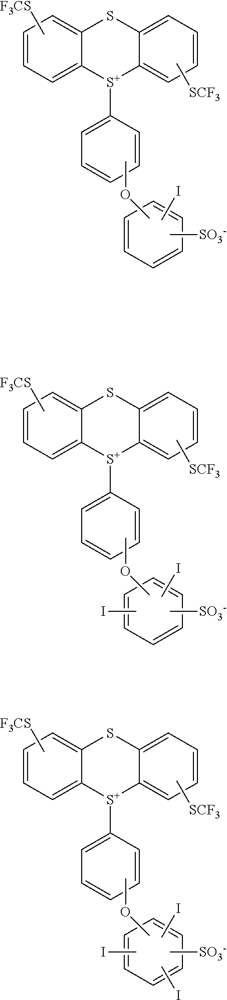

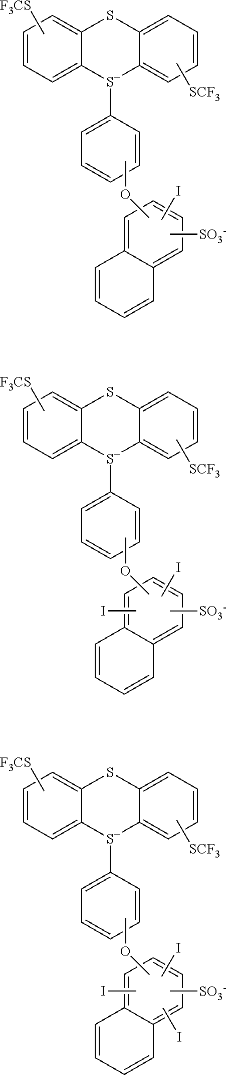

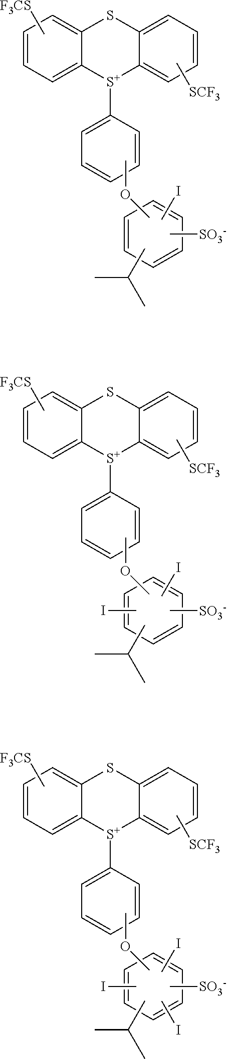

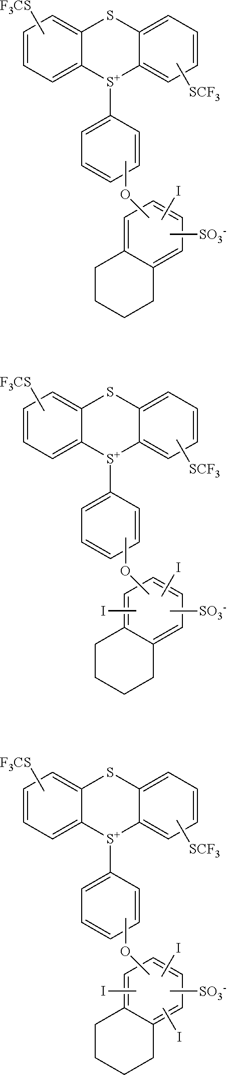

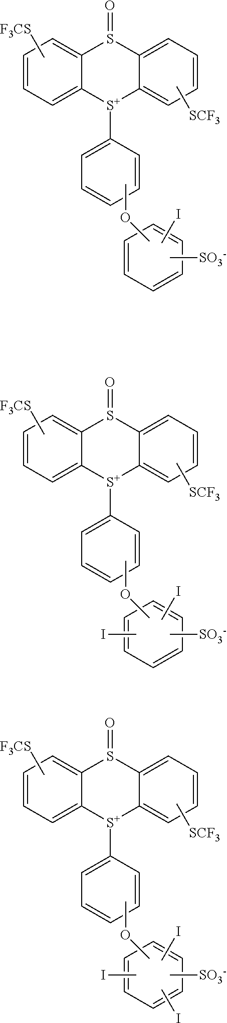

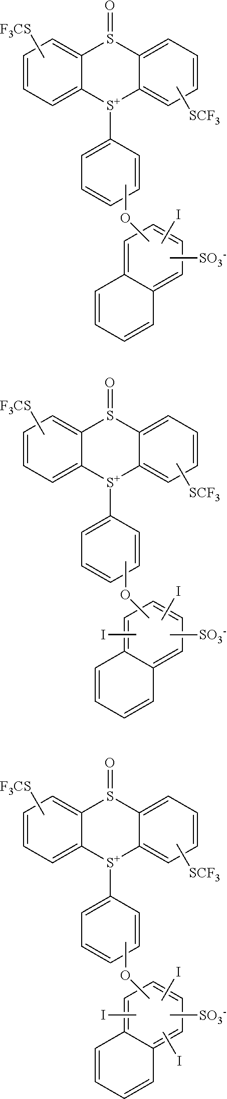

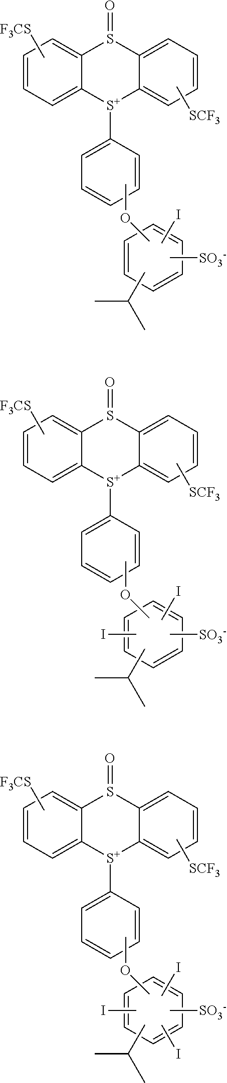

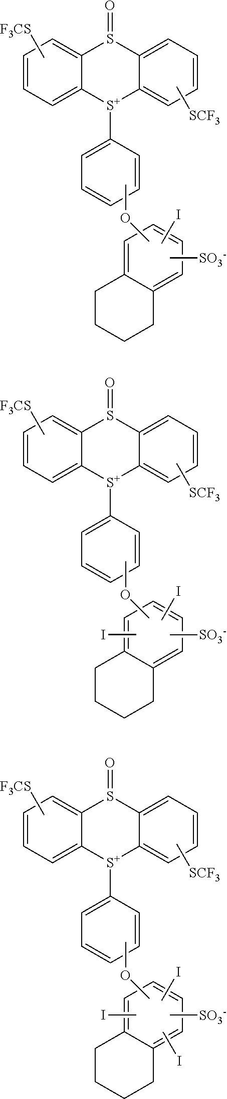

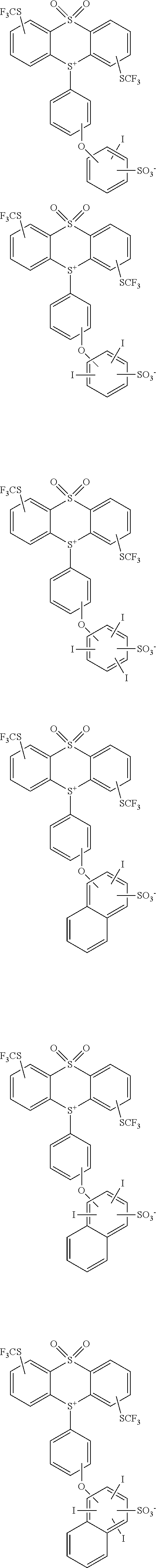

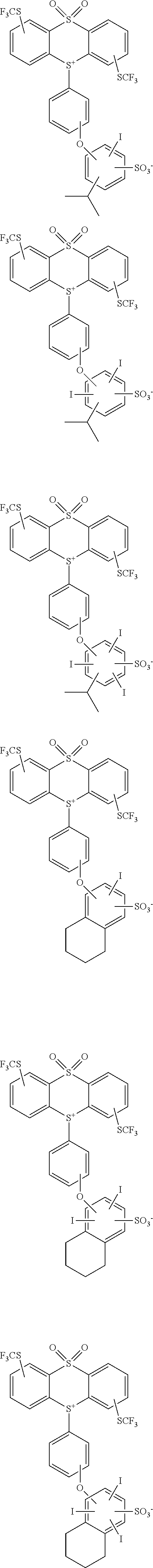

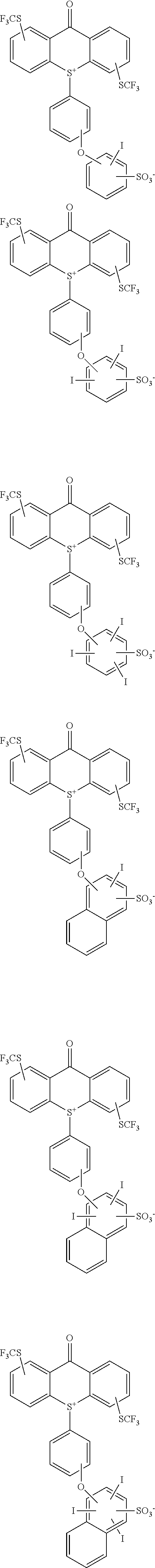

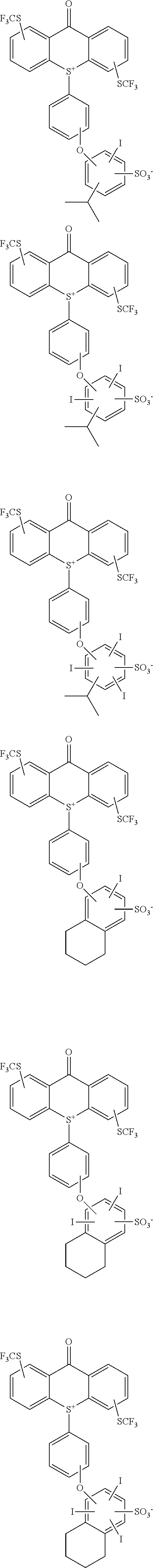

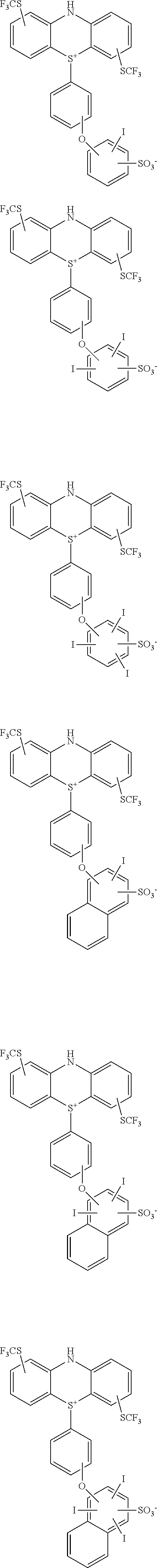

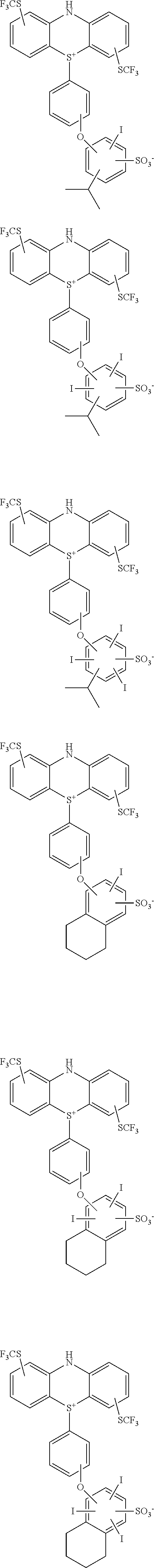

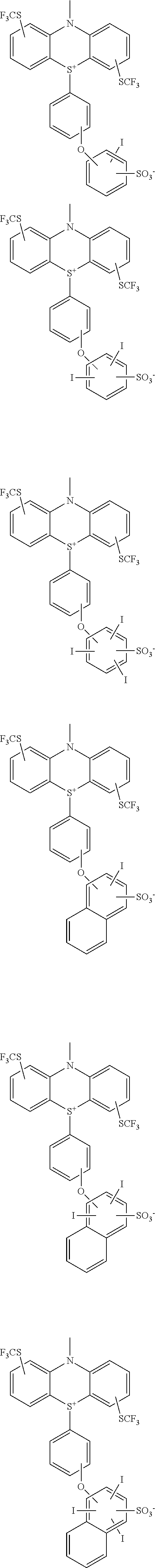

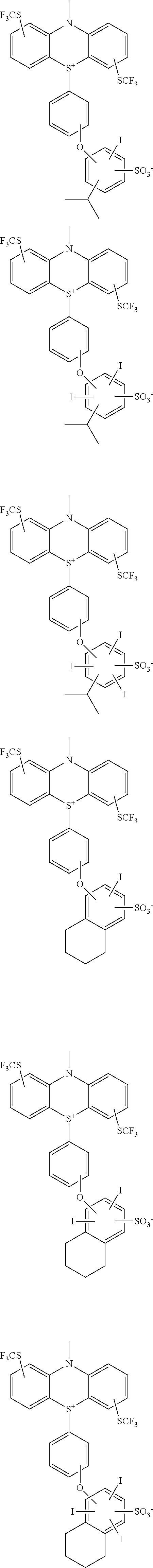

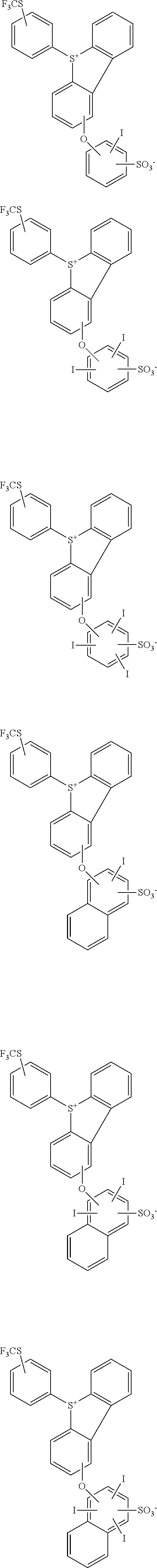

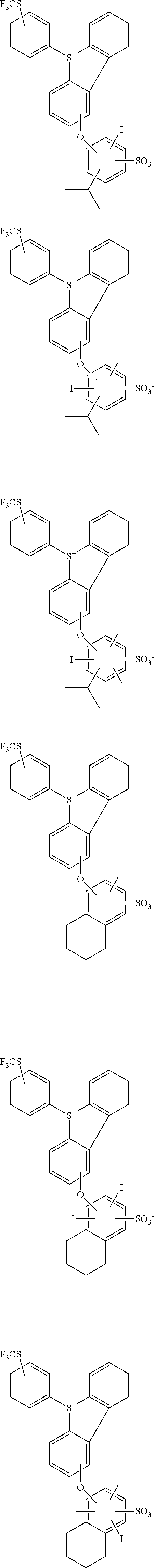

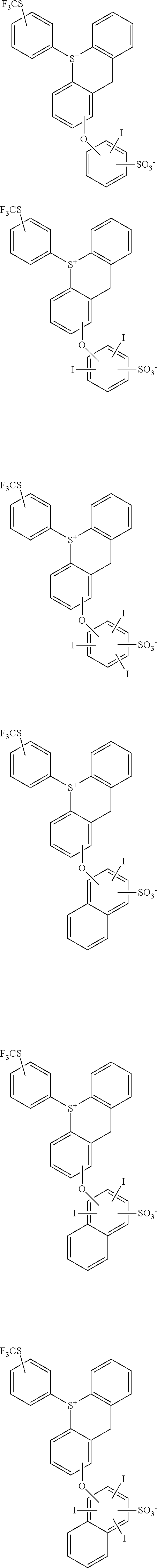

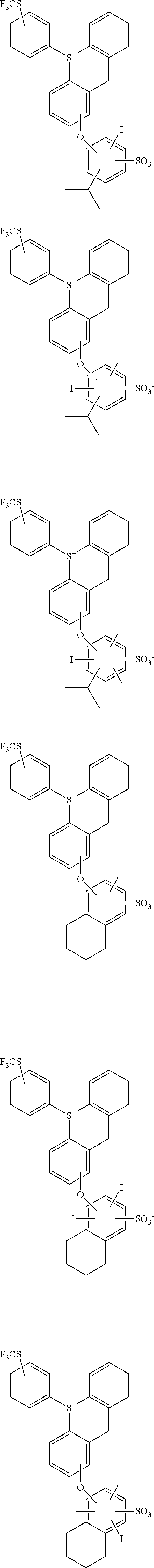

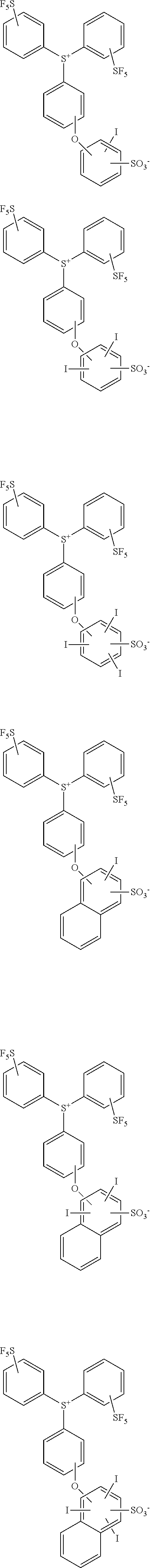

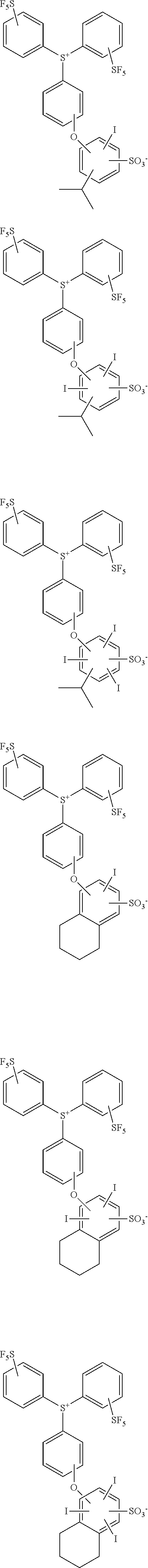

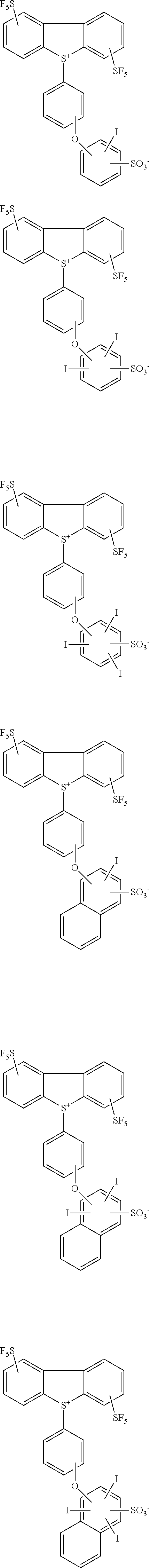

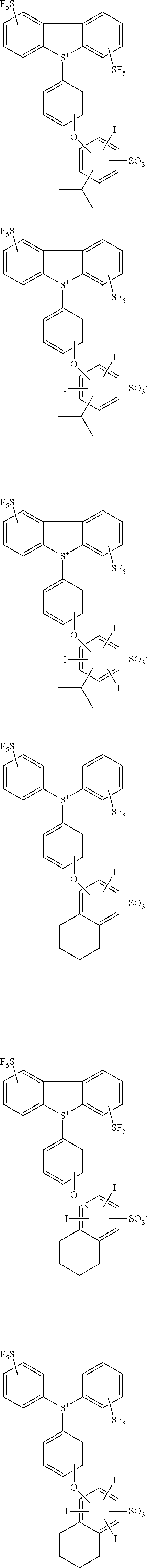

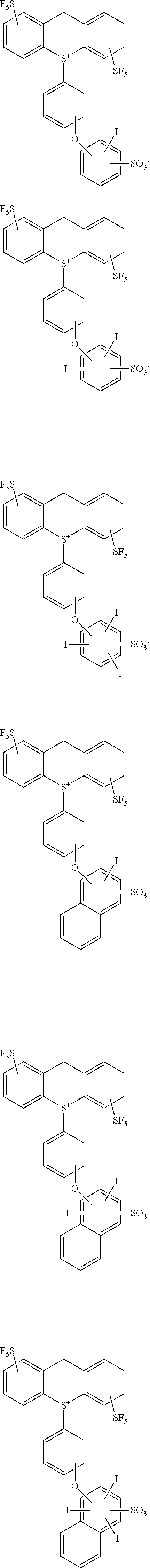

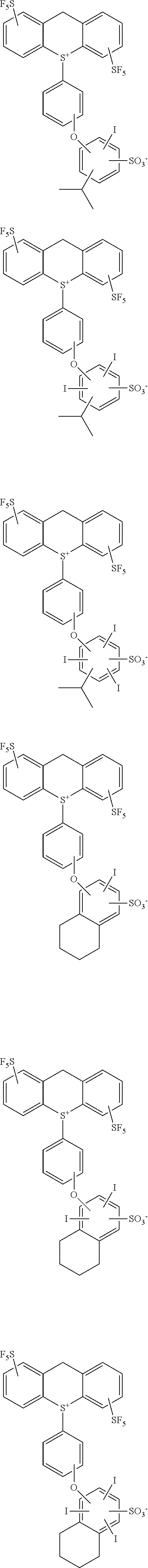

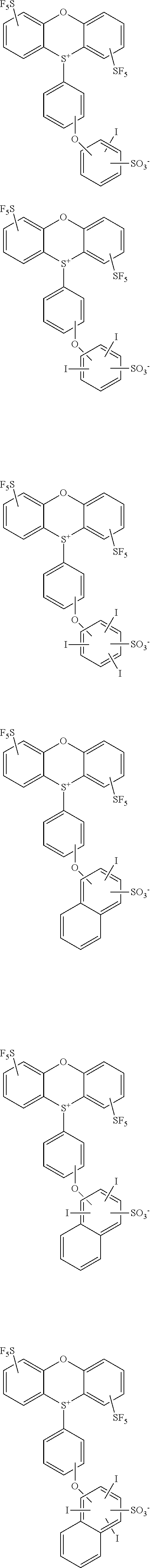

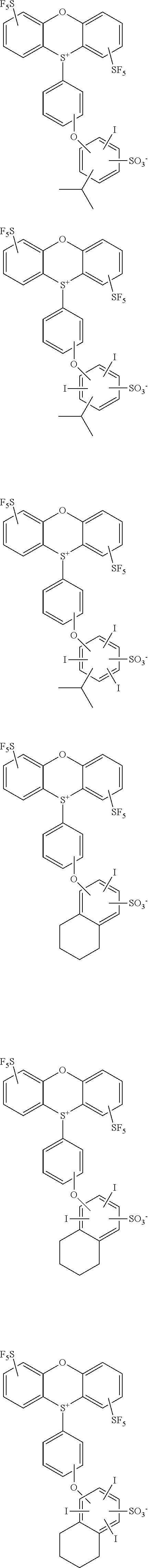

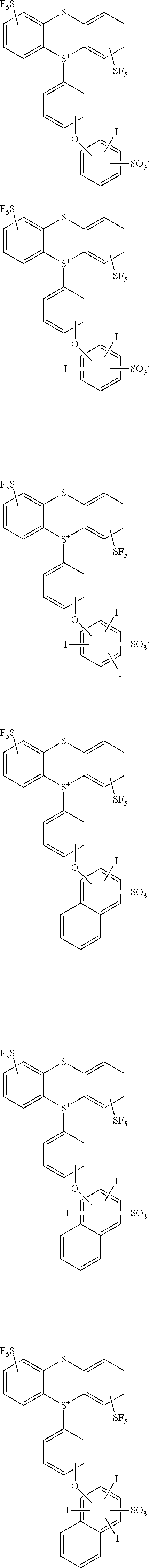

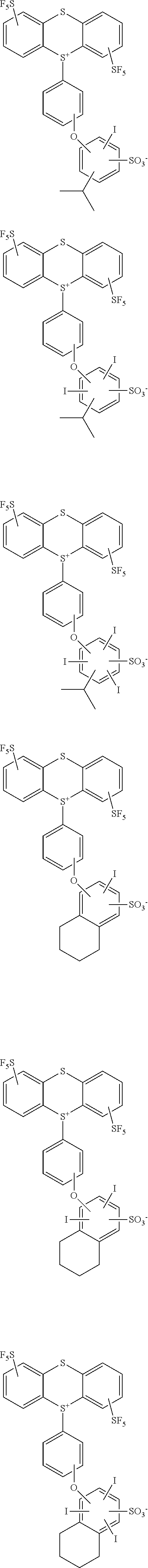

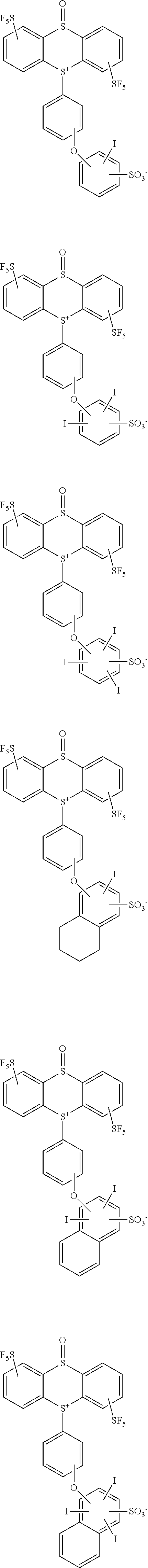

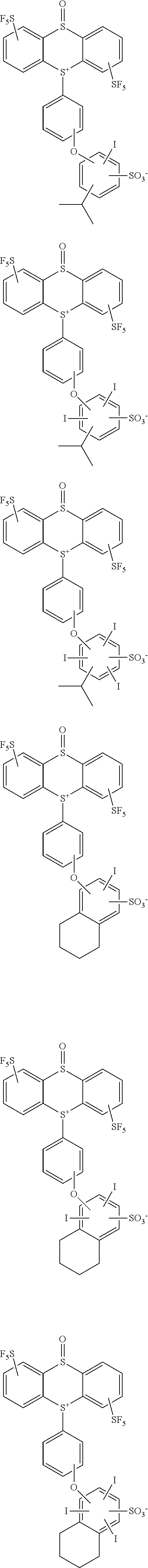

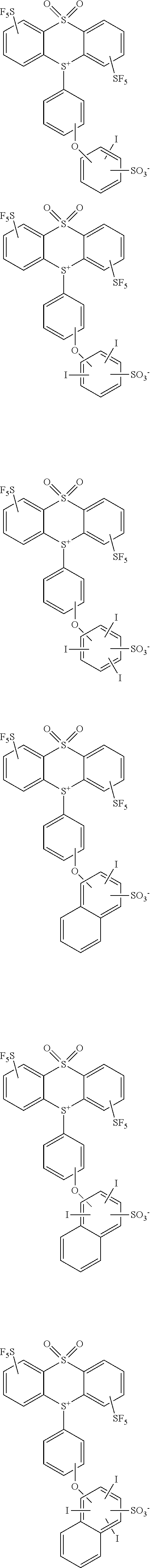

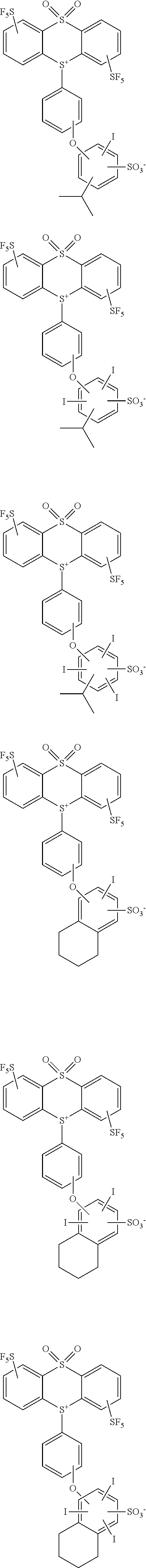

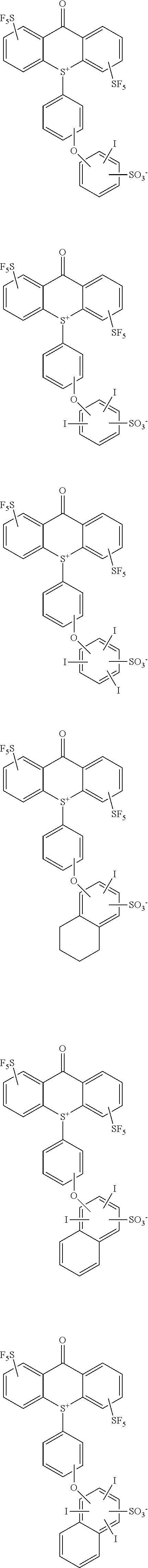

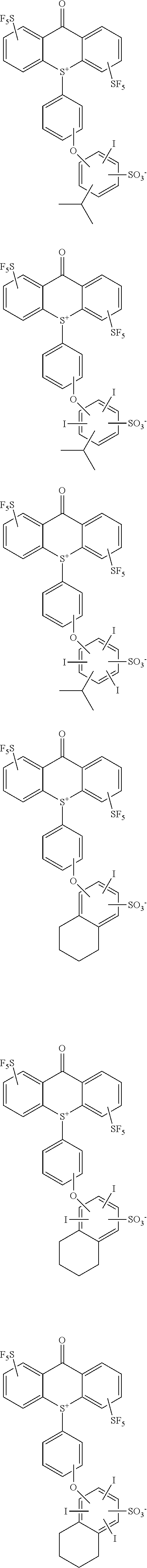

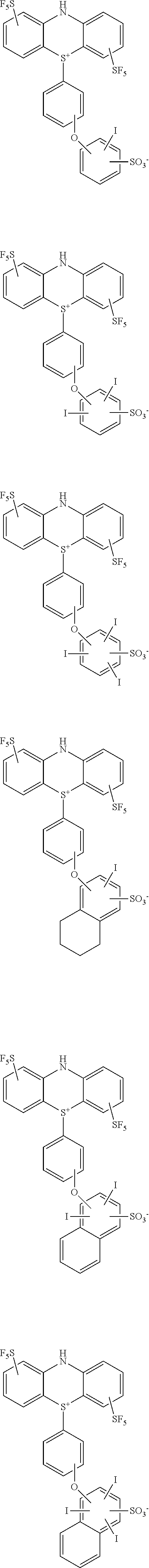

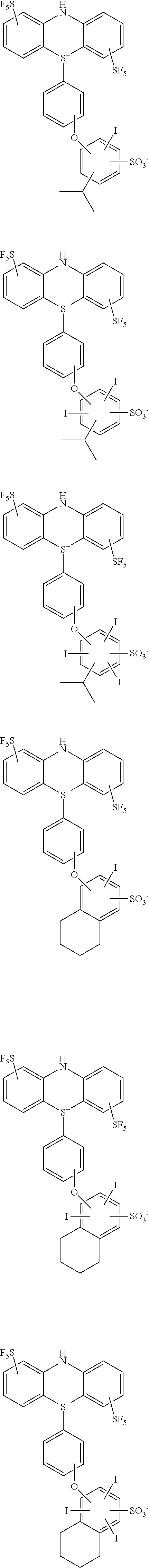

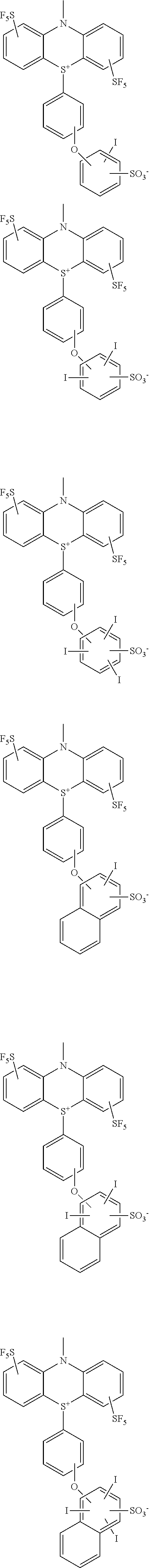

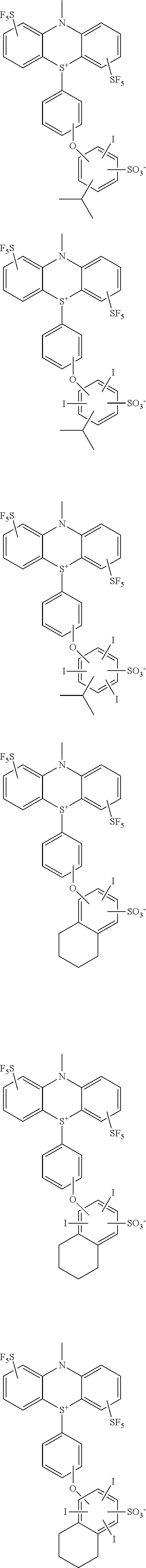

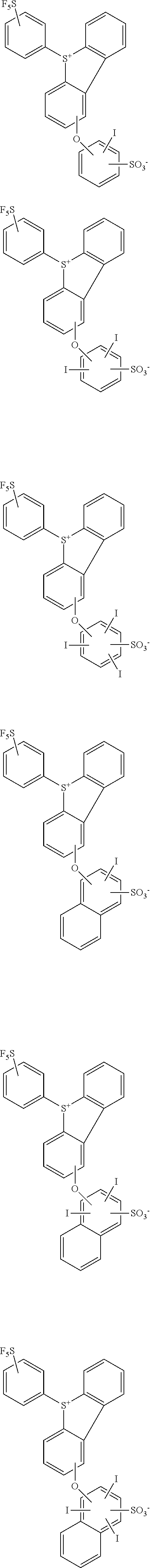

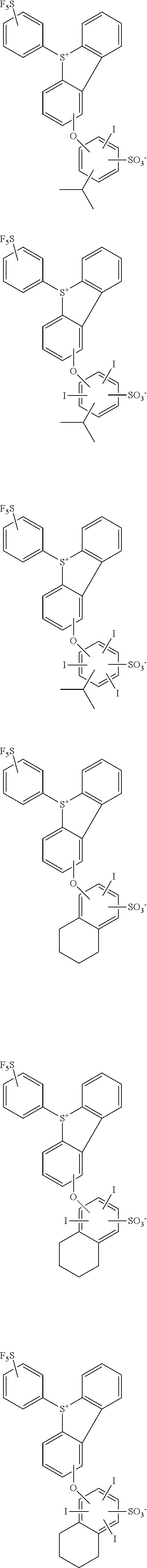

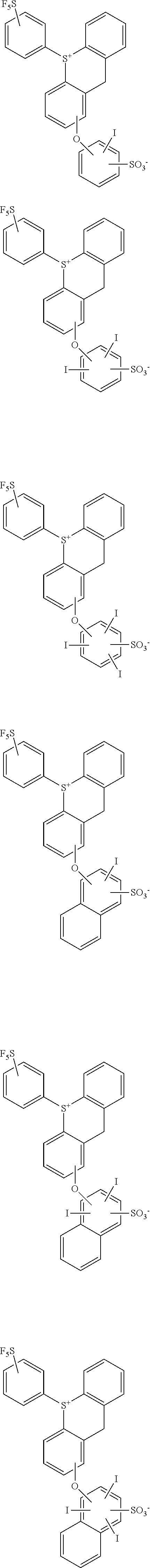

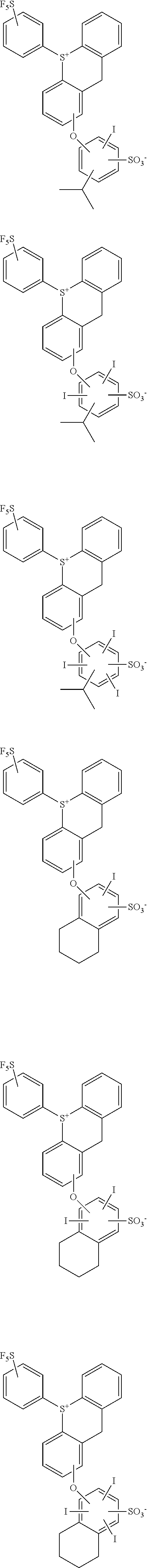

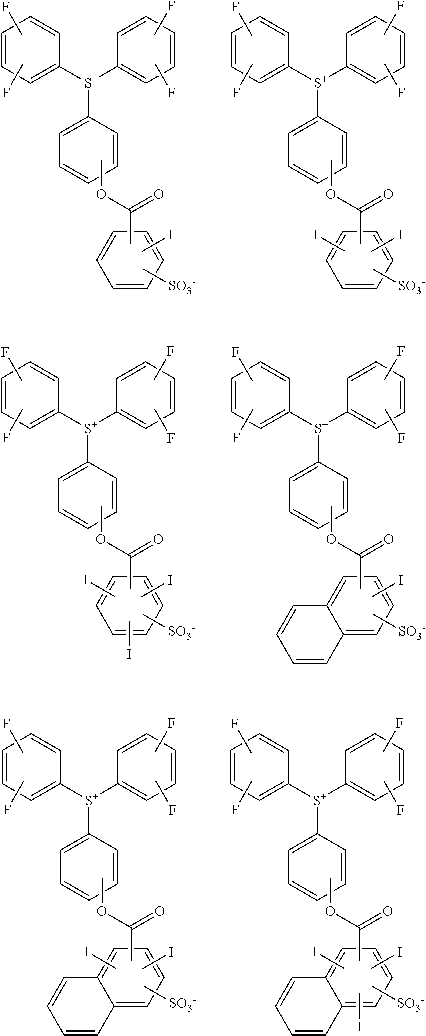

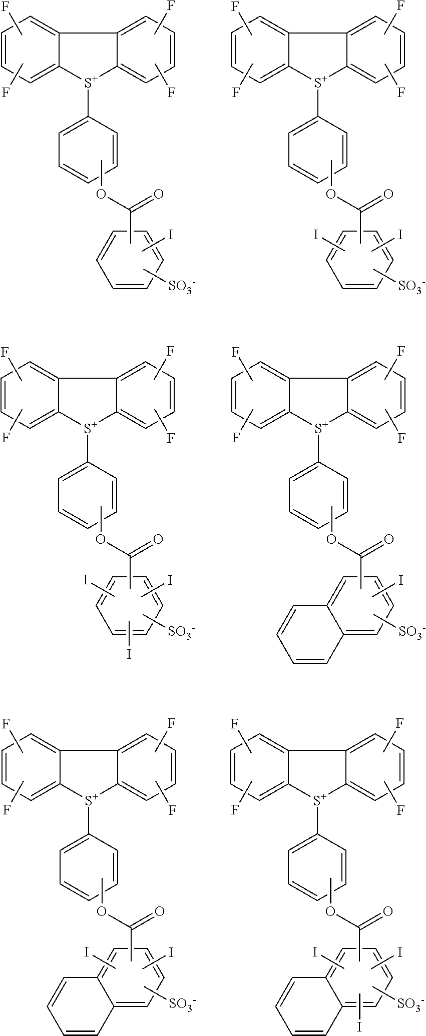

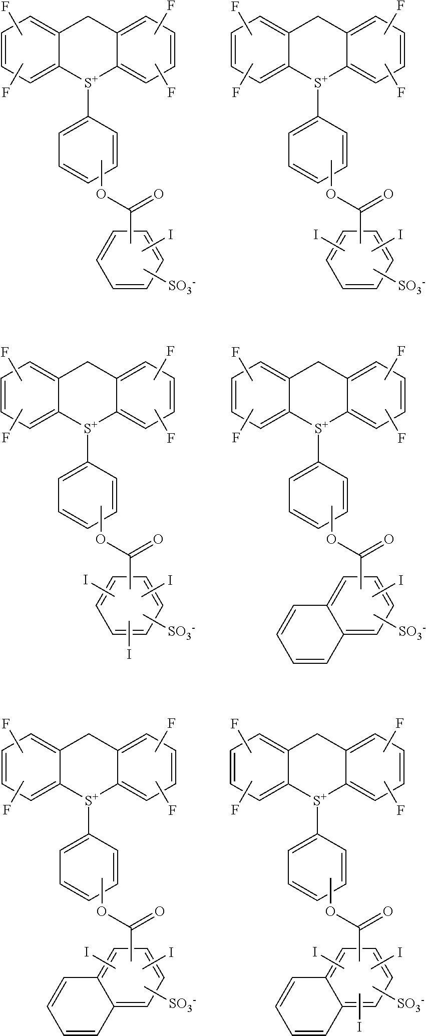

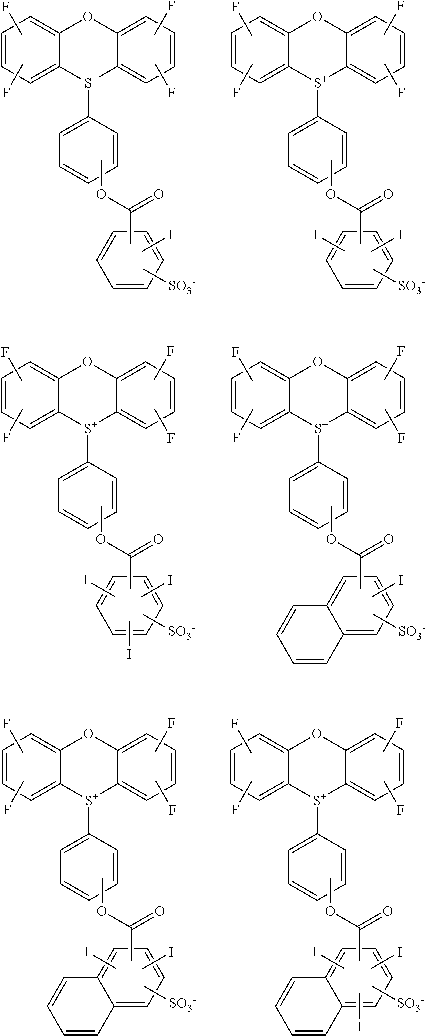

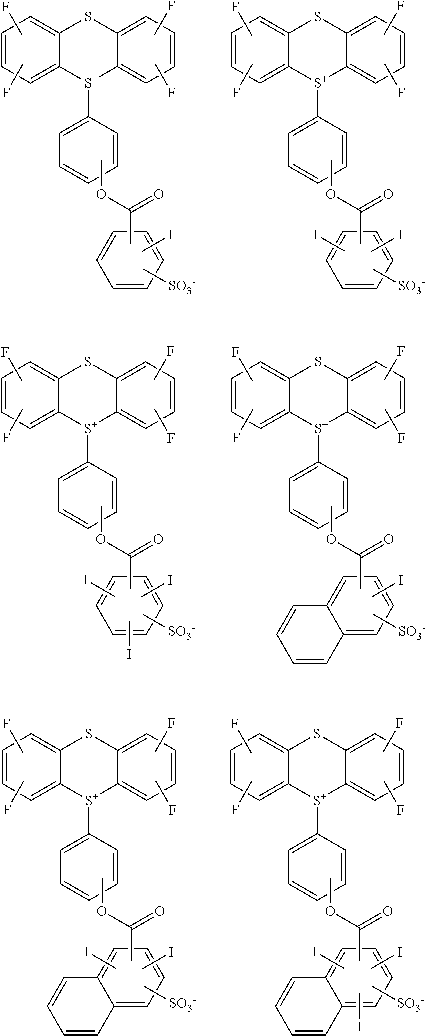

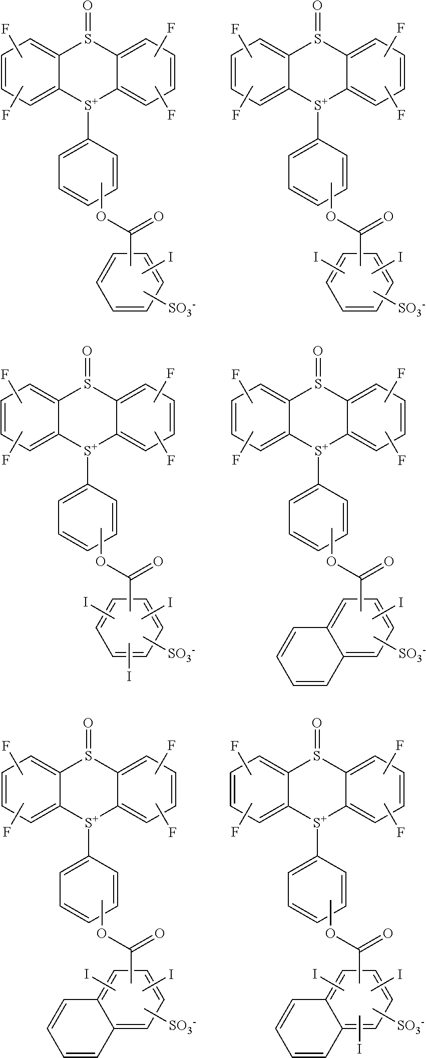

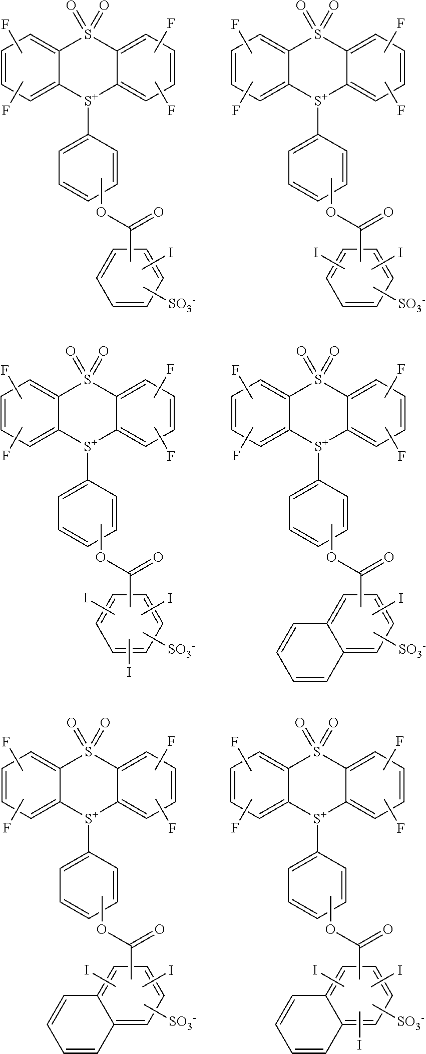

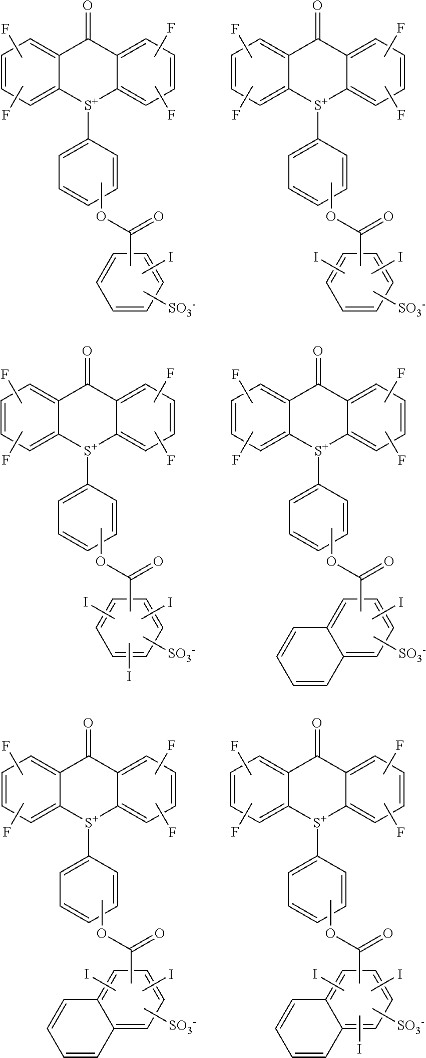

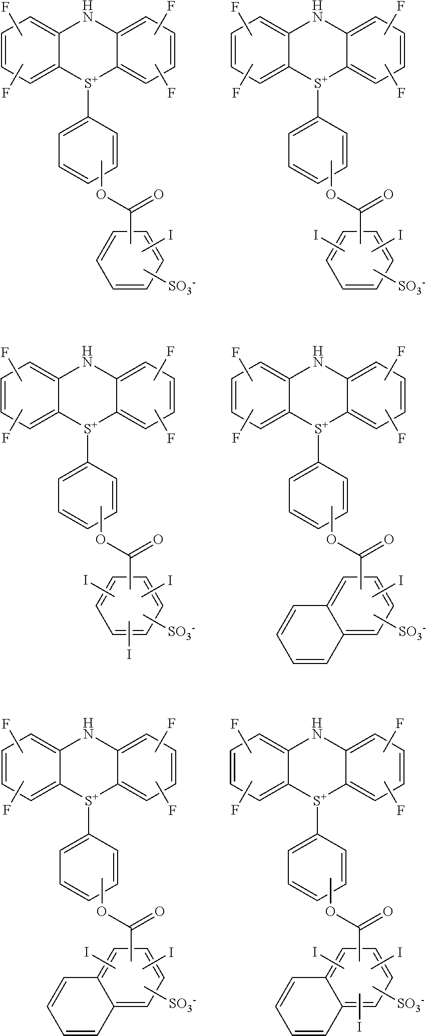

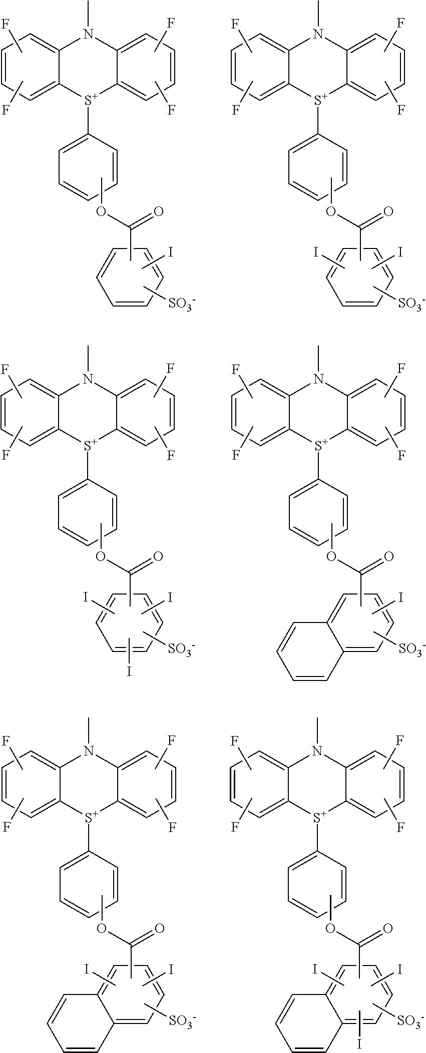

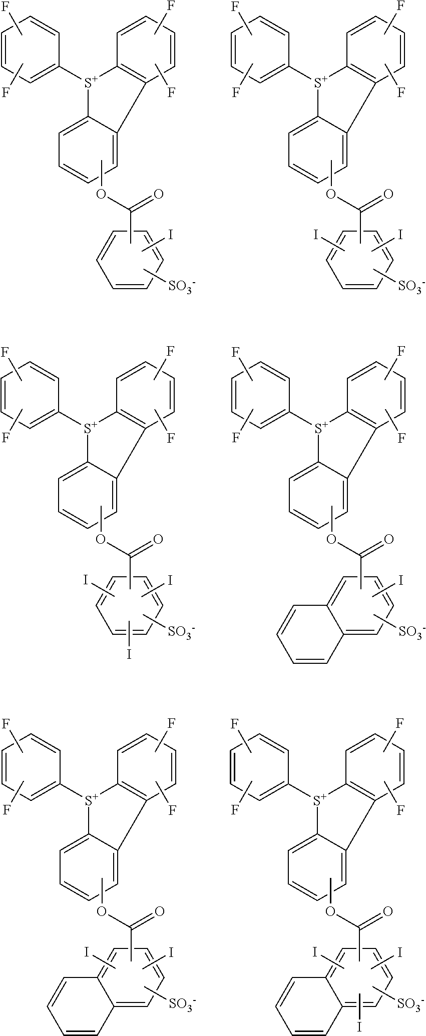

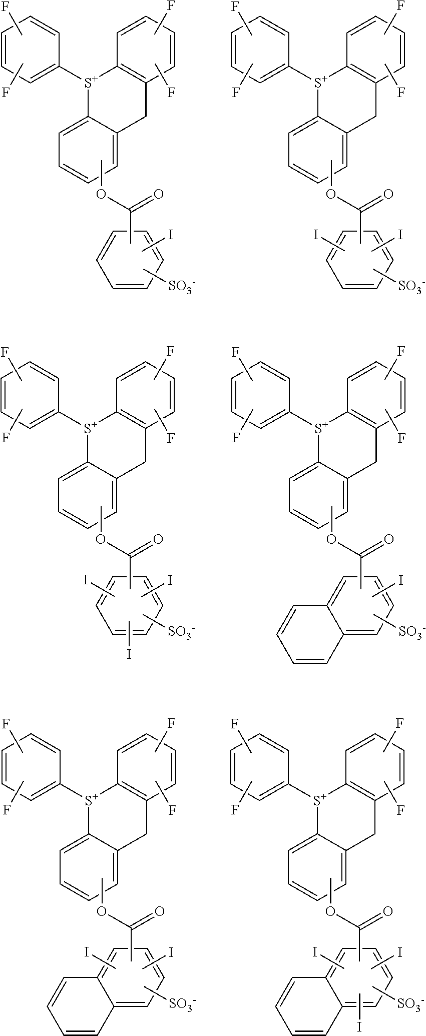

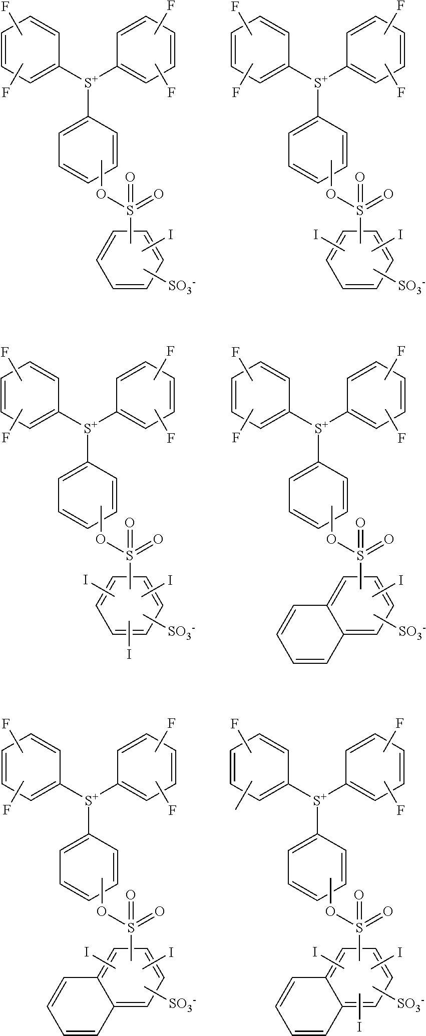

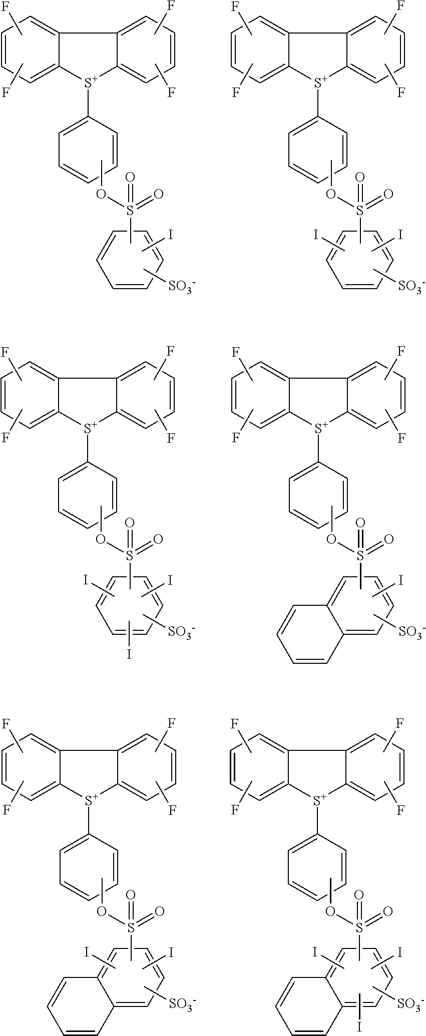

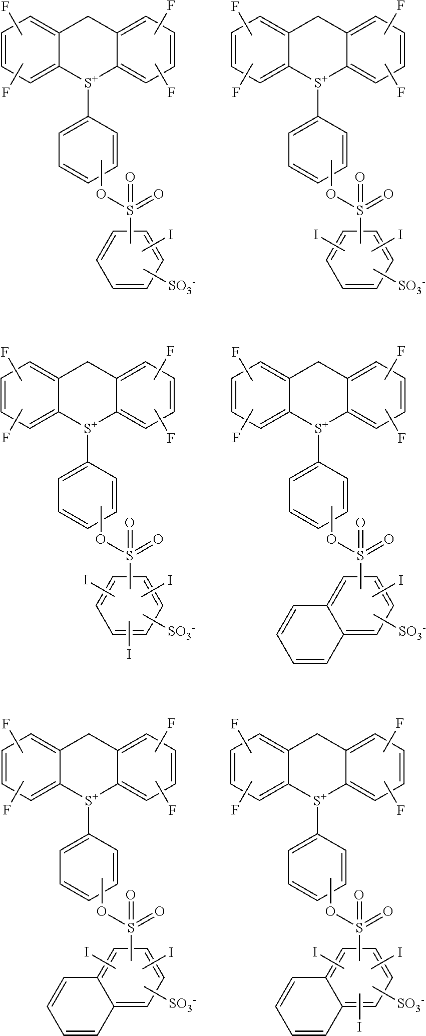

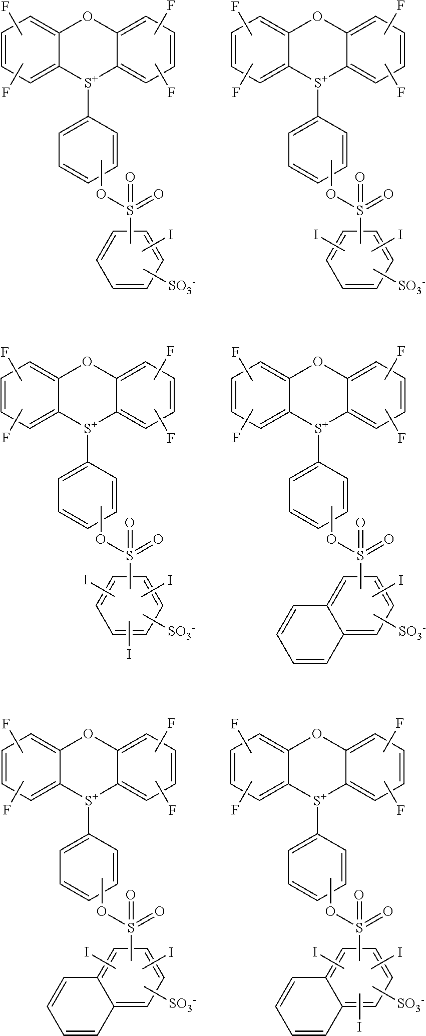

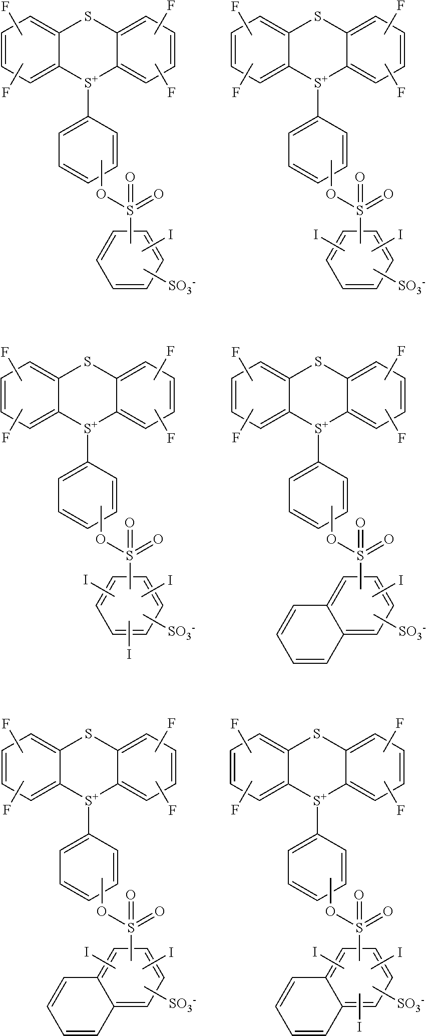

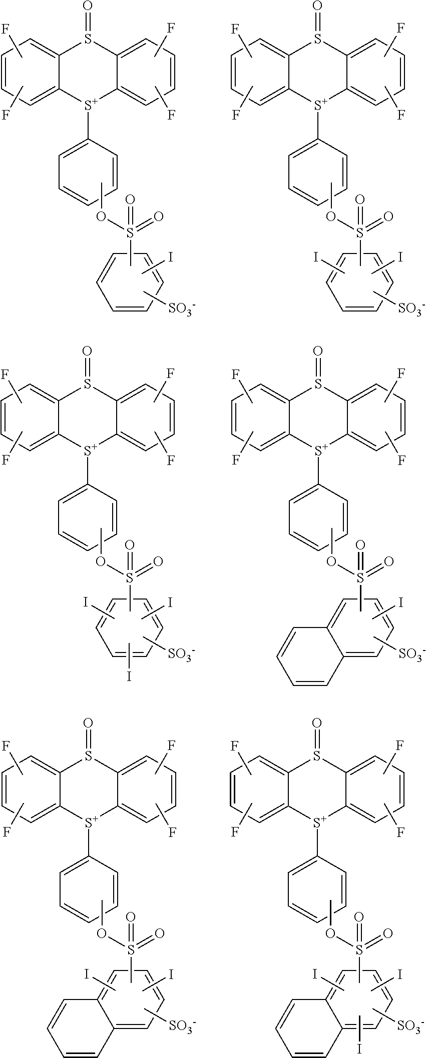

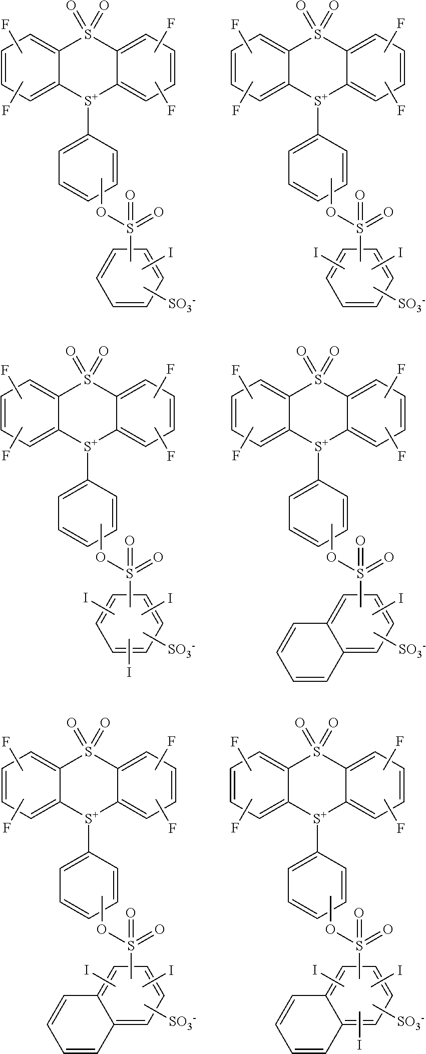

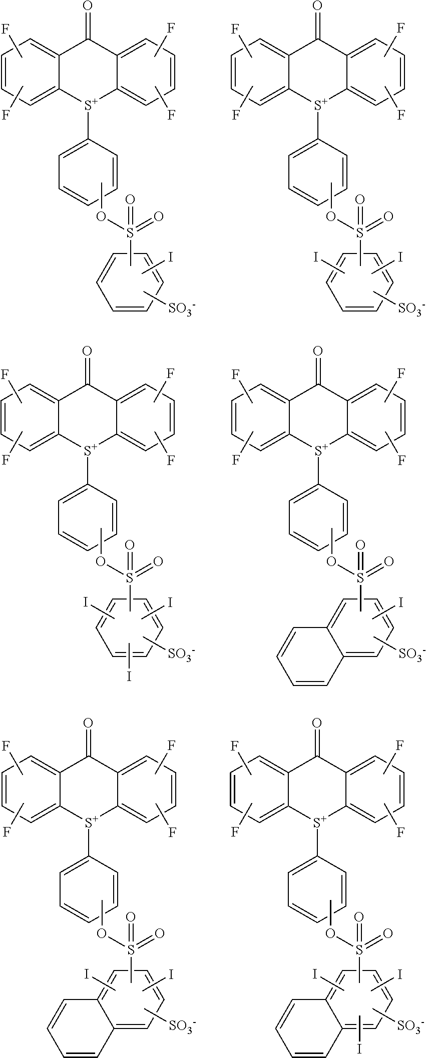

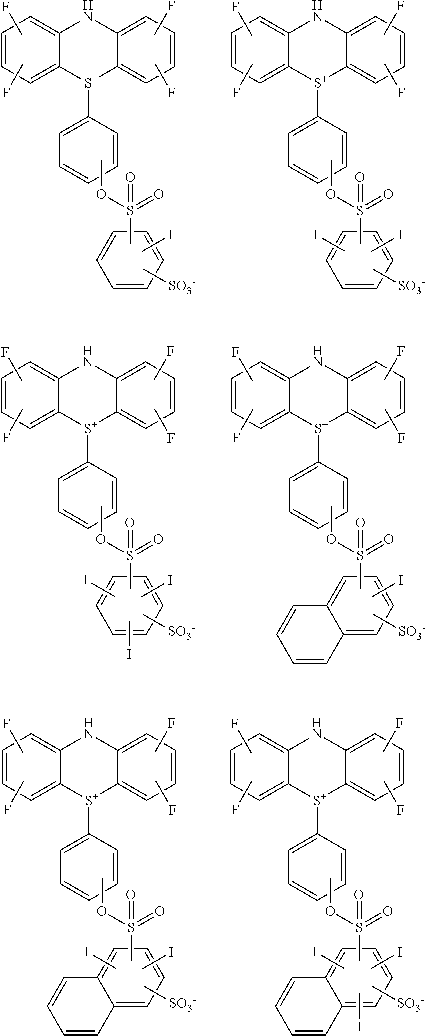

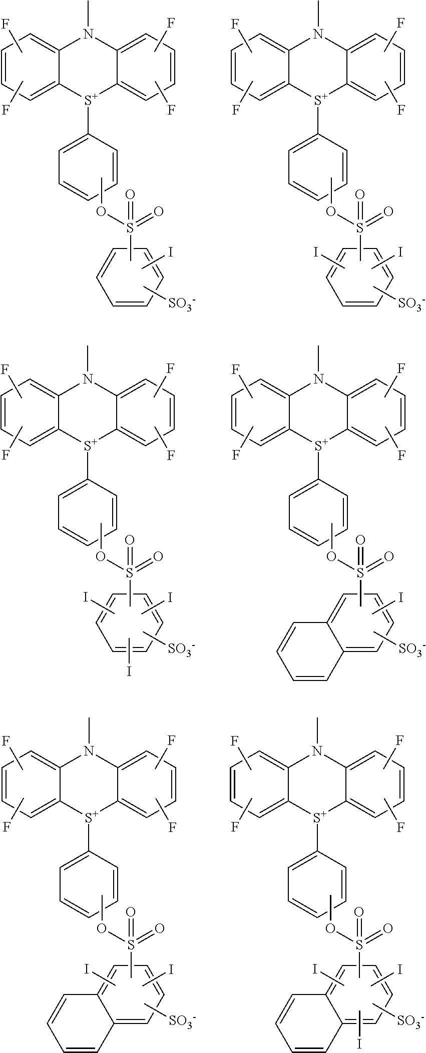

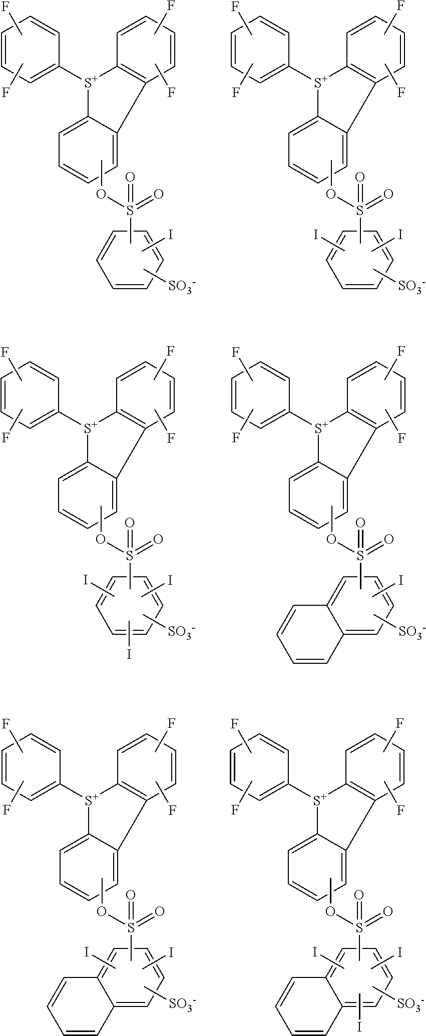

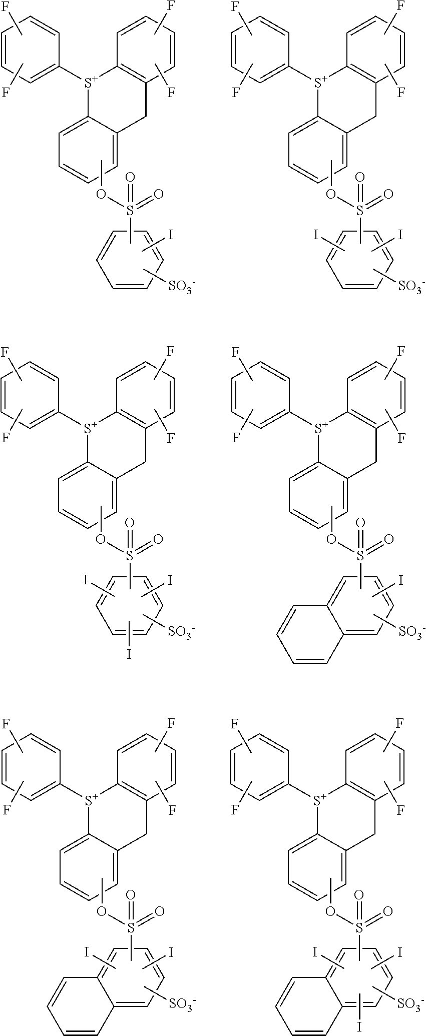

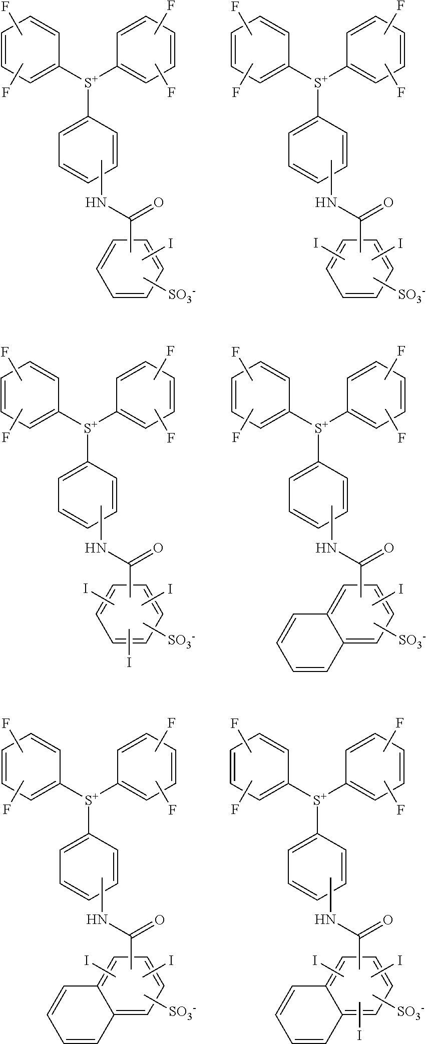

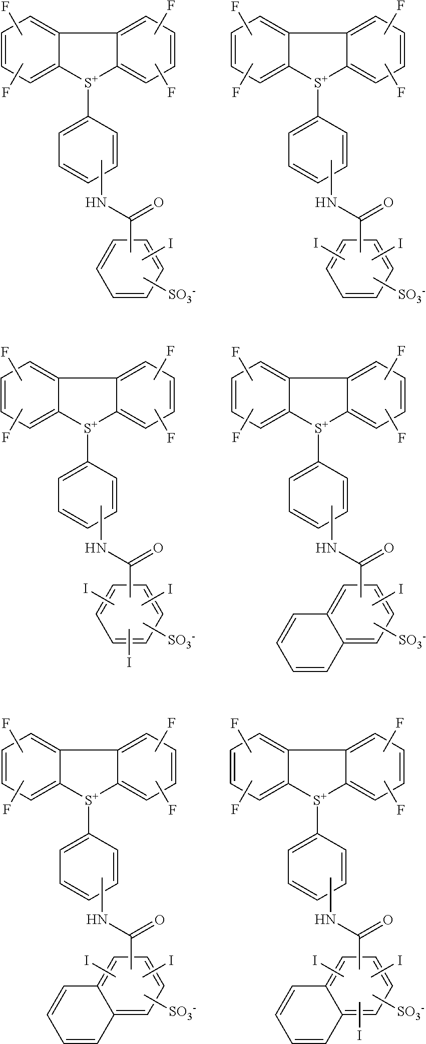

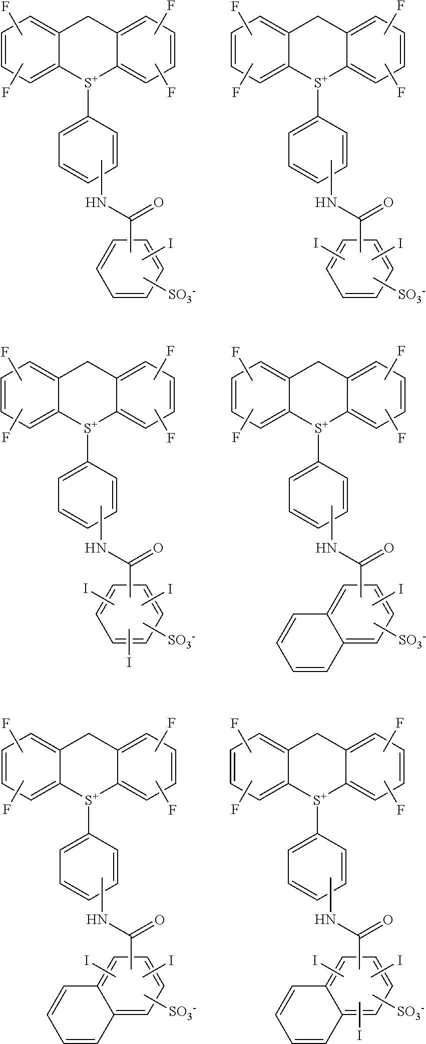

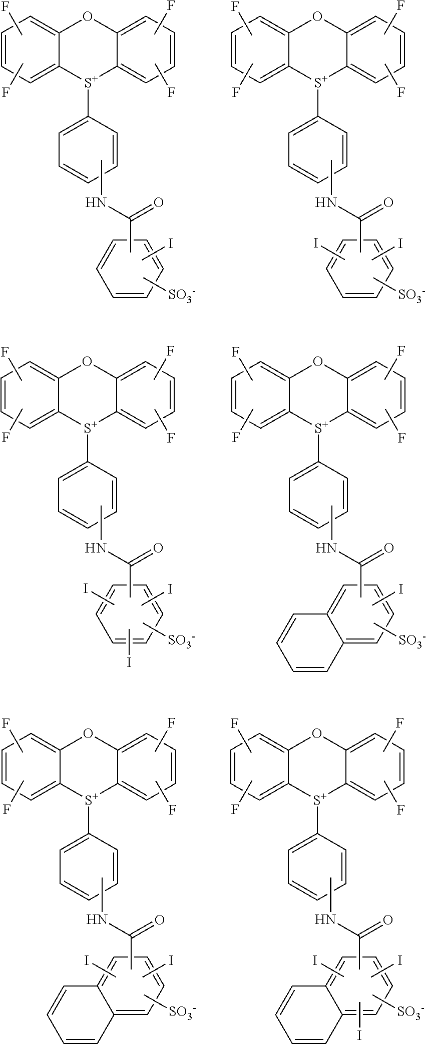

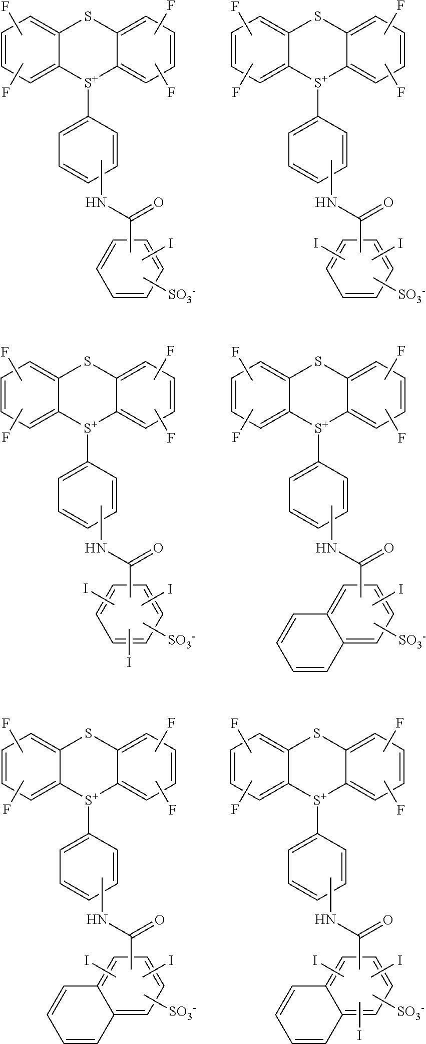

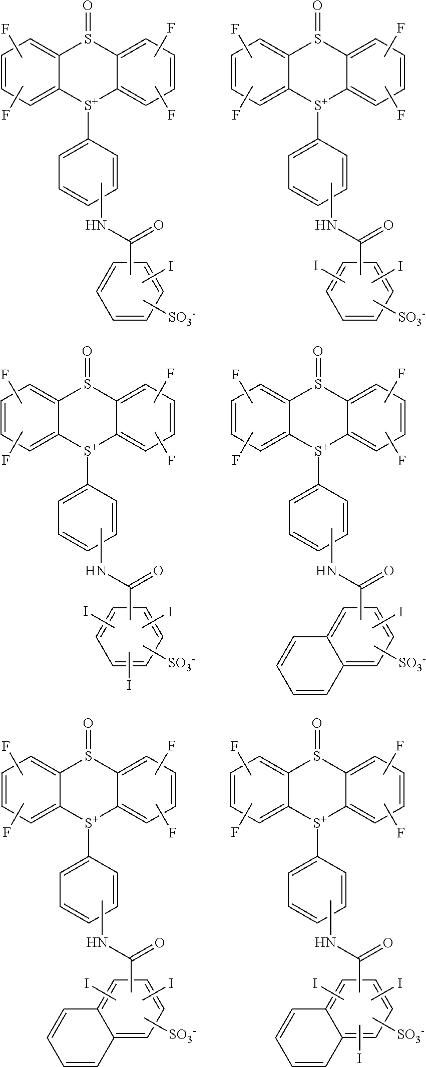

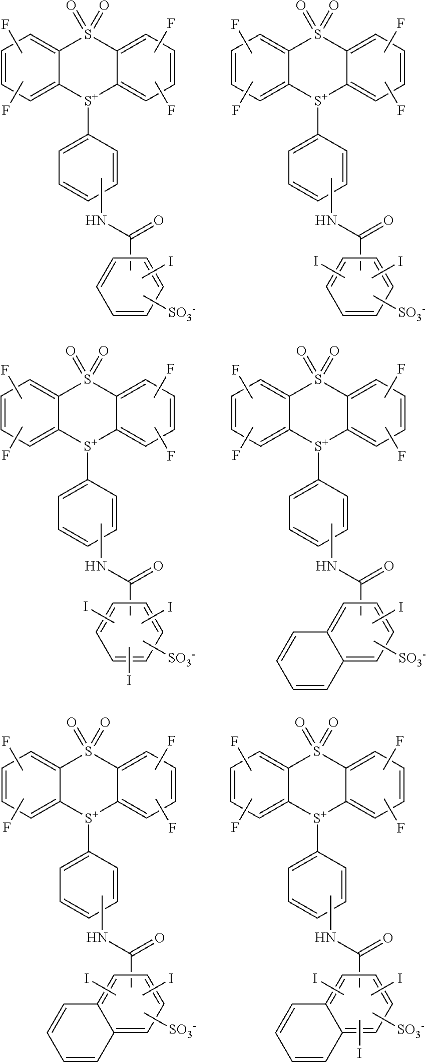

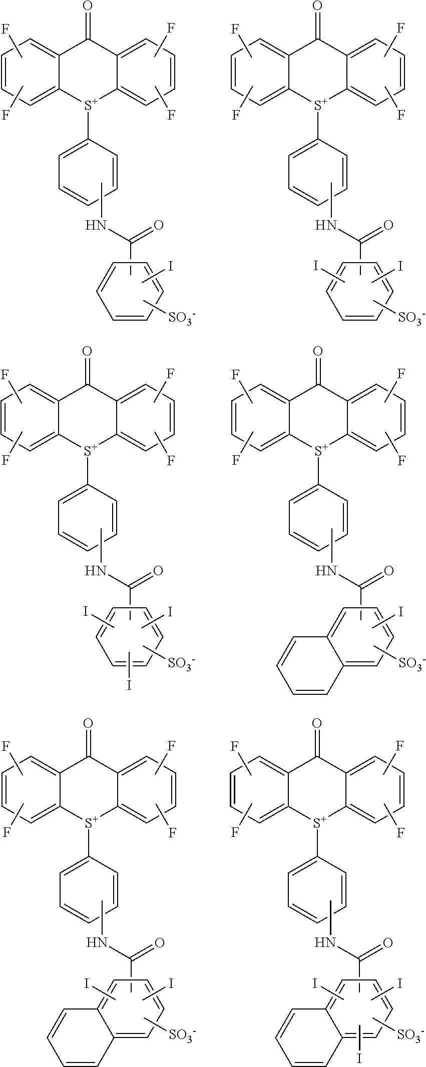

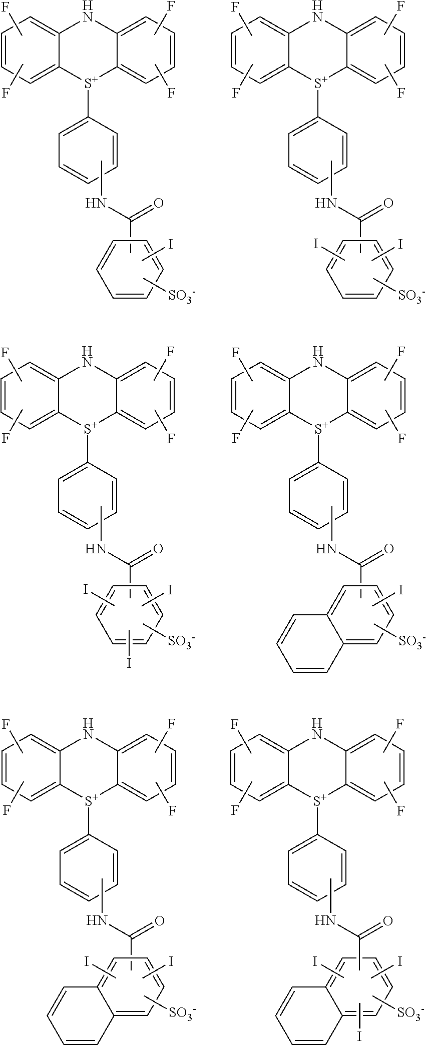

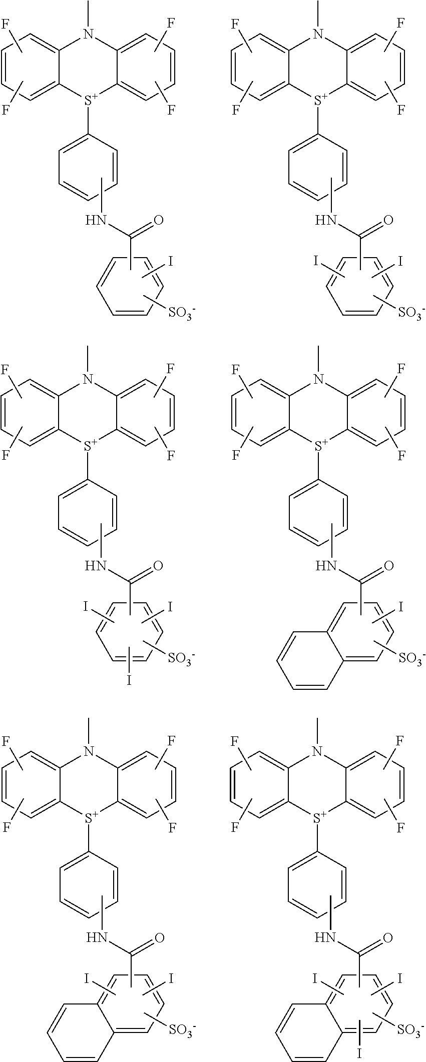

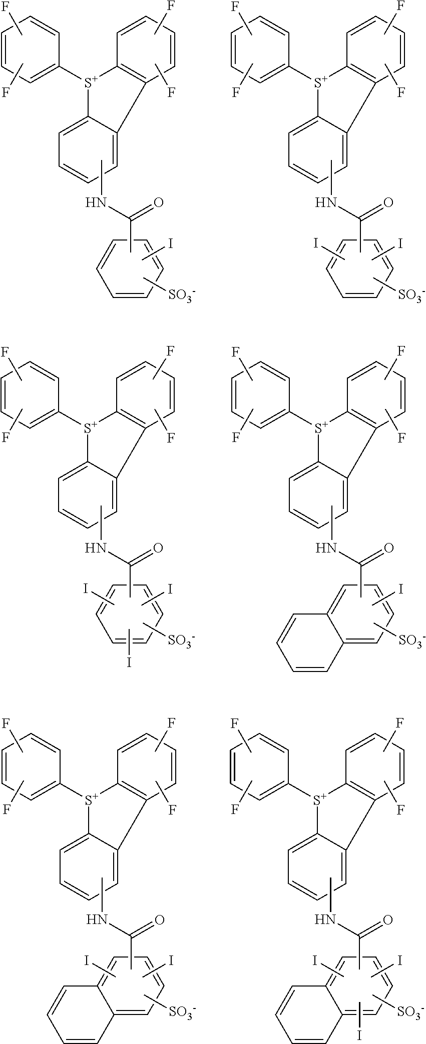

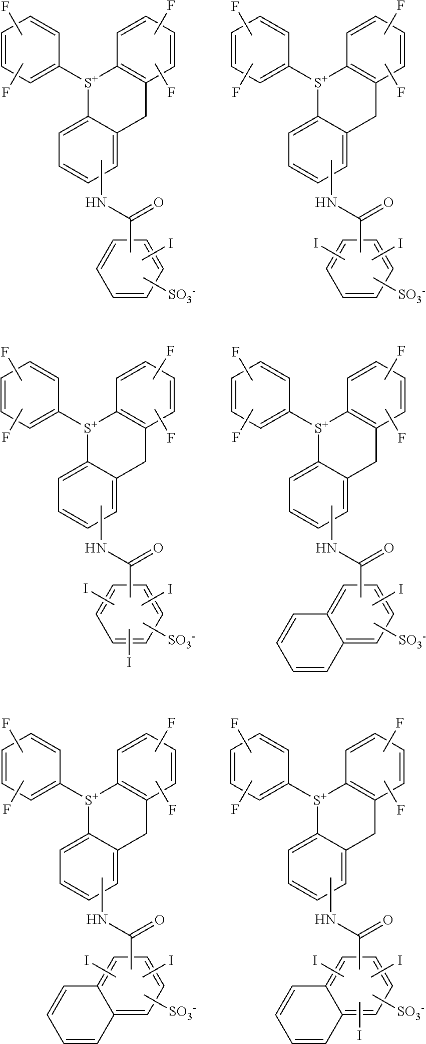

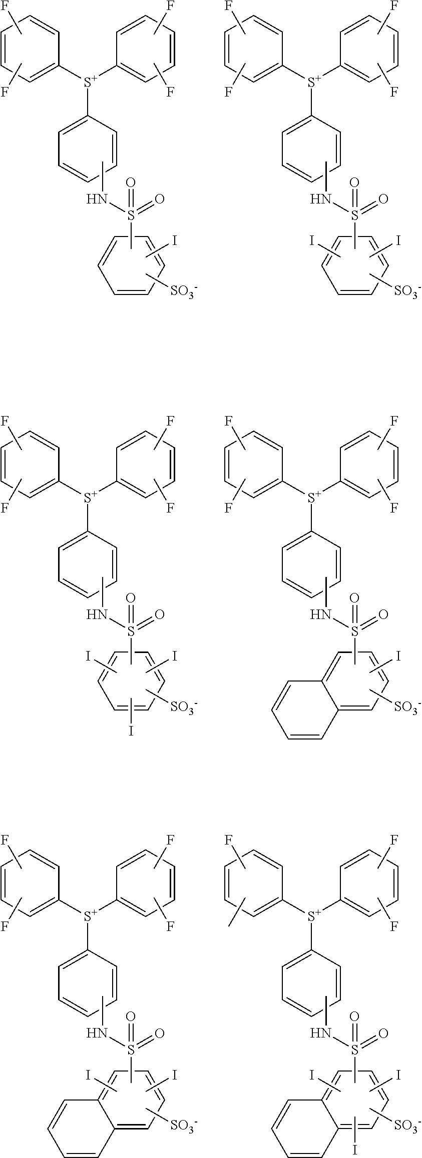

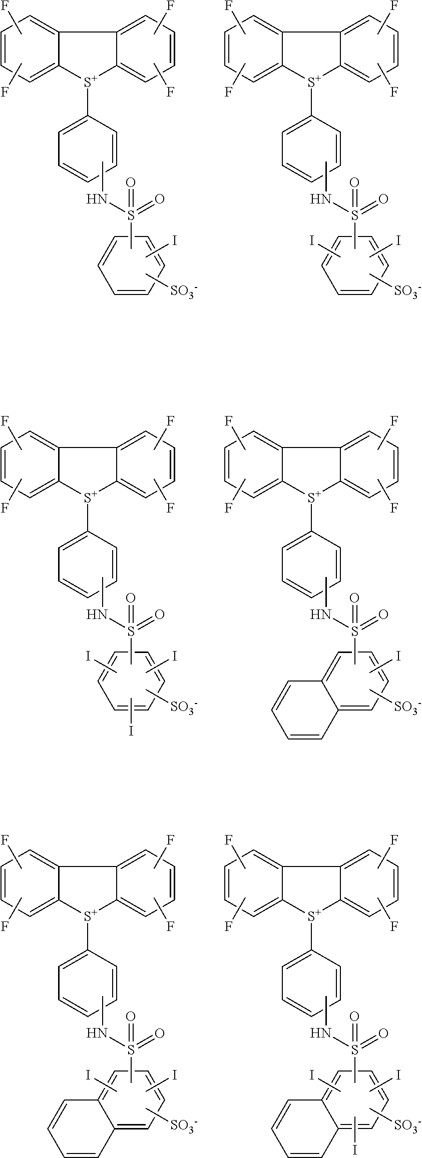

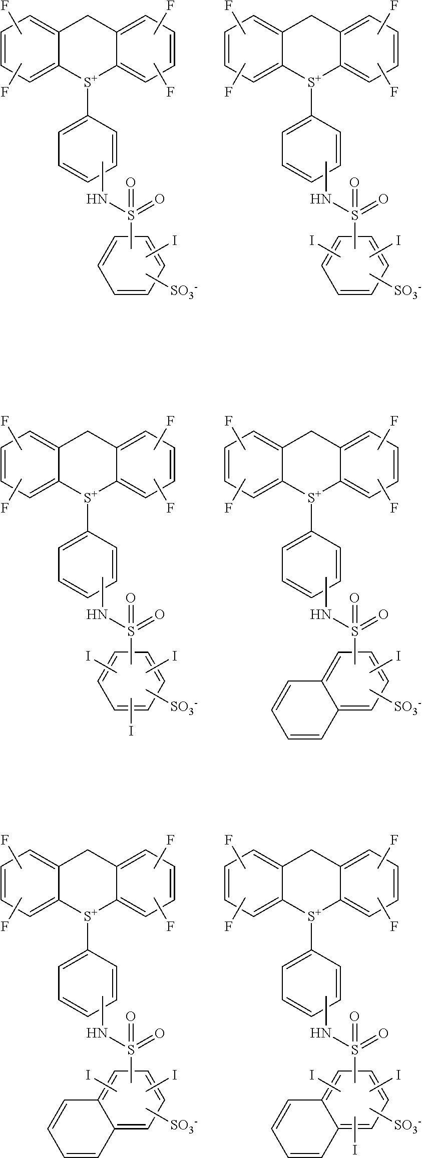

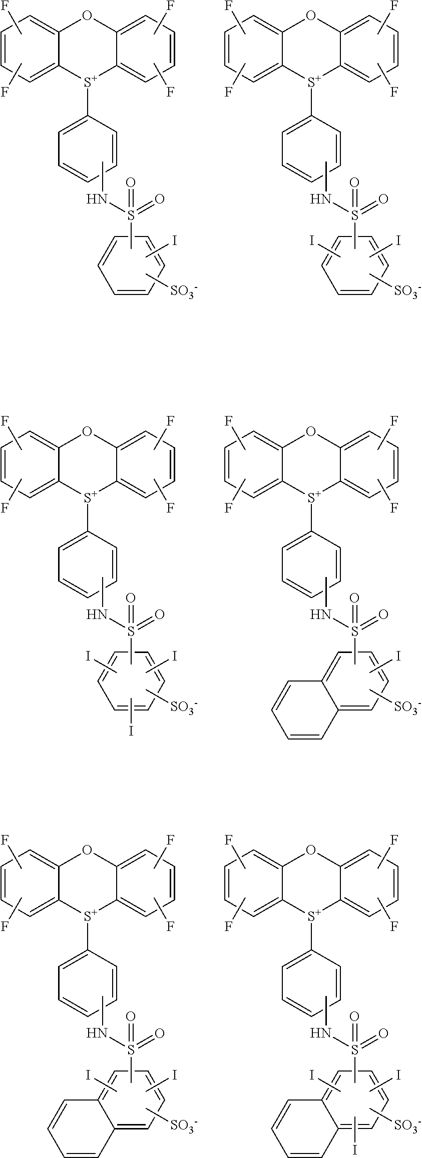

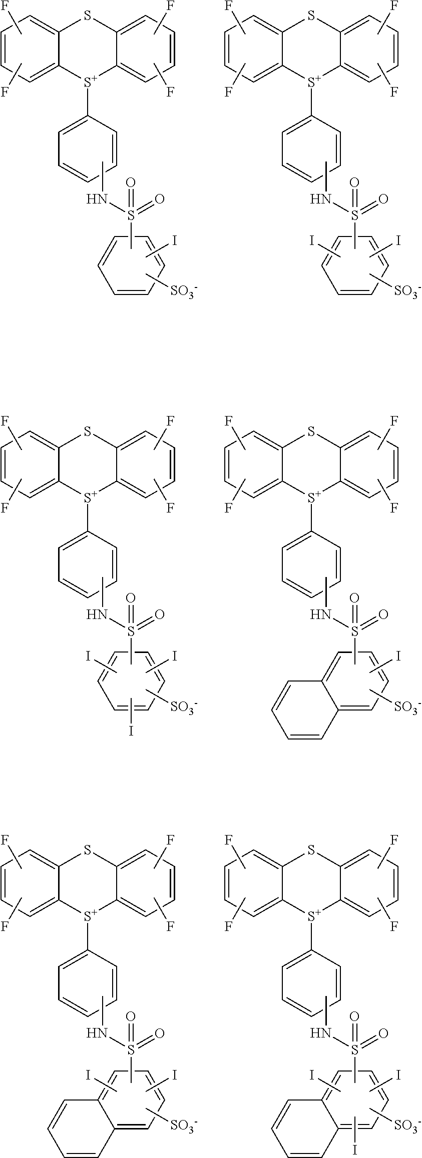

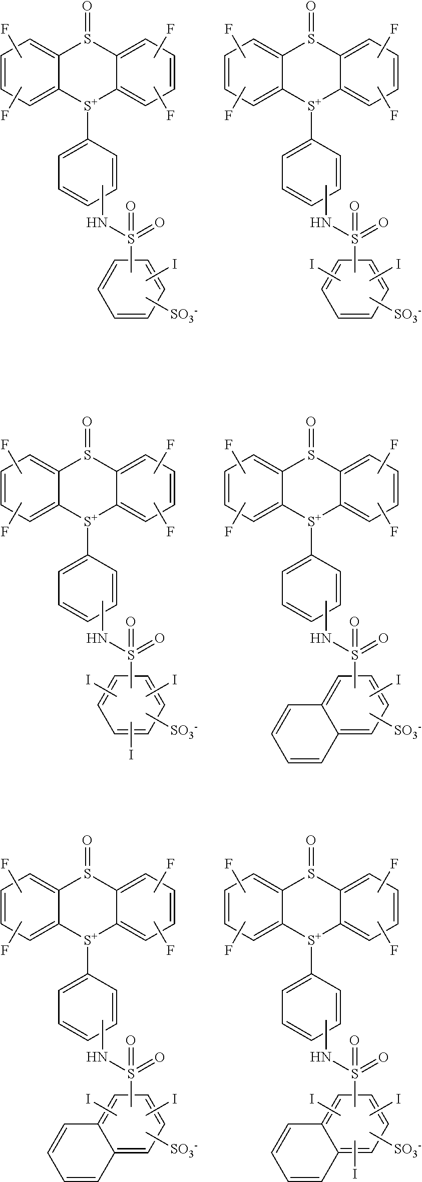

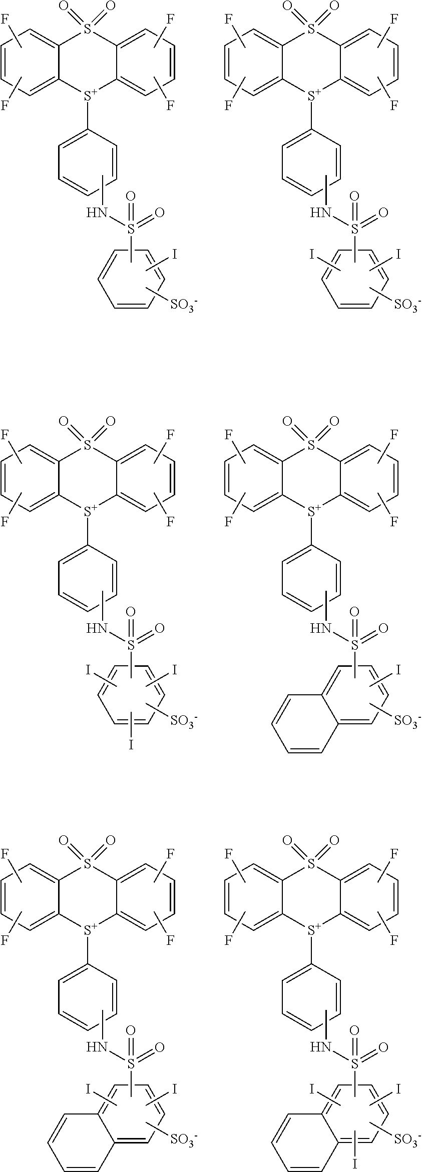

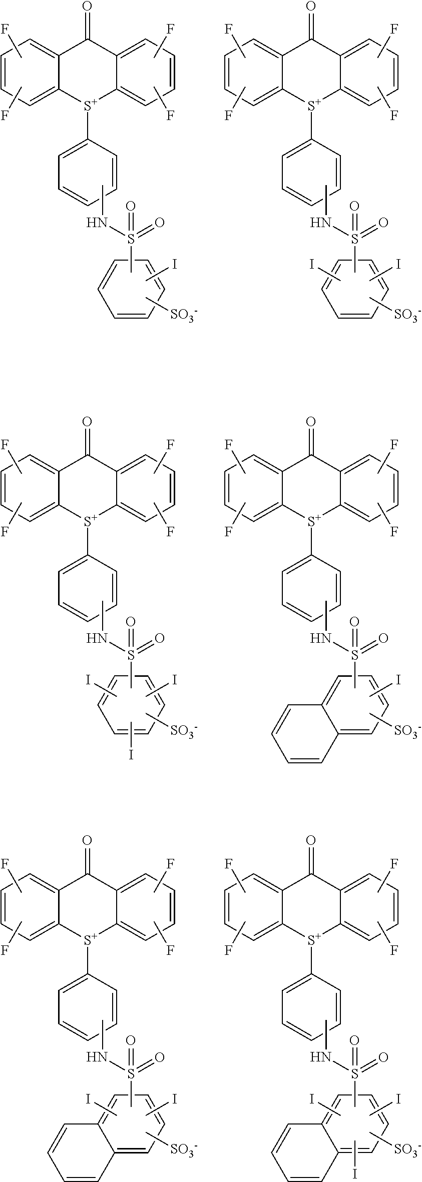

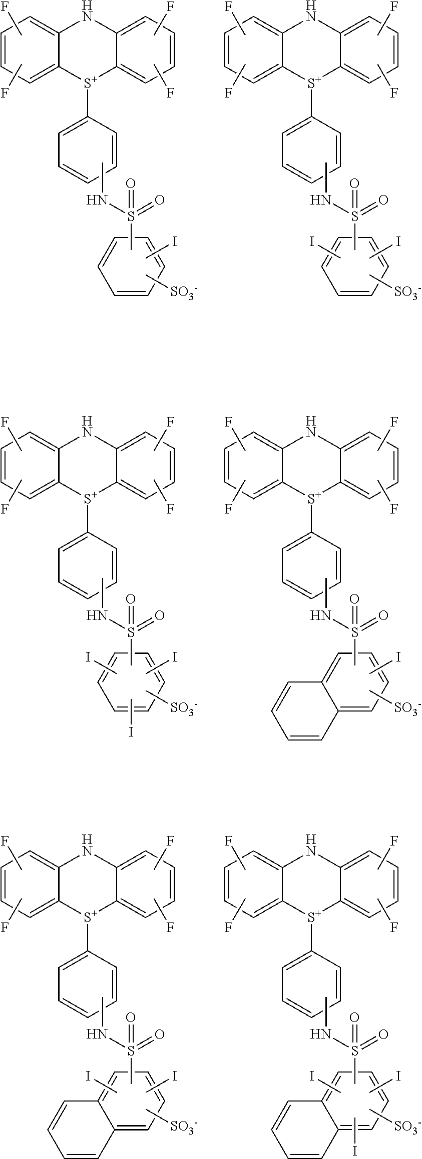

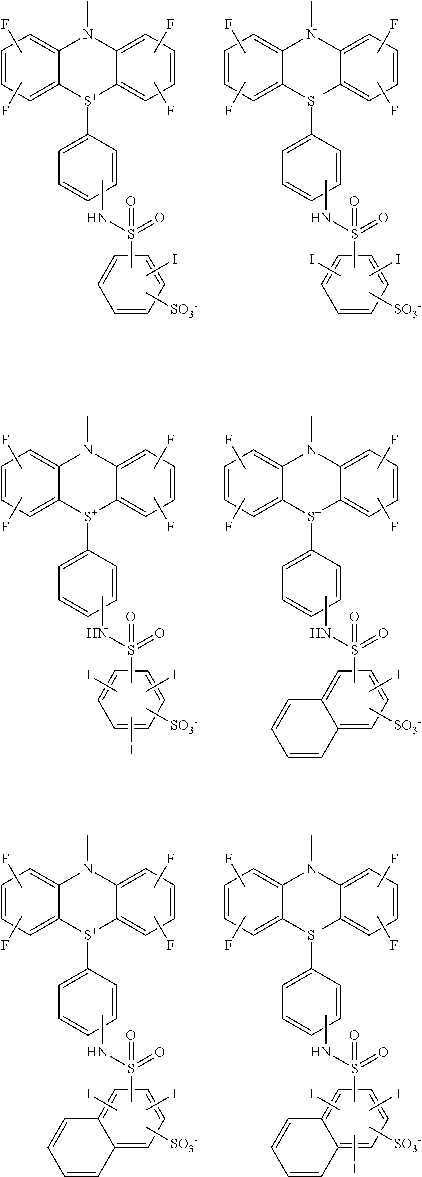

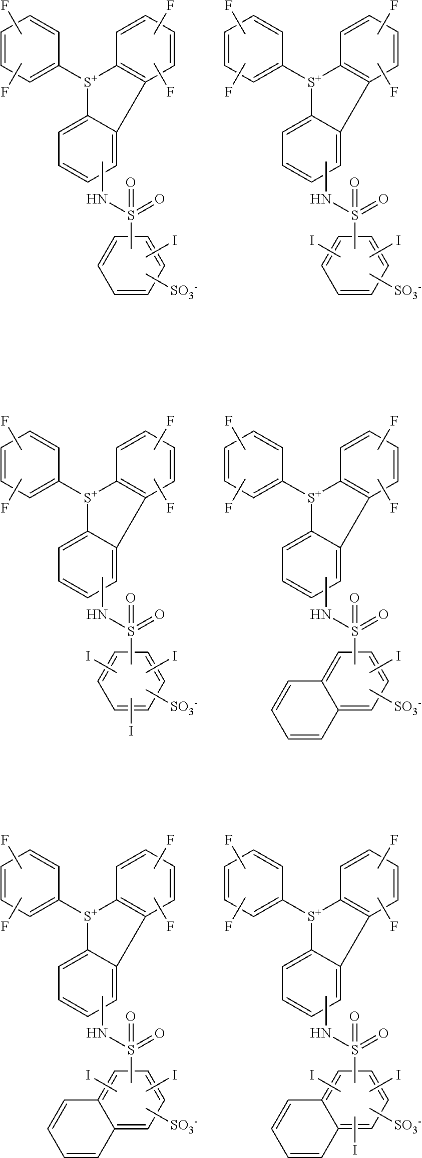

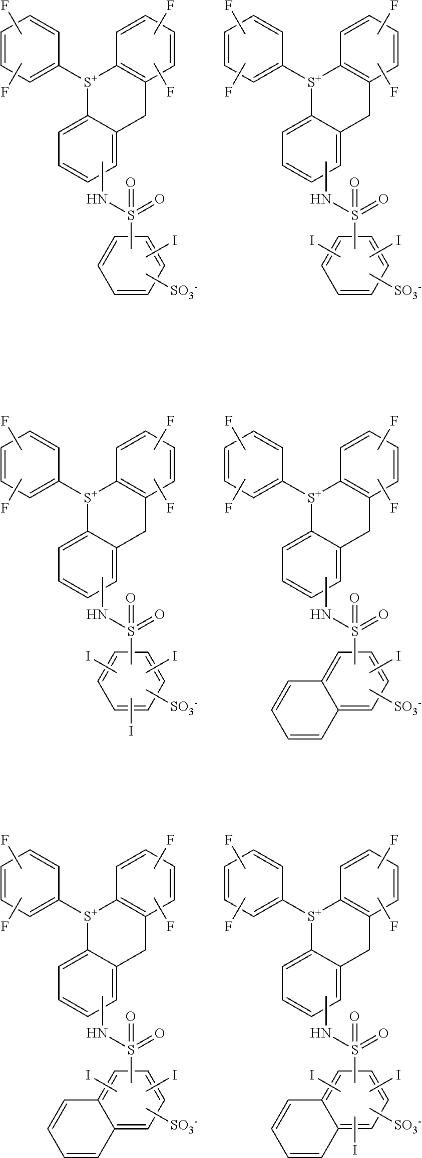

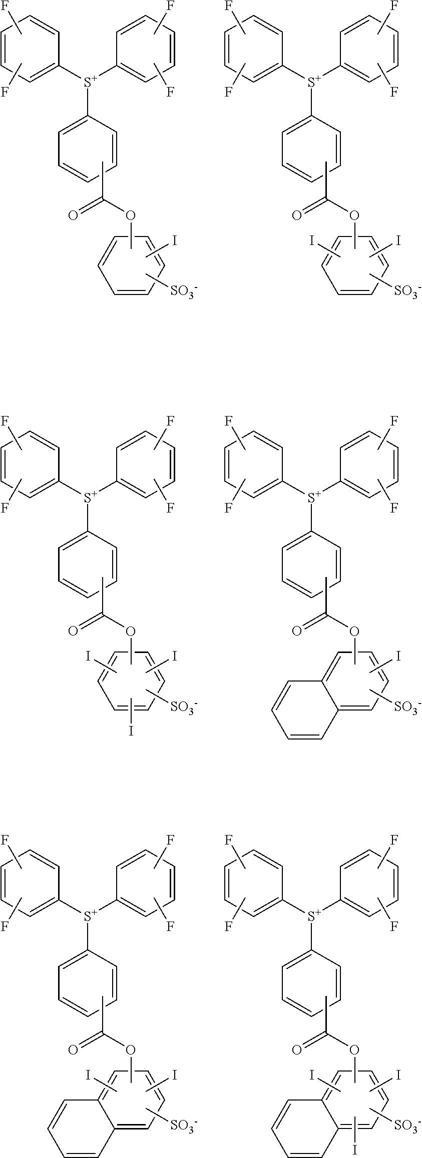

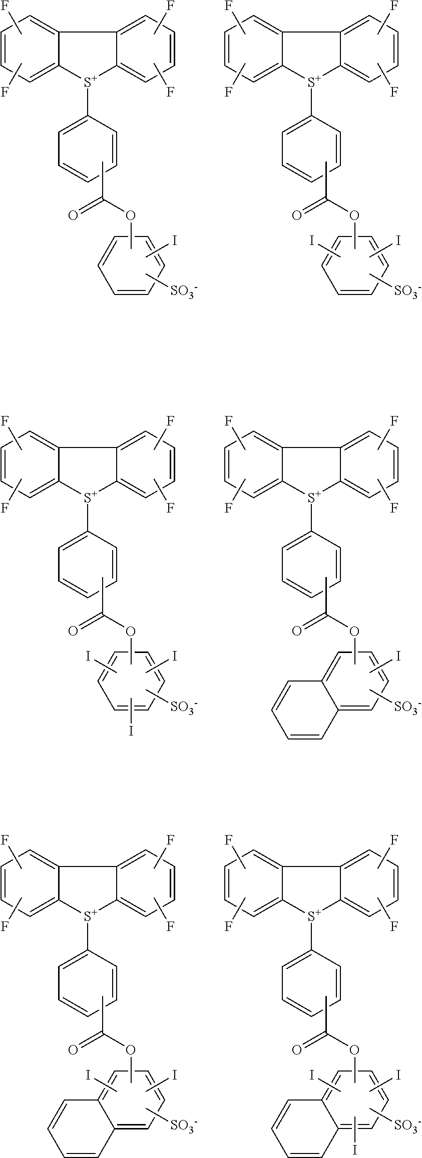

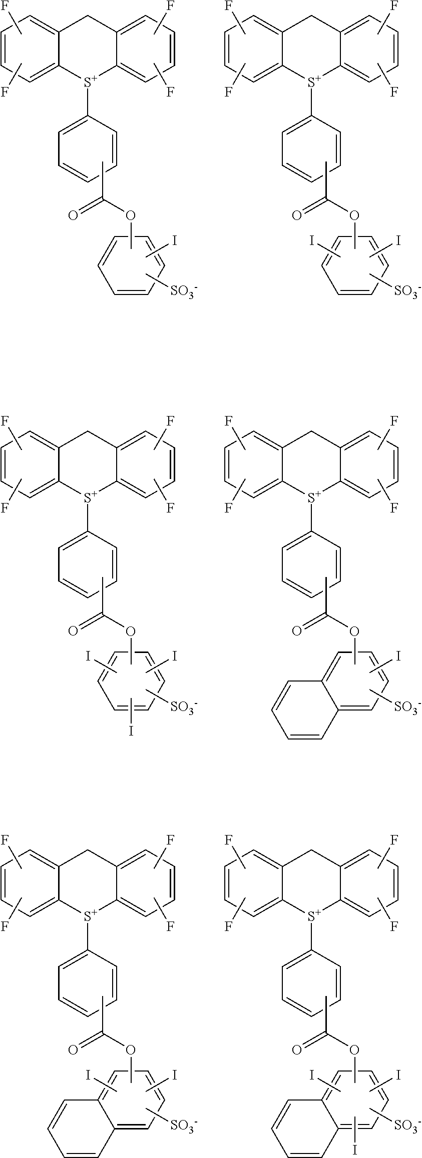

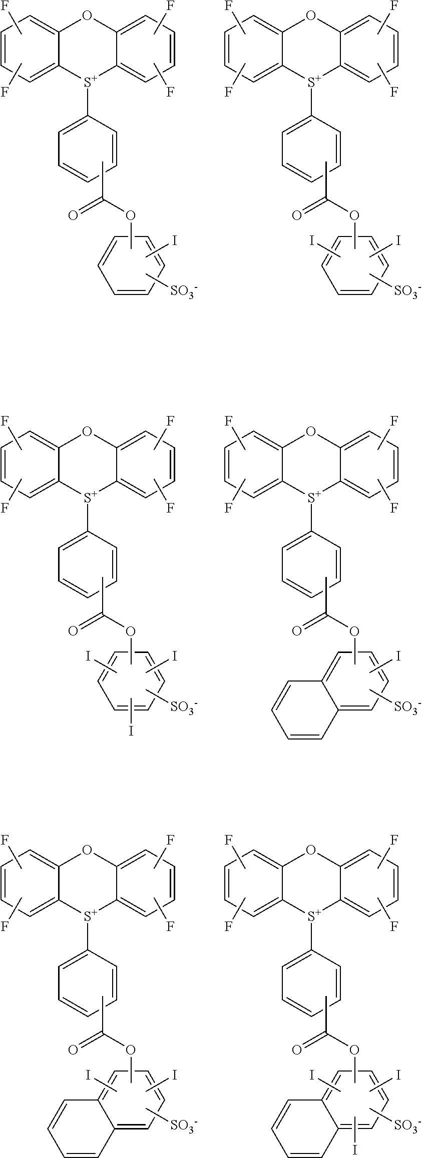

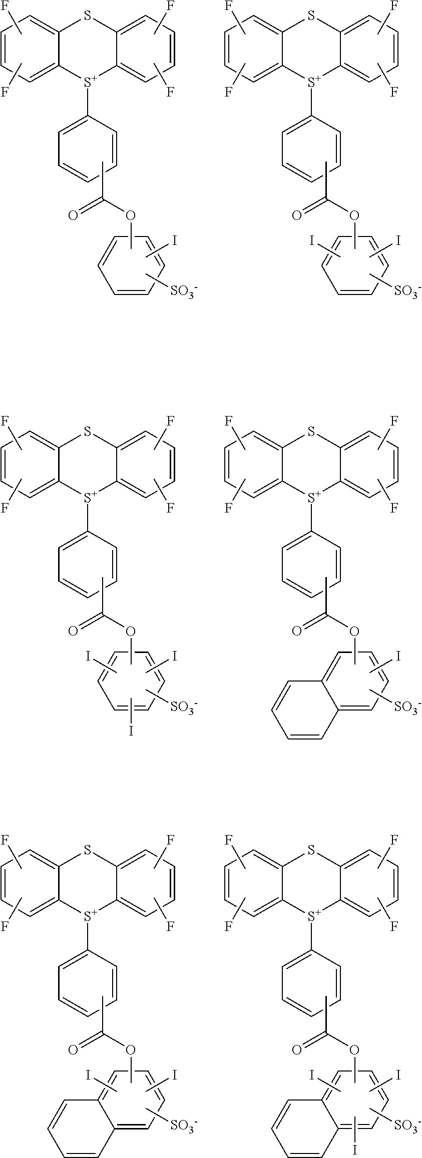

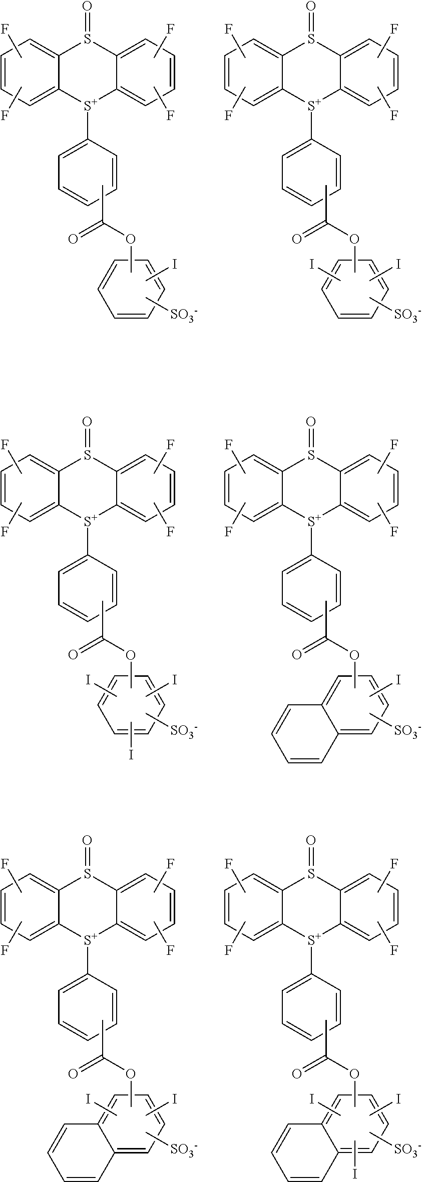

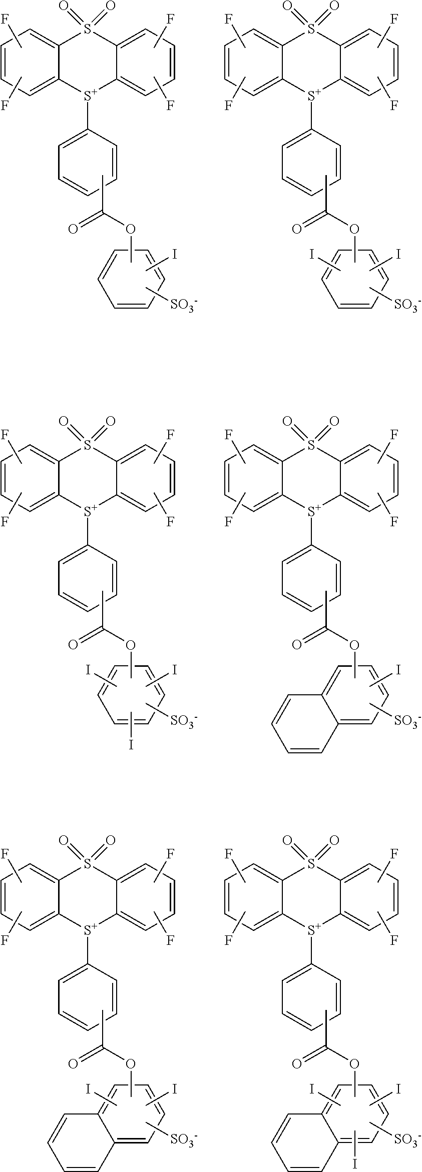

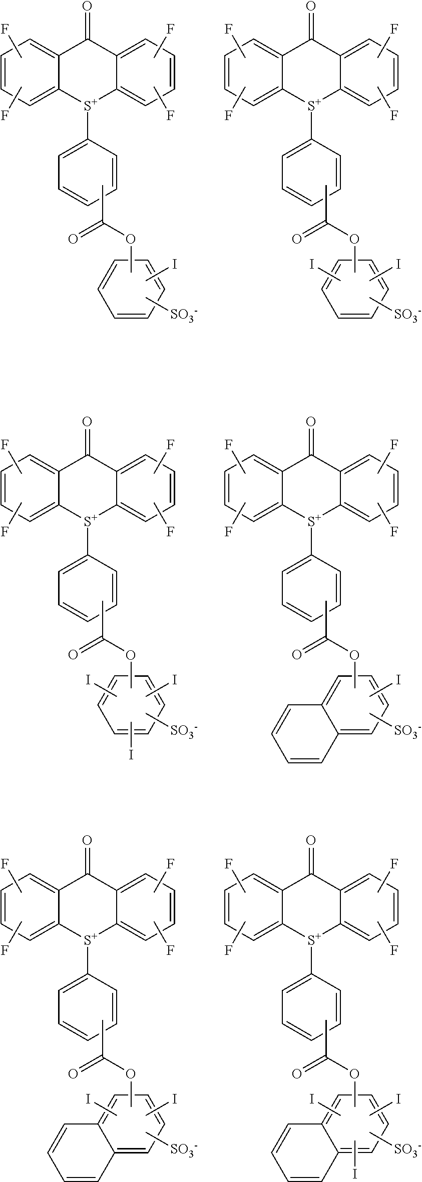

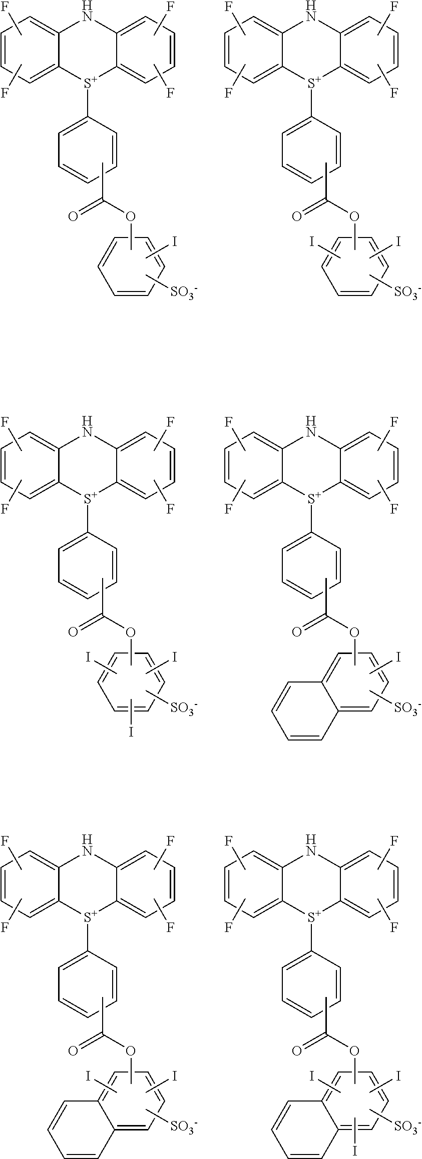

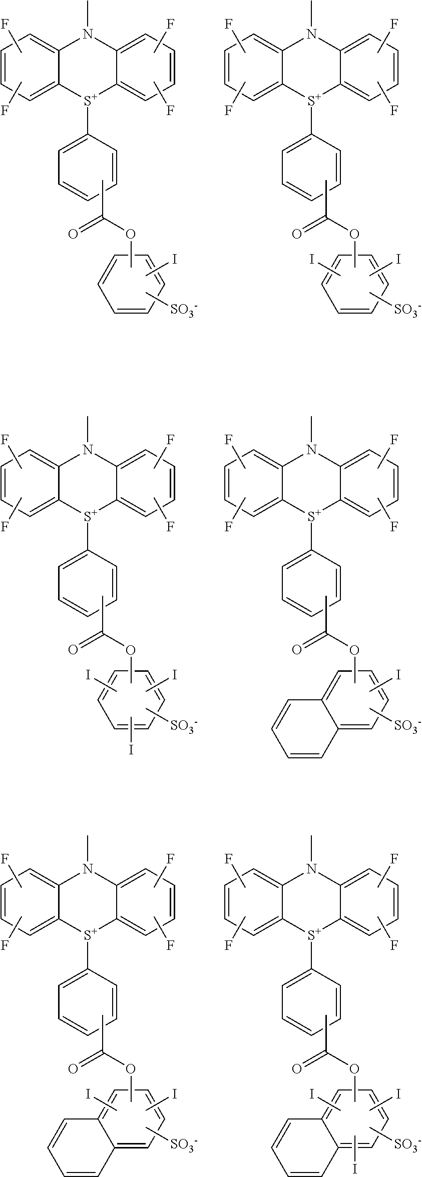

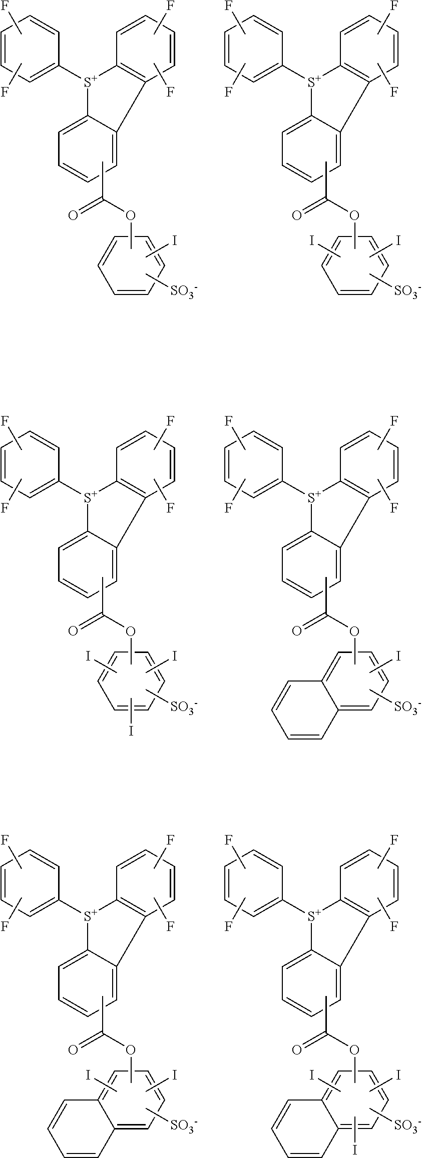

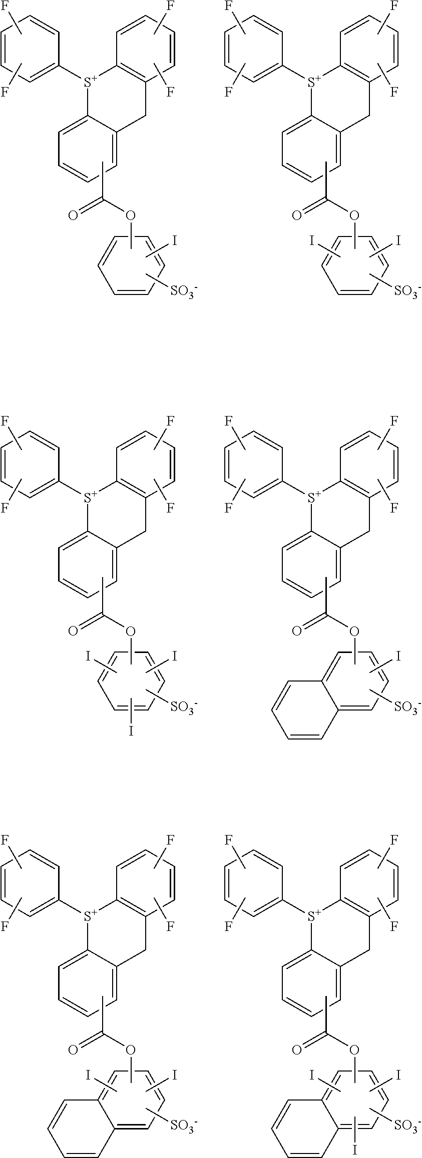

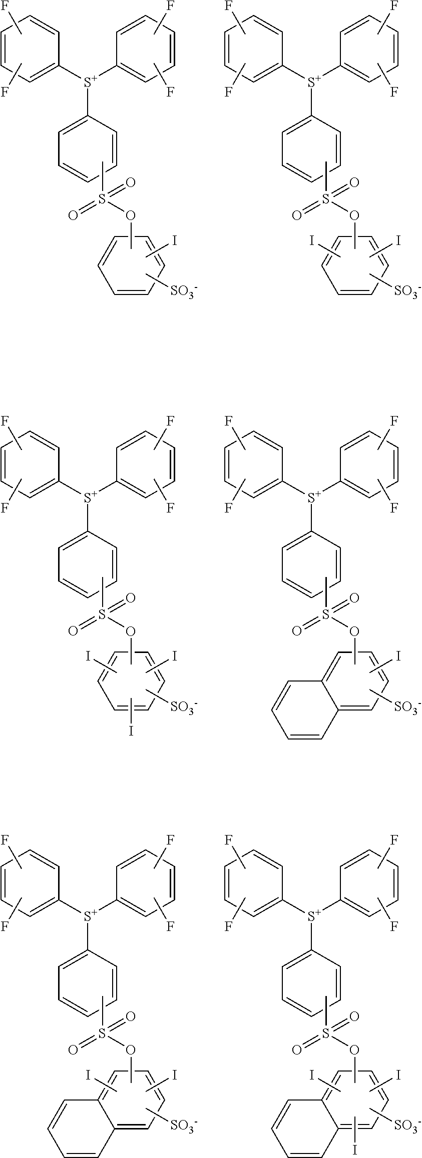

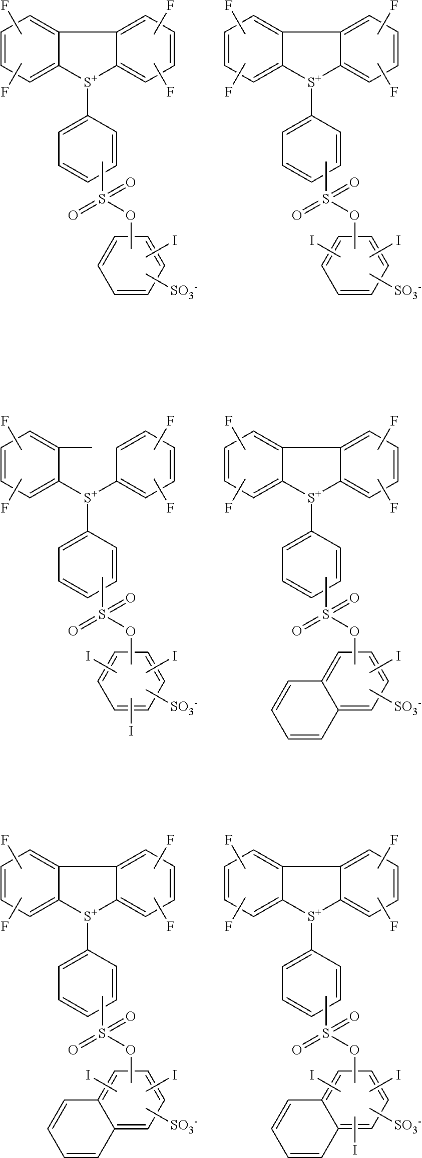

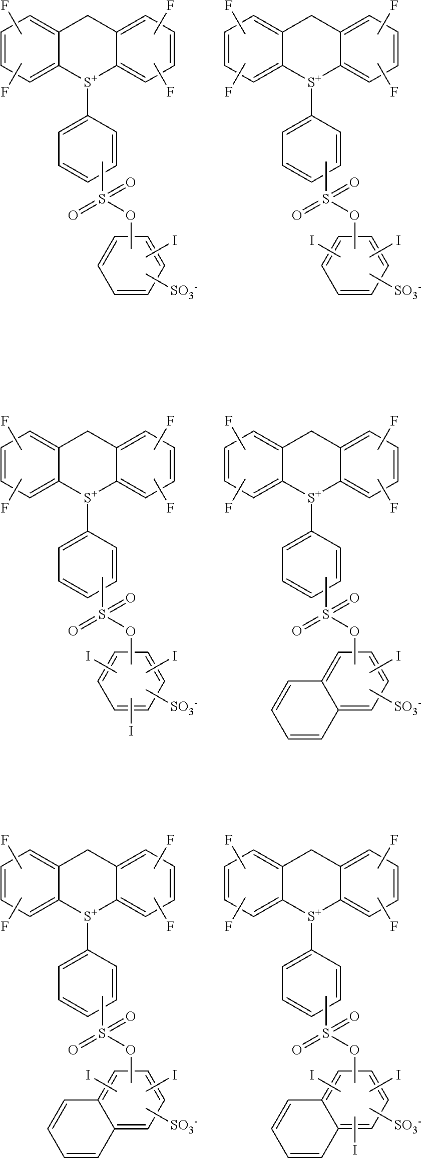

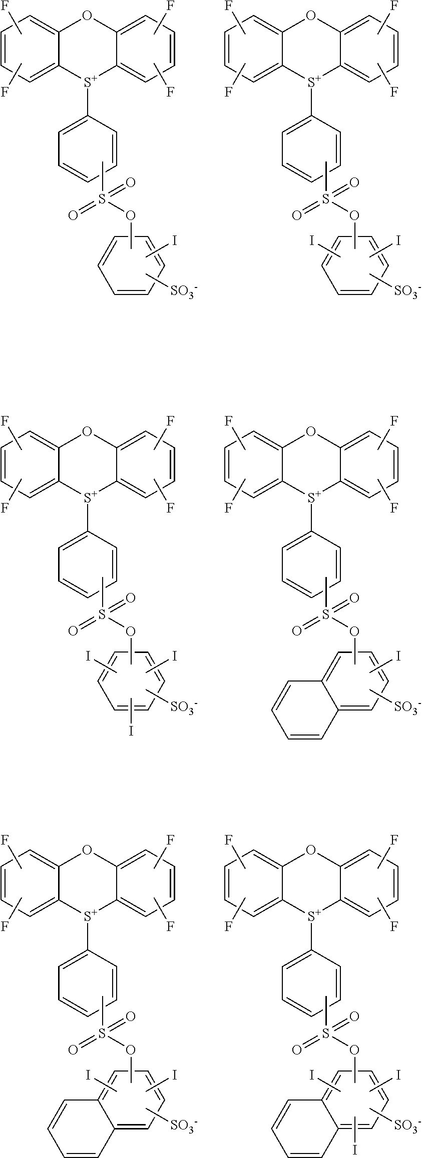

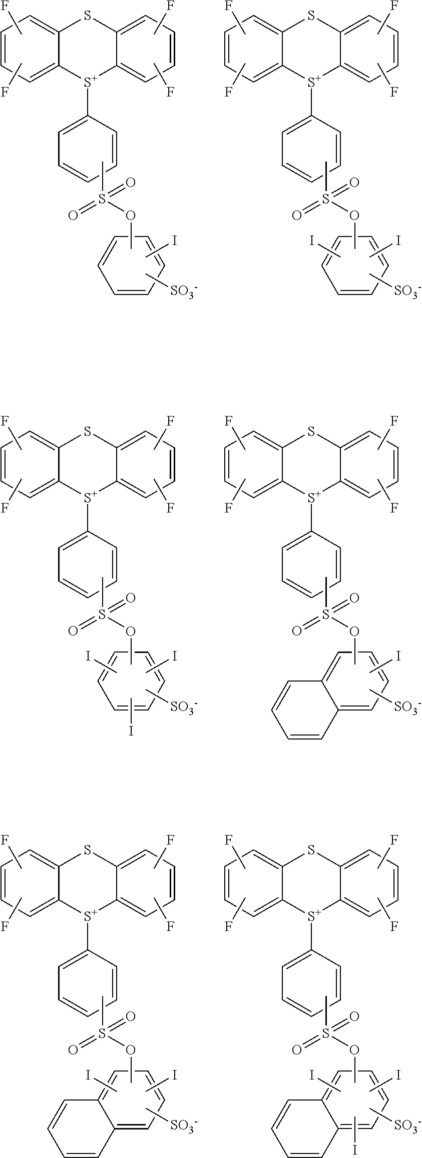

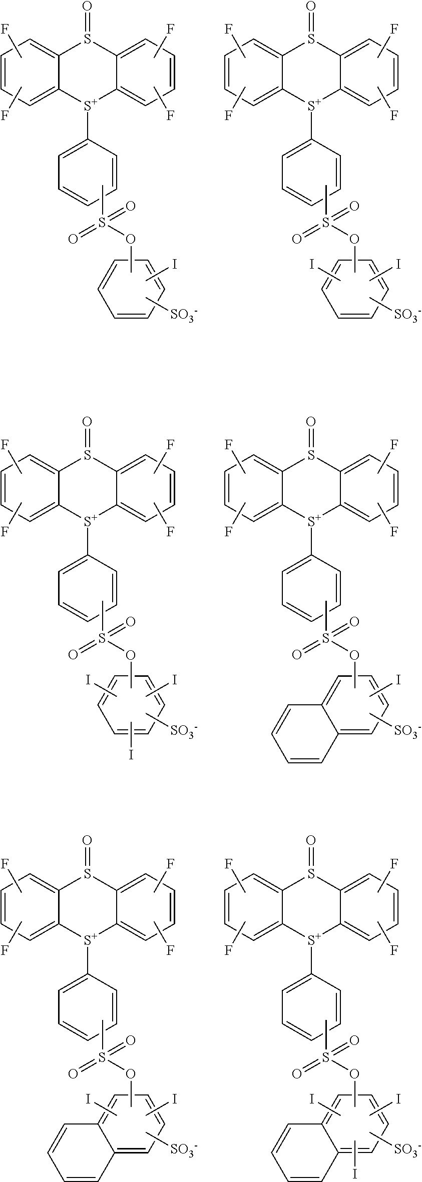

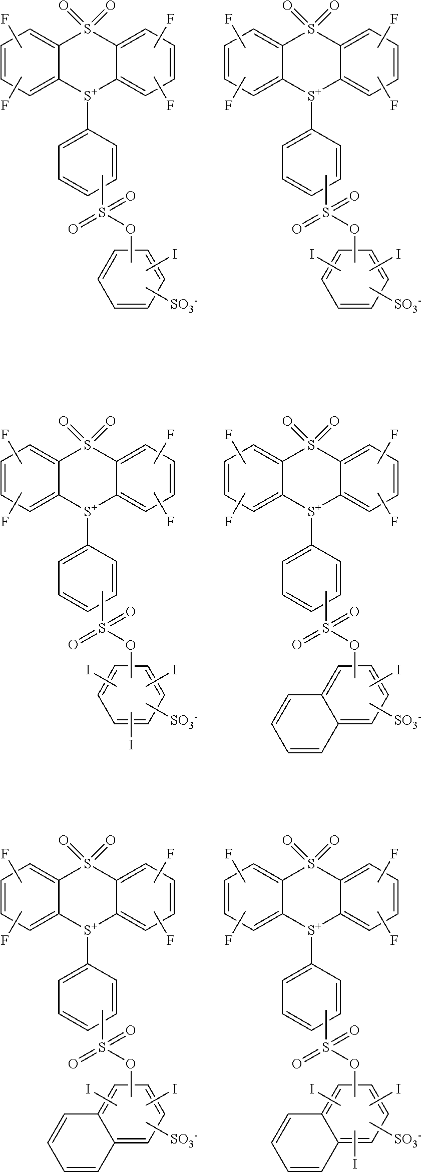

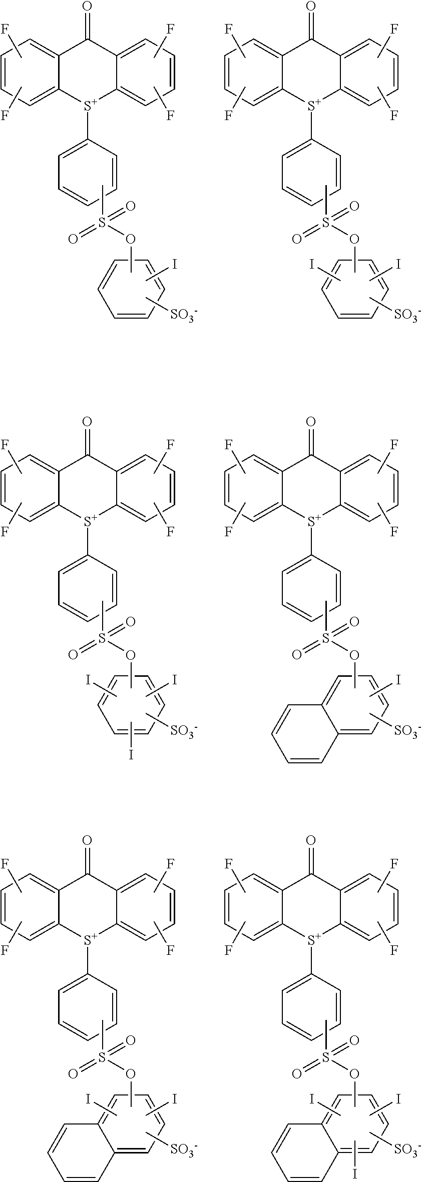

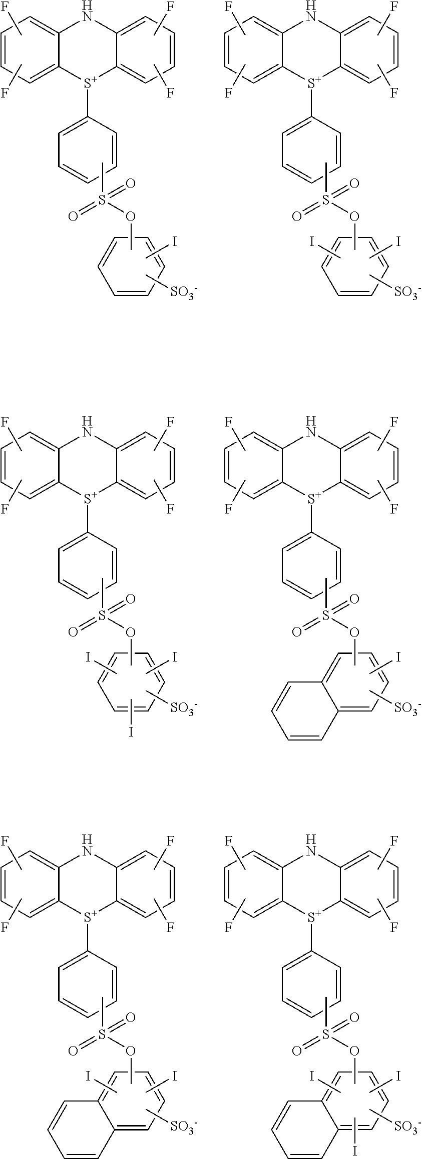

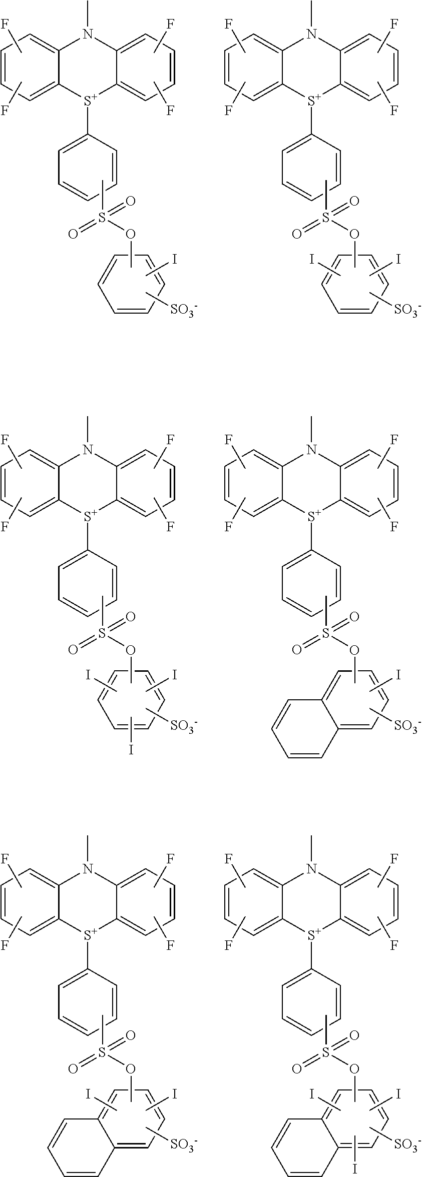

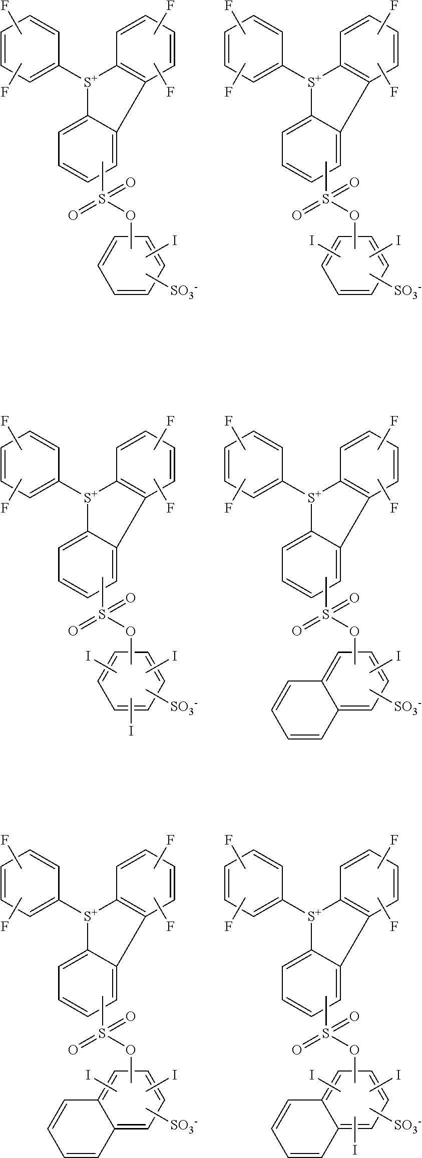

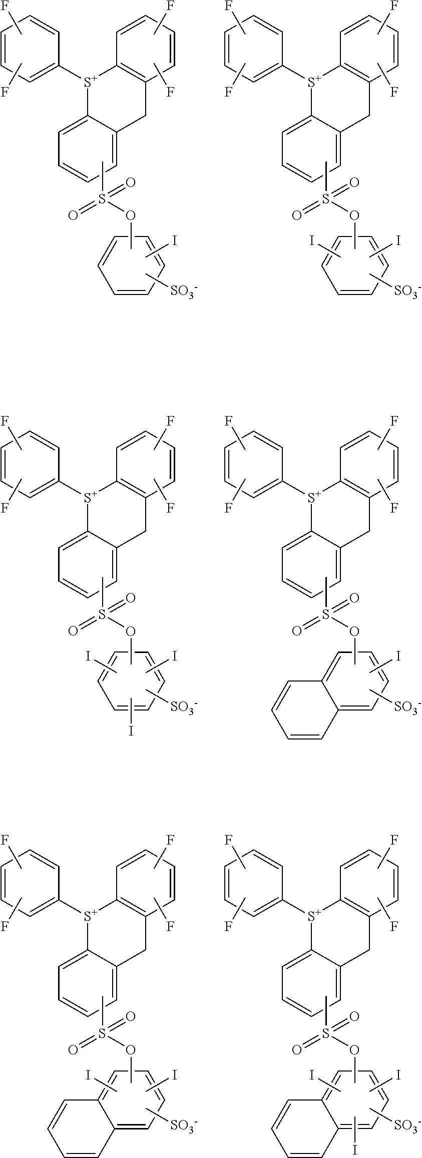

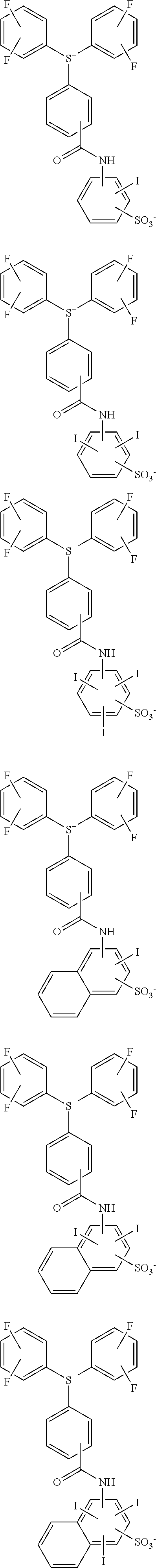

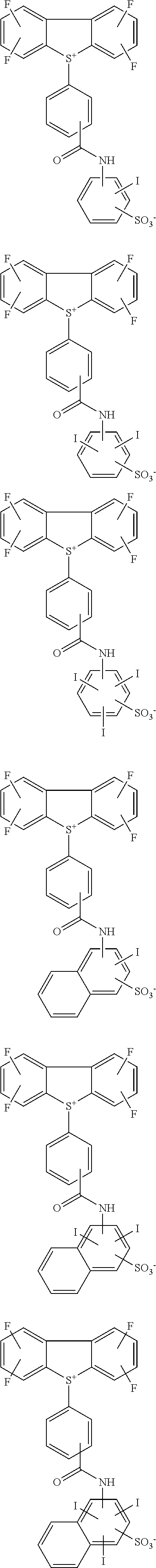

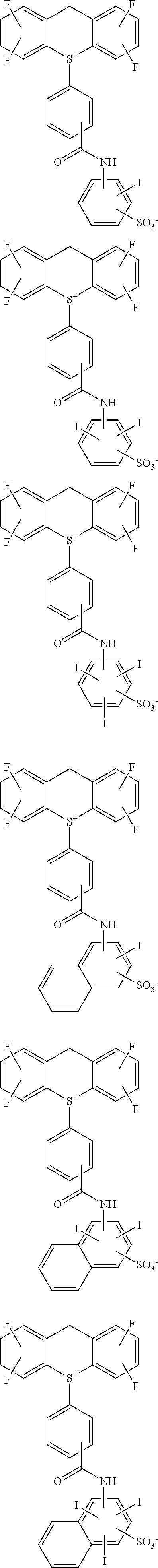

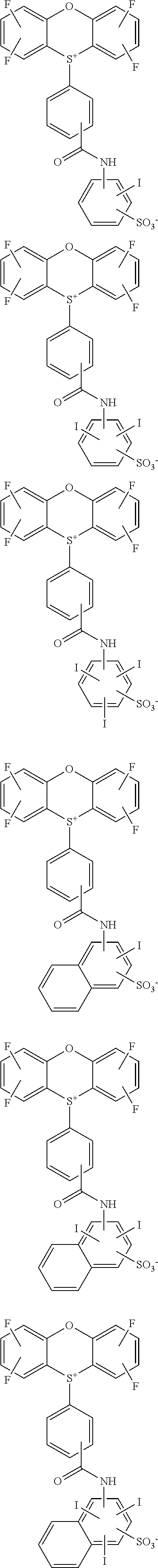

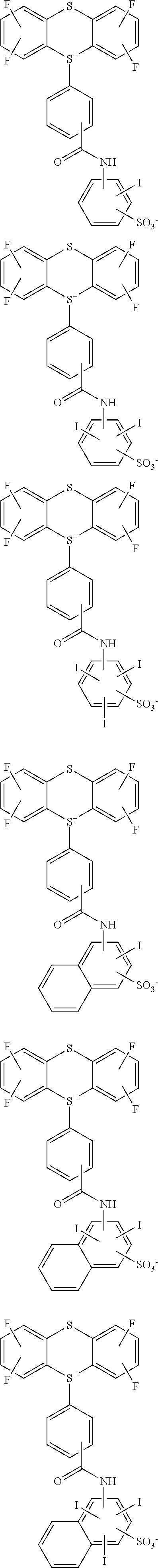

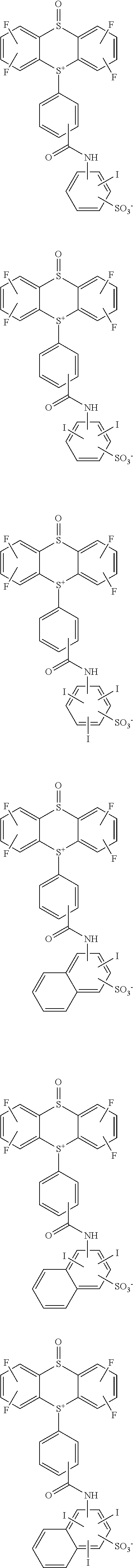

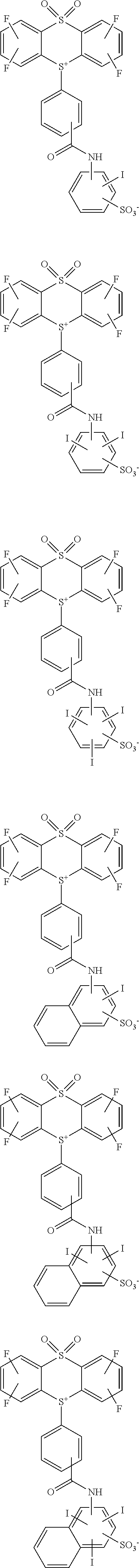

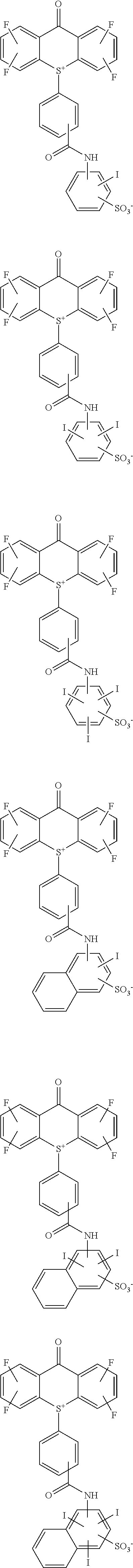

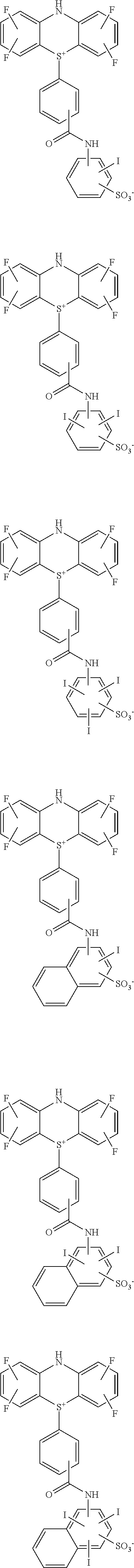

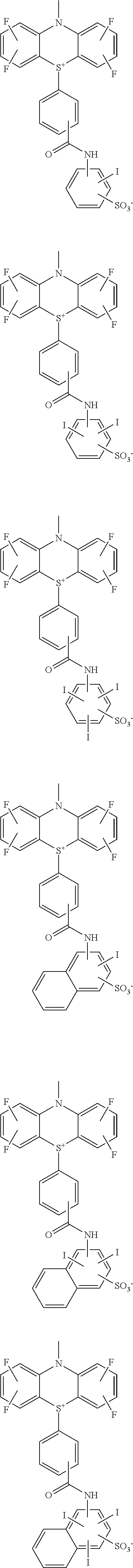

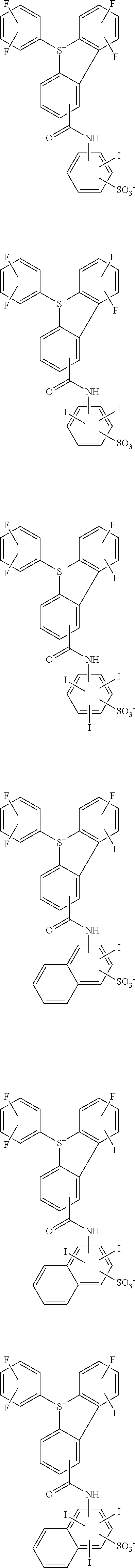

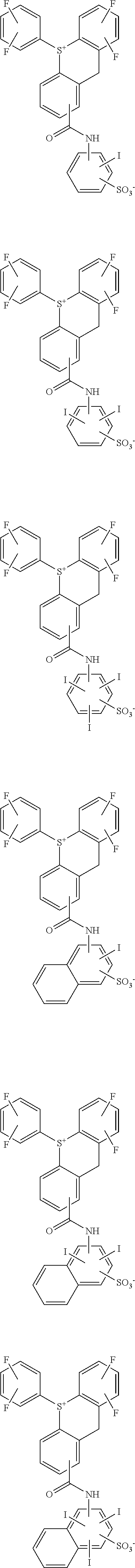

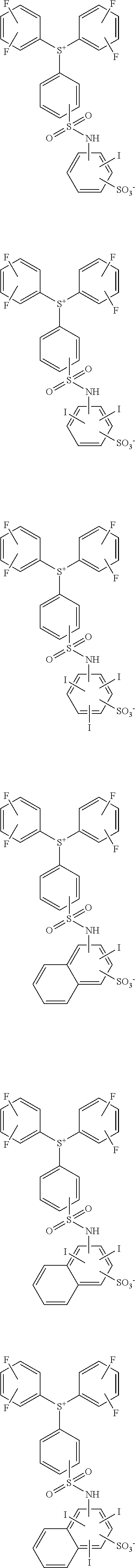

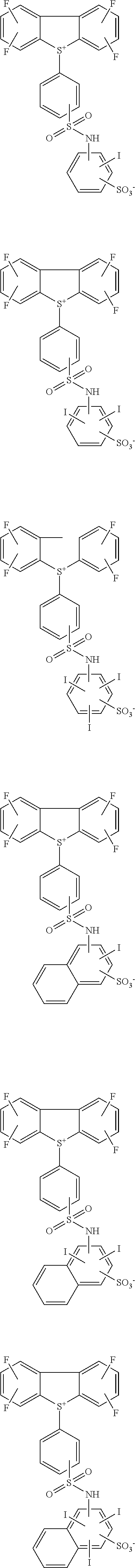

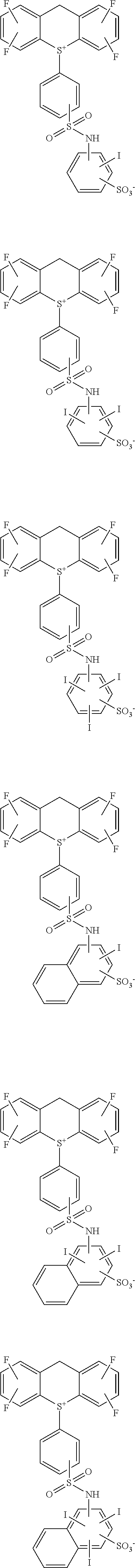

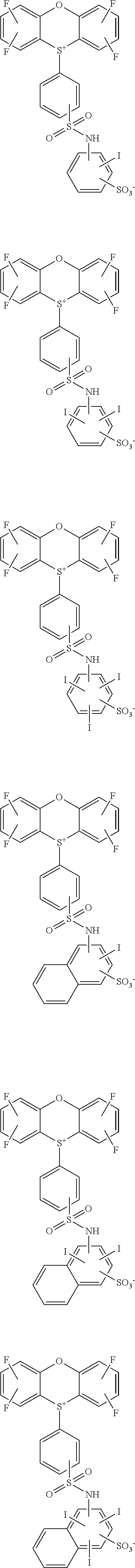

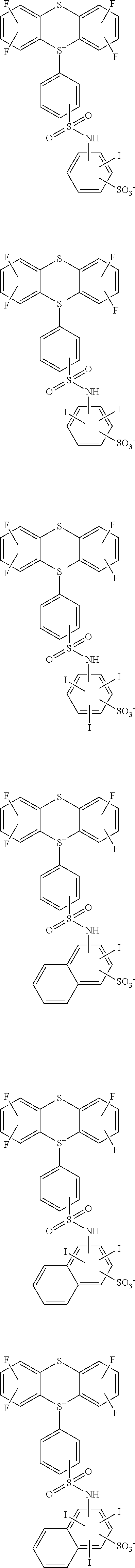

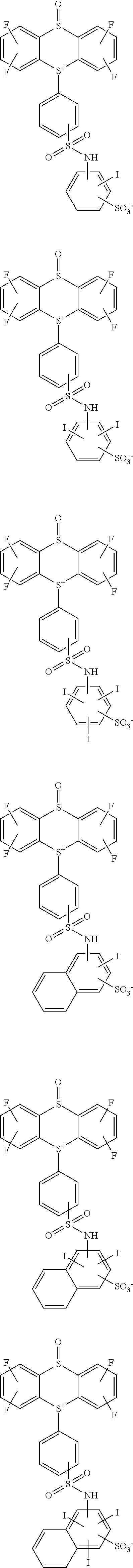

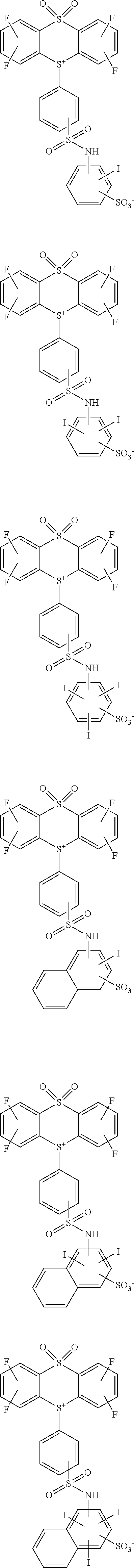

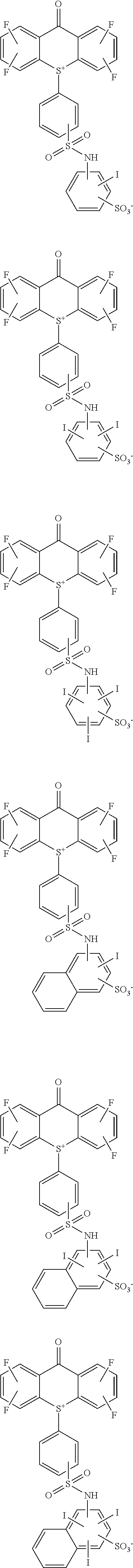

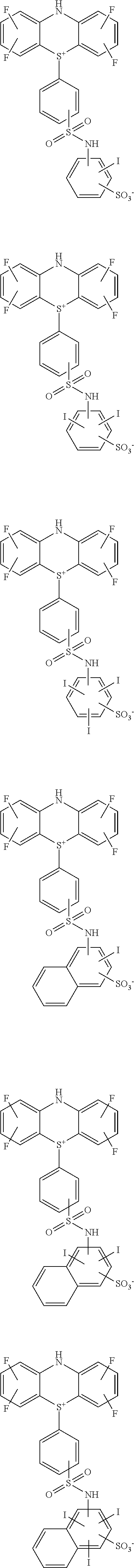

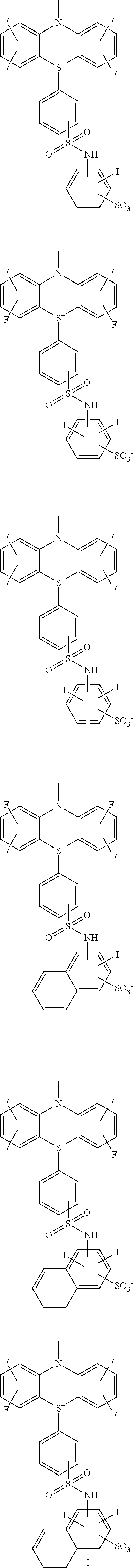

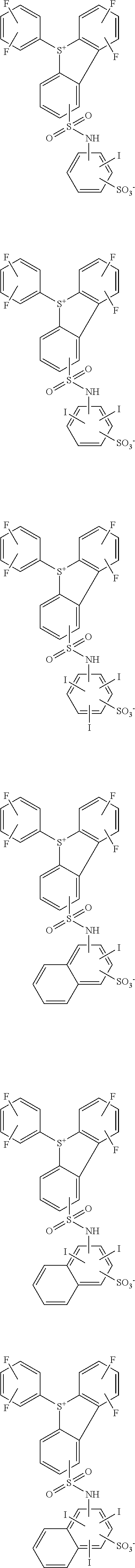

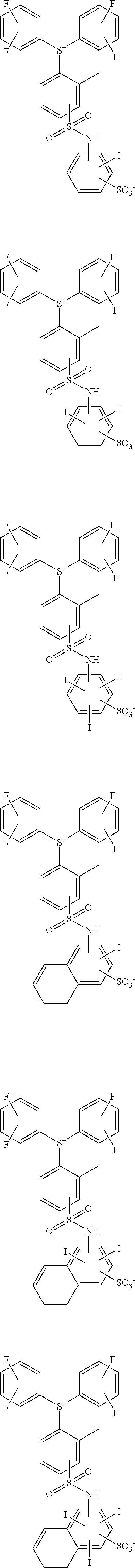

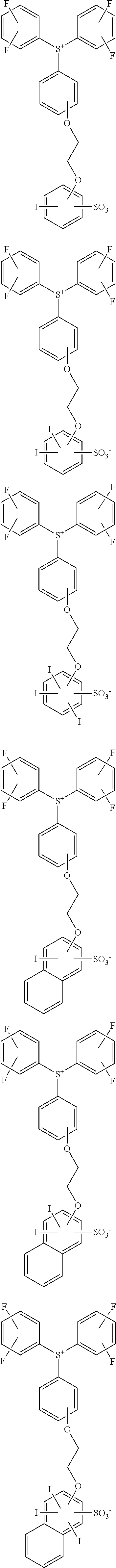

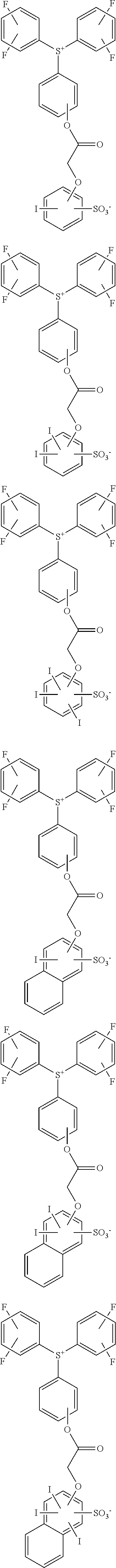

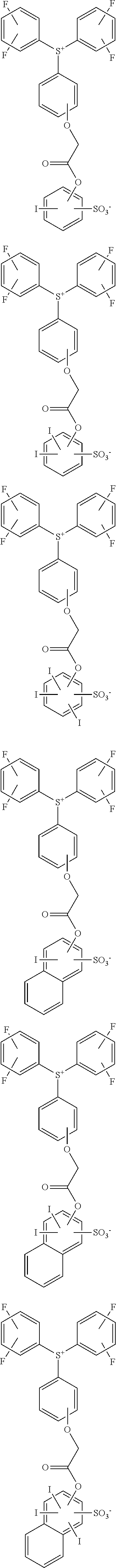

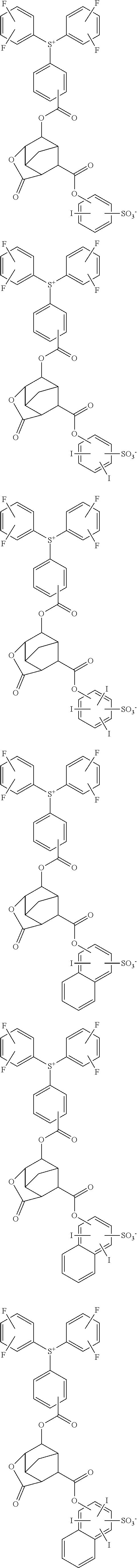

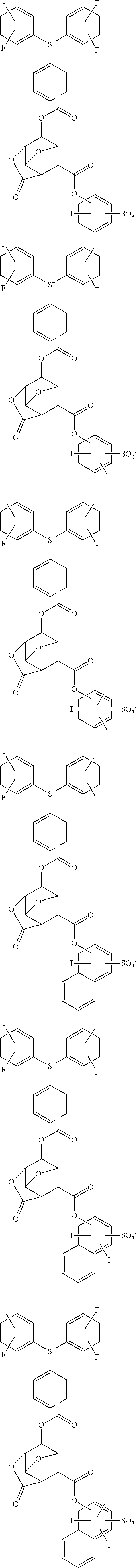

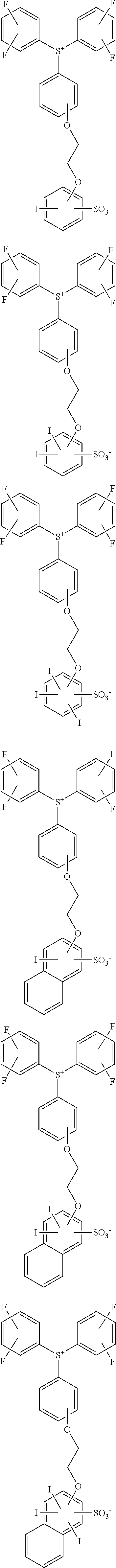

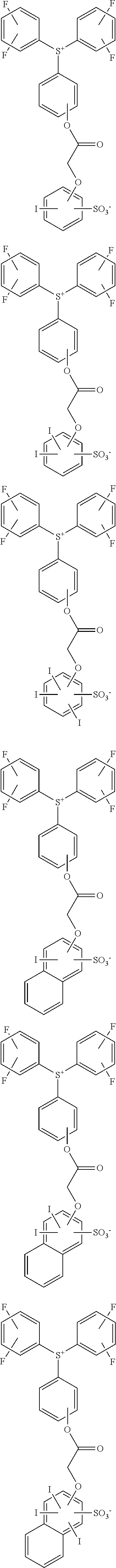

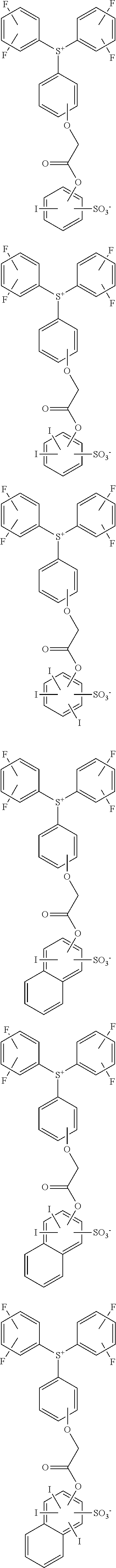

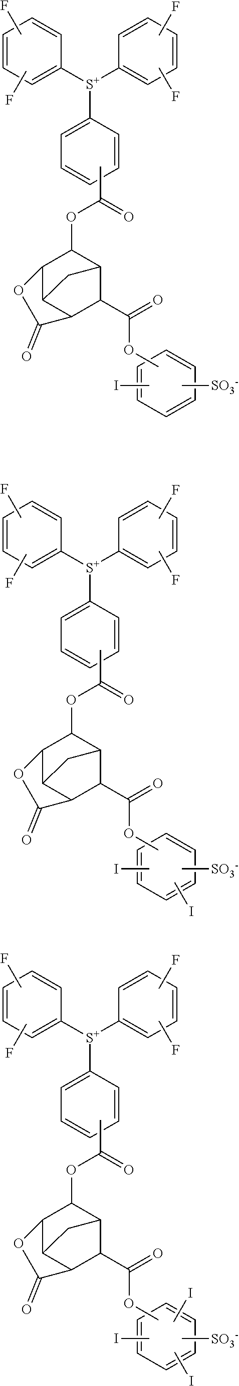

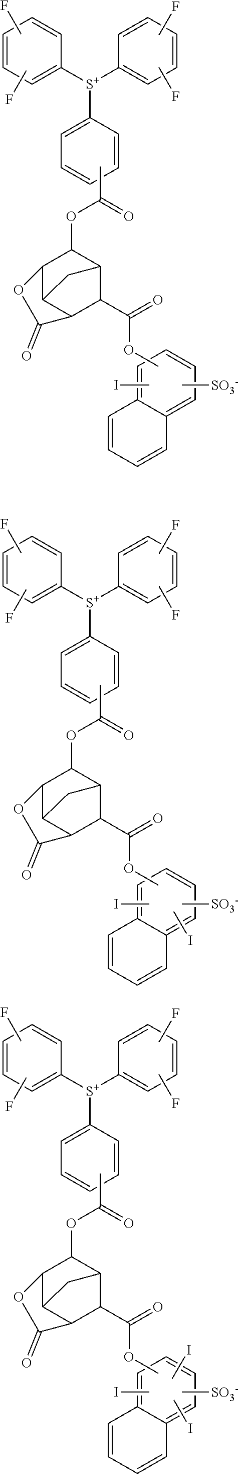

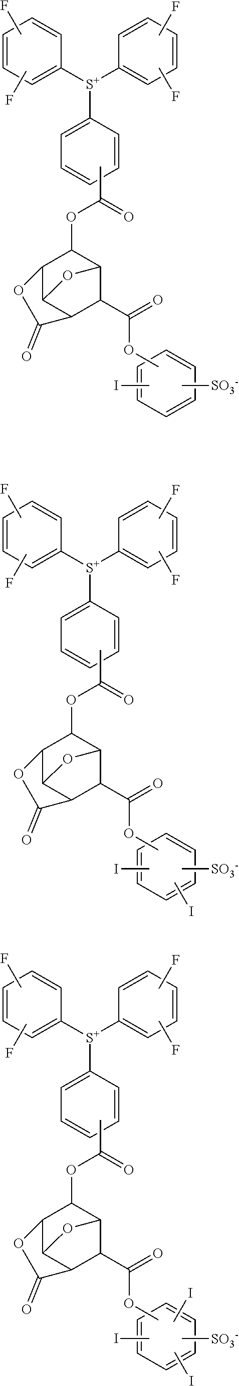

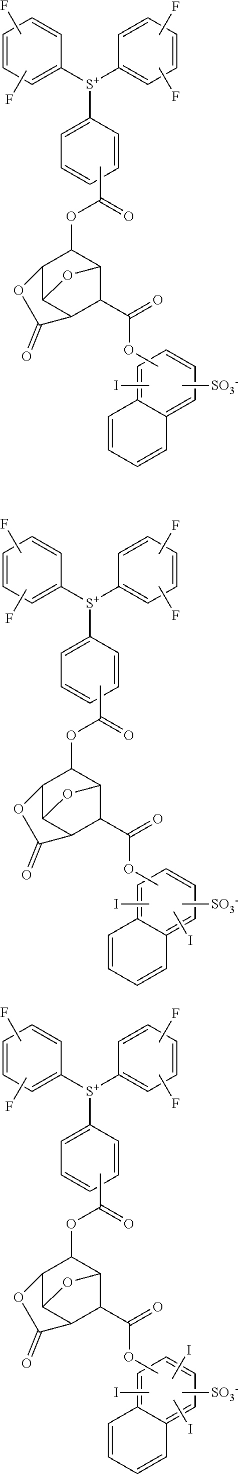

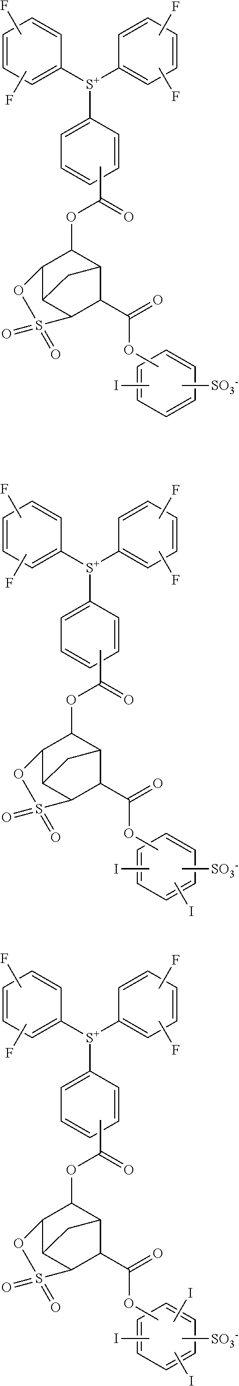

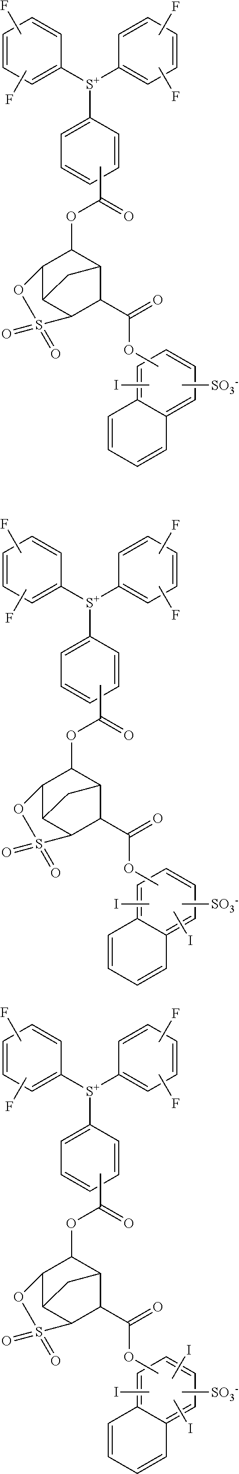

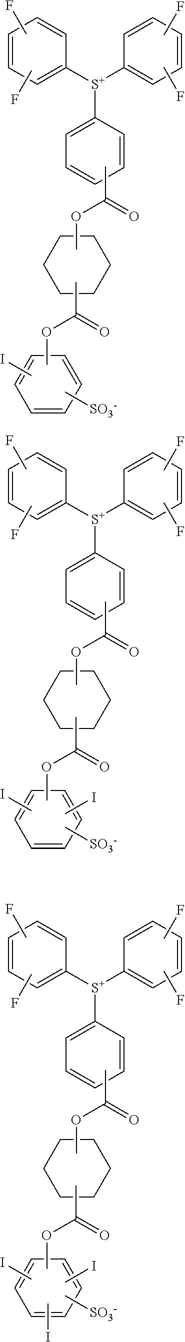

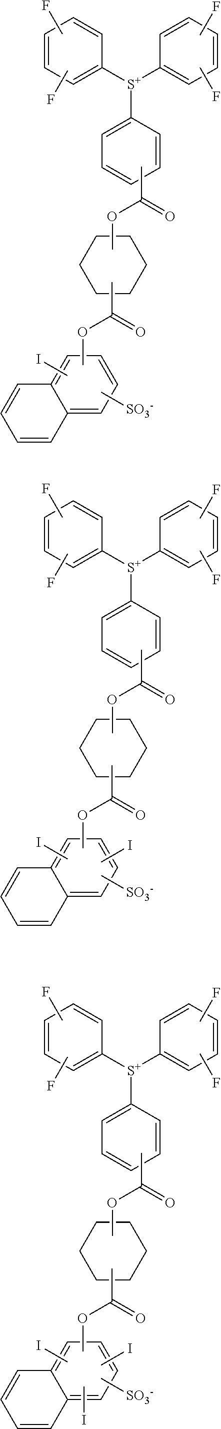

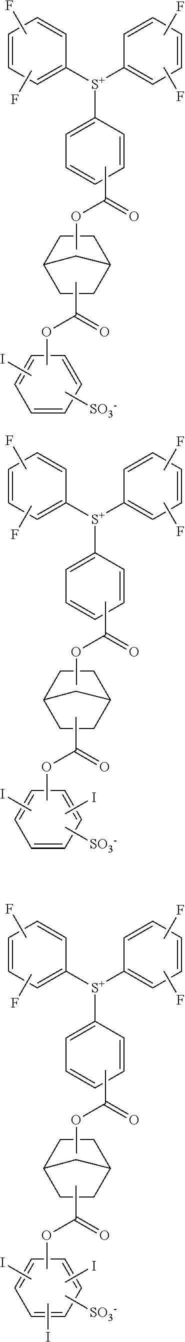

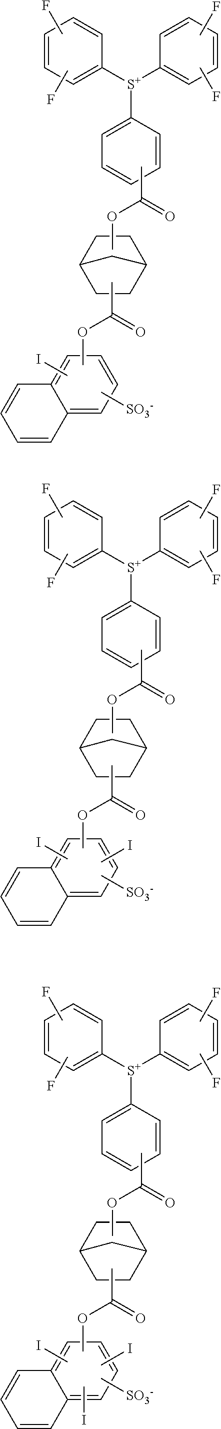

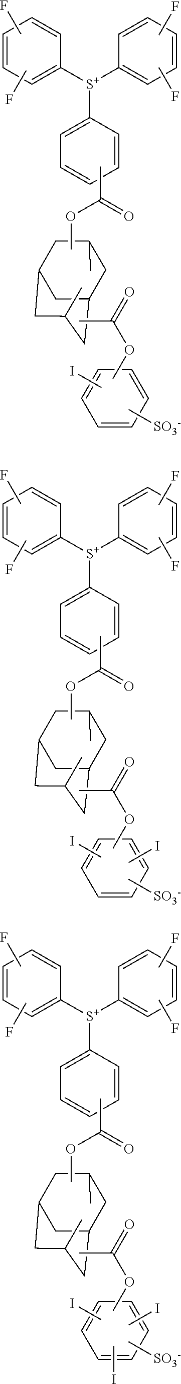

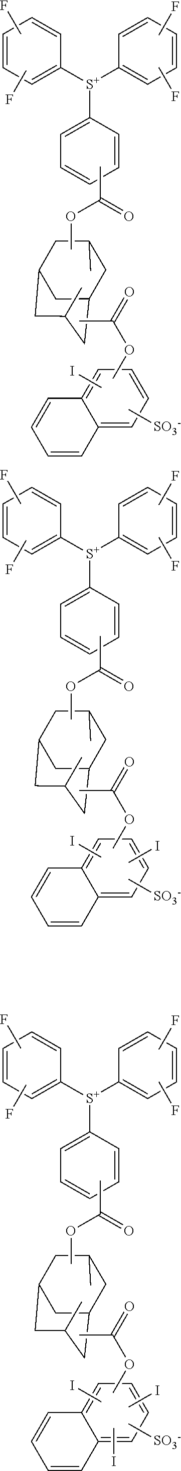

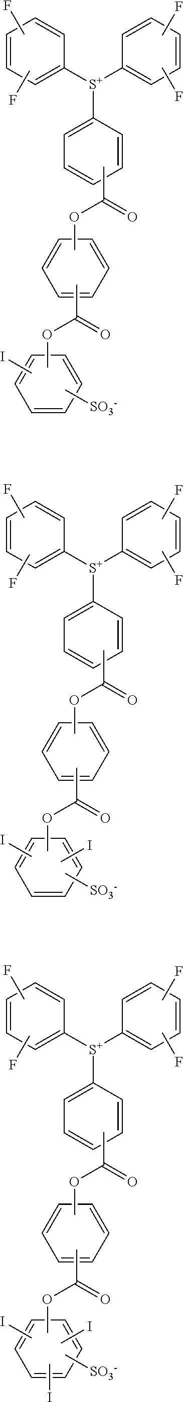

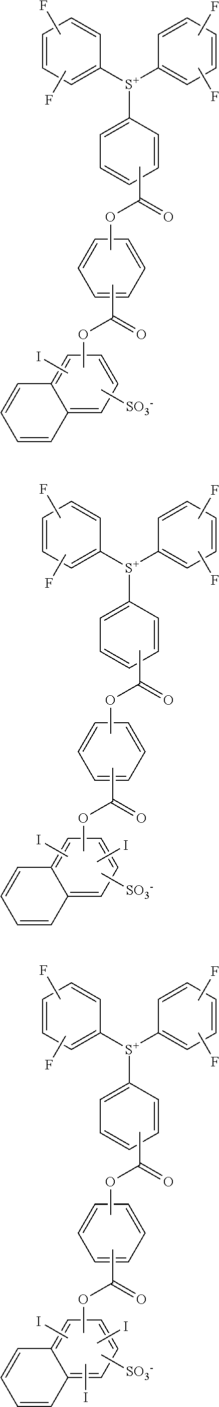

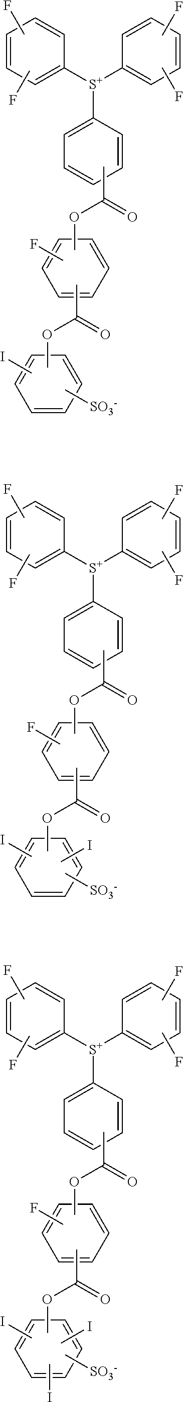

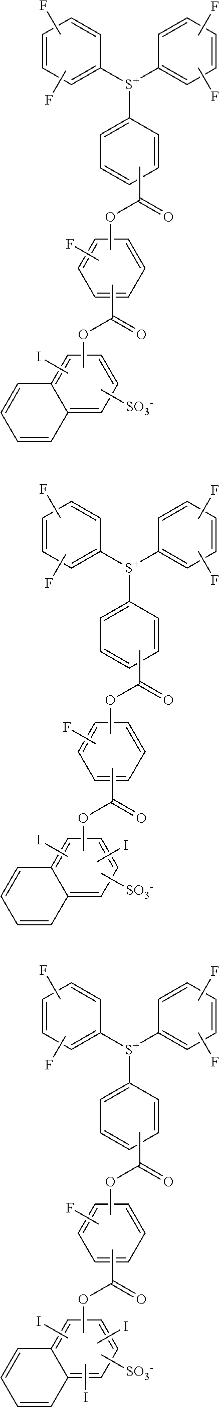

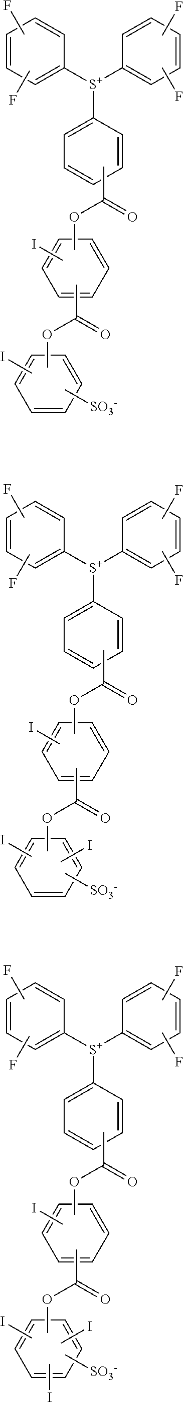

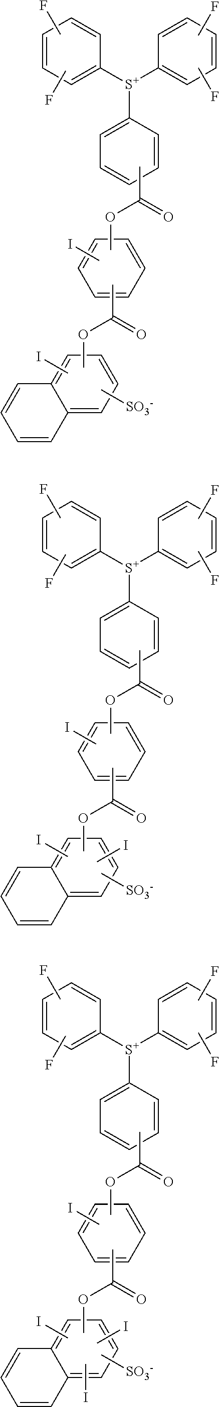

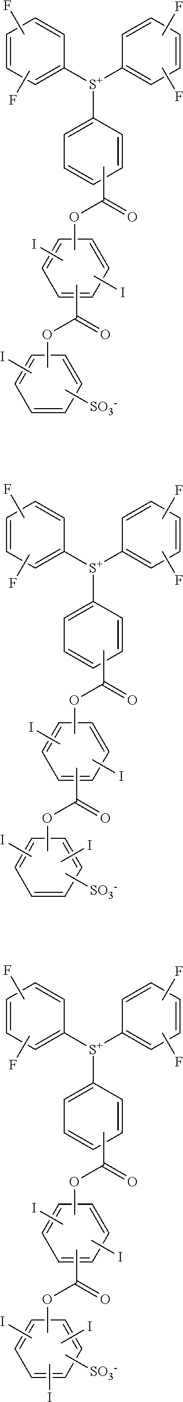

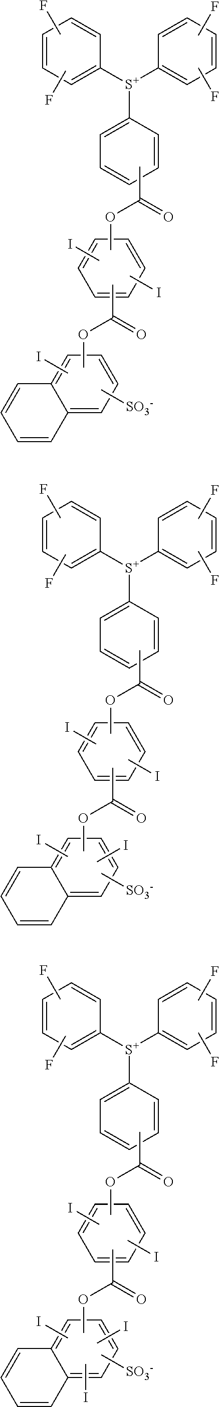

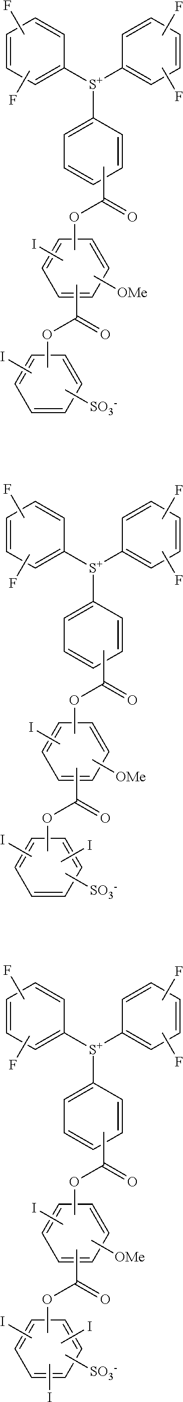

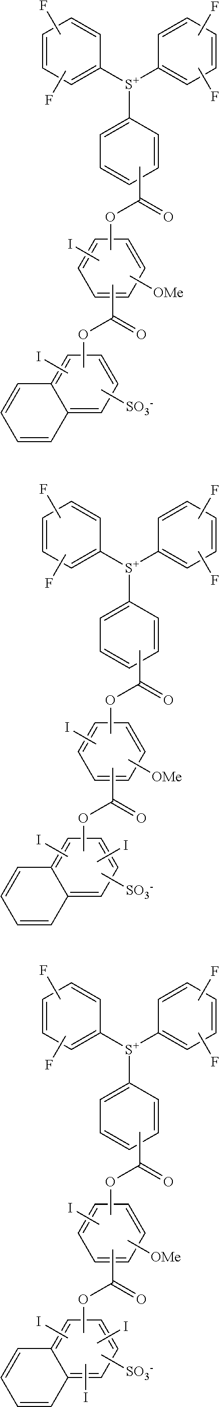

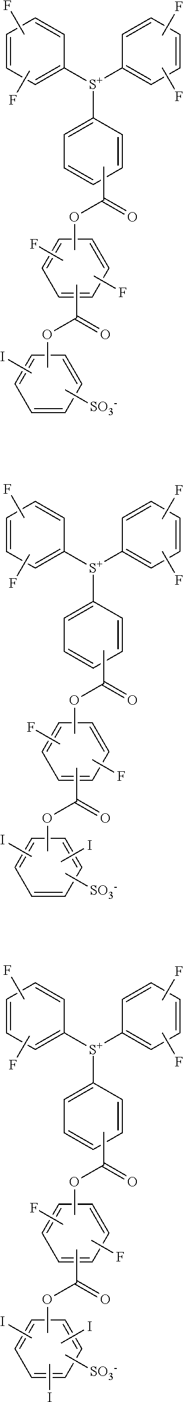

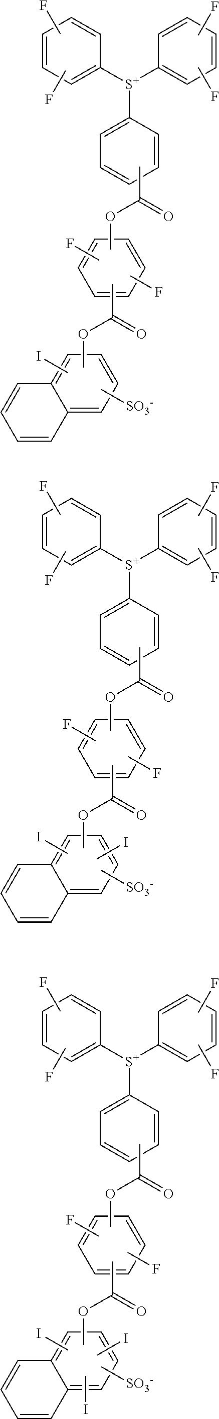

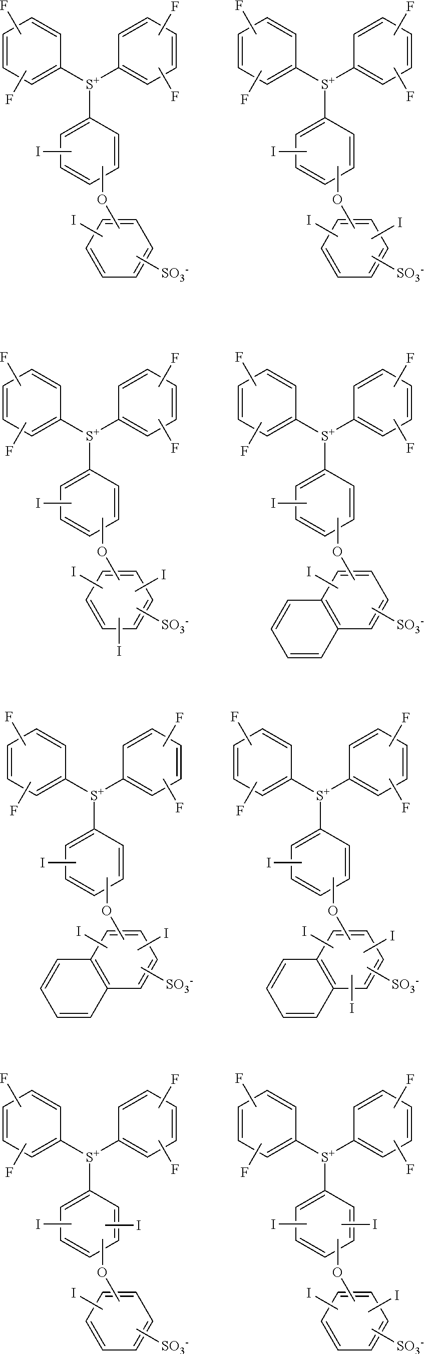

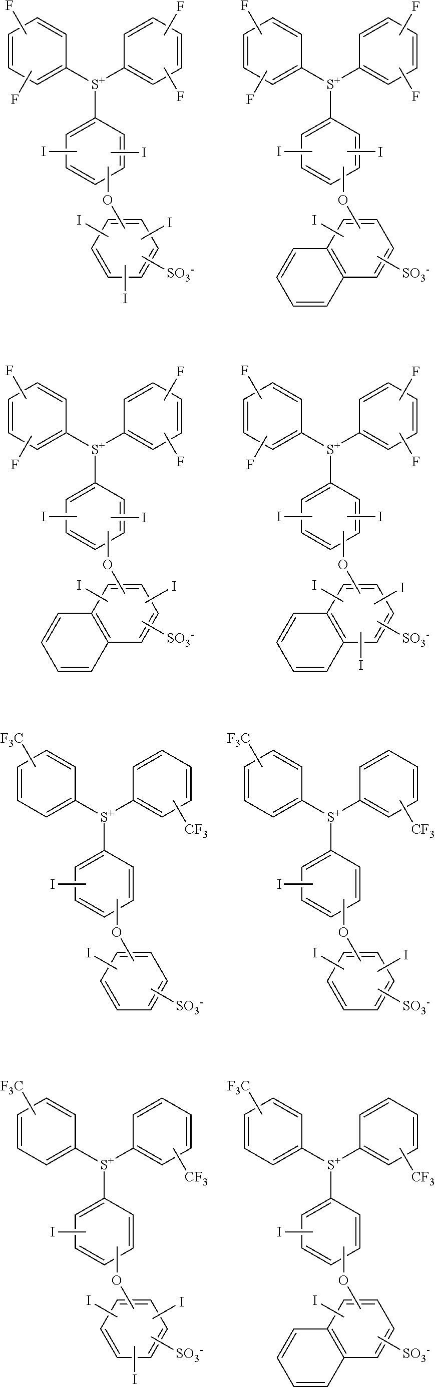

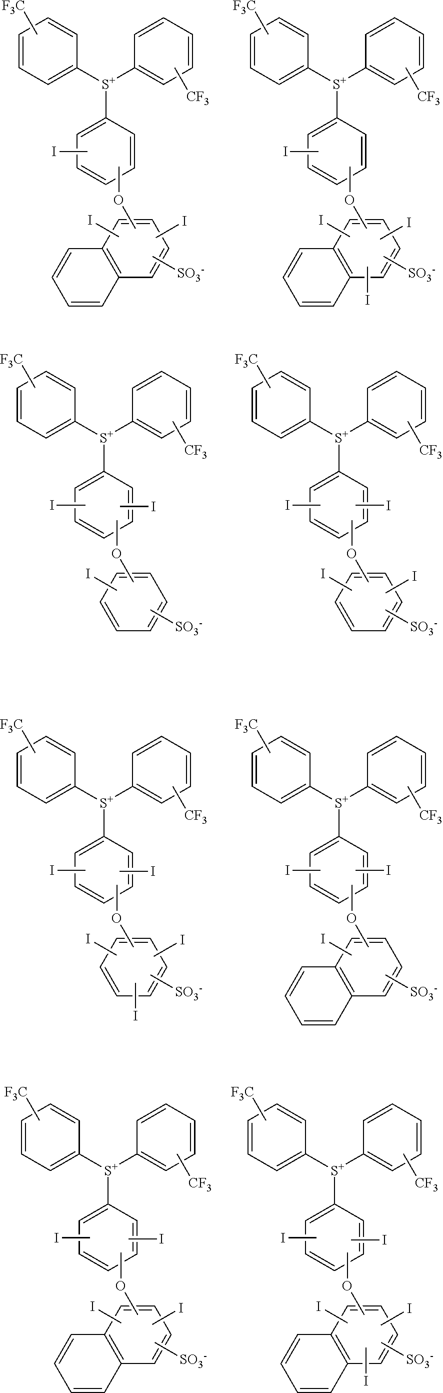

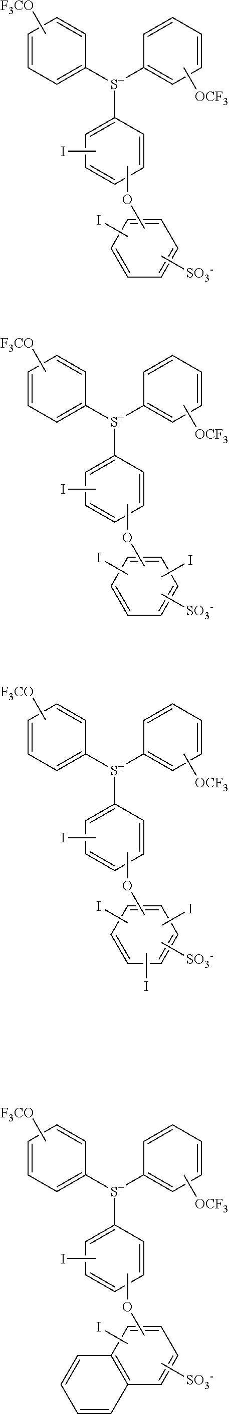

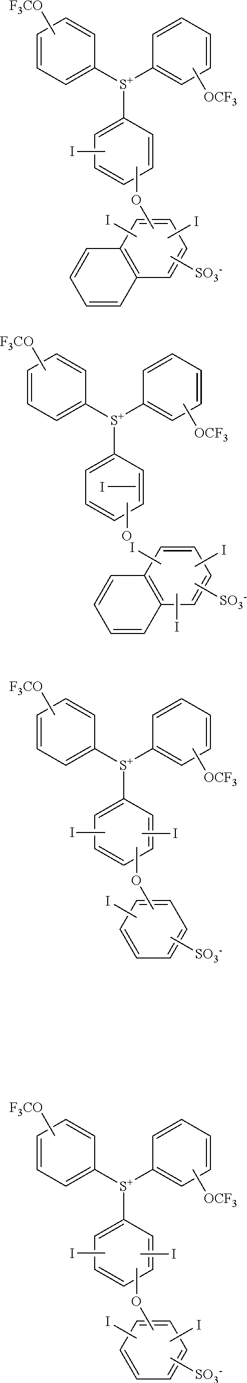

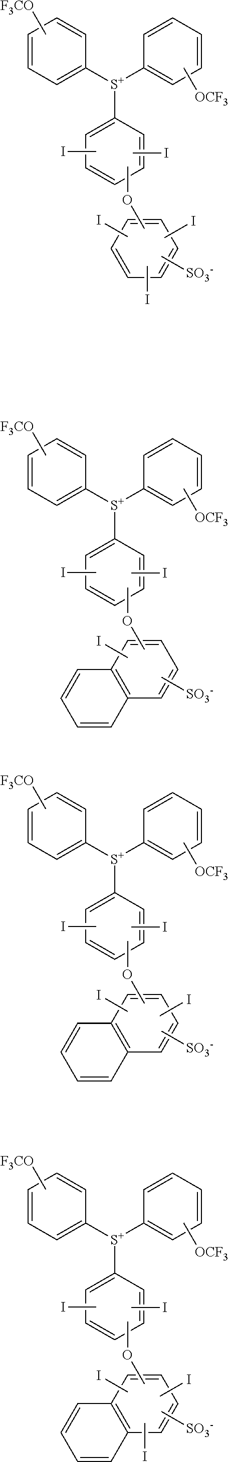

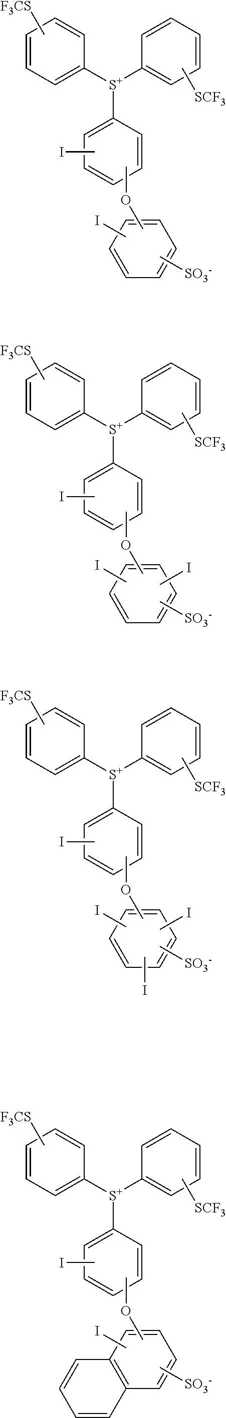

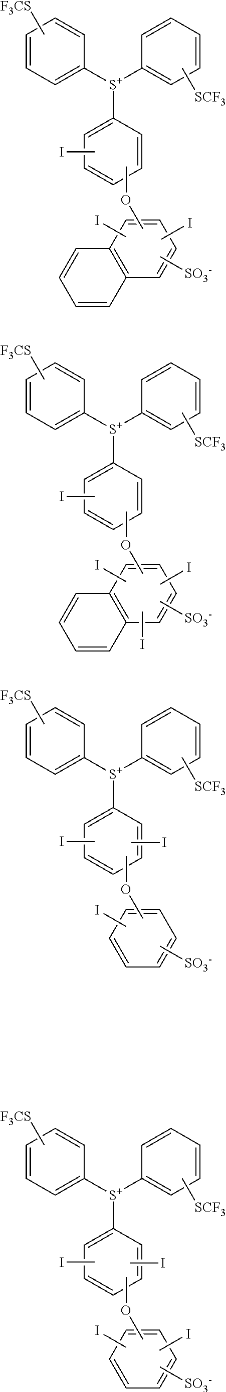

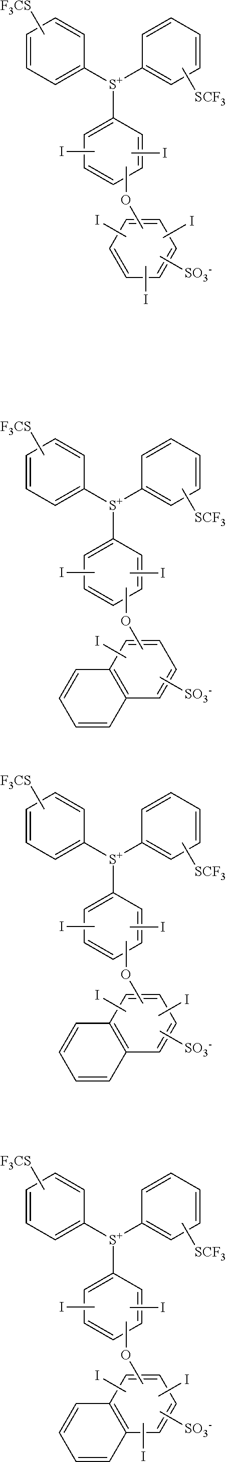

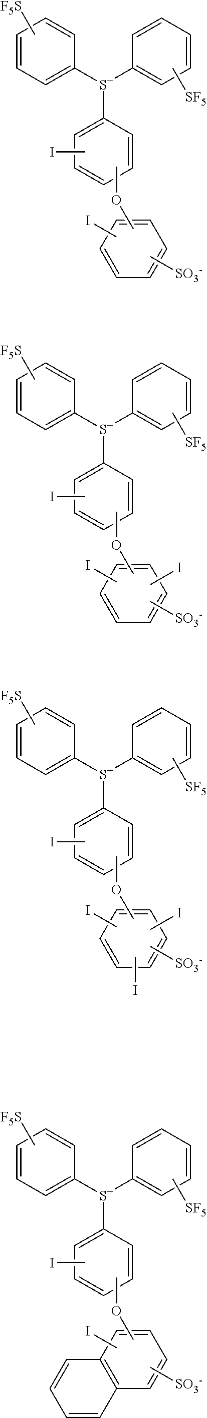

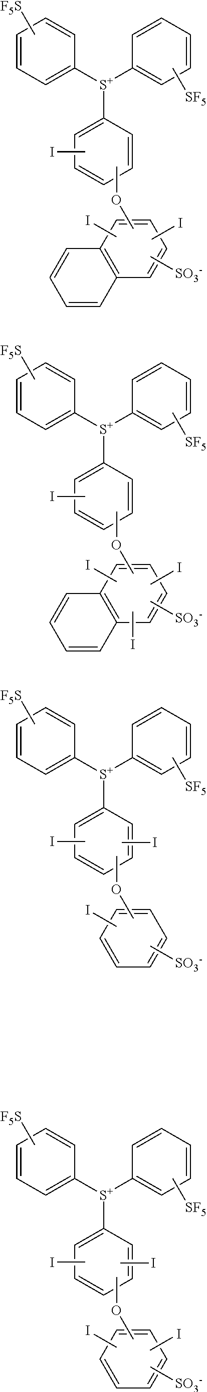

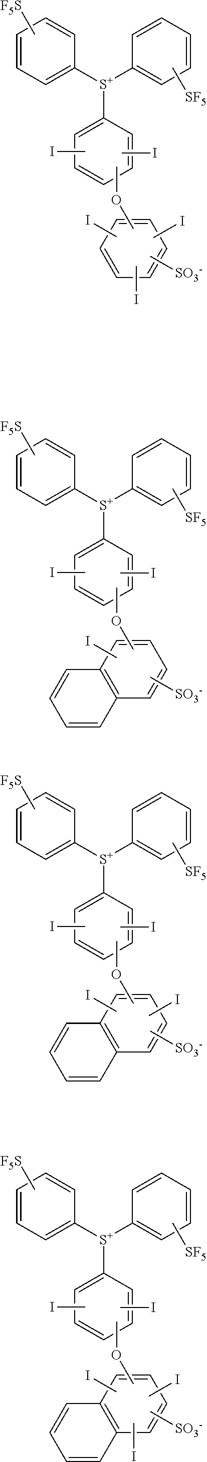

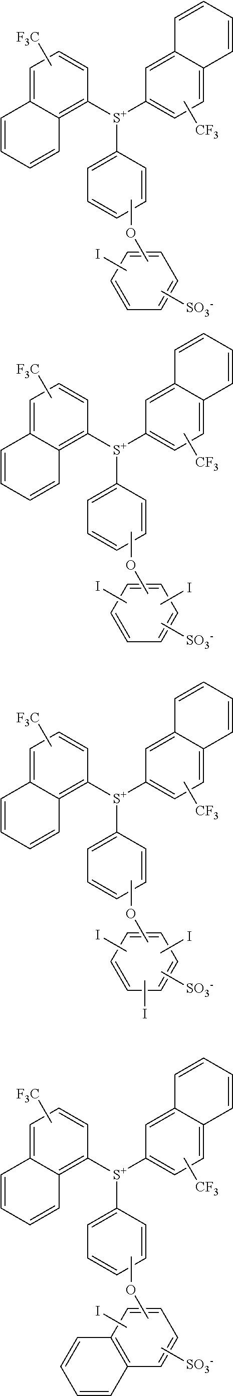

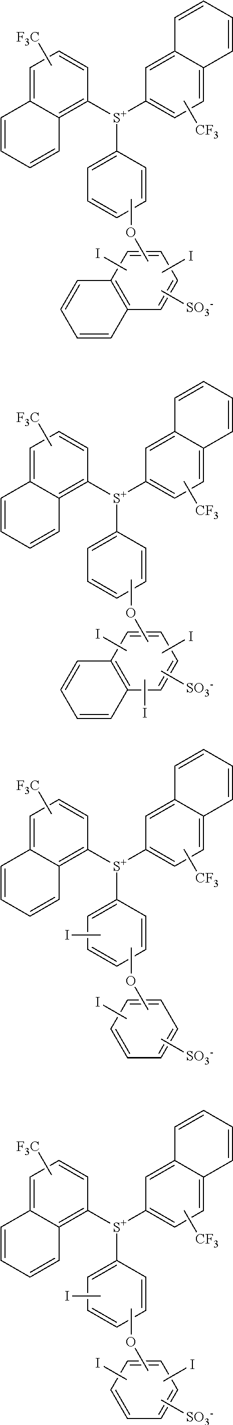

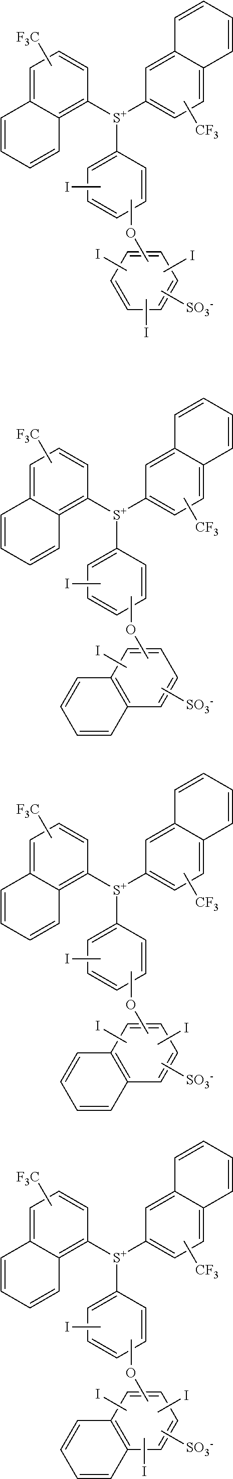

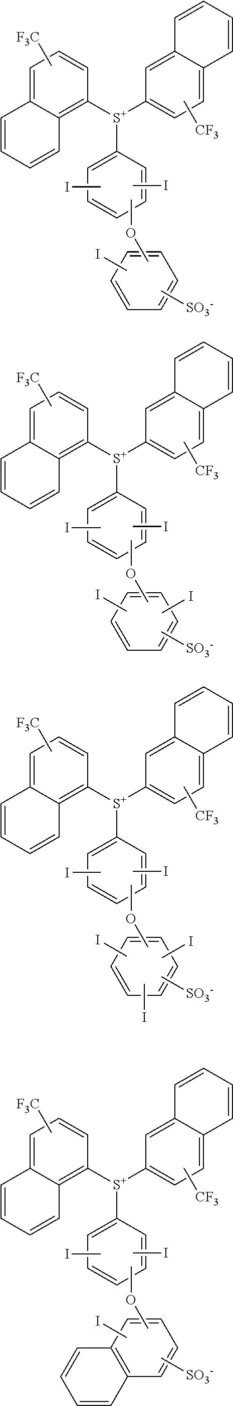

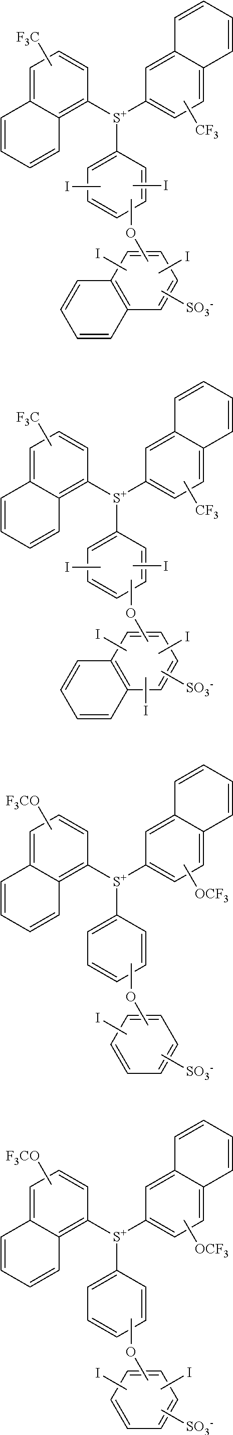

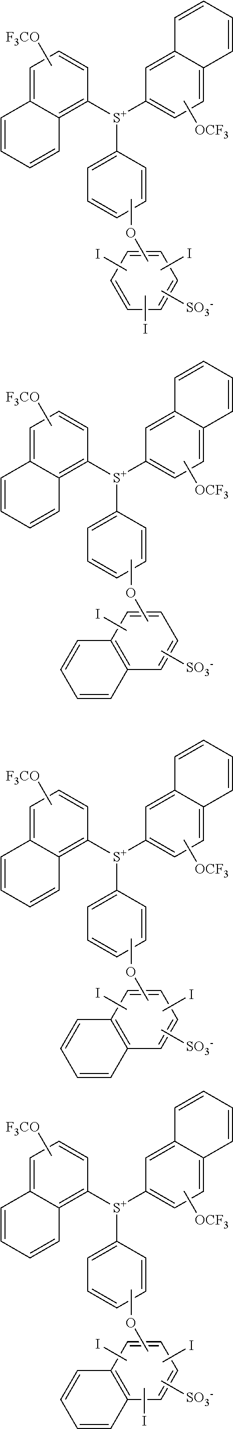

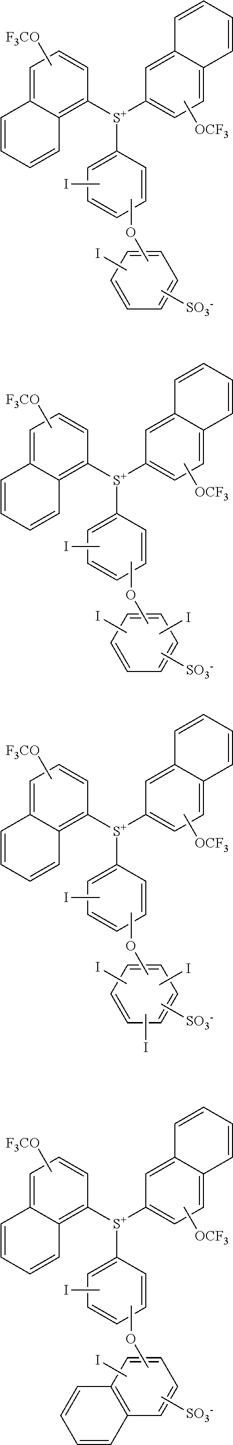

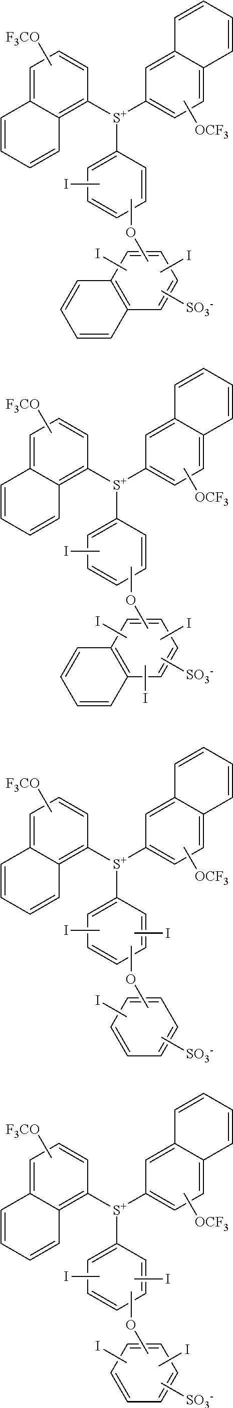

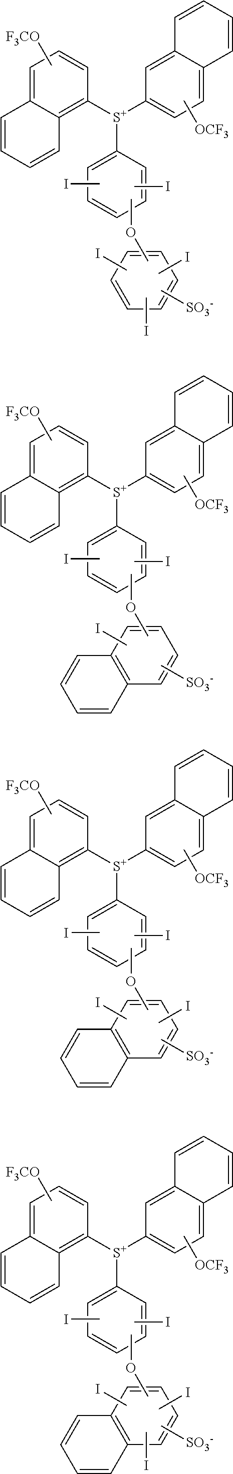

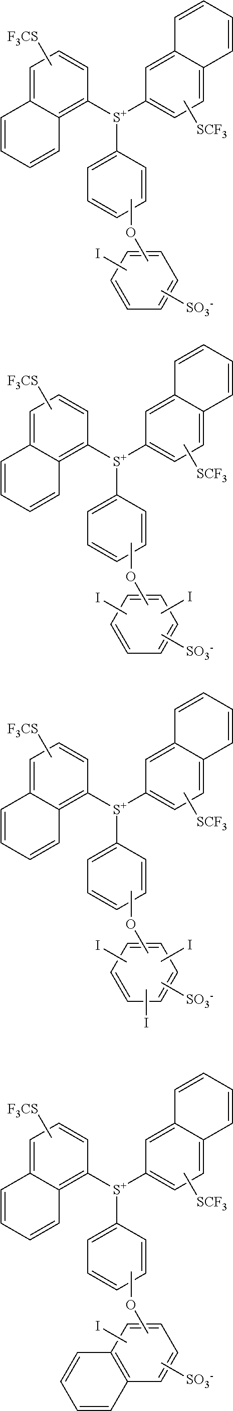

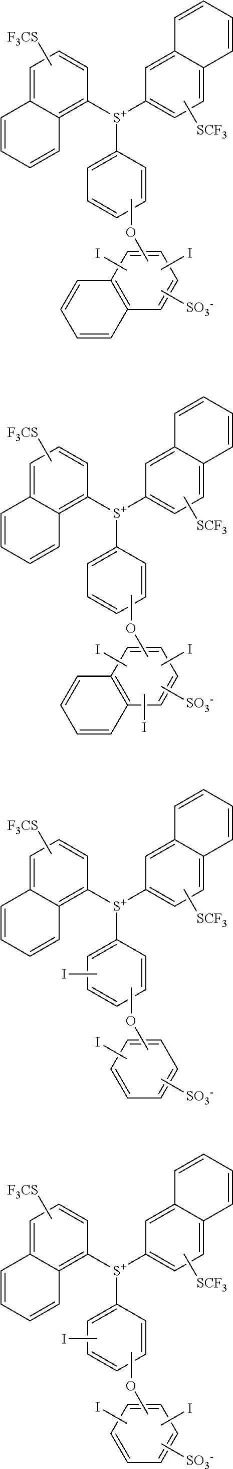

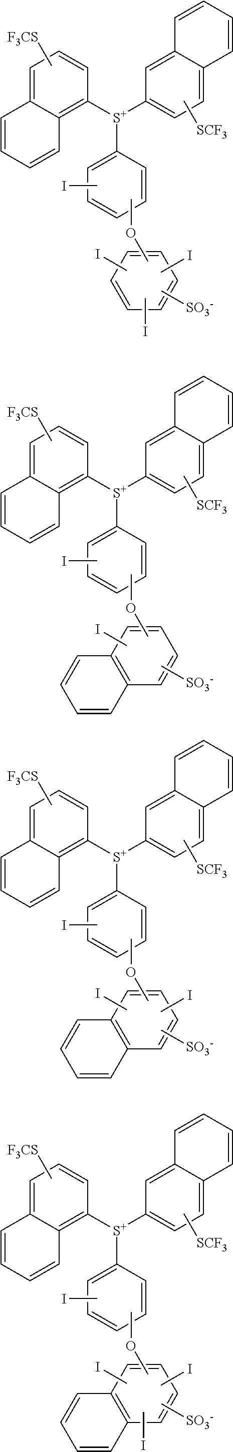

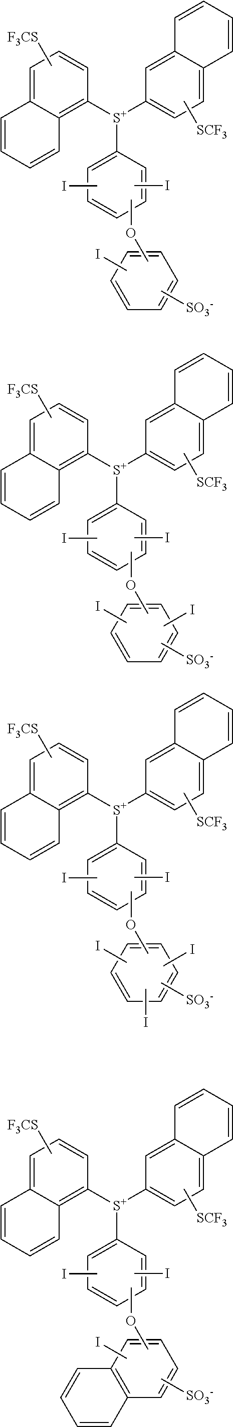

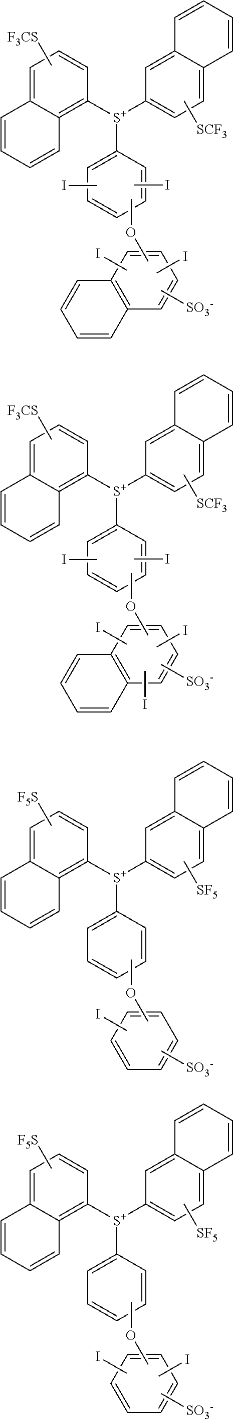

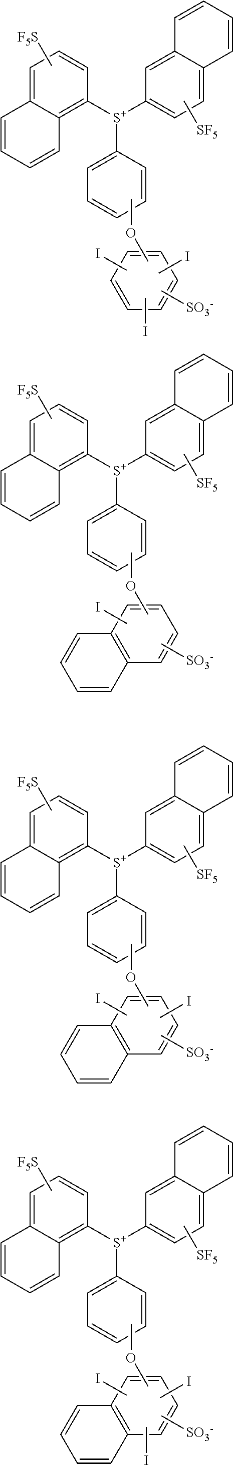

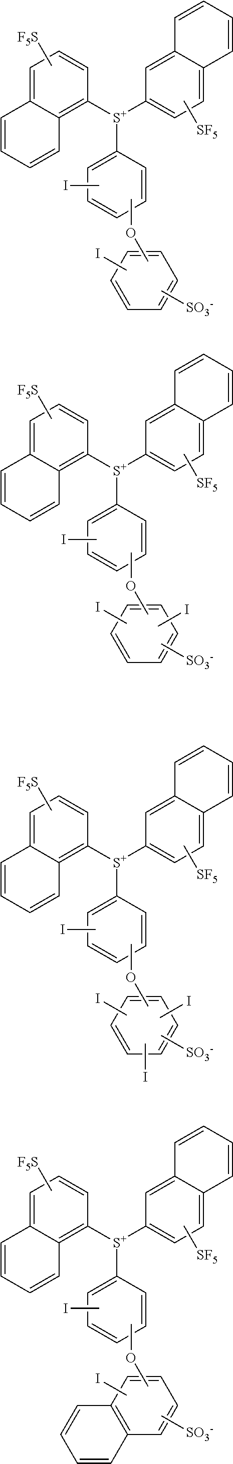

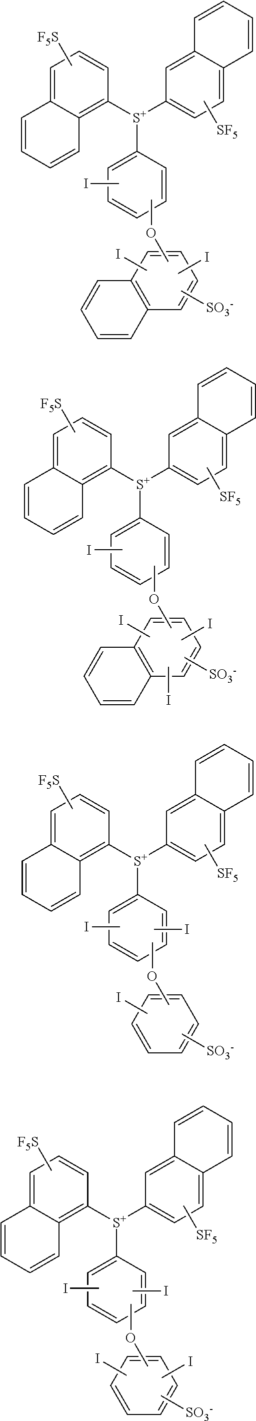

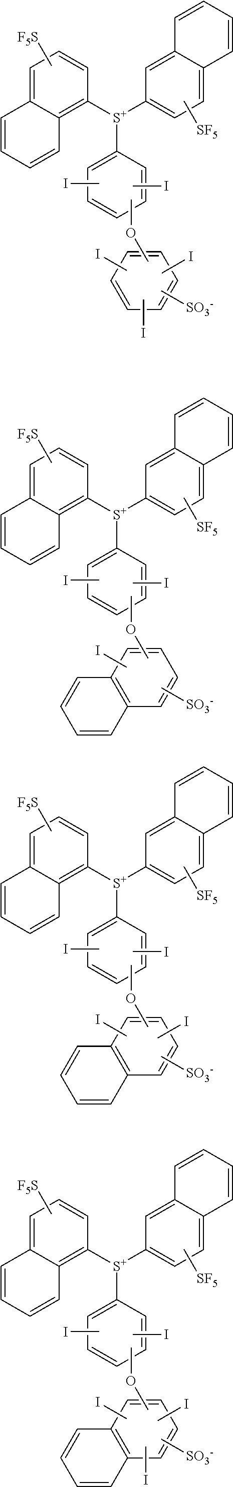

The onium salt of the invention can be synthesized by a known method. Specifically, the onium salt can be synthesized using the corresponding aromatic sulfonic acid anion by the method described in JP 6237428, [0084] to [0088]. The above production method is merely an example, and the method for producing the onium salt of the invention is not limited thereto.

Examples of the structural characteristics of the onium salt of the invention include having a betaine structure in which an aromatic sulfonic acid anion site having an aromatic ring substituted with iodine and a sulfonium cation site are bonded via a linking group. The iodine atom is an element having a large molecular weight and thus can be used as a group that suppresses acid diffusion. In particular, in EUV lithography having a wavelength of 13.5 nm, the iodine atom has very large absorption of EUV, so that secondary electrons are generated from the iodine atom during exposure. Furthermore, since the iodine atom has appropriate electron withdrawing properties, the acidity of generated acid is improved to promote the deprotection reaction of the base polymer. Moreover, in the case of having fluorine or fluorine-containing substituent on the aromatic ring bonded to S⁺ in the sulfonium cation, the solvent solubility of the onium salt itself is enhanced, and the LUMO in frontier molecular orbital theory of the sulfonium cation site is lowered due to the electron withdrawing effect, so that electrons are easily received. Since the onium salt molecule has an iodine atom, a spatial distance between the sulfonium cation site and the iodine atom is short, and the generated secondary electron is received by LUMO, whereby the cation site is efficiently decomposed, and an acid is efficiently generated. In addition, since the onium salt of the invention has a betaine structure, it is expected that the onium salts are brought close to each other by electrostatic interaction and have a structure in which the molecular weight is doubled in a pseudo manner. As a result, excessive acid diffusion of the generated acid is suppressed. By a synergistic effect of them, a resist composition containing the onium salt of the invention has good solvent solubility, and has high sensitivity and low acid diffusibility, so that the resist composition has excellent LWR of a line pattern and CDU of a hole pattern, and can form a pattern resistant to pattern collapse, and thus is suitable for small-size pattern formation.

### Photoacid Generator

The onium salt can be suitably used as a photoacid generator.

### Chemically Amplified Resist Composition

The chemically amplified resist composition of the invention contains (A) a photoacid generator comprising the onium salt having formula (1).

In the chemically amplified resist composition of the invention, the amount of the photoacid generator comprising the onium salt having formula (1) (A), is preferably 0.1 to parts by weight, more preferably 0.5 to 30 parts by weight per 80 parts by weight of a base polymer to be described just below. As long as the amount of the component (A) is in the range, good sensitivity and resolution are achievable and the risk of foreign matter being formed after development or during stripping of resist film is avoided. The photoacid generator (A) may be used alone or in combination of two or more.

### (B) Base Polymer

The chemically amplified resist composition of the invention may comprise a base polymer as component (B). Examples of the base polymer (B) include repeat units having the formula (a1), which are also referred to as repeat units (a1) or repeat units having the formula (a2), which are also referred to as repeat units (a2).

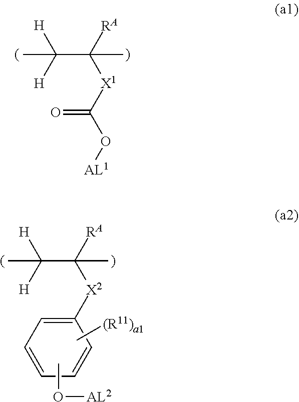

In formulae (a1) and (a2), R^{A} is each independently hydrogen, fluorine, methyl or trifluoromethyl.

In formula (a1), X¹ is a single bond, phenylene group, naphthylene group, *—C(═O)—O—X¹¹—, or *—C(═O)—NH—X¹¹—. The phenylene or naphthylene group may be substituted by a hydroxy moiety, nitro moiety, cyano moiety, optionally fluorinated C₁-C₁₀ saturated hydrocarbyl moiety, optionally fluorinated C₁-C₁₀ saturated hydrocarbyloxy moiety, or halogen. X¹¹ is a C₁-C₁₀ saturated hydrocarbylene group which may contain a hydroxy moiety, ether bond, ester bond or lactone ring, or phenylene or naphthylene group. * designates a point of attachment to the carbon atom in the backbone.

In formula (a2), X² is a single bond, *—C(═O)—O—, or *—C(═O)—NH—.
* designates a point of attachment to the carbon atom in the backbone. R¹¹ is halogen, cyano, hydroxy, nitro, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom. a1 is 0, 1, 2, 3, or 4, preferably 0 or 1.

In formulae (a1) and (a2), AL¹ and AL² are each independently an acid labile group.

Examples of the acid labile group include those described in JP-A 2013-080033 and JP-A 2013-083821.

Typical examples of the acid labile groups include those having the formulae (AL-3) to (AL-5).

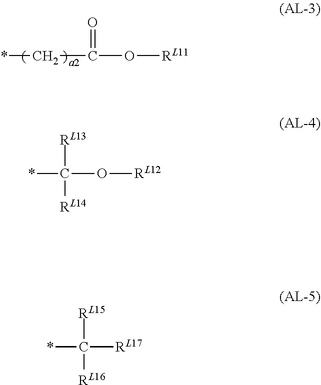

Herein * is a valence bond.

In formulae (AL-3) and (AL-4), R^{L11} and R^{L12} are each independently a C₁-C₄₀ hydrocarbyl group which may contain a heteroatom such as oxygen, sulfur, nitrogen or fluorine. The hydrocarbyl group may be saturated or unsaturated and straight, branched or cyclic. The hydrocarbyl group is preferably a C₁-C₂₀ hydrocarbyl group.

In formula (AL-3), a2 is an integer of 0 to 10, preferably 1, 2, 3, 4, or 5.

In formula (AL-4), R^{L13} and R^{L14} are each independently hydrogen or a C₁-C₂₀ hydrocarbyl group which may contain a heteroatom such as oxygen, sulfur, nitrogen or fluorine. The hydrocarbyl group may be saturated or unsaturated and straight, branched or cyclic. The hydrocarbyl group is preferably a C₁-C₂₀ hydrocarbyl group. Any two of R^{L12}, R^{L13}, and R^{L14} may bond together to form a C₃-C₂₀ ring with the carbon atom or carbon and oxygen atoms to which they are attached. The ring is preferably a C₄-C₁₆ ring, particularly preferably an alicyclic ring.

In formula (AL-5), R^{L15}, R^{L16}, and R^{L17} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. The hydrocarbyl group is preferably a C₁-C₂₀ hydrocarbyl group. Any two of R^{L15}, R^{L16}, and R^{L17} may bond together to form a C₃-C₂₀ ring with the carbon atom to which they are attached. The ring is preferably a C₄-C₁₆ ring, particularly preferably an alicyclic ring.

Examples of the repeat units (a1) are shown below, but not limited thereto. In the formulae, R^{A} and AL¹ are as defined above.

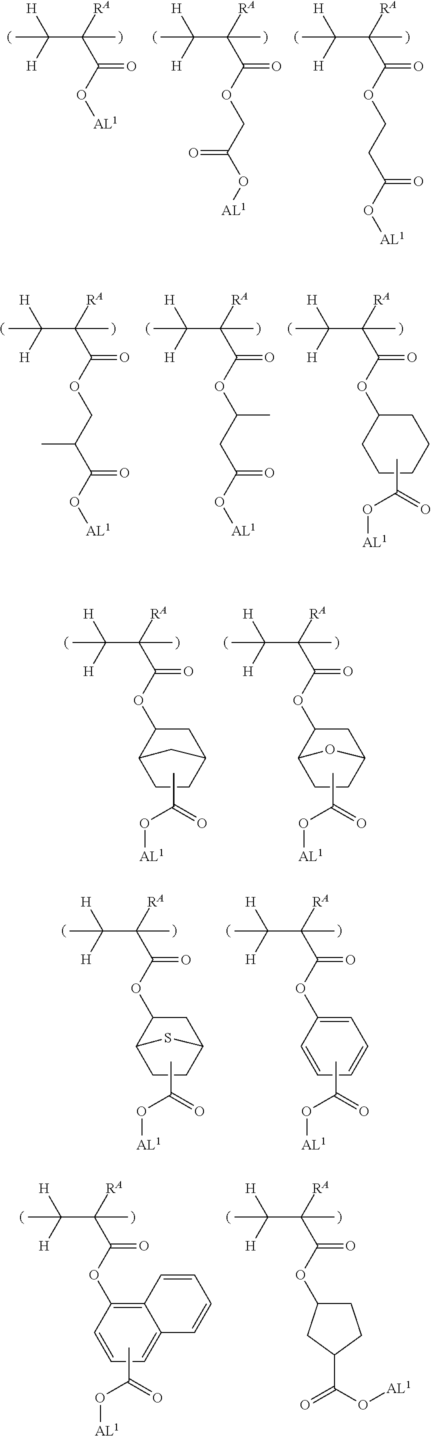

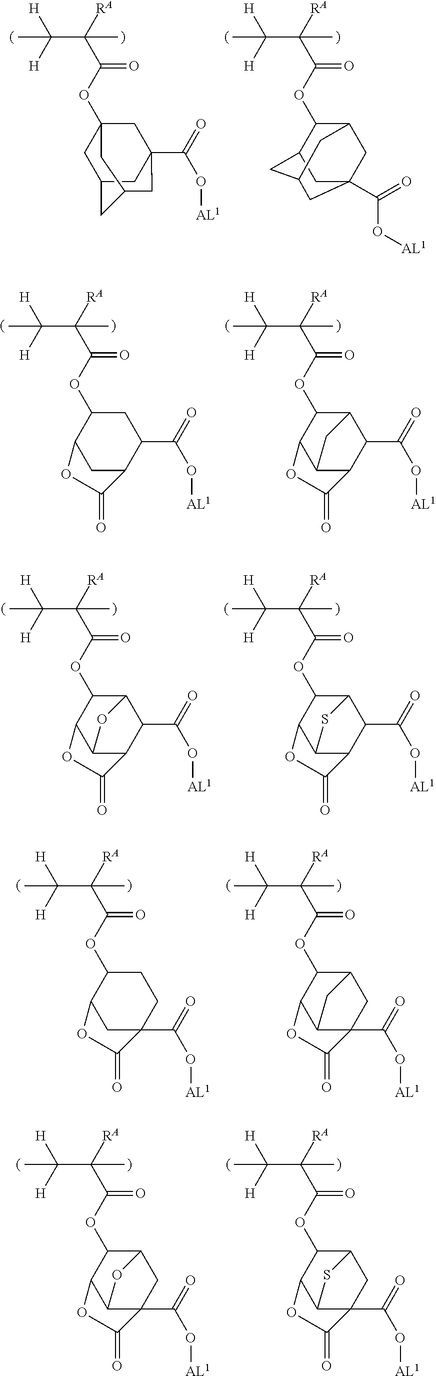

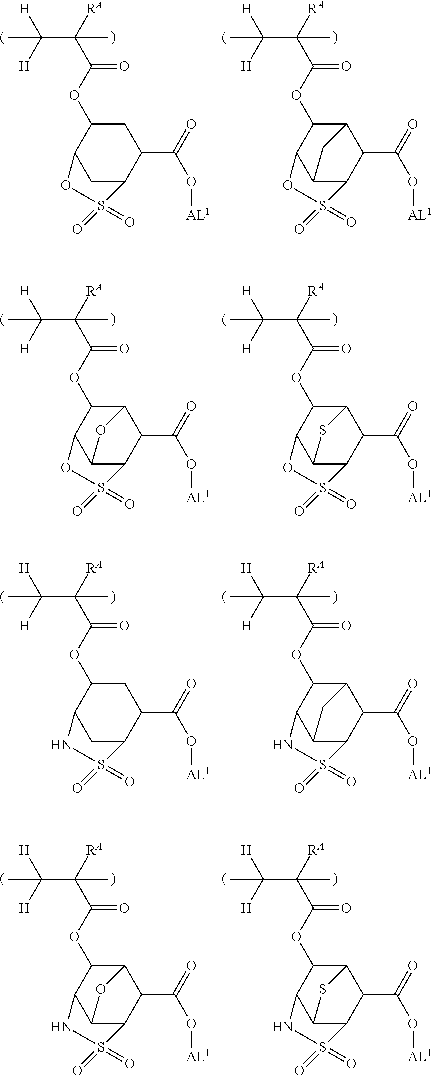

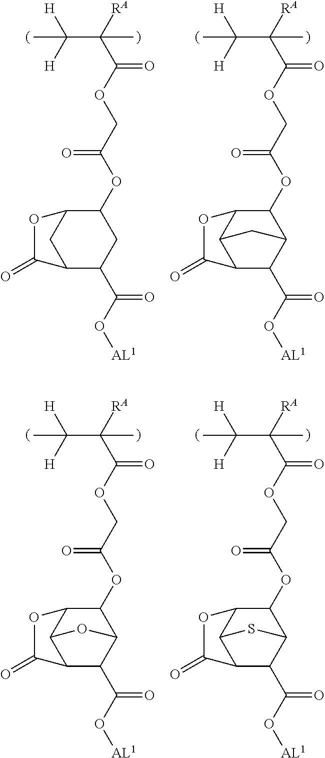

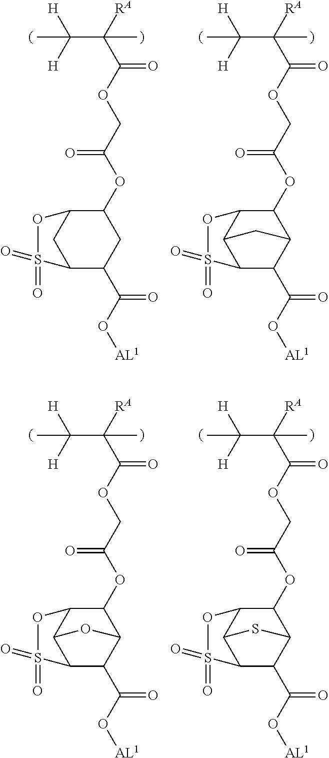

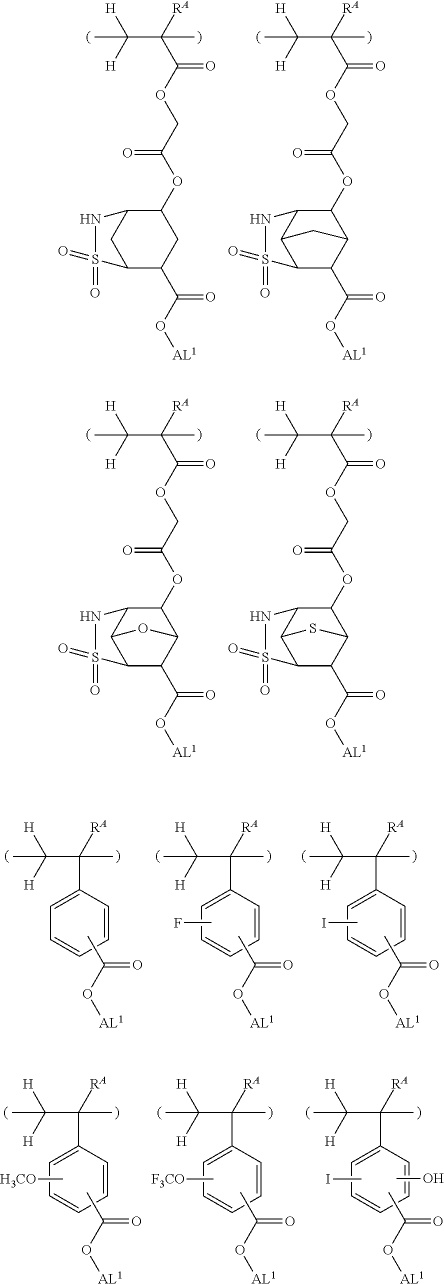

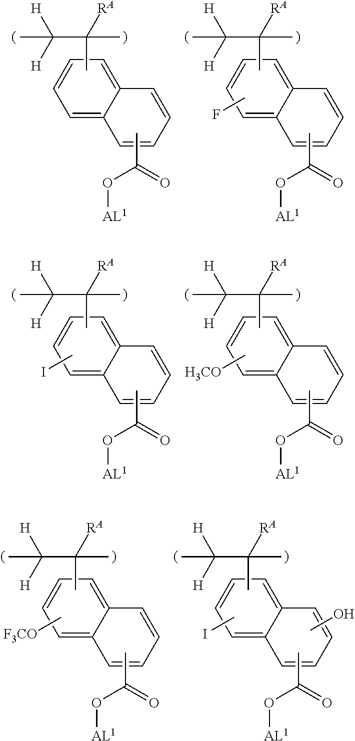

Examples of the repeat units (a2) are shown below, but not limited thereto. In the formulae, R^{A} and AL² are as defined above.

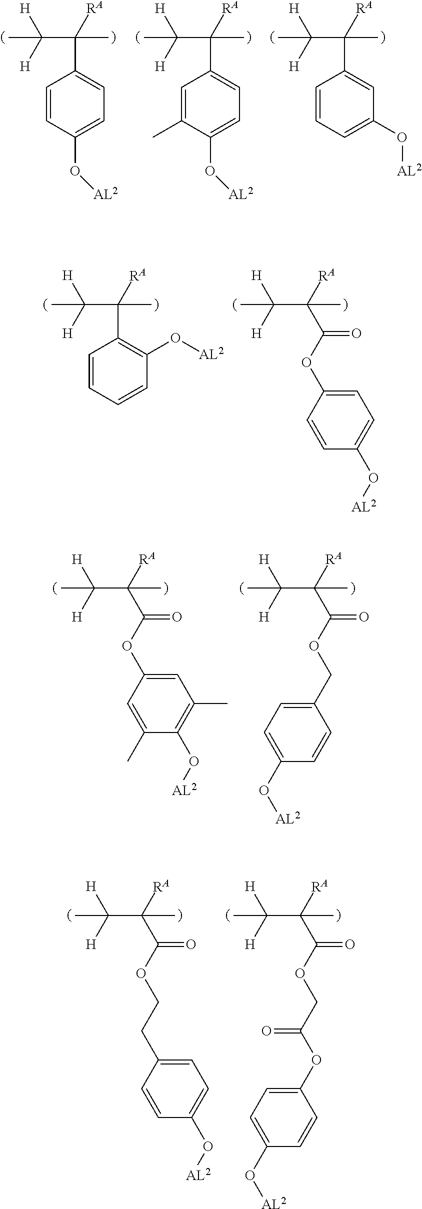

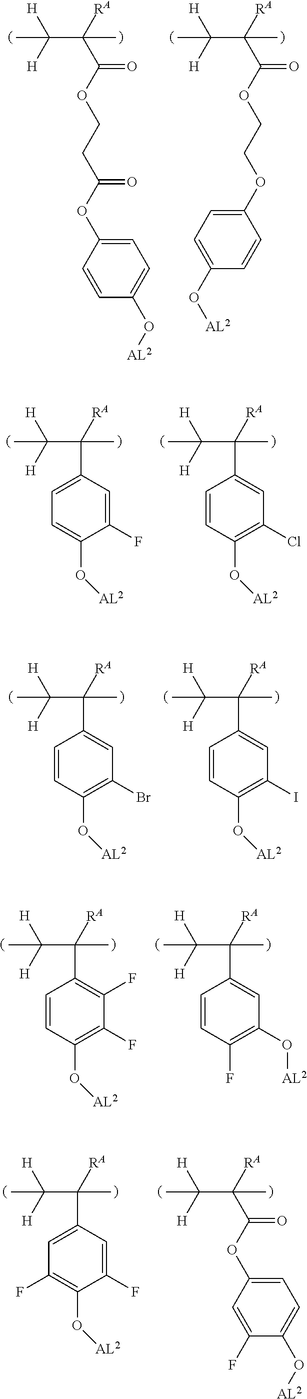

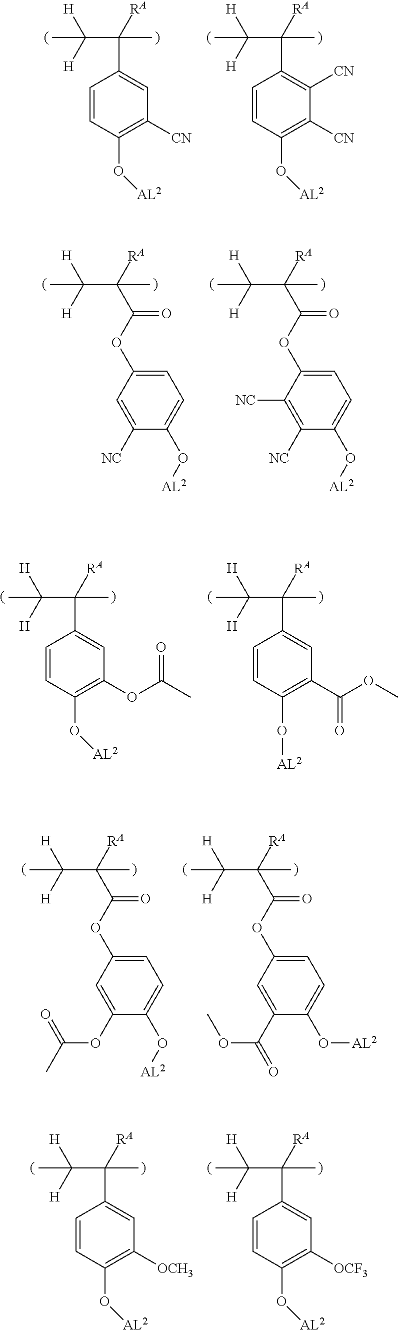

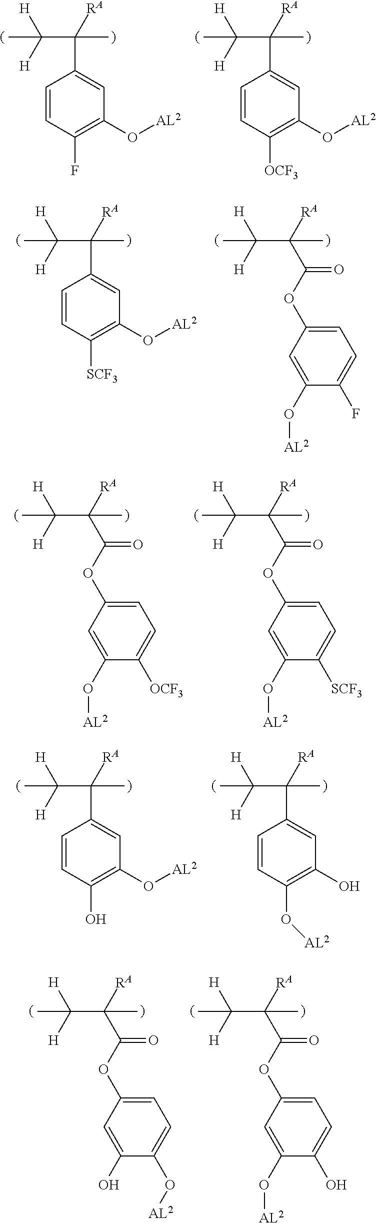

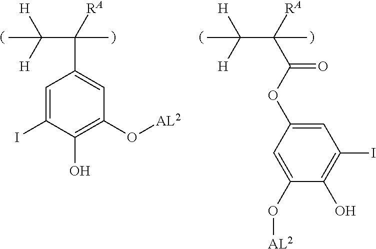

The base polymer may comprise repeat units having the formula (a3), which are also referred to as repeat units (a3).

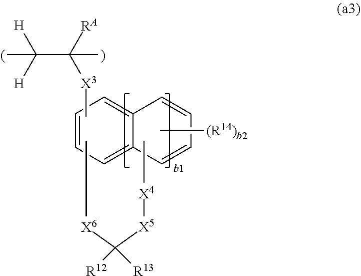

In formula (a3), b1 is 0 or 1. The relevant structure is a benzene ring in case of b1=0, and a naphthalene ring in case of b1=1. The benzene corresponding to b1=0 is preferred from the aspect of solvent solubility. b2 is 0, 1, 2, or 3 in case of b1=0, and is 0, 1, 2, 3, 4, or 5 in case of b1=1. b2 is preferably 0, 1, 2, or 3, more preferably 0, 1, or 2 from the aspect of availability of reactants.

In formula (a3), R^{A} is hydrogen, fluorine, methyl or trifluoromethyl. Among them, R^{A} is preferably hydrogen or methyl, more preferably hydrogen.

In formula (a3), X³ is a single bond, *—C(═O)—O—, or *—C(═O)—NH—. * designates a point of attachment to the carbon atom in the backbone. Among them, X³ is preferably a single bond or *—C(═O)—O—, more preferably a single bond.

In formula (a3), X⁴ is a single bond, a C₁-C₄ aliphatic hydrocarbylene group, carbonyl group, sulfonyl group, or a group obtained by combining the foregoing. Of these, X⁴ is preferably a single bond, carbonyl group or sulfonyl group from the aspect of availability of reactants, more preferably a single bond or a carbonyl group from the aspect of a polar group created after reaction.

In formula (a3), X⁵ and X⁶ are each independently oxygen or sulfur. Notably, X⁴ and X⁶ are bonded to vicinal carbon atoms on the aromatic ring. X⁵ and X⁶ may be identical or different. Both X⁵ and X⁶ are preferably oxygen from the aspect of reactivity.

In formula (a3), R¹² and R¹³ are each independently hydrogen or a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl, and icosyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, 1-propenyl, 2-propenyl, butenyl, and hexenyl; C₃-C₂₀ cyclic unsaturated hydrocarbyl groups such as cyclohexenyl; C₆-C₂₀ aryl groups such as phenyl and naphthyl; C₇-C₂₀ aralkyl groups such as benzyl, 1-phenylethyl, and 2-phenylethyl; and combinations thereof. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

Also, R¹² and R¹³ may bond together to form a ring with the carbon atoms to which they are attached. Examples of the ring thus formed include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

In formula (a3), R¹⁴ is halogen, hydroxy, cyano, nitro, a C₁-C₂₀ hydrocarbyl group which may contain a heteroatom, a C₁-C₂₀ hydrocarbyloxy group which may contain a heteroatom, a C₂-C₂₀ hydrocarbyloxycarbonyl group which may contain a heteroatom, a C₁-C₂₀ hydrocarbylthio group which may contain a heteroatom, or —N(R^{14A})(R^{14B}) R^{14A} and R^{14B} are each independently hydrogen or a C₁-C₆ hydrocarbyl group. The halogen atom is preferably fluorine, chlorine, bromine or iodine, more preferably fluorine or iodine. The hydrocarbyl group and hydrocarbyl moiety in the hydrocarbyloxy, hydrocarbyloxycarbonyl and hydrocarbylthio groups may be saturated or unsaturated and straight, branched or cyclic. Examples thereof are as exemplified above for the hydrocarbyl groups represented by R¹² and R¹³. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety. A plurality of R¹⁴ may be identical or different when b2 is 2 or more.

Also, when b2 is 2 or more, a plurality of R¹⁴ may bond together to form a ring with the carbon atom of the aromatic ring to which they are attached. Examples of the ring thus formed include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

Examples of the repeat units (a3) are shown below, but not limited thereto. In the formulae, R^{A} is as defined above, and Me is methyl. The bond positions of substituents on the aromatic ring are interchangeable.

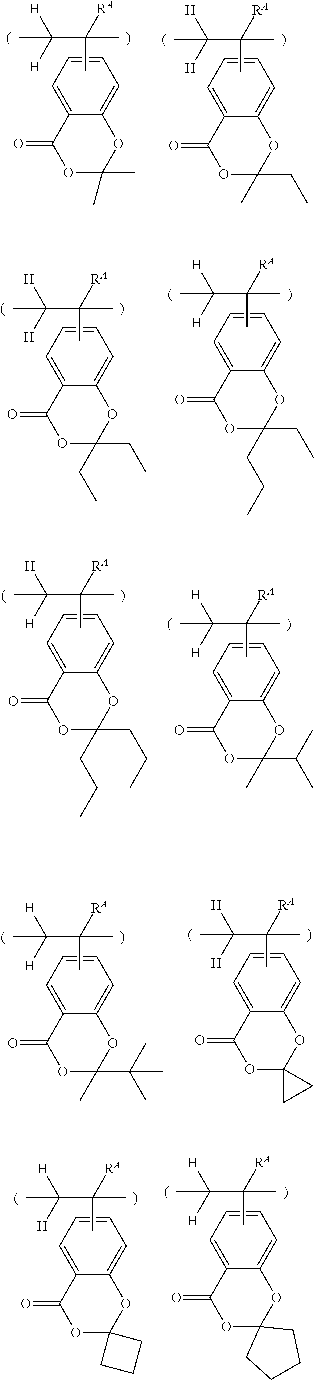

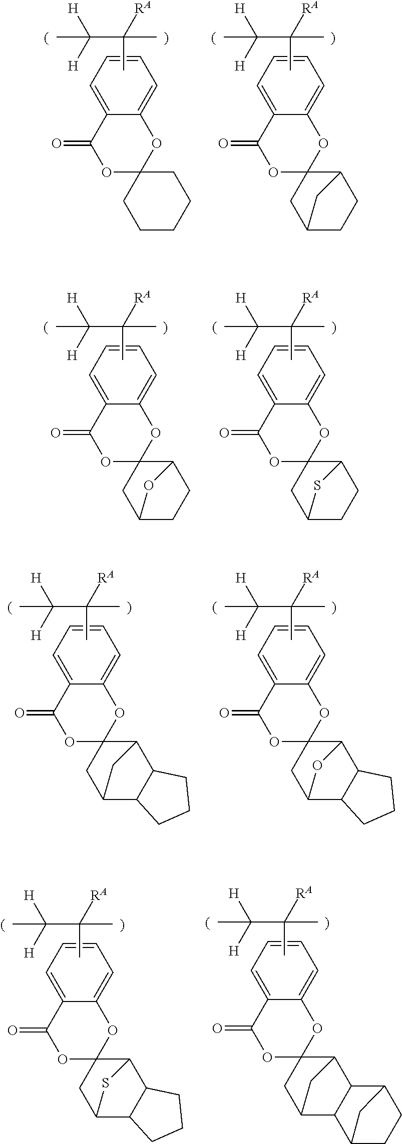

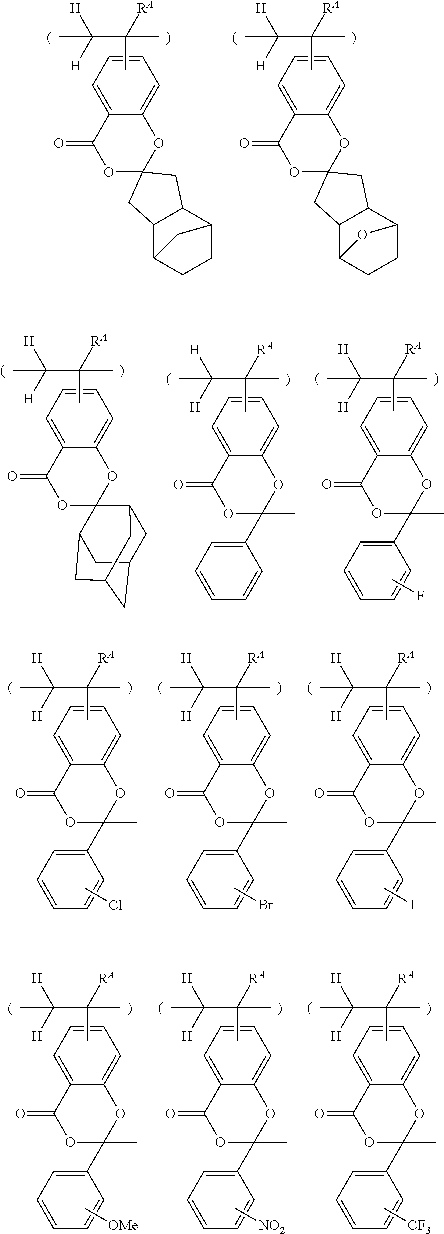

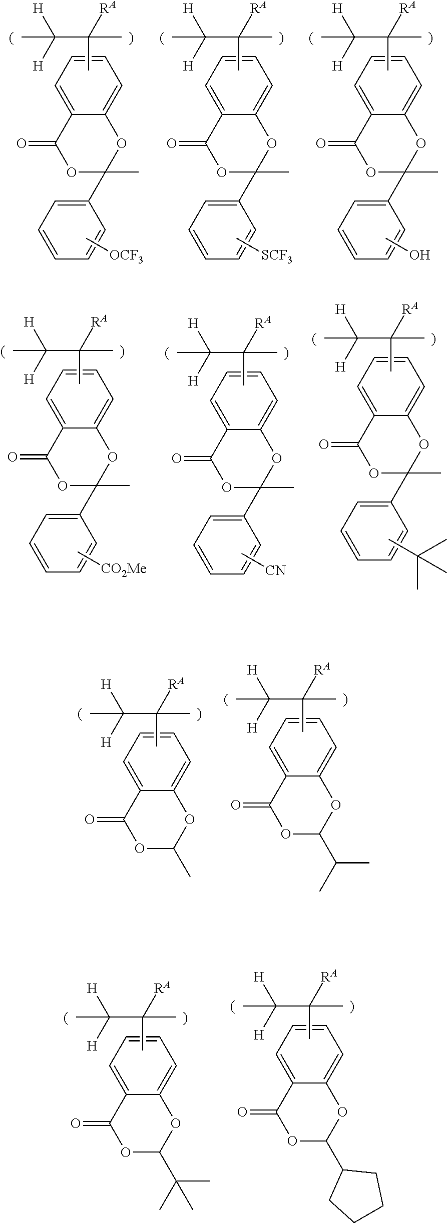

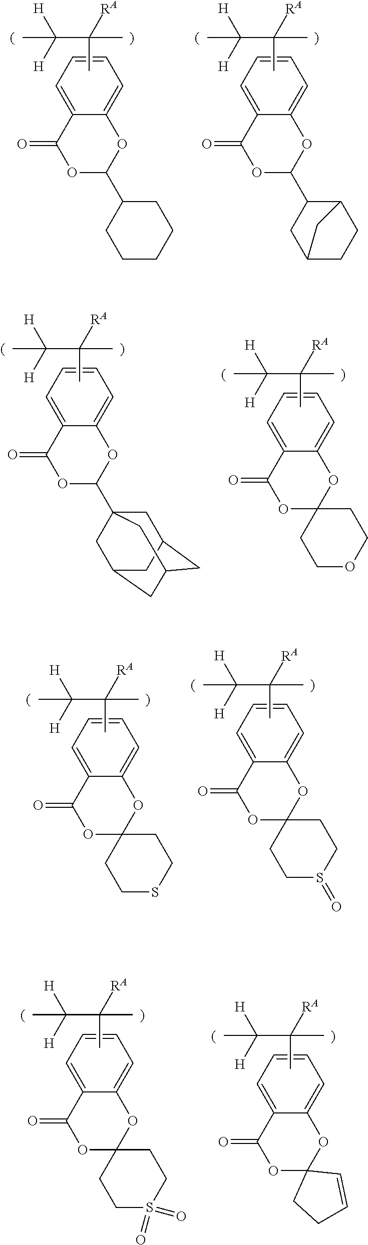

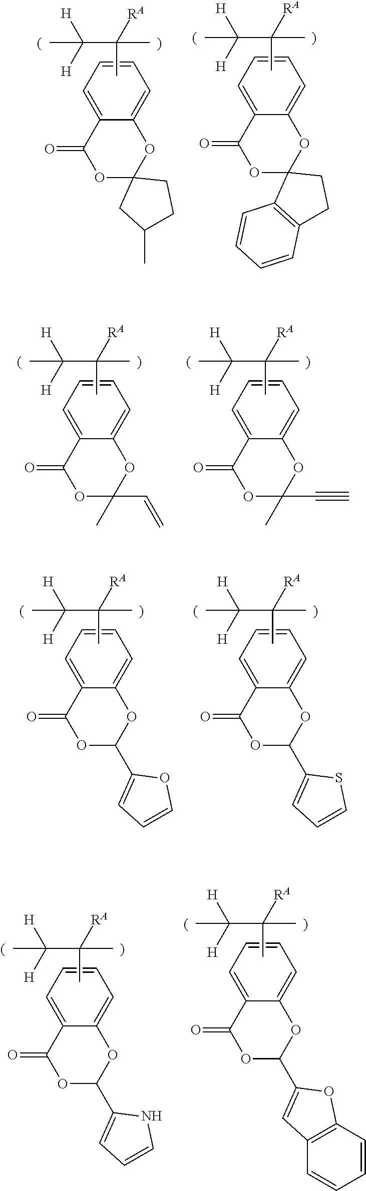

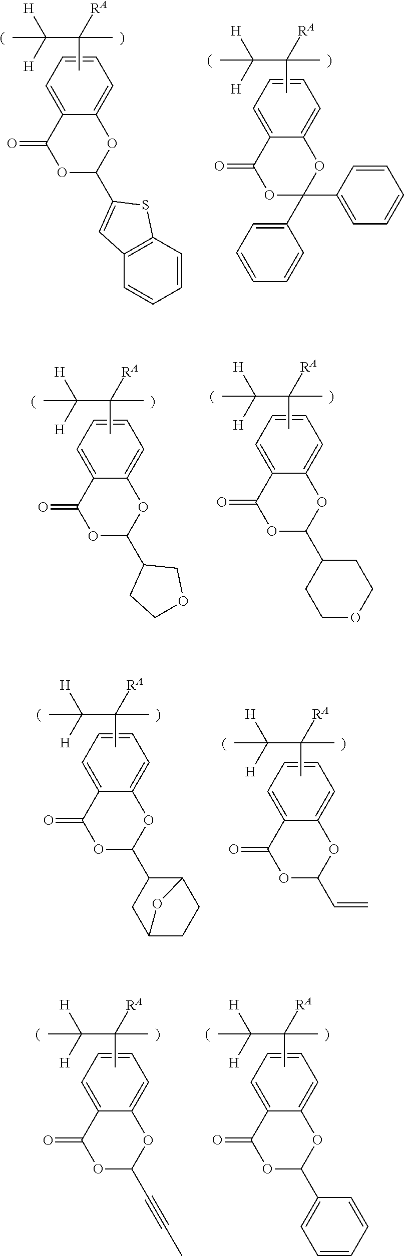

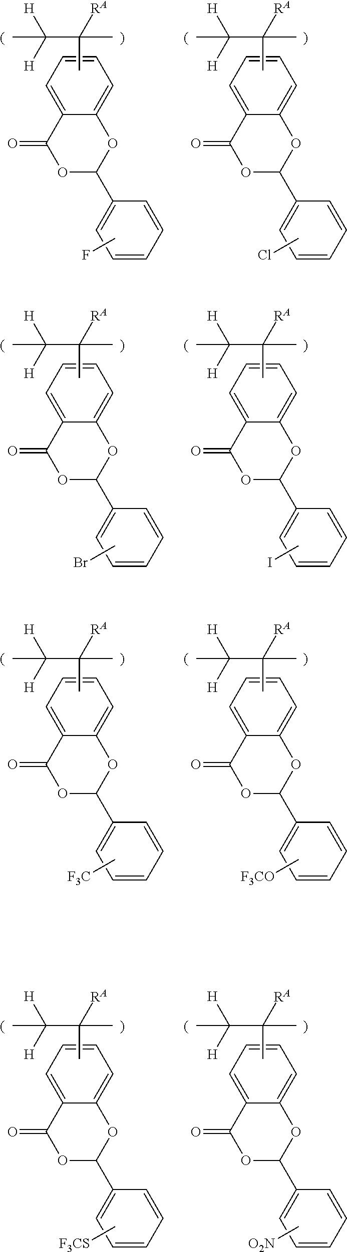

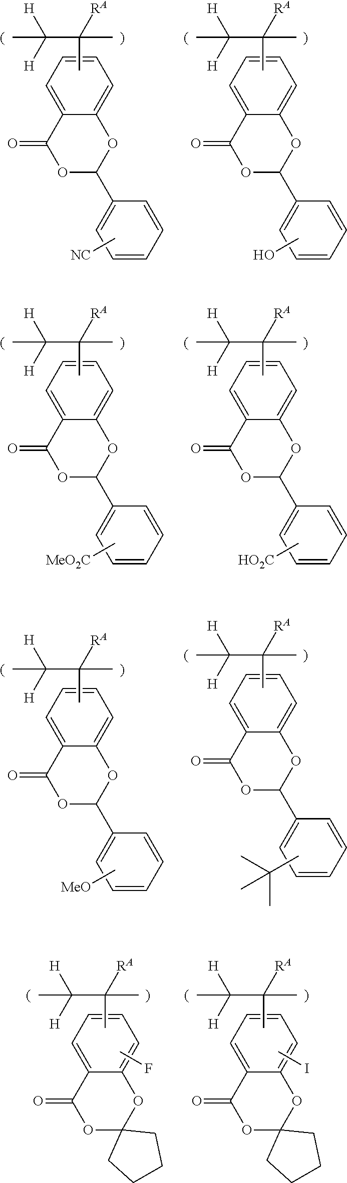

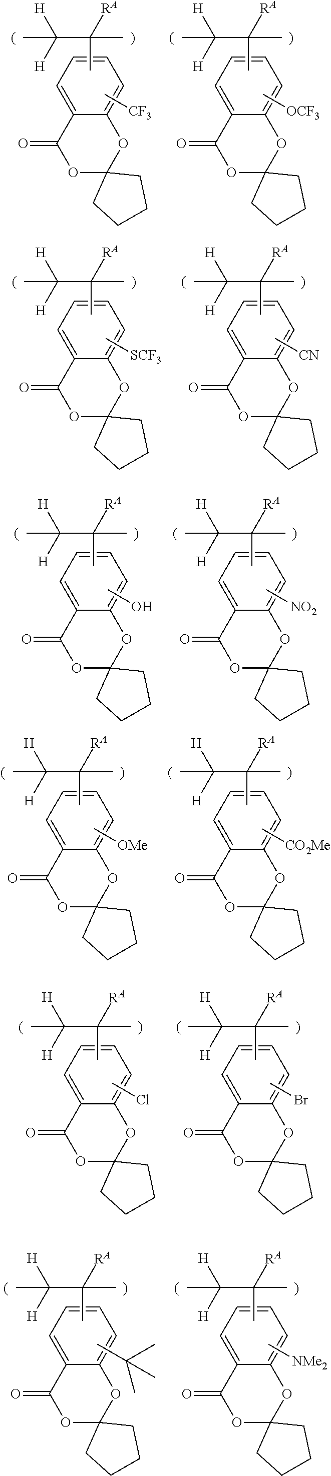

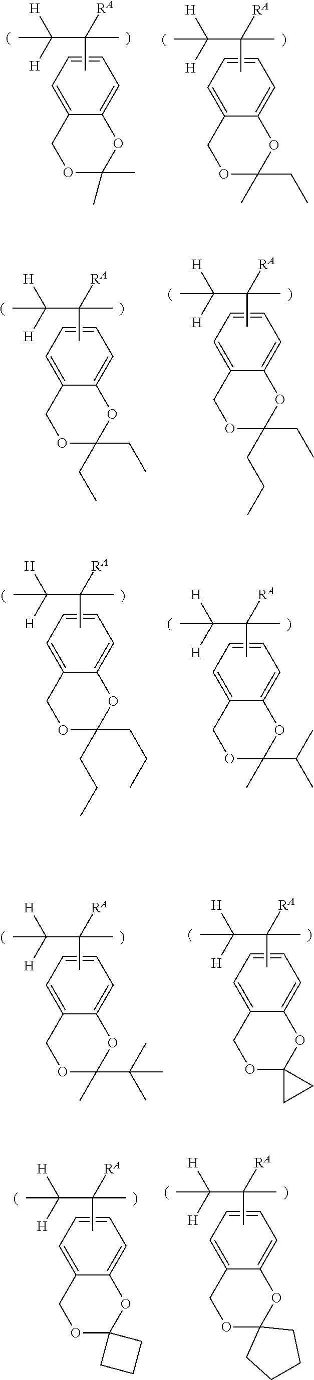

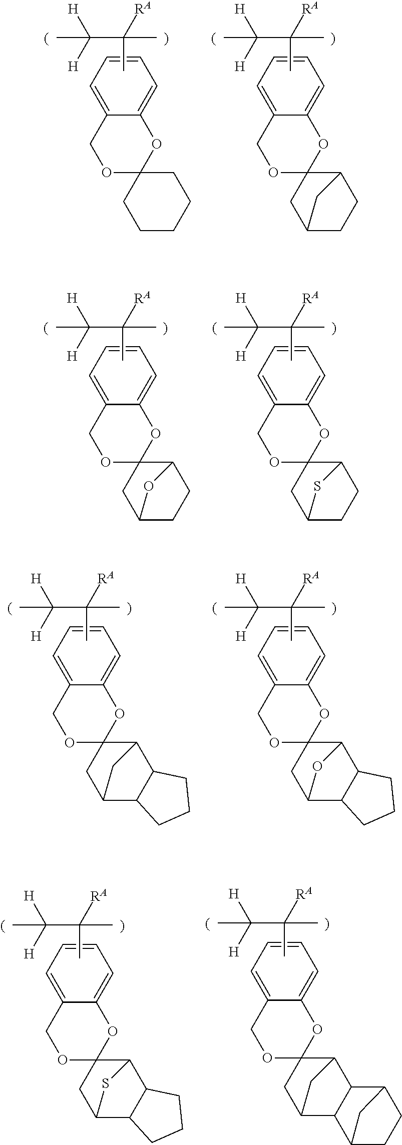

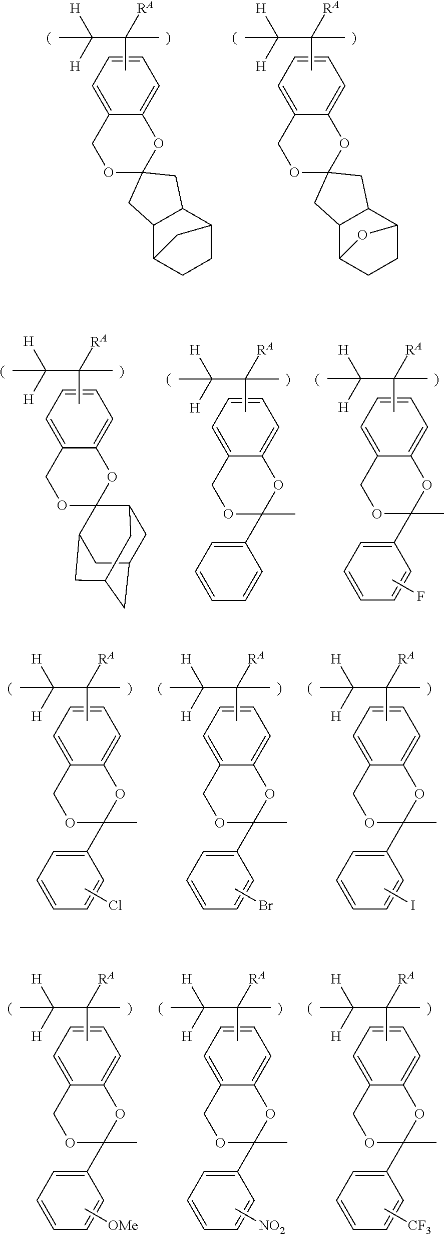

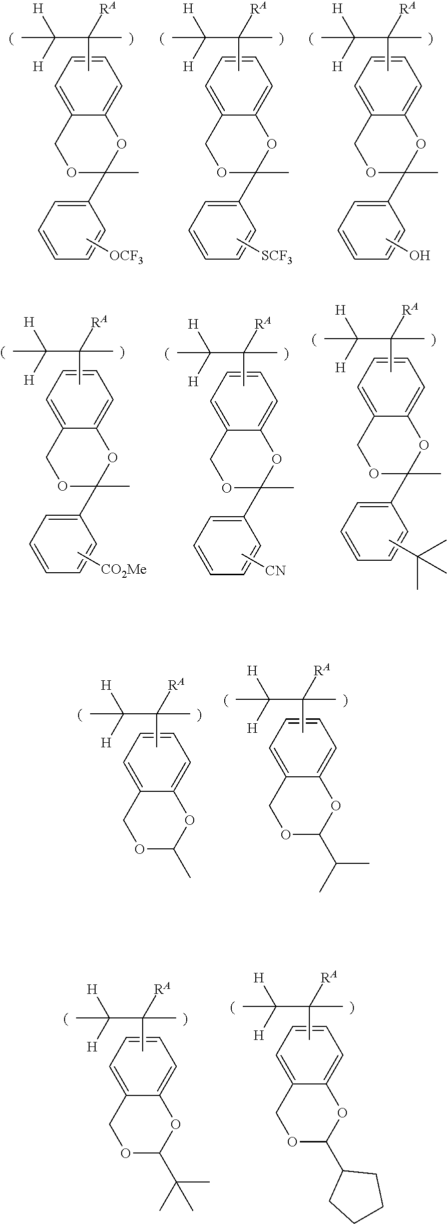

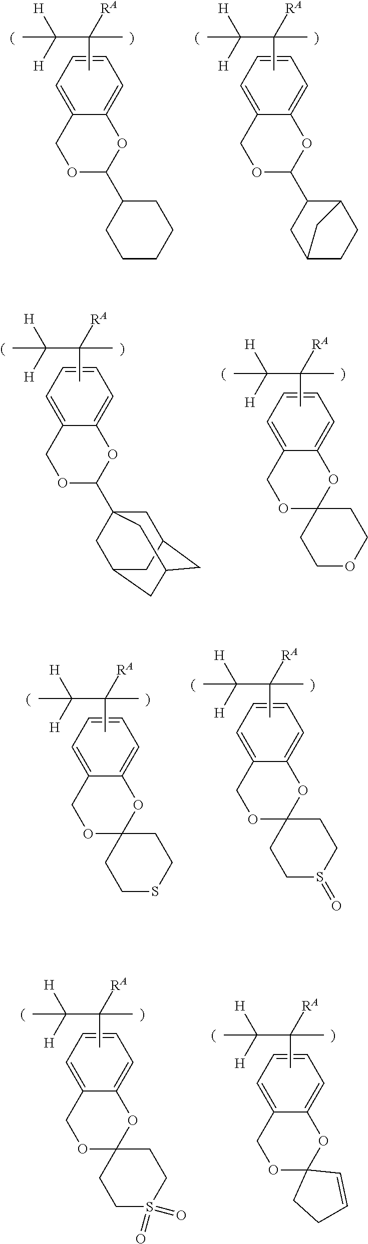

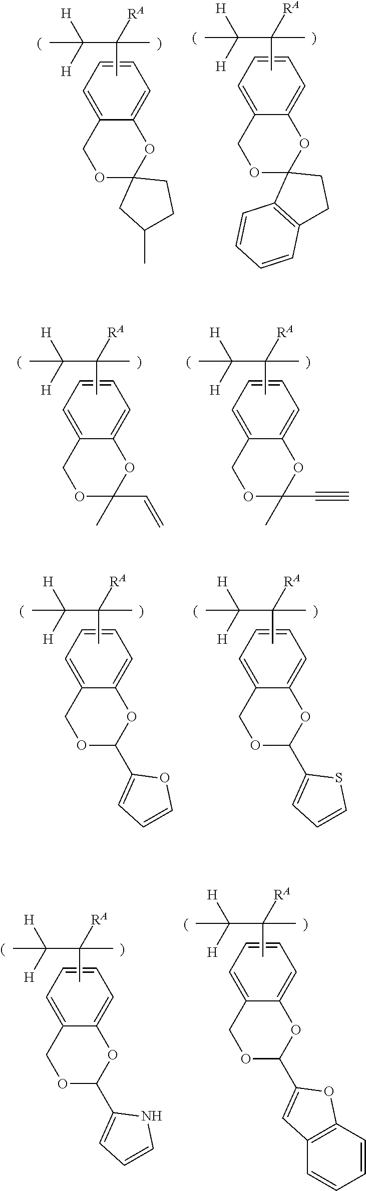

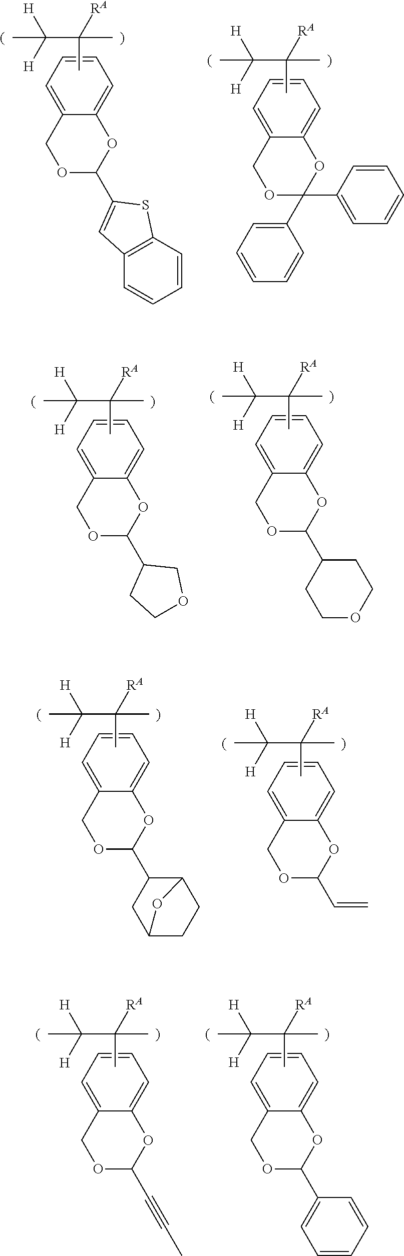

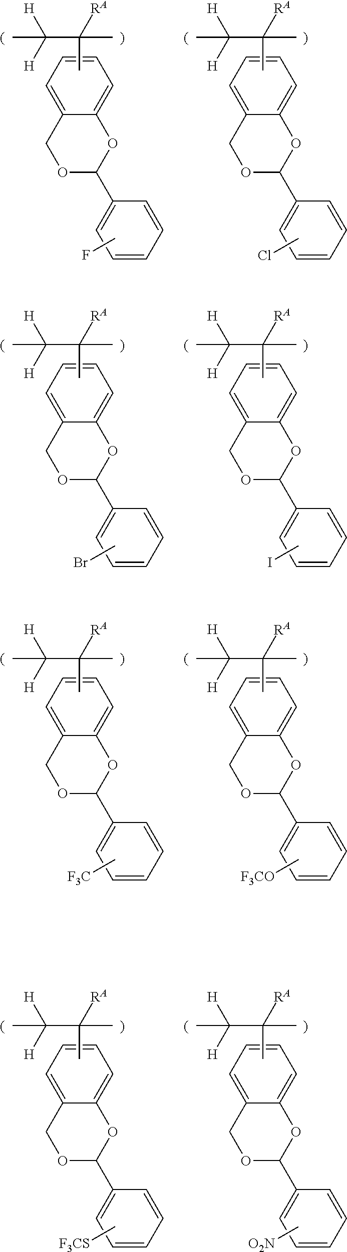

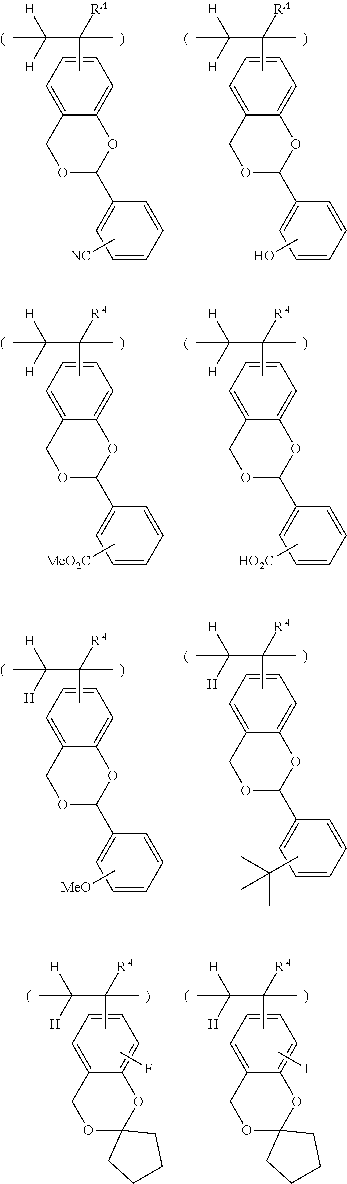

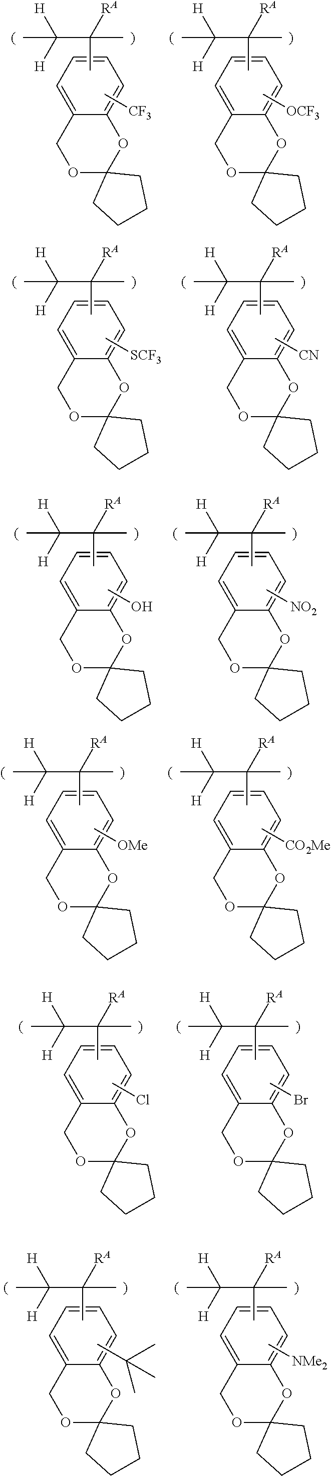

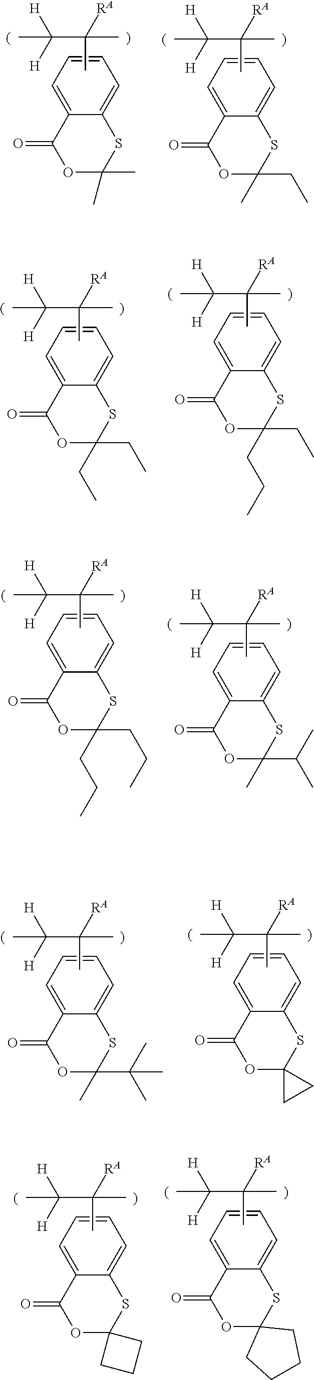

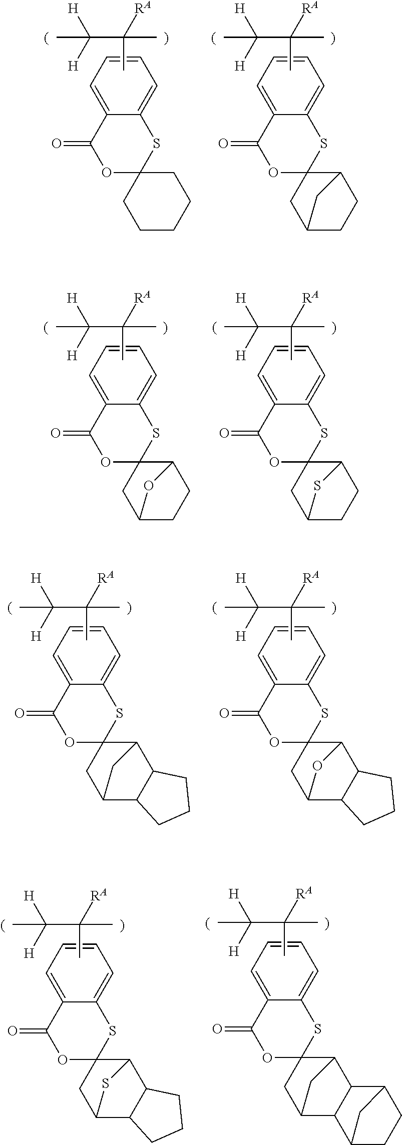

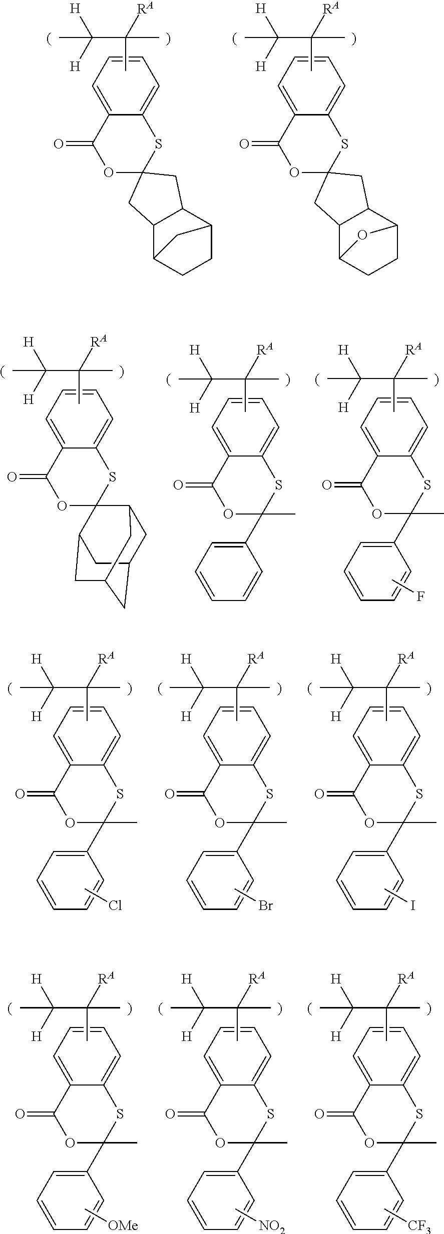

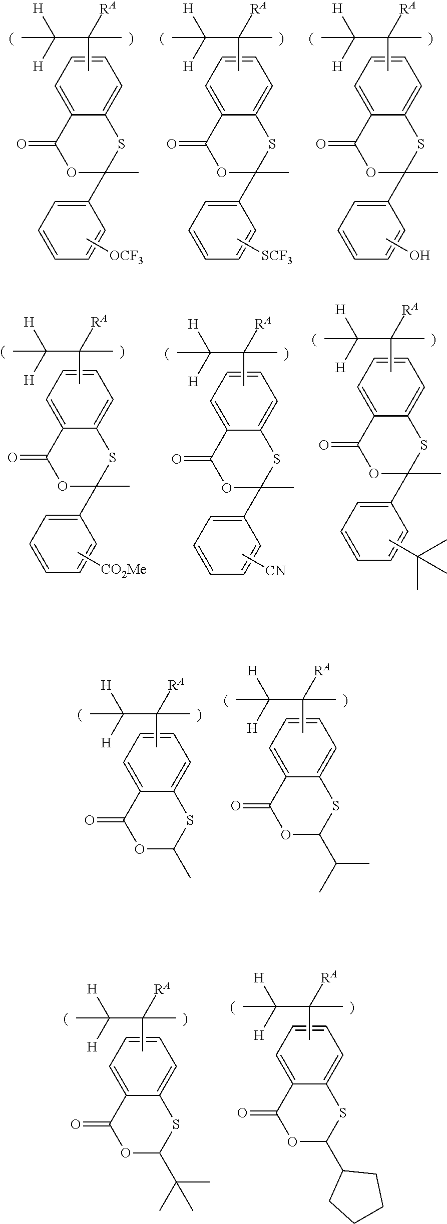

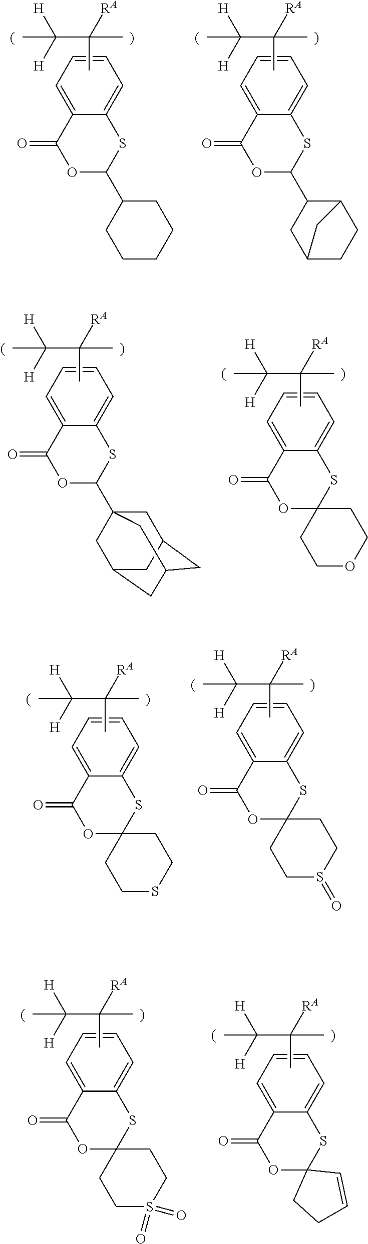

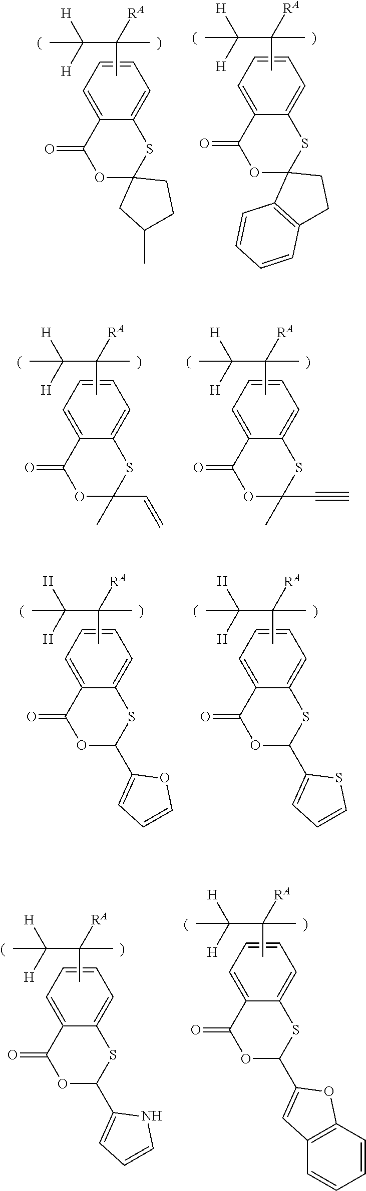

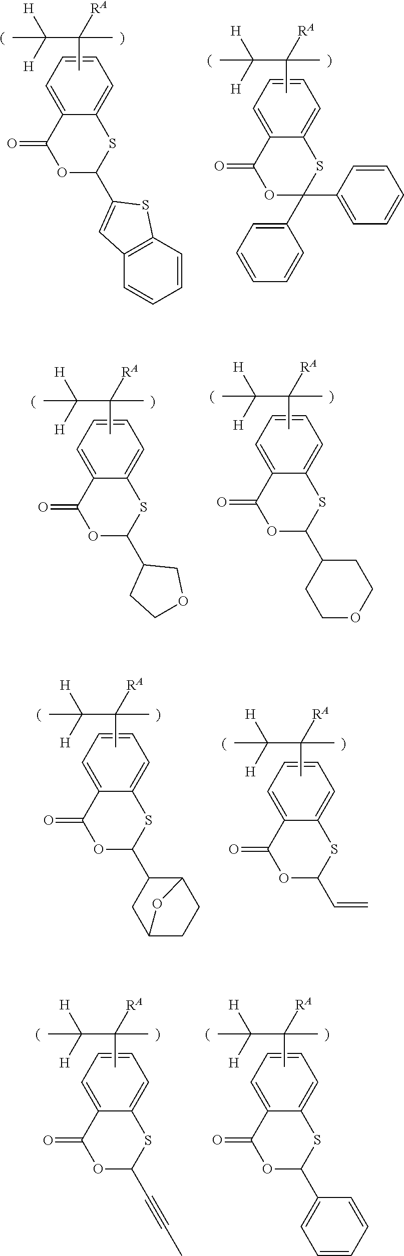

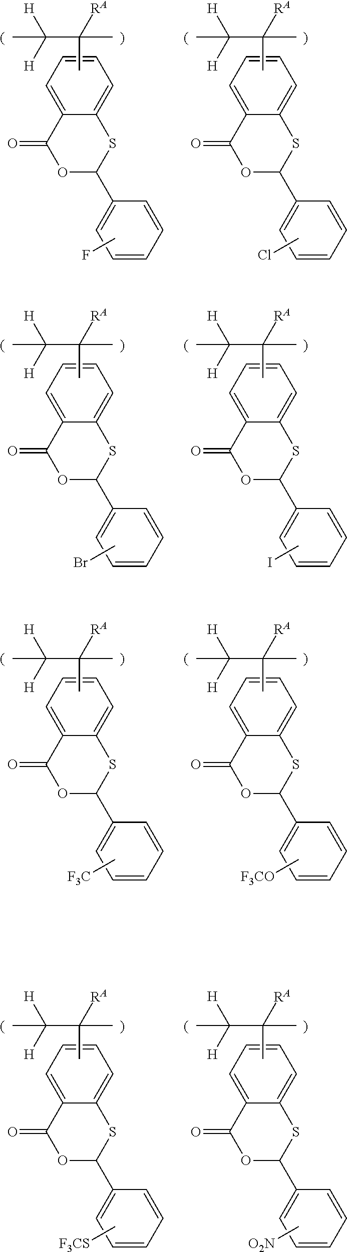

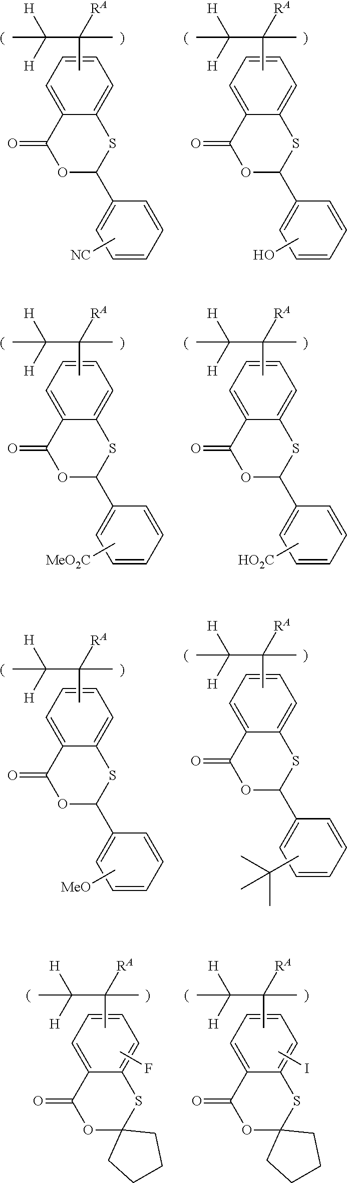

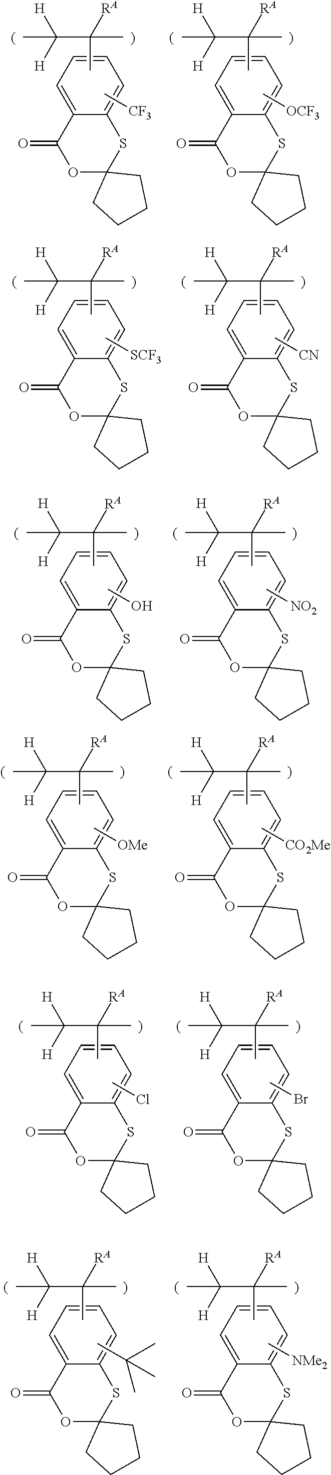

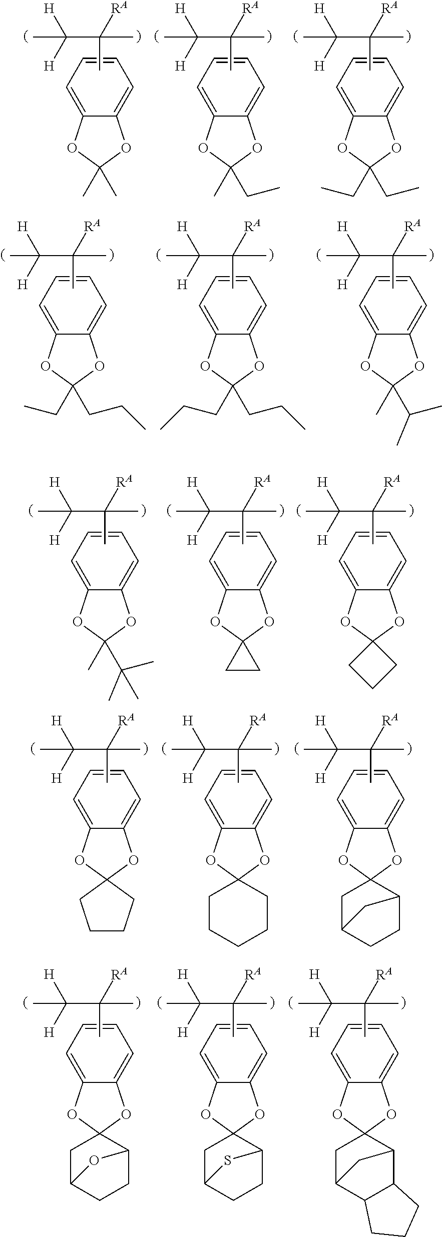

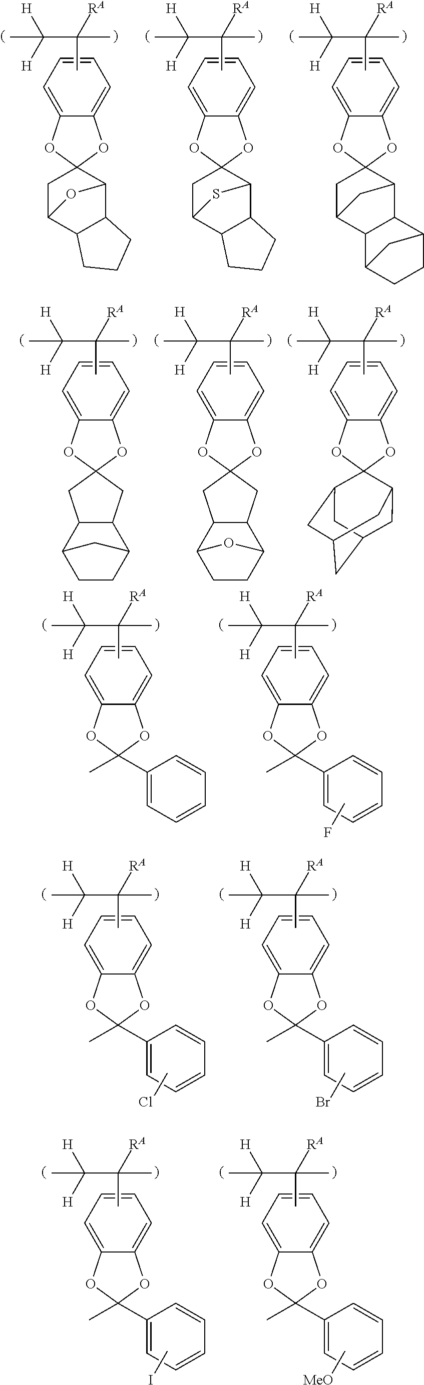

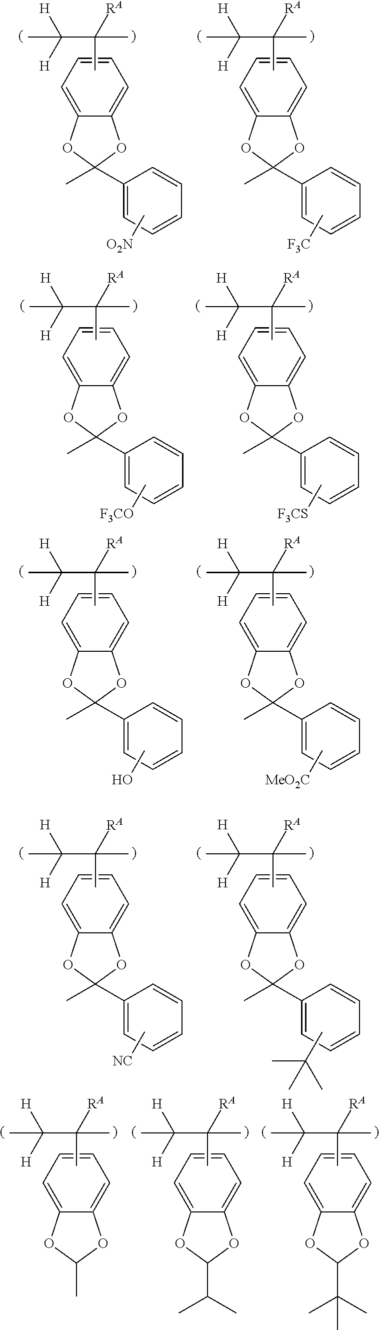

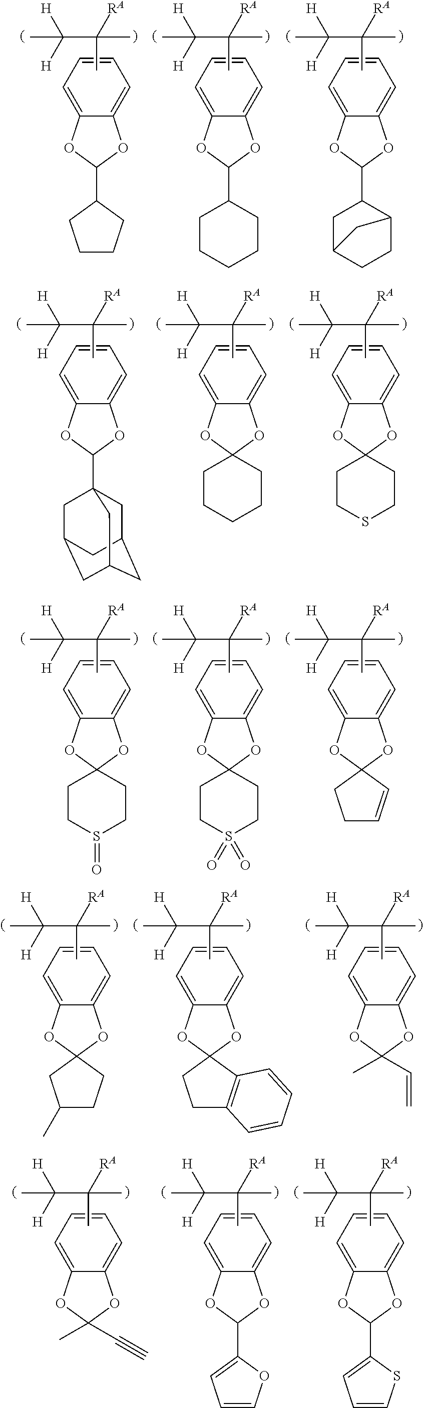

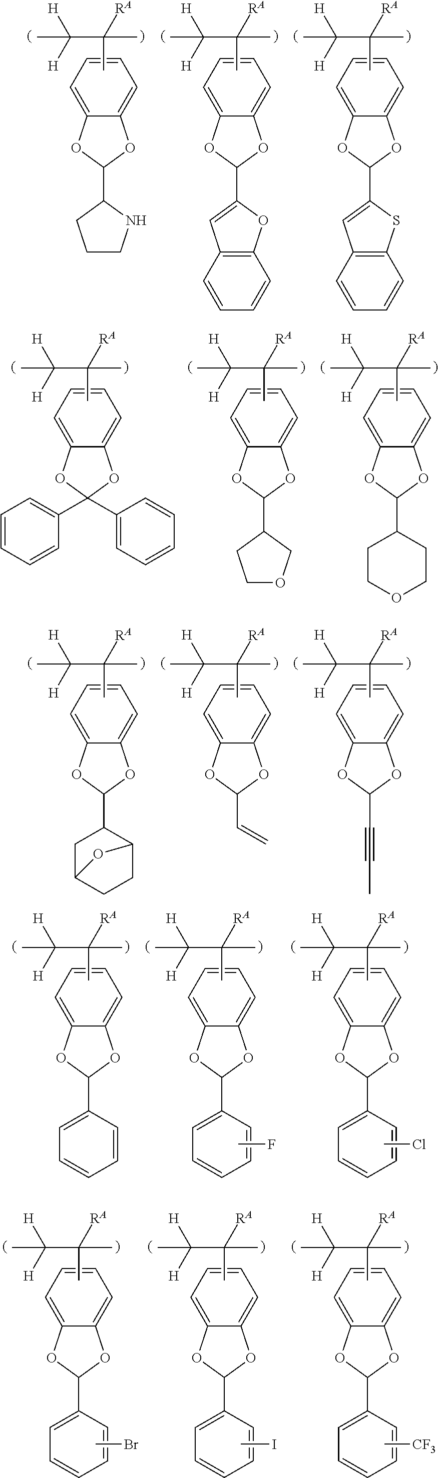

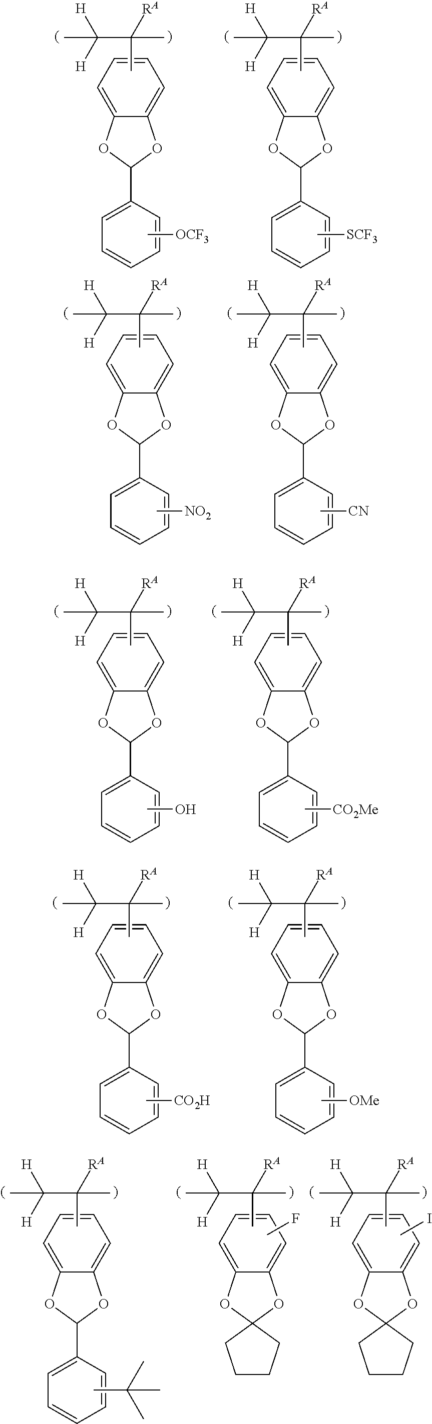

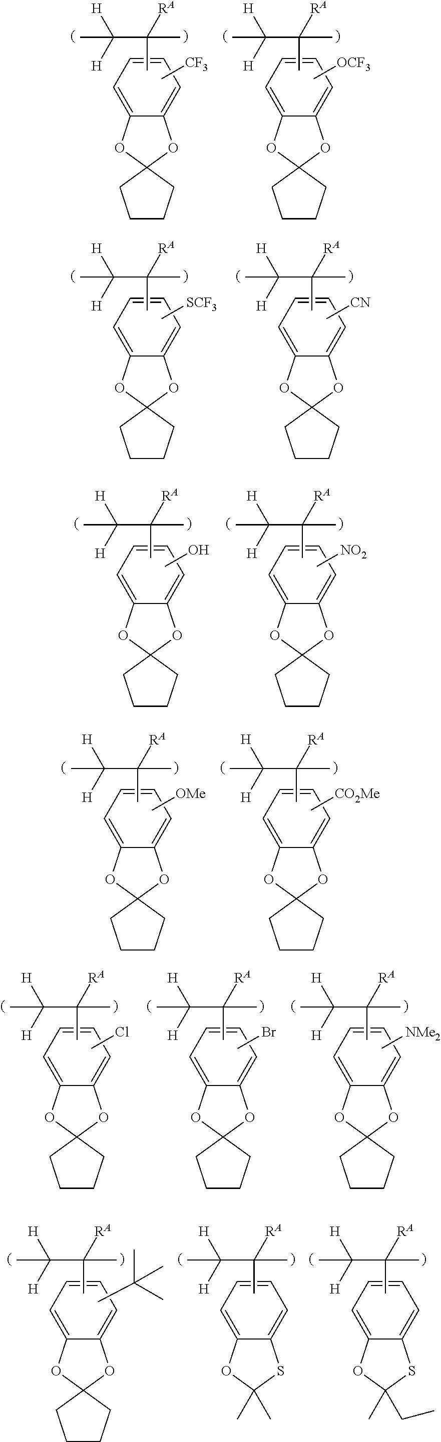

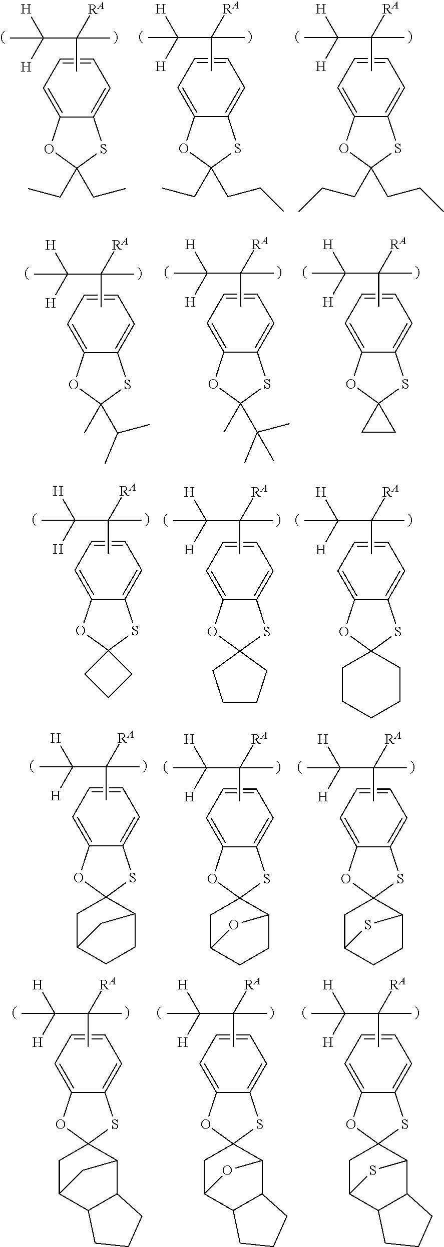

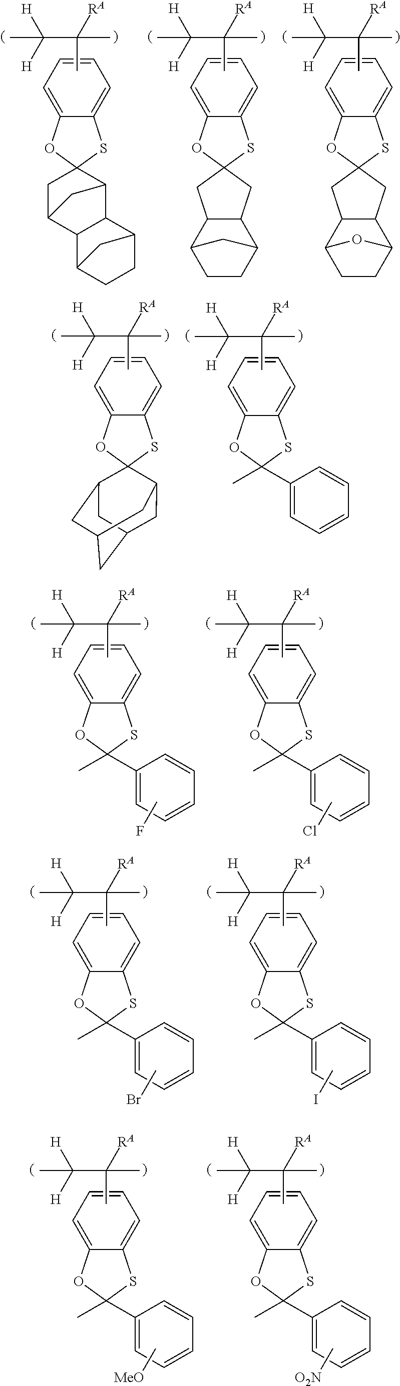

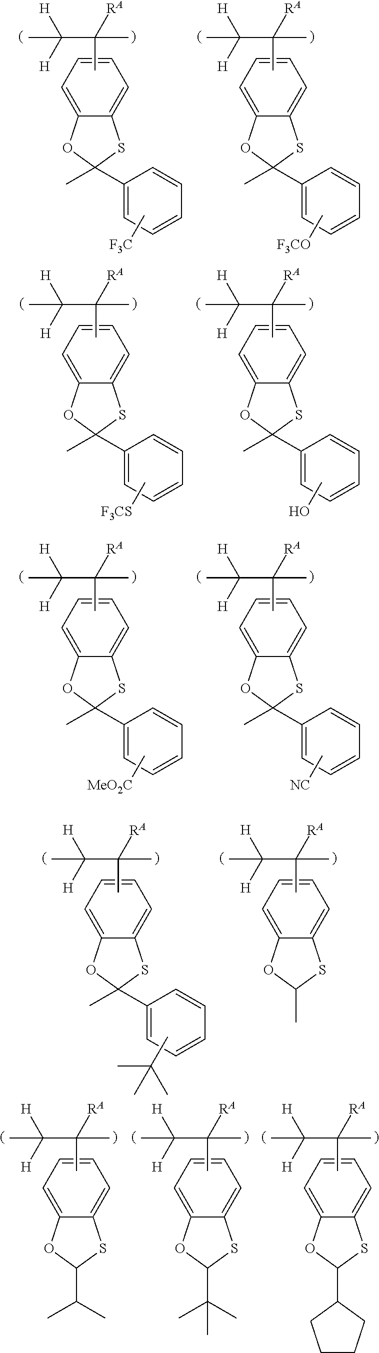

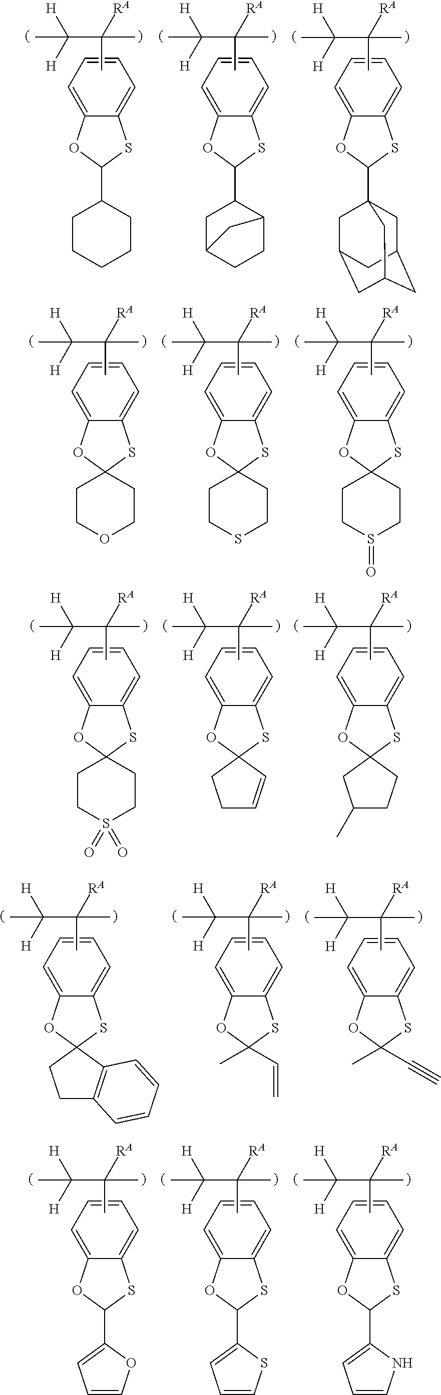

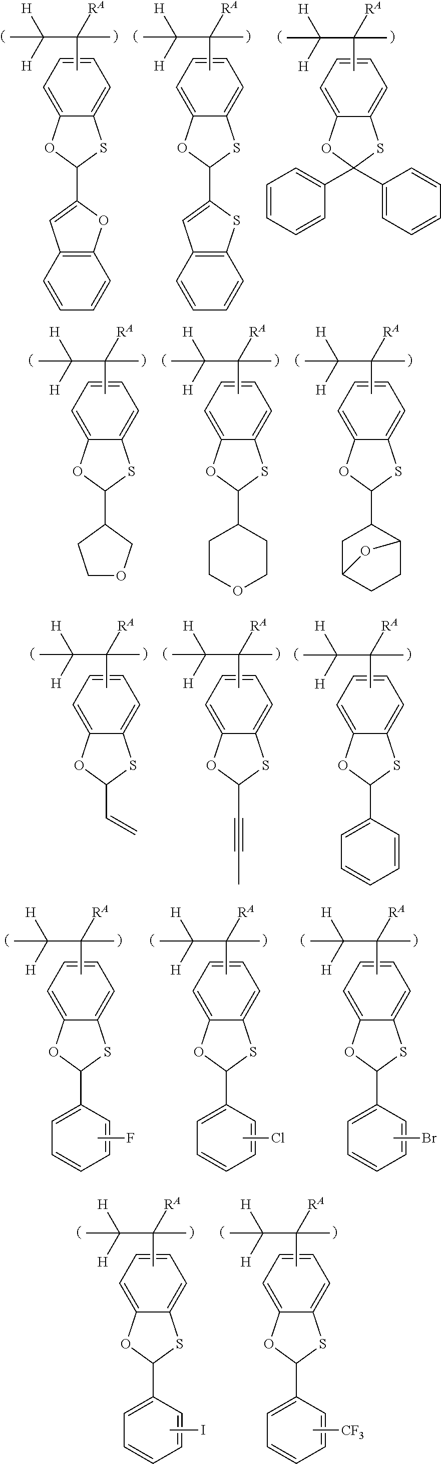

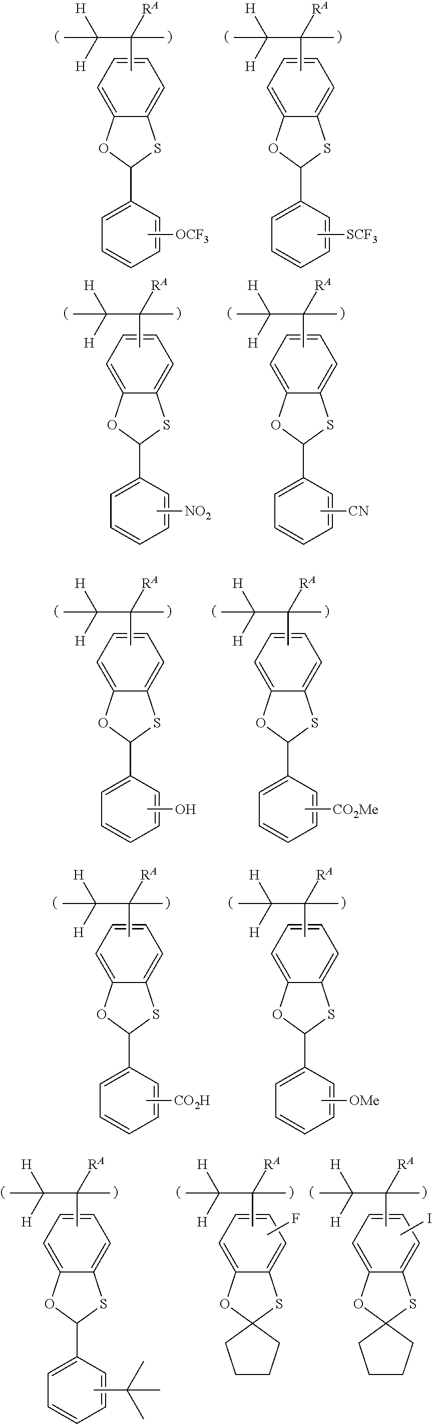

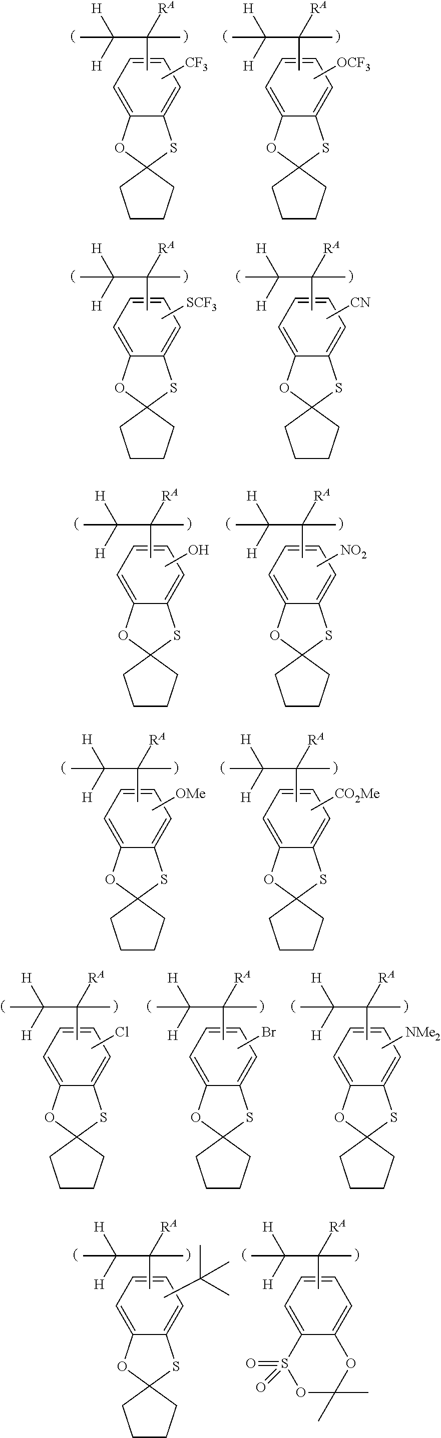

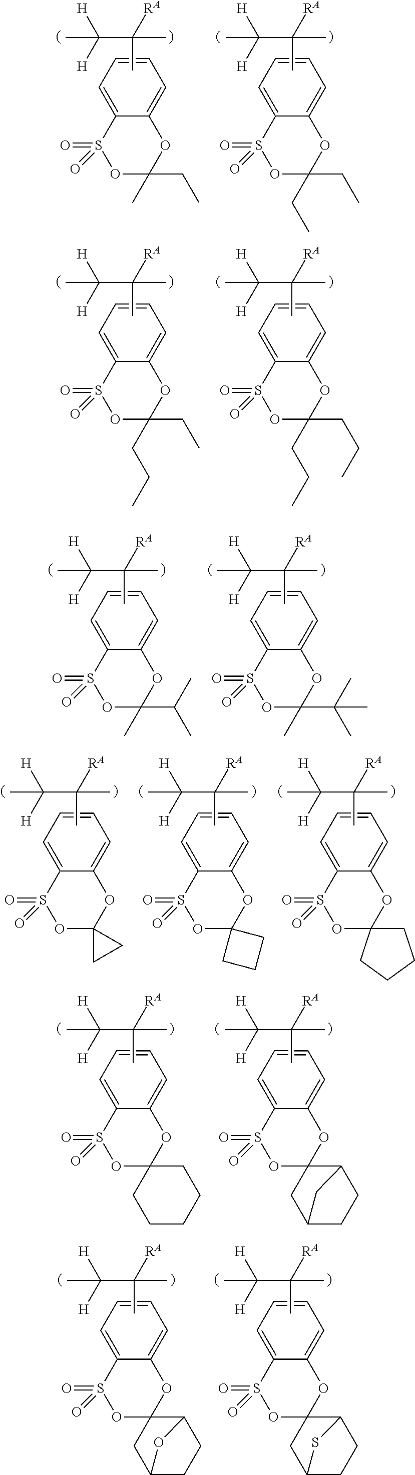

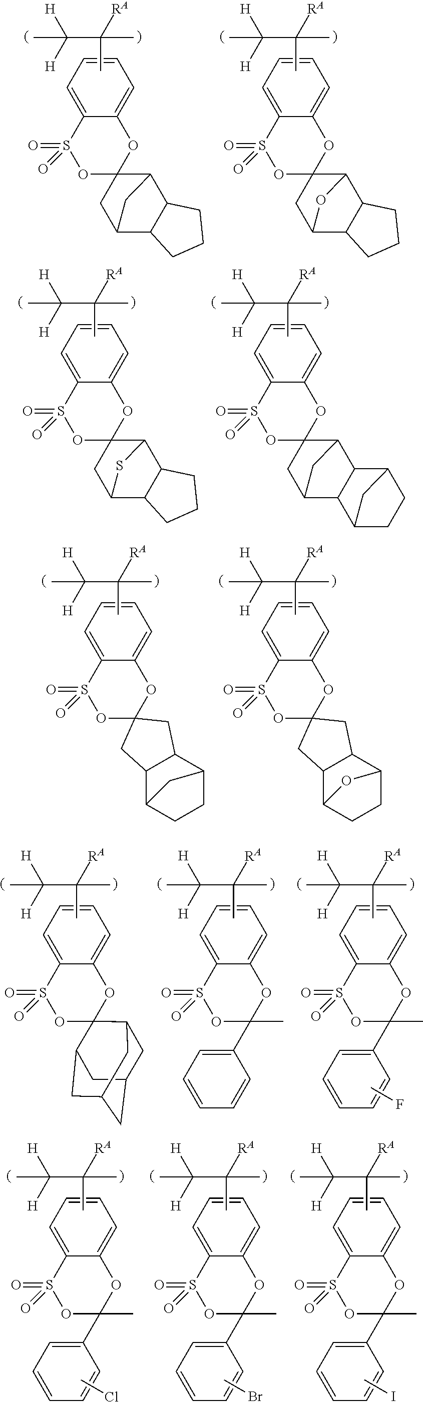

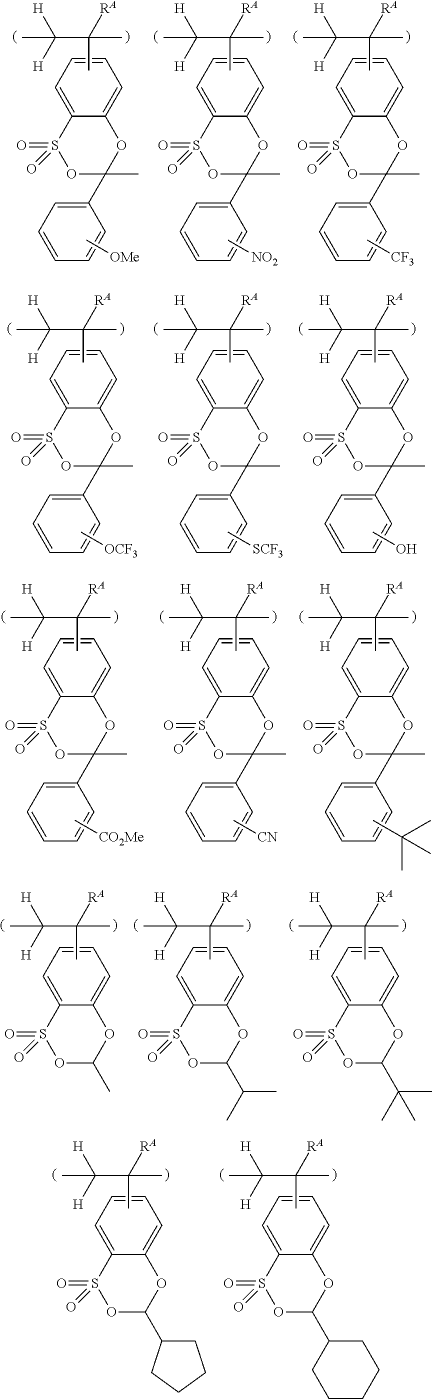

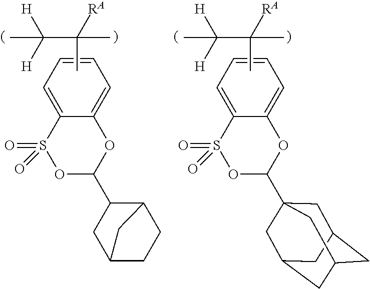

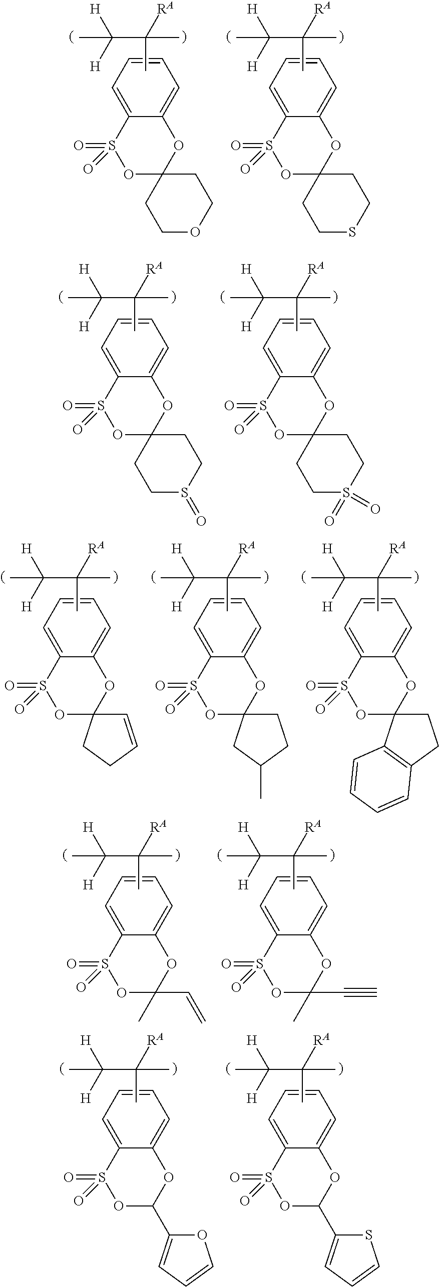

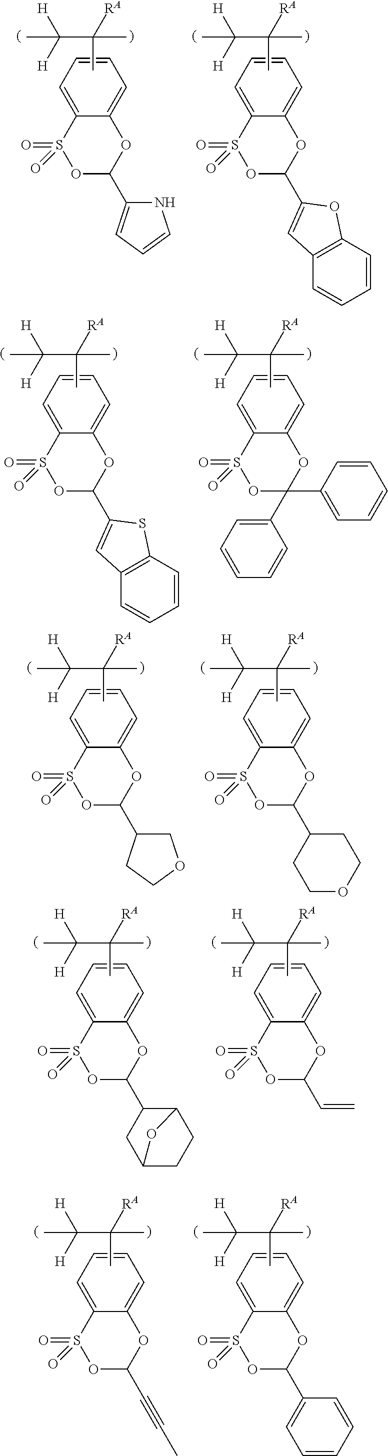

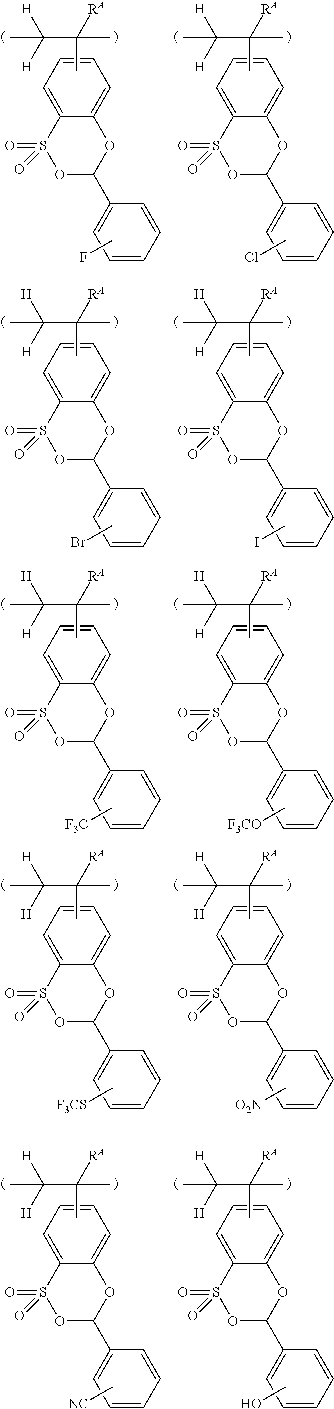

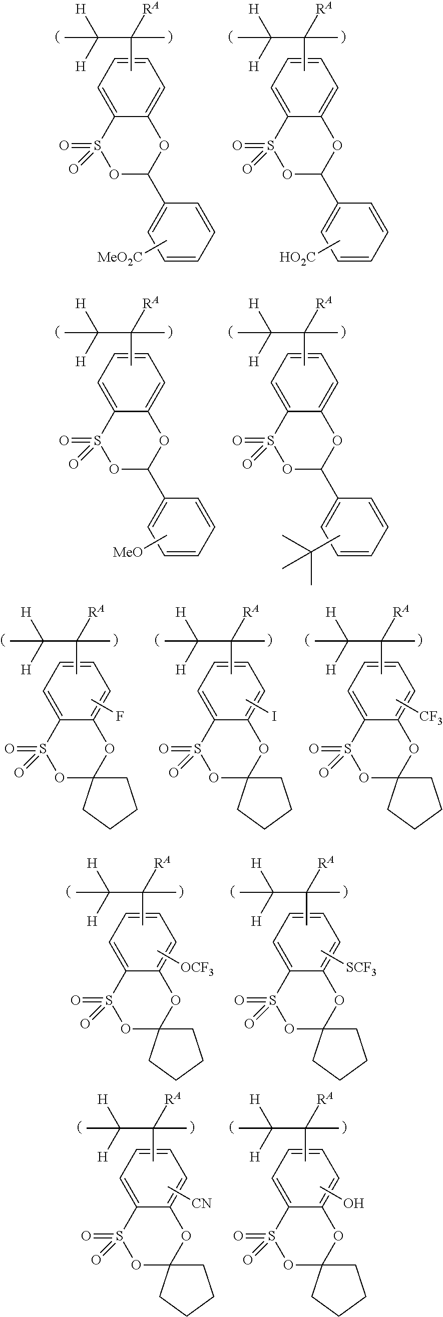

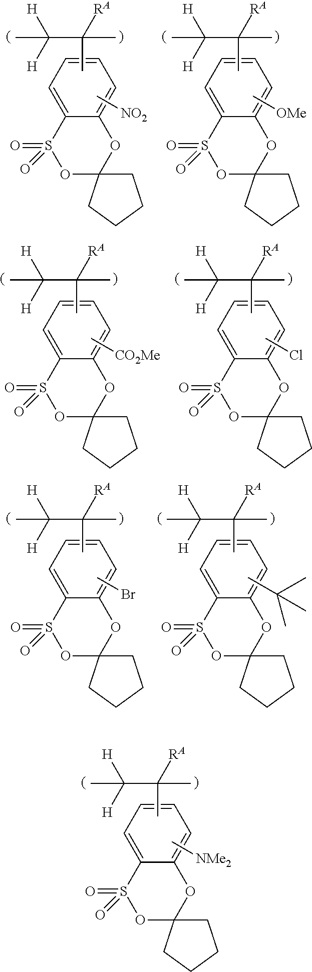

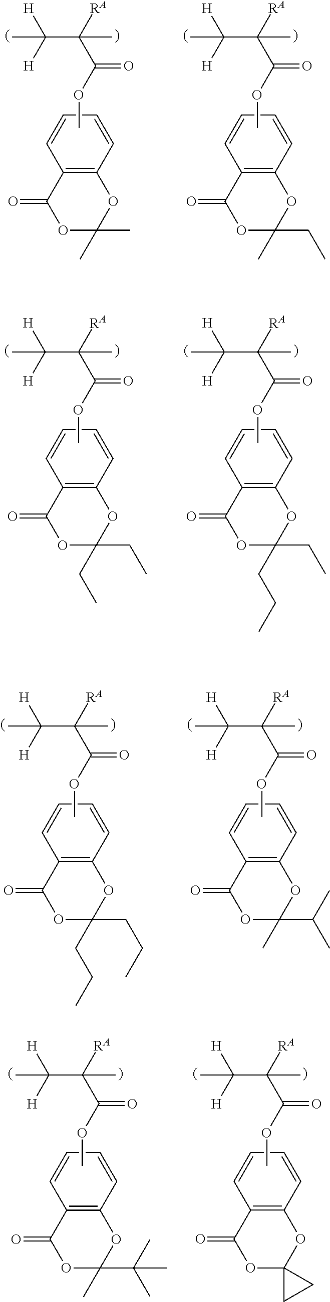

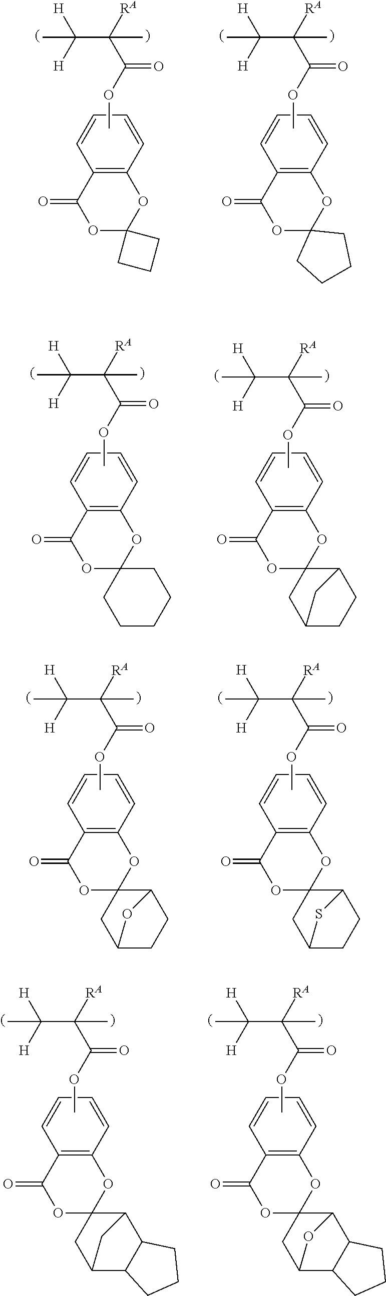

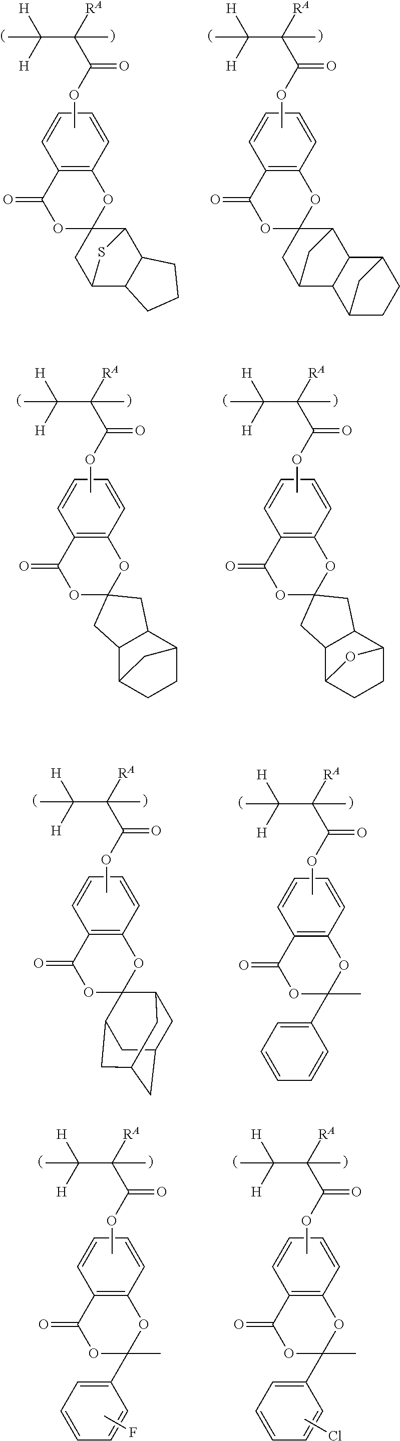

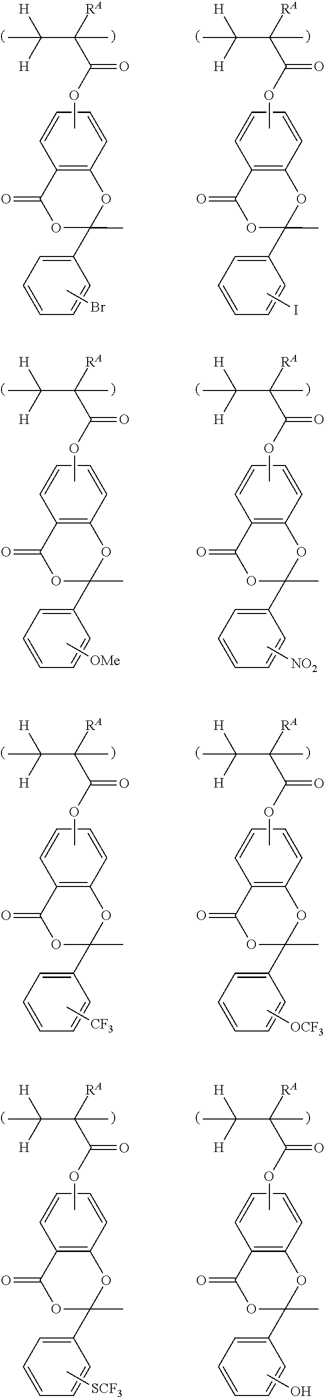

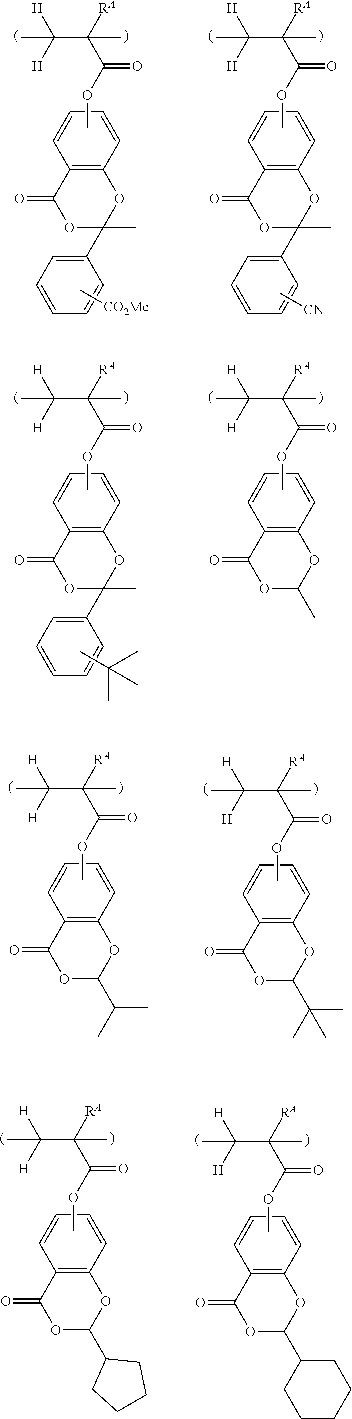

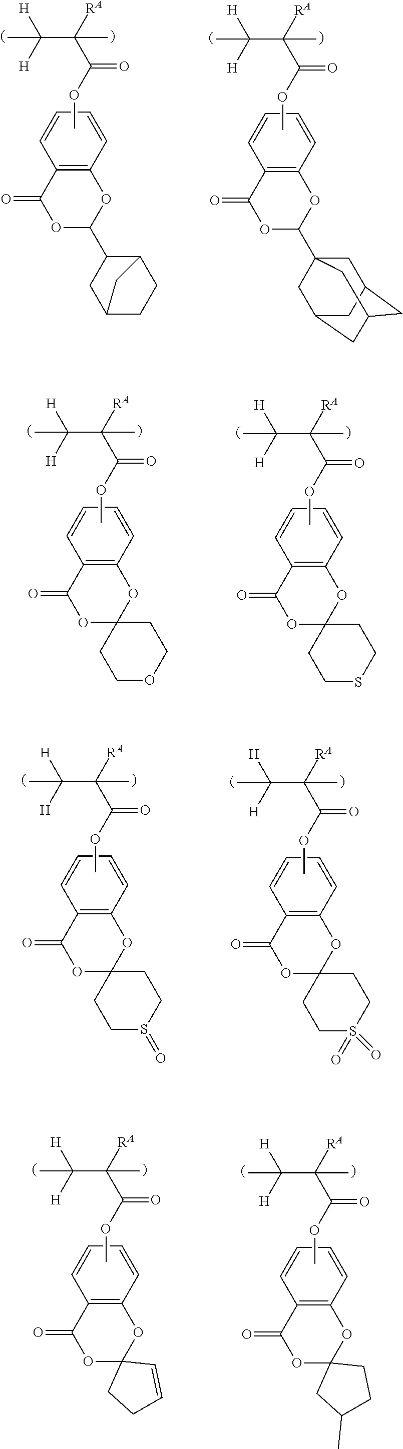

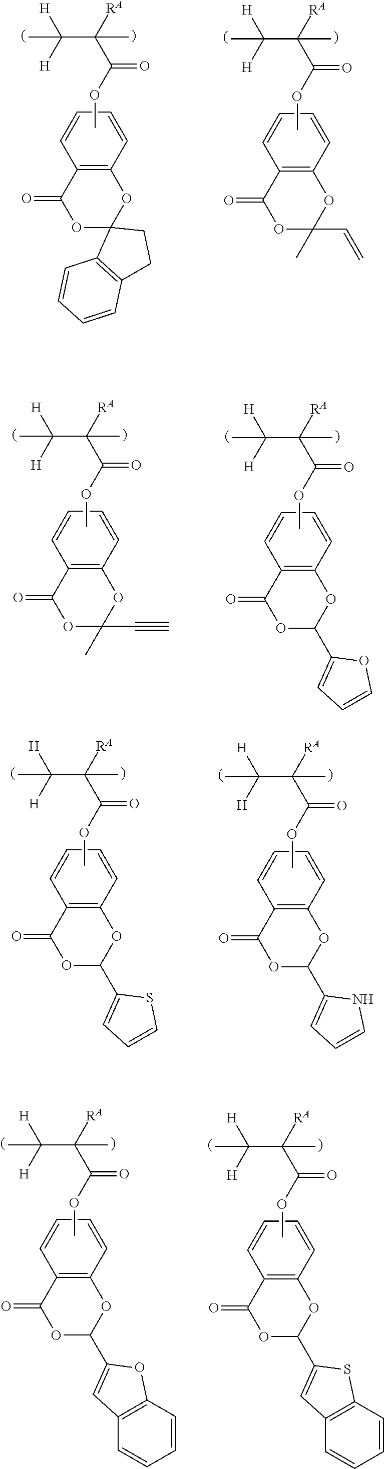

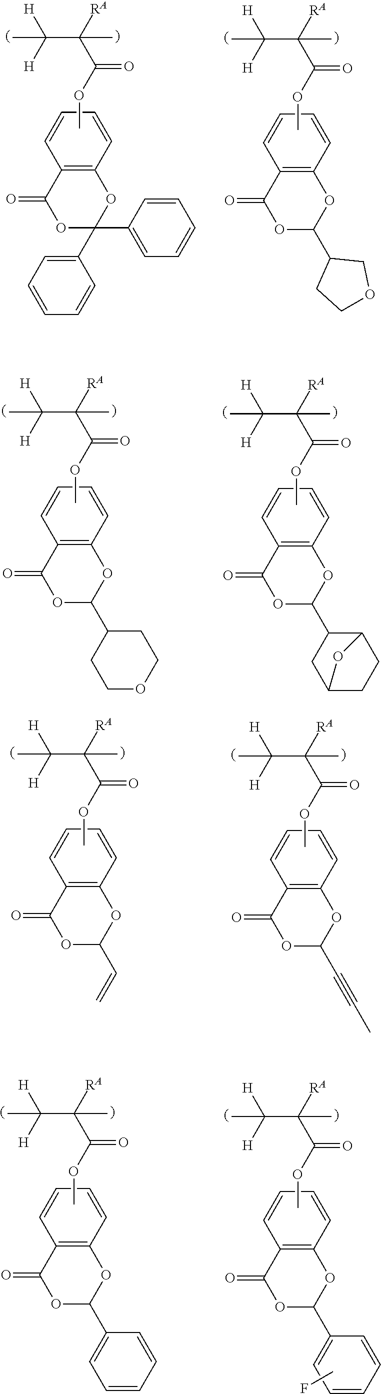

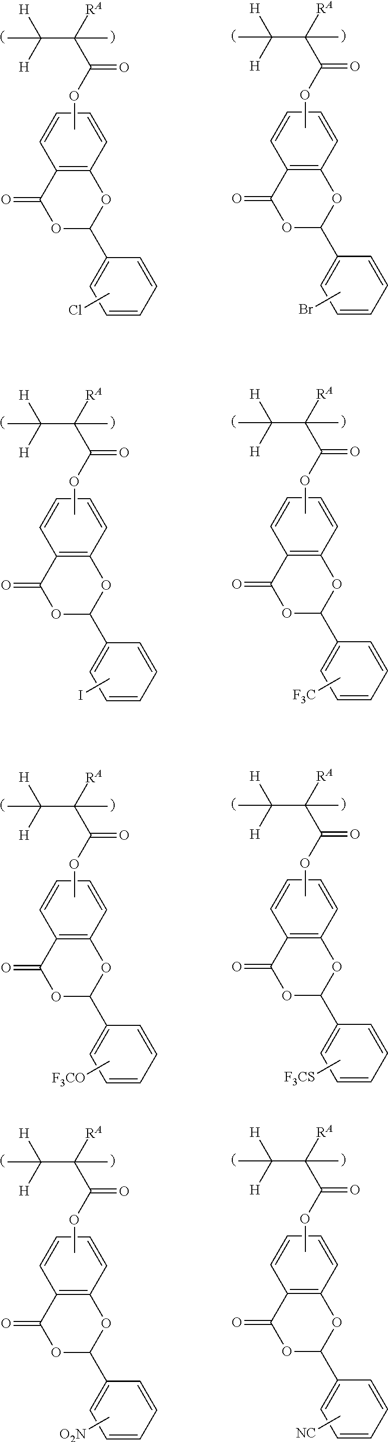

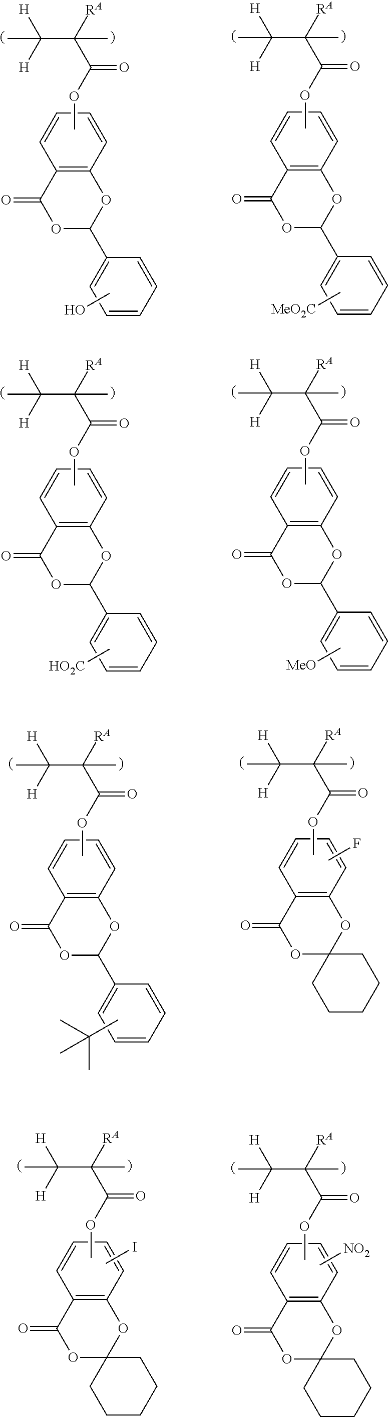

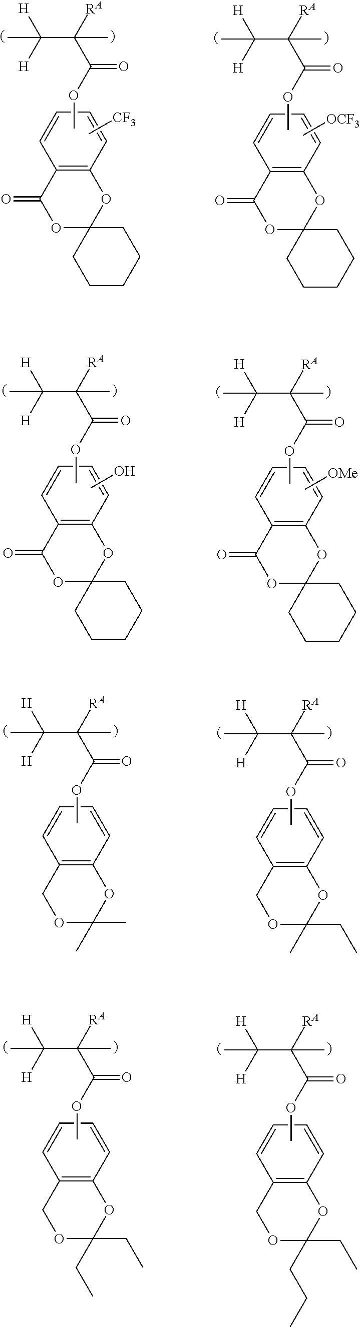

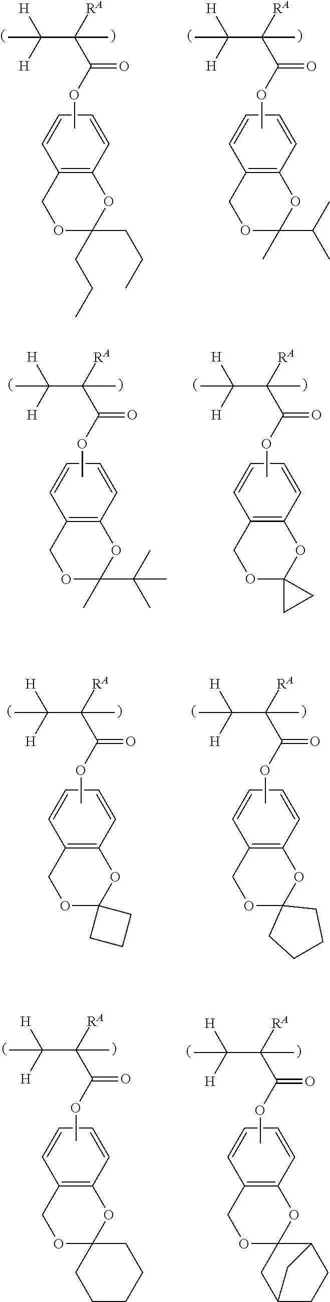

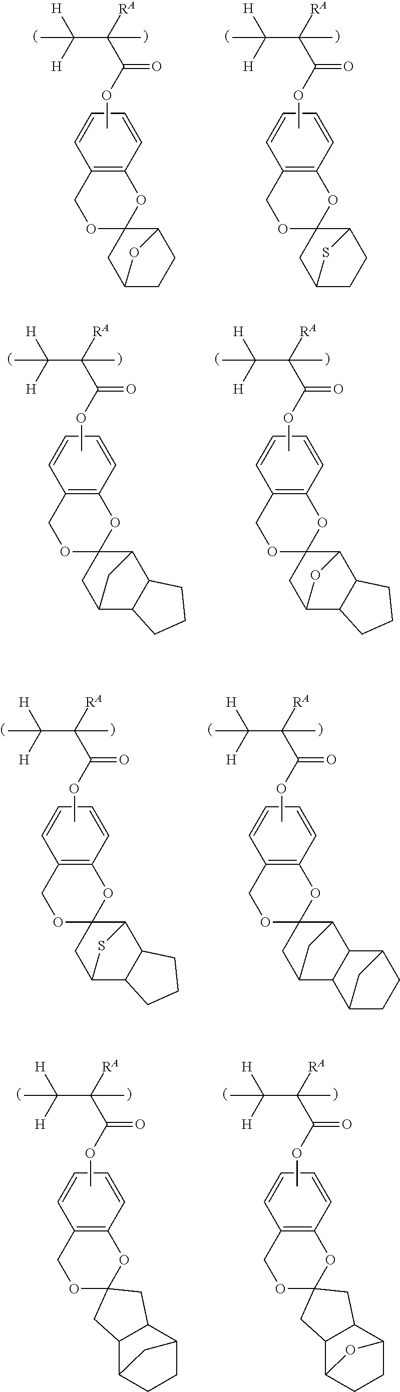

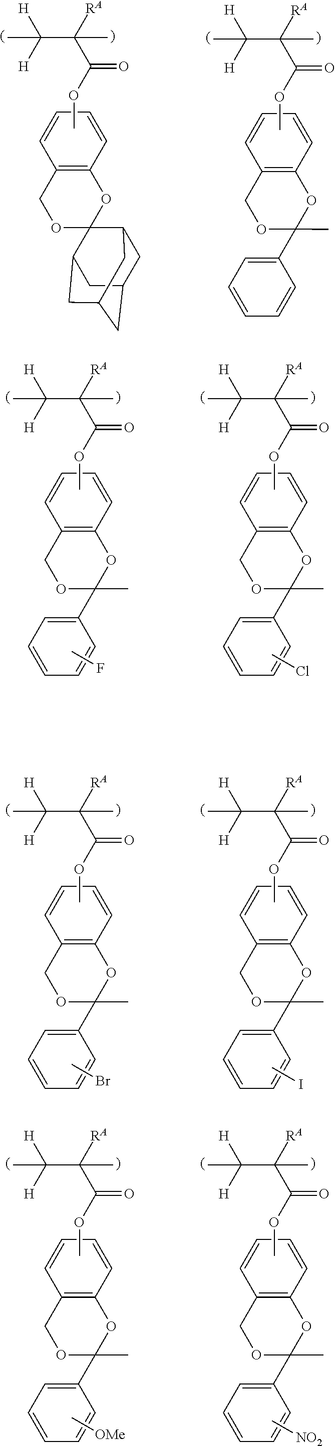

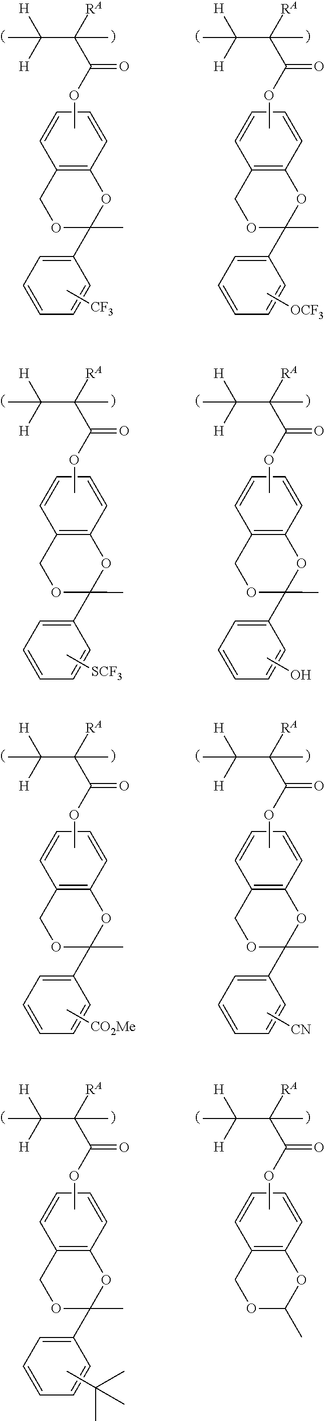

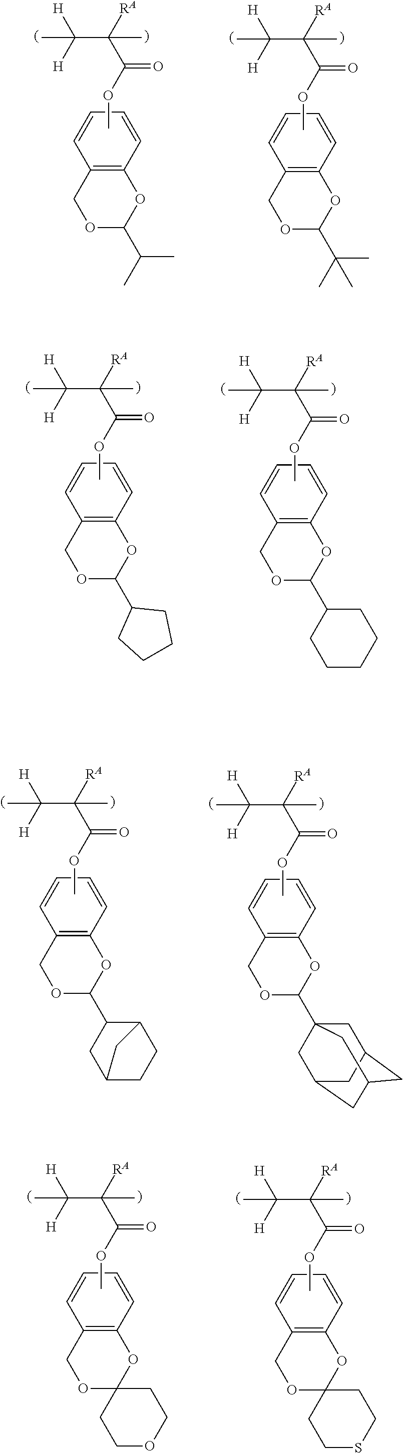

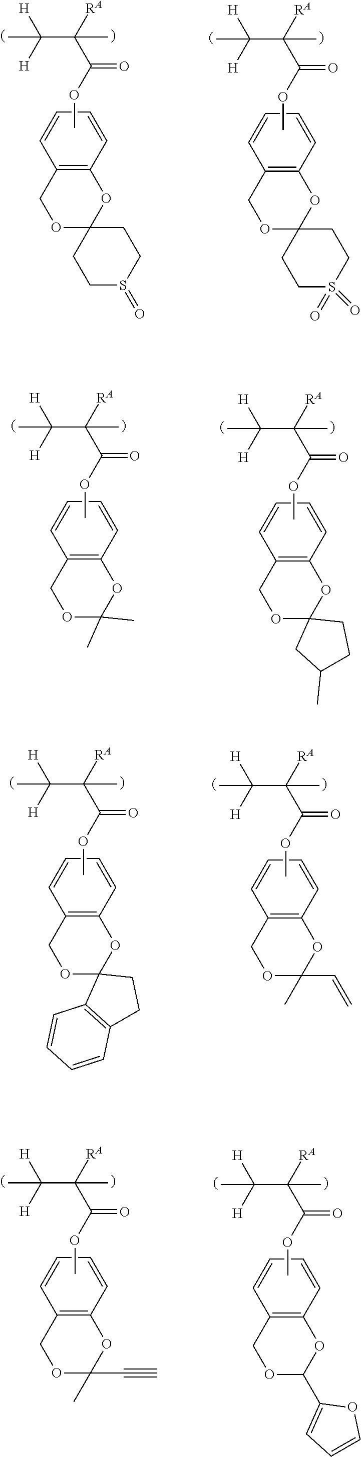

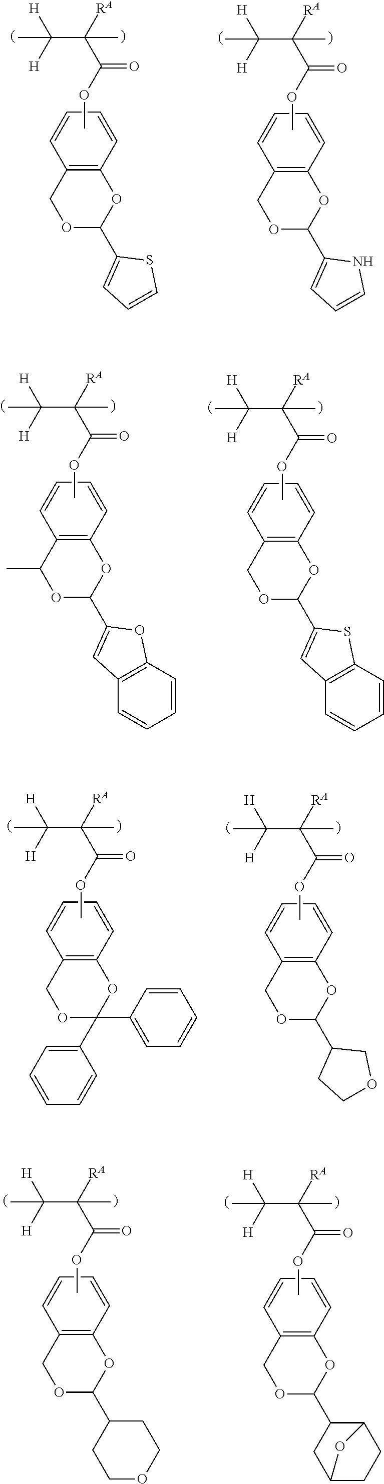

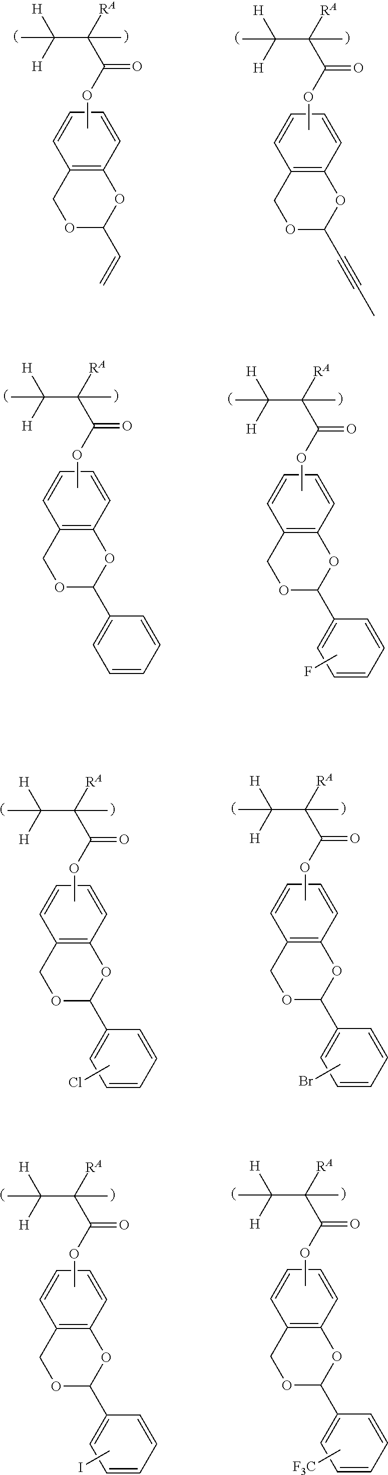

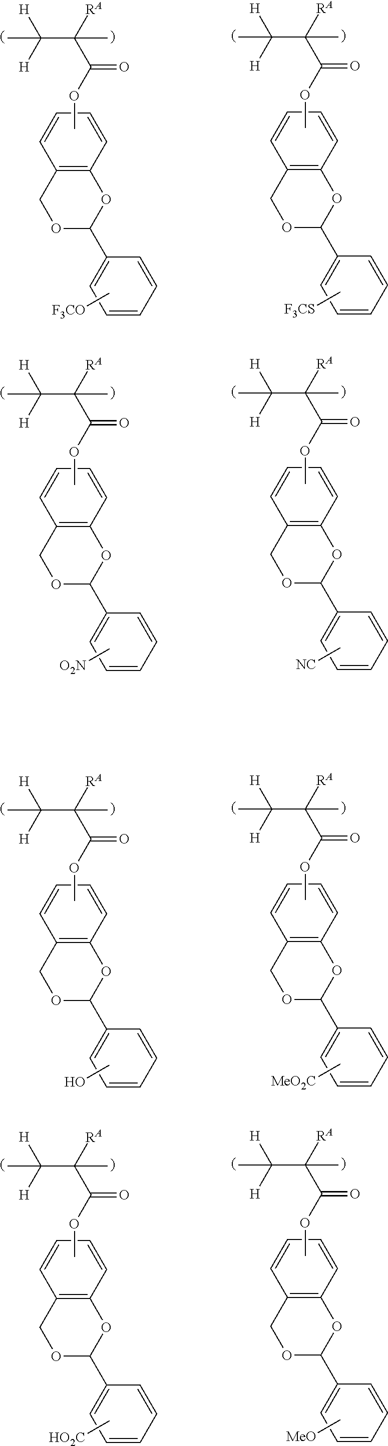

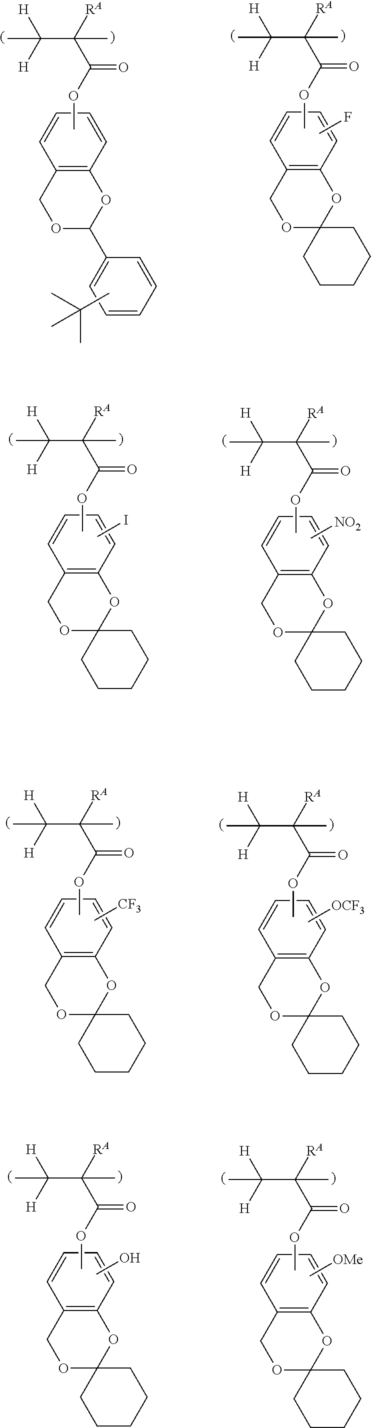

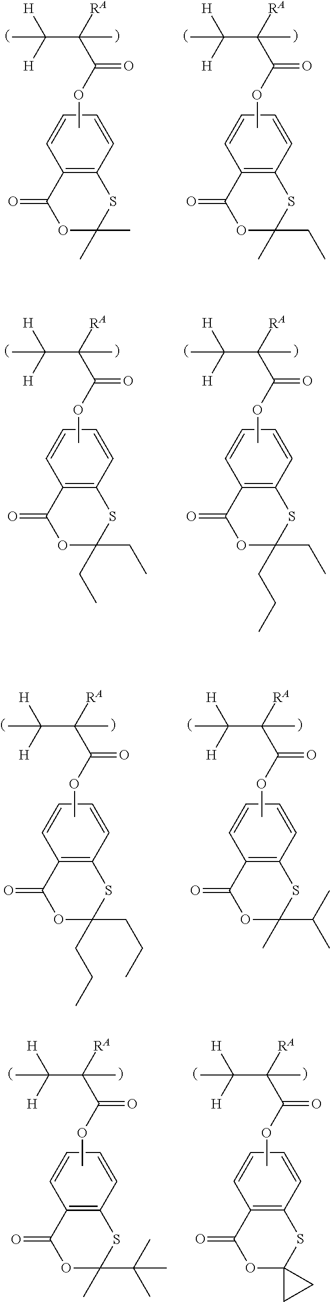

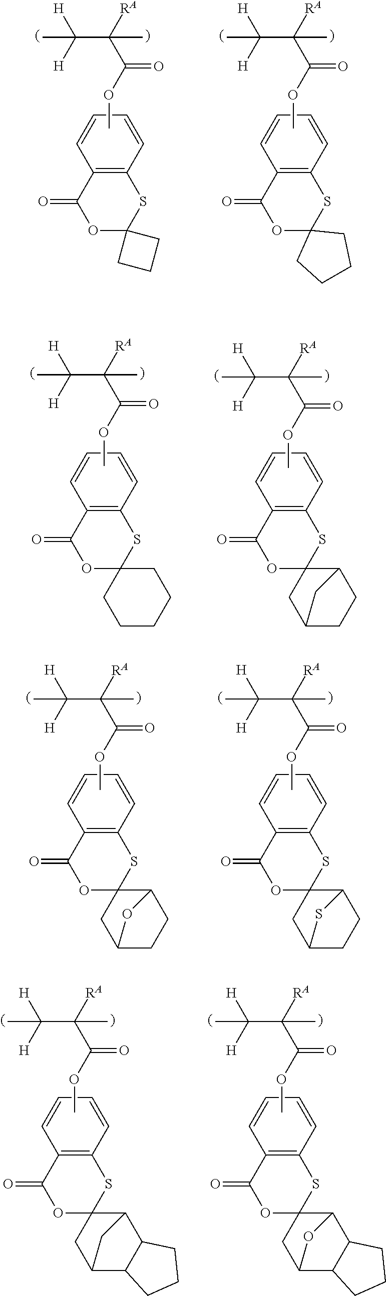

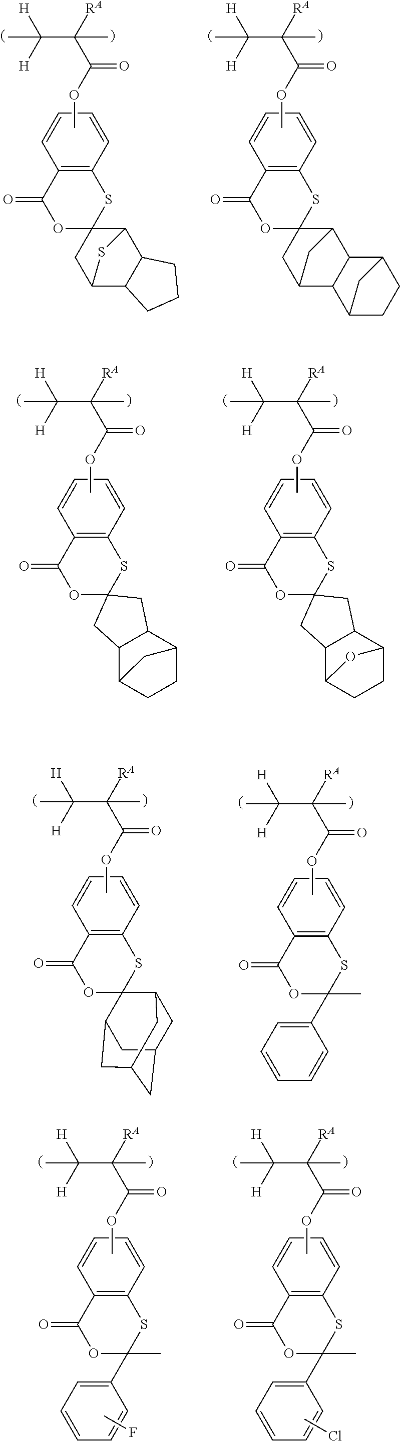

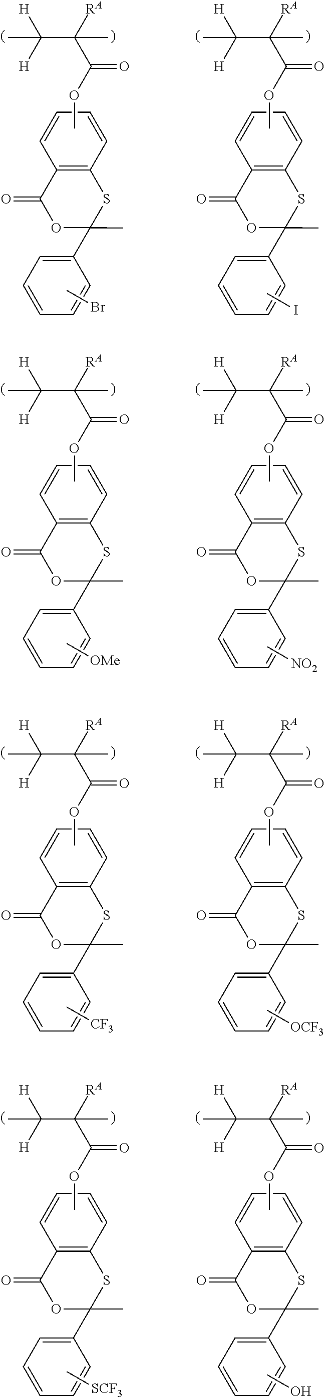

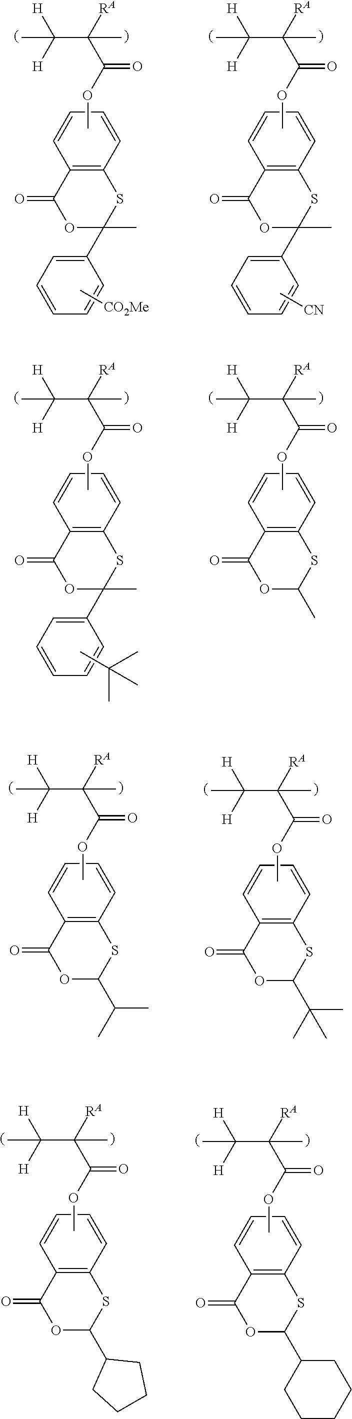

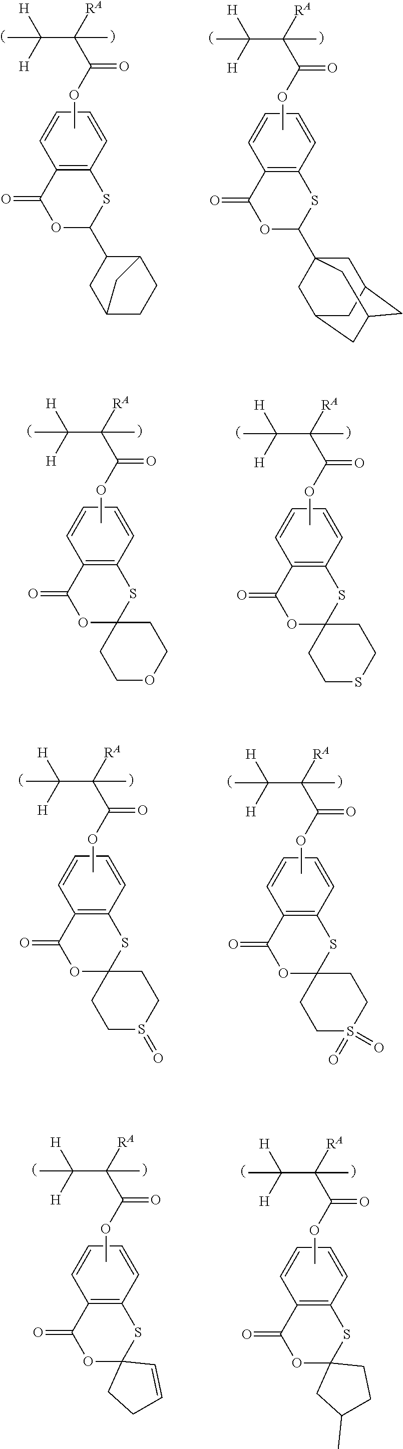

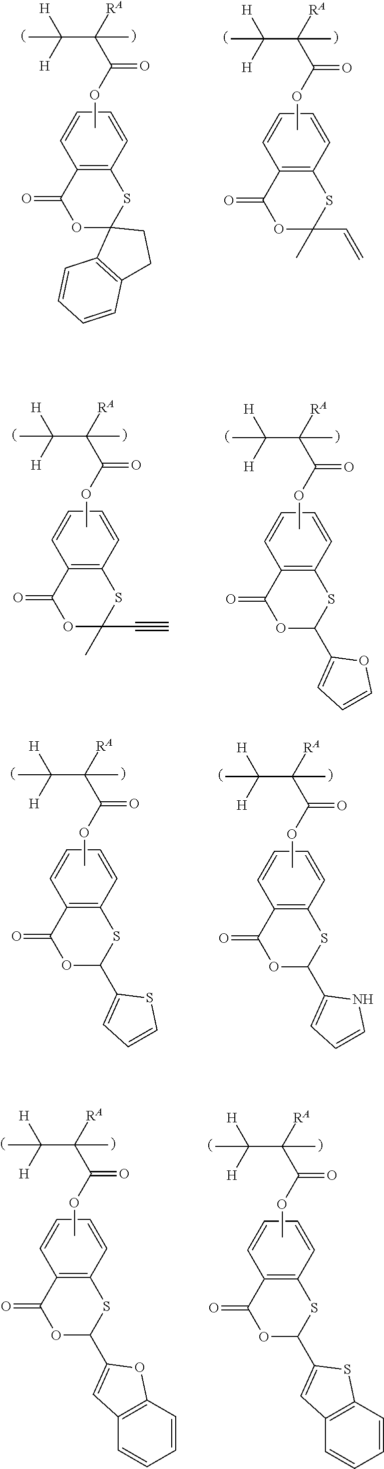

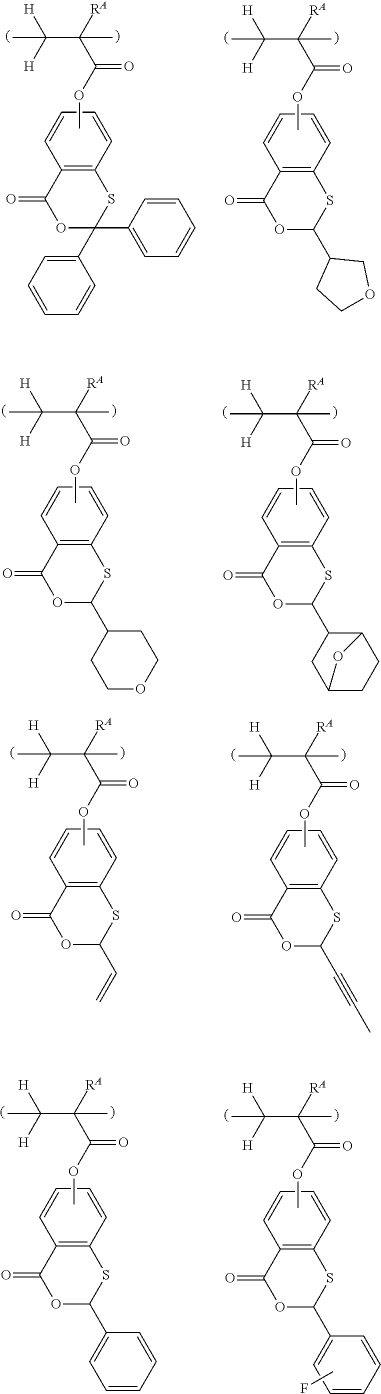

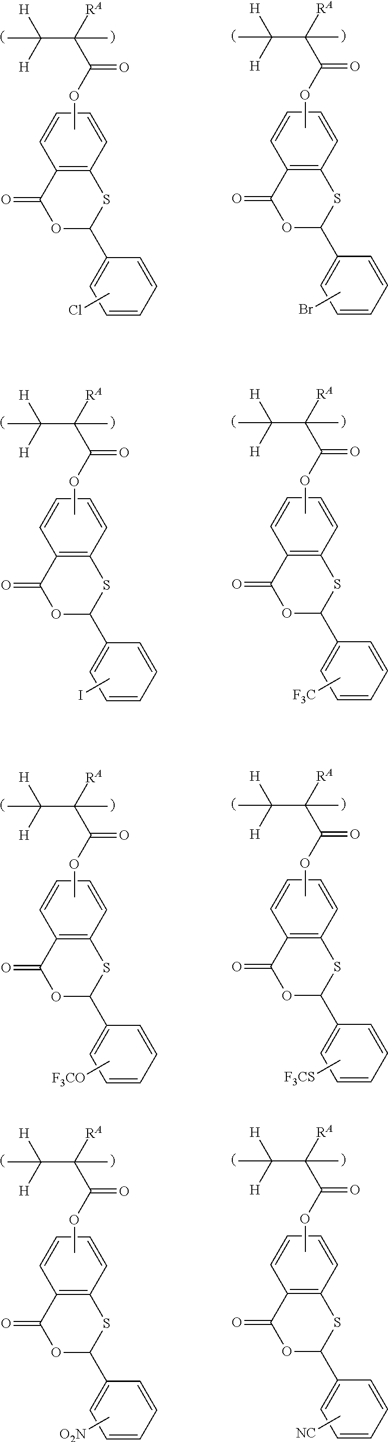

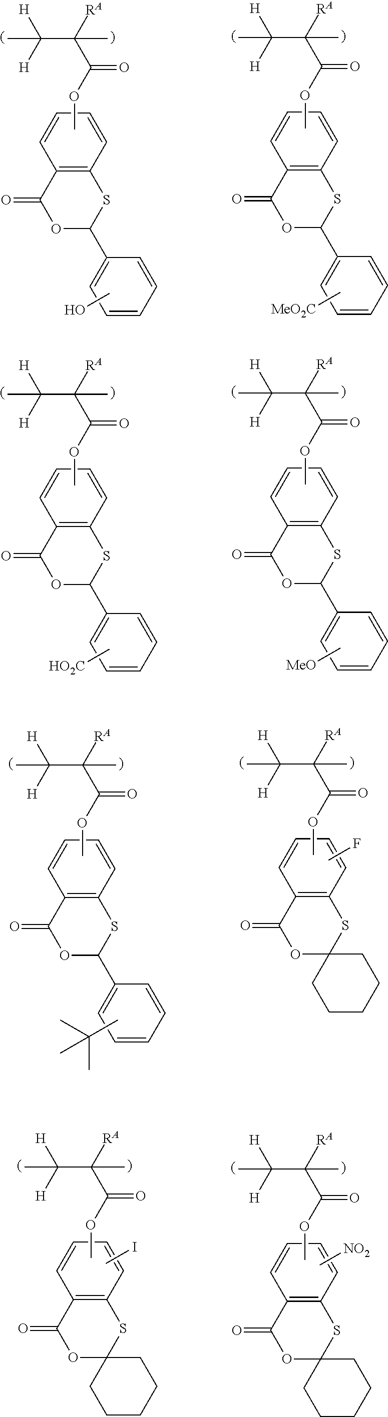

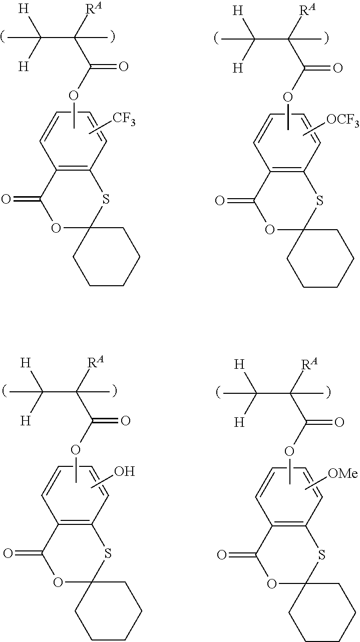

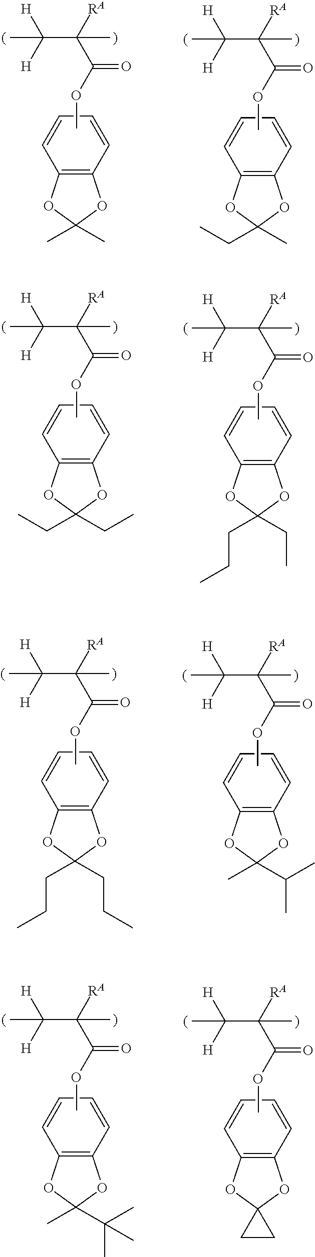

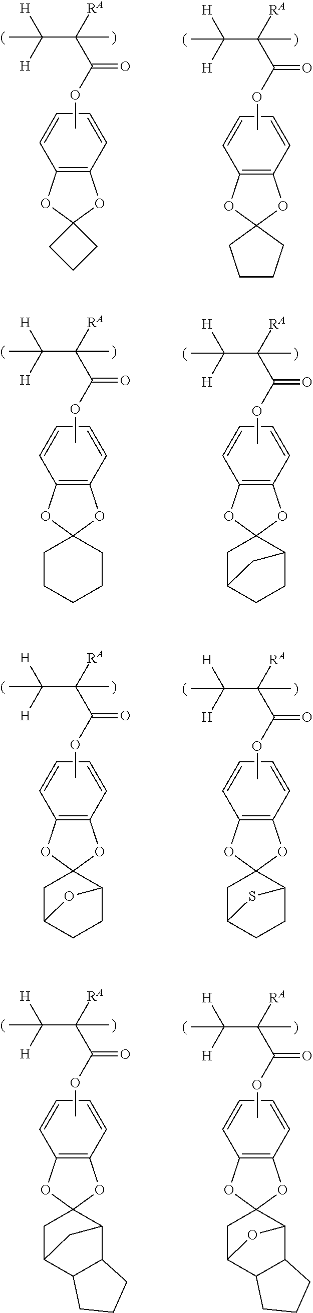

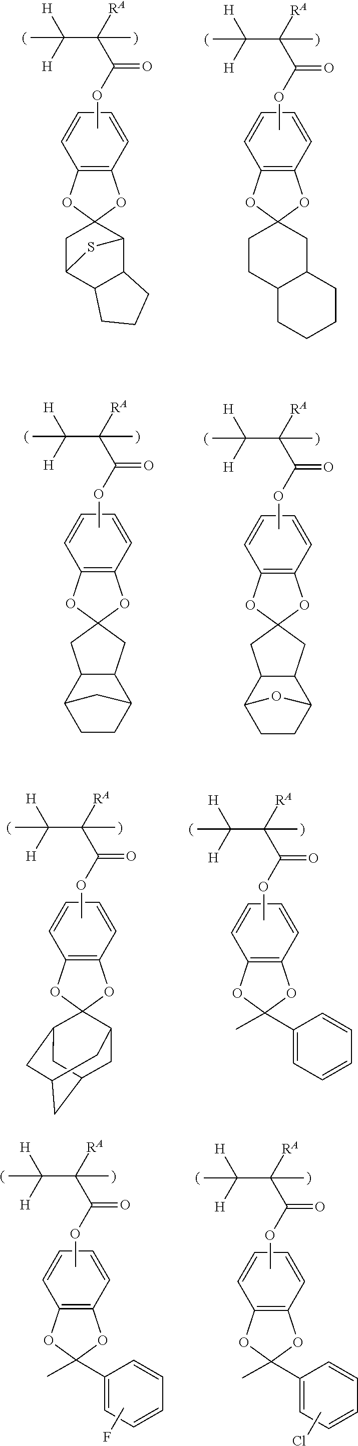

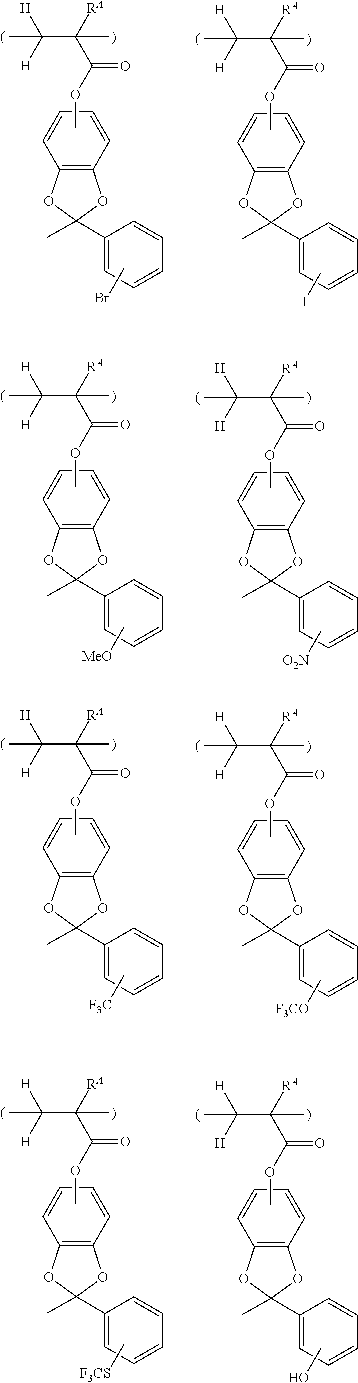

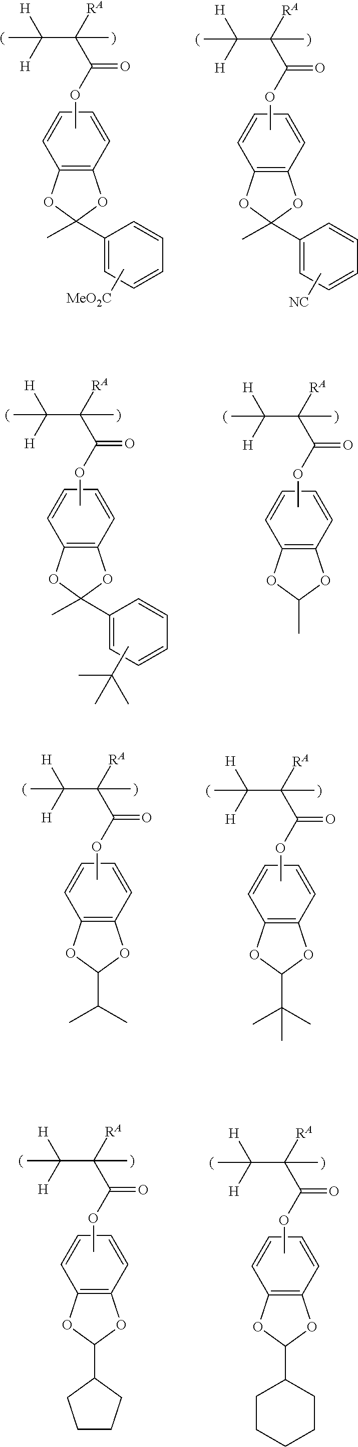

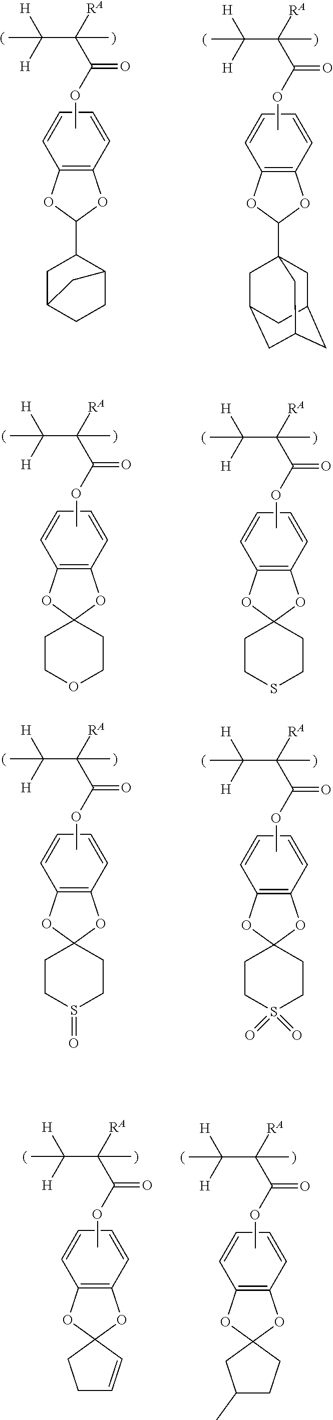

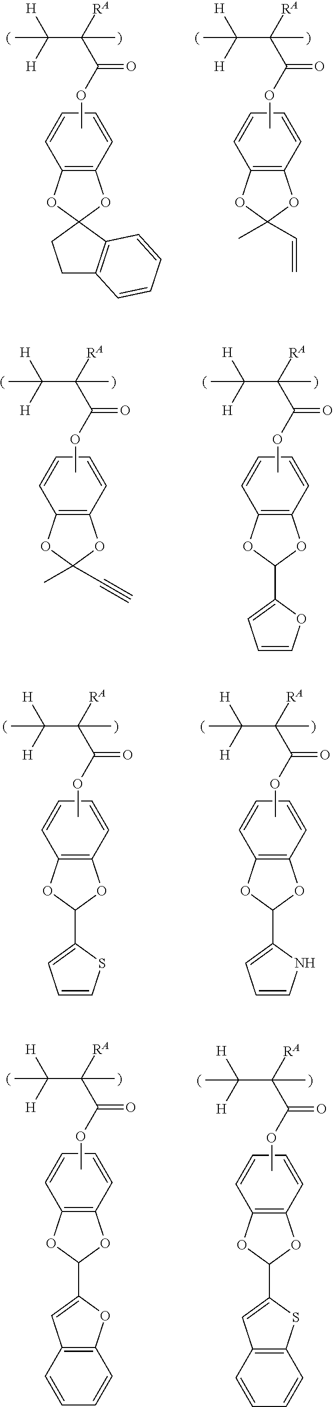

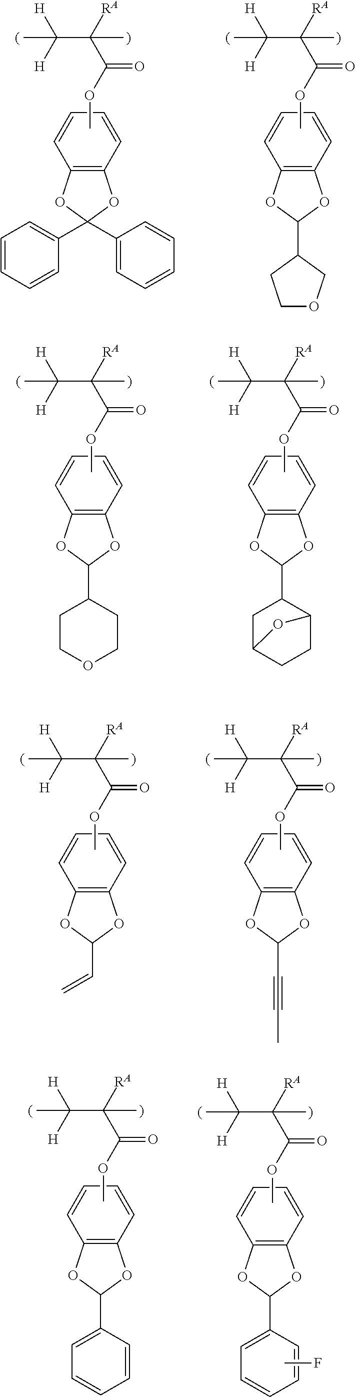

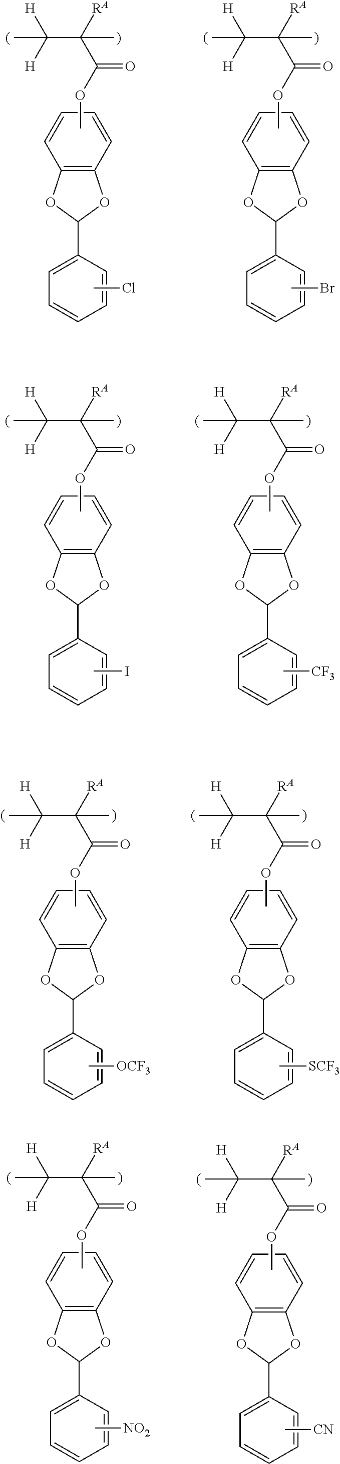

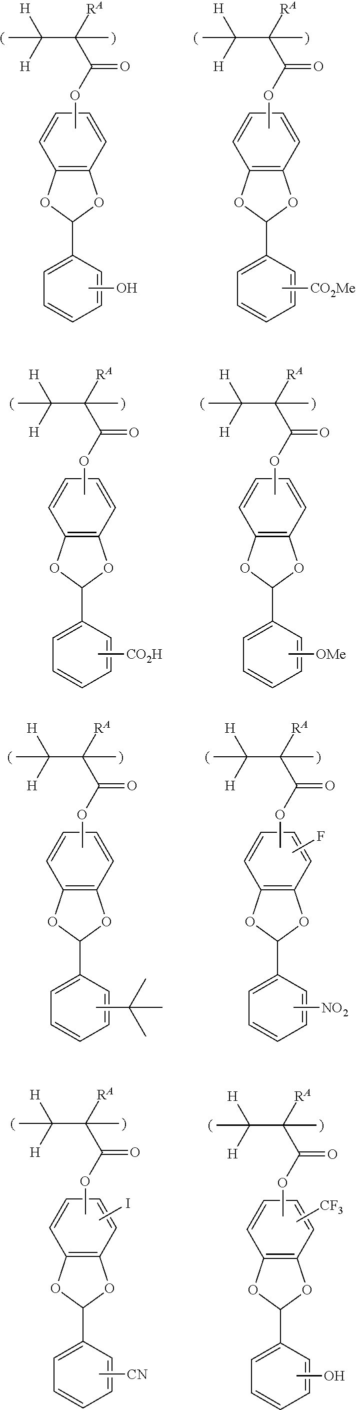

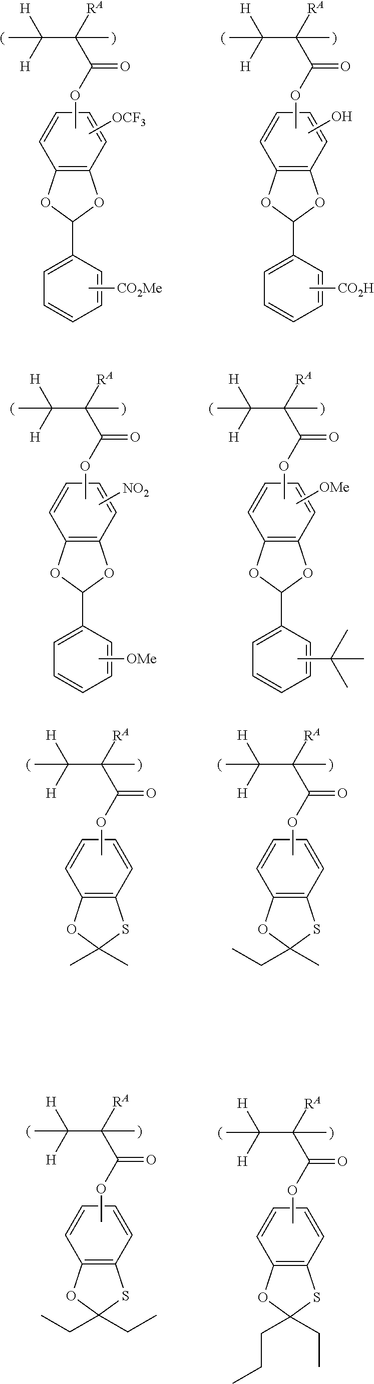

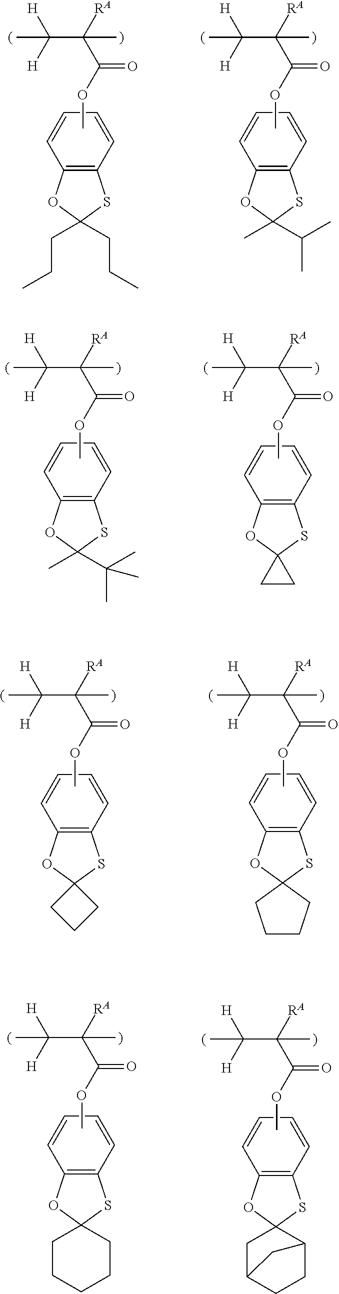

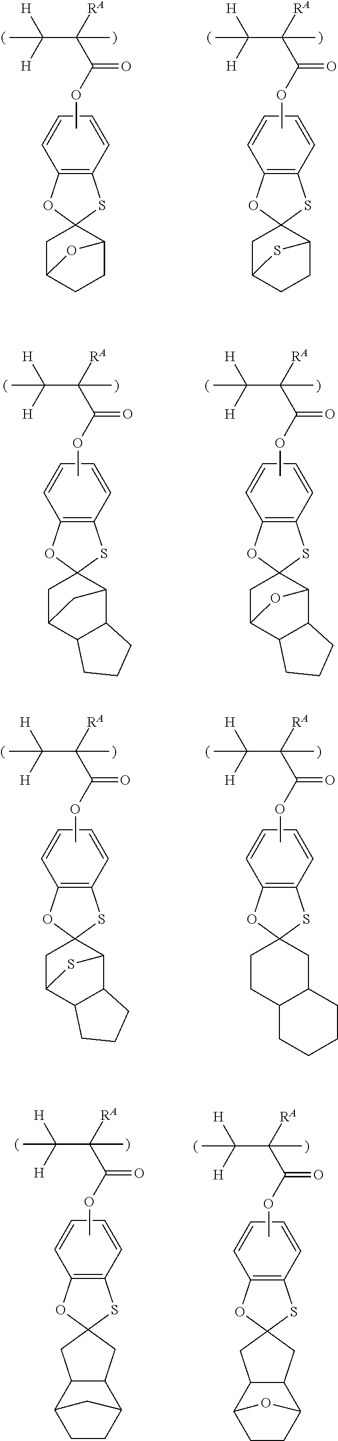

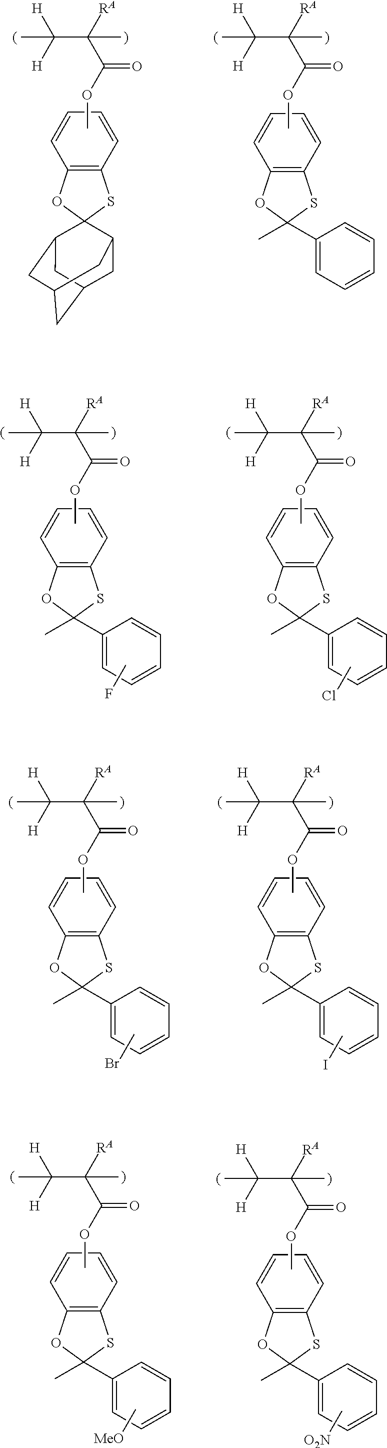

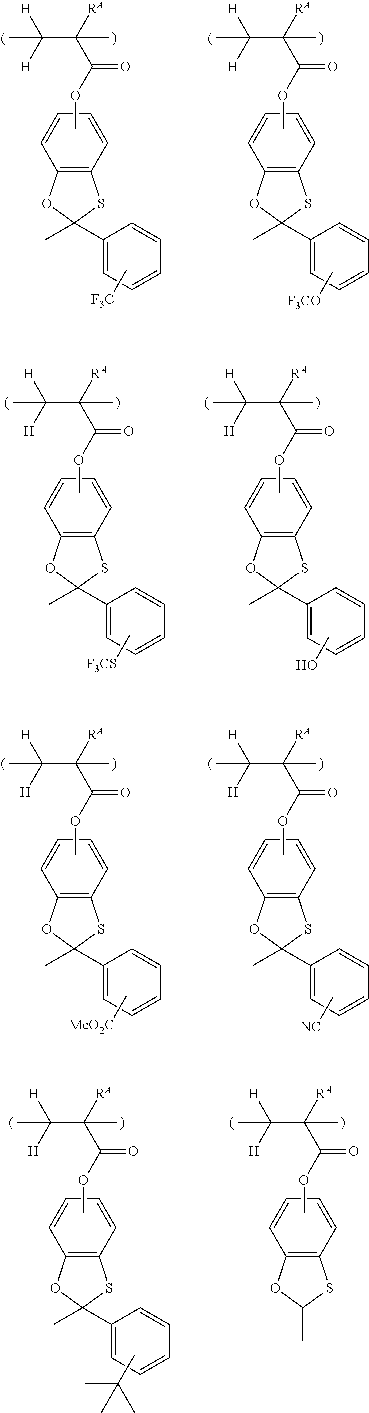

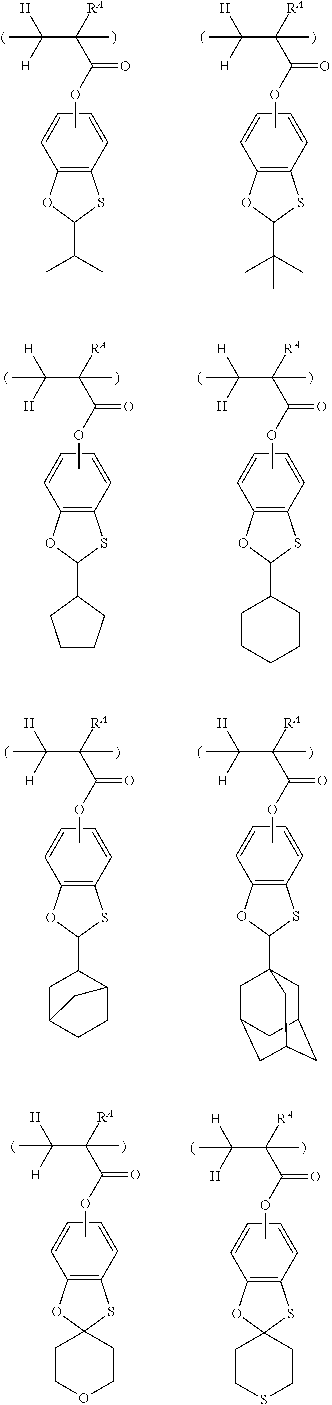

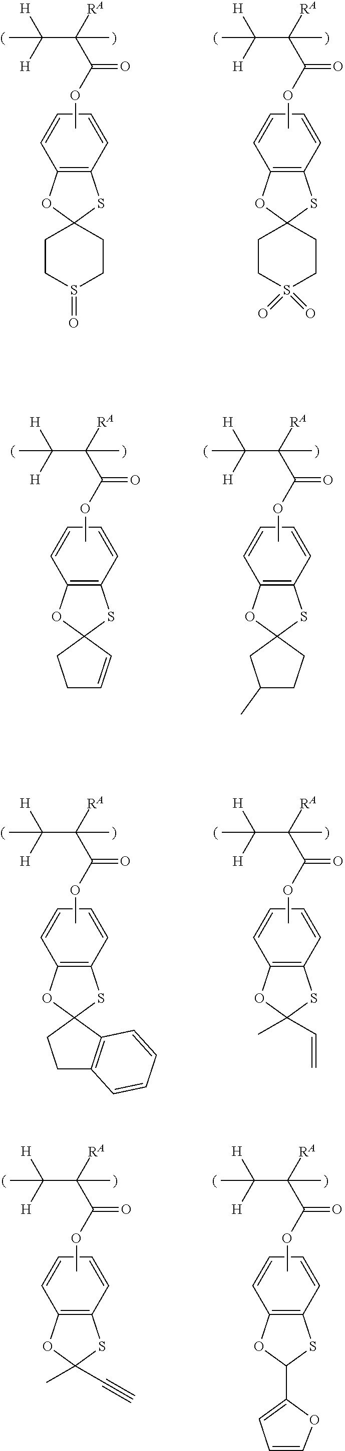

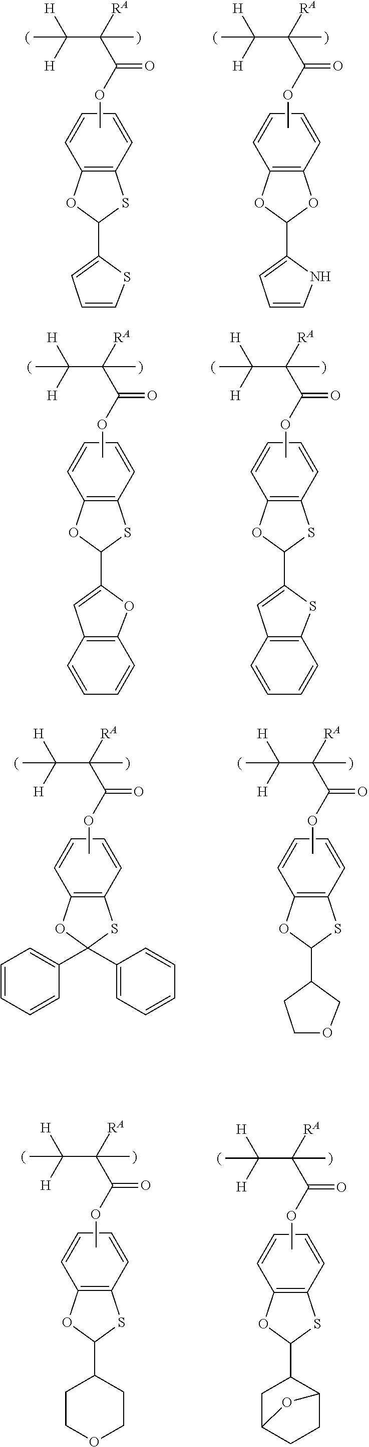

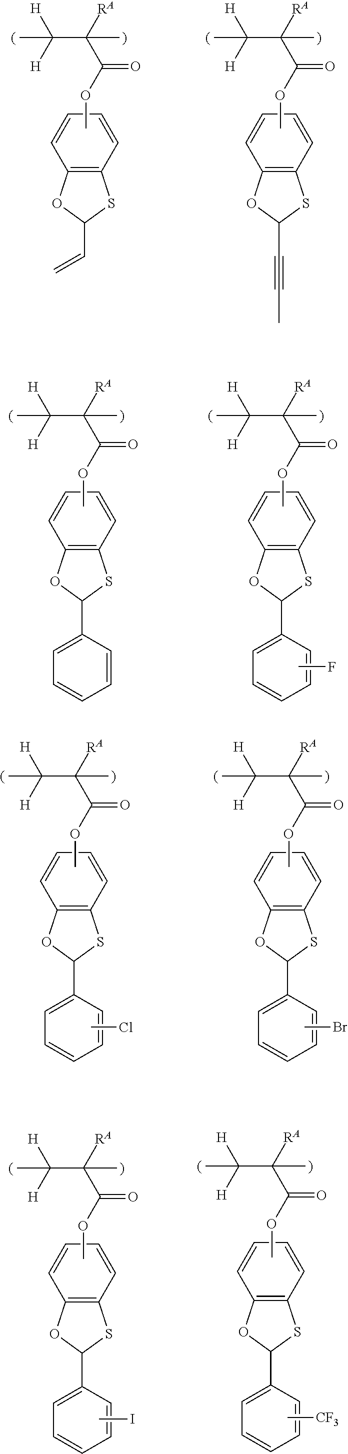

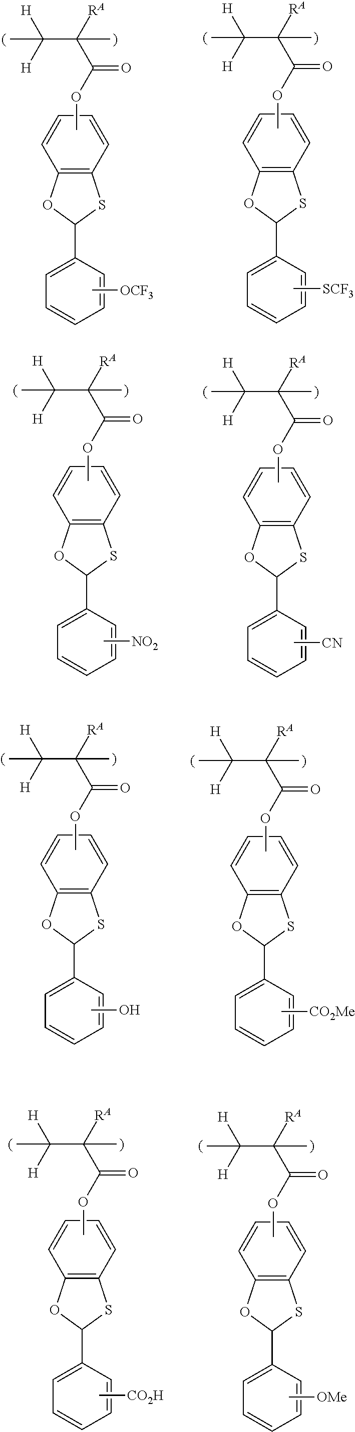

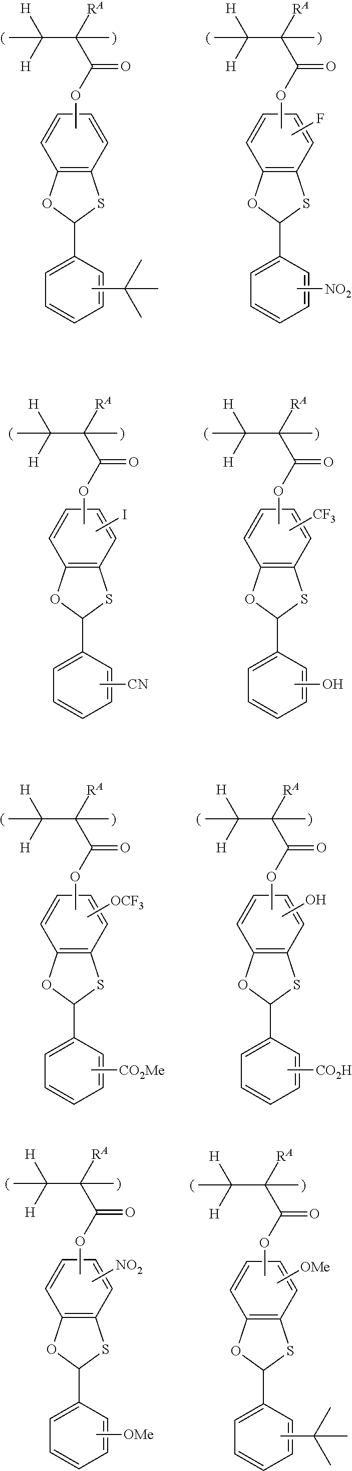

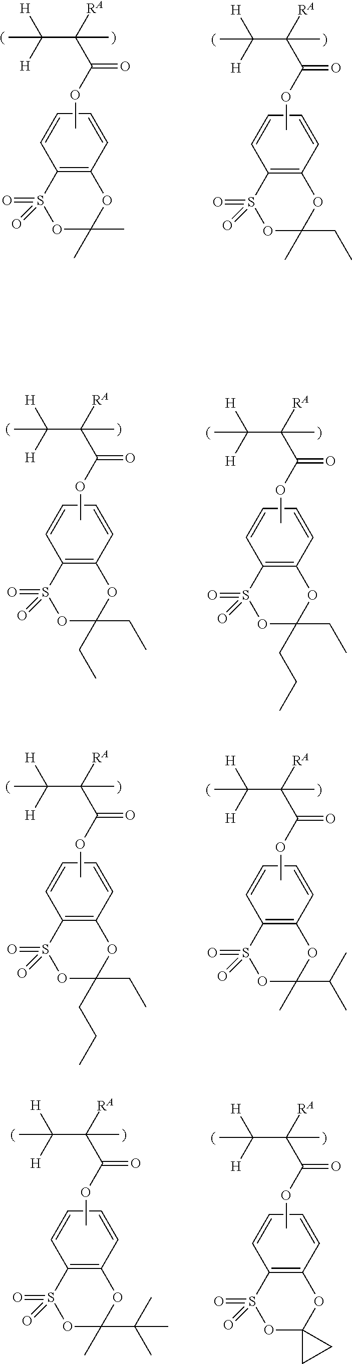

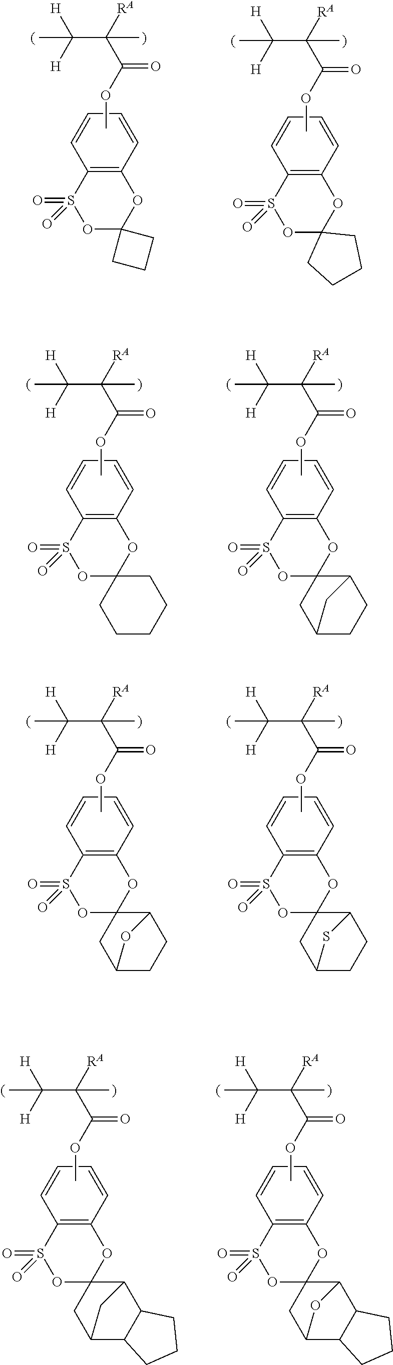

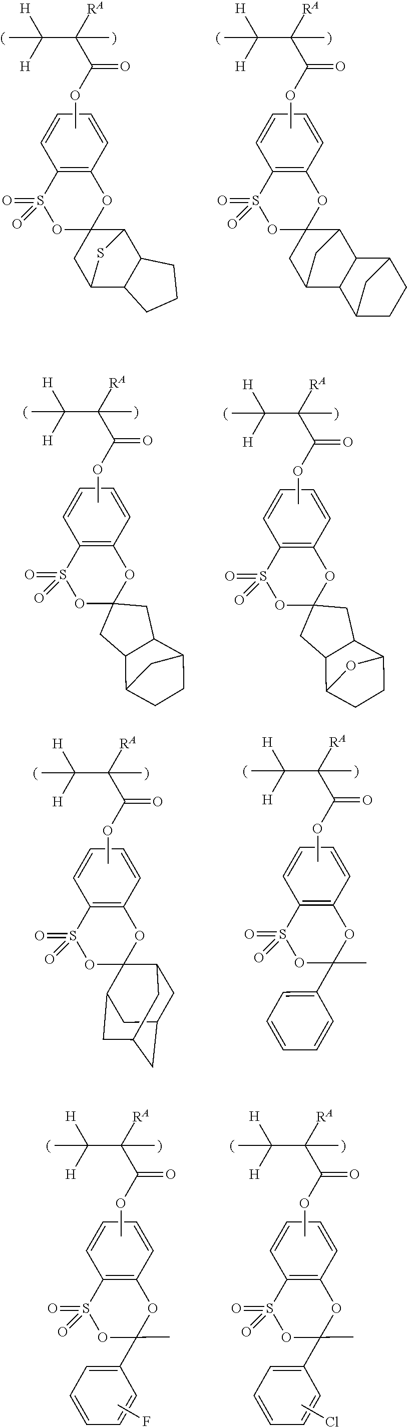

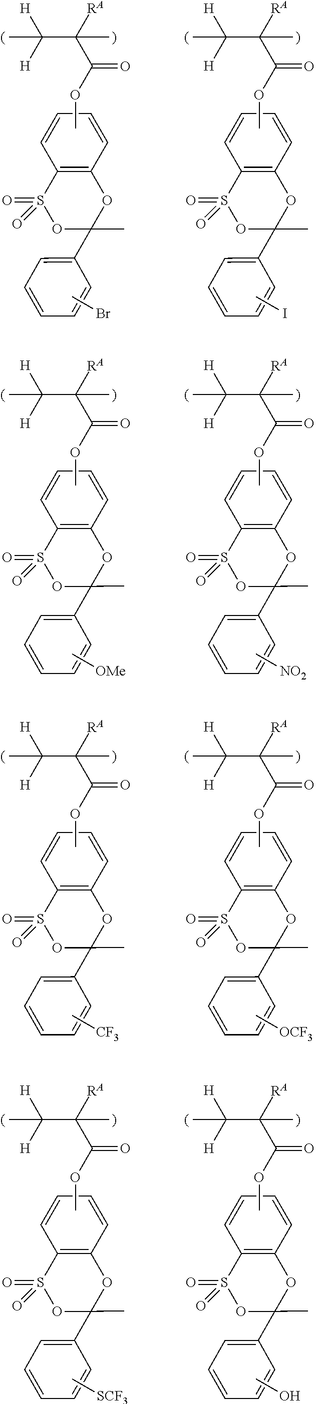

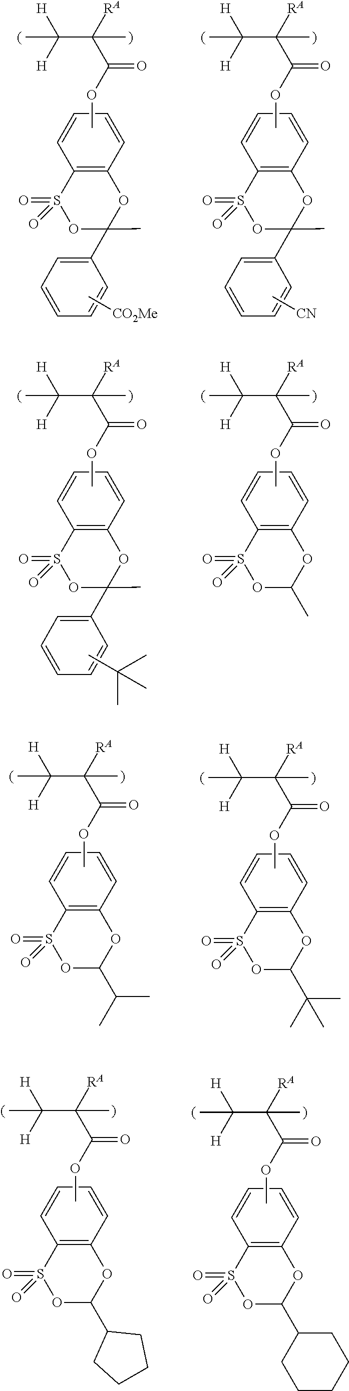

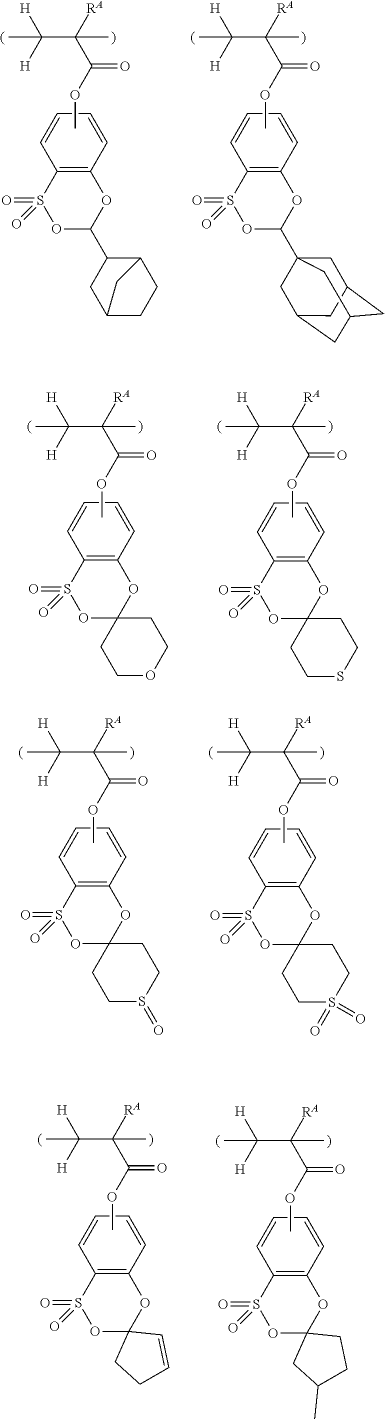

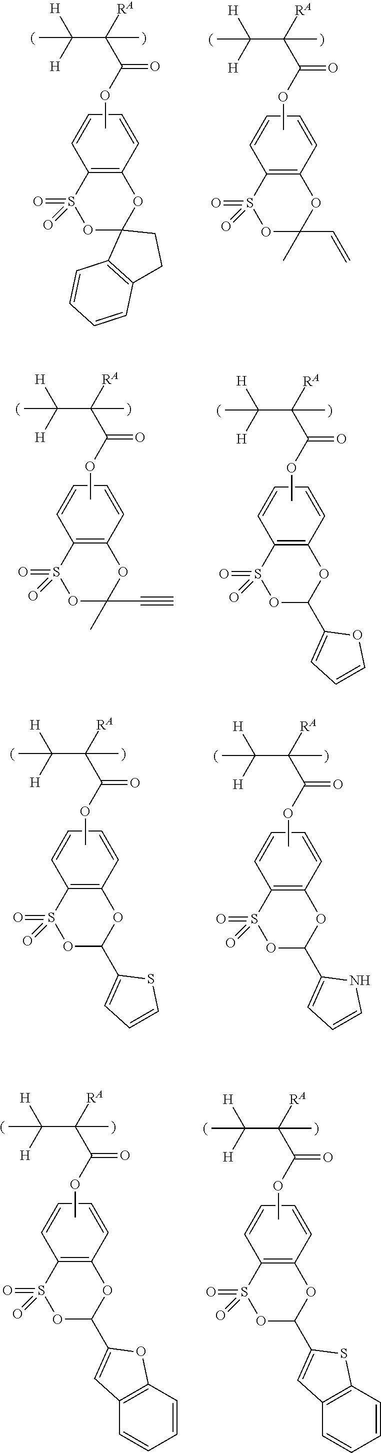

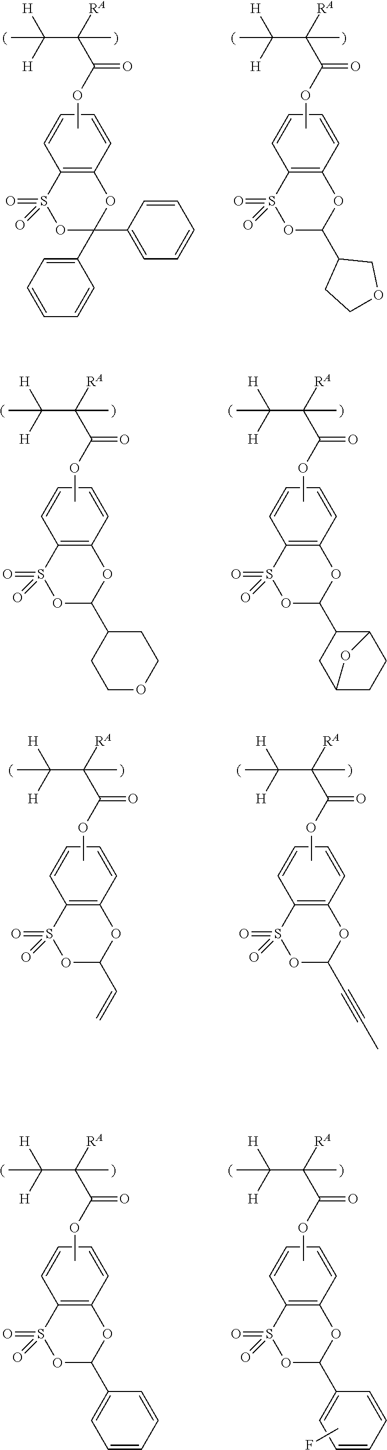

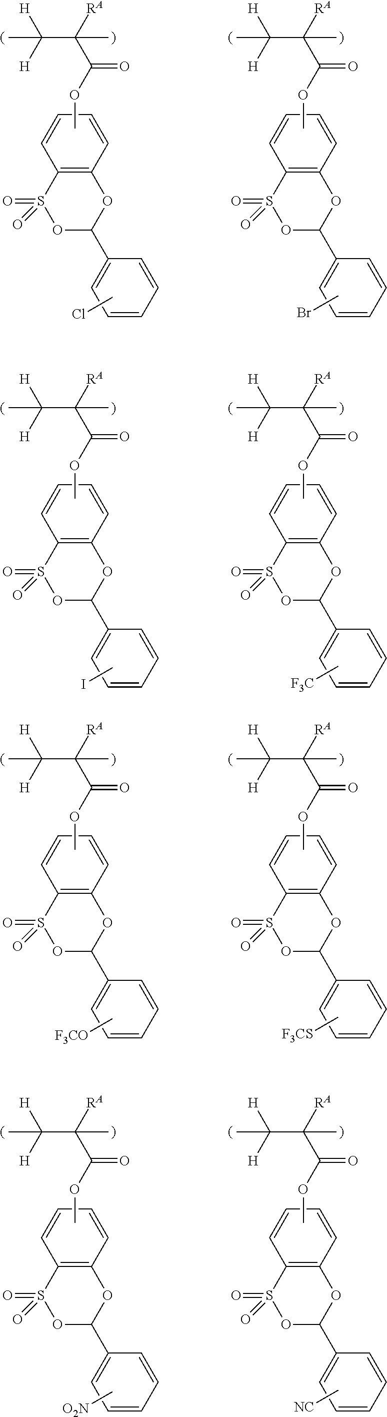

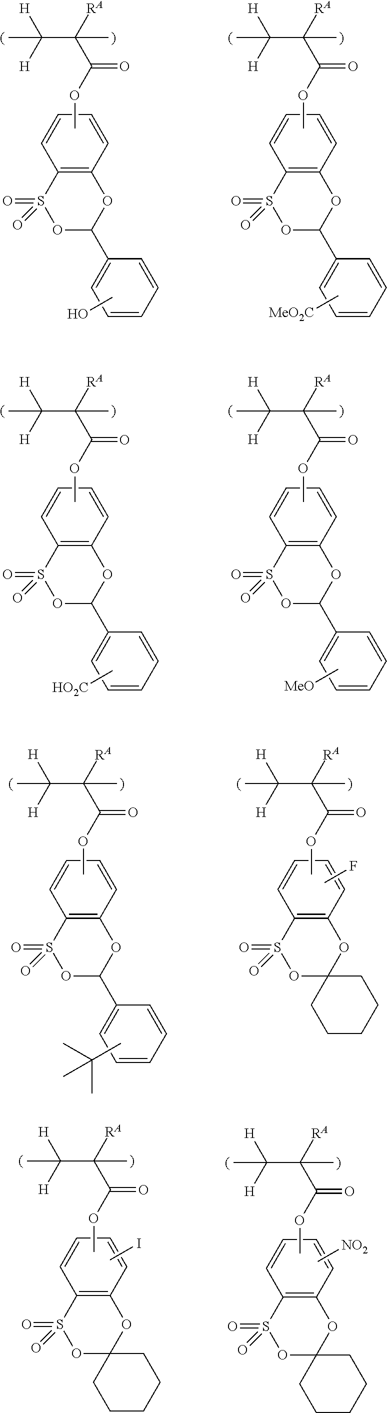

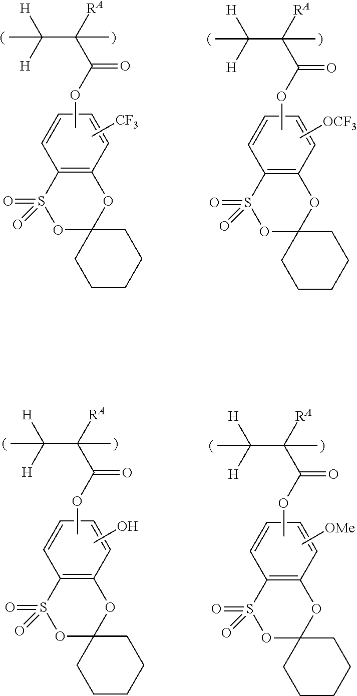

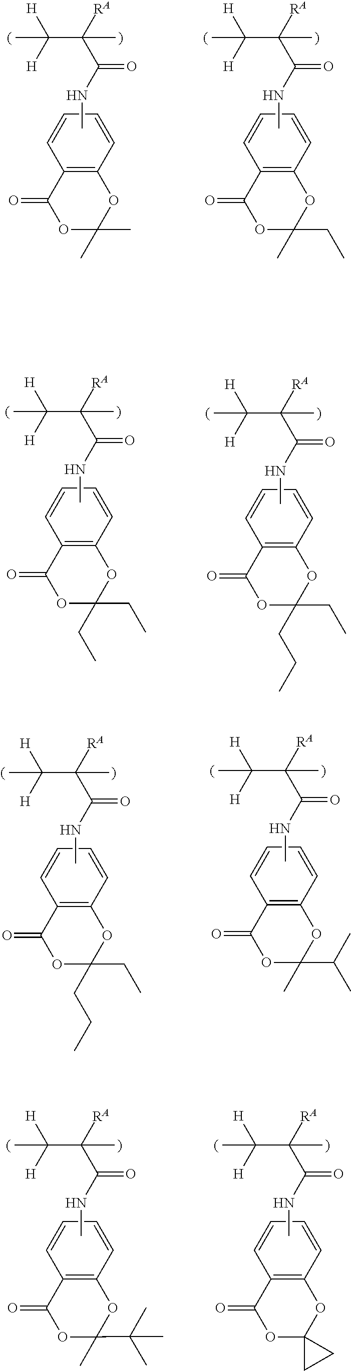

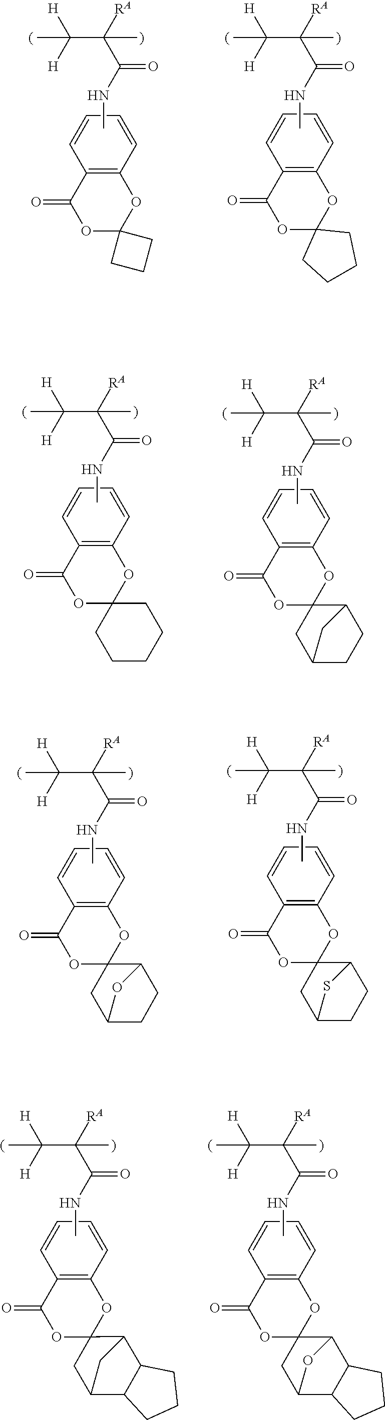

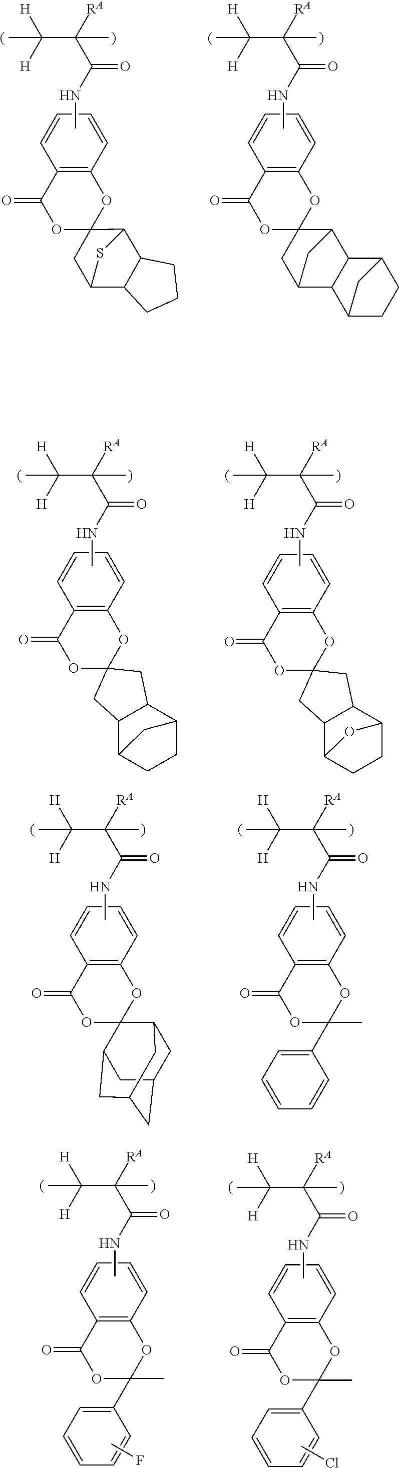

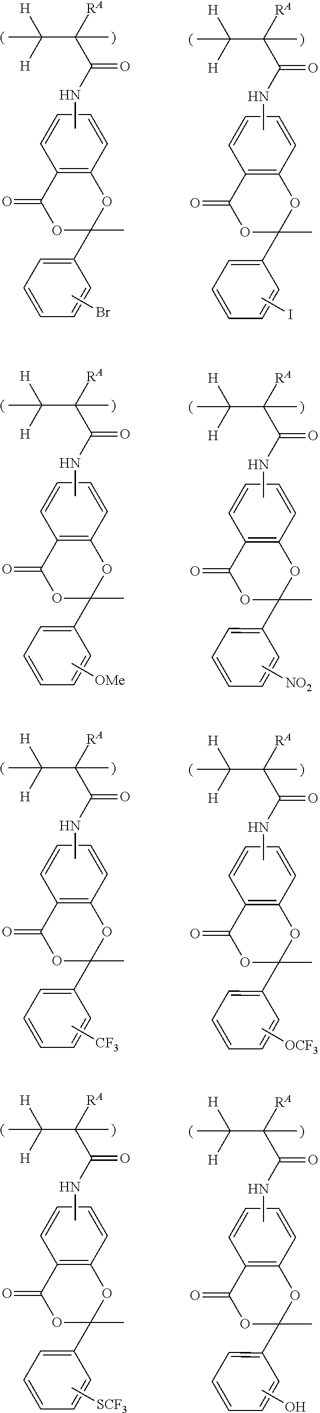

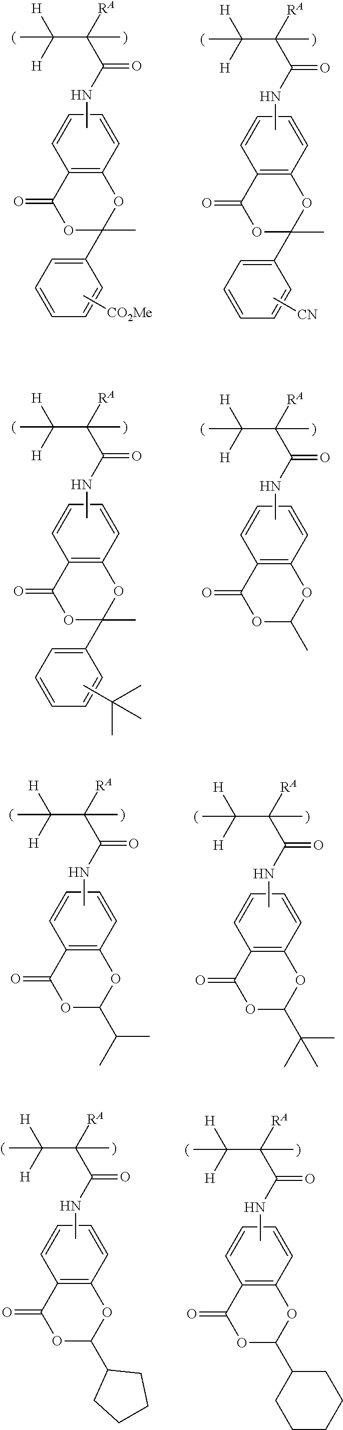

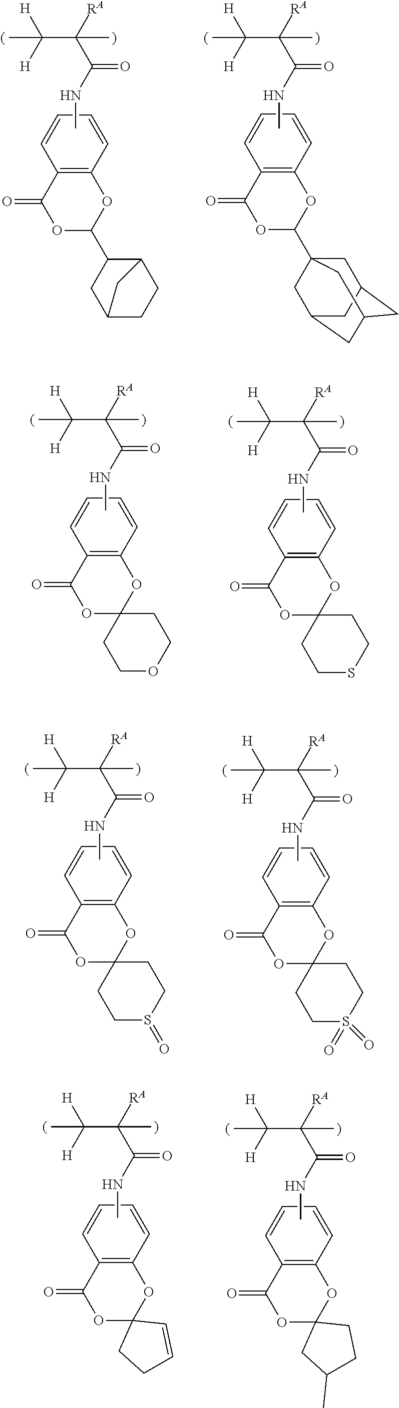

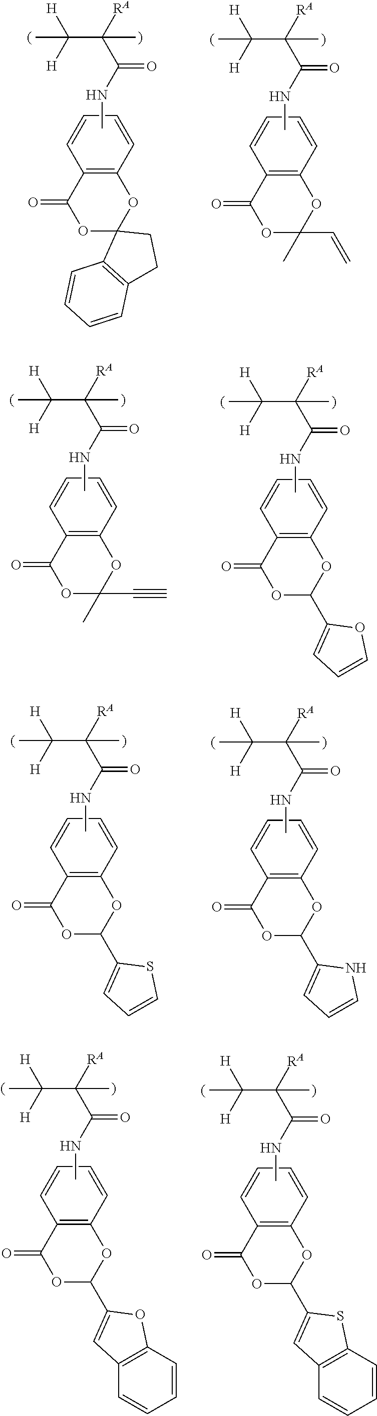

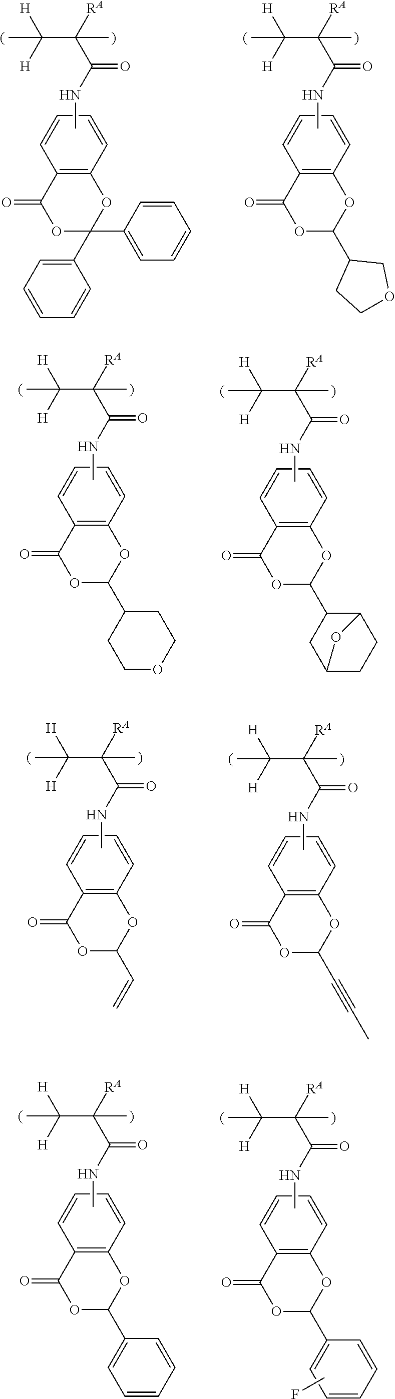

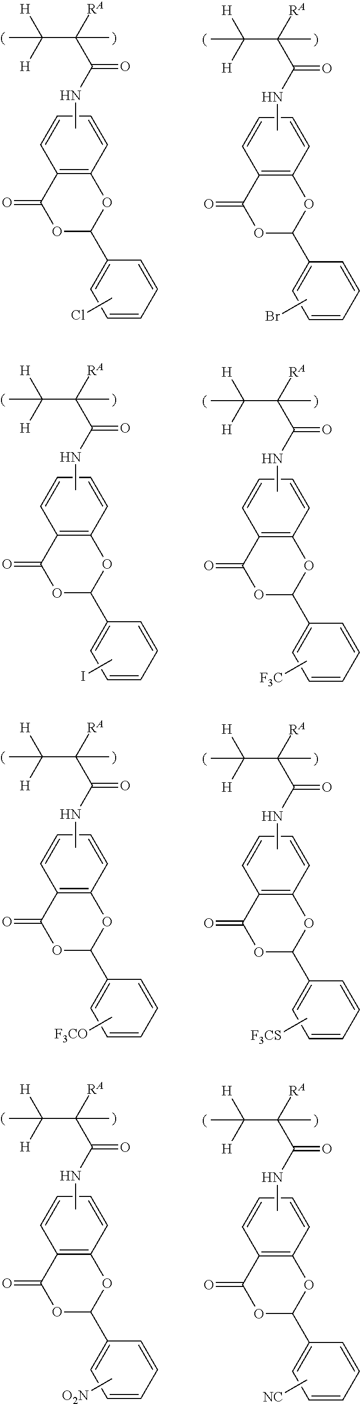

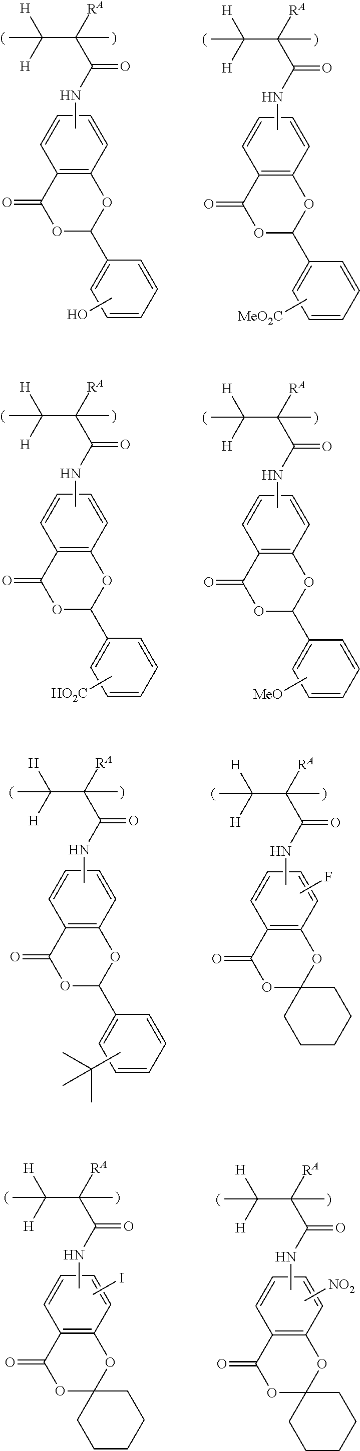

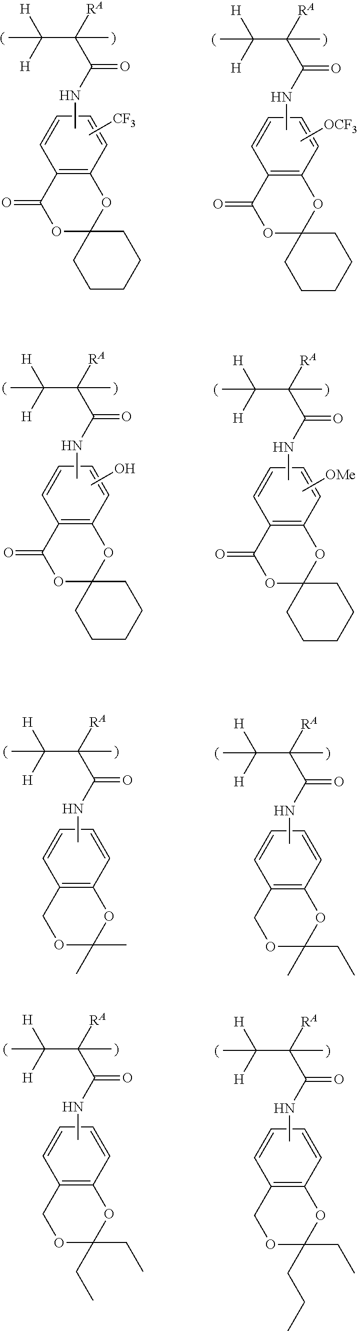

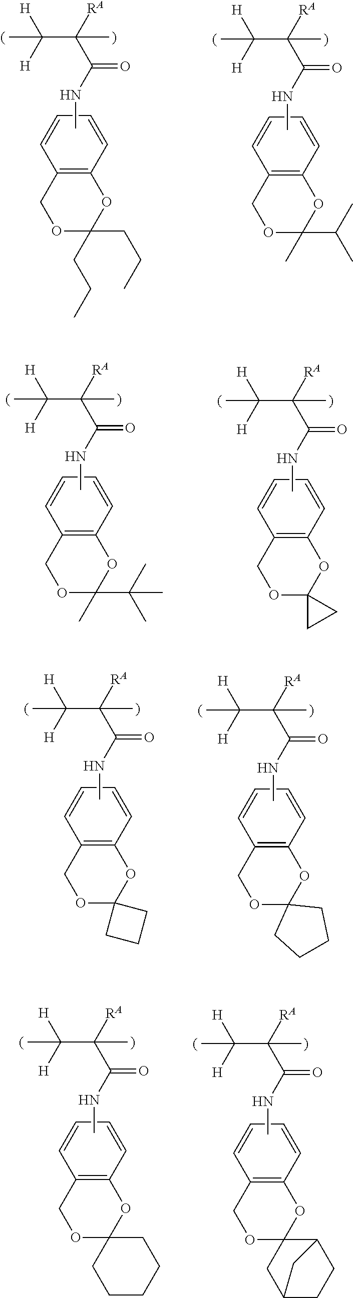

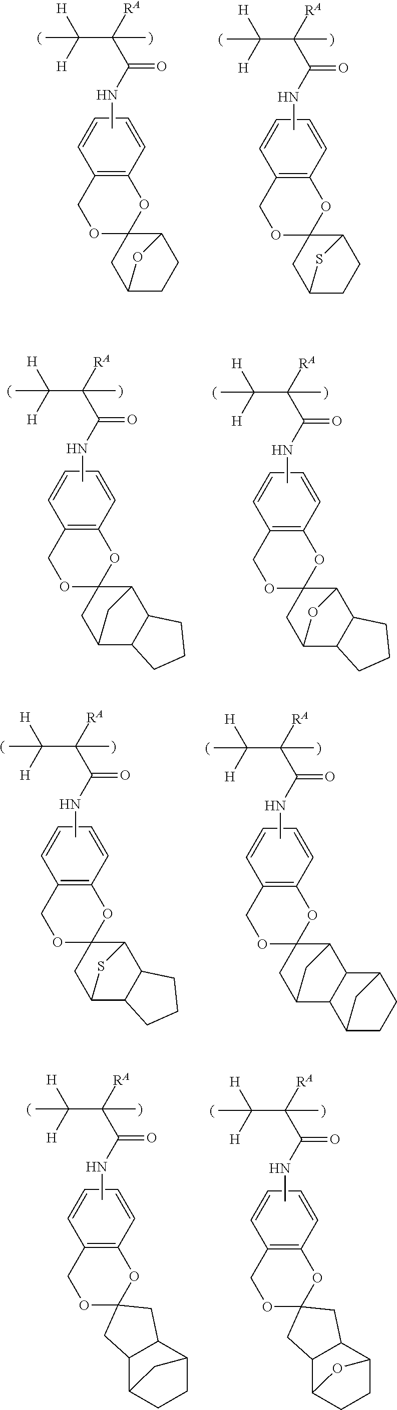

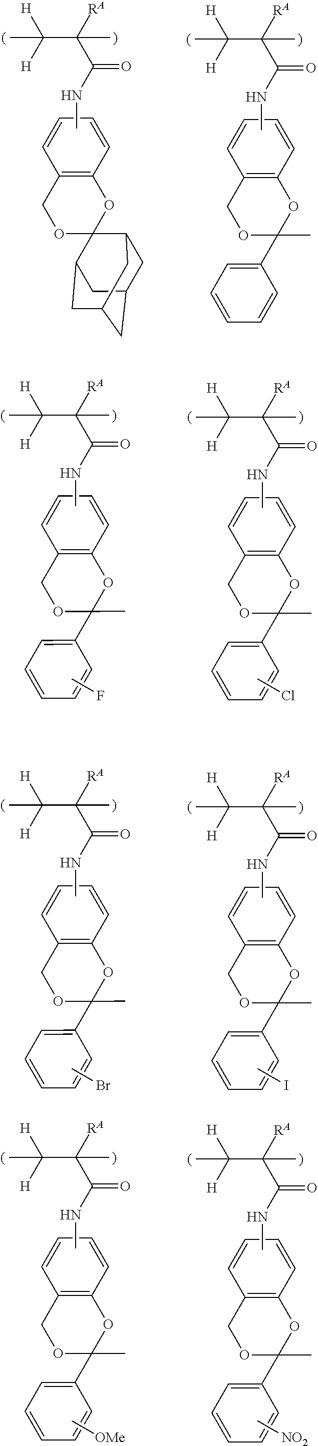

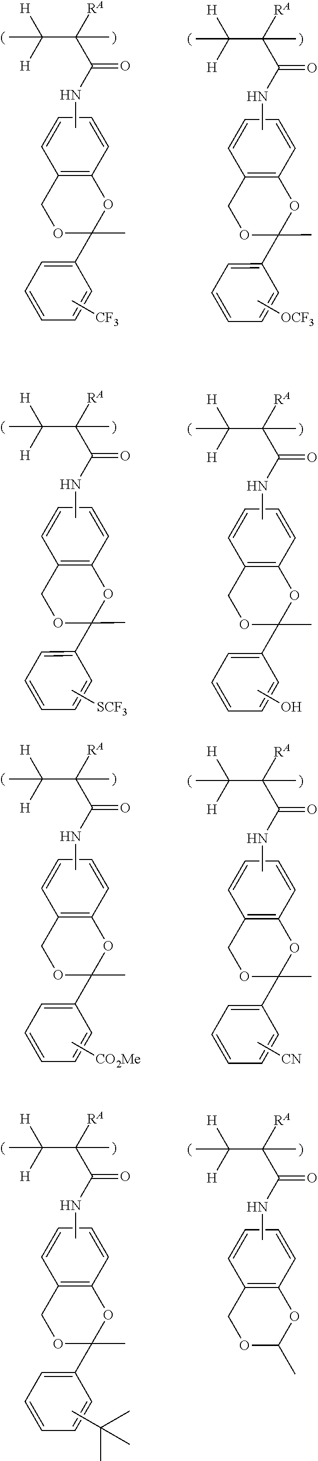

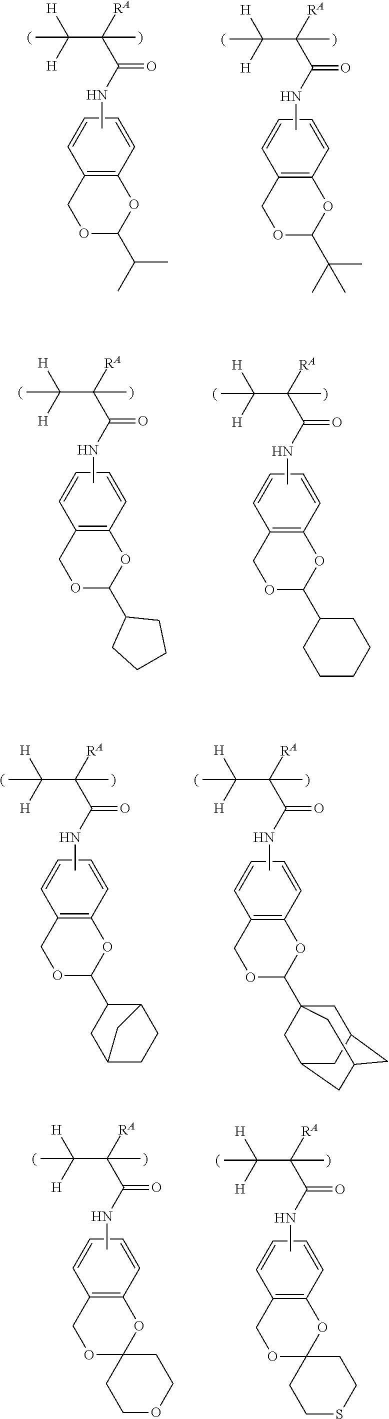

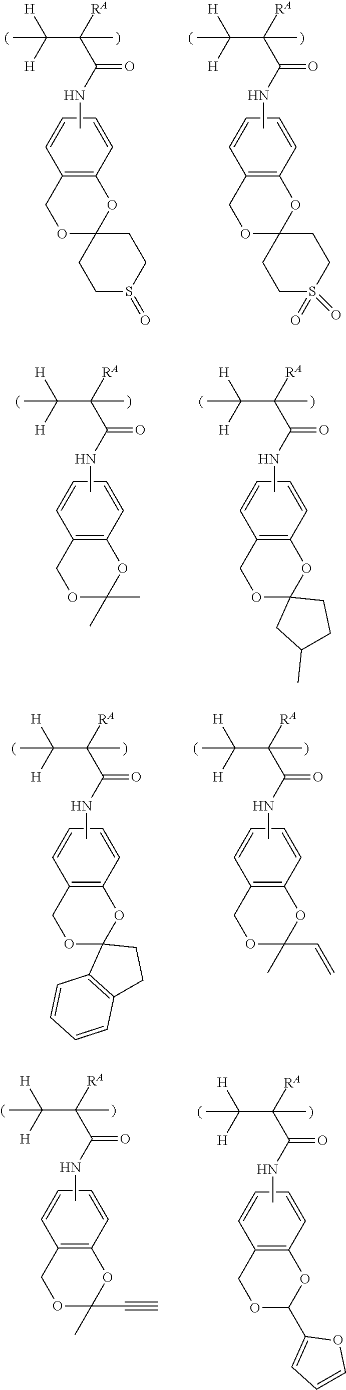

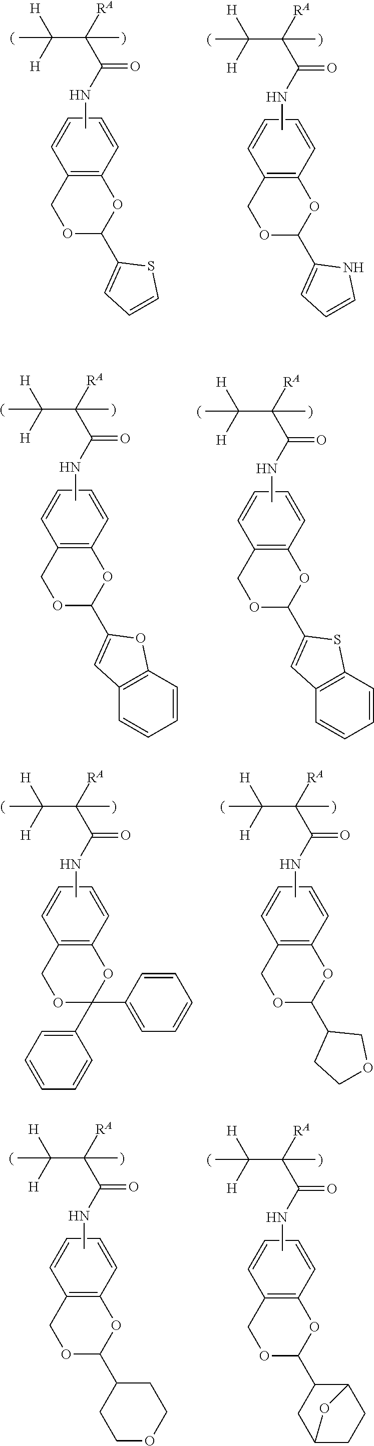

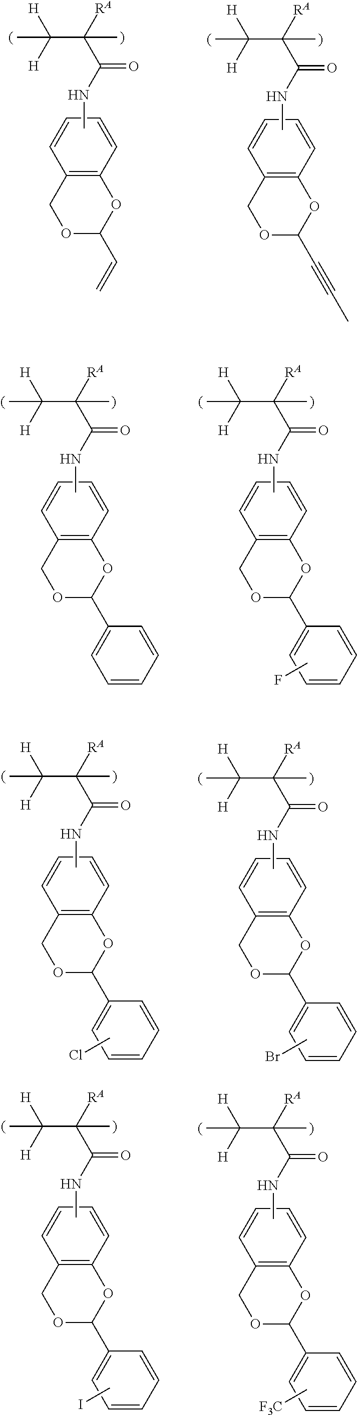

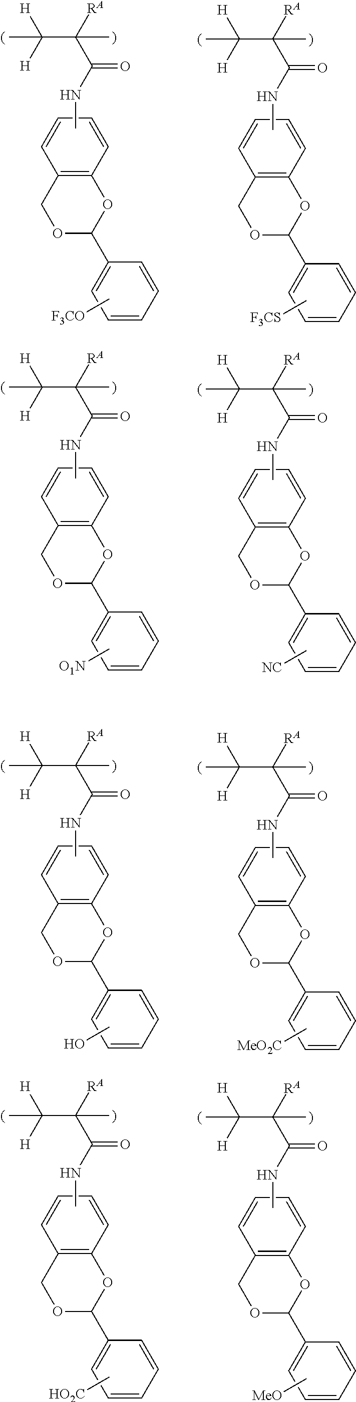

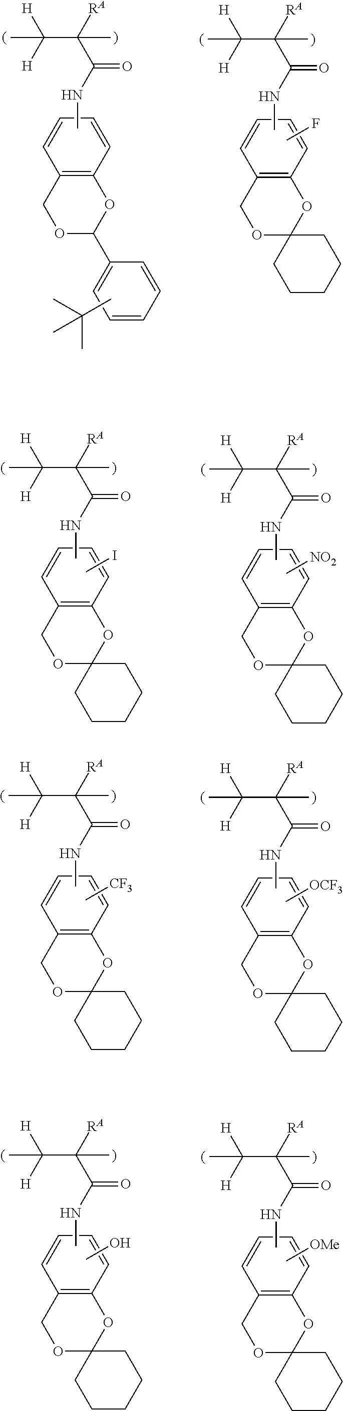

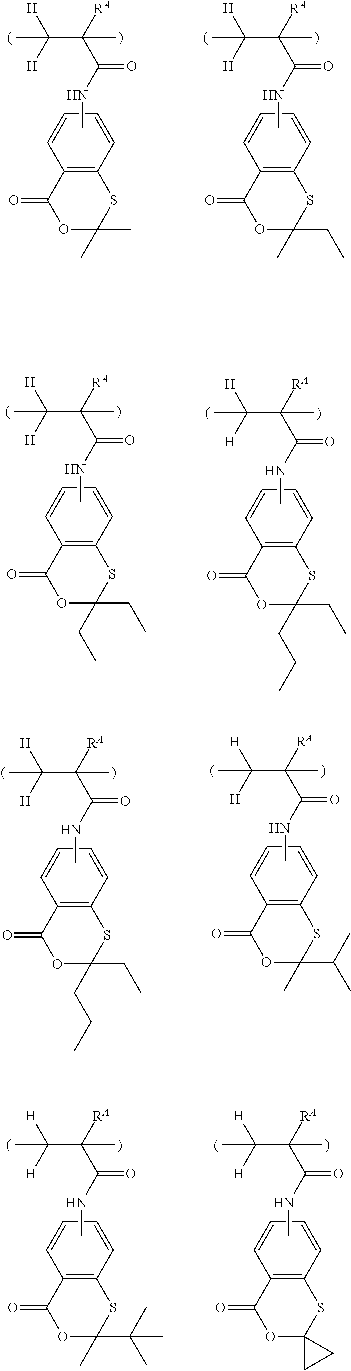

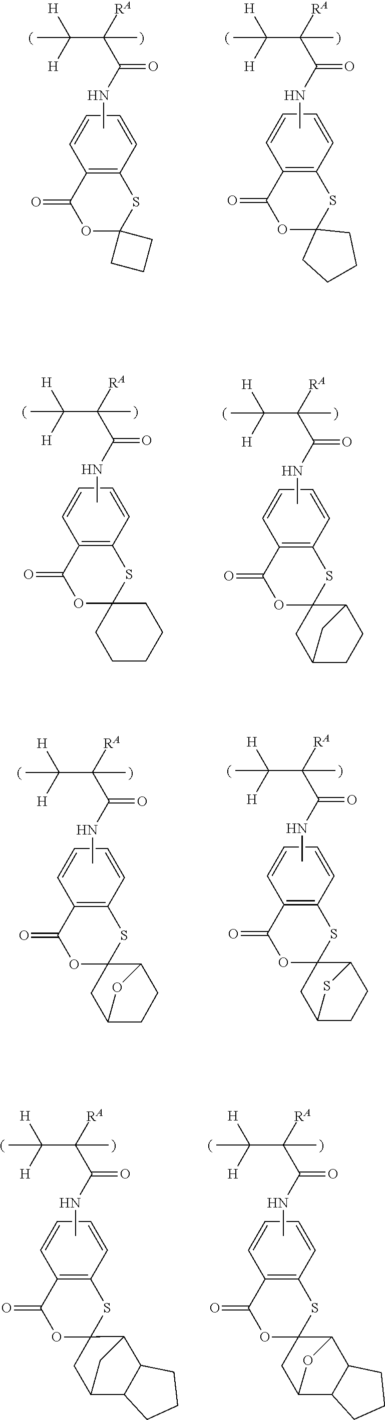

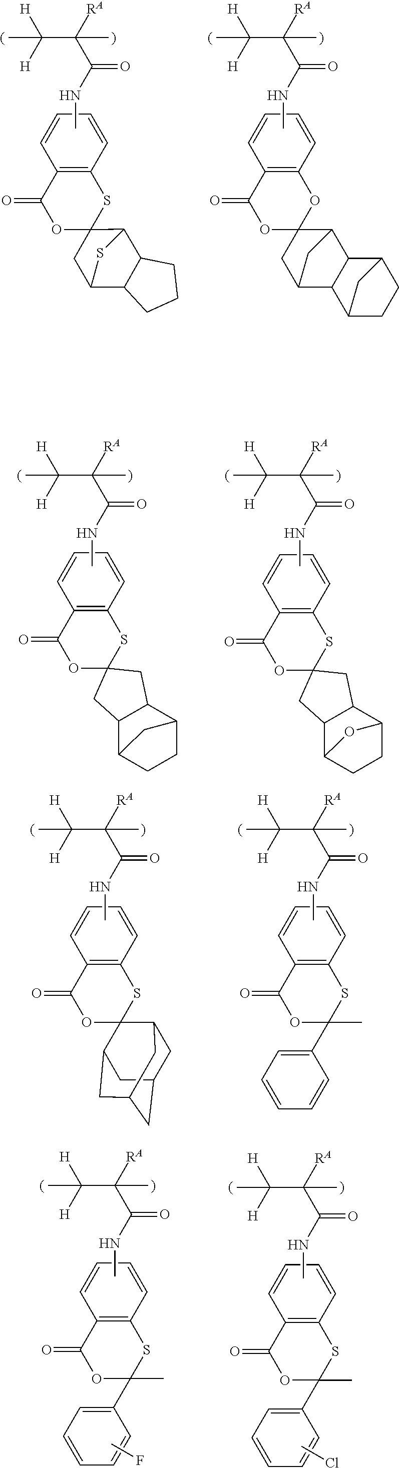

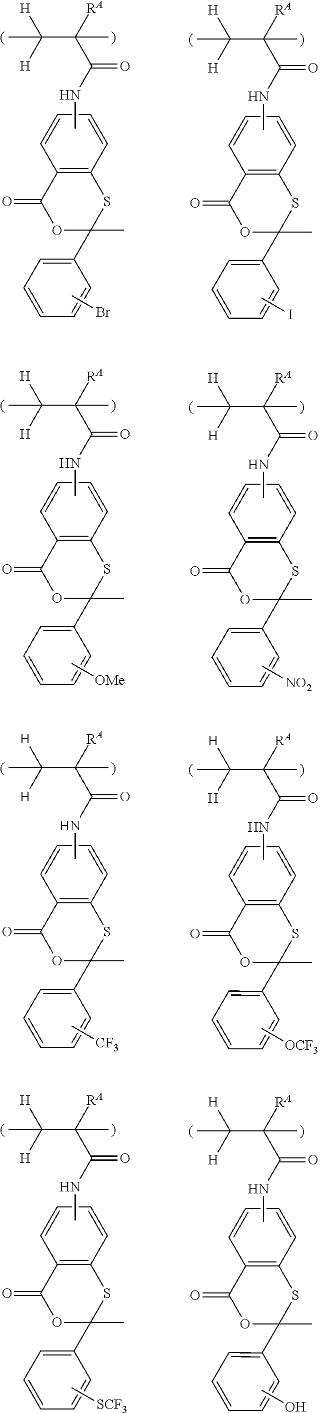

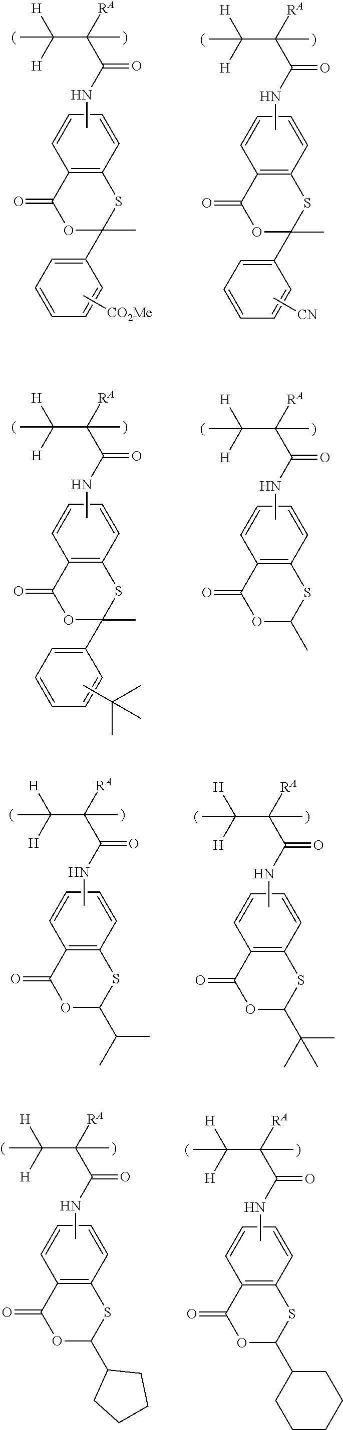

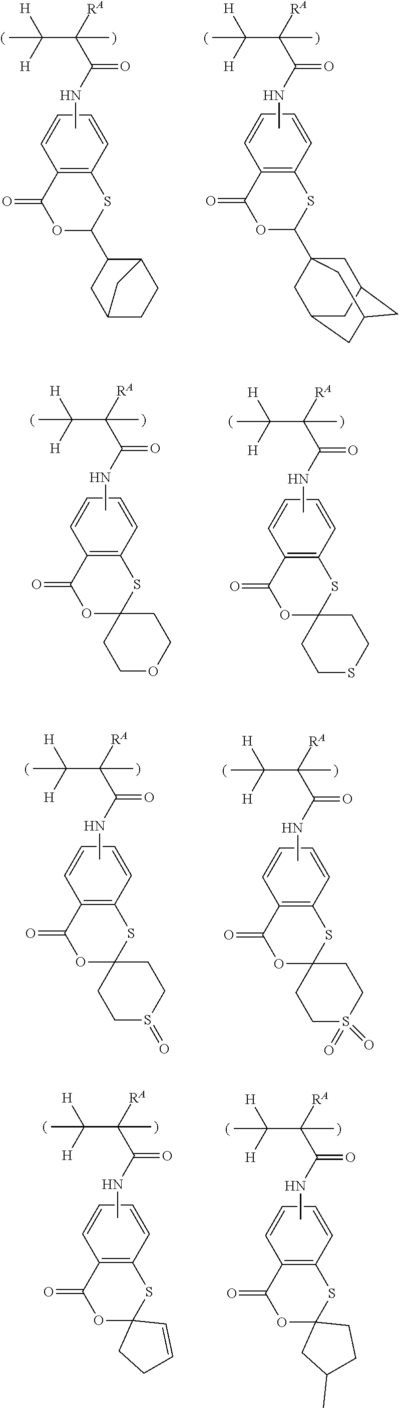

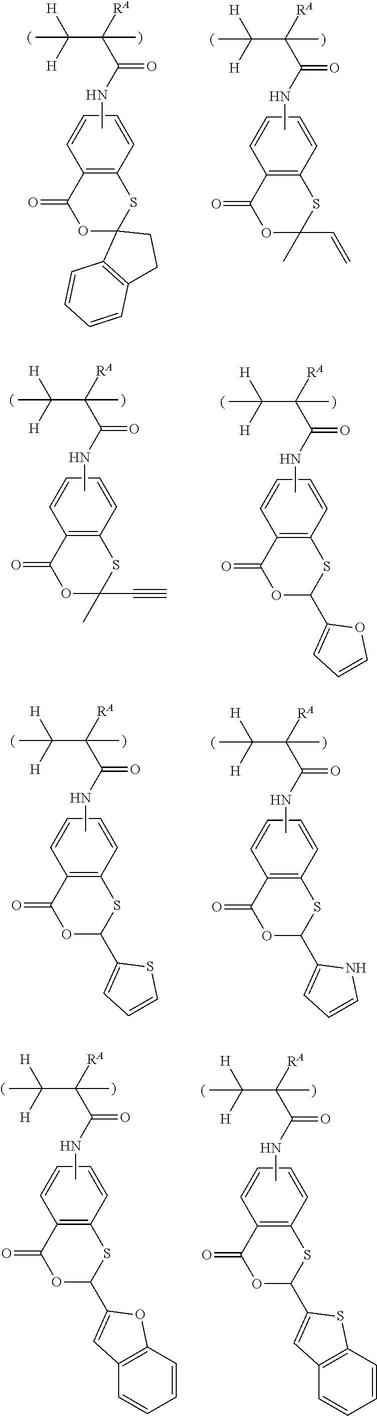

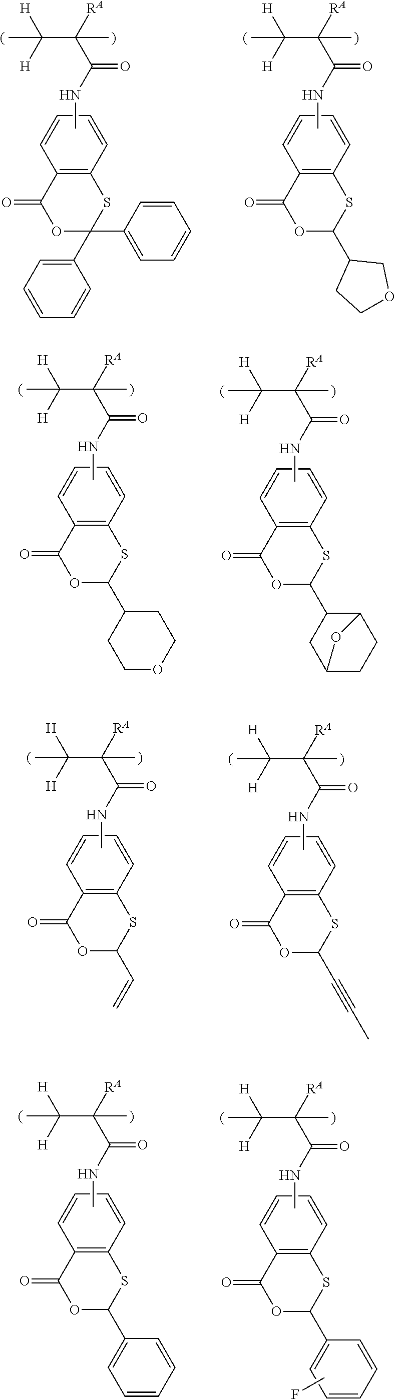

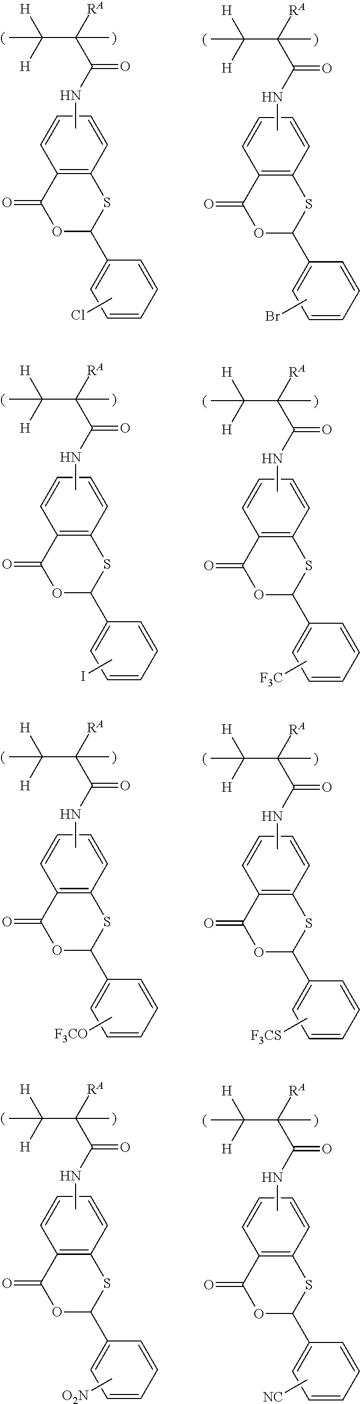

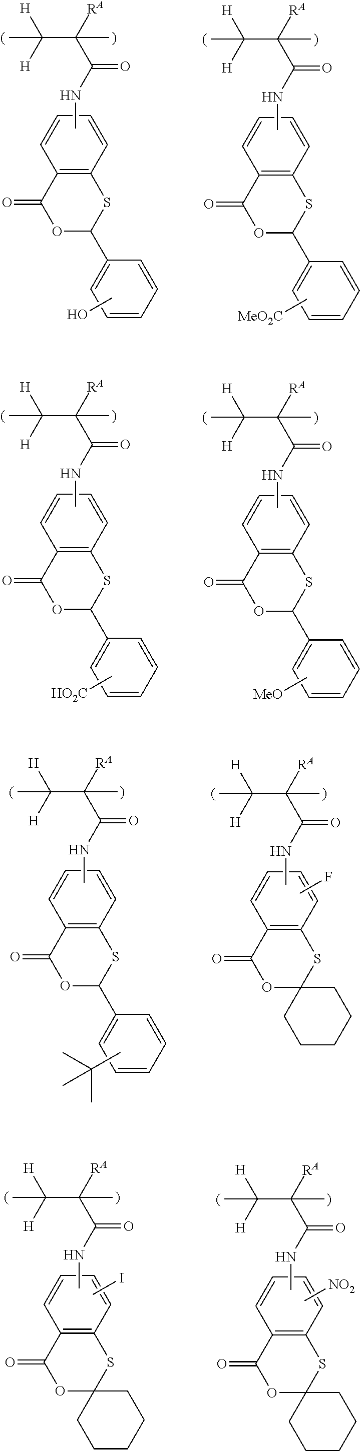

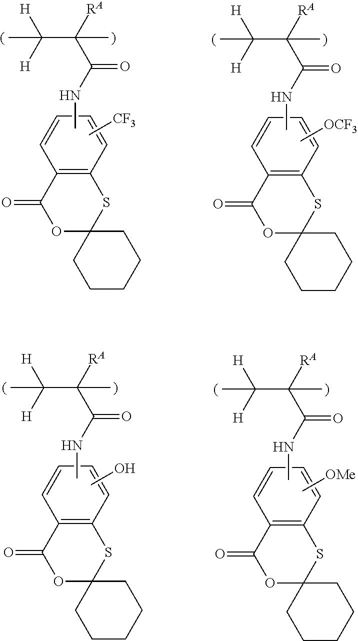

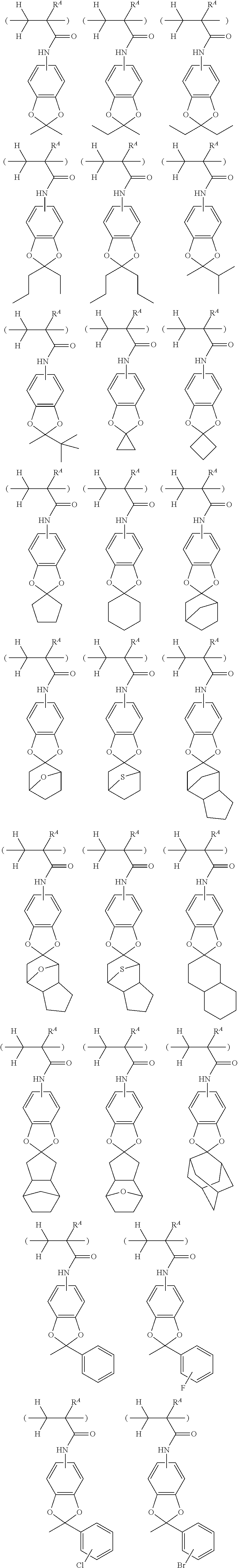

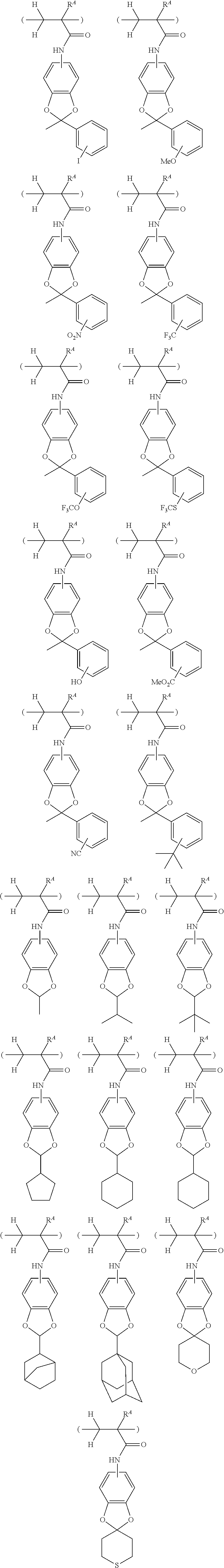

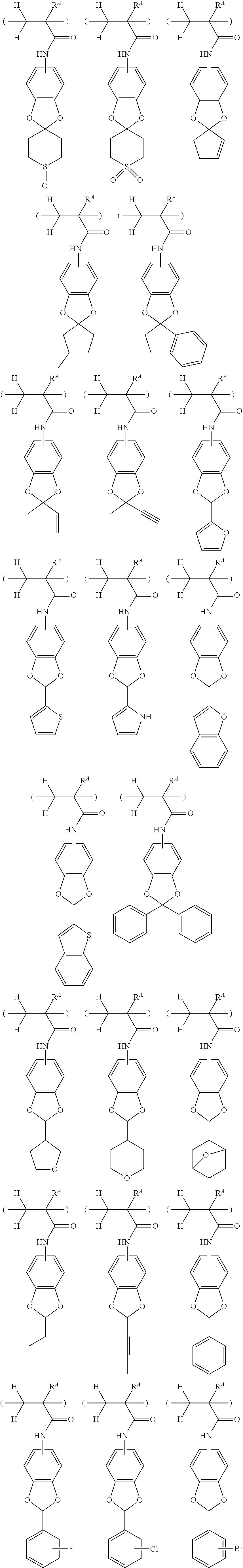

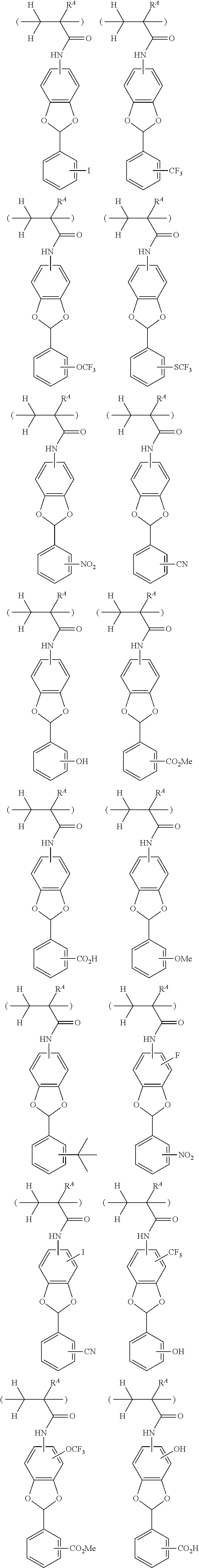

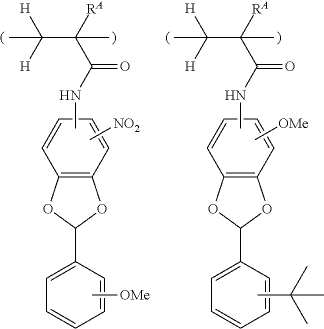

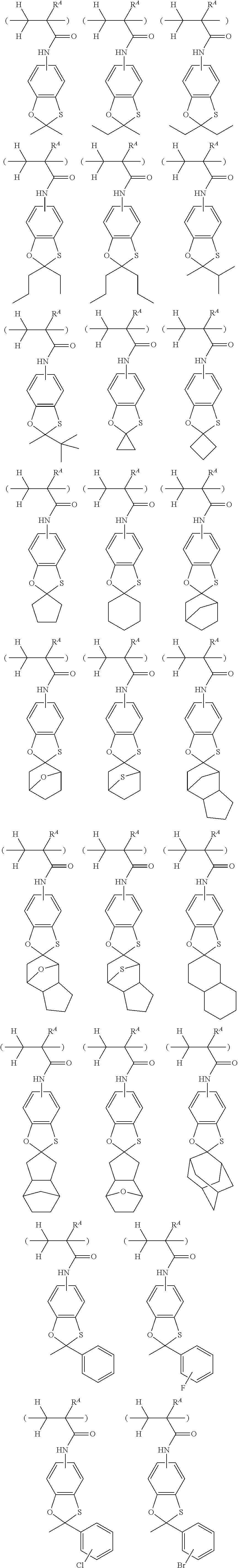

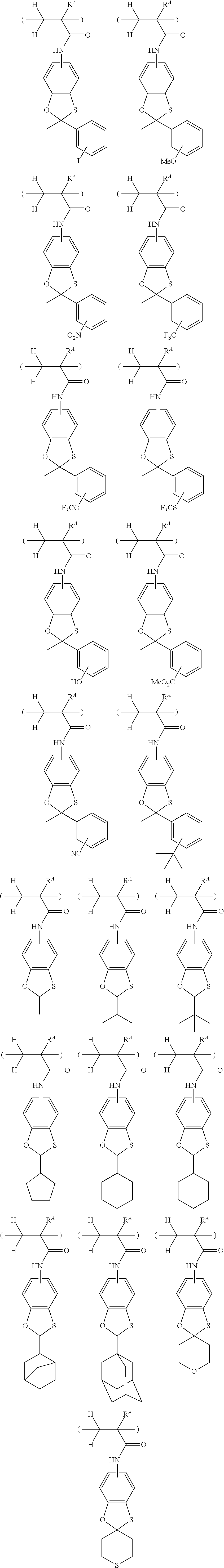

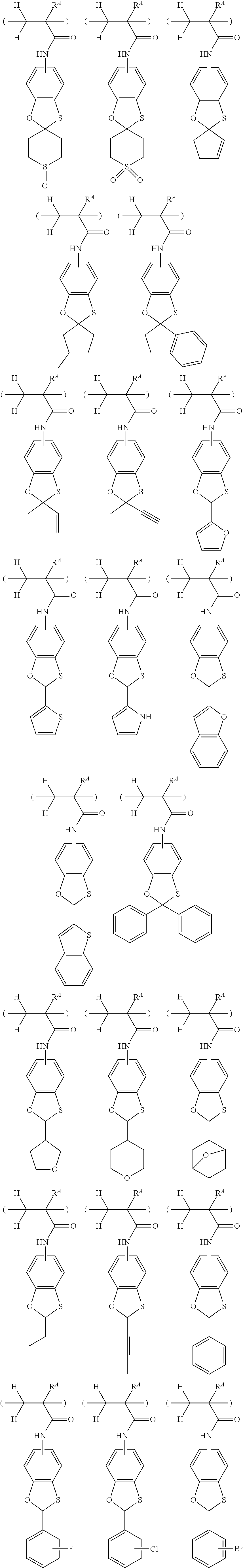

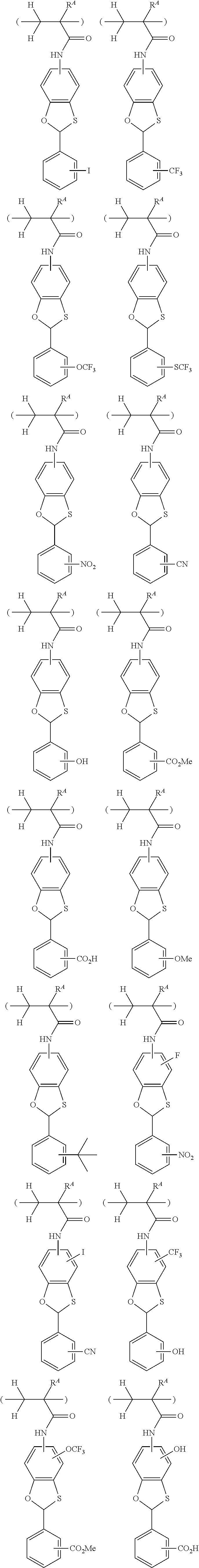

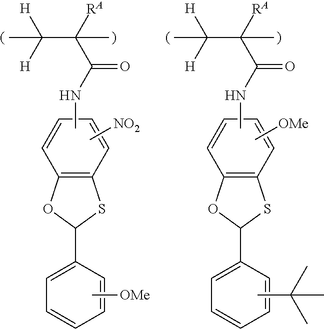

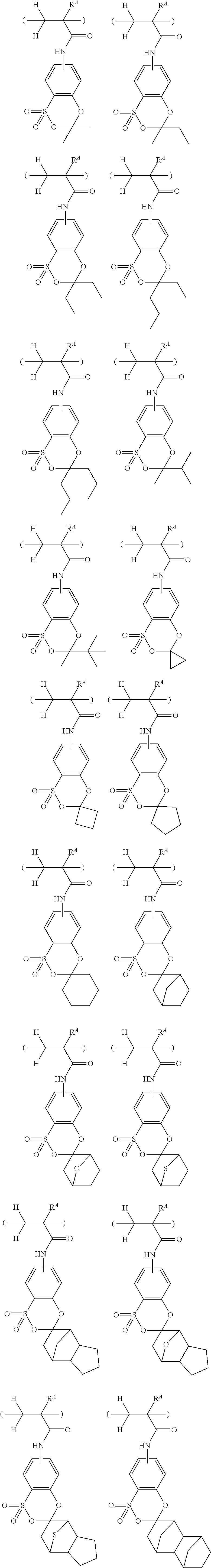

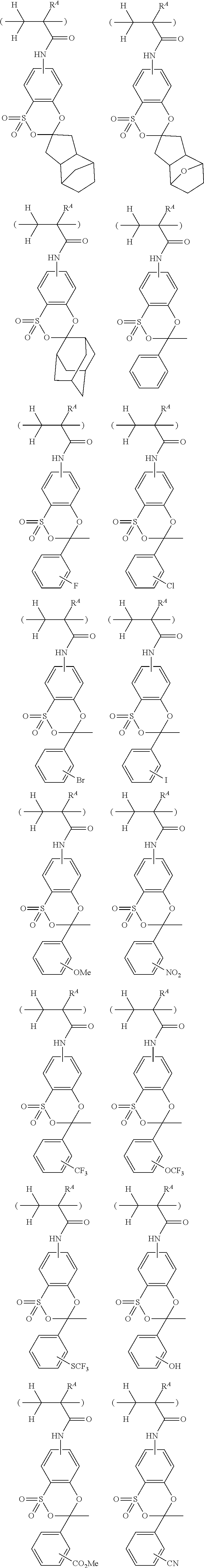

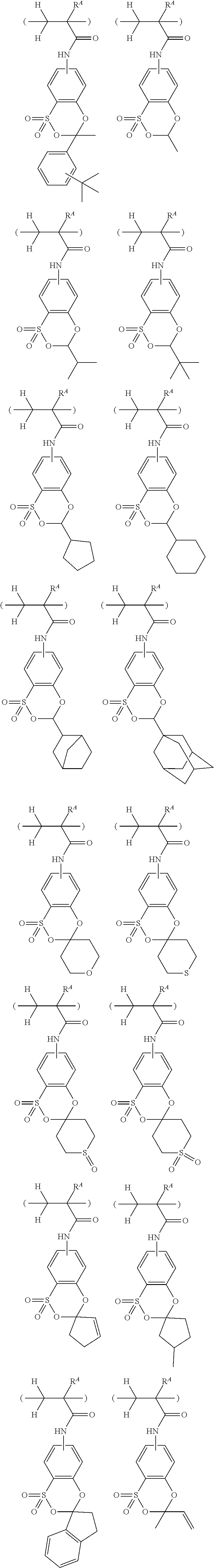

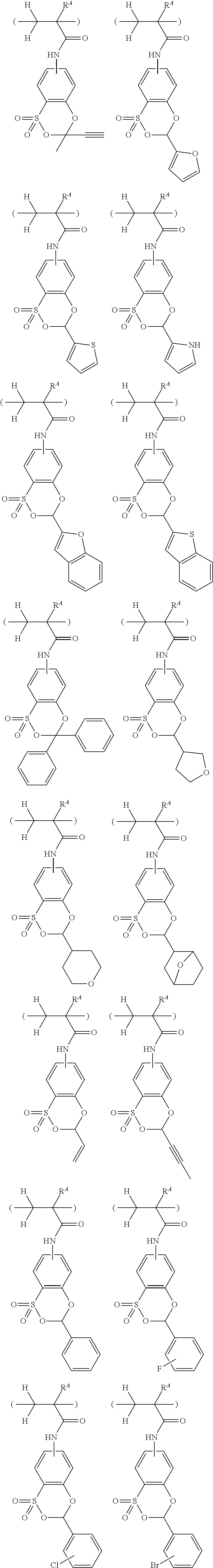

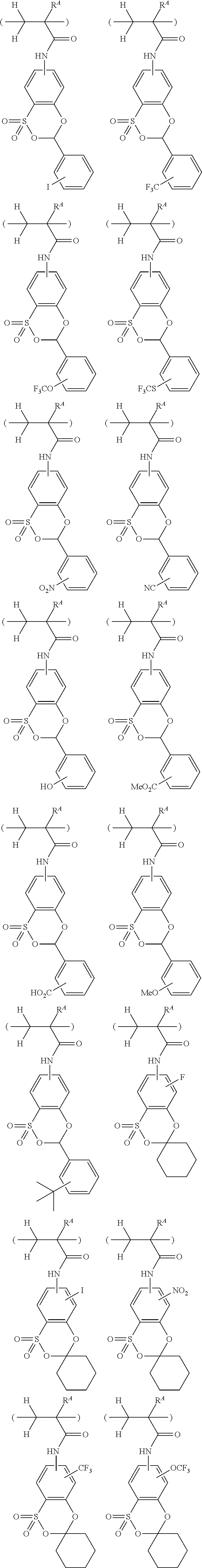

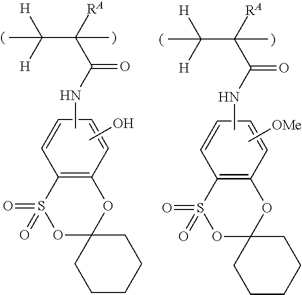

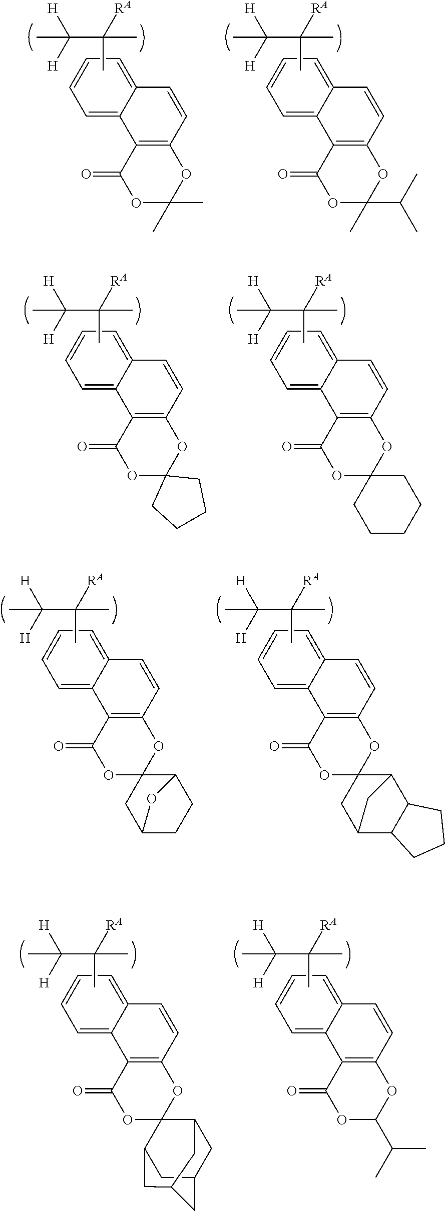

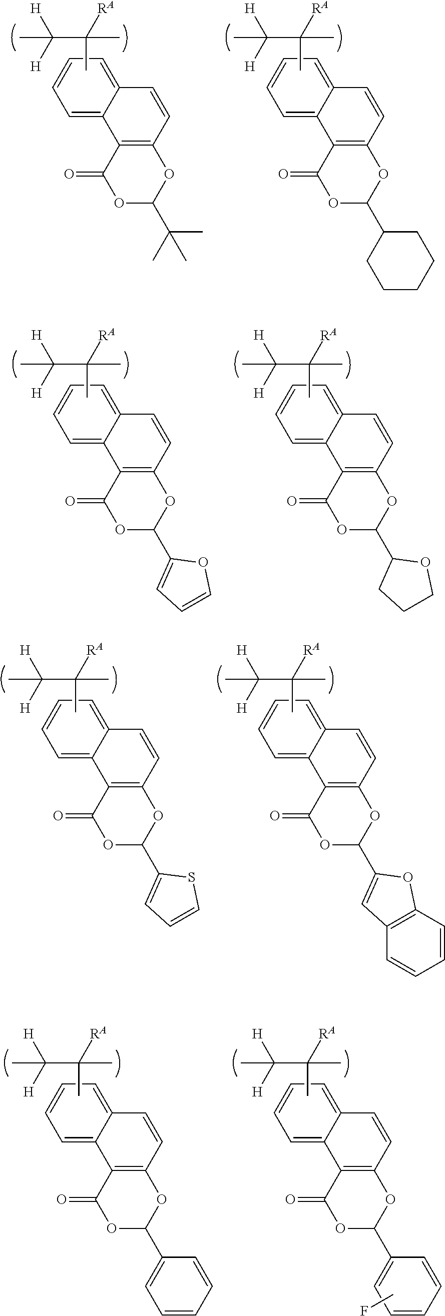

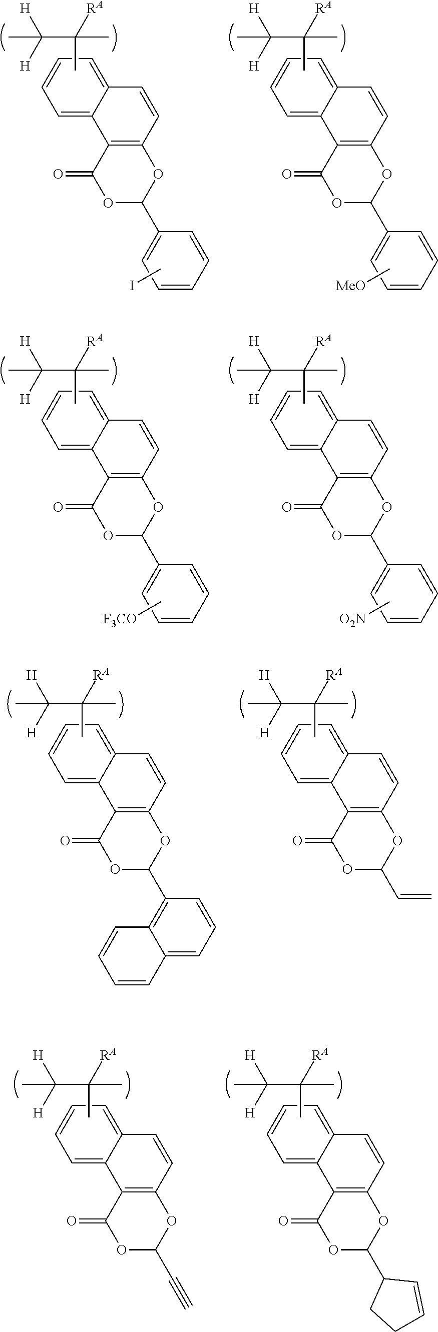

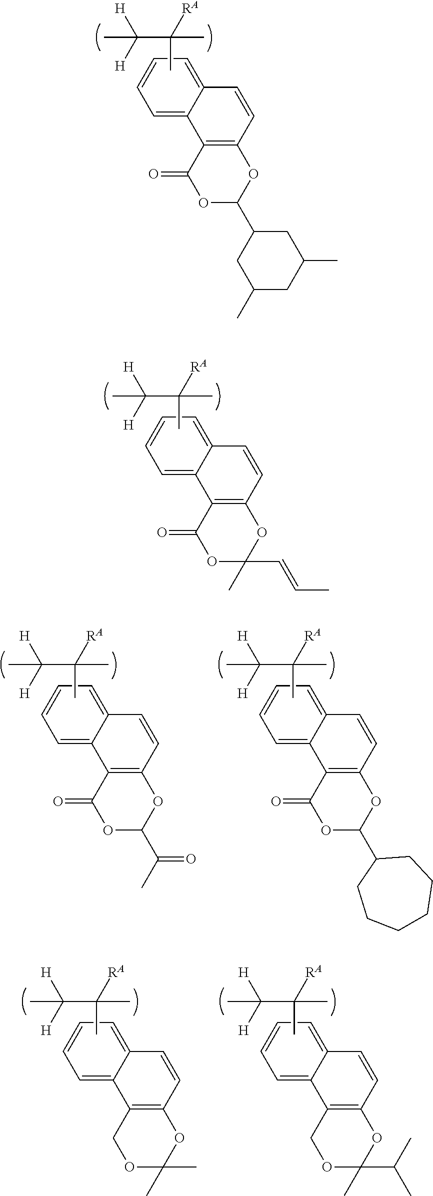

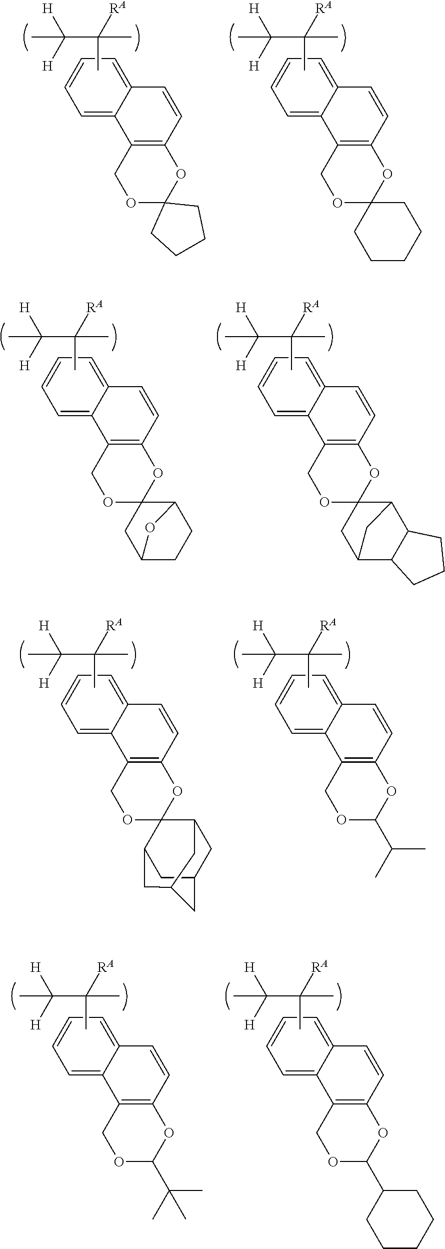

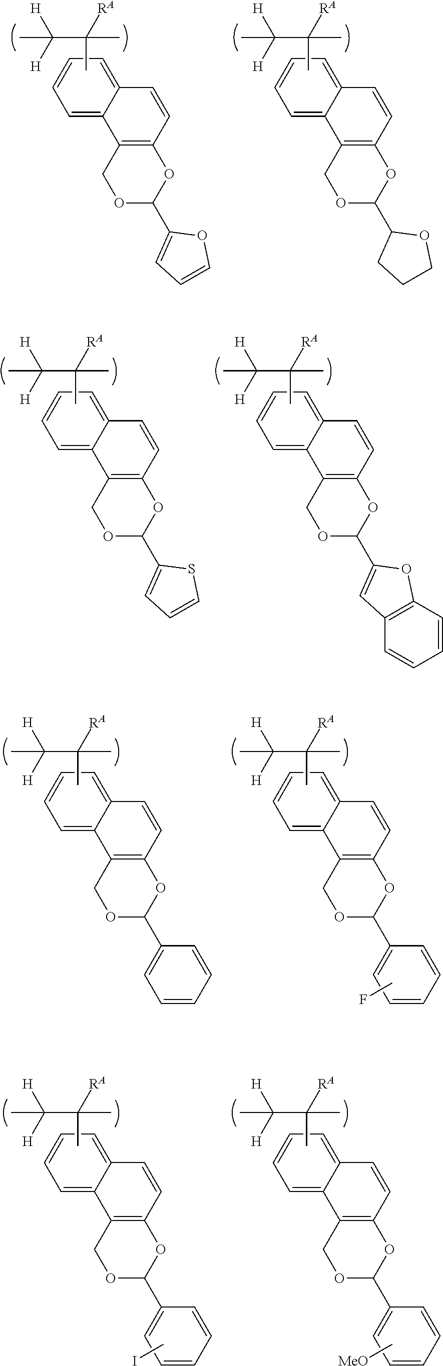

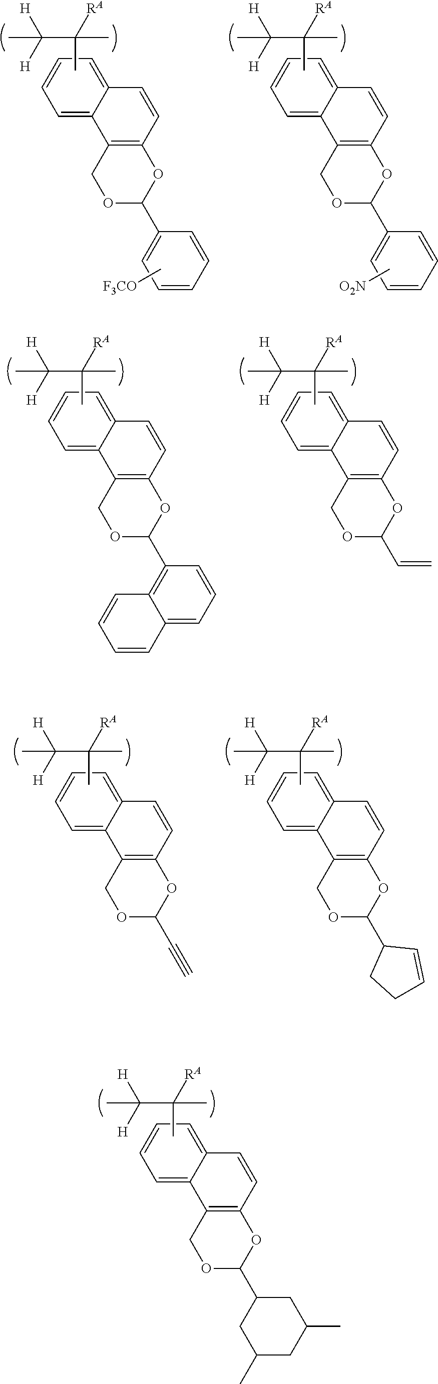

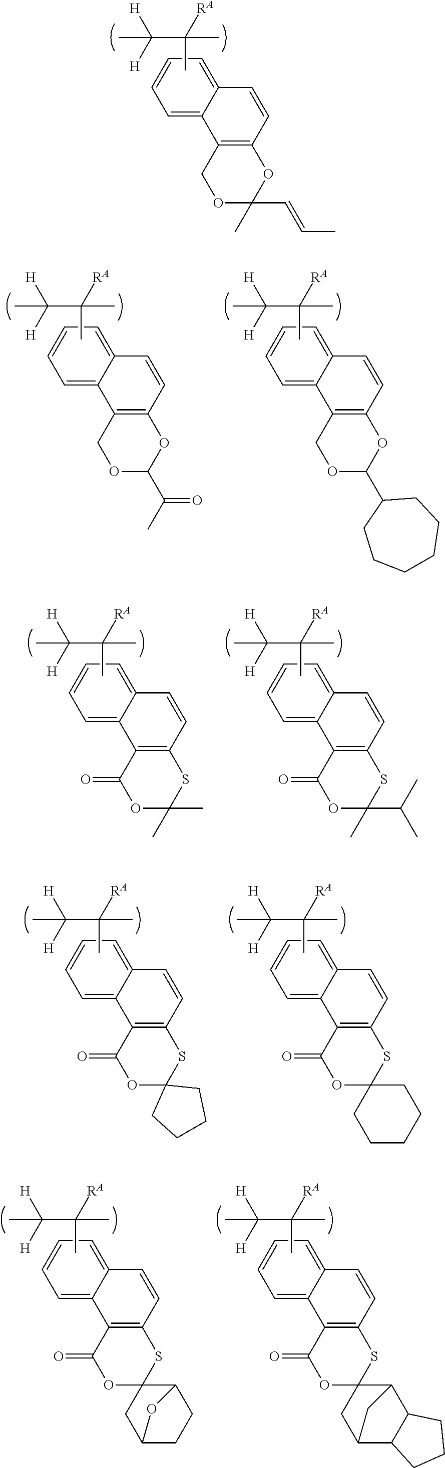

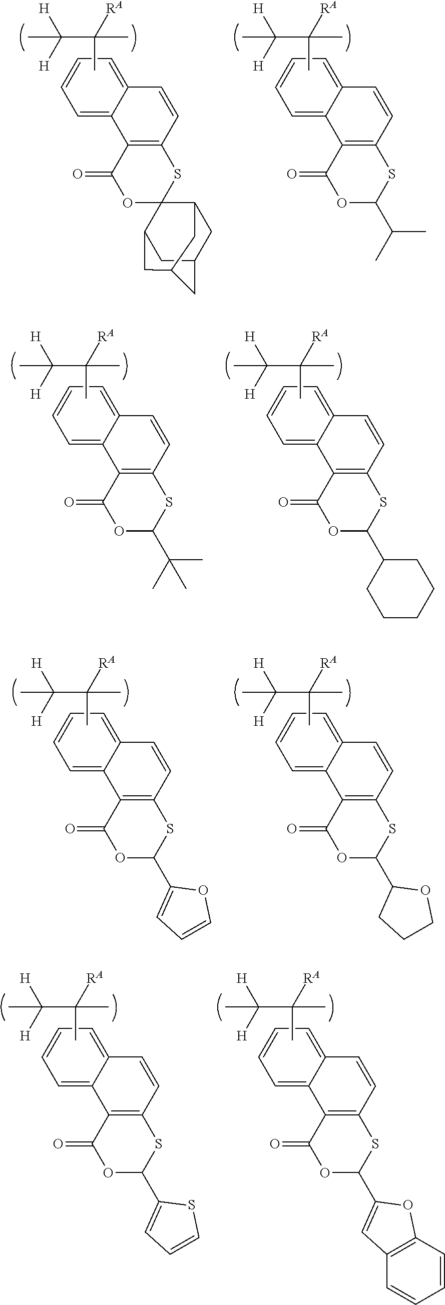

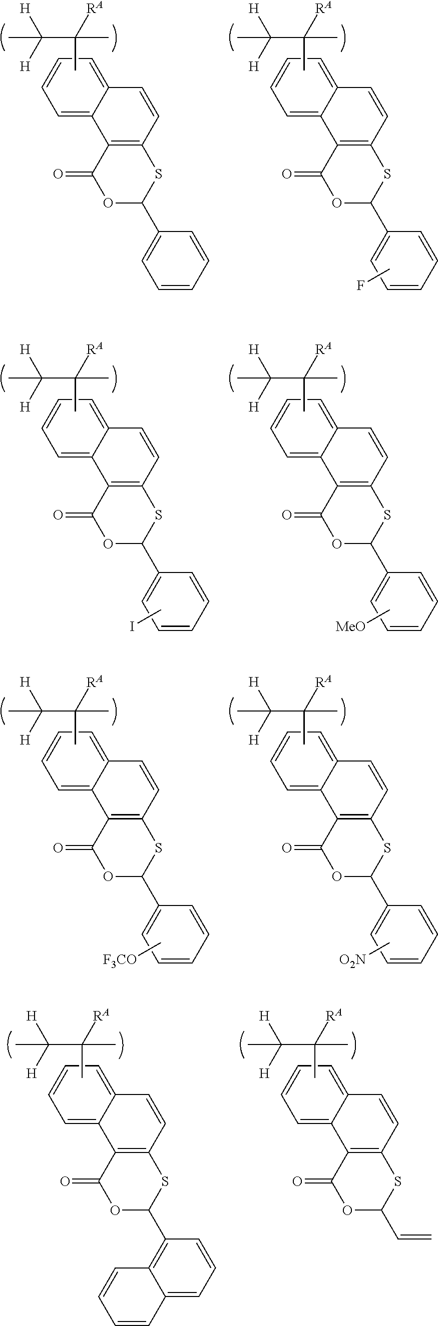

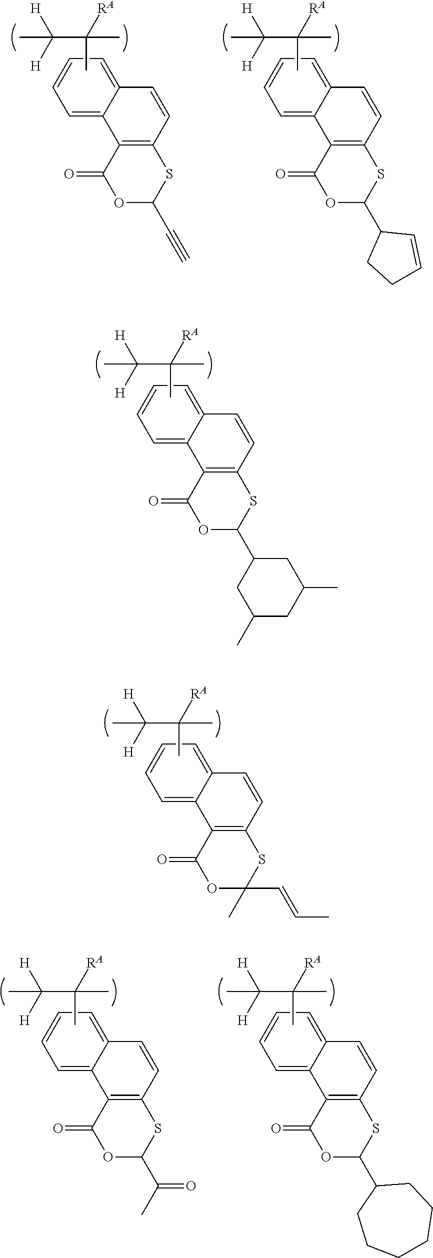

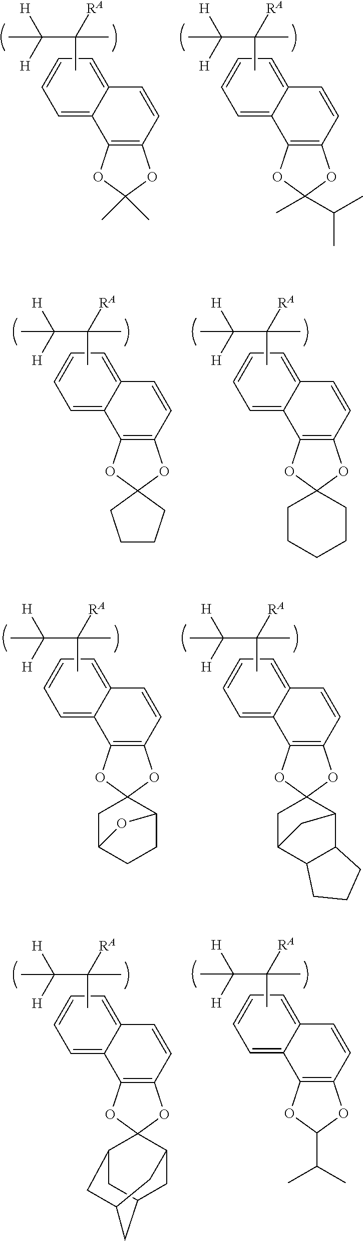

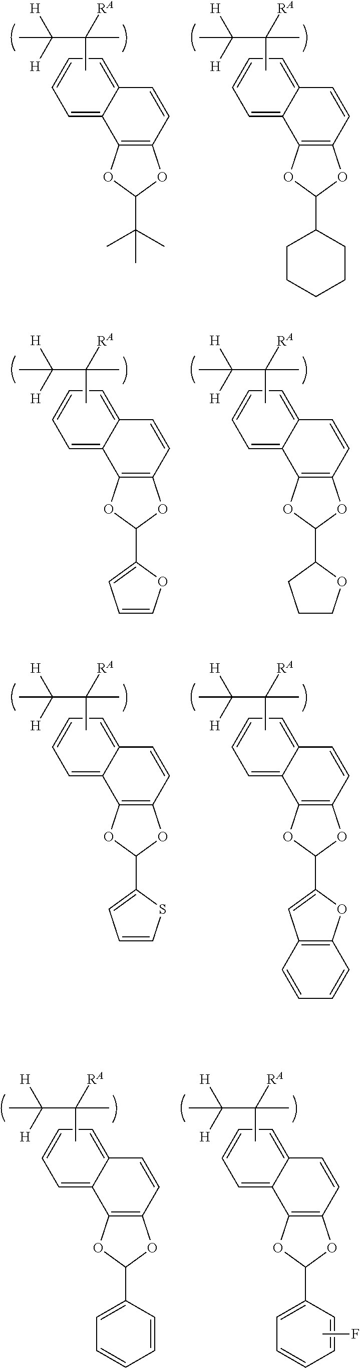

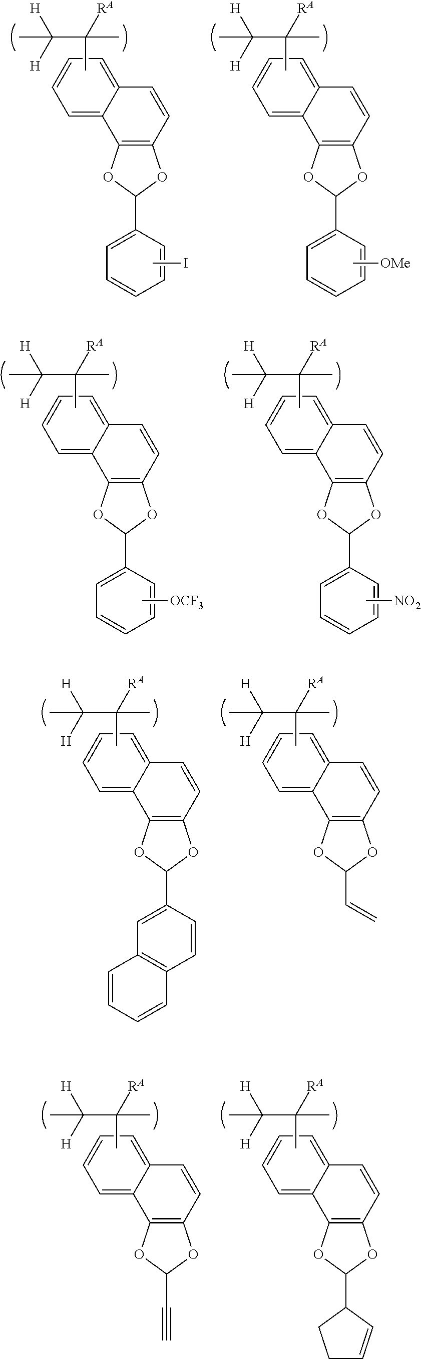

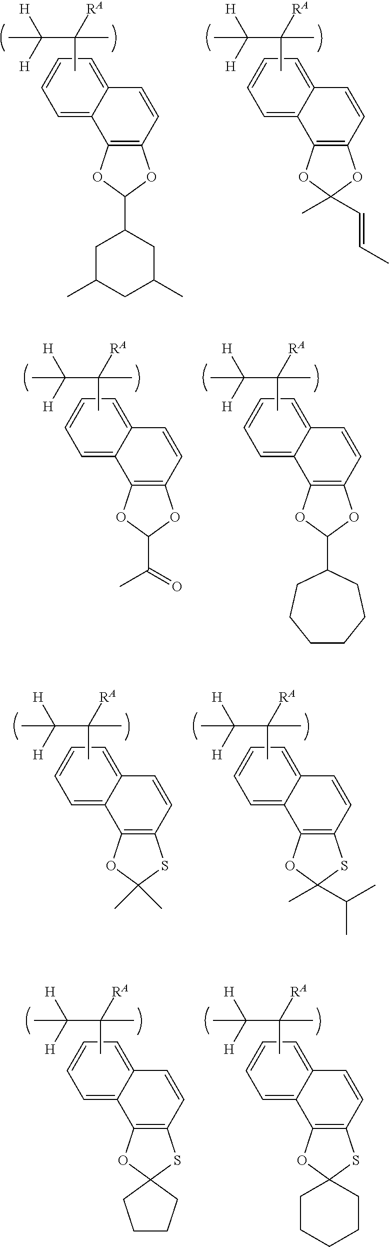

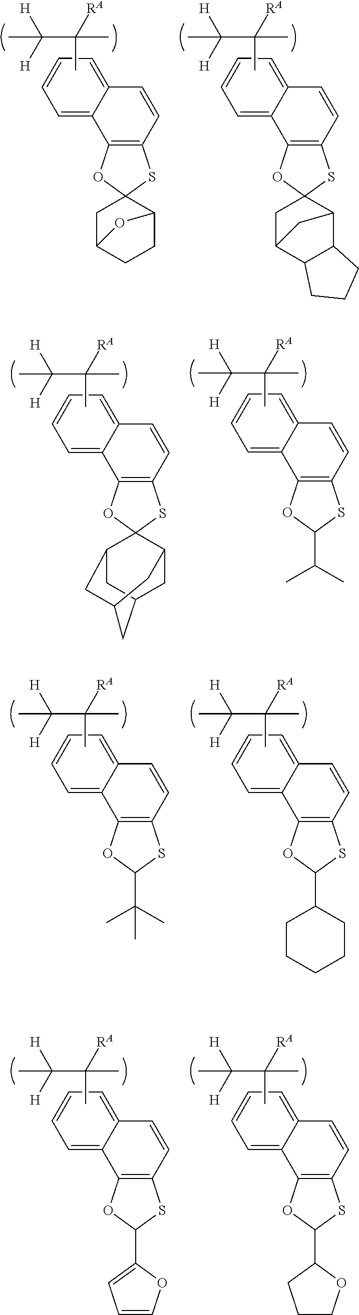

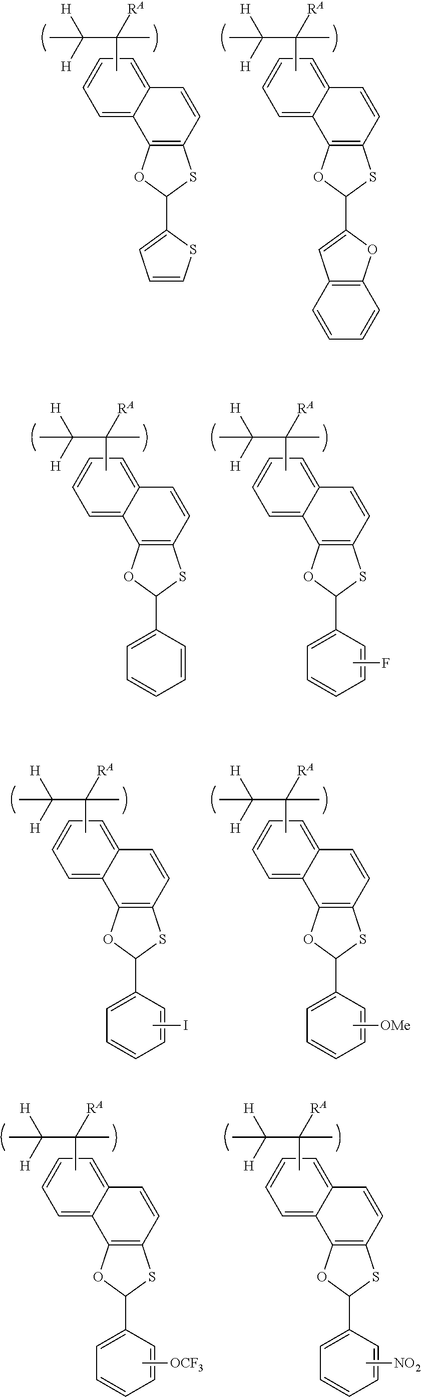

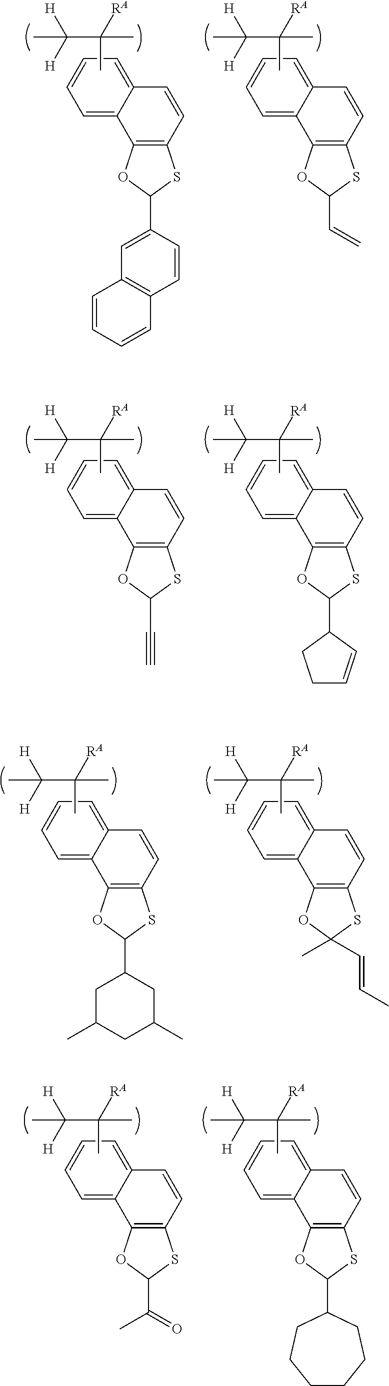

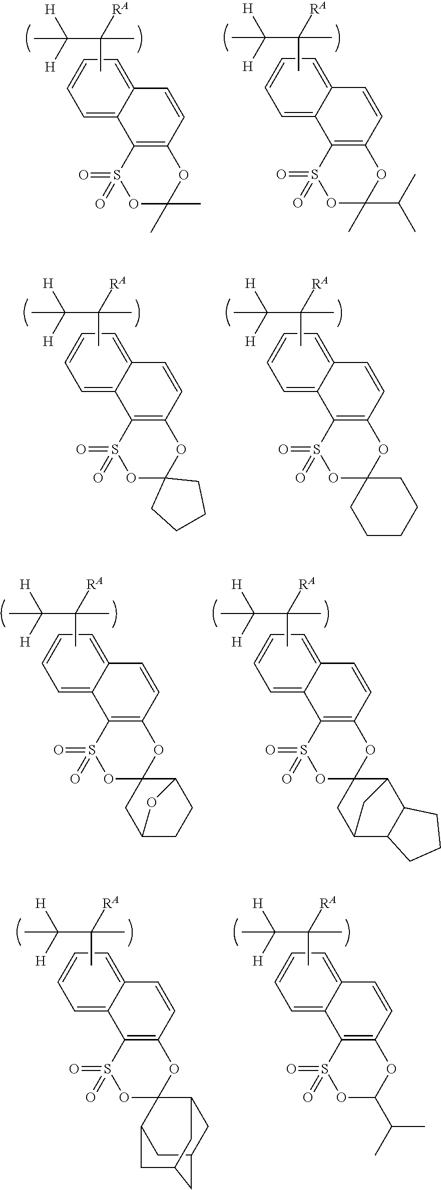

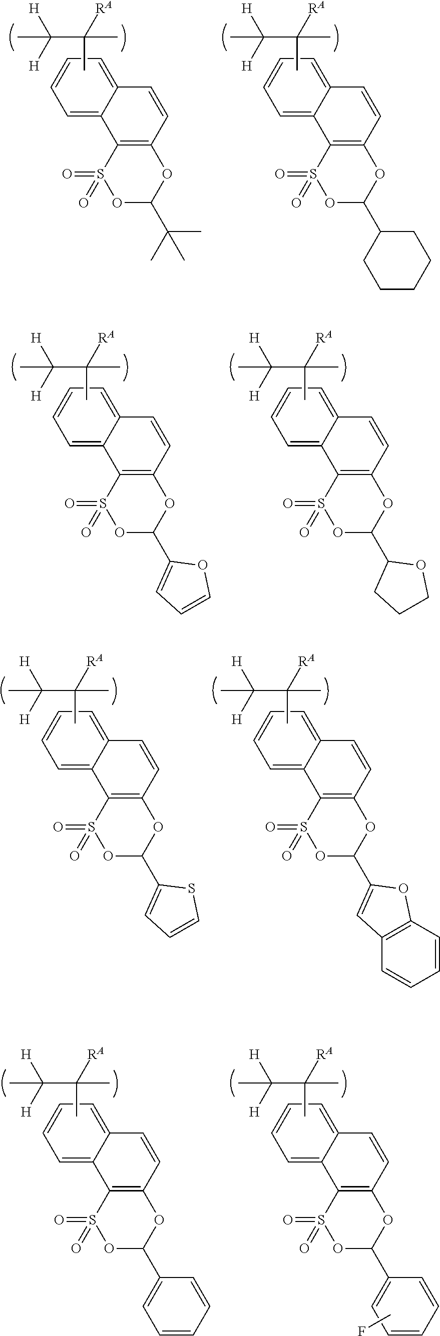

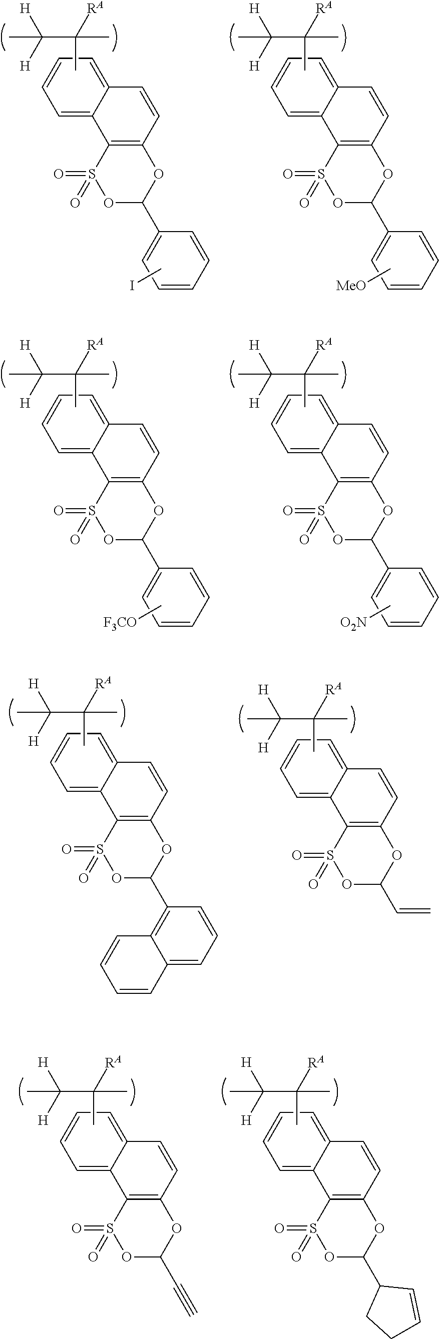

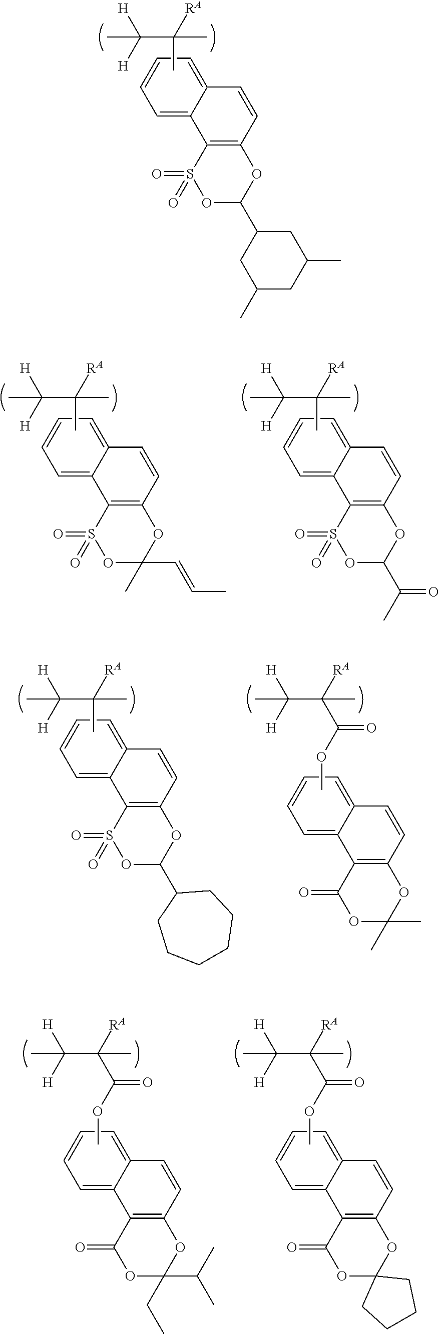

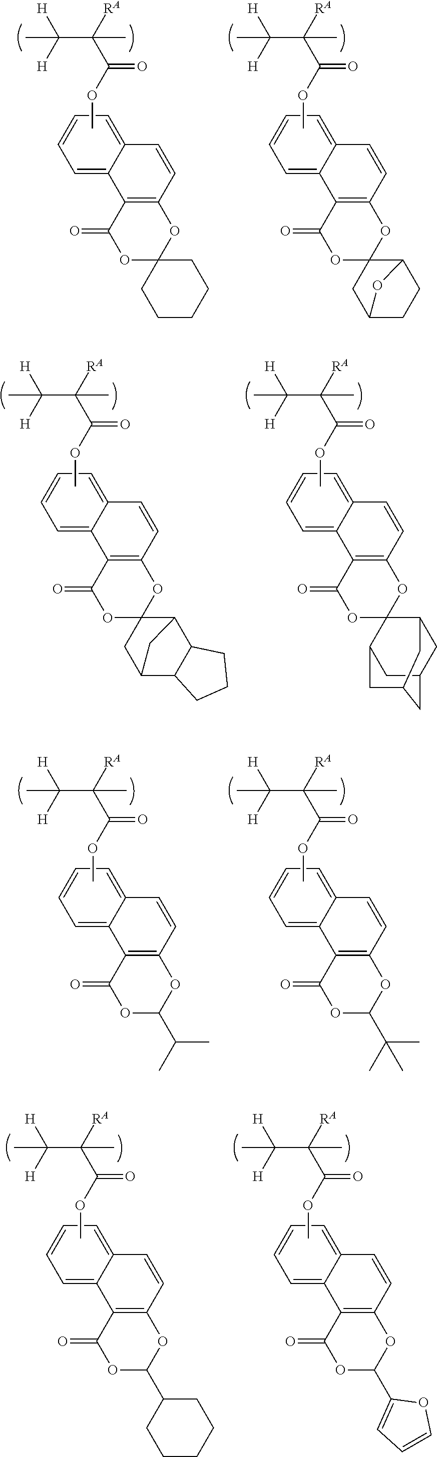

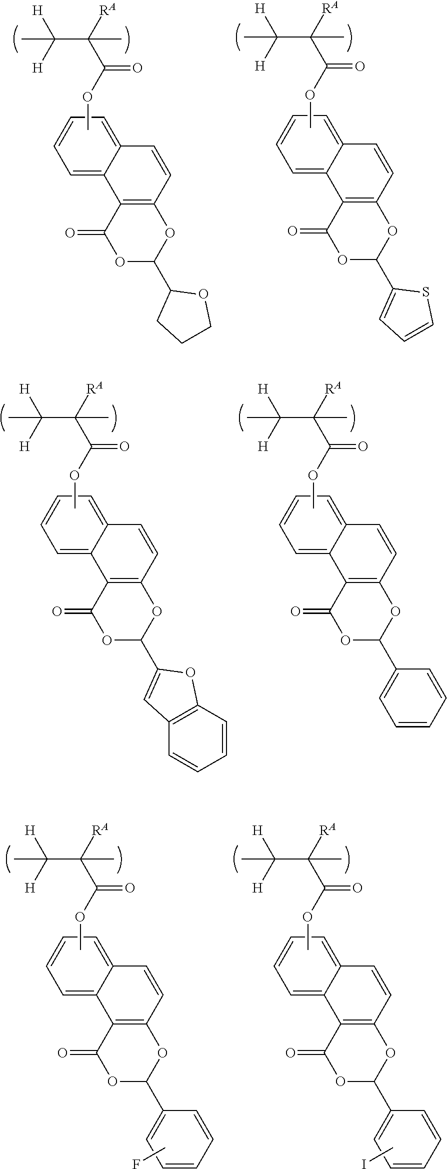

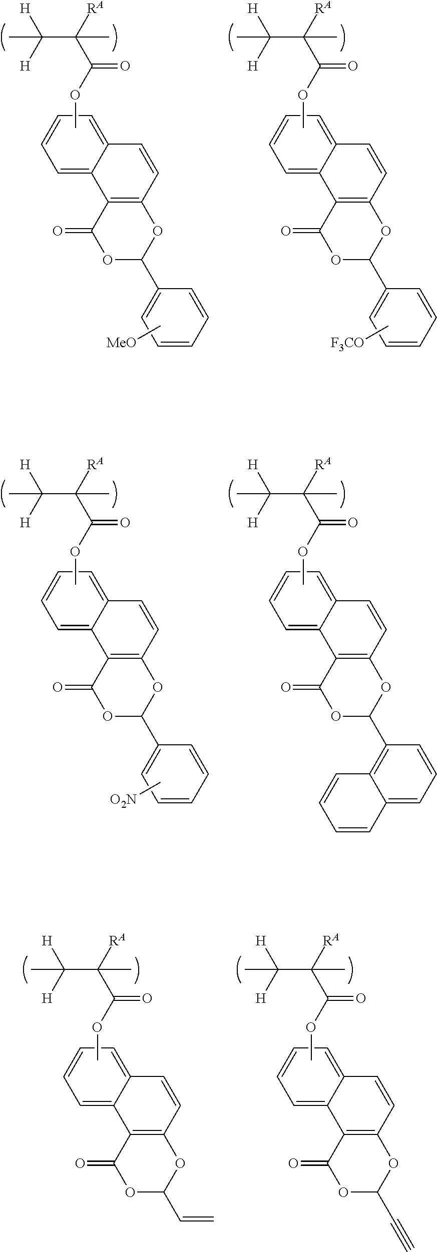

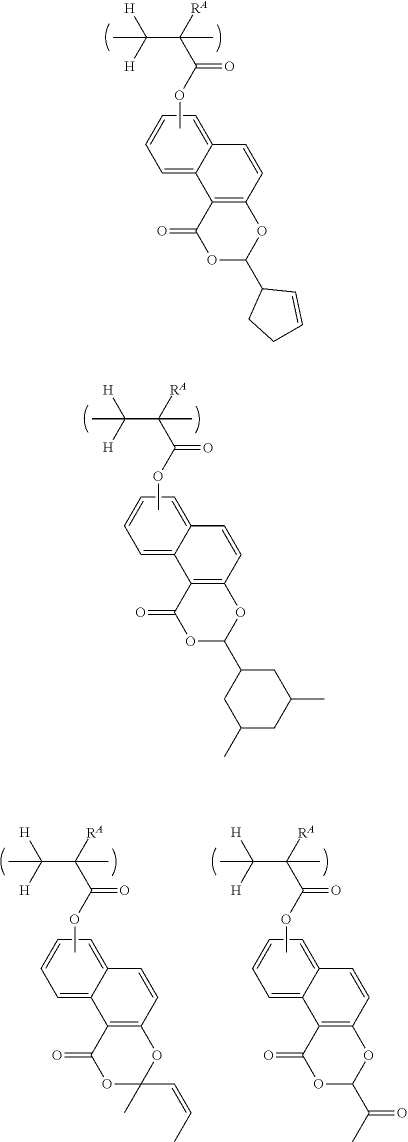

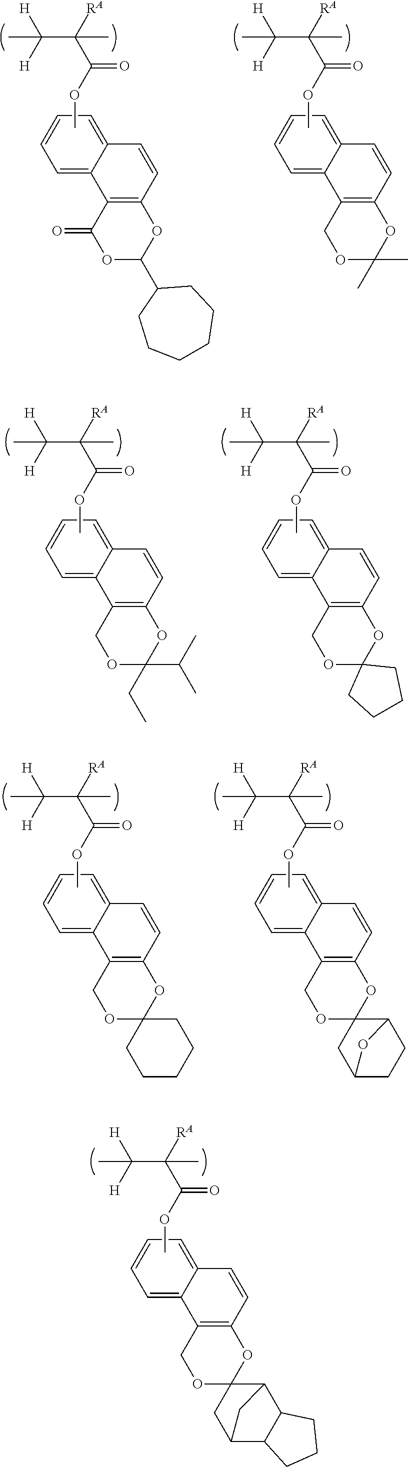

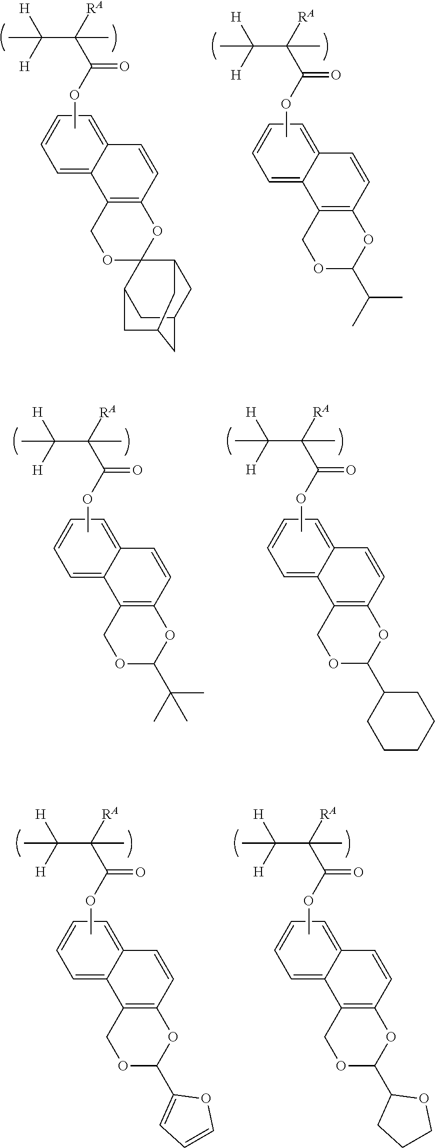

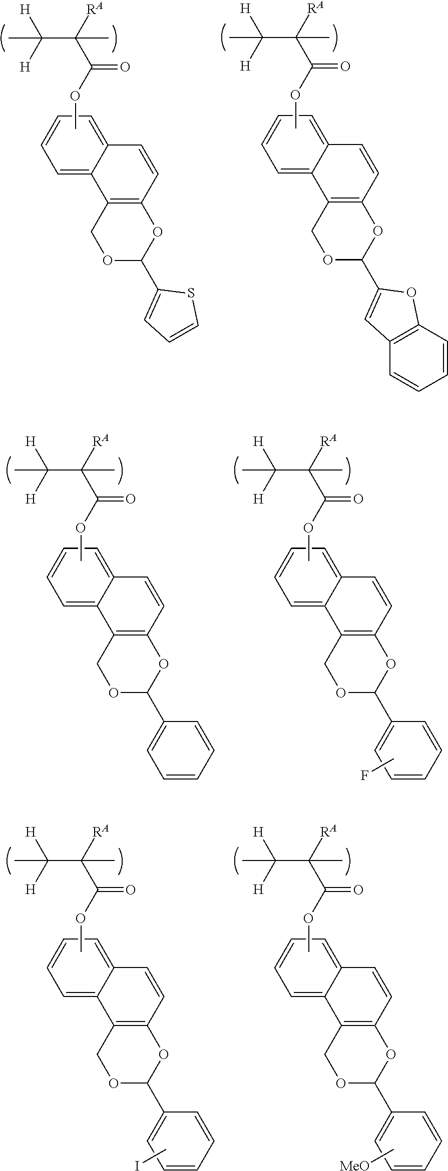

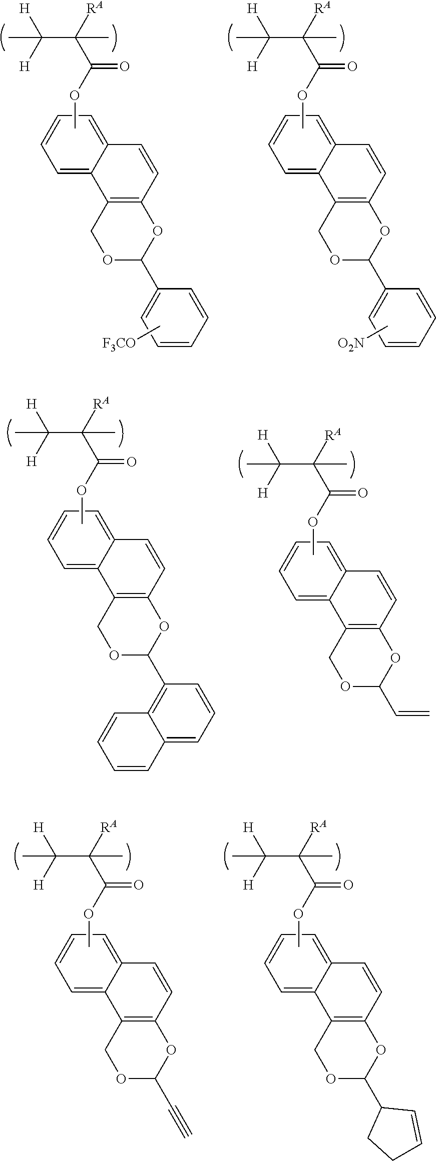

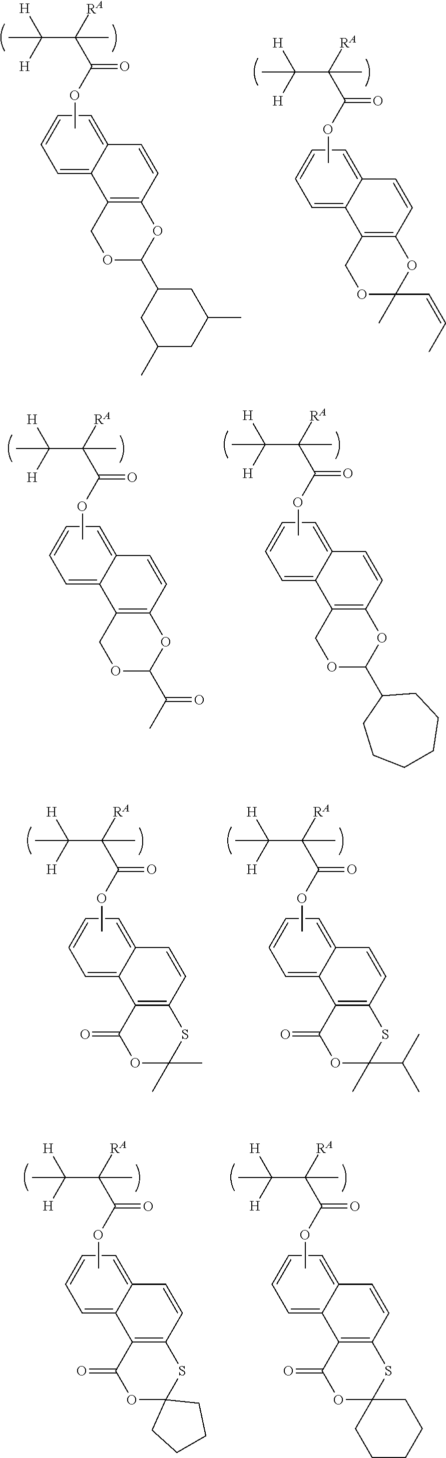

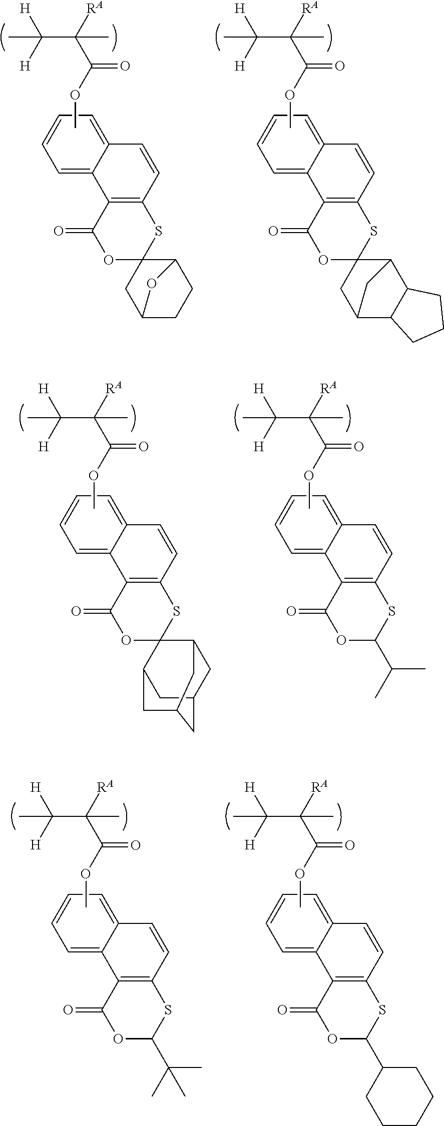

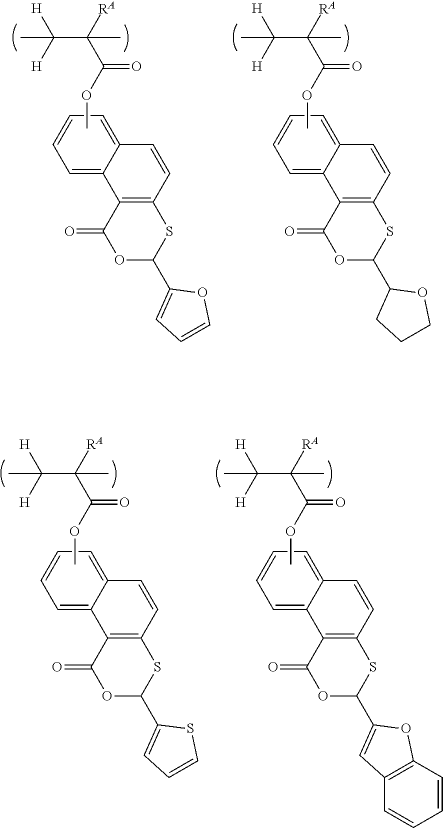

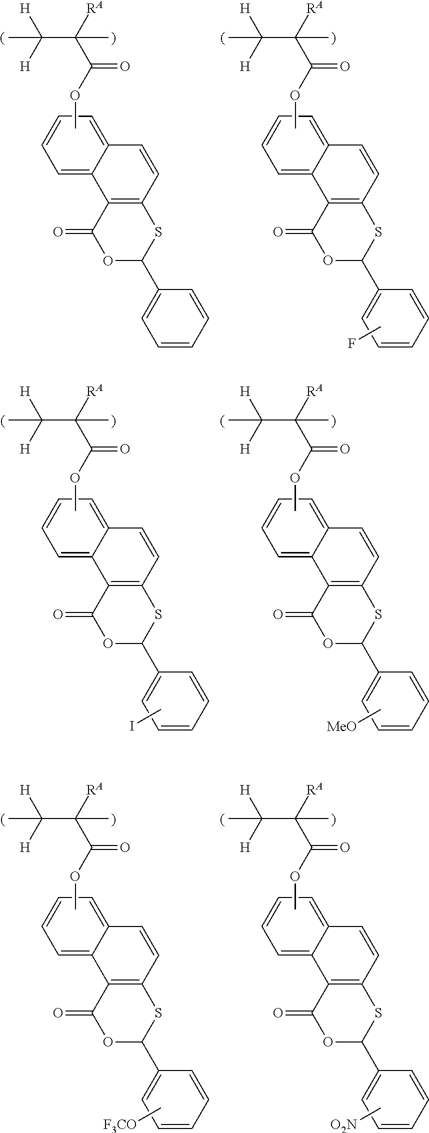

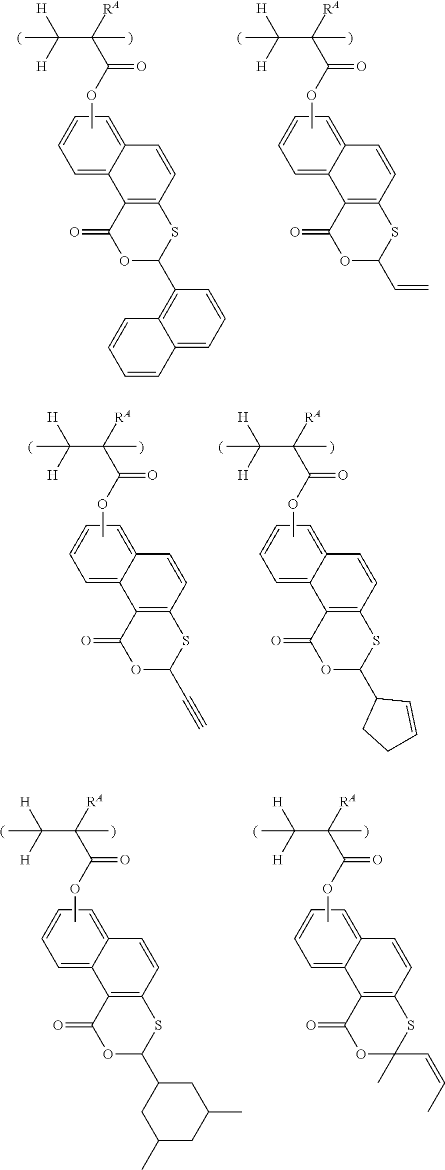

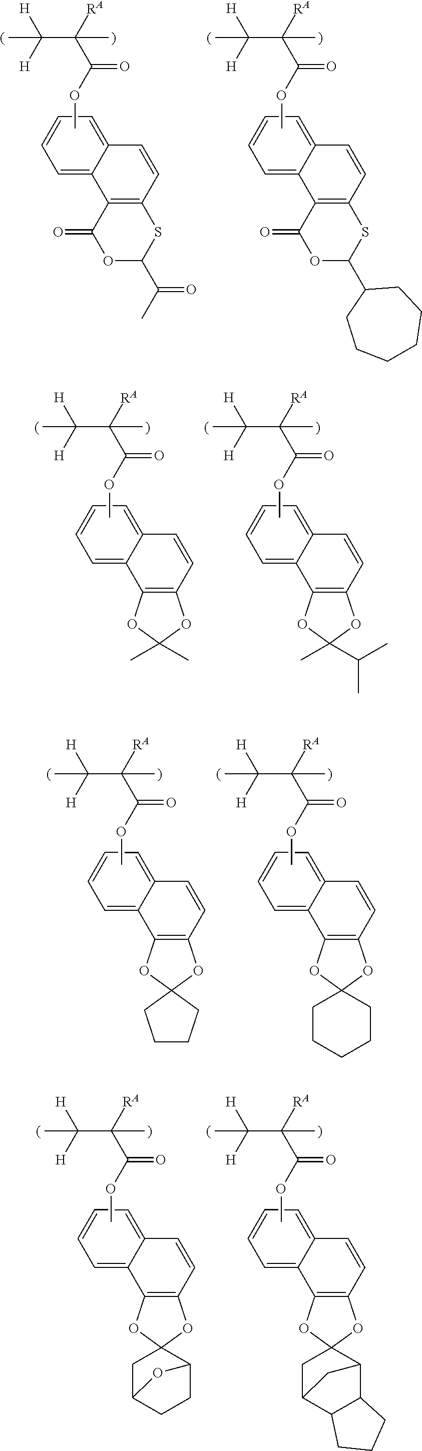

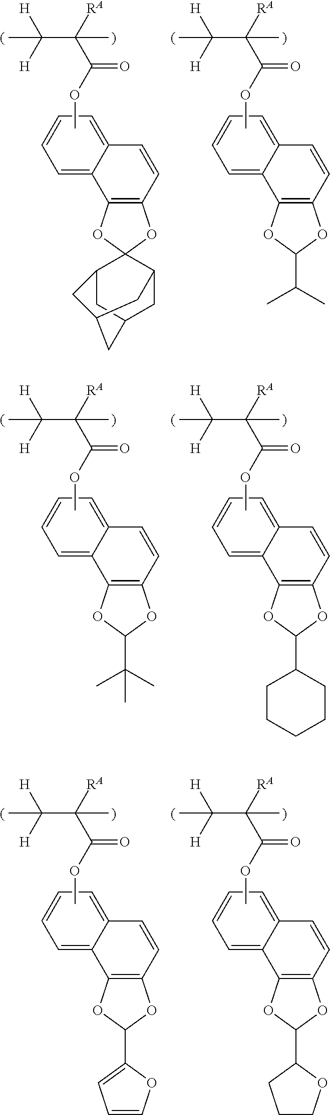

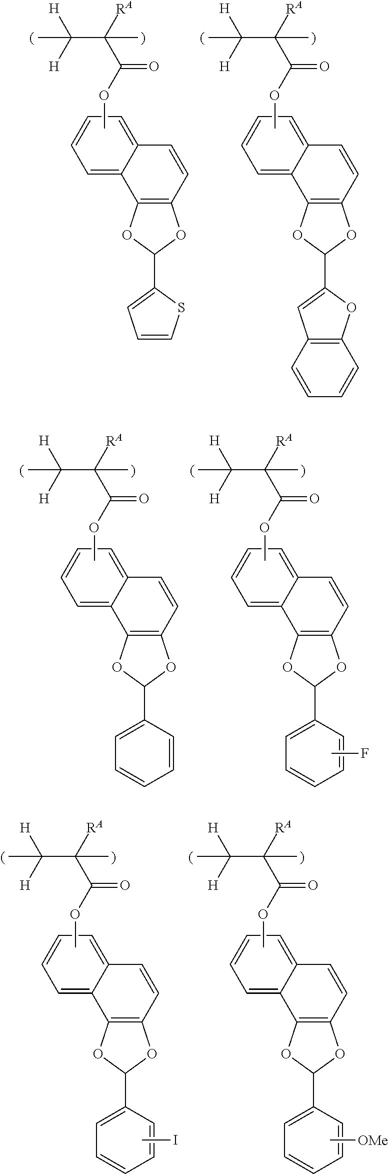

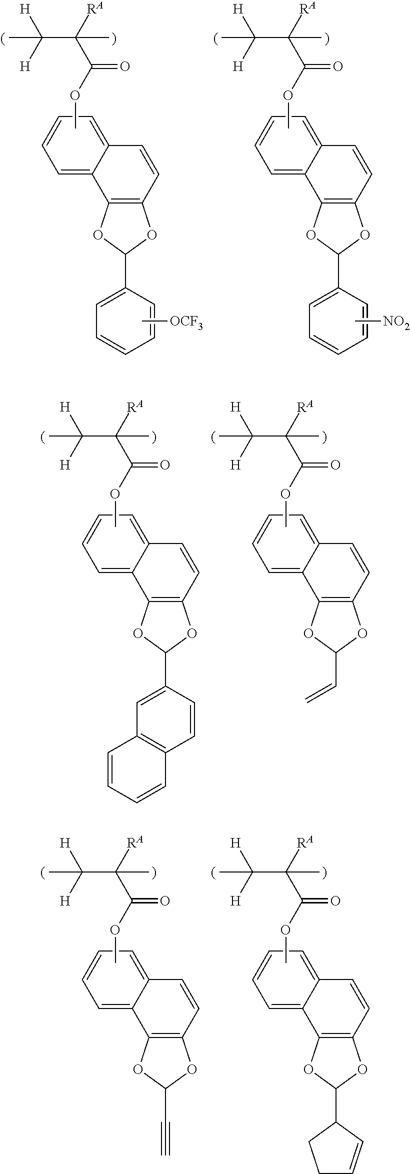

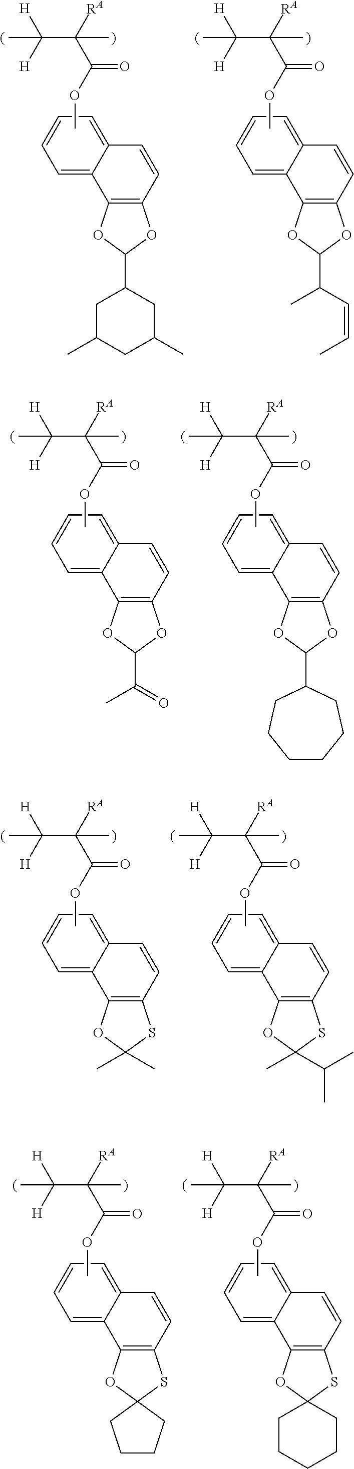

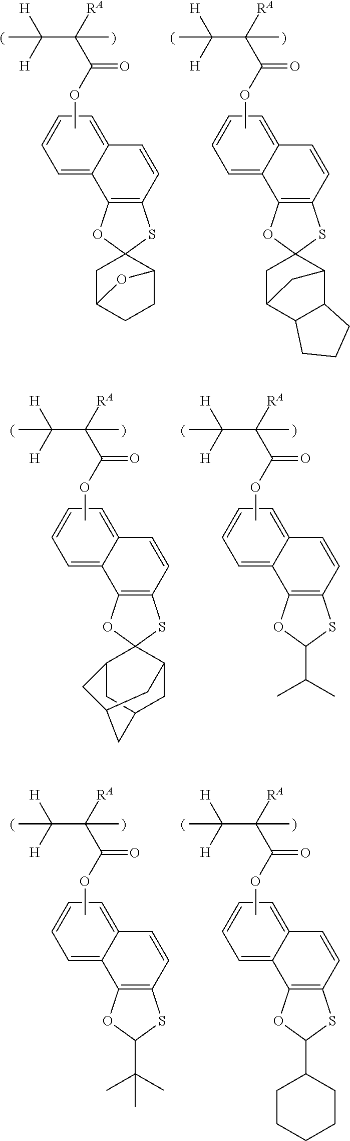

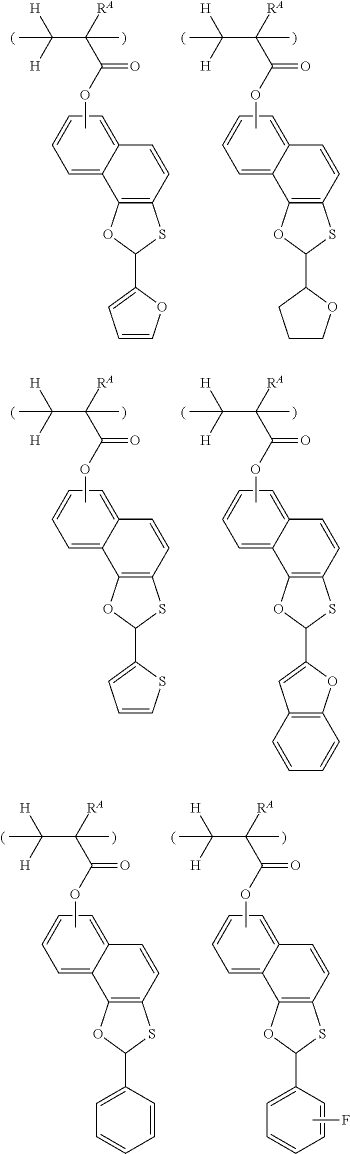

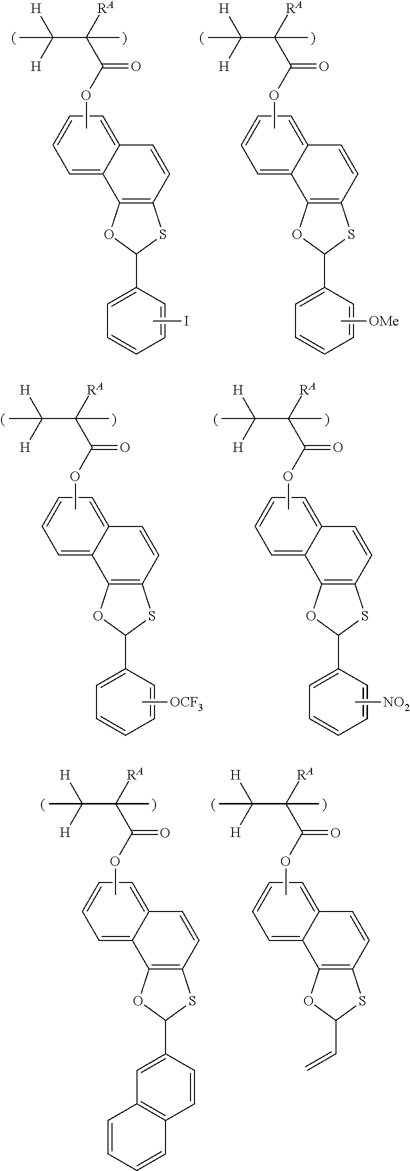

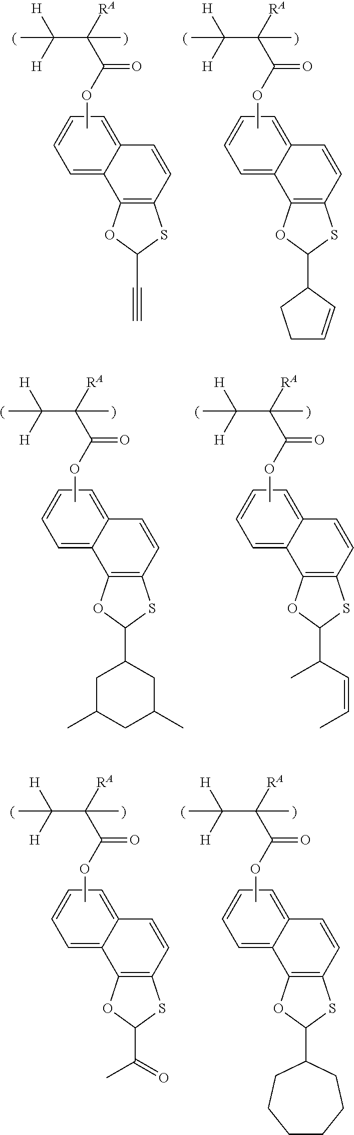

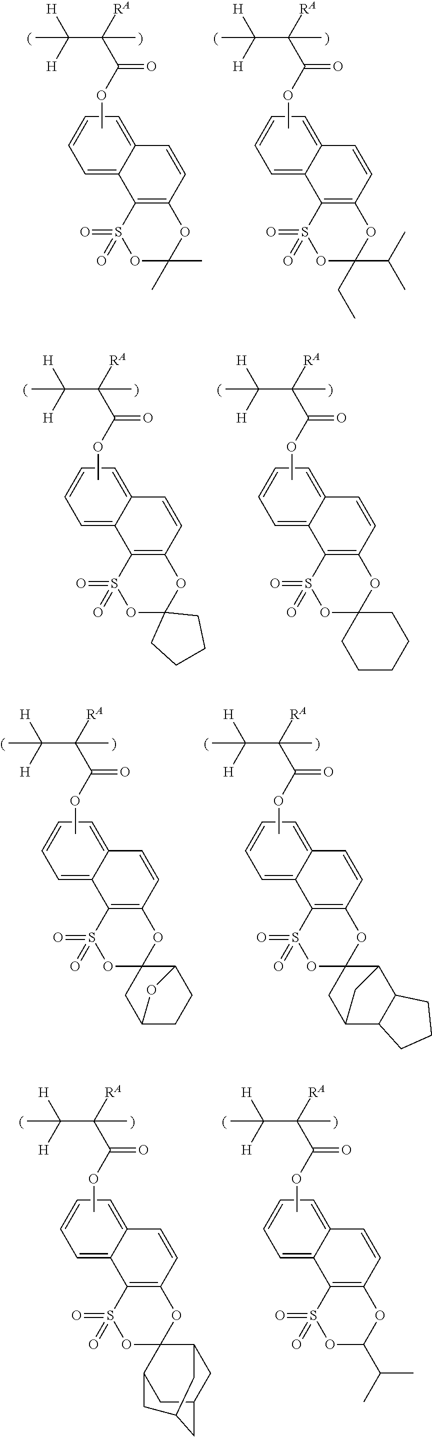

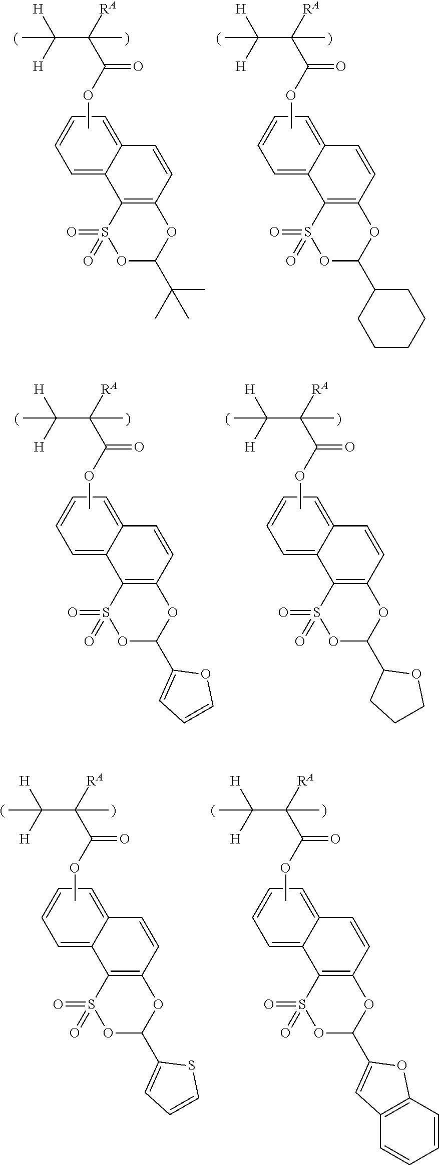

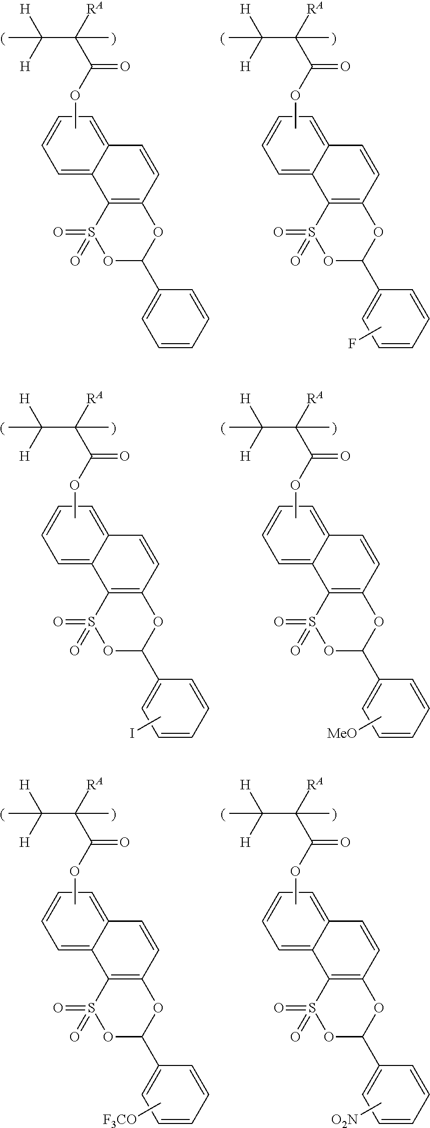

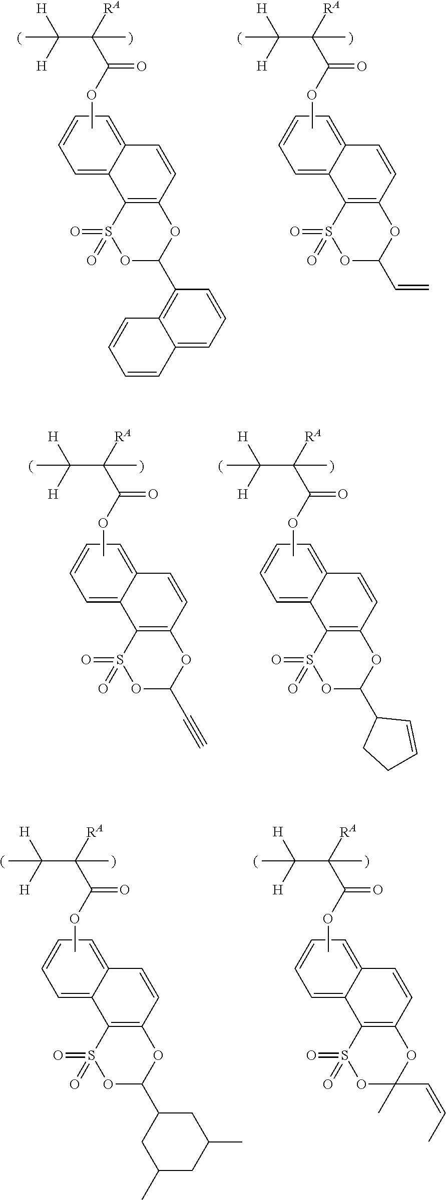

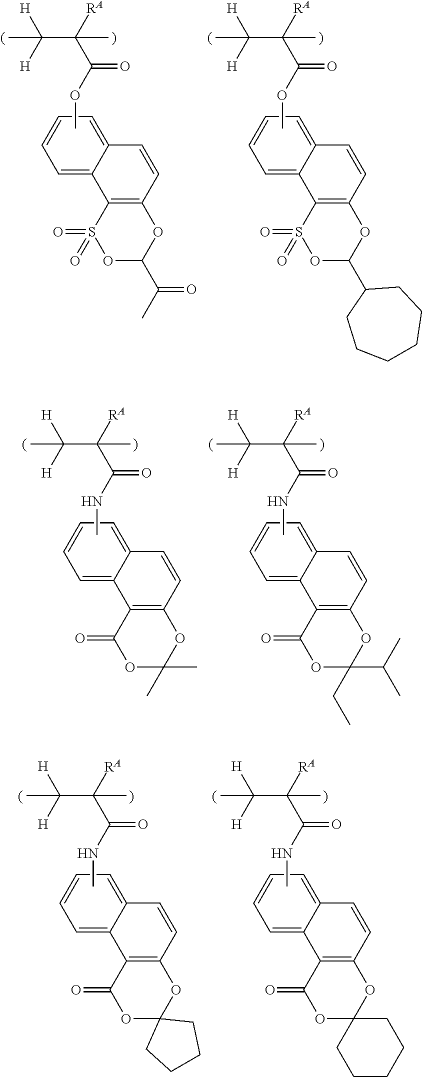

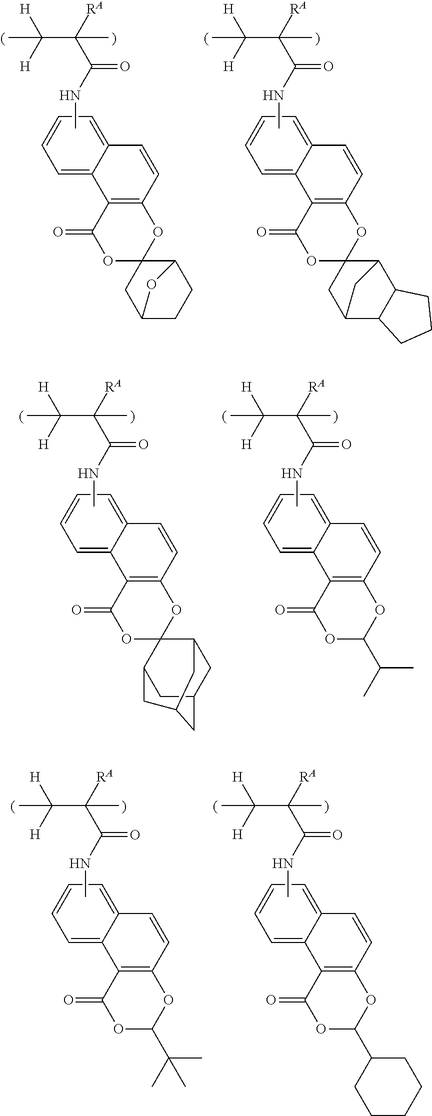

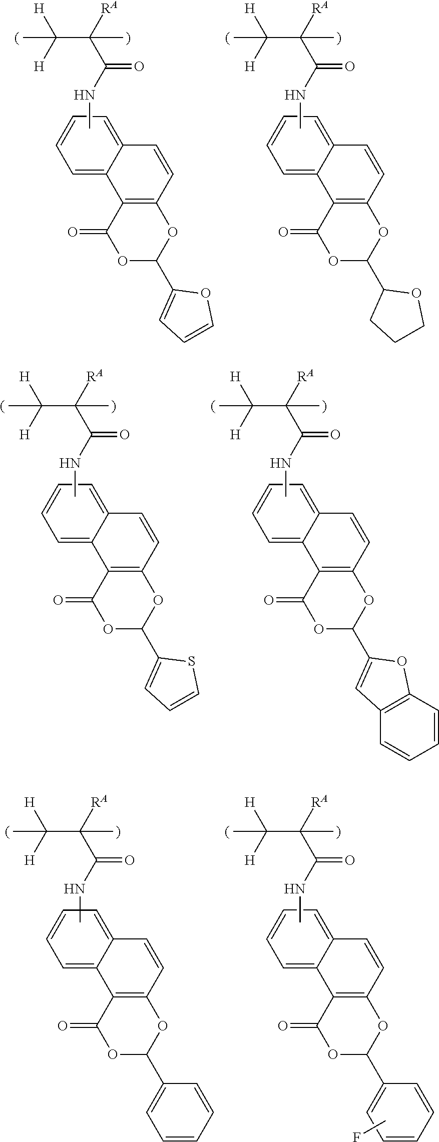

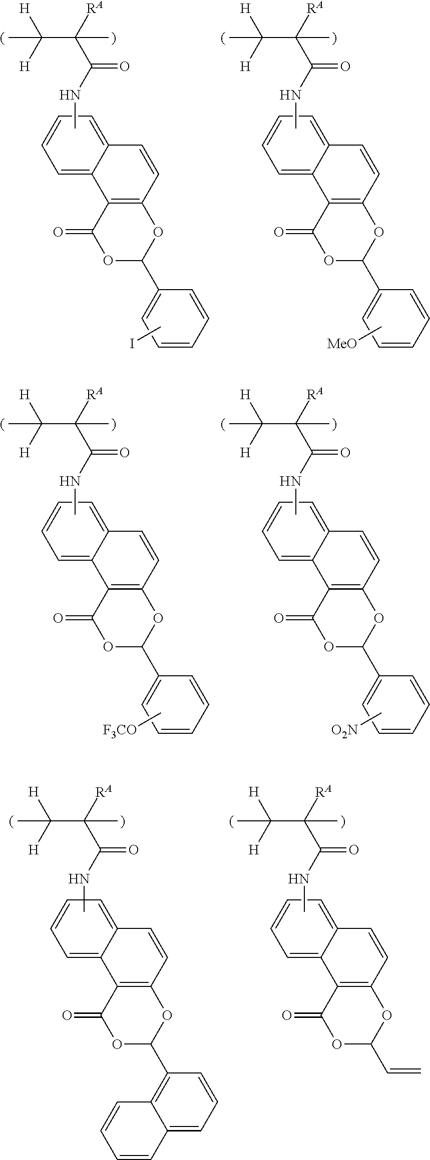

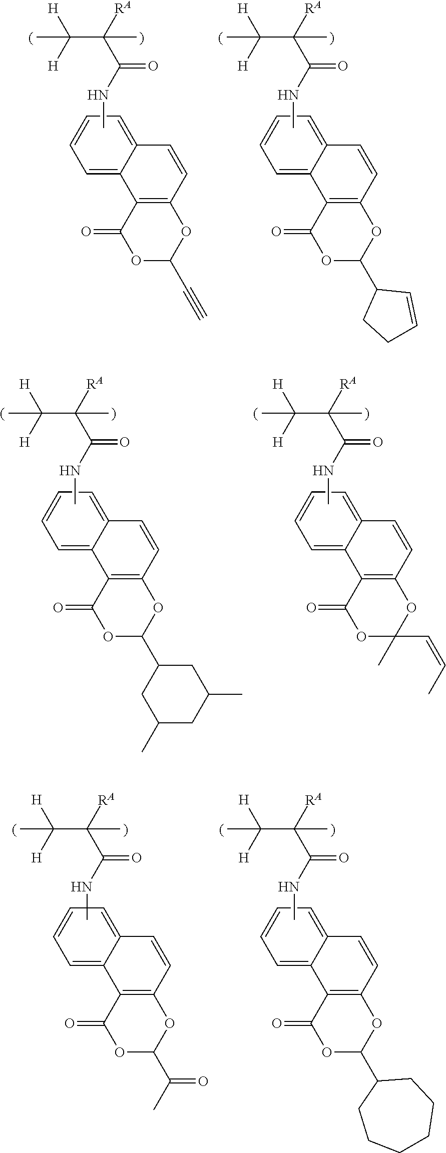

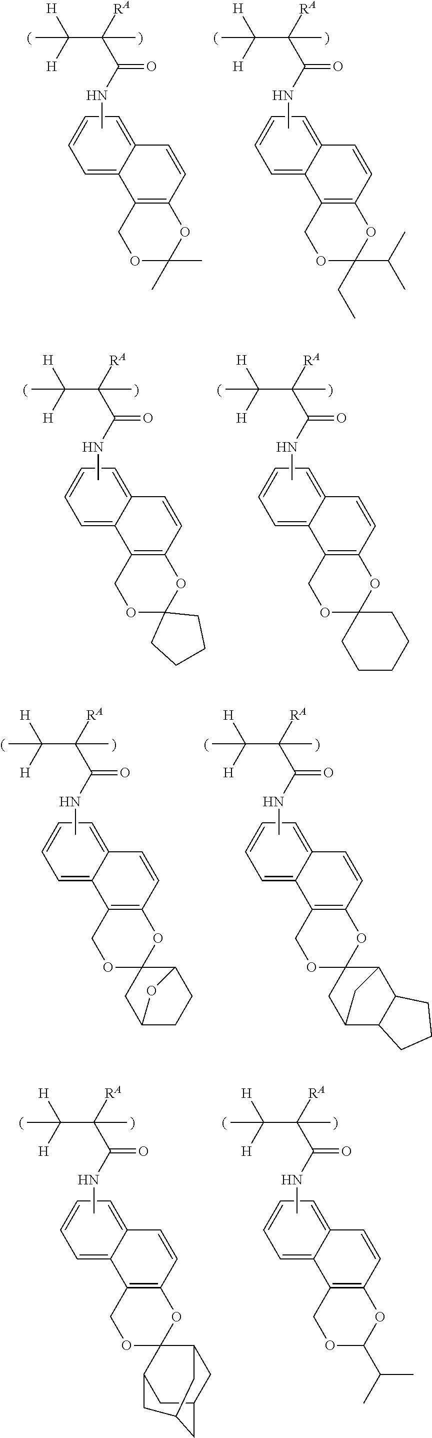

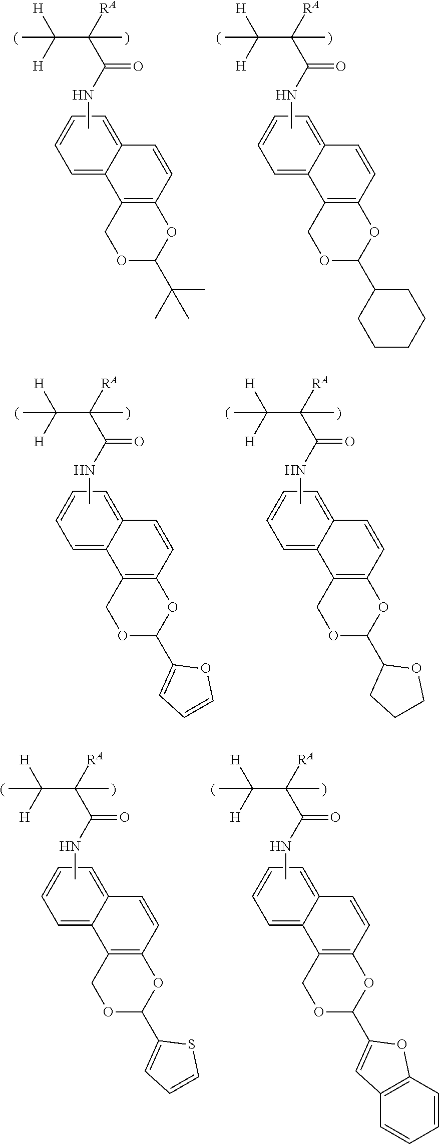

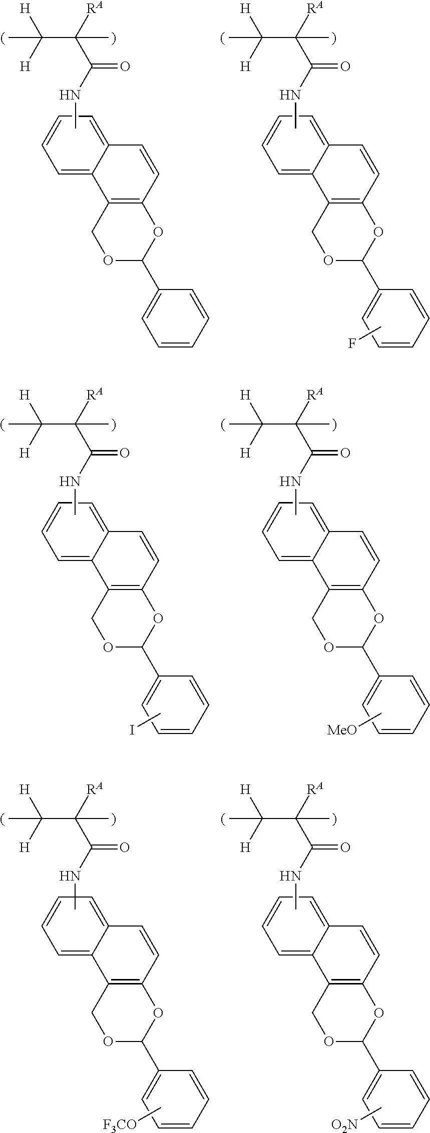

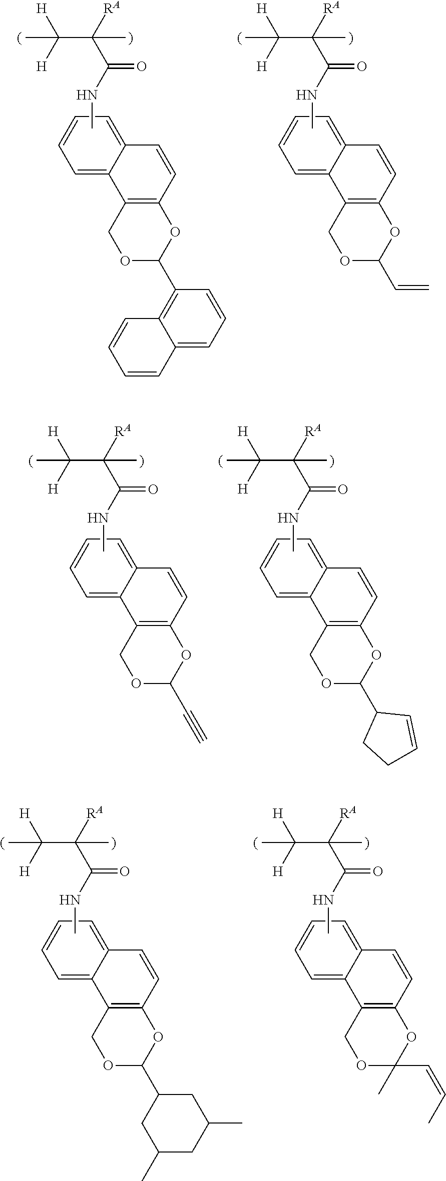

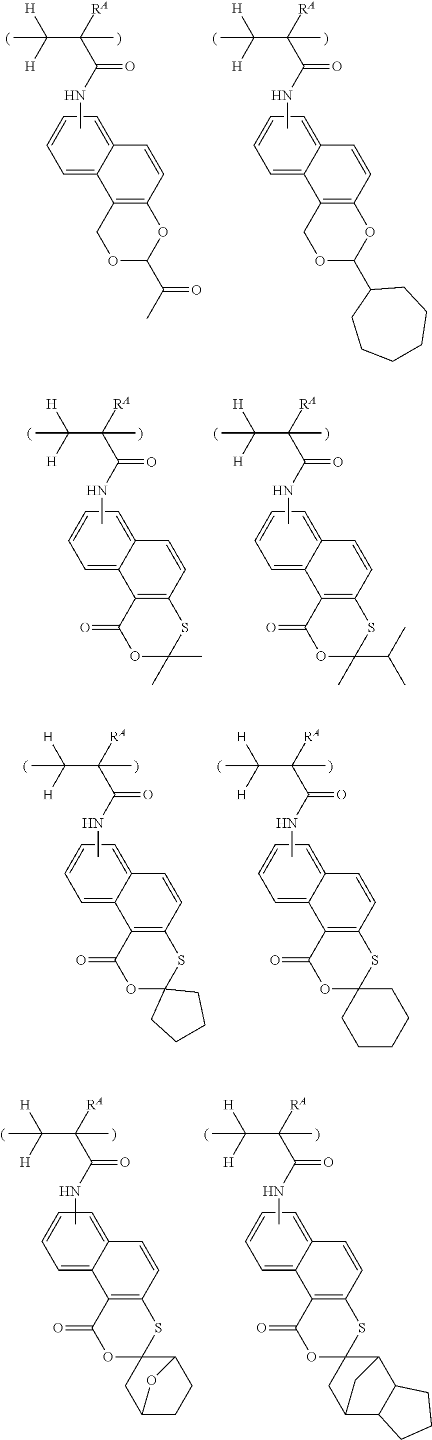

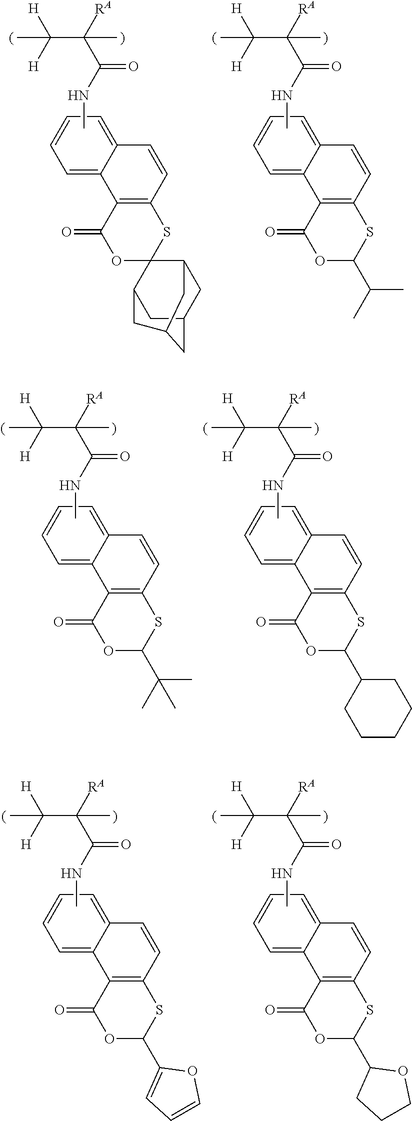

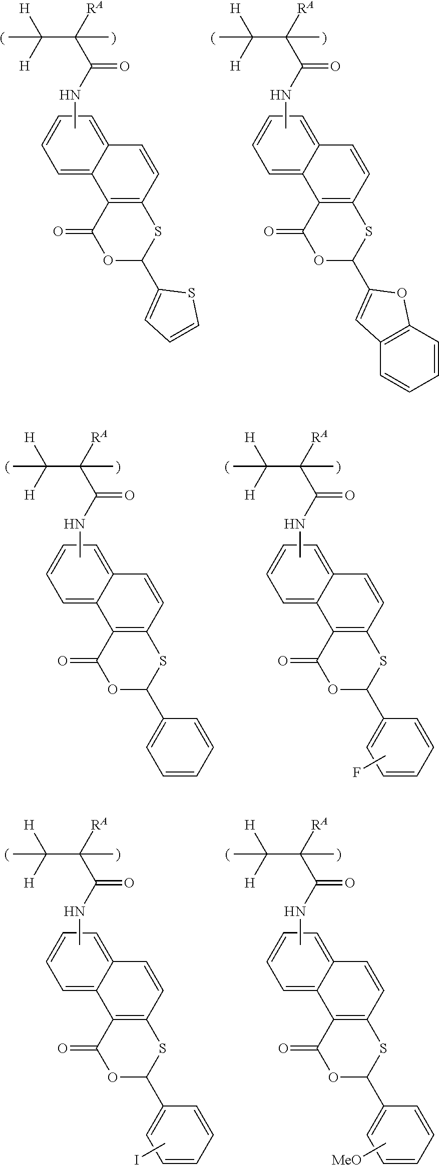

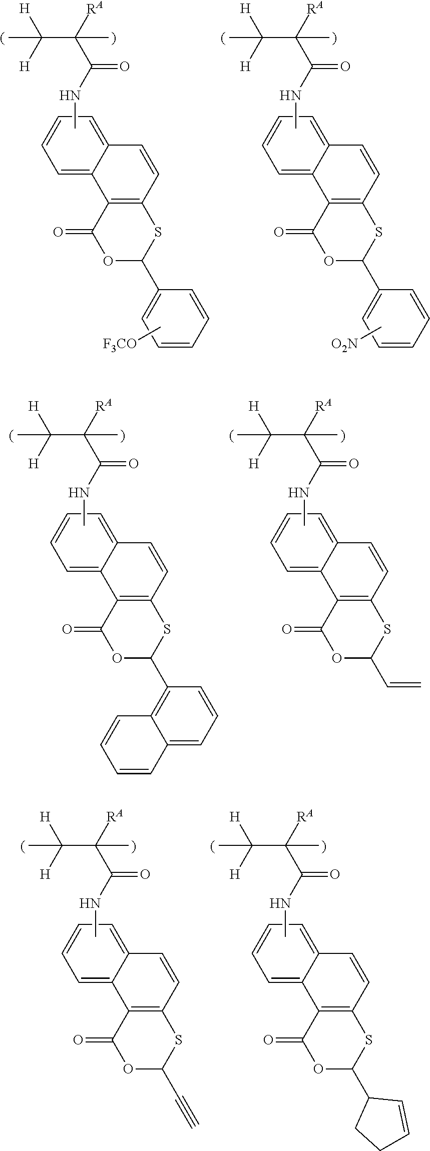

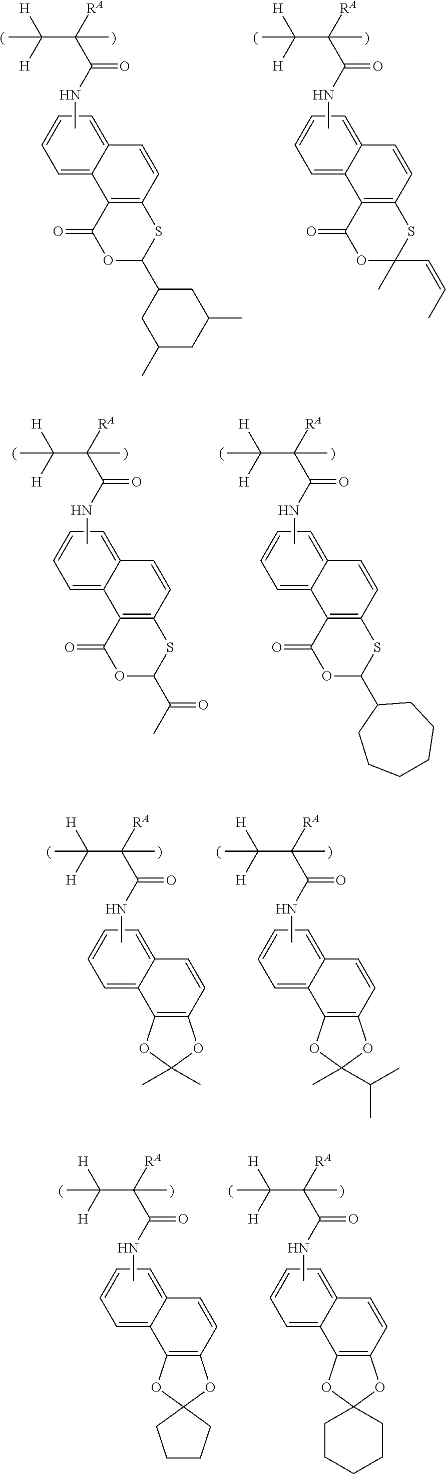

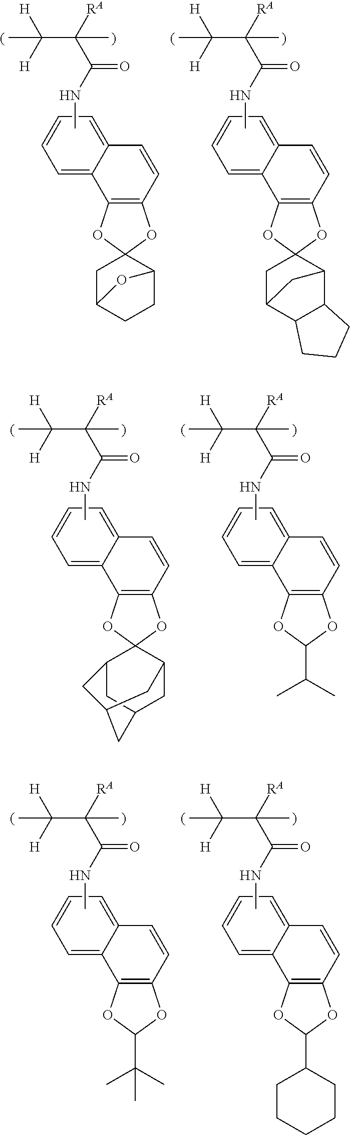

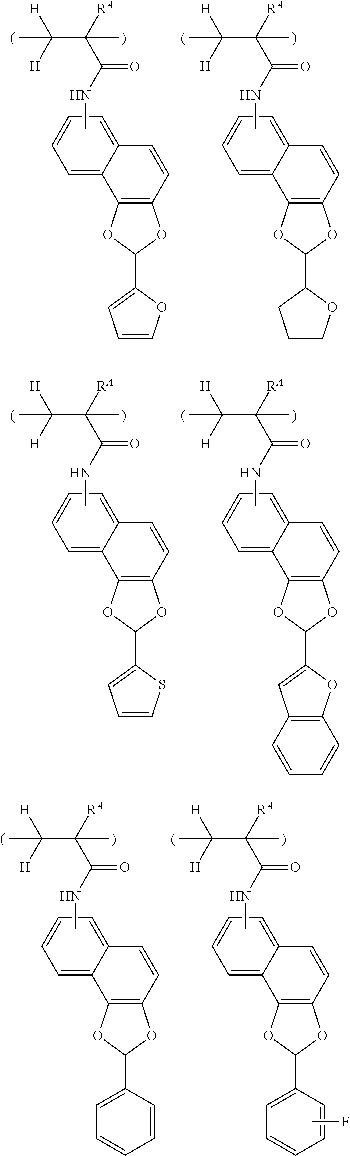

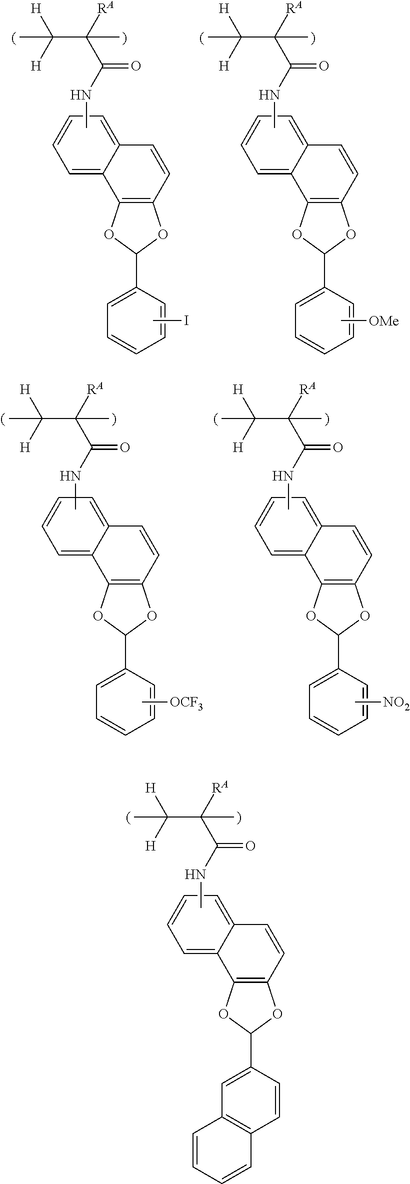

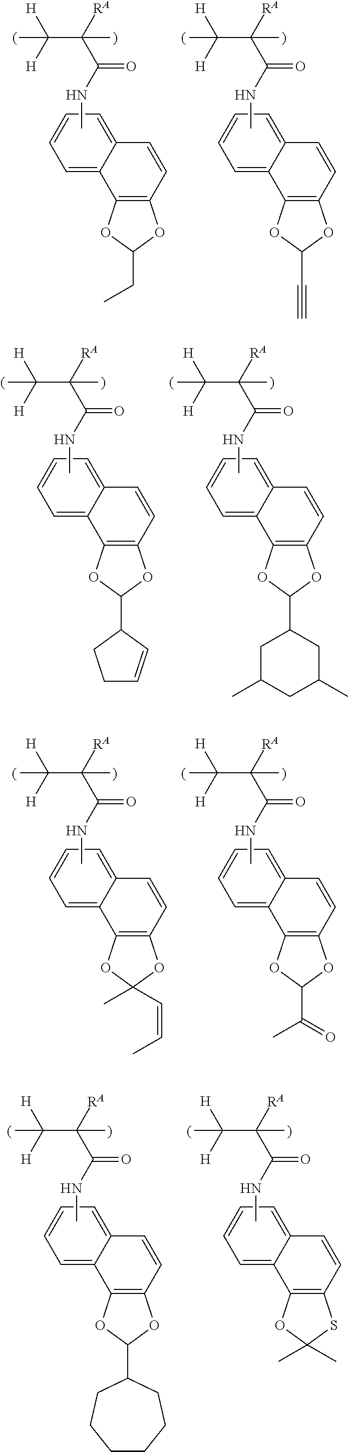

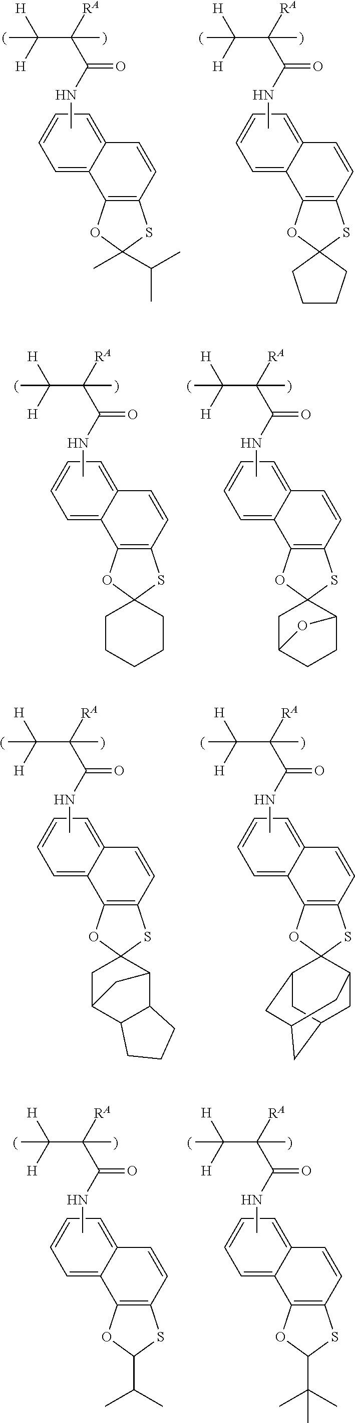

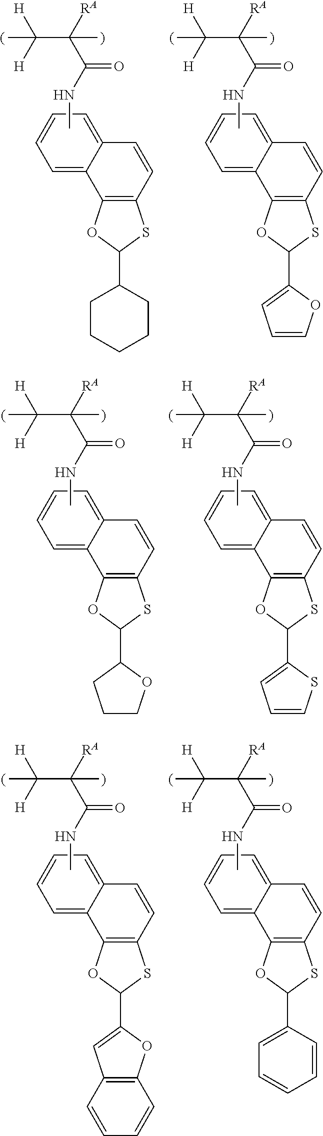

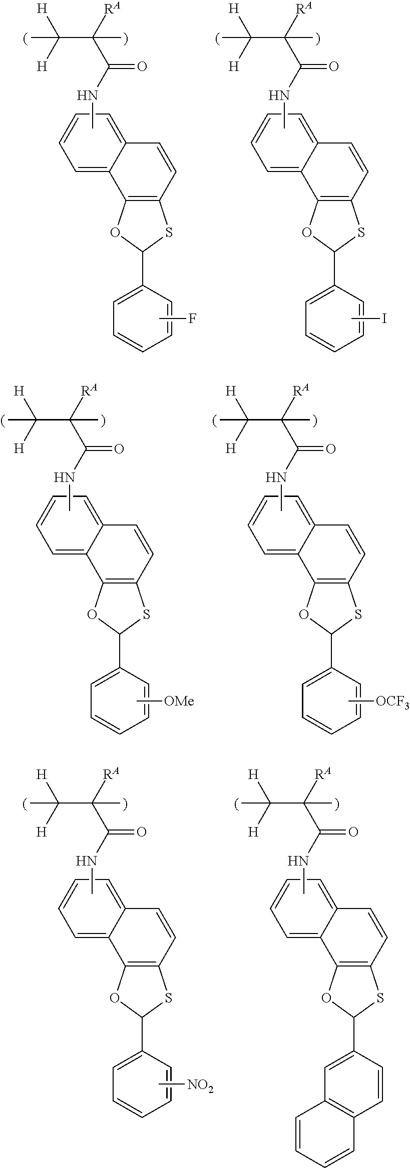

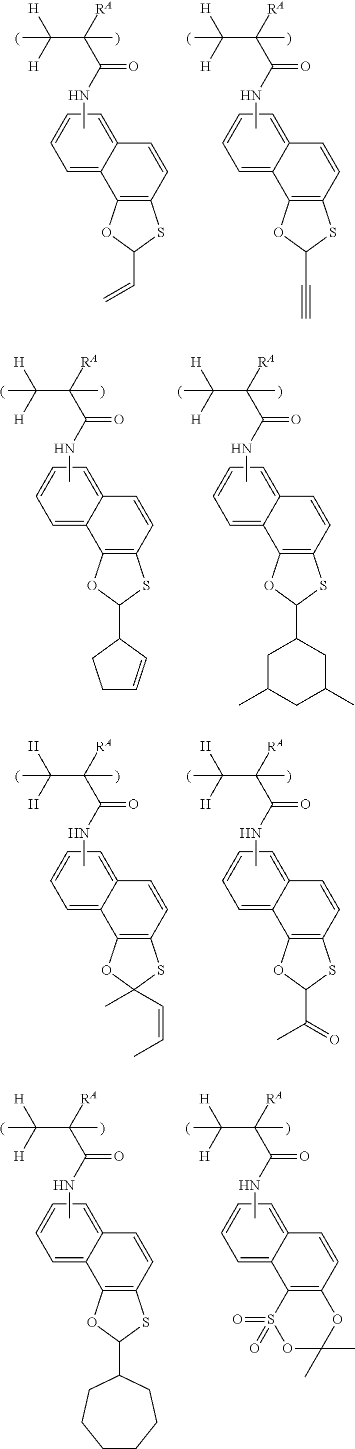

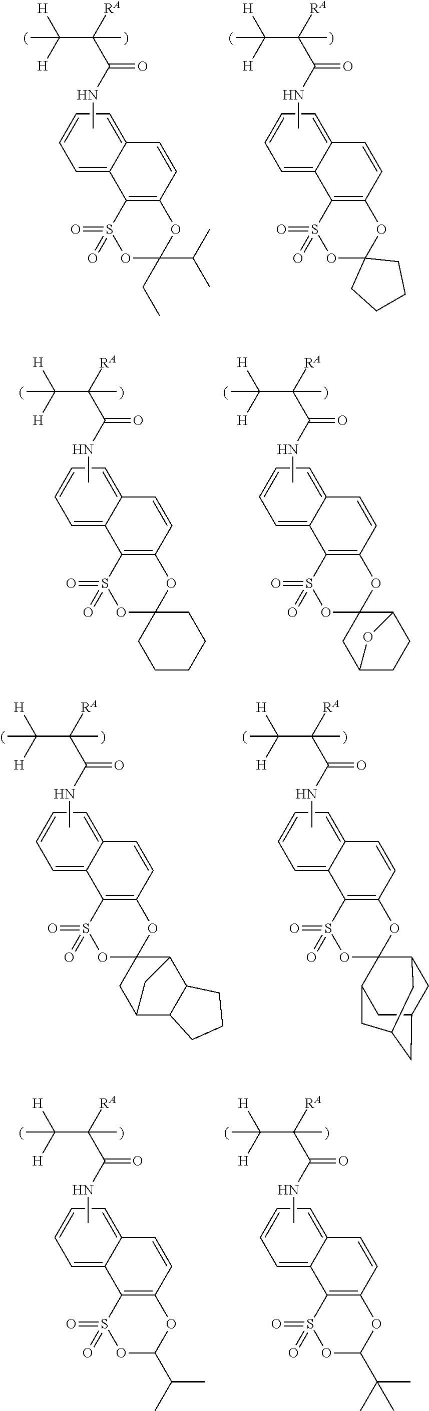

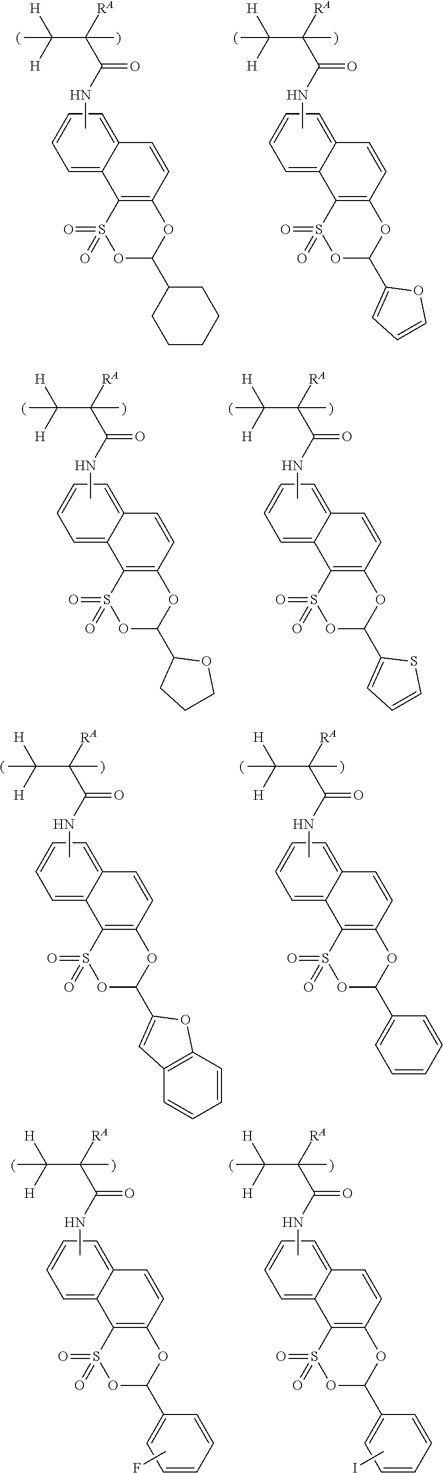

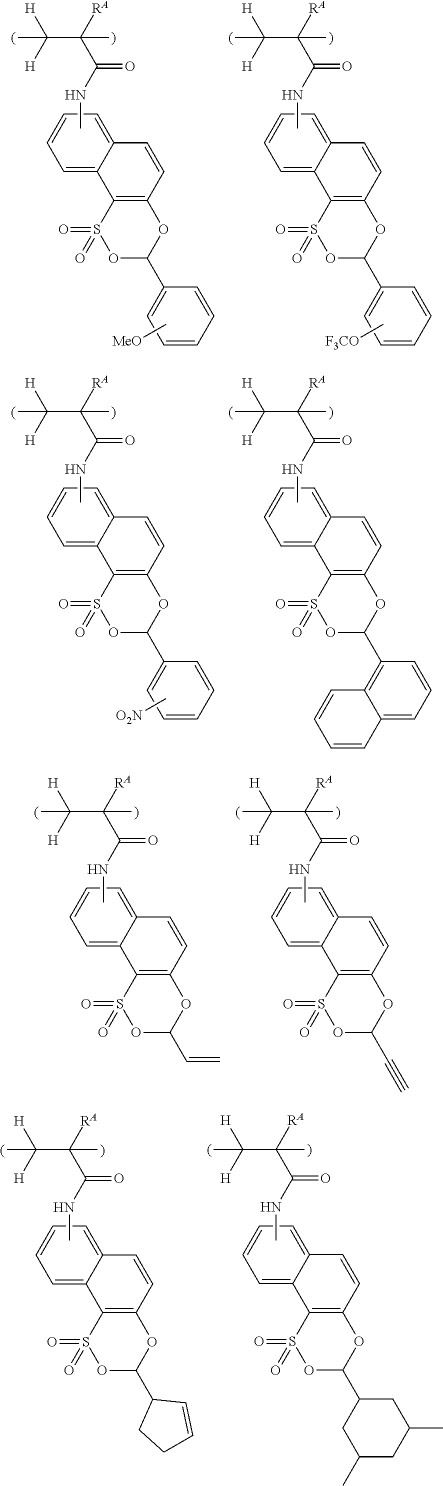

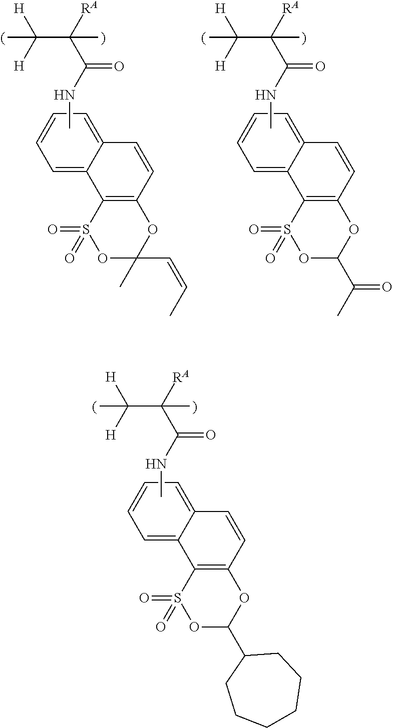

The base polymer preferably further comprises at least one type selected from repeat units having the formula (b1), which are also referred to as repeat units (b1) and repeat units having the formula (b2), which are also referred to as repeat units (b2).

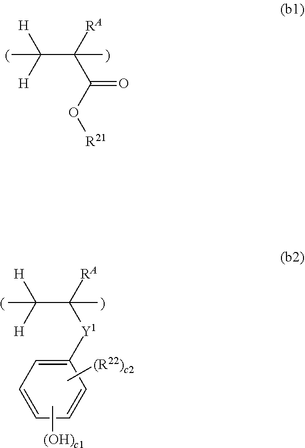

In formulae (b1) and (b2), R^{A} is each independently hydrogen, fluorine, methyl or trifluoromethyl. Y¹ is a single bond or *—C(═O)—O—. * designates a point of attachment to the carbon atom in the backbone. R²¹ is hydrogen or a C₁-C₂₀ group containing at least one structure selected from among hydroxy other than phenolic hydroxy, cyano, carbonyl, carboxy, ether bond, ester bond, sulfonate ester bond, carbonate bond, lactone ring, sultone ring and carboxylic anhydride (—C(═O)—O—C(═O)—). R²² is halogen, hydroxy, carboxy, nitro, cyano, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom. c1 is 1, 2, 3, or 4. c2 is 0, 1, 2, 3, or 4. It is noted that 1≤c1+c2≤5. A plurality of R²² may be identical or different when c2 is 2, 3, or 4.

Examples of the repeat units (b1) are shown below, but not limited thereto. In the formulae, R^{A} is as defined above.

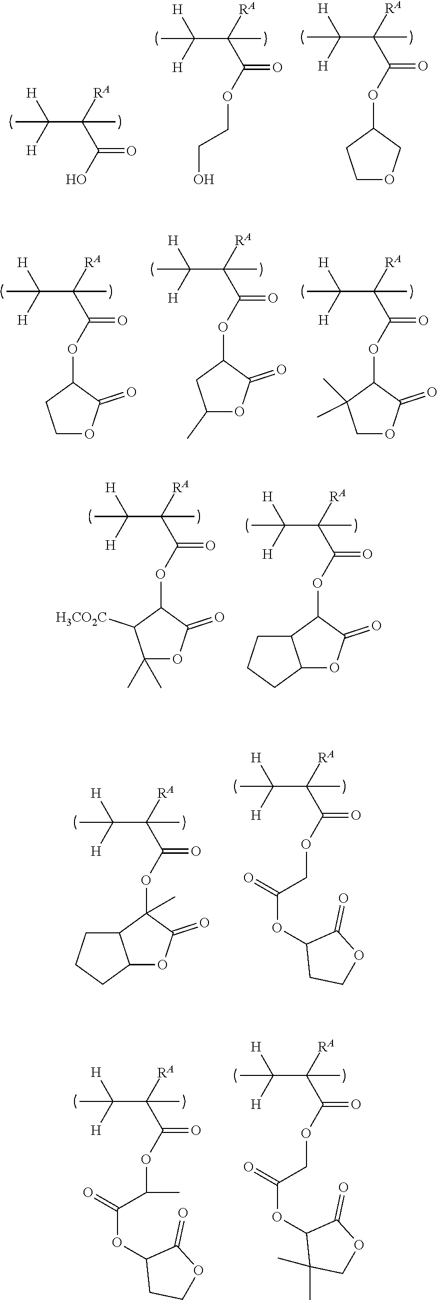

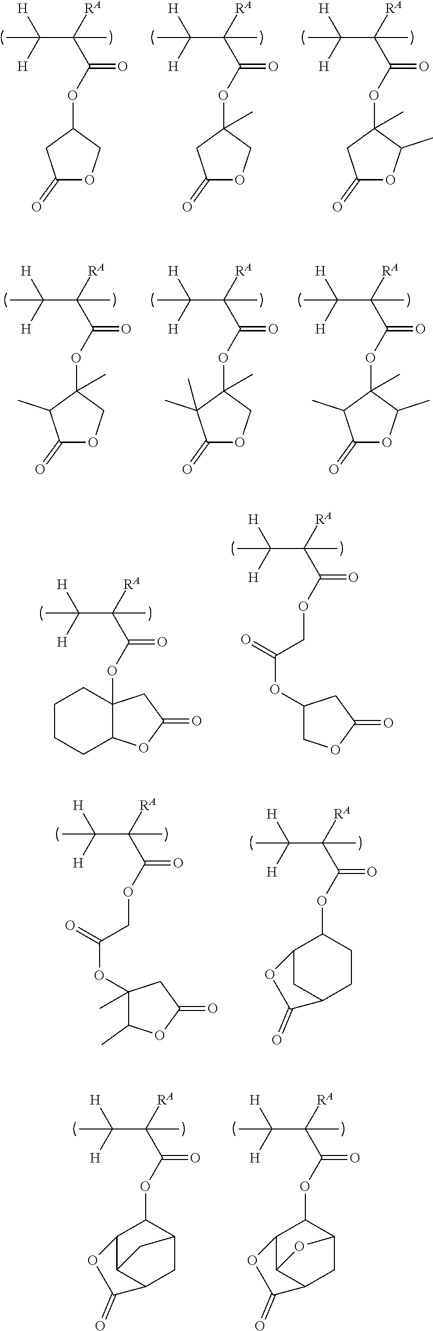

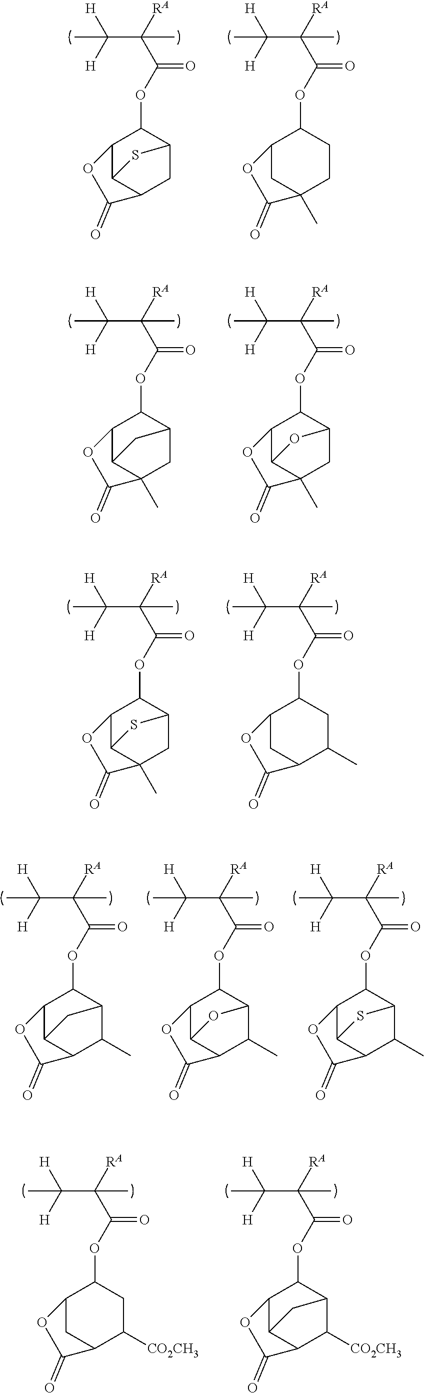

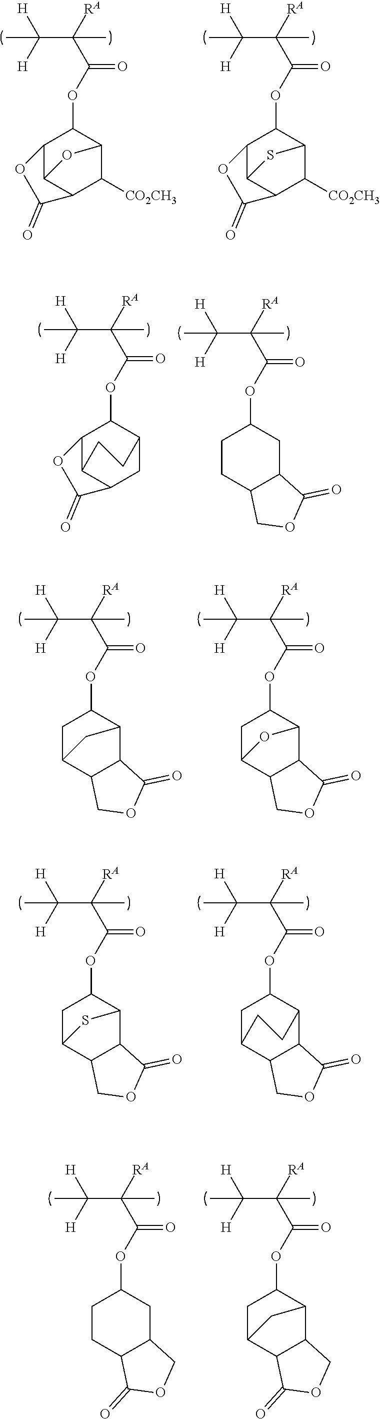

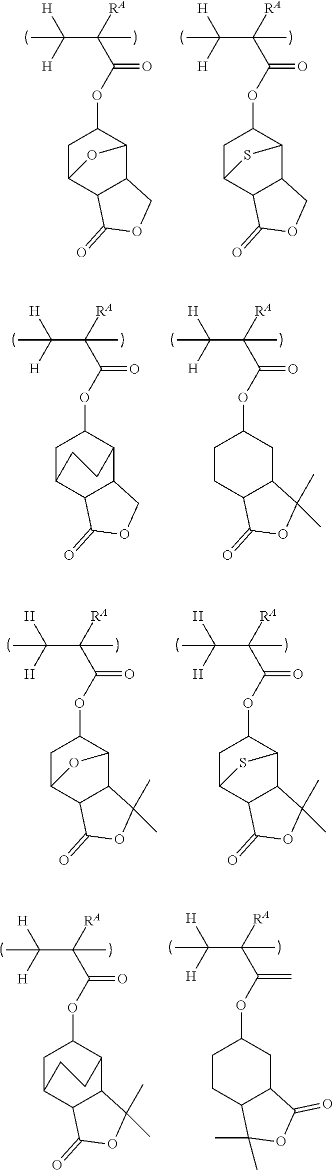

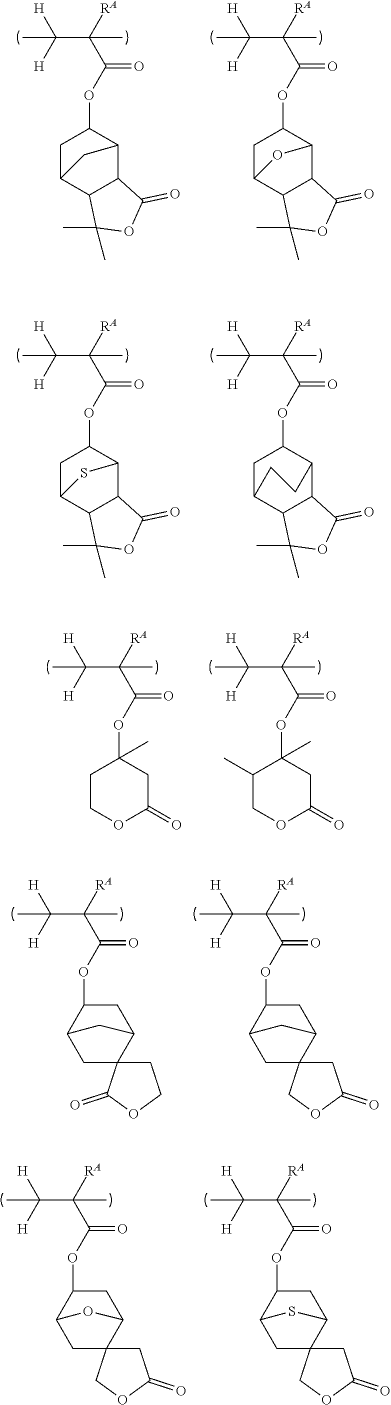

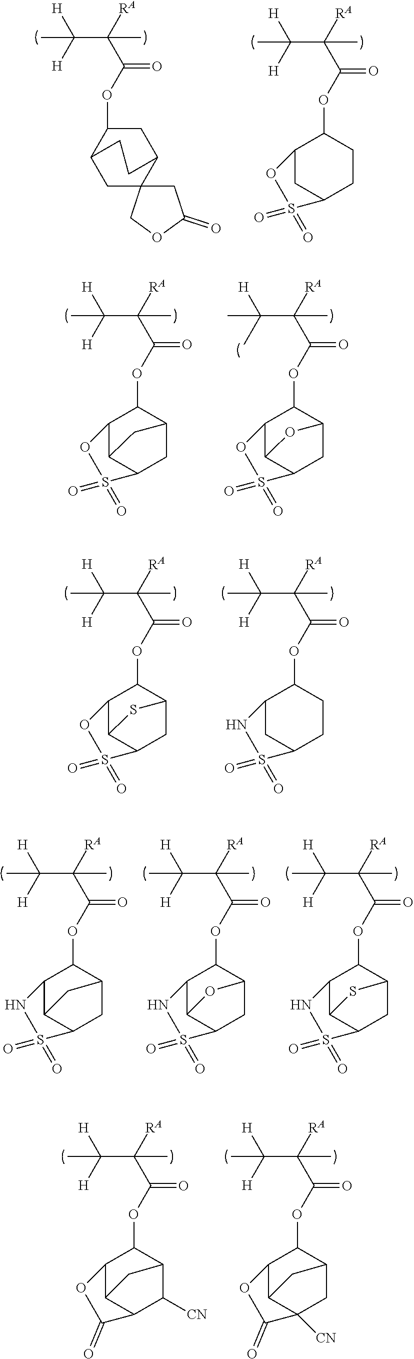

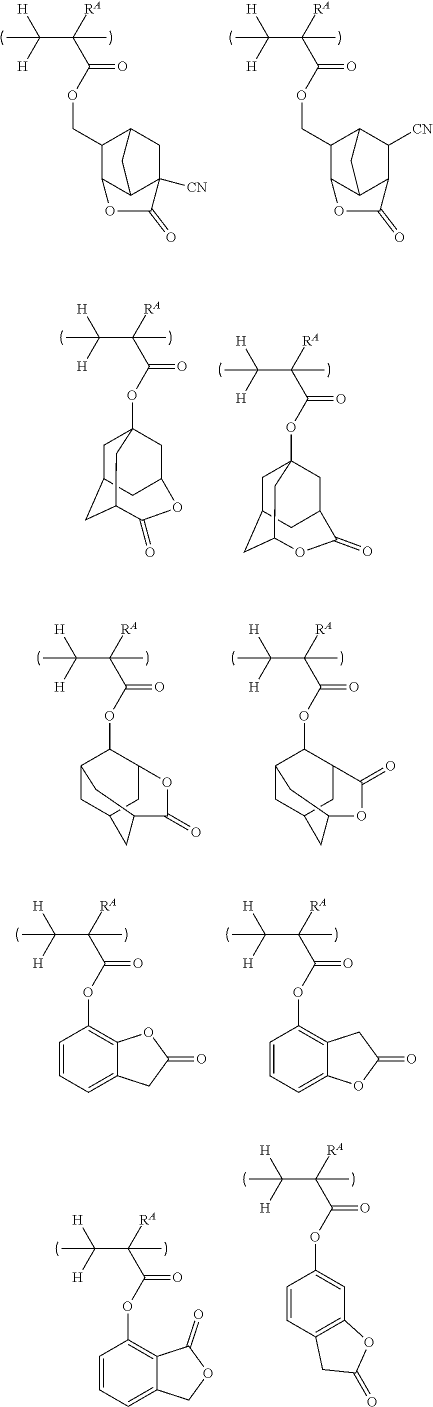

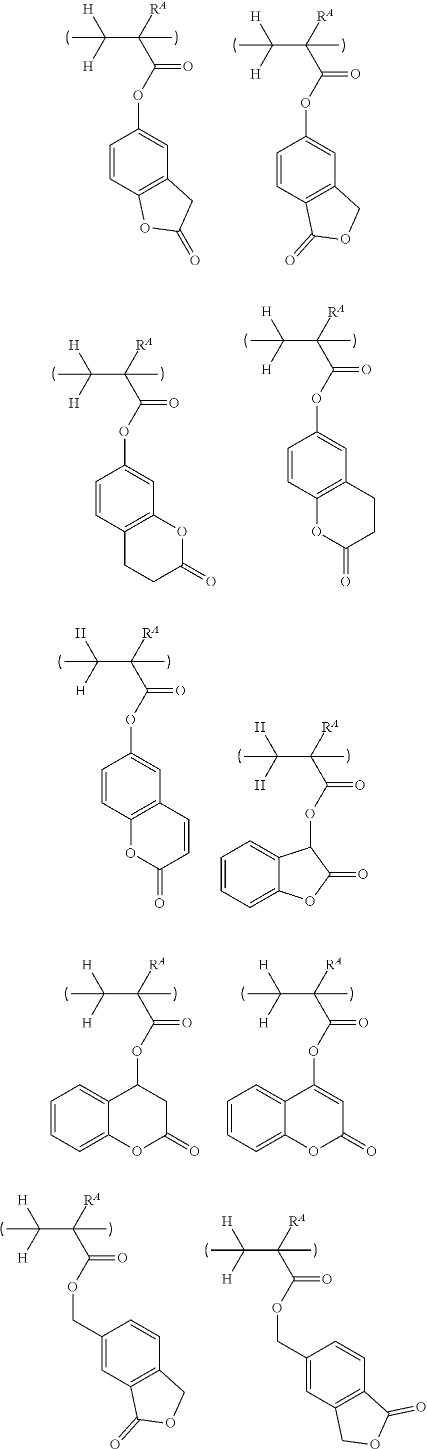

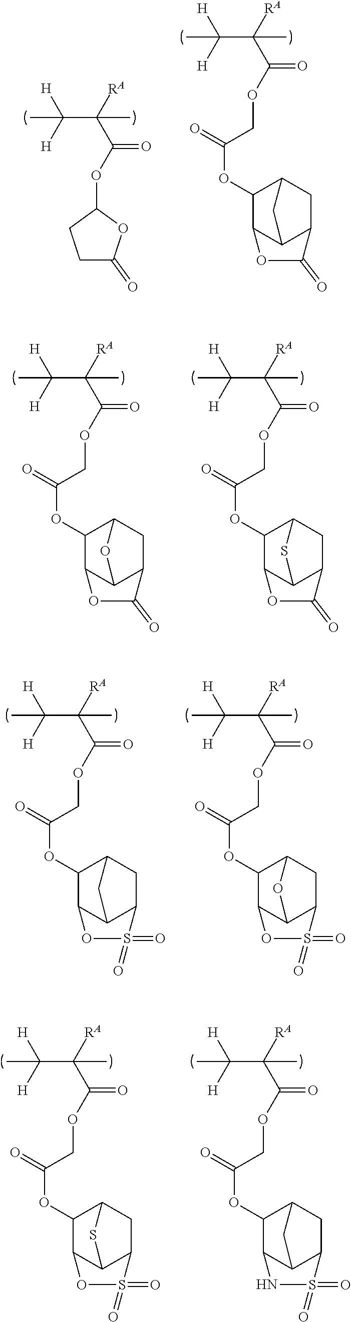

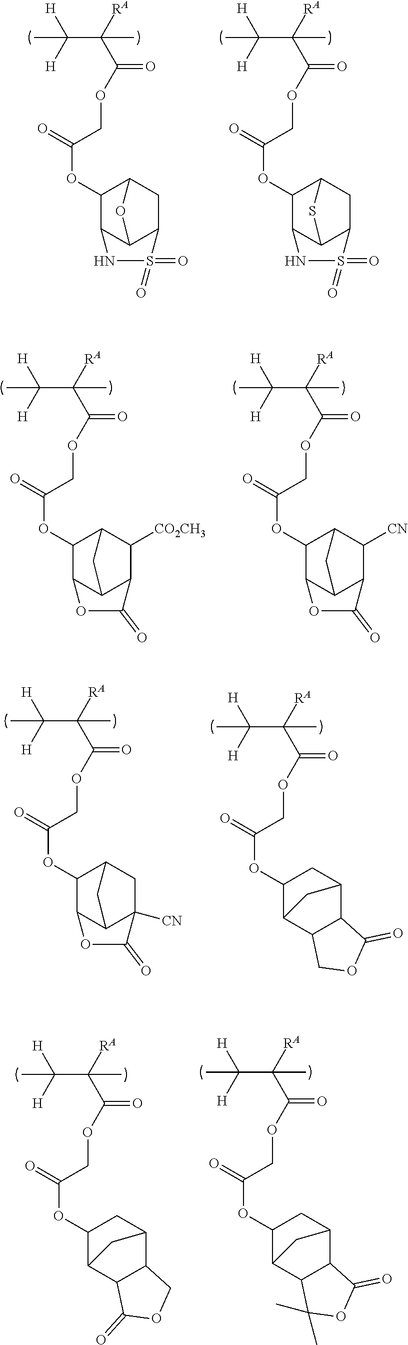

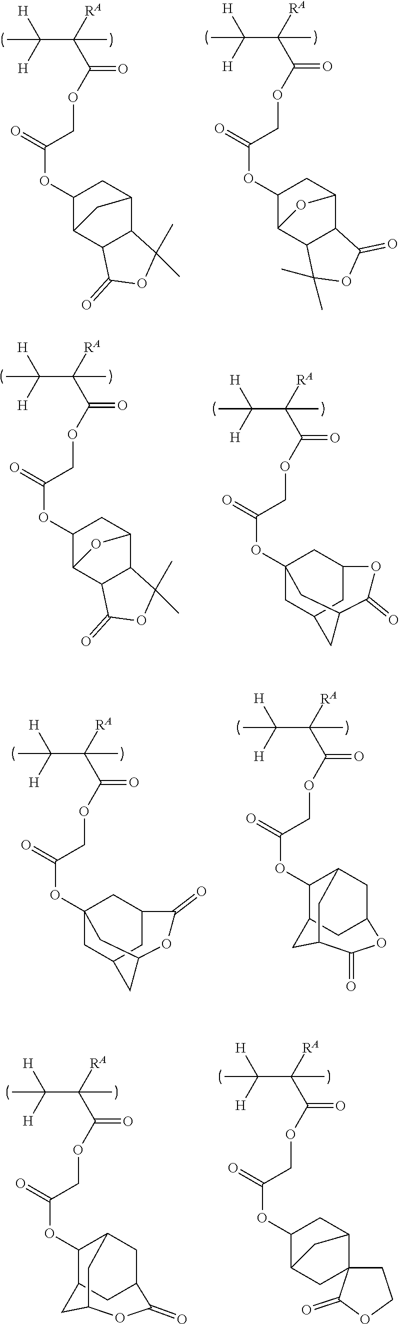

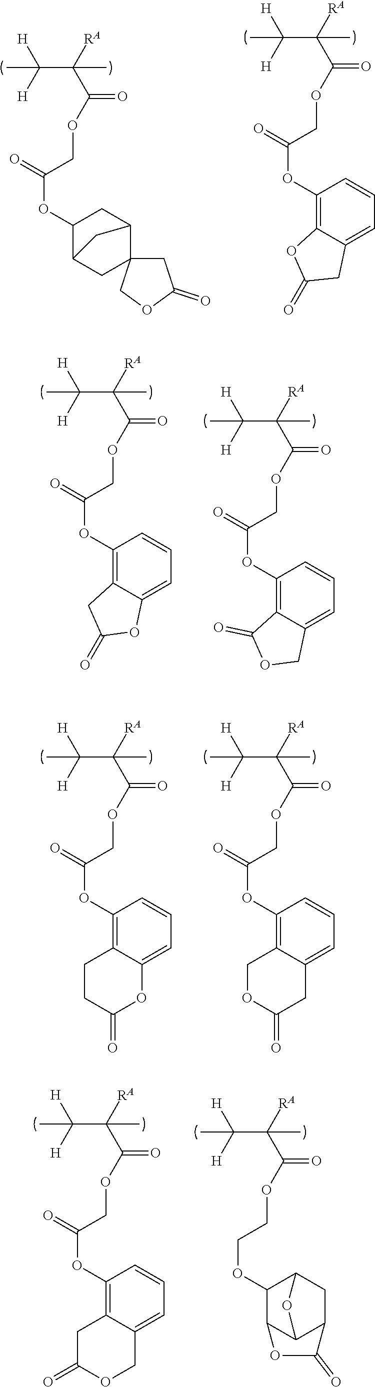

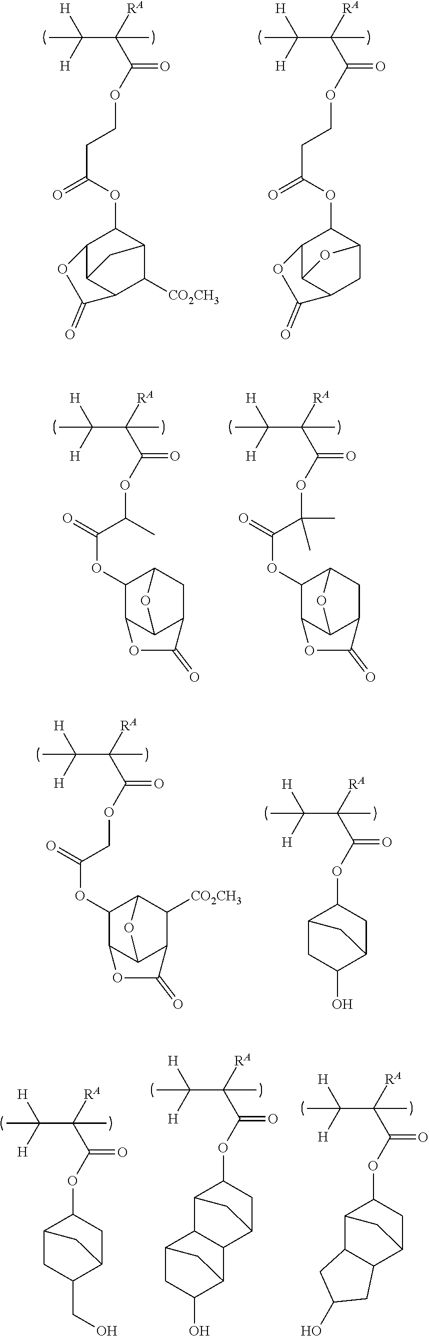

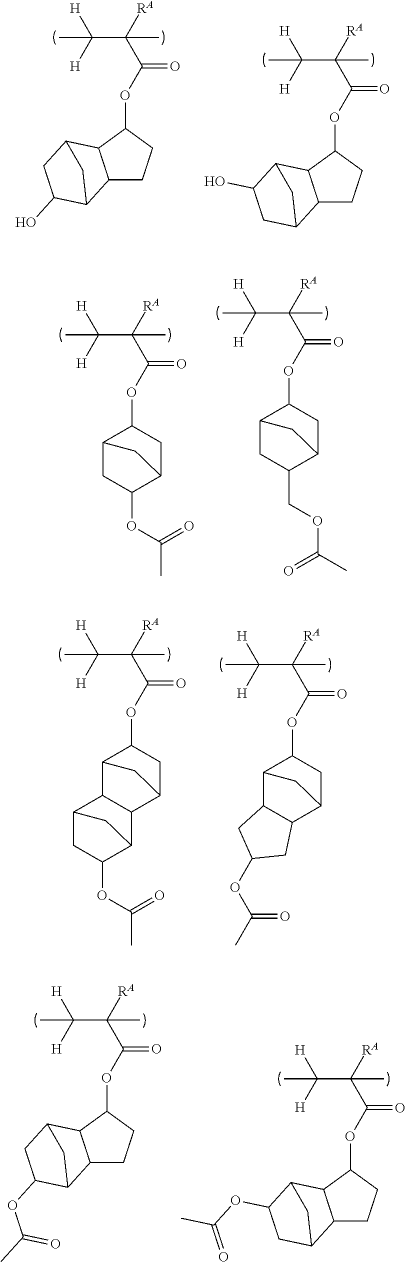

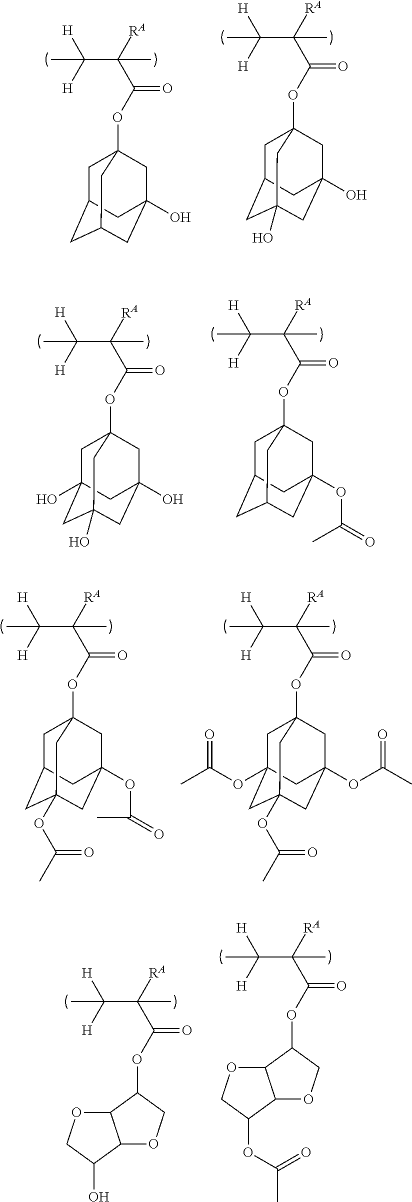

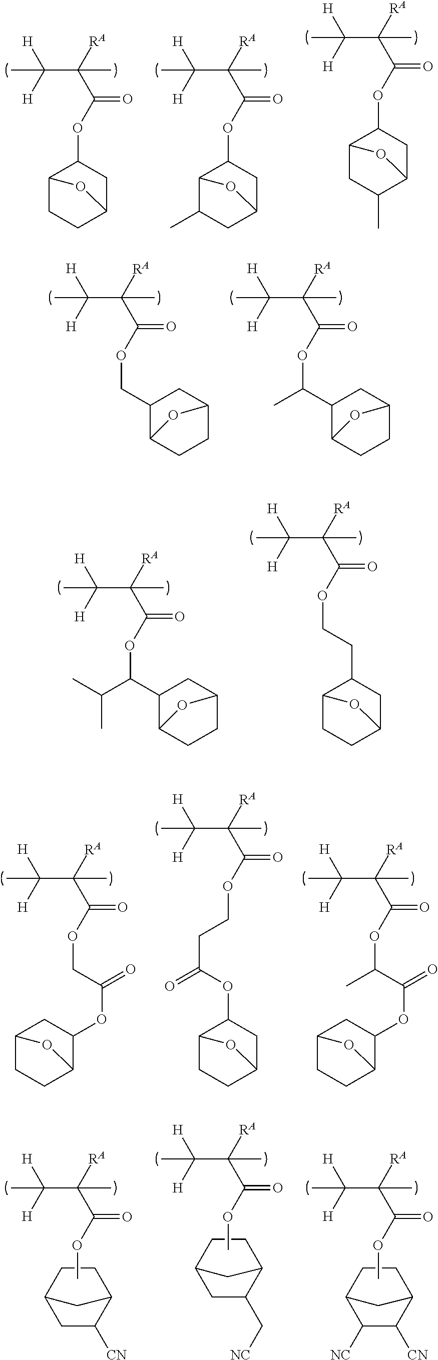

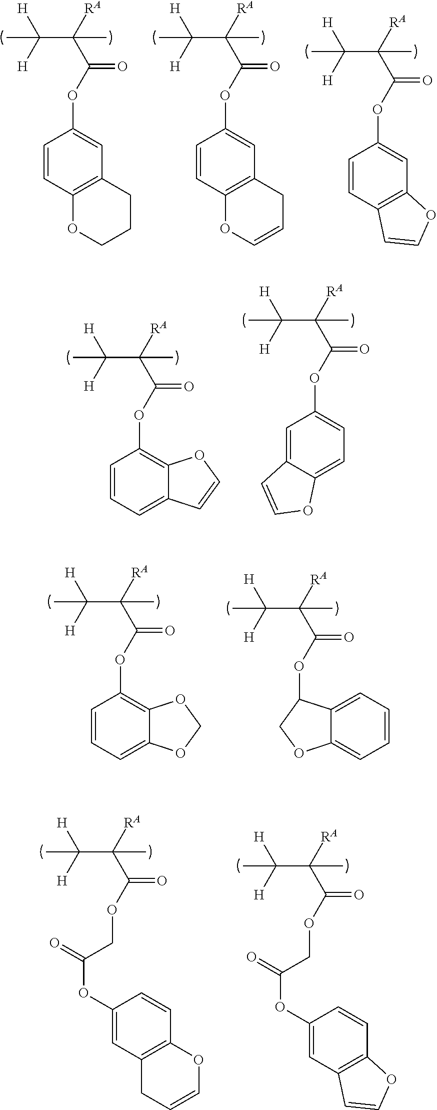

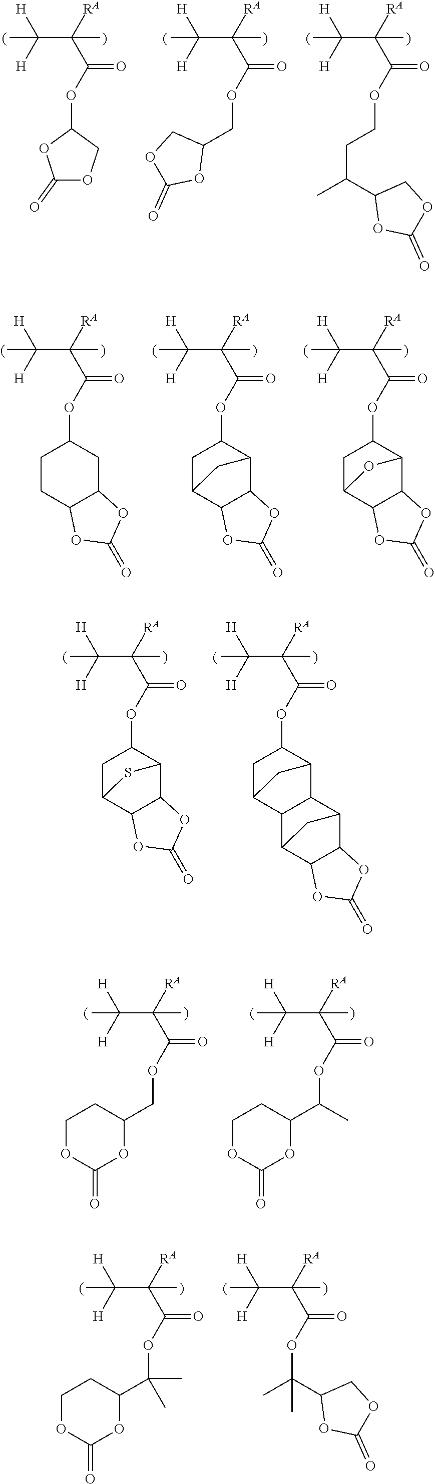

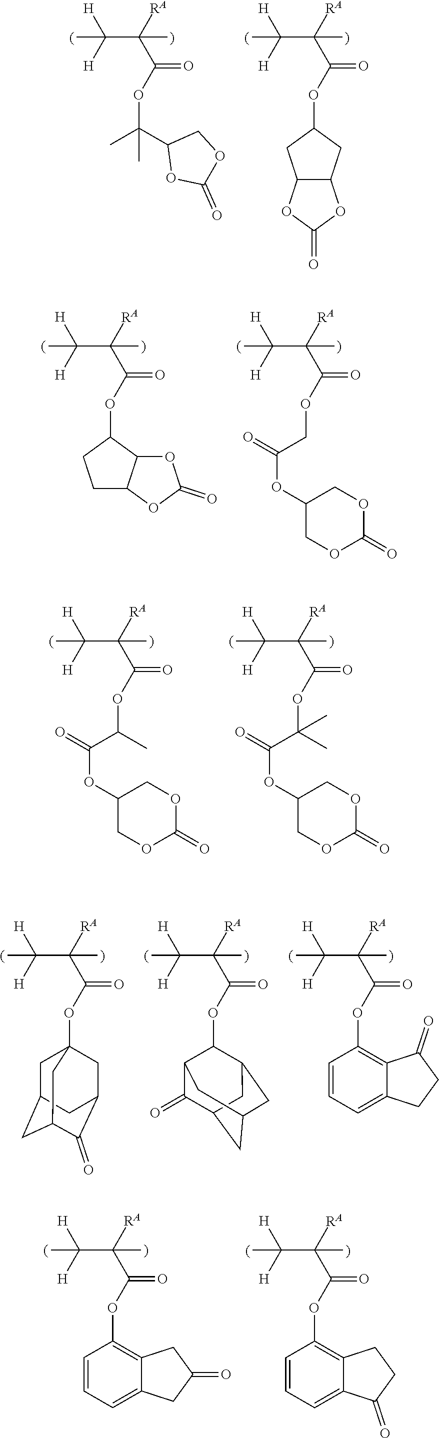

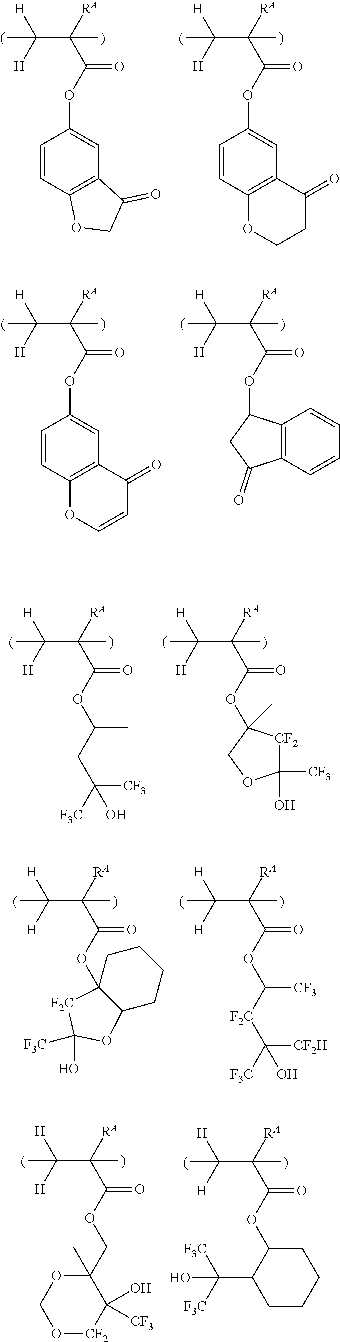

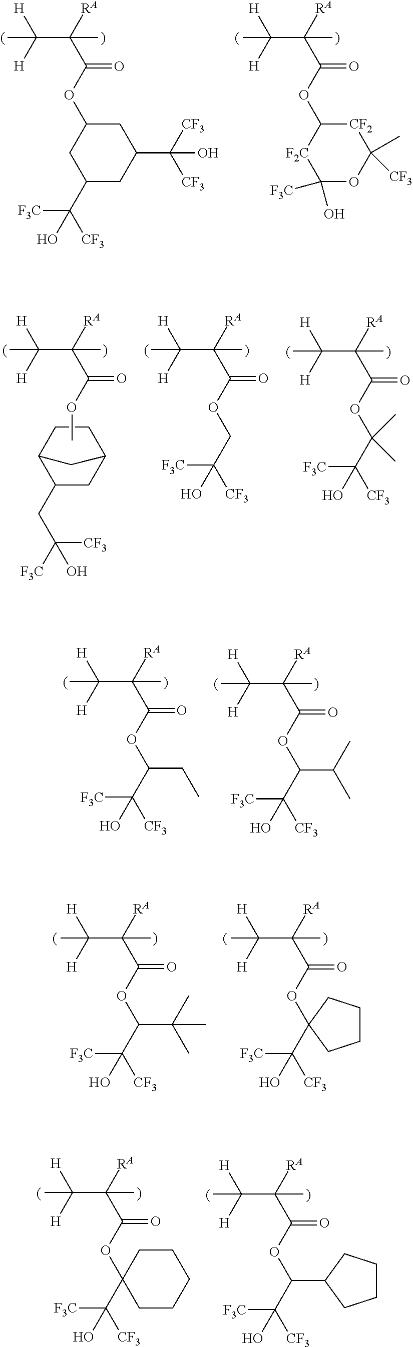

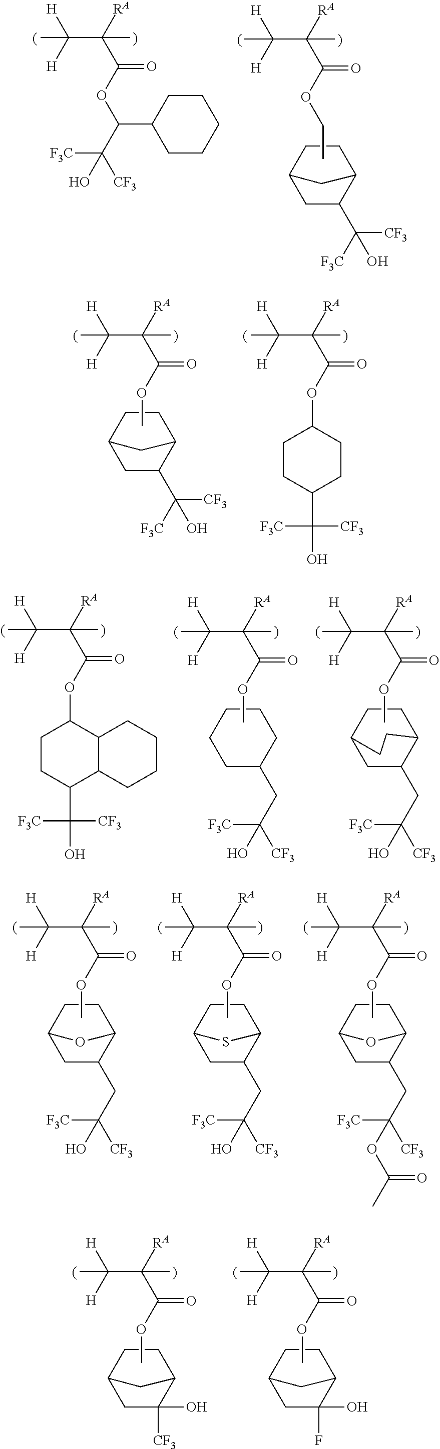

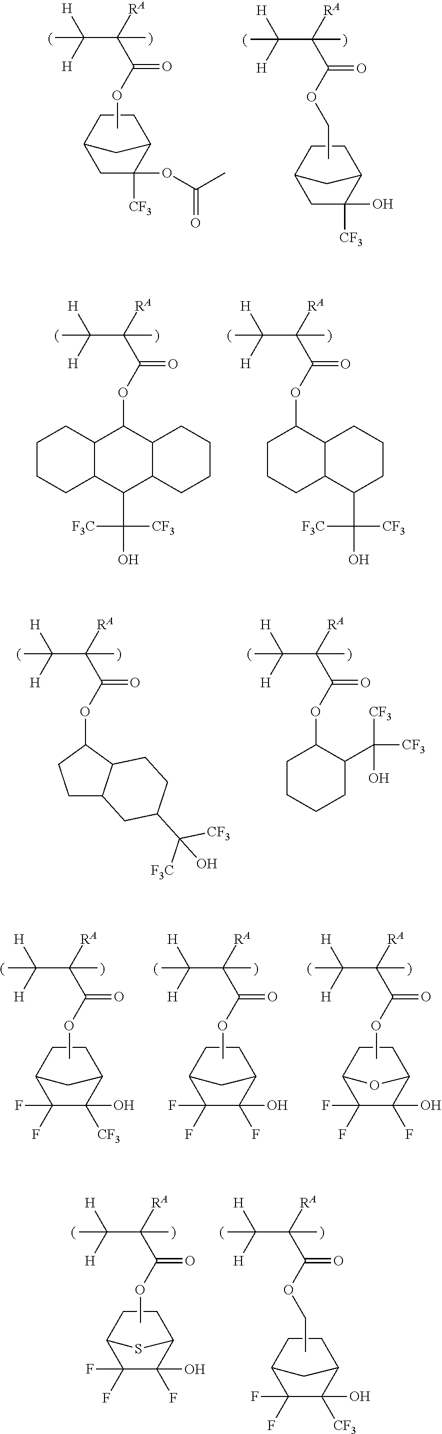

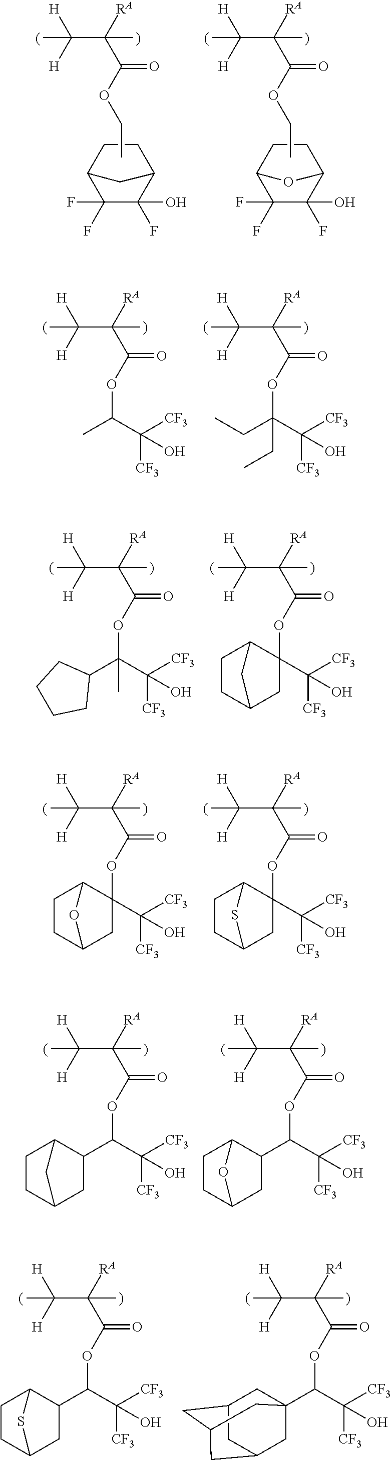

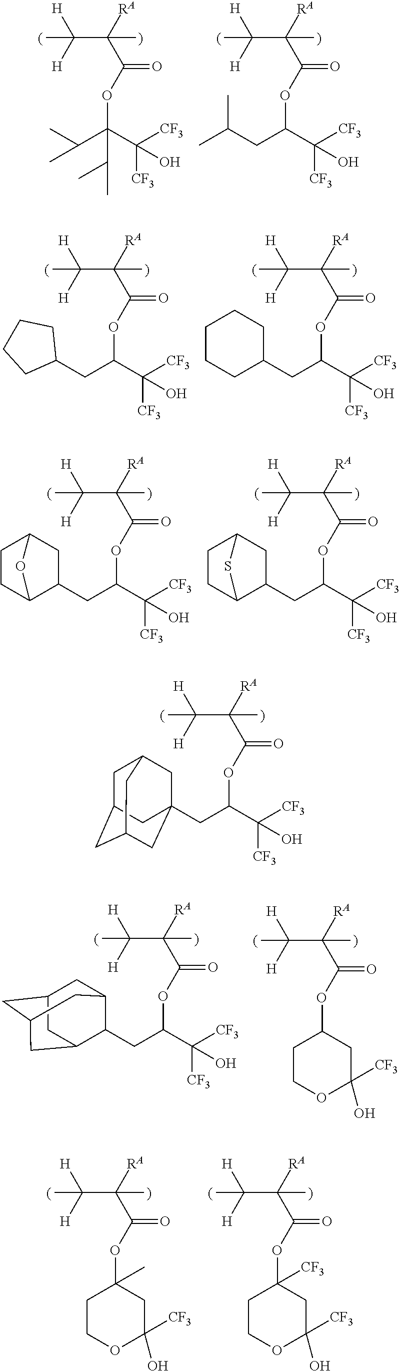

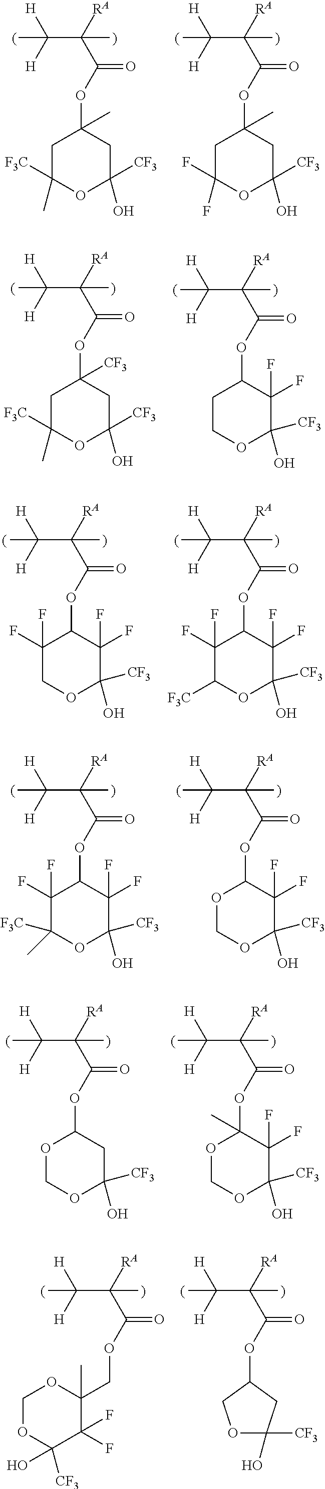

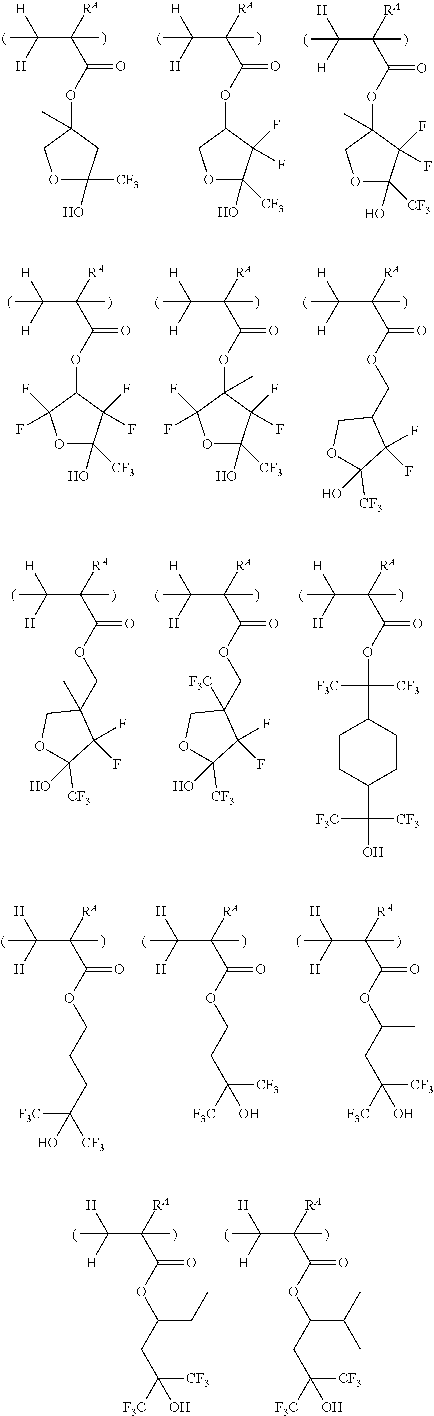

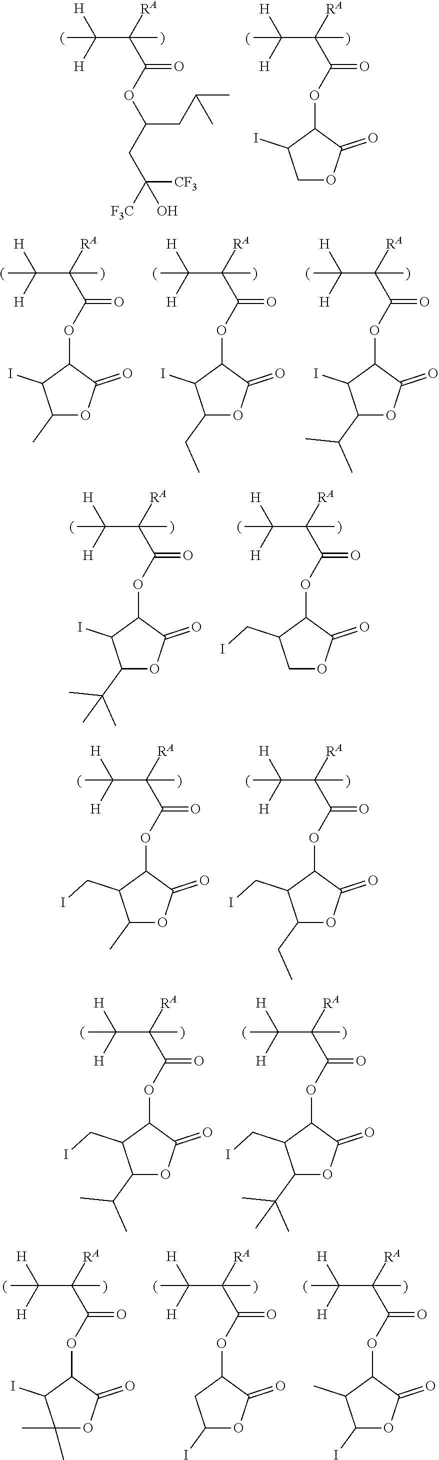

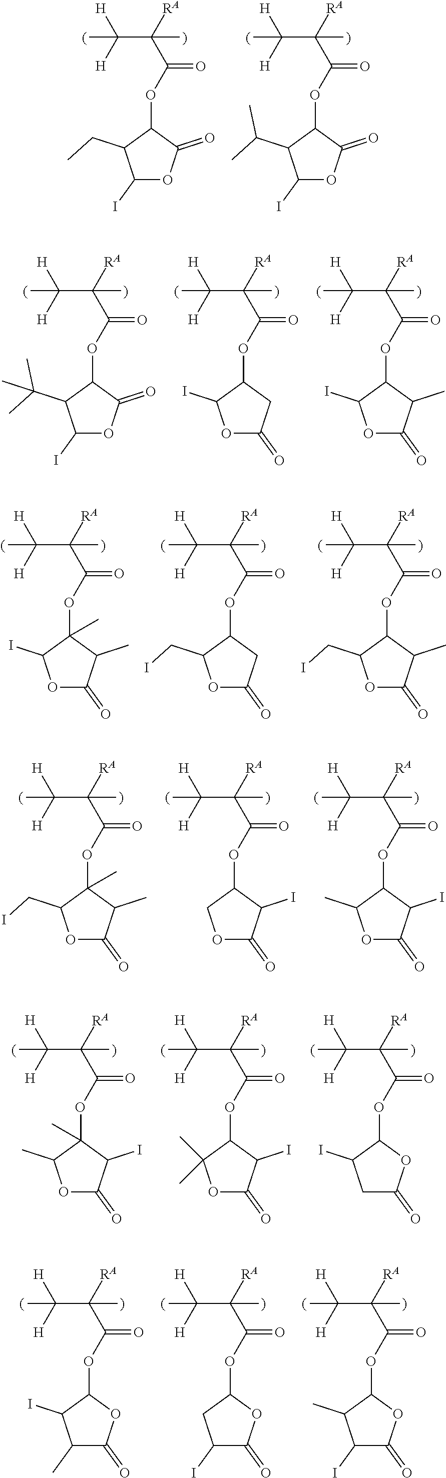

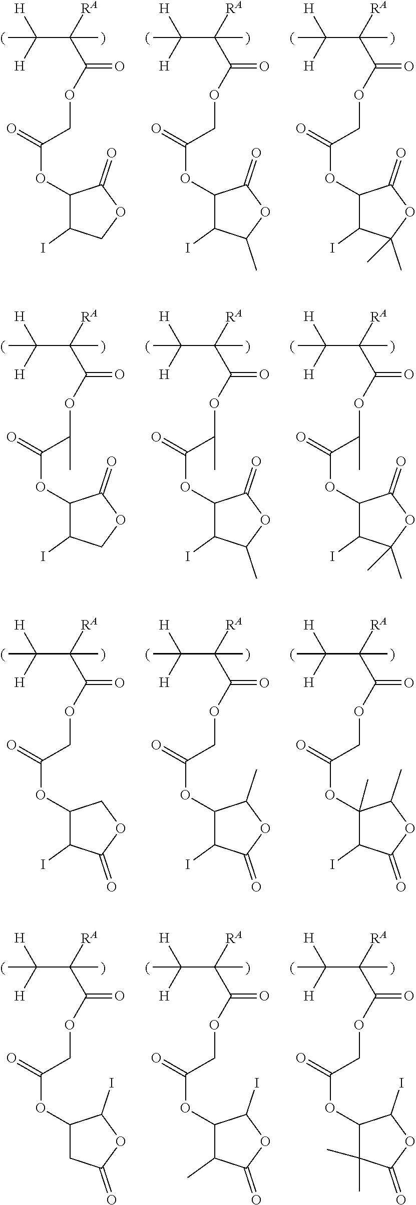

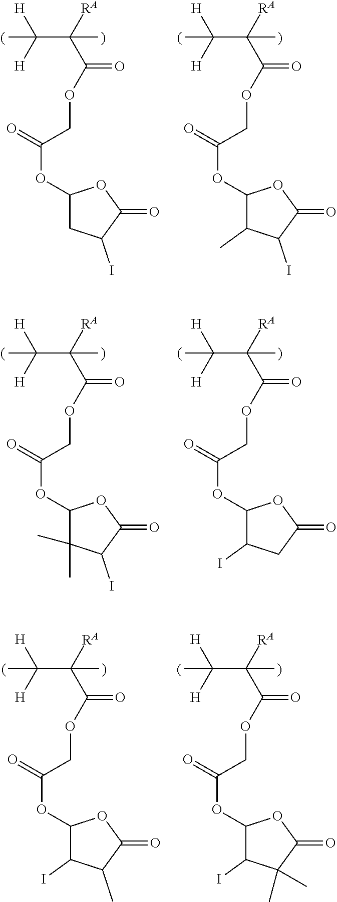

Examples of the repeat units (b2) are shown below, but not limited thereto. In the formulae, R^{A} is as defined above.

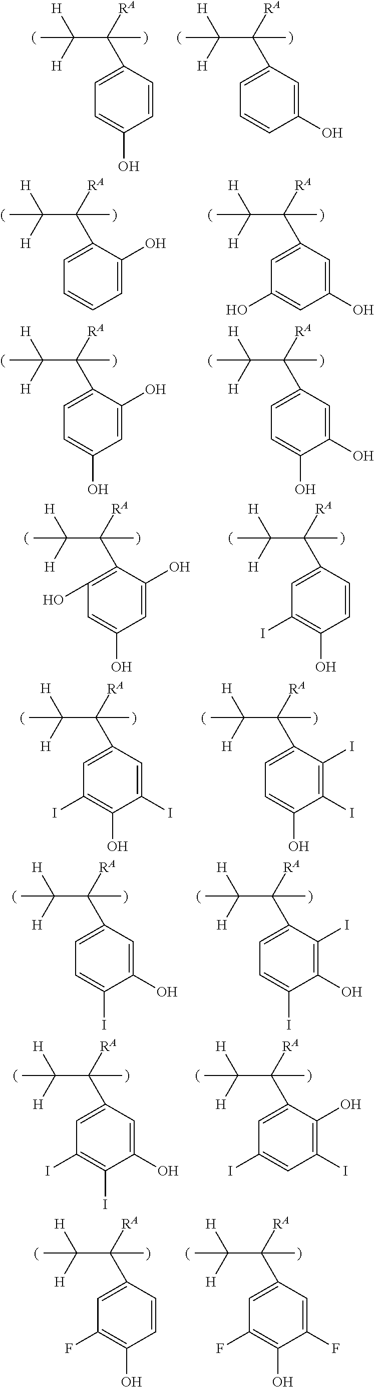

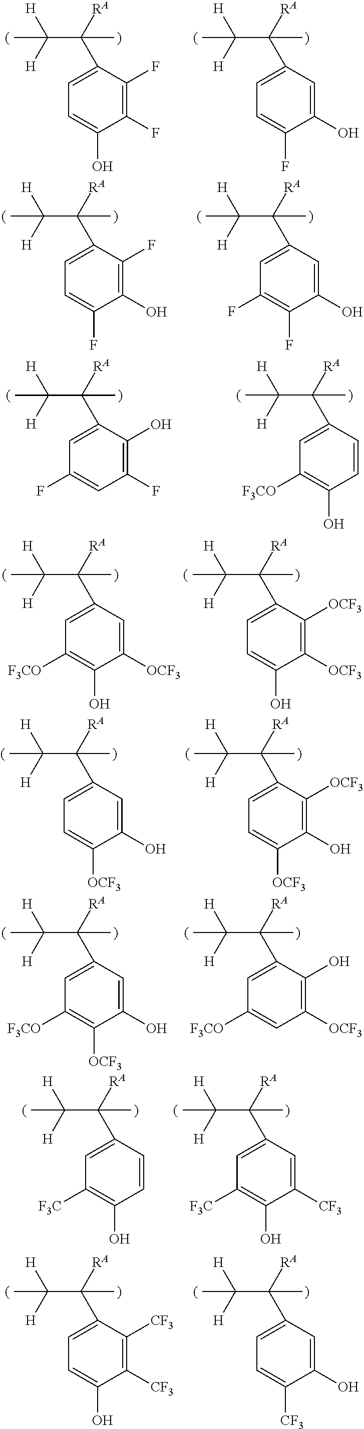

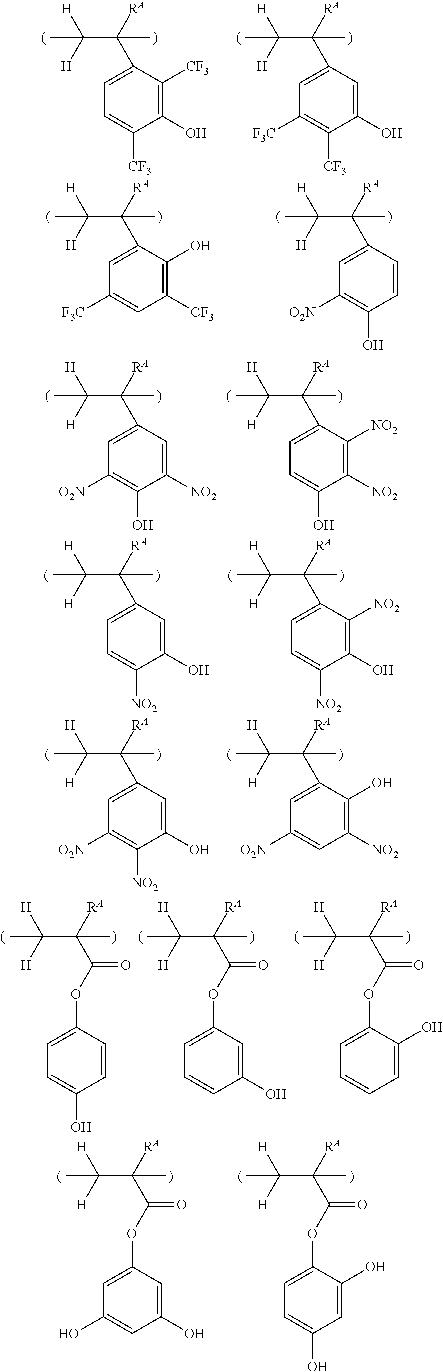

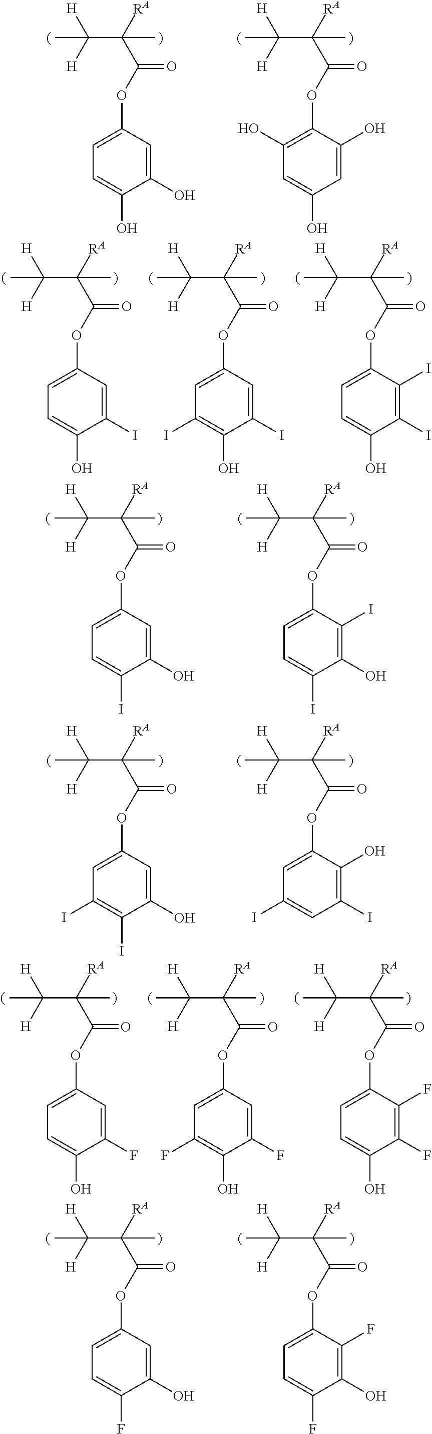

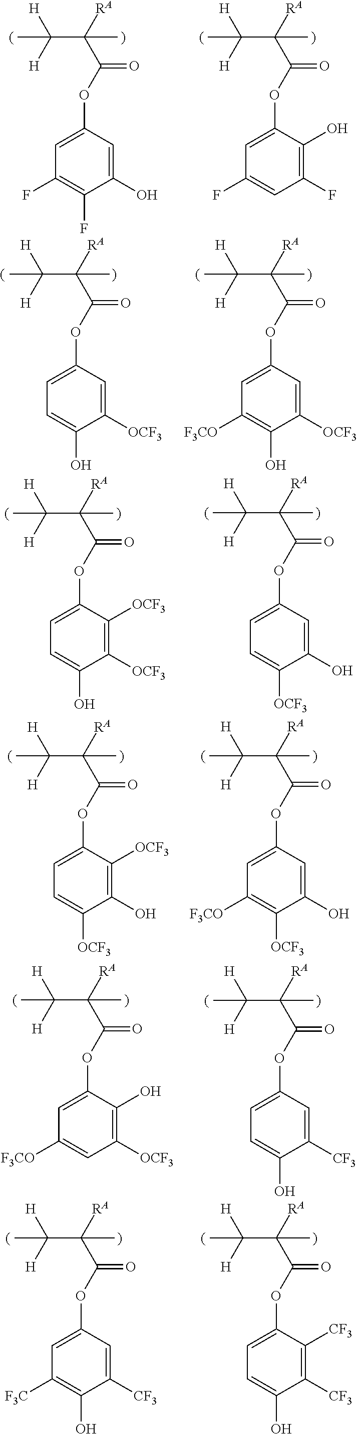

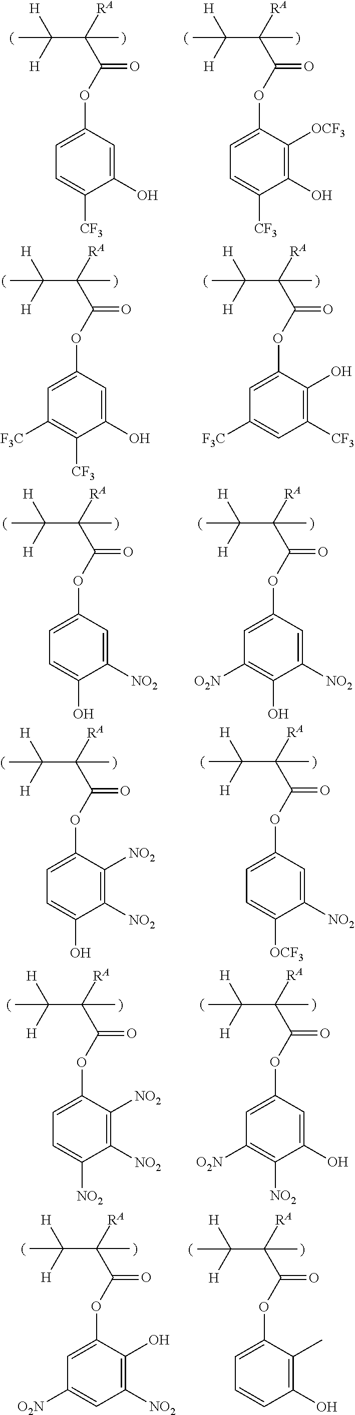

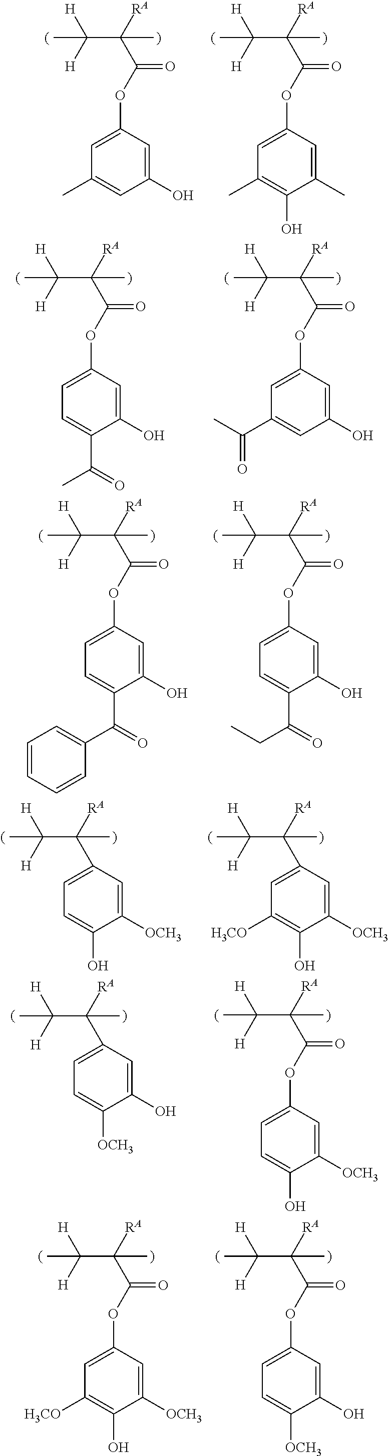

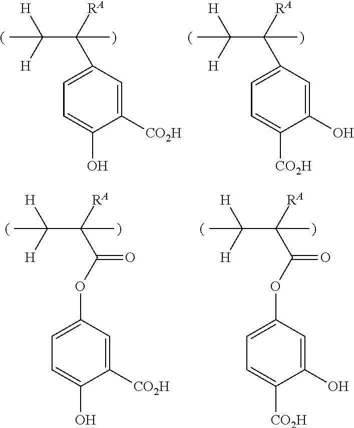

Of the repeat units (b1) or (b2), those units having a lactone ring as the polar group are preferred in the ArF lithography and those units having a phenolic site are preferred in the KrF, EB and EUV lithography.

The base polymer may further comprise at least one type selected from repeat units having the formula (c1), which are also referred to as repeat units (c1), repeat units having the formula (c2), which are also referred to as repeat units (c2), repeat units having the formula (c3), which are also referred to as repeat units (c3), repeat units having the formula (c4), which are also referred to as repeat units (c4), and repeat units having the formula (c5), which are also referred to as repeat units (c5).

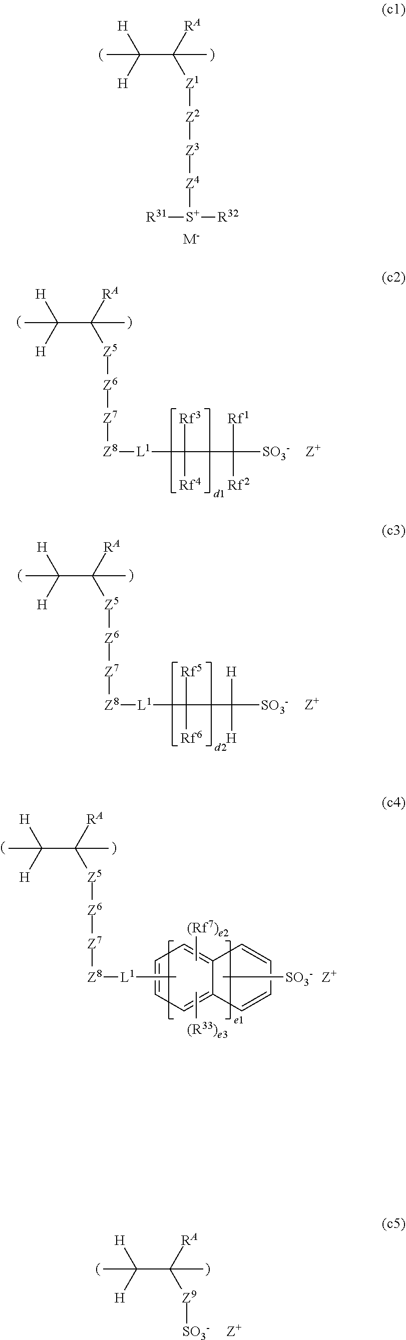

In formulae (c1) to (c5), R^{A} is each independently hydrogen, fluorine, methyl or trifluoromethyl. Z¹ is a single bond or optionally substituted phenylene group. Z² is a single bond, **—C(═O)—O—Z²¹—, **—C(═O)—NH—Z²¹—, or **—O—Z²¹—. Z²¹ is a C₁-C₆ aliphatic hydrocarbylene group, a phenylene group or a divalent group obtained by combining the foregoing, which may contain halogen, a carbonyl moiety, ester bond, ether bond or hydroxy moiety. Z³ is a single bond, ether bond, ester bond, amide bond, sulfonate ester bond, sulfonamide bond, carbonate bond or carbamate bond. Z⁴ is a single bond, or a C₁-C₆ aliphatic hydrocarbylene group, a phenylene group or a divalent group obtained by combining the foregoing, which may contain halogen, a carbonyl moiety, ester bond, ether bond or hydroxy moiety. Z⁵ is each independently a single bond, optionally substituted phenylene group, naphthylene group, or *—C(═O)—O—Z⁵. Z⁵¹ is a C₁-C₁₀ aliphatic hydrocarbylene group, or phenylene or naphthylene group, the aliphatic hydrocarbylene group may contain halogen, a hydroxy moiety, ether bond, ester bond or lactone ring. Z⁶ is a single bond, ether bond, ester bond, amide bond, sulfonate ester bond, sulfonamide bond, carbonate bond or carbamate bond. Z⁷ is each independently a single bond, ***—Z⁷¹—C(═O)—O—, ***—C(═O)—NH—Z⁷¹—, or ***—O—Z⁷¹—. Z⁷¹ is a C₁-C₂₀ hydrocarbylene group which may contain a heteroatom. Z⁸ is each independently a single bond, ****—Z⁸¹—C(═O)—O—, ****—C(═O)—NH—Z⁸¹—, or ****—O—Z⁸¹—. Z⁸¹ is a C₁-C₂₀ hydrocarbylene group which may contain a heteroatom. Z⁹ is a single bond, methylene, ethylene, phenylene, fluorinated phenylene, trifluoromethyl-substituted phenylene, *—C(═O)—O—Z⁹¹—, *—C(═O)—N(H)—Z⁹¹—, or *—O—Z⁹¹—. Z⁹¹ is a C₁-C₆ aliphatic hydrocarbylene group, phenylene group, fluorinated phenylene group or trifluoromethyl-substituted phenylene group, which may contain a carbonyl moiety, ester bond, ether bond or hydroxy moiety. * designates a point of attachment to the carbon atom in the backbone. ** designates a point of attachment to Z¹. *** designates a point of attachment to Z⁶. **** designates a point of attachment to Z⁷.

The aliphatic hydrocarbylene group represented by Z²¹, Z⁵¹, and Z⁹¹ may be straight, branched or cyclic. Examples thereof include alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, and hexane-1,6-diyl; cycloalkanediyl groups such as cyclopropanediyl, cyclobutanediyl, cyclopentanediyl and cyclohexanediyl; and combinations thereof.

The hydrocarbylene group which may contain a heteroatom, represented by Z⁷¹ and Z⁸¹, may be saturated or unsaturated and straight, branched or cyclic. Examples thereof are shown below, but not limited thereto.

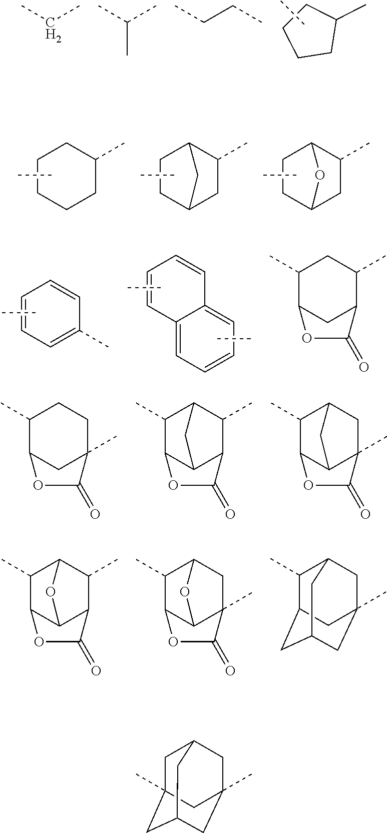

Herein the broken line denotes a valence bond.

In formula (c1), R³¹ and R³² are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, and tert-butyl; C₃-C₂₀ cyclic saturated hydrocarbyl groups such as cyclic saturated hydrocarbyl groups such as cyclopropyl, cyclopentyl, cyclohexyl, cylopropylmethyl, 4-methylcyclohexyl, cyclohexylmethyl, norbornyl, and adamantyl; C₂-C₂₀ alkenyl groups such as vinyl, 1-propenyl, 2-propenyl, butenyl, and hexenyl; C₃-C₂₀ cyclic unsaturated hydrocarbyl groups such as cyclohexenyl; C₆-C₂₀ aryl groups such as phenyl, naphthyl, and thienyl; C₇-C₂₀ aralkyl groups such as benzyl, 1-phenylethyl, and 2-phenylethyl; and combinations thereof. Of these, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(O)—O—C(O)—) or haloalkyl moiety.

R³¹ and R³² may bond together to form a ring with the sulfur atoms to which they are attached. Examples of the ring include those having the formulae.

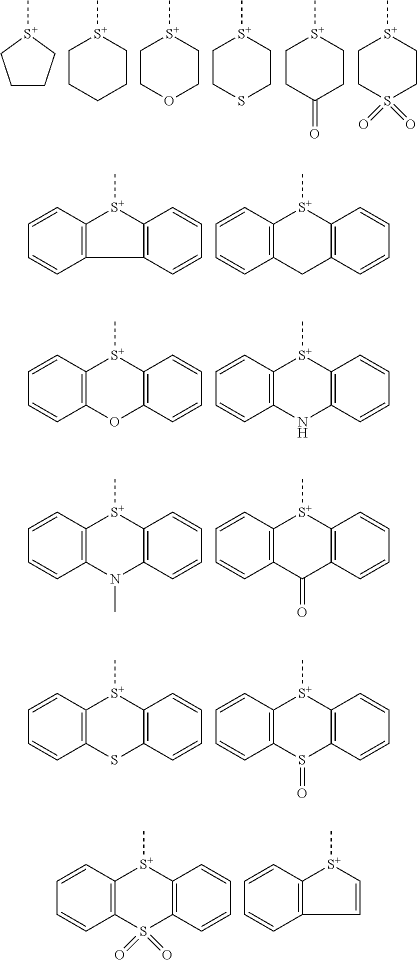

Herein the broken line is a point of attachment to Z⁴.

Examples of the cation in repeat unit (c1) are given below, but not limited thereto. In the formulae, R^{A} is as defined above.

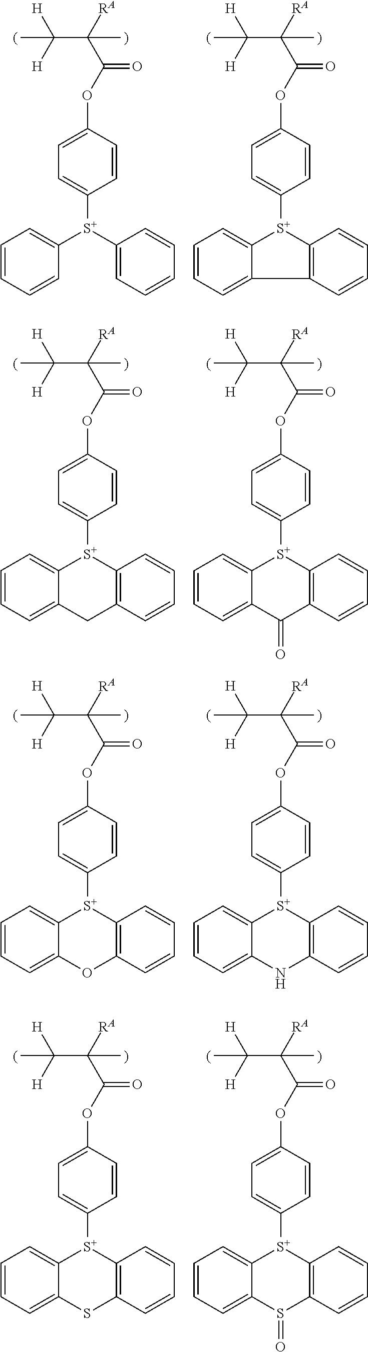

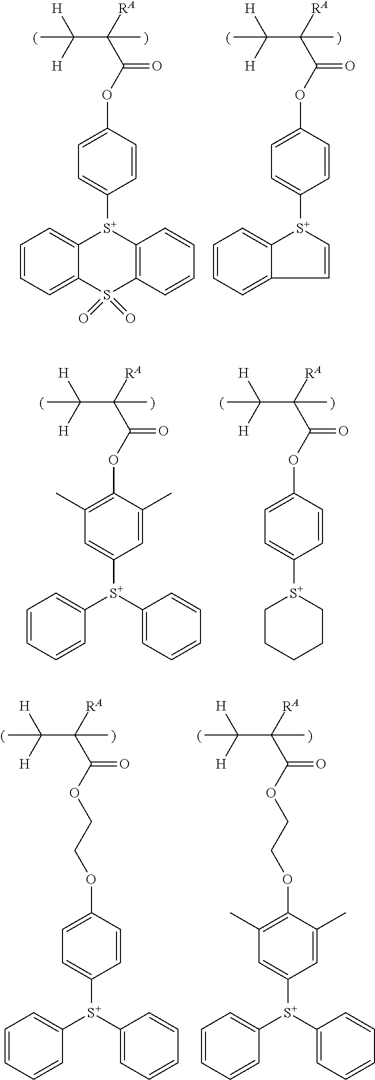

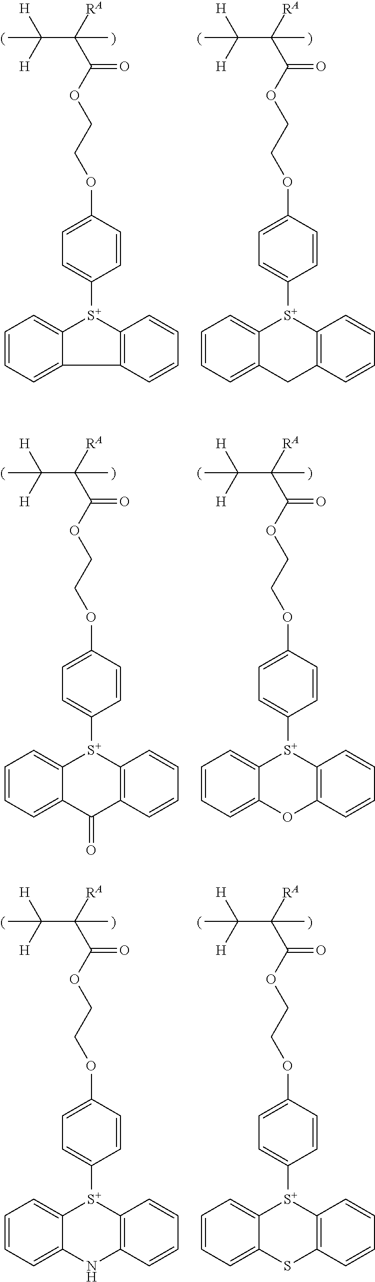

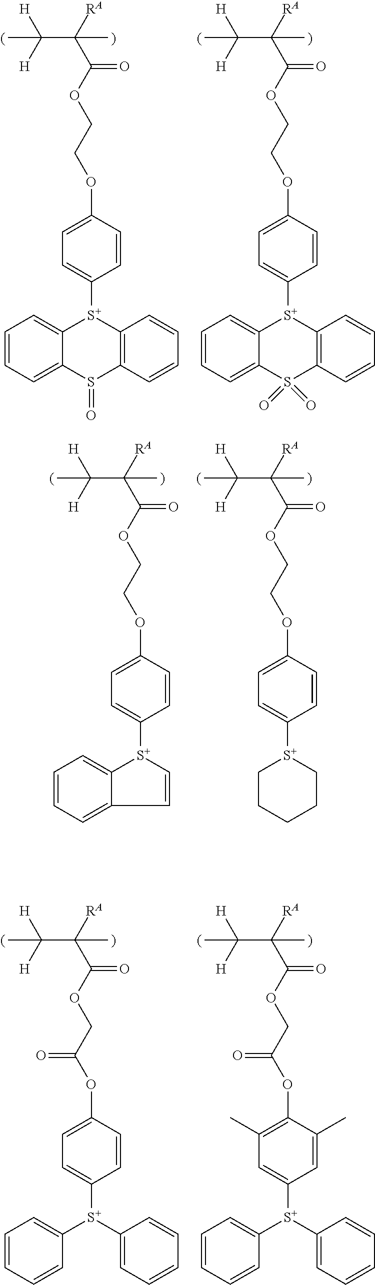

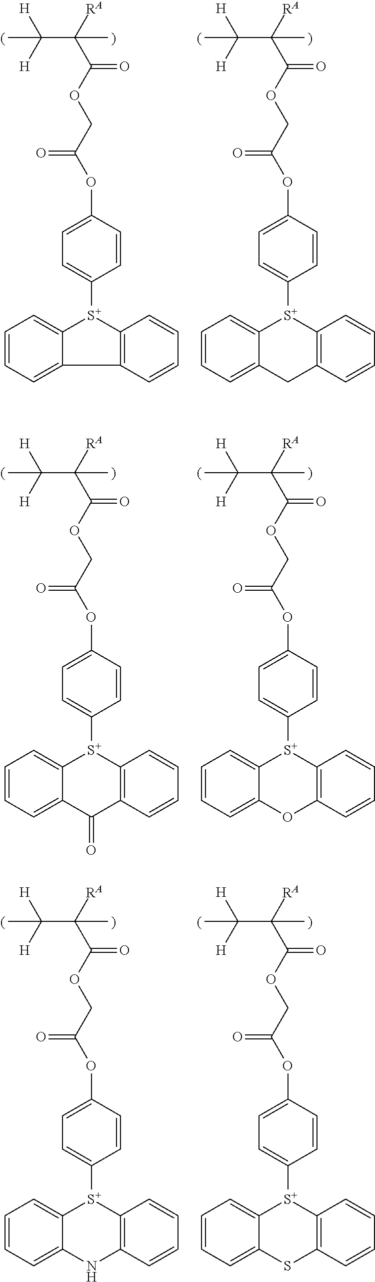

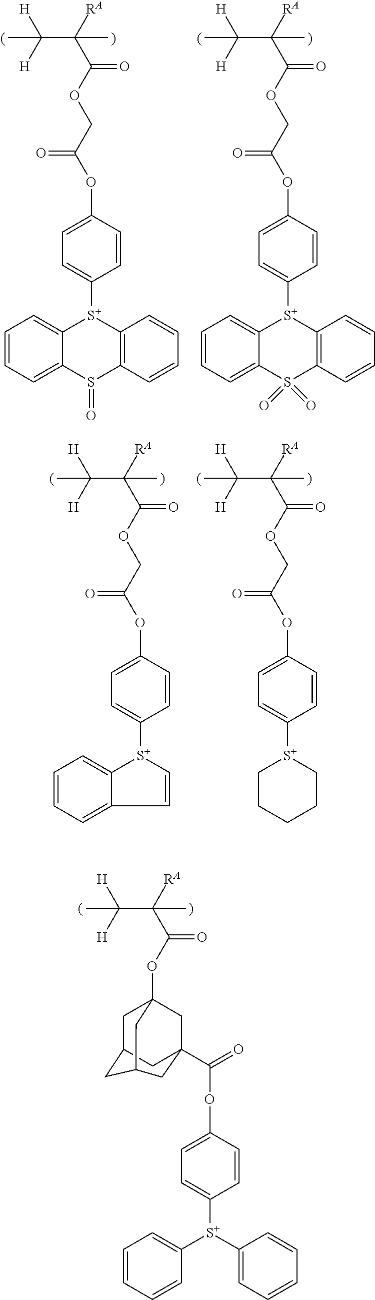

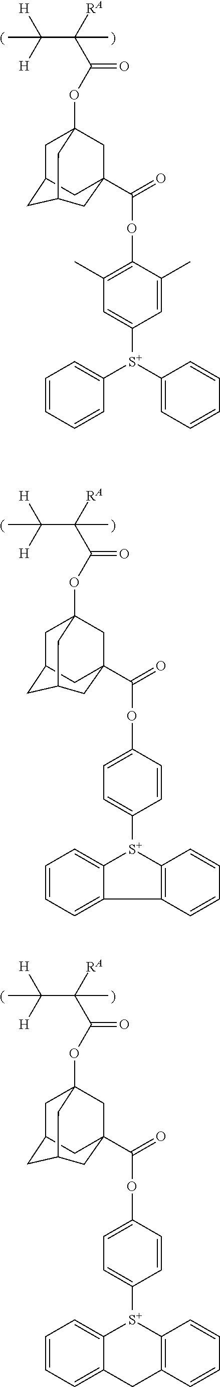

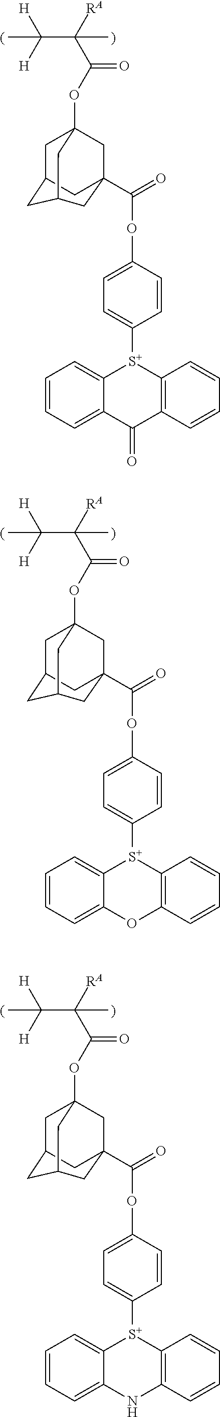

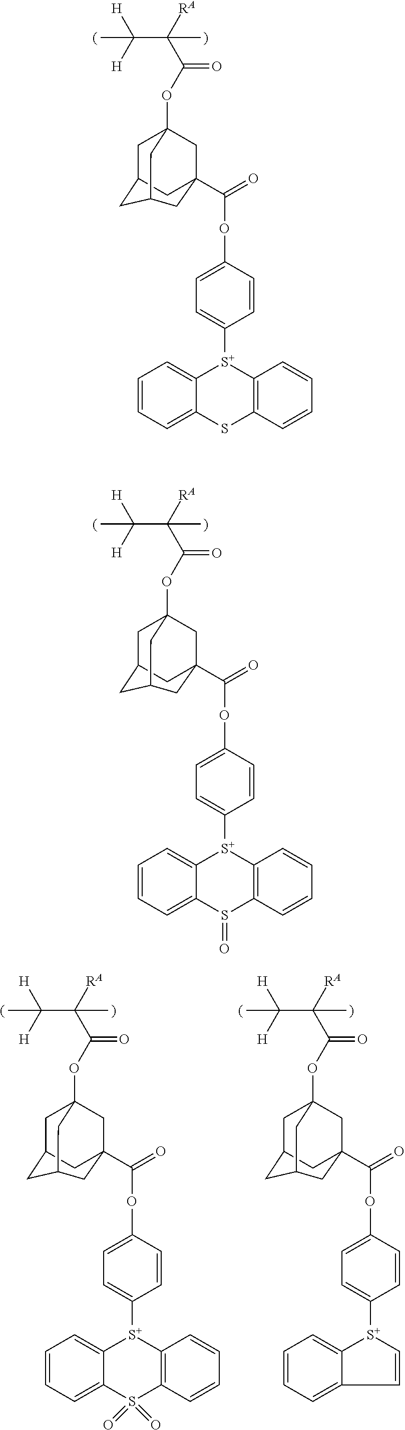

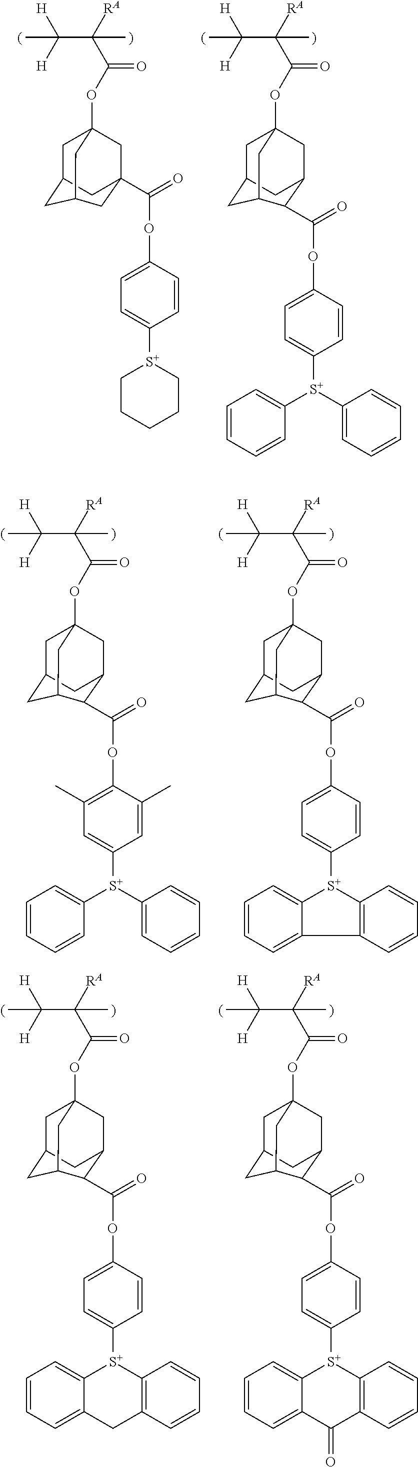

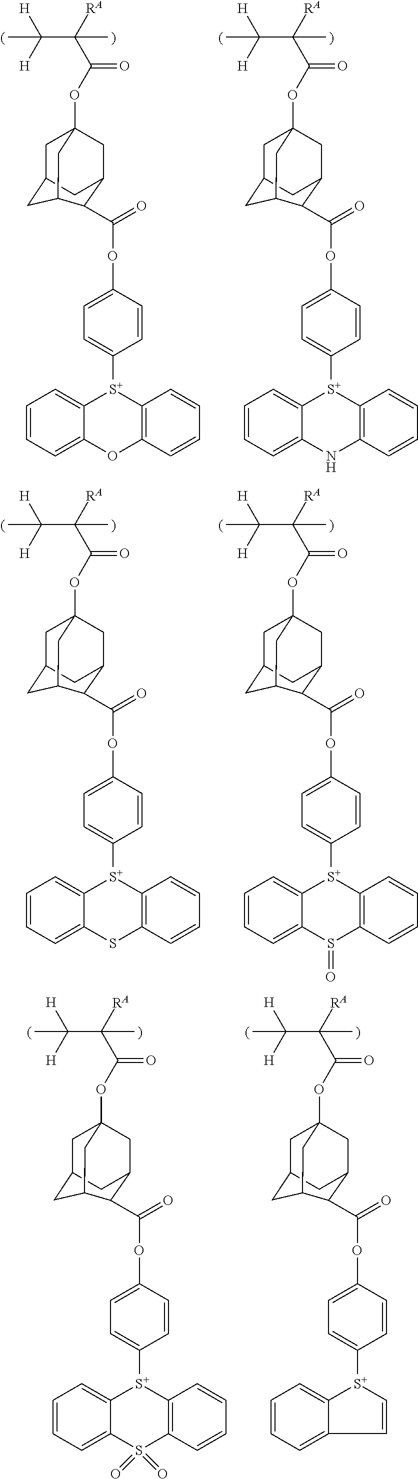

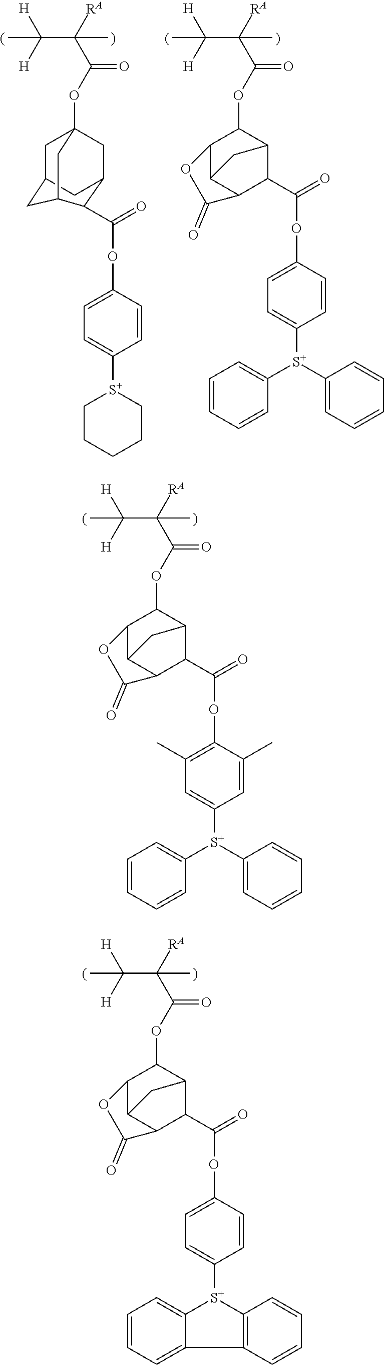

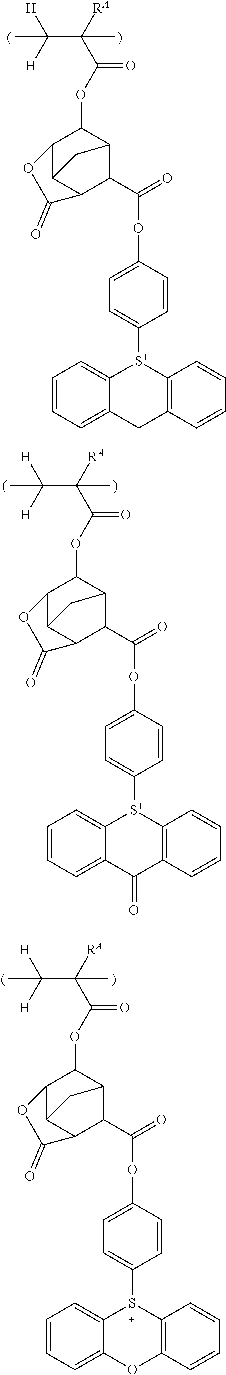

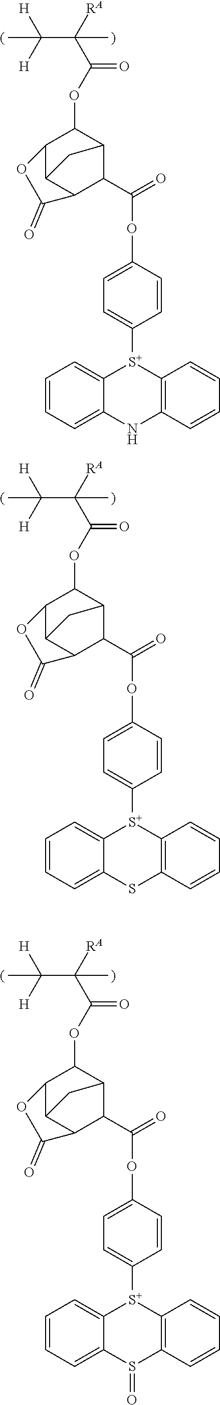

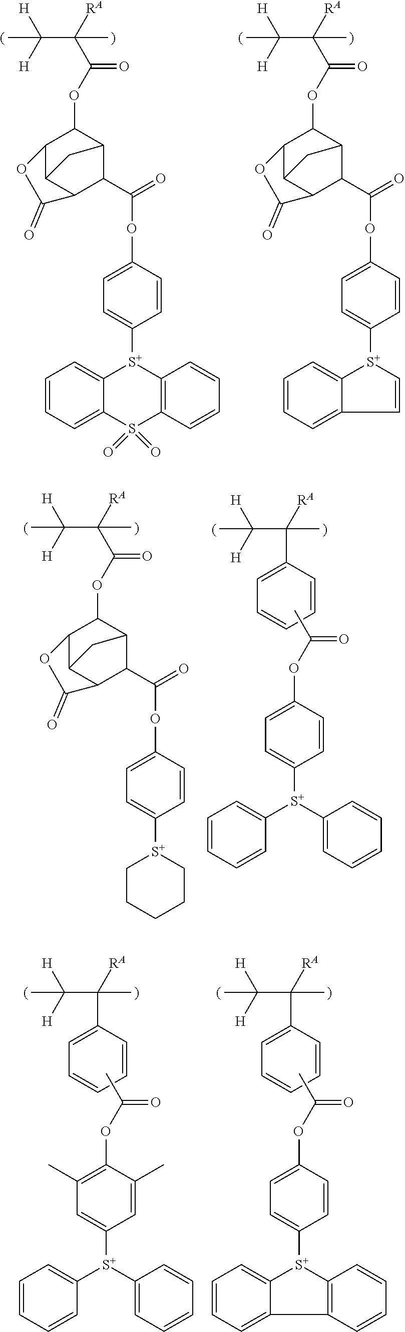

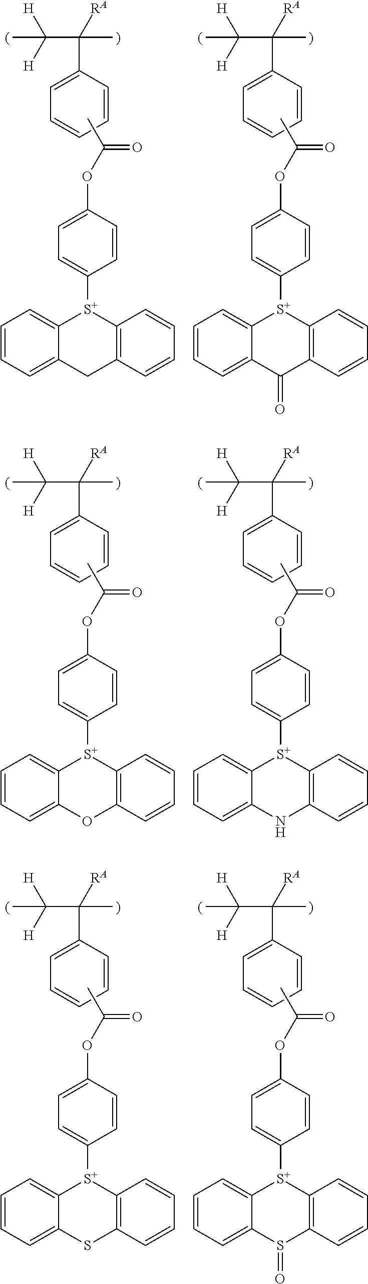

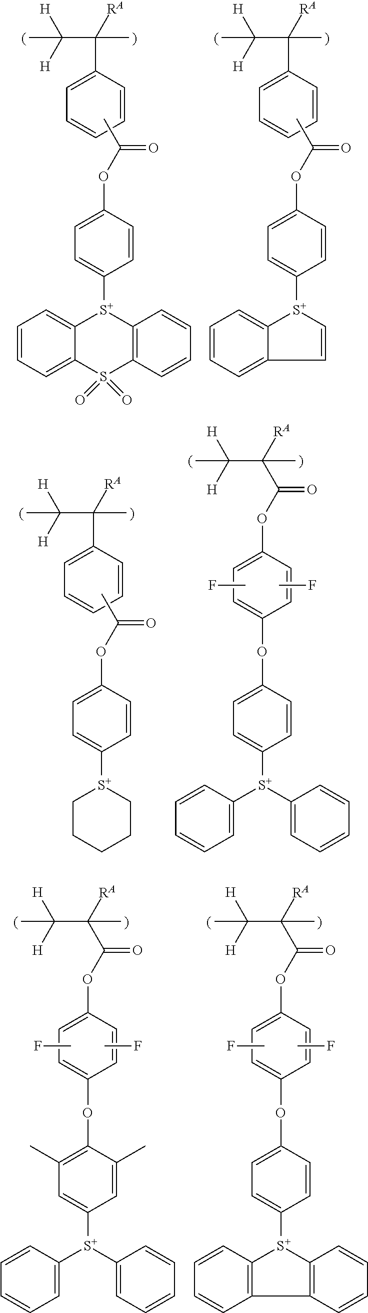

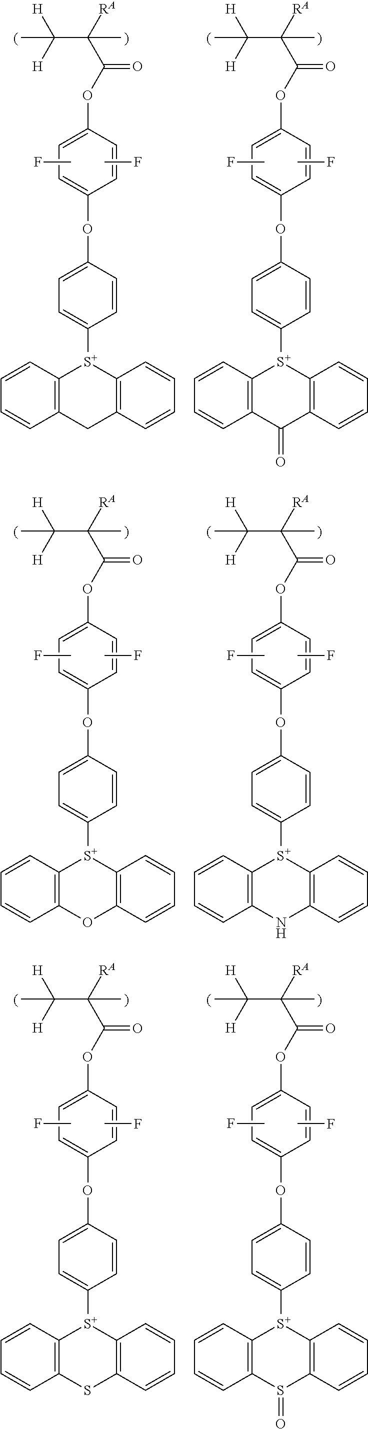

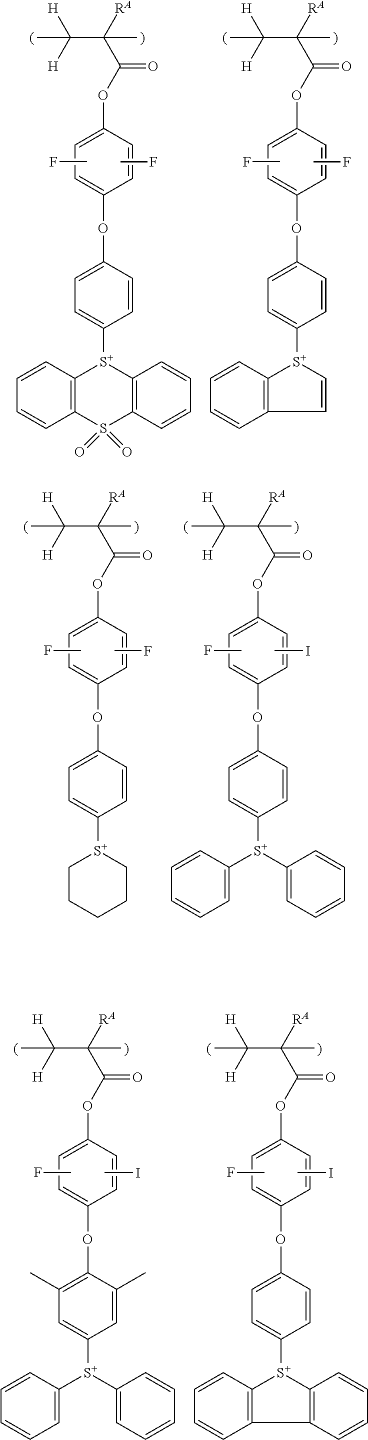

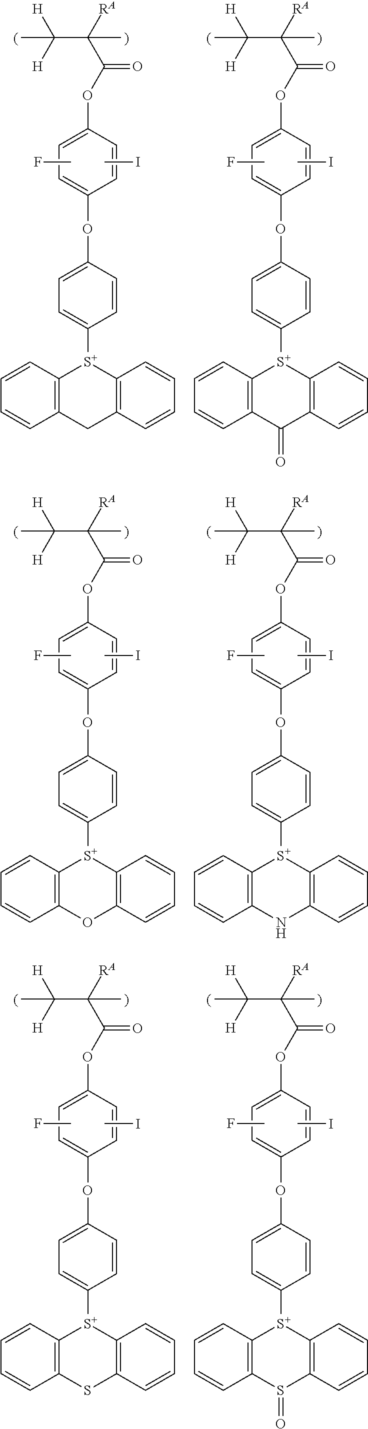

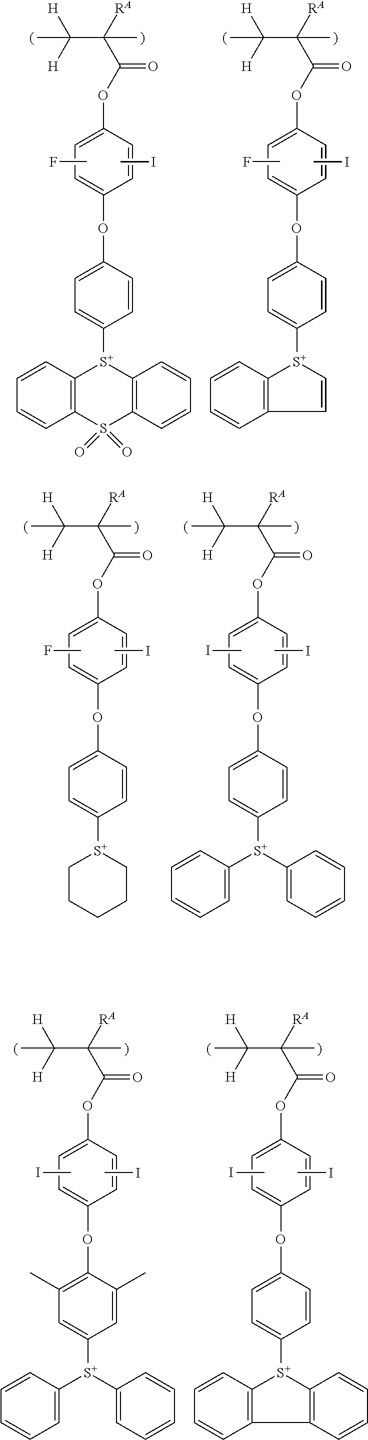

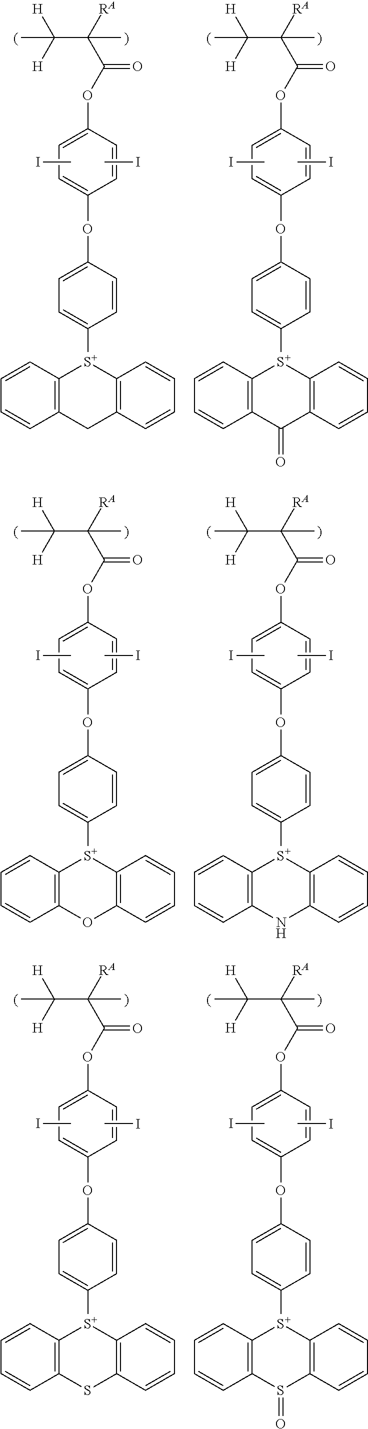

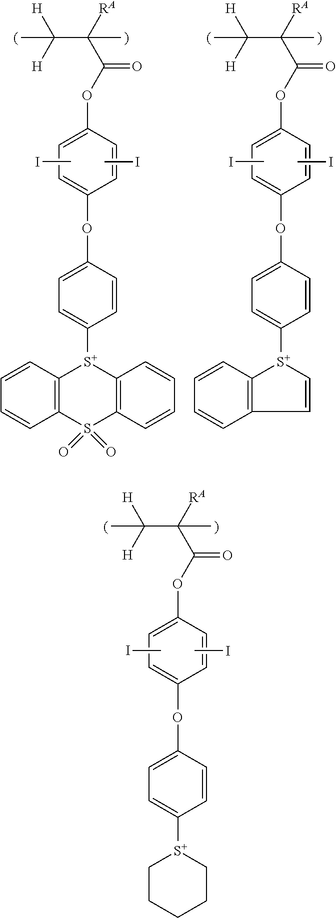

In formula (c1), M⁻ is a non-nucleophilic counter ion. Halide, sulfonate, imide and methide anions are preferred as the non-nucleophilic counter ion. Examples of the non-nucleophilic counter ion include halide ions such as chloride and bromide ions; sulfonate anions, specifically fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide, and bis(perfluorobutylsulfonyl)imide; and methide ions such as tris(trifluoromethylsulfonyl)methide and tris(perfluoroethylsulfonyl)methide.

Anions having the formulae (c1-1) to (c1-4) are also useful as the non-nucleophilic counter ion.

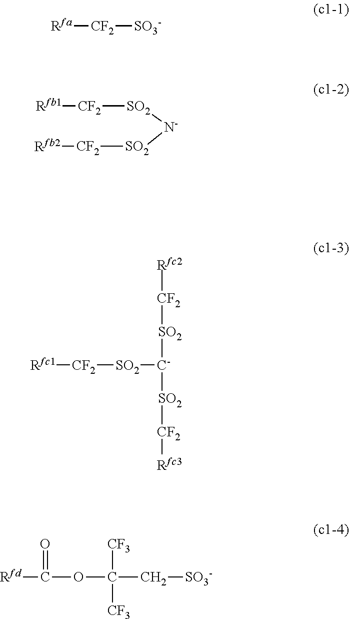

In formula (c1-1), R^{fa} is fluorine or a C₁-C₄₀ hydrocarbyl group which may contain a heteroatom. The hydrocarbyl group may be saturated or unsaturated and straight, branched or cyclic. Examples thereof are as exemplified below for the hydrocarbyl group represented by R^{fa1} in formula (c1-1-1).

Of the anions of formula (c1-1), an anion having the formula (c1-1-1) is preferred.

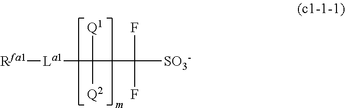

In formula (c1-1-1), Q¹ and Q² are each independently hydrogen, fluorine or a C₁-C₆ fluorinated saturated hydrocarbyl group. It is preferred for solvent solubility that at least one of Q¹ and Q² be trifluoromethyl. m is 0, 1, 2, 3, or 4, most preferably 1. R^{fa1} is a C₁-C₃₅ hydrocarbyl group which may contain a heteroatom. As the heteroatom, oxygen, nitrogen, sulfur and halogen atoms are preferred, with oxygen being more preferred. Of the hydrocarbyl groups, those groups of 6 to 30 carbon atoms are preferred from the aspect of achieving a high resolution in forming small-size patterns.

In formula (c1-1-1), the C₁-C₃₅ hydrocarbyl group represented by R^{fa1} may be saturated or unsaturated and straight, branched or cyclic. Examples thereof include C₁-C₃₅ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosyl; C₃-C₃₅ cyclic saturated hydrocarbyl groups such as cyclopentyl, cyclohexyl, 1-adamantyl, 2-adamantyl, 1-adamantylmethyl, norbornyl, norbornylmethyl, tricyclodecyl, tetracyclododecyl, tetracyclododecylmethyl, and dicyclohexylmethyl; C₂-C₃₅ unsaturated aliphatic hydrocarbyl groups such as 2-propenyl and 3-cyclohexenyl; C₆-C₃₅ aryl groups such as phenyl, 1-naphthyl, 2-naphthyl, and 9-fluorenyl; and C₇-C₃₅ aralkyl groups such as benzyl and diphenylmethyl; and combinations thereof.

In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonate ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl and 3-oxocyclohexyl groups.

In formula (c1-1-1), L¹ is a single bond, ether bond, ester bond, sulfonate ester bond, carbonate bond or carbamate bond. From the aspect of synthesis, an ether bond or ester bond is preferred, with the ester bond being more preferred.

Examples of the anion having formula (c1-1) are shown below, but not limited thereto. In the formula, Q¹ is as described above, and Ac is acetyl.

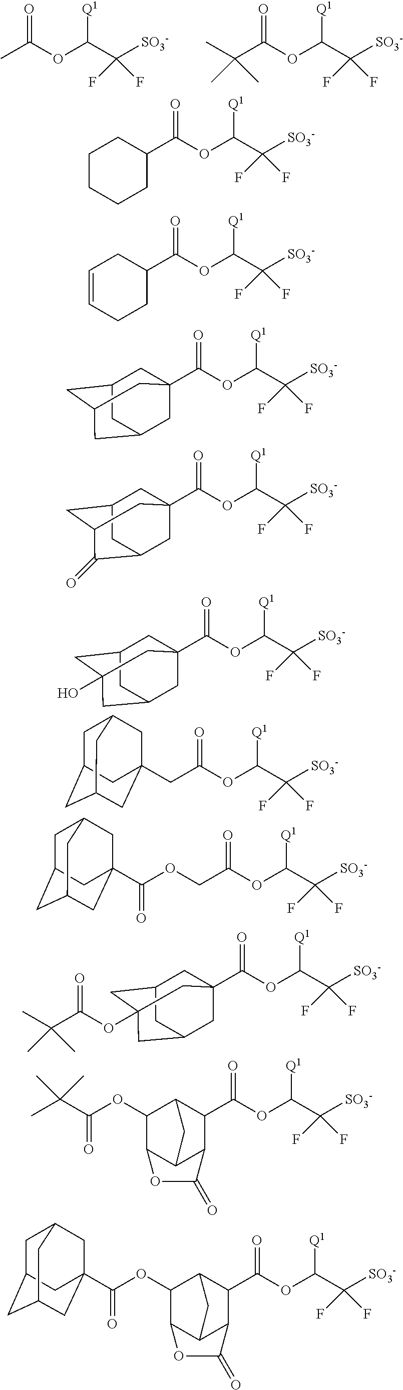

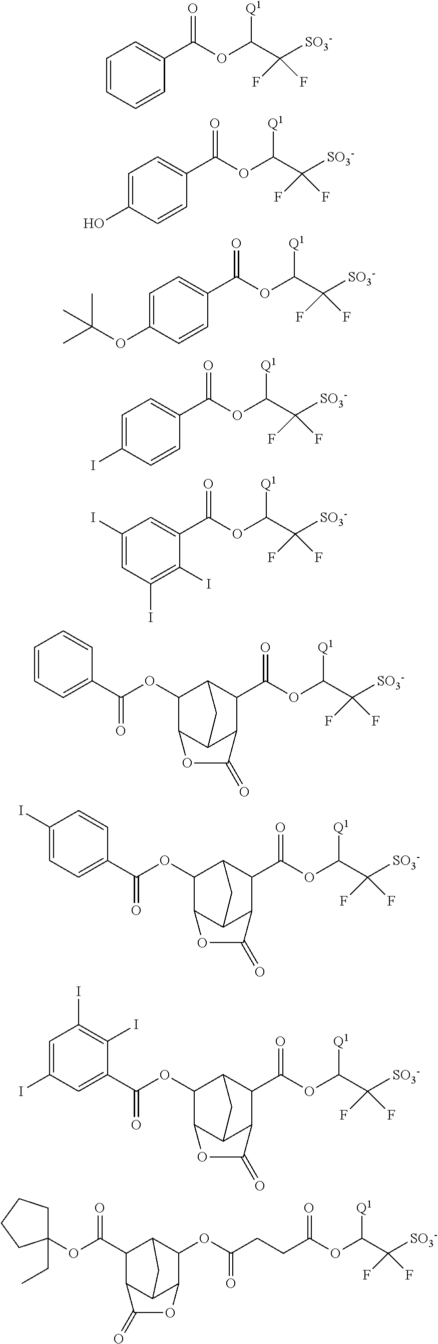

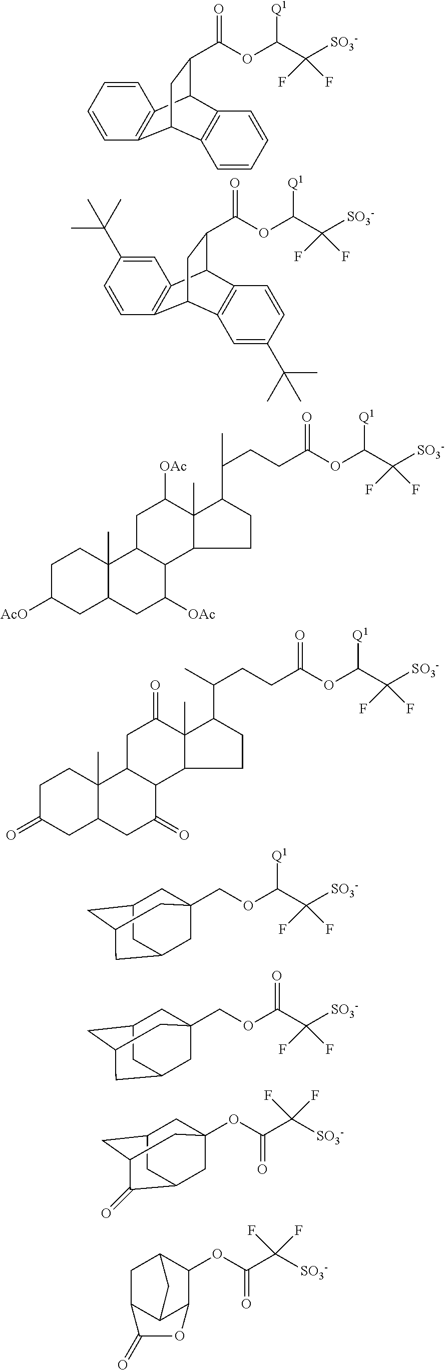

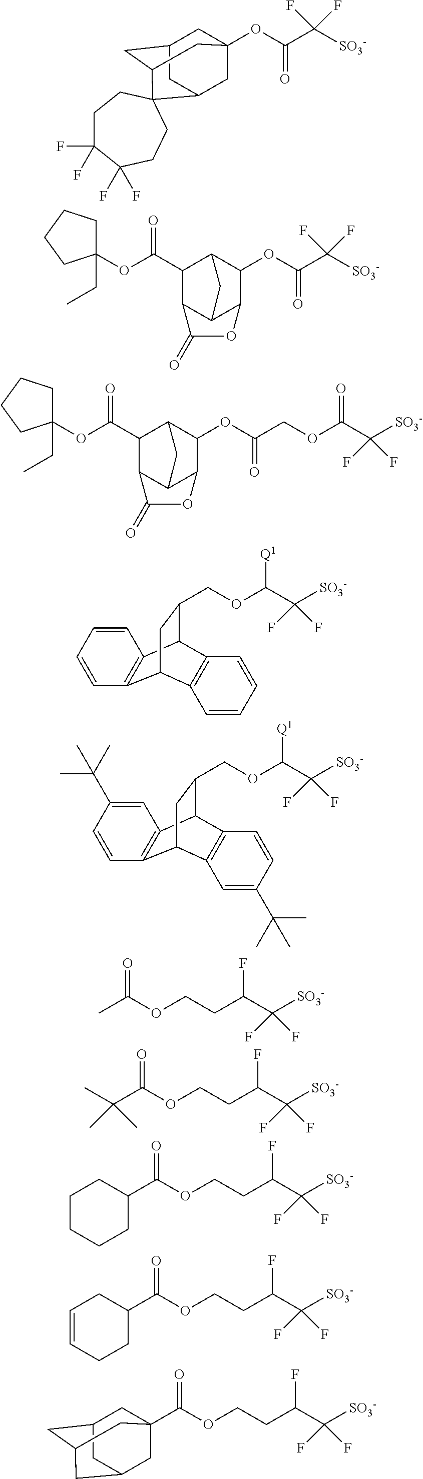

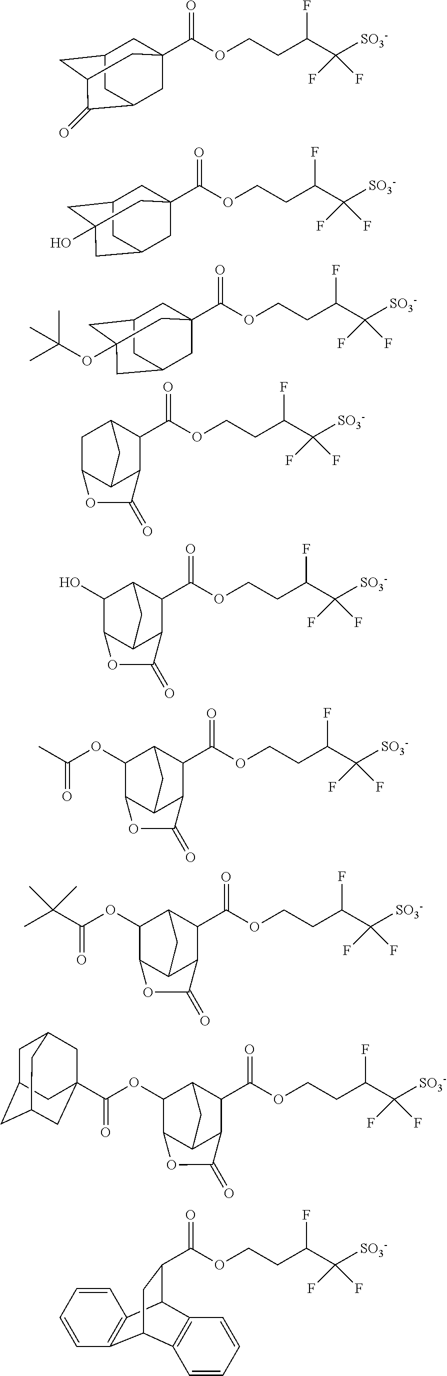

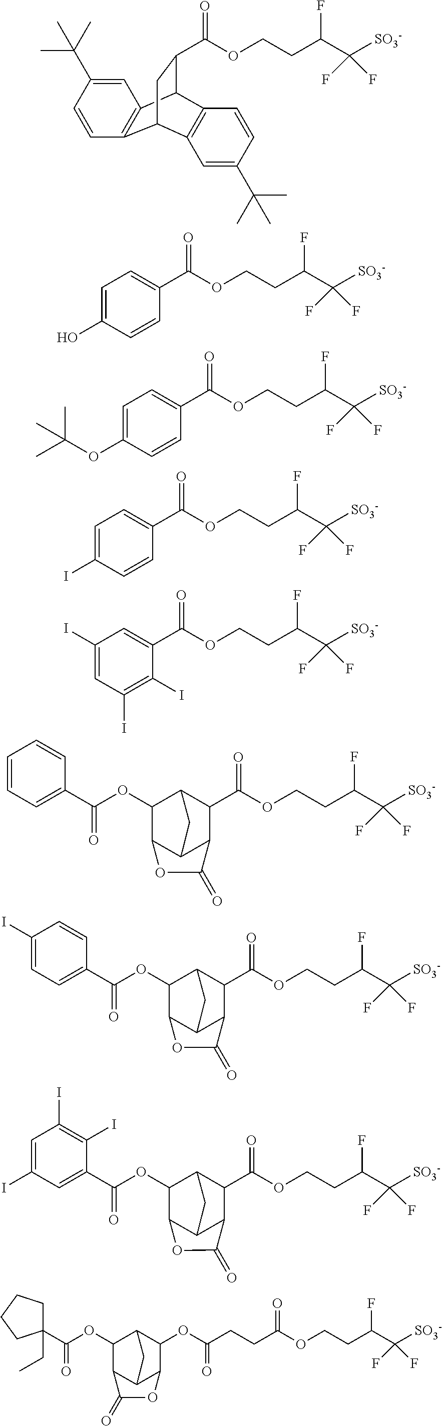

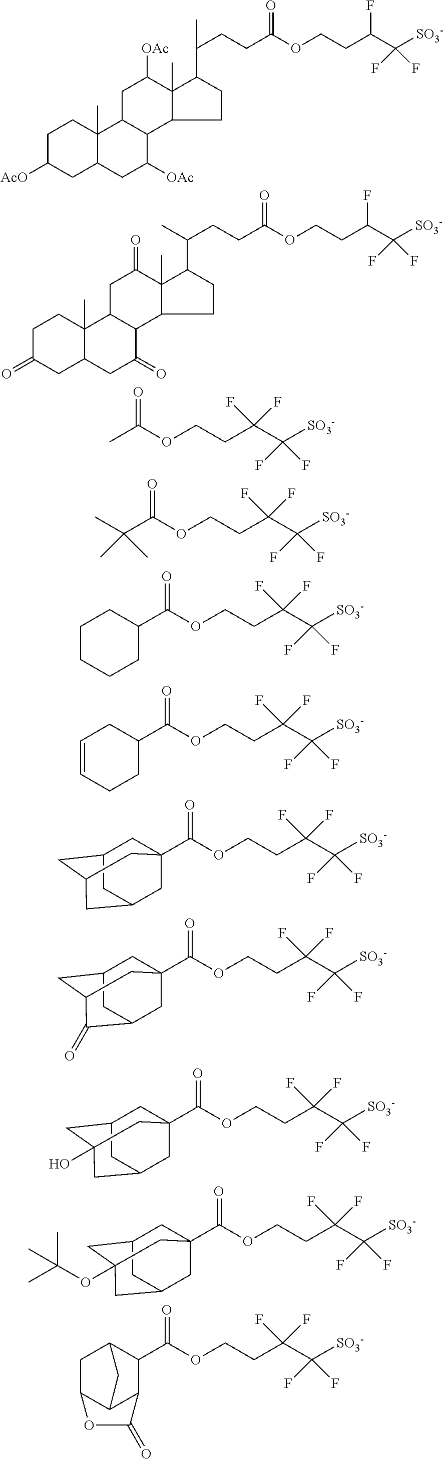

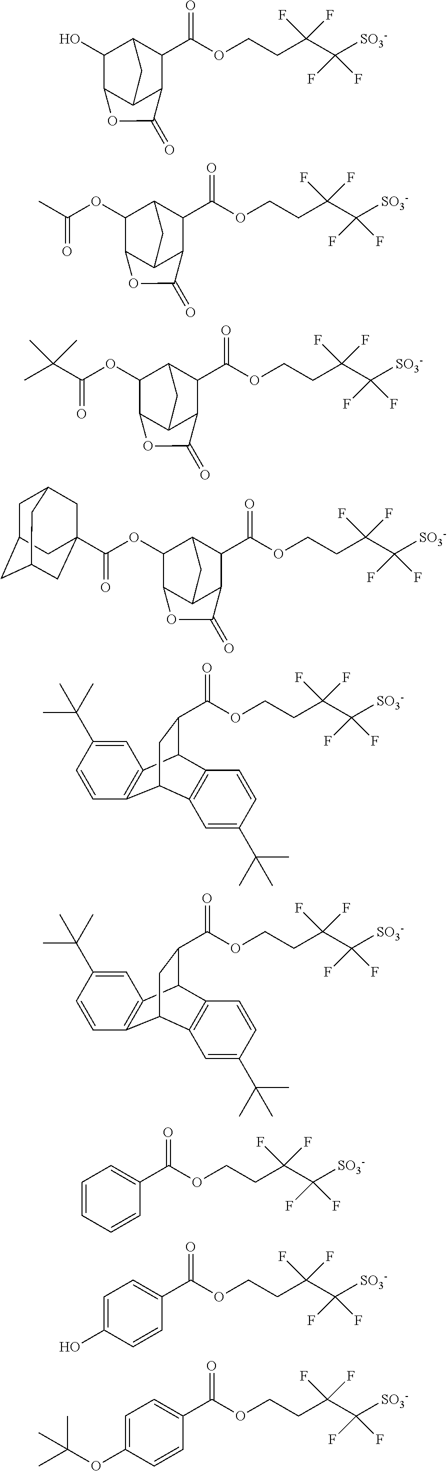

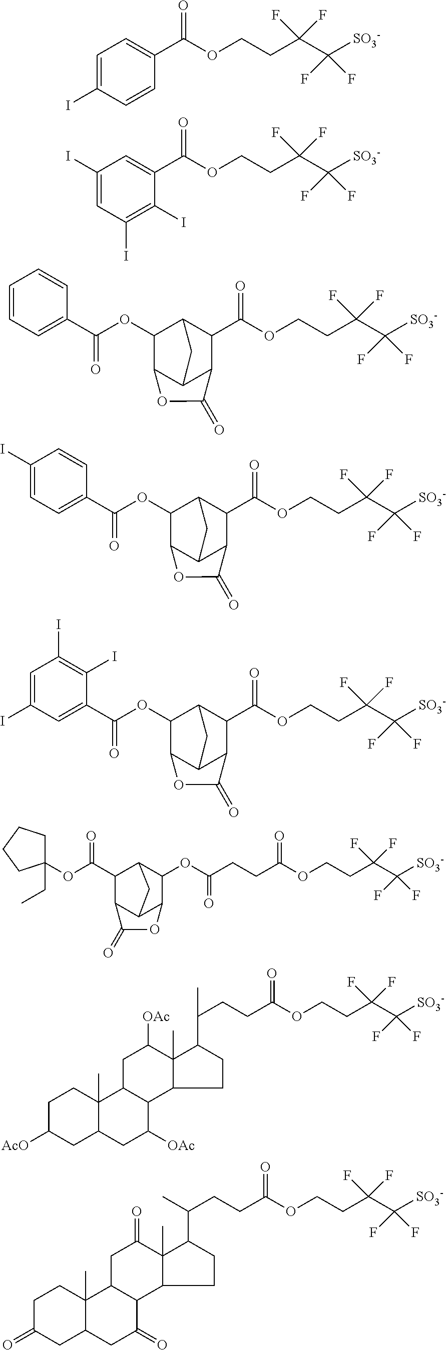

In formula (c1-2), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Examples thereof are as exemplified above for the hydrocarbyl group represented by R^{fa1} in formula (c1-1-1). R^{fb1} and R^{fb2} are preferably fluorine or C₁-C₄ straight fluorinated alkyl groups. Also, R^{fb1} and R^{fb2} may bond together to form a ring with the linkage: —CF₂—SO₂—N⁻—SO₂—CF₂— to which they are attached. It is preferred that a combination of R^{fb1} and R^{fb2} be a fluorinated ethylene or fluorinated propylene group.

In formula (c1-3), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Examples thereof are as exemplified above for the hydrocarbyl group represented by R^{fa1} in formula (c1-1-1). R^{fc1}, R^{fc2} and R^{fc3} are preferably fluorine or C₁-C₄ straight fluorinated alkyl groups. Also, R^{fc1} and R^{fc2} may bond together to form a ring with the linkage: —CF₂—SO₂—C⁻—SO₂—CF₂— to which they are attached. It is preferred that a combination of R^{fc1} and R^{fc2} be a fluorinated ethylene or fluorinated propylene group.

In formula (c1-4), R^{fd} is a C₁-C₄₀ hydrocarbyl group which may contain a heteroatom. The hydrocarbyl group may be saturated or unsaturated and straight, branched or cyclic. Examples thereof are as exemplified above for the hydrocarbyl group represented by R^{fa1} in formula (c1-1-1).

Examples of the anion having formula (c1-4) are shown below, but not limited thereto.

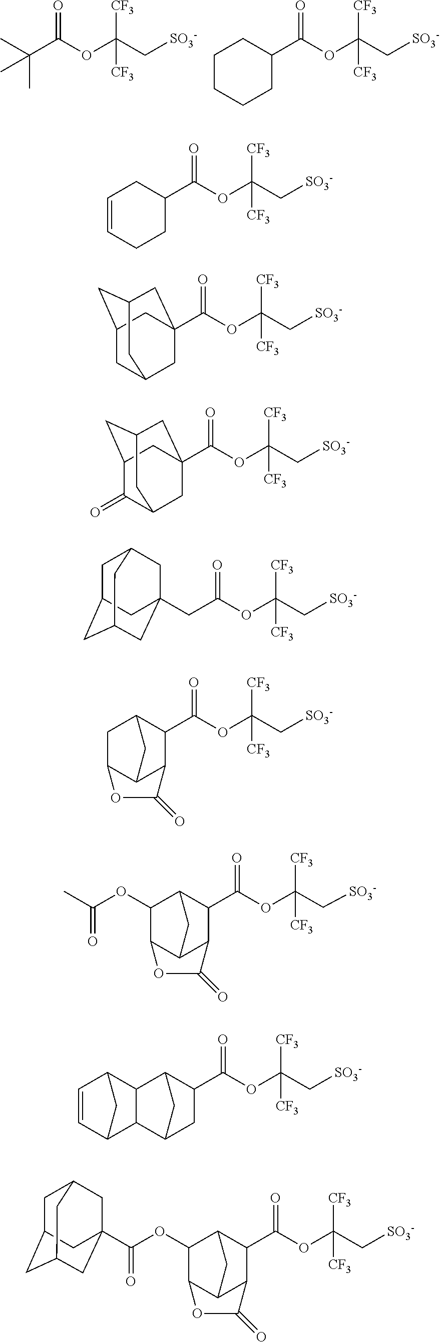

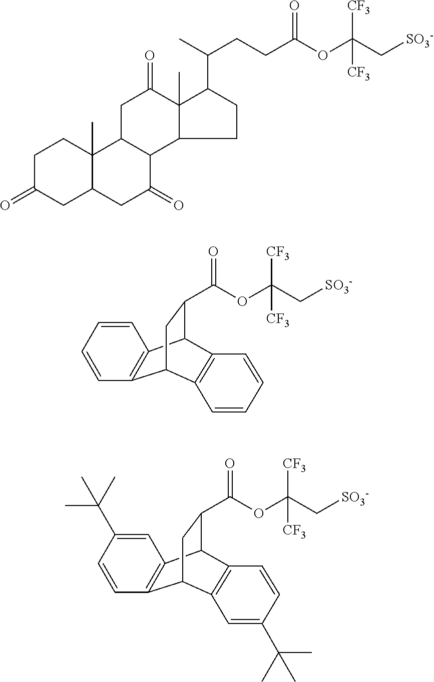

Examples of the non-nucleophilic counter ion further include anions having an aromatic ring substituted with iodine or bromine. Examples of these anions include those having the formula (c1-5).

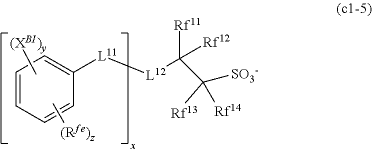

In formula (c1-5), x is 1, 2, or 3. y is 1, 2, 3, 4, or 5. z is 0, 1, 2, or 3. It is noted that 1≤y+z≤5. y is preferably 1, 2, or 3, more preferably 2 or 3. z is preferably 0, 1, or 2.

In formula (c1-5), X^{BI} is iodine or bromine. A plurality of X^{BI} may be identical or different when x and/or y is 2 or more.

In formula (c1-5), L¹¹ is a single bond, ether bond, ester bond, or a C₁-C₆ saturated hydrocarbylene group which may contain an ether bond or ester bond. The saturated hydrocarbylene group may be straight, branched or cyclic.

In formula (c1-5), L¹² is a single bond or a C₁-C₂₀ divalent linking group when x=1, or a C₁-C₂₀ (x+1)-valent linking group when x=2 or 3. The linking group may contain an oxygen, sulfur or nitrogen atom.

In formula (c1-5), R^{fe} is hydroxy, carboxy, fluorine, chlorine, bromine, amino group, or a C₁-C₂₀ hydrocarbyl, C₁-C₂₀ hydrocarbyloxy, C₂-C₂₀ hydrocarbylcarbonyl, C₂-C₂₀ hydrocarbyloxycarbonyl, C₂-C₂₀ hydrocarbylcarbonyloxy, or C₁-C₂₀ hydrocarbylsulfonyloxy group, which may contain fluorine, chlorine, bromine, a hydroxy moiety, amino moiety or ether bond, or —N(R^{feA})(R^{feB}), —N(R^{feC})—C(═O)—R^{feD} or —N(R^{feC})—C(═O)—O—R^{feD}. R^{feA} and R^{feB} are each independently hydrogen or a C₁-C₆ saturated hydrocarbyl group. R^{feC} is hydrogen, or a C₁-C₆ saturated hydrocarbyl group which may contain halogen, a hydroxy, C₁-C₆ saturated hydrocarbyloxy, C₂-C₆ saturated hydrocarbylcarbonyl or C₂-C₆ saturated hydrocarbylcarbonyloxy moiety. R^{feD} is a C₁-C₁₆ aliphatic hydrocarbyl group, C₆-C₁₂ aryl group or C₇-C₁₅ aralkyl group, which may contain halogen, a hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. A plurality of R^{fe} may be identical or different when x and/or z is 2 or more.

Of these, R^{fe} is preferably hydroxy, —N(R^{feC})—C(═O)—R^{feD}, —N(R^{feC})—C(═O)—O—R^{feD}, fluorine, chlorine, bromine, methyl or methoxy.

In formula (c1-5), Rf¹¹ to Rf¹⁴ are each independently hydrogen, fluorine or trifluoromethyl, and at least one of Rf¹¹ to Rf¹⁴ is fluorine or trifluoromethyl. Rf¹¹ and Rf¹², taken together, may form a carbonyl group. More preferably, both Rf¹³ and Rf¹⁴ are fluorine.

Examples of the anion having formula (c1-5) are shown below, but not limited thereto. In the formulae, X^{BI} is as defined above.

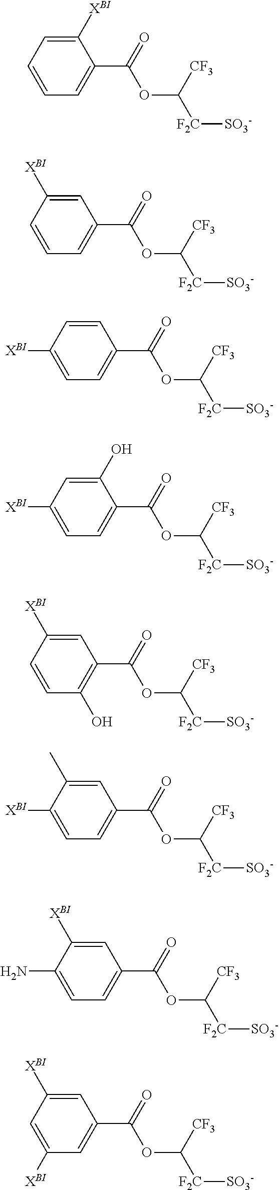

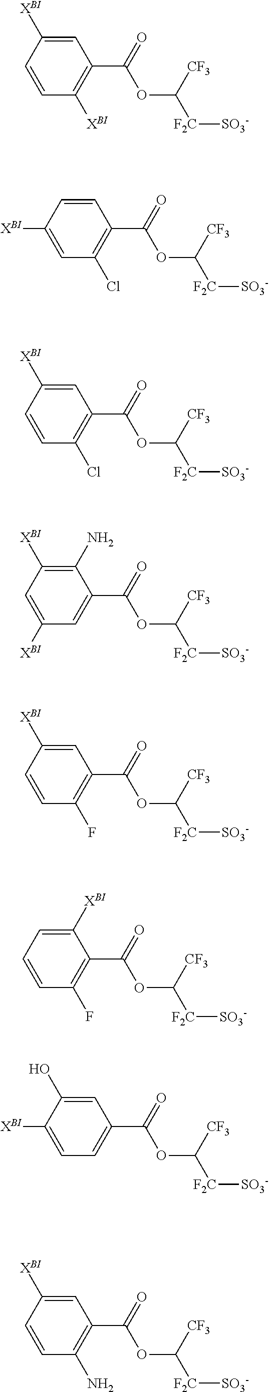

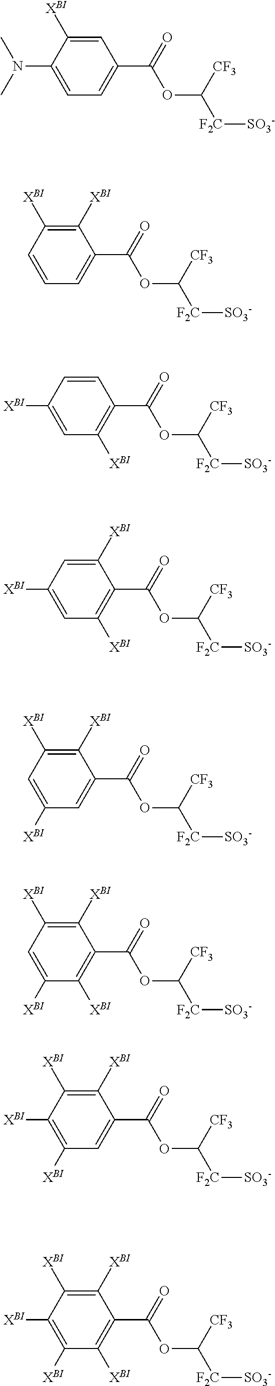

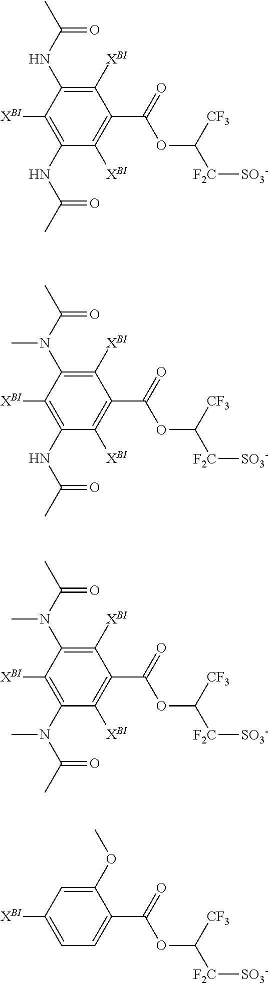

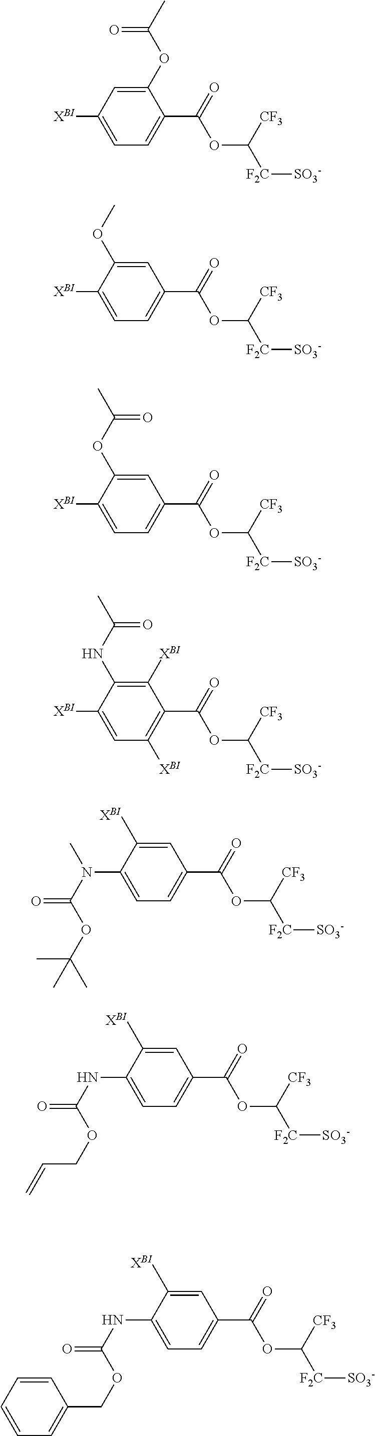

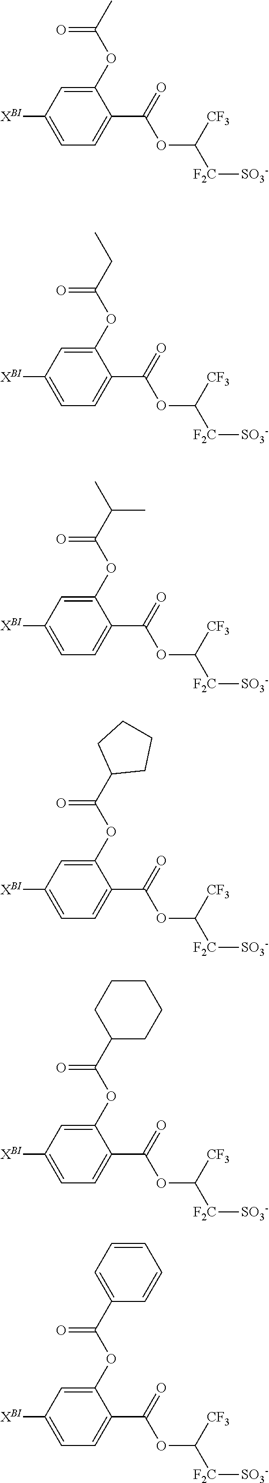

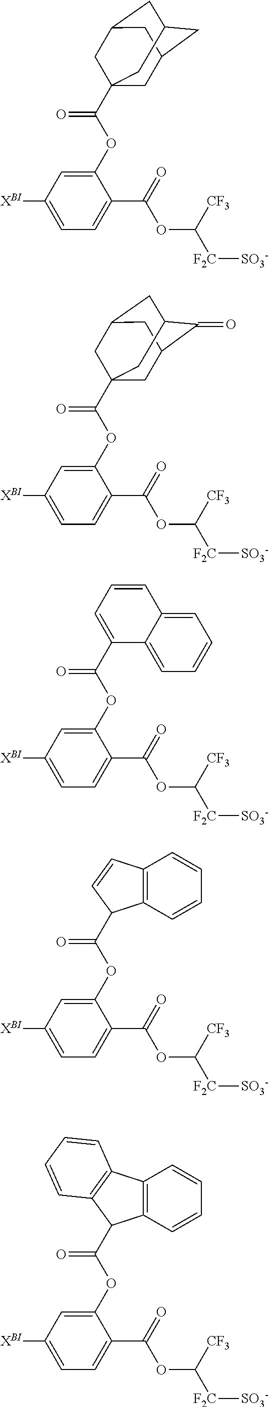

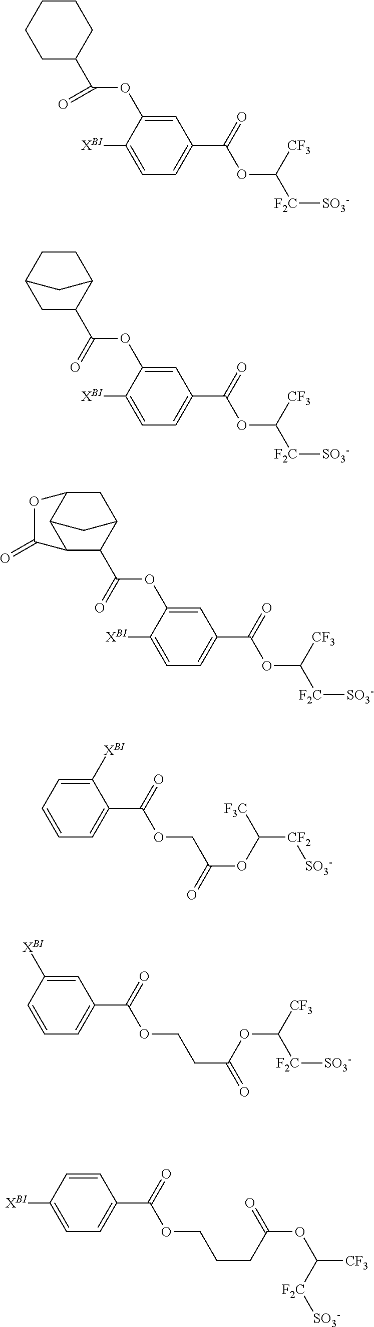

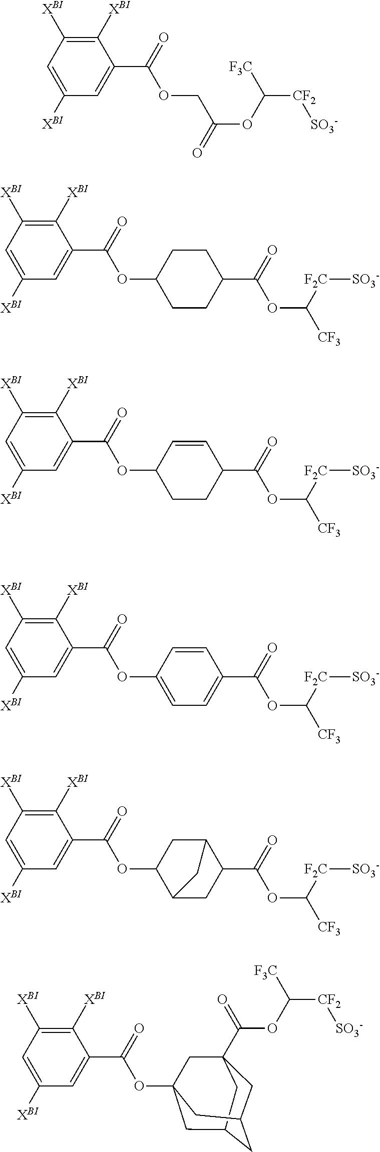

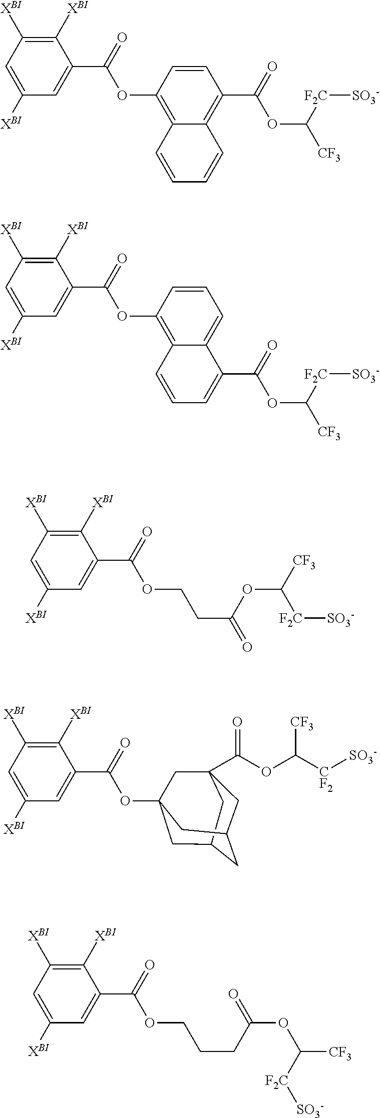

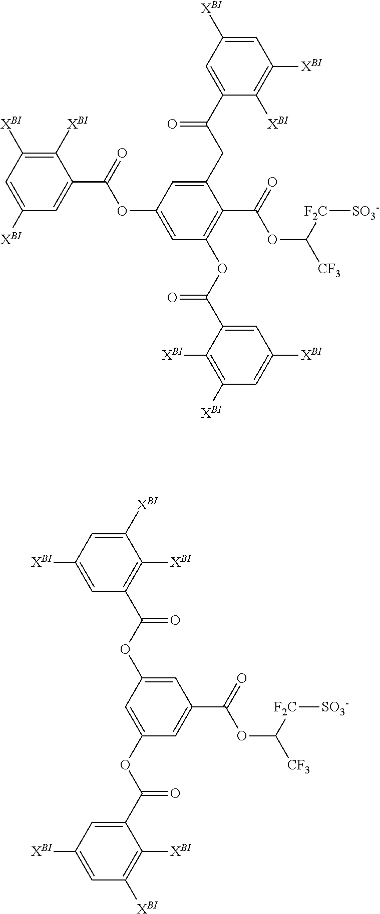

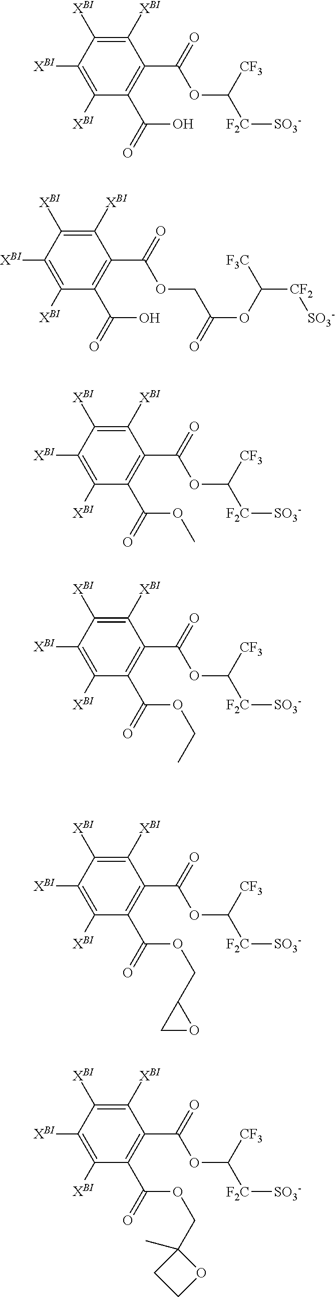

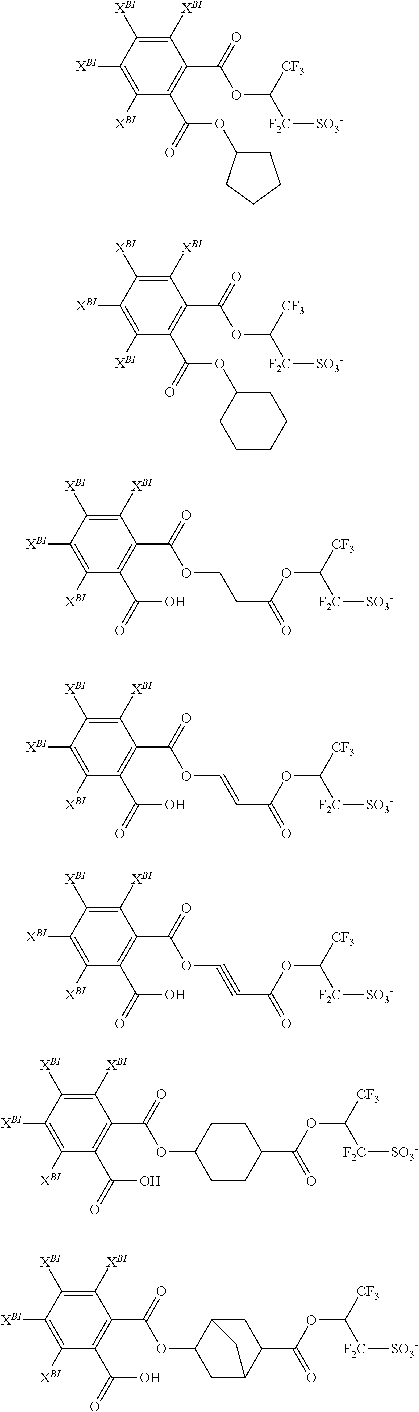

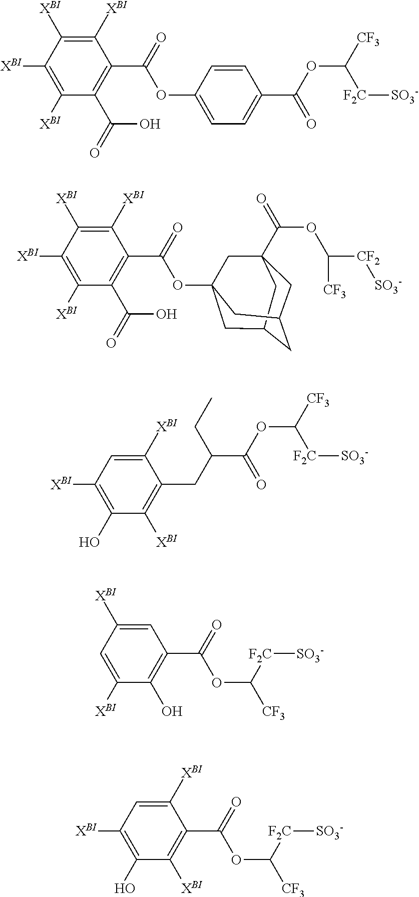

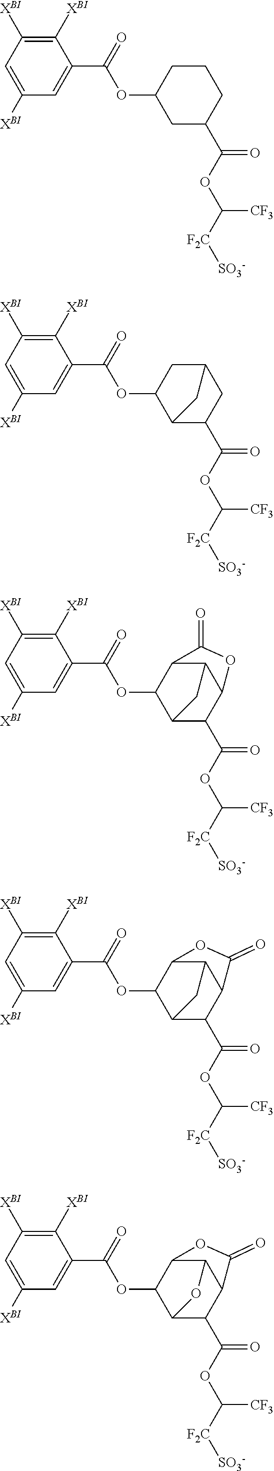

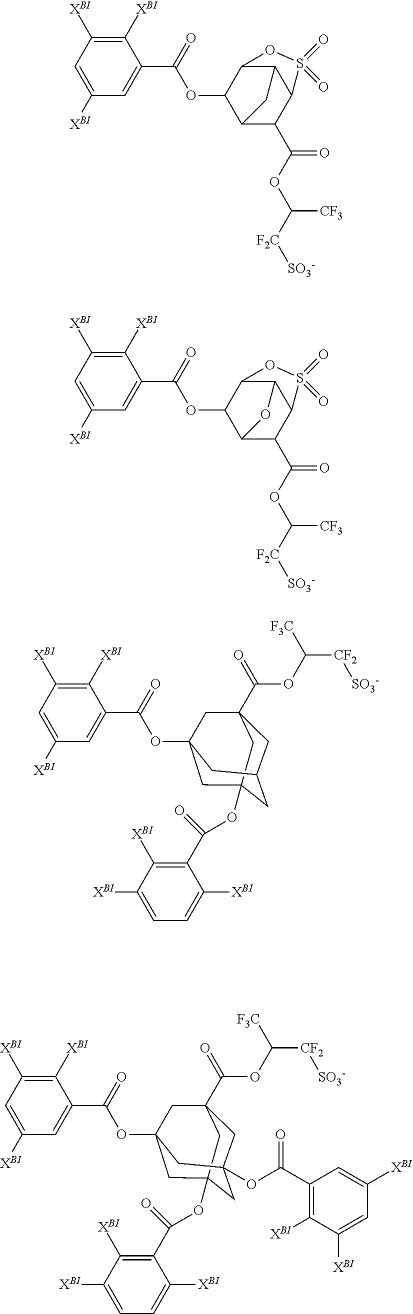

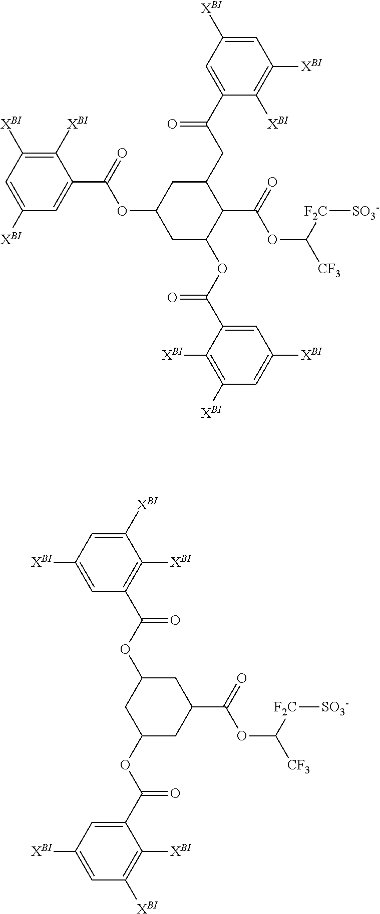

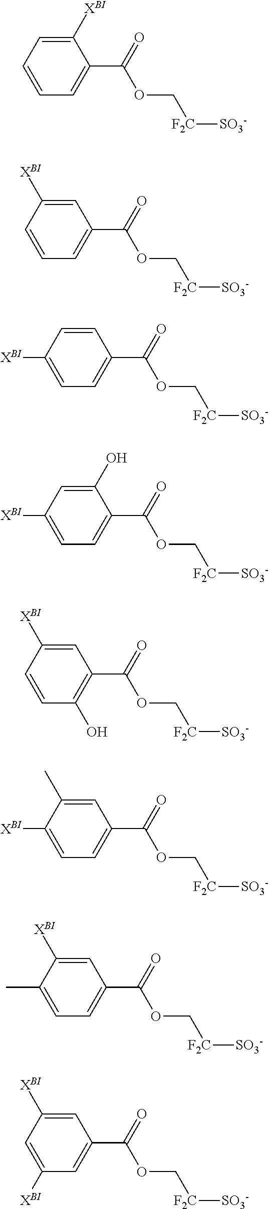

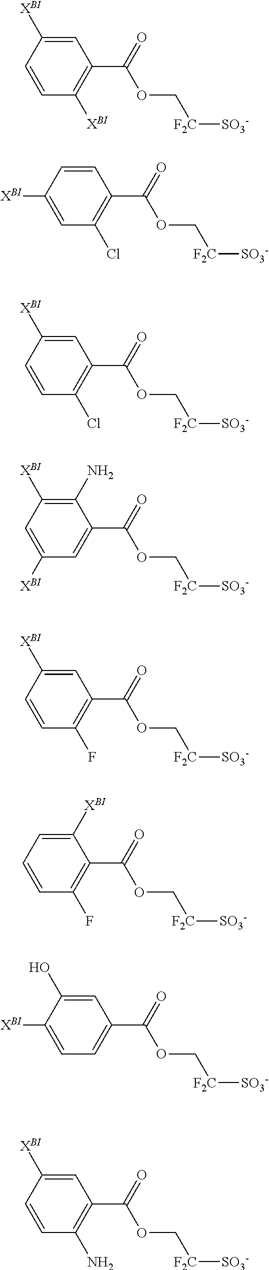

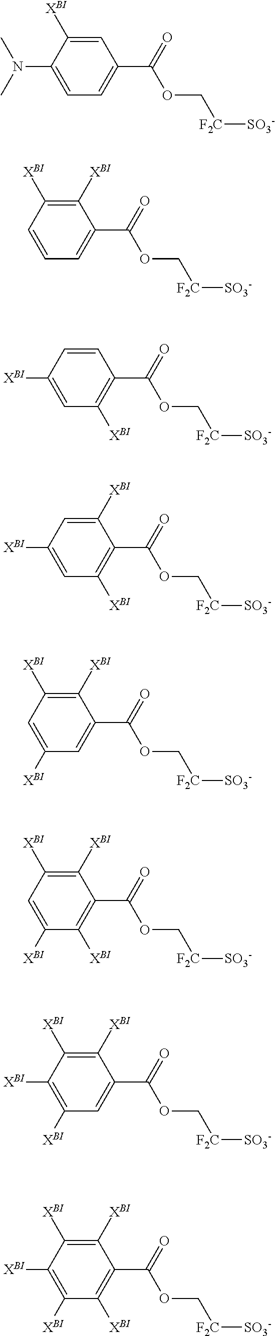

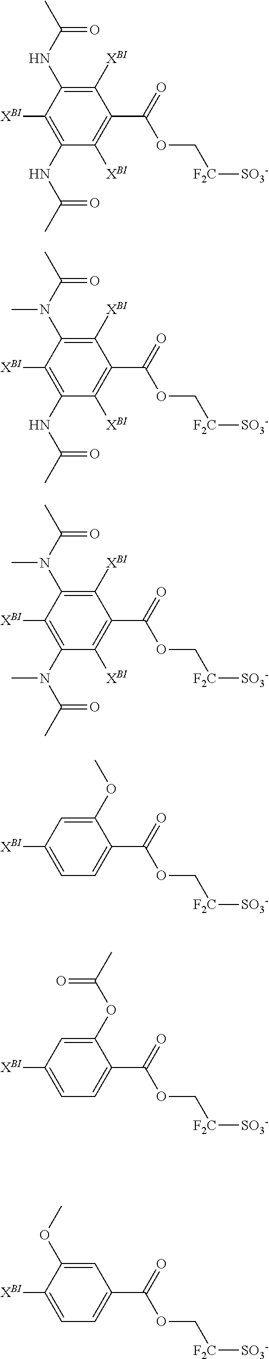

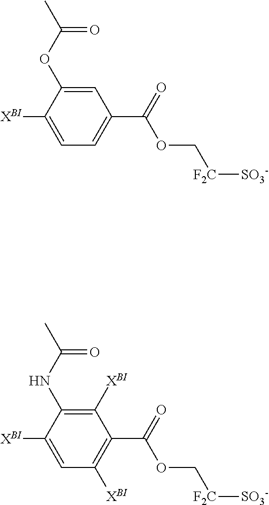

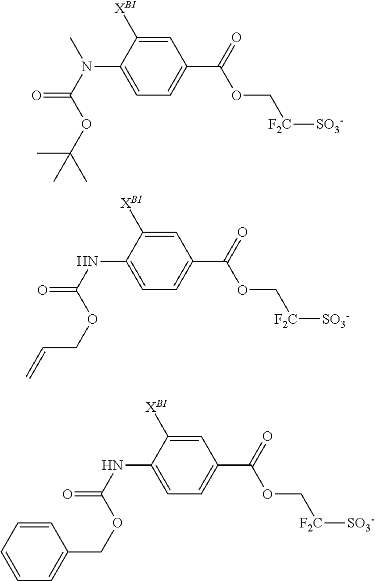

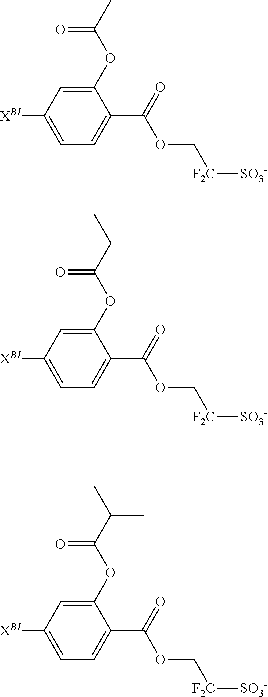

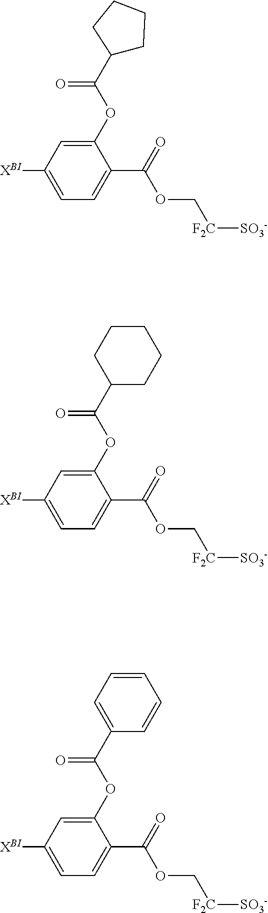

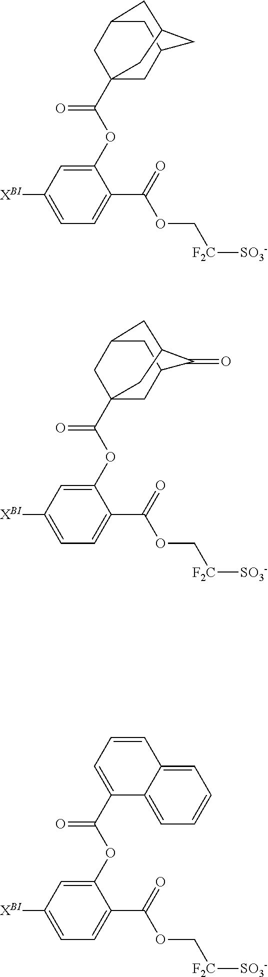

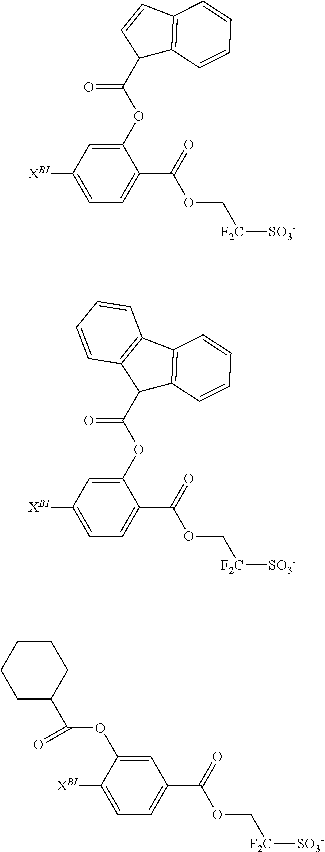

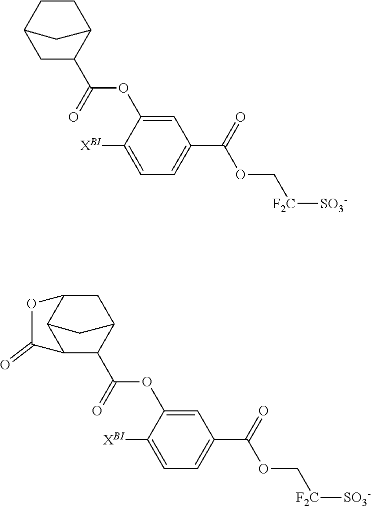

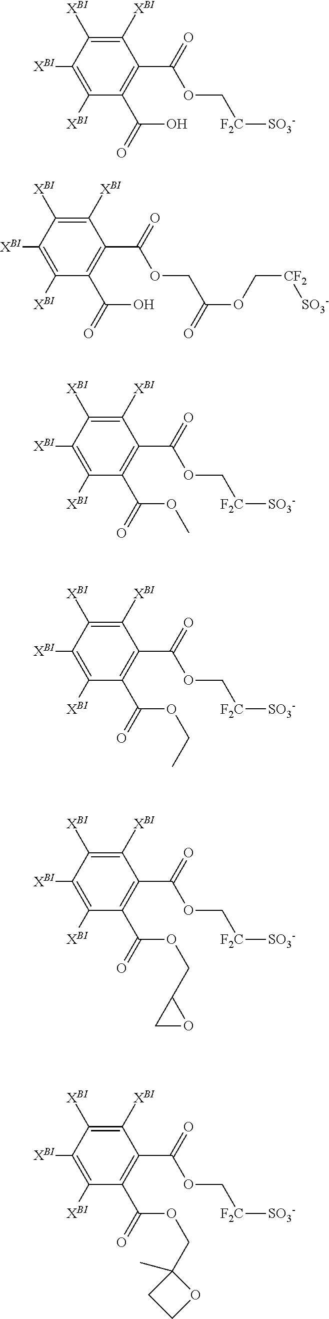

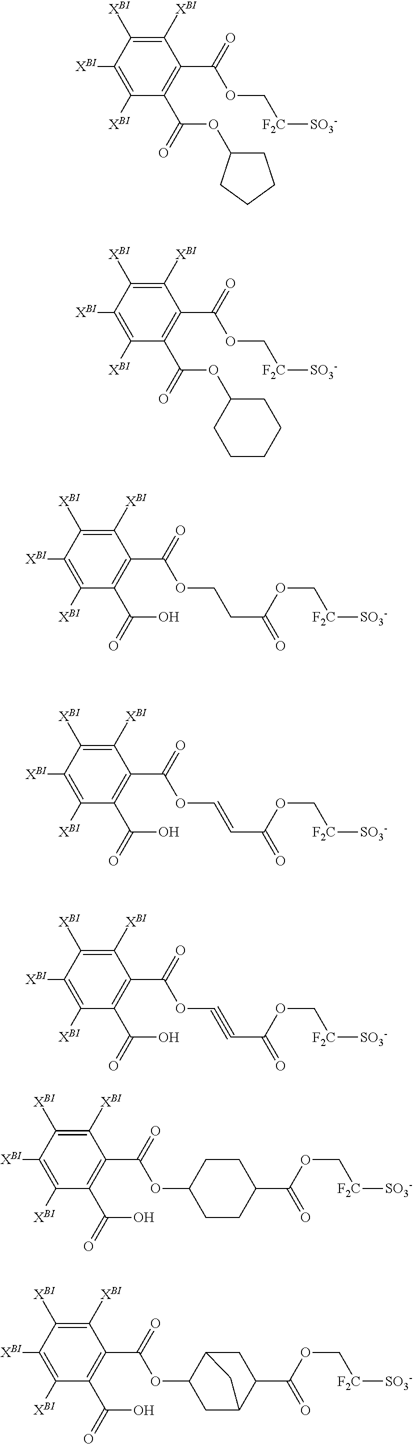

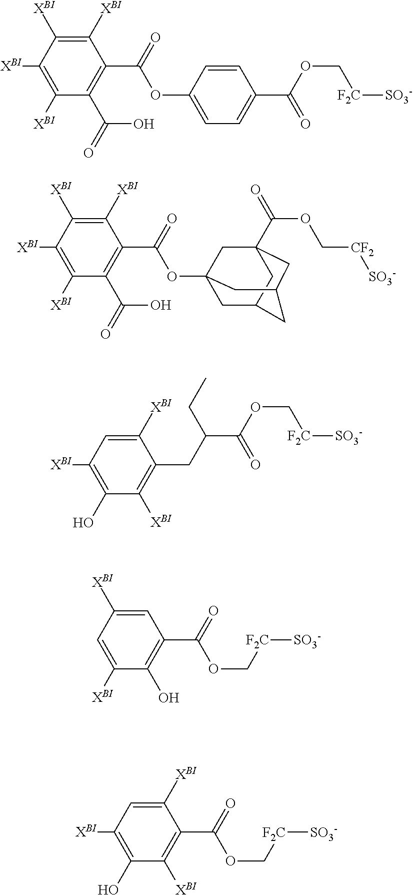

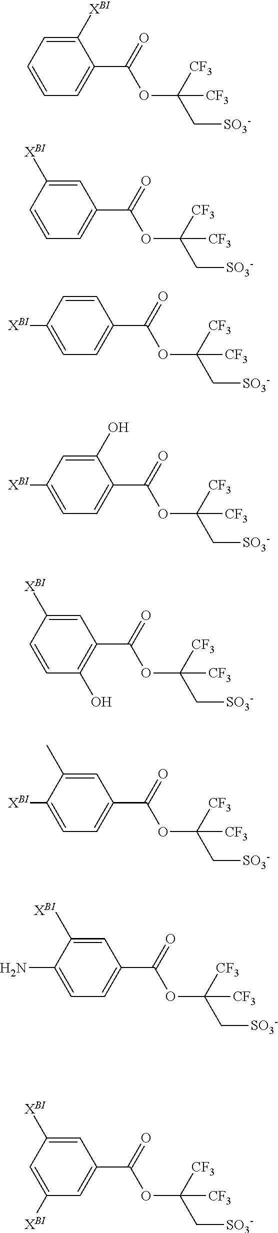

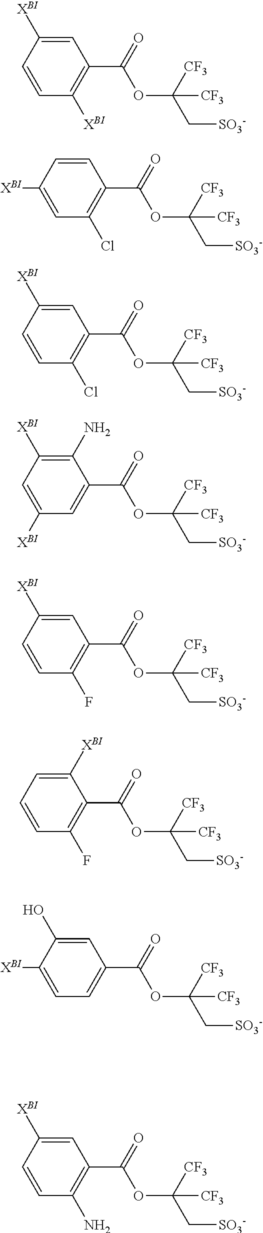

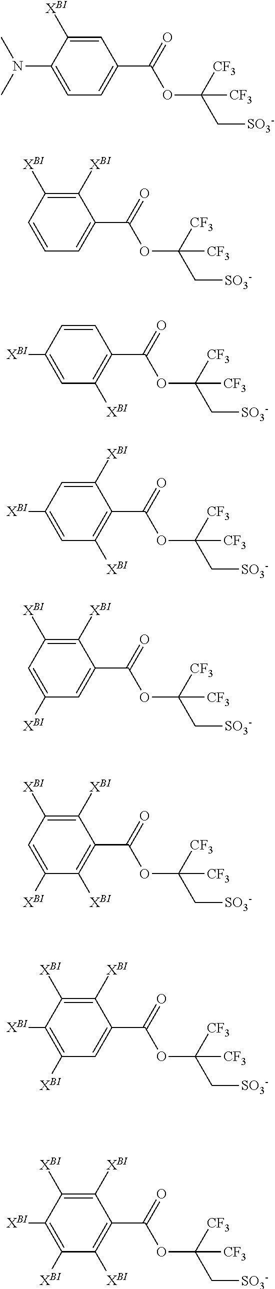

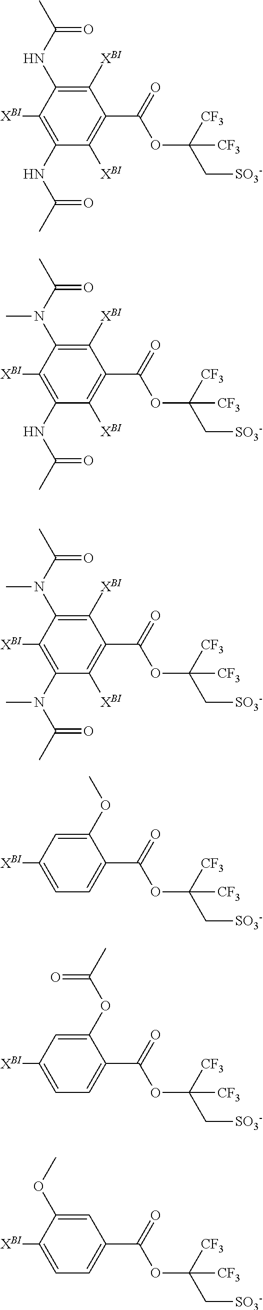

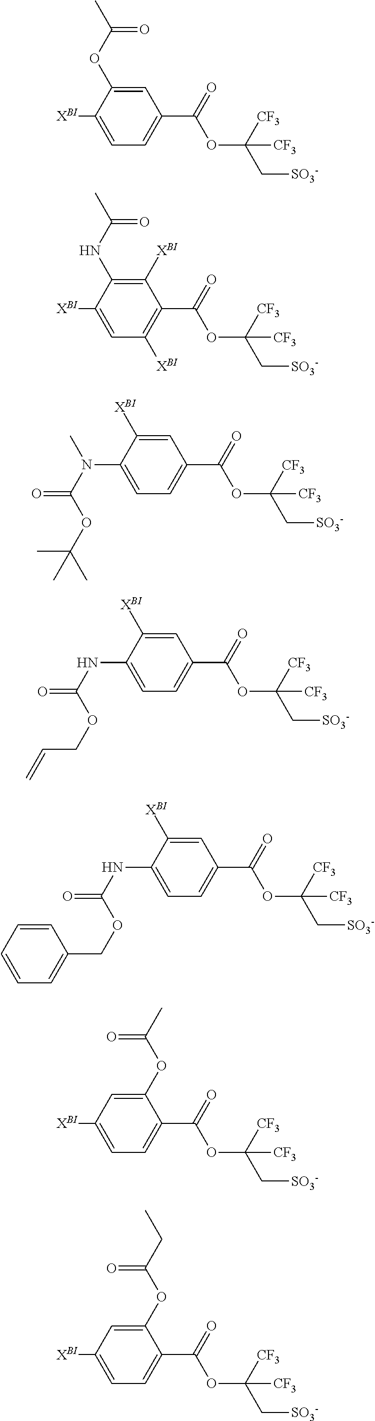

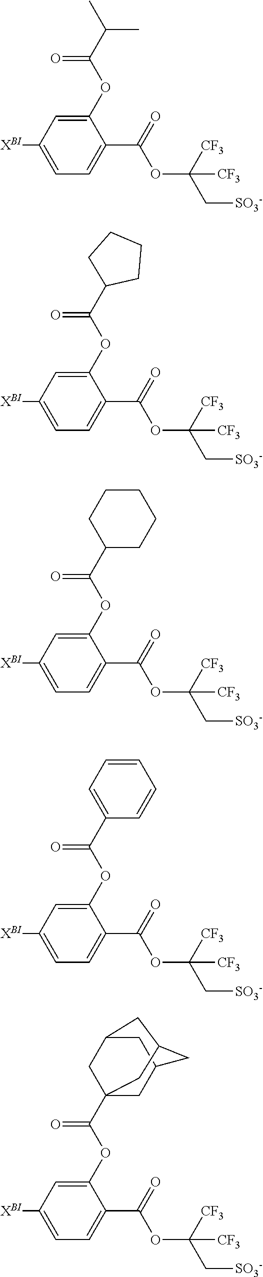

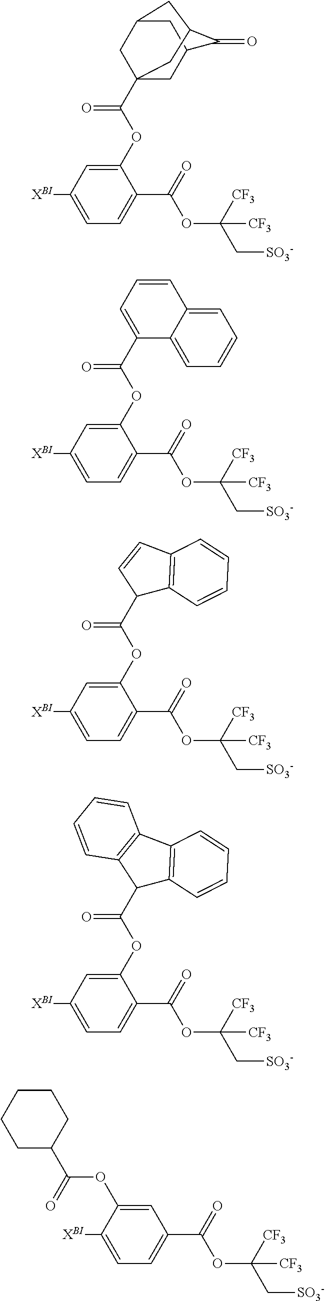

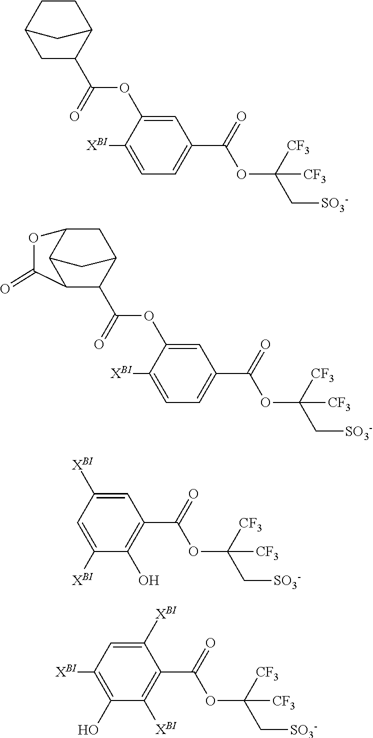

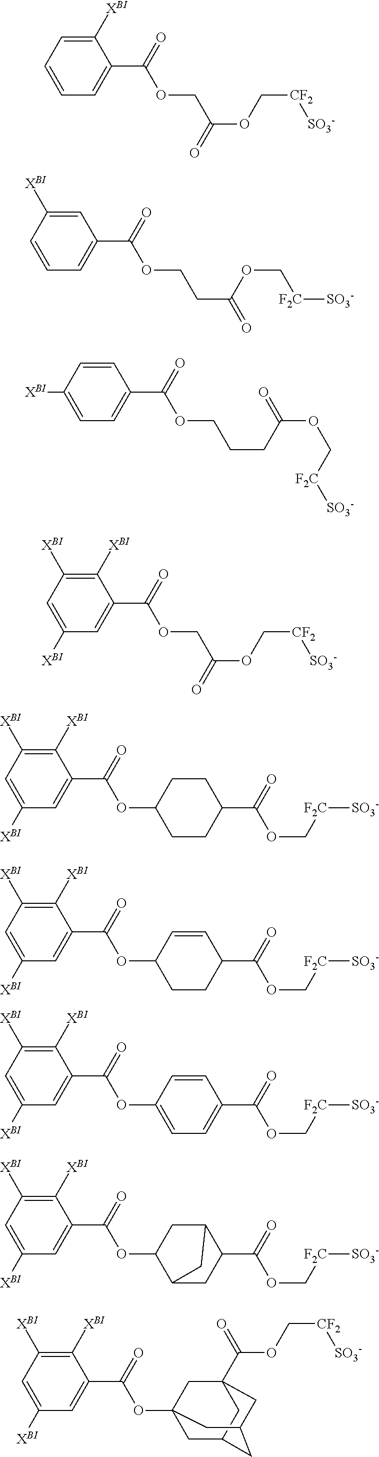

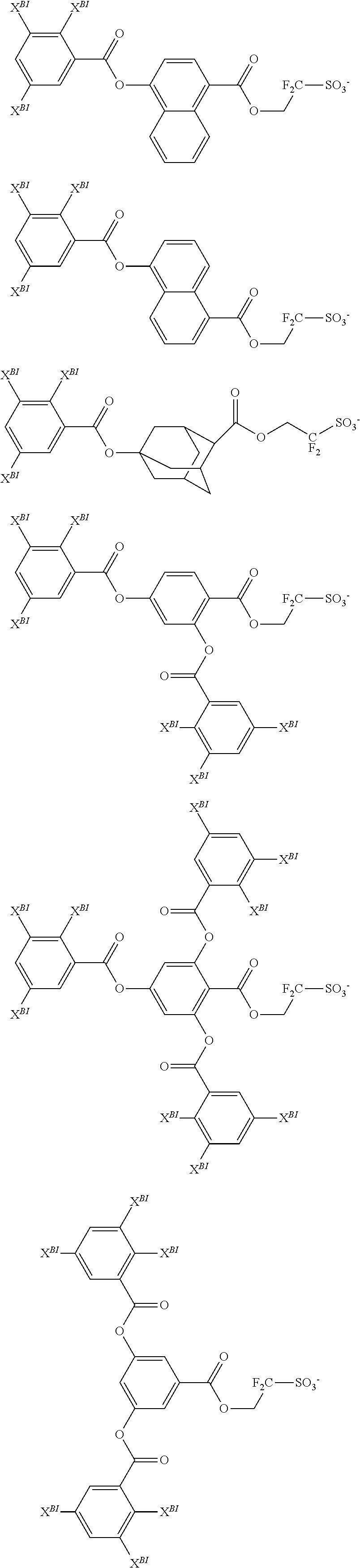

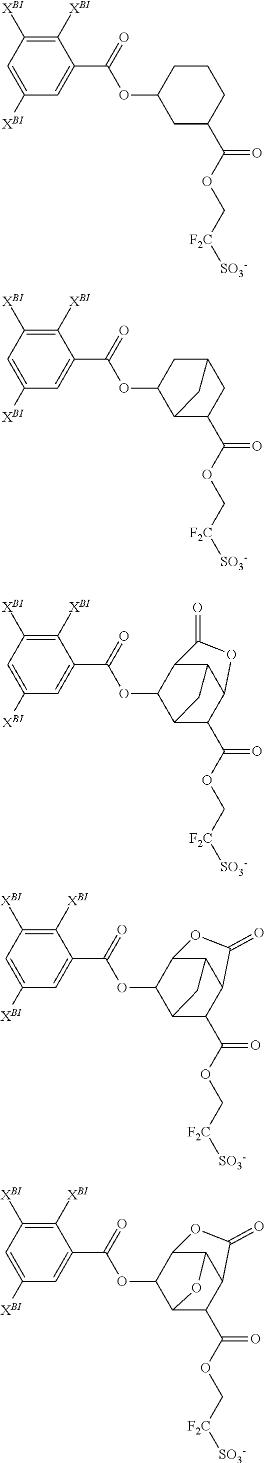

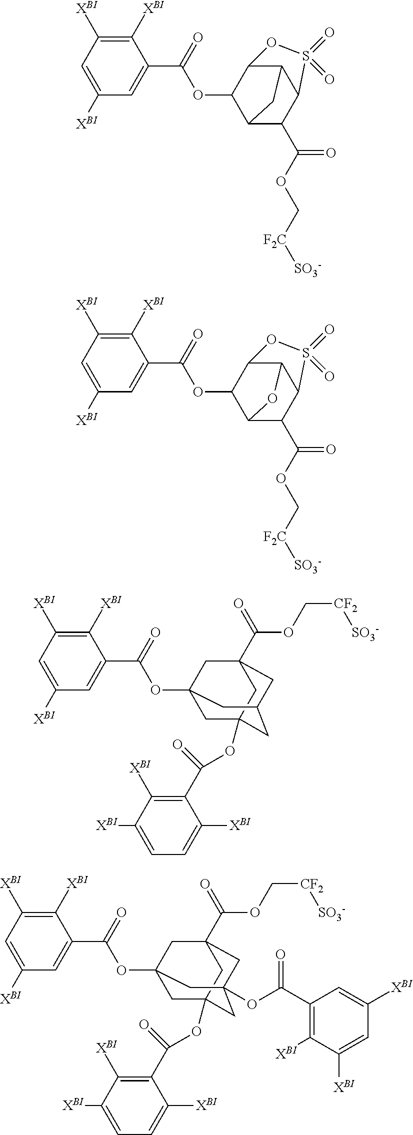

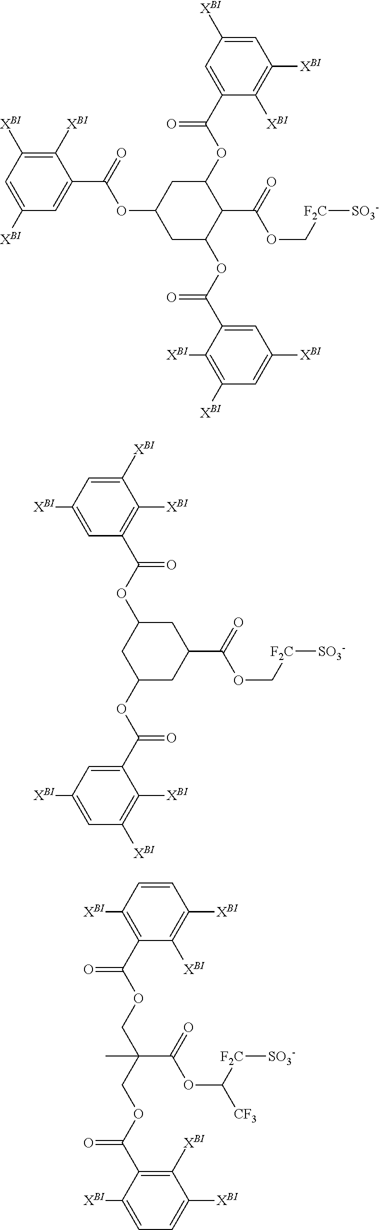

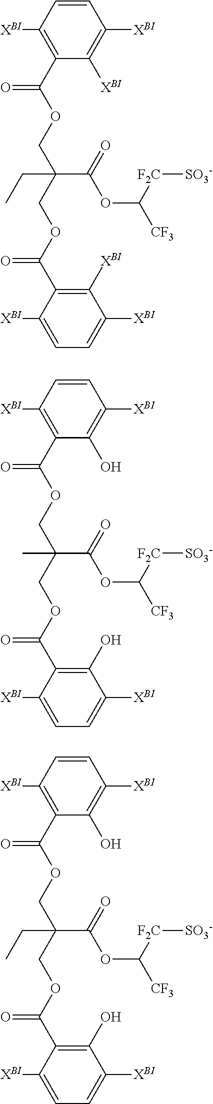

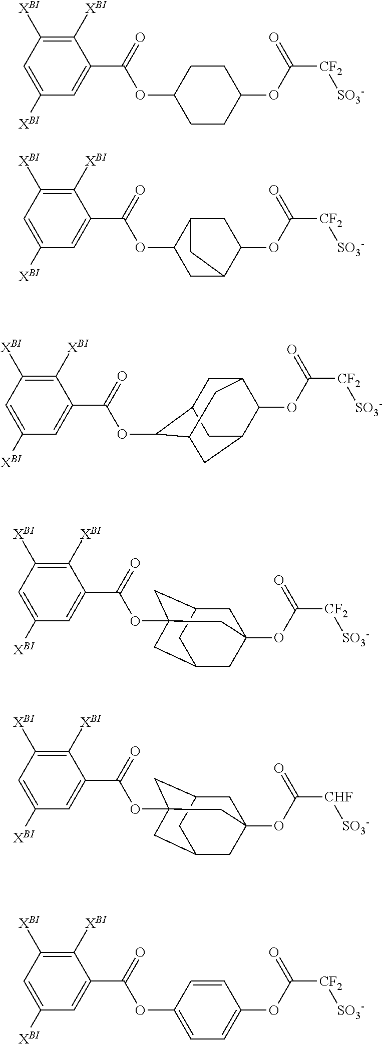

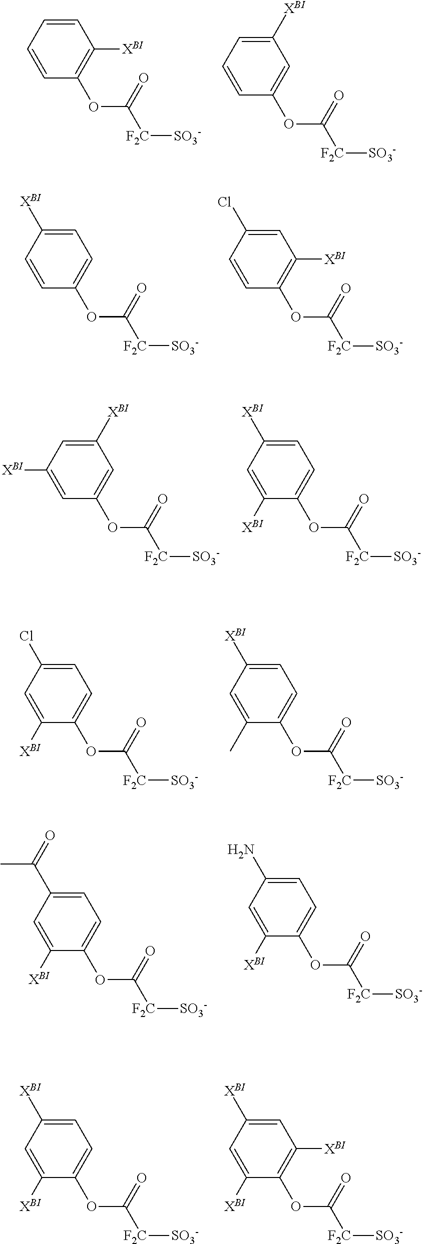

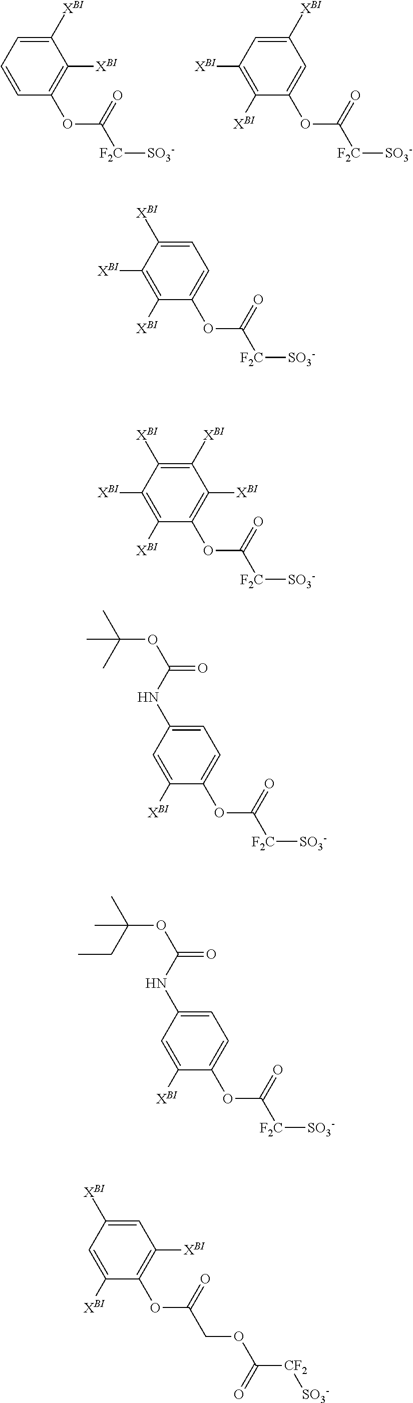

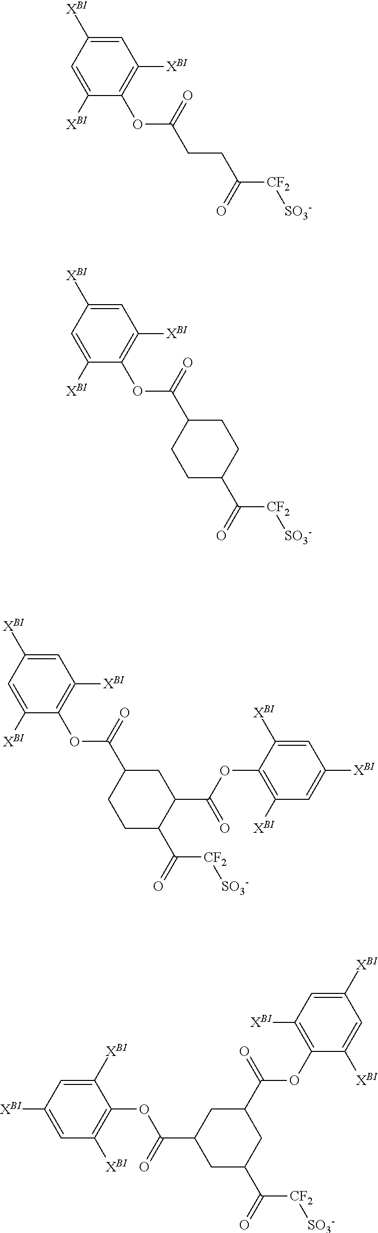

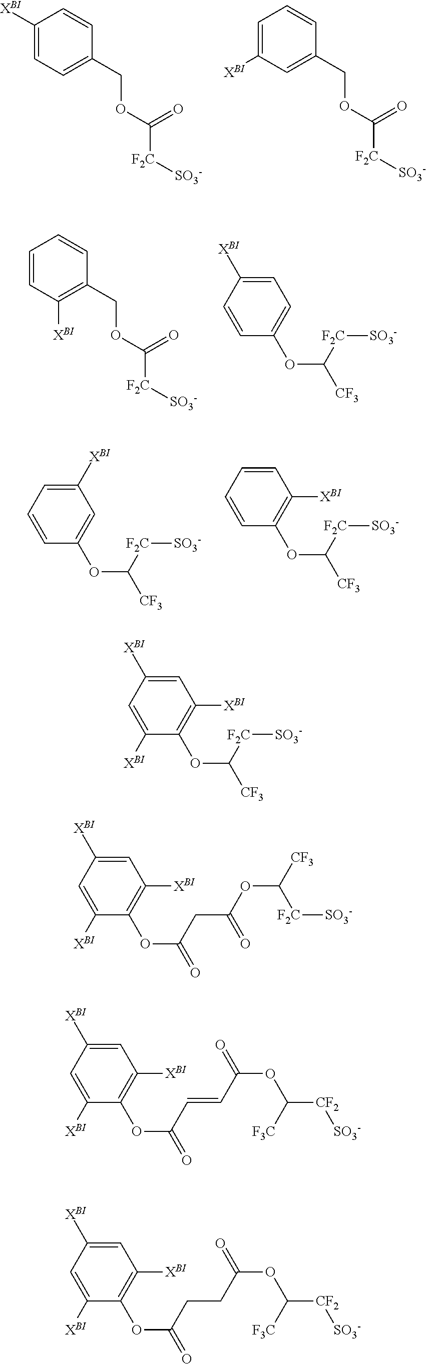

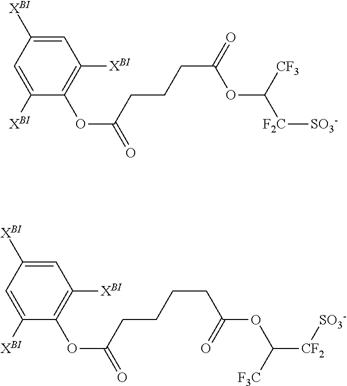

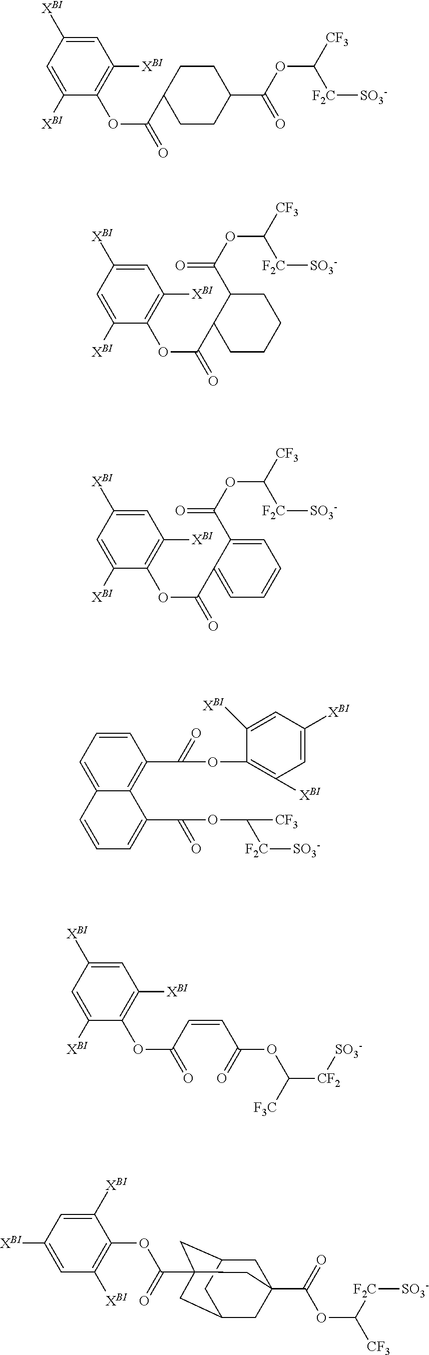

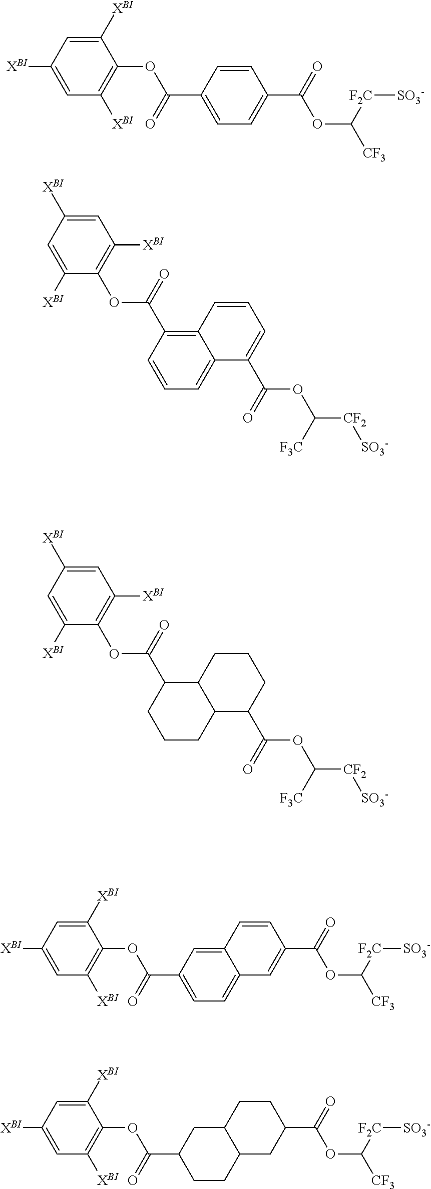

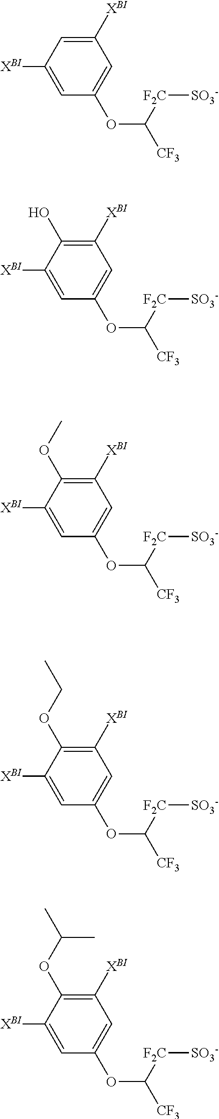

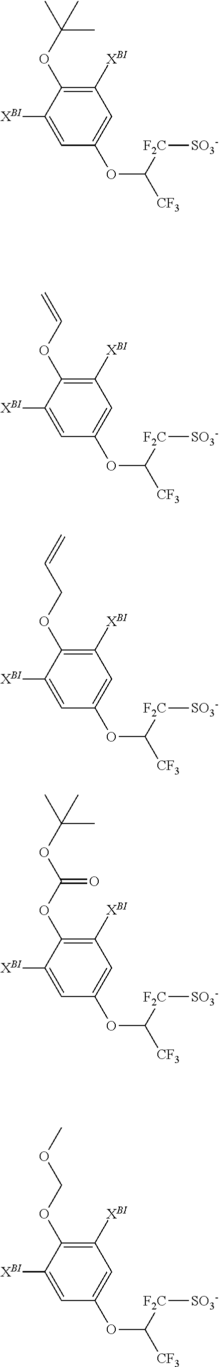

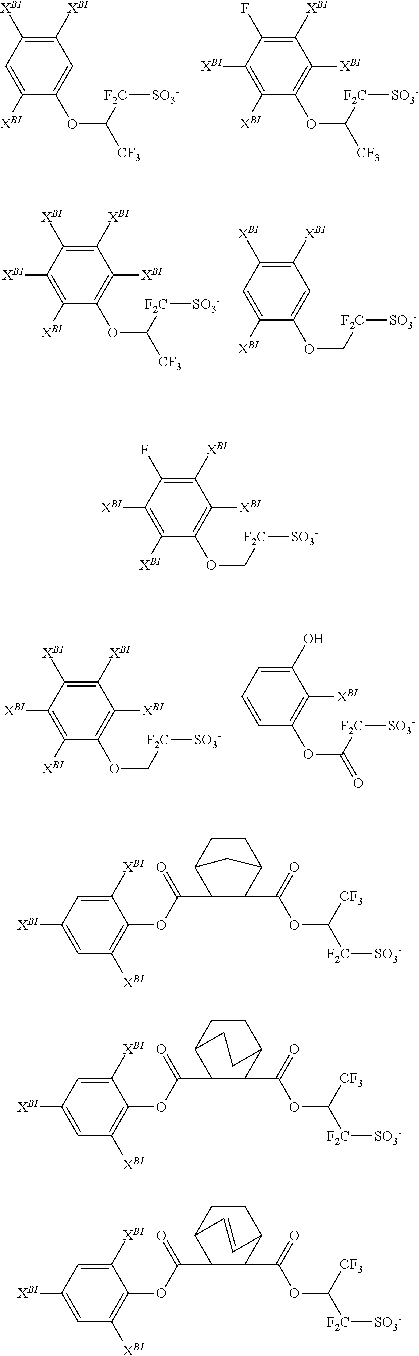

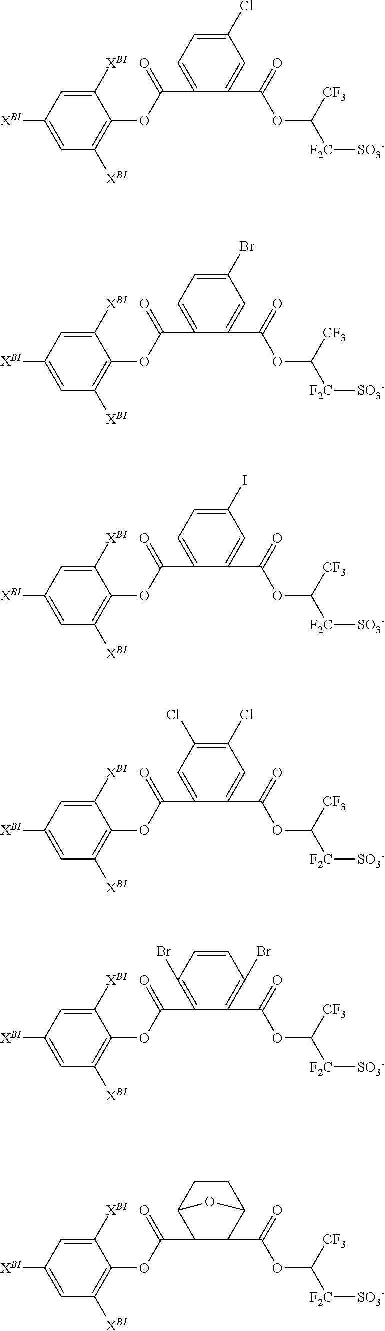

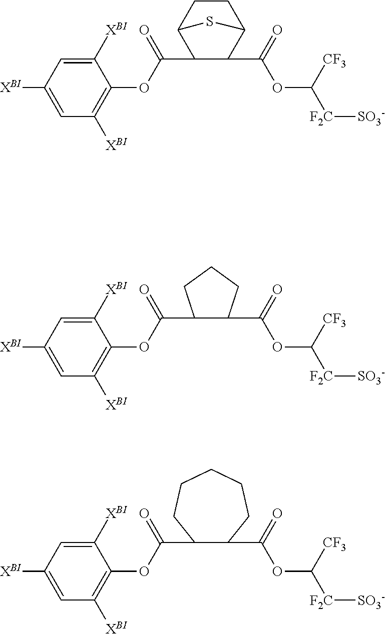

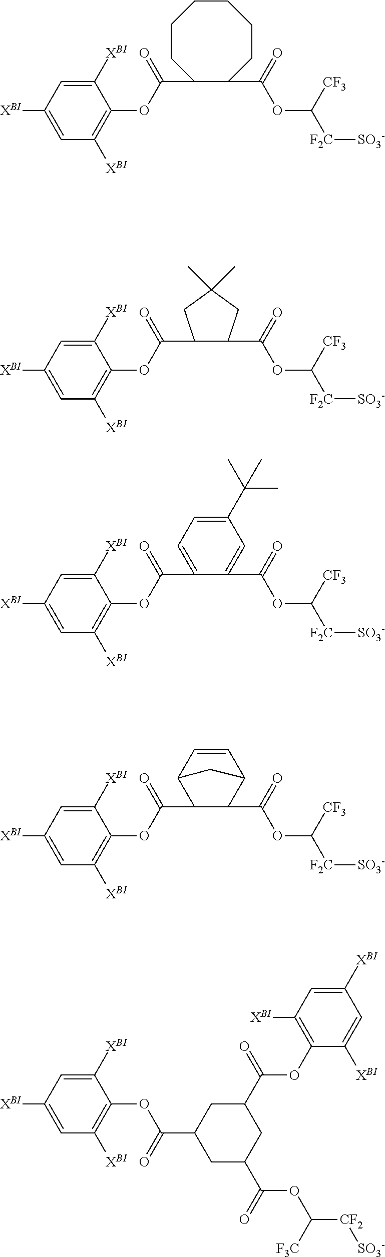

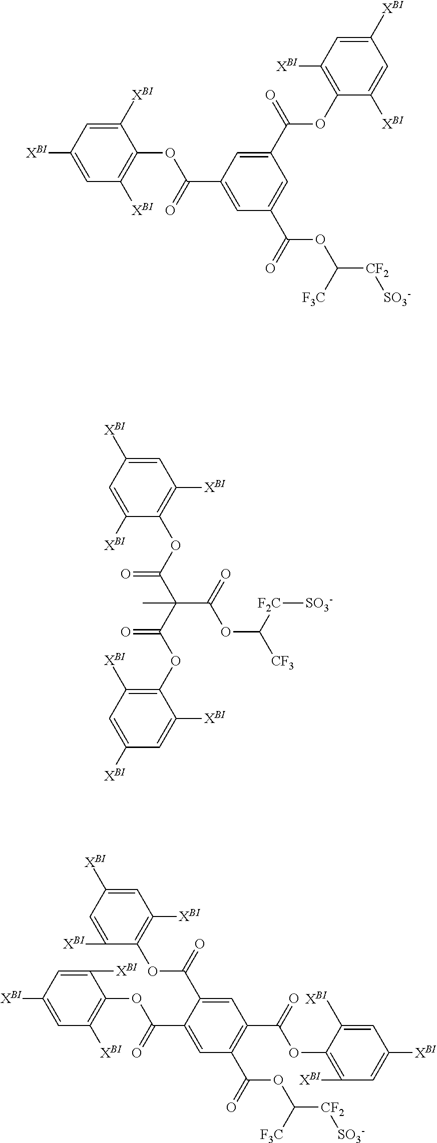

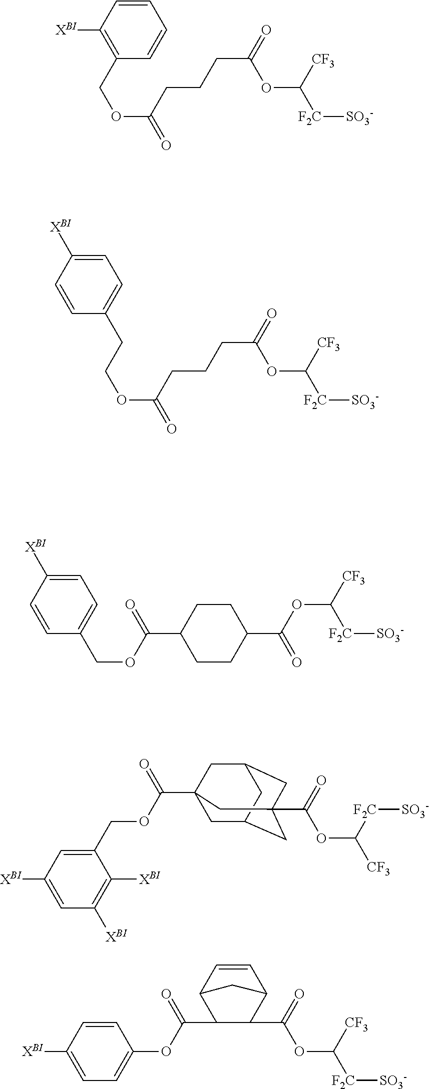

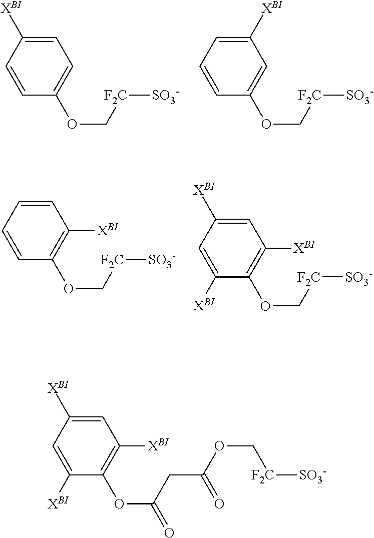

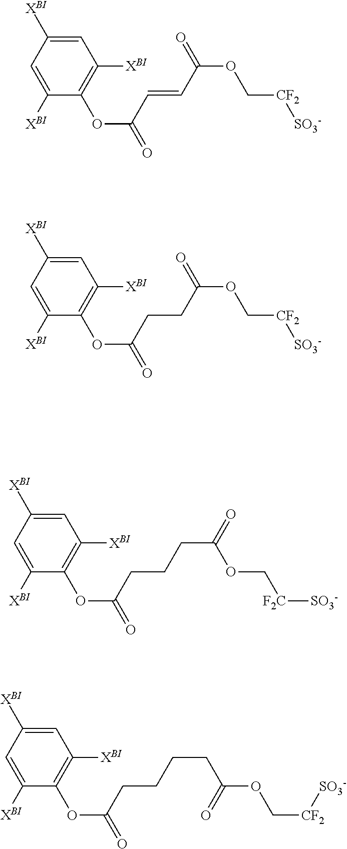

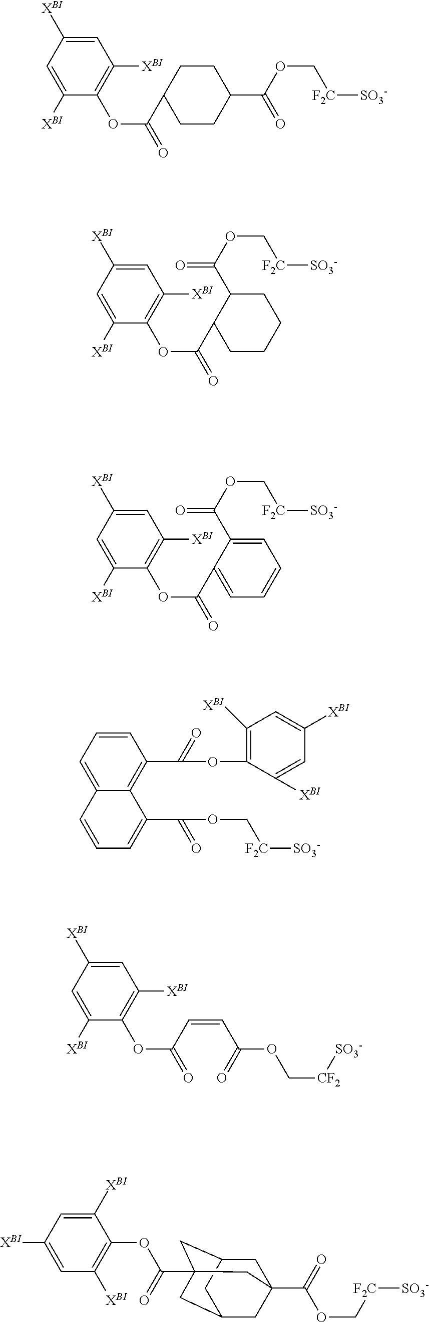

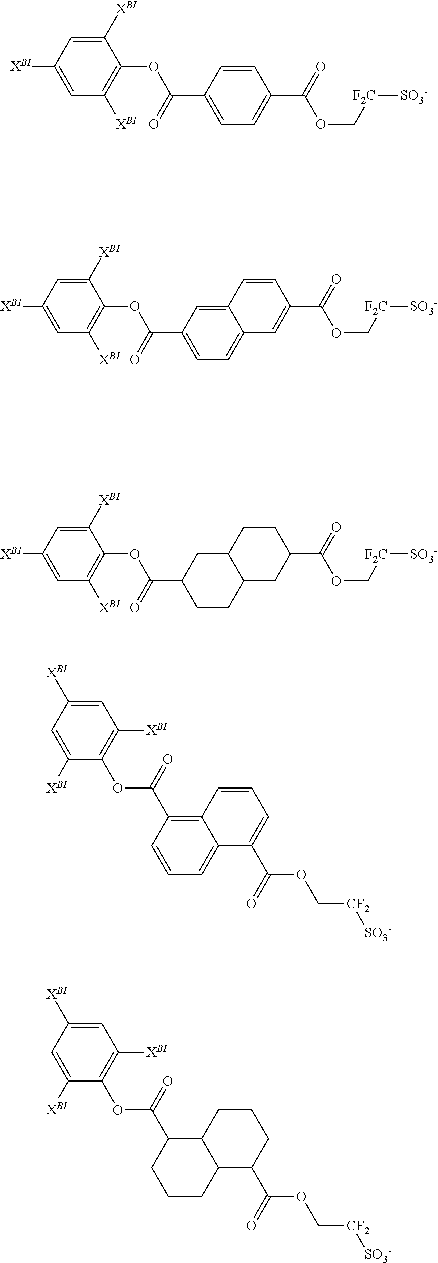

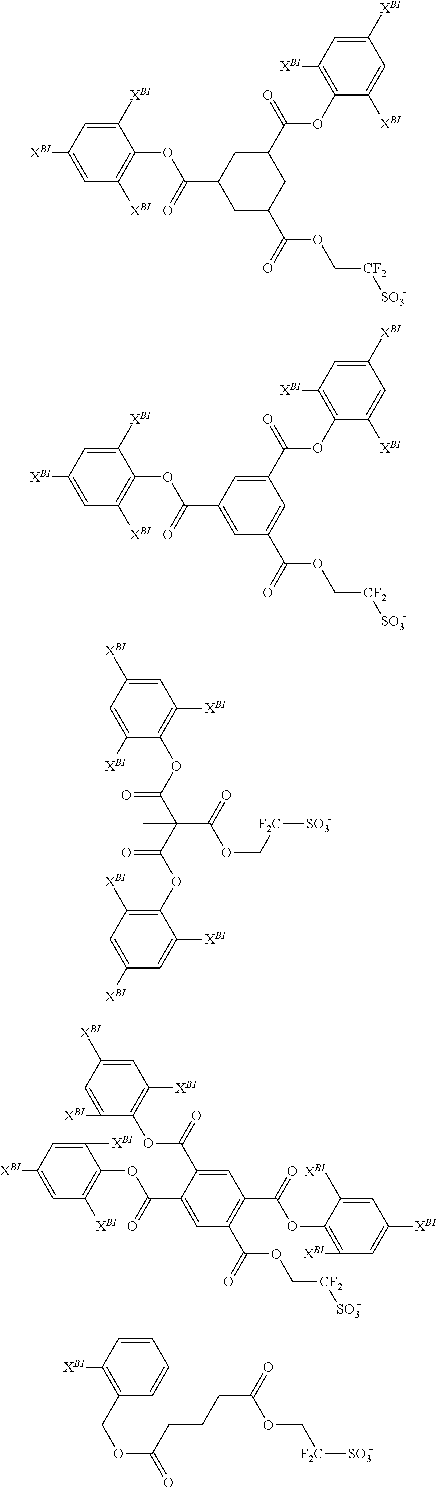

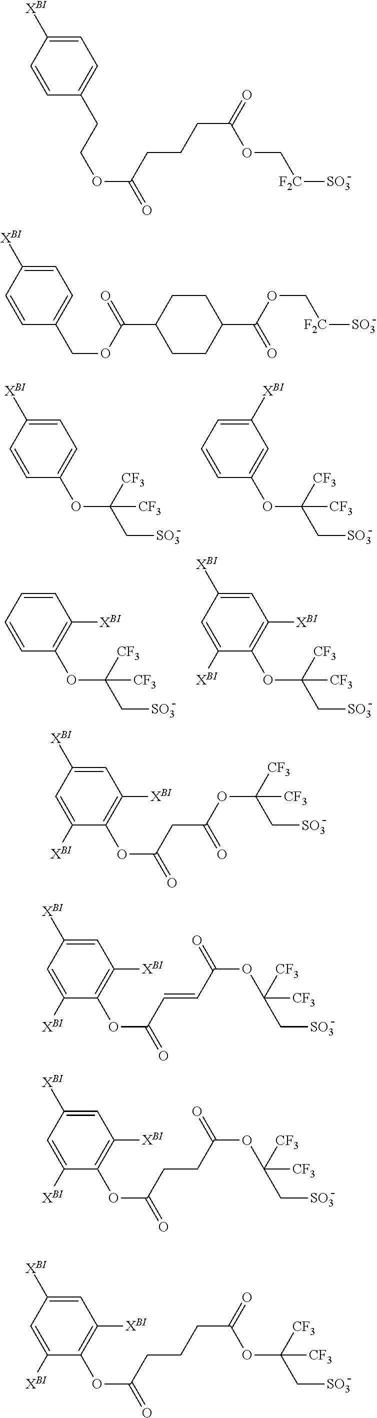

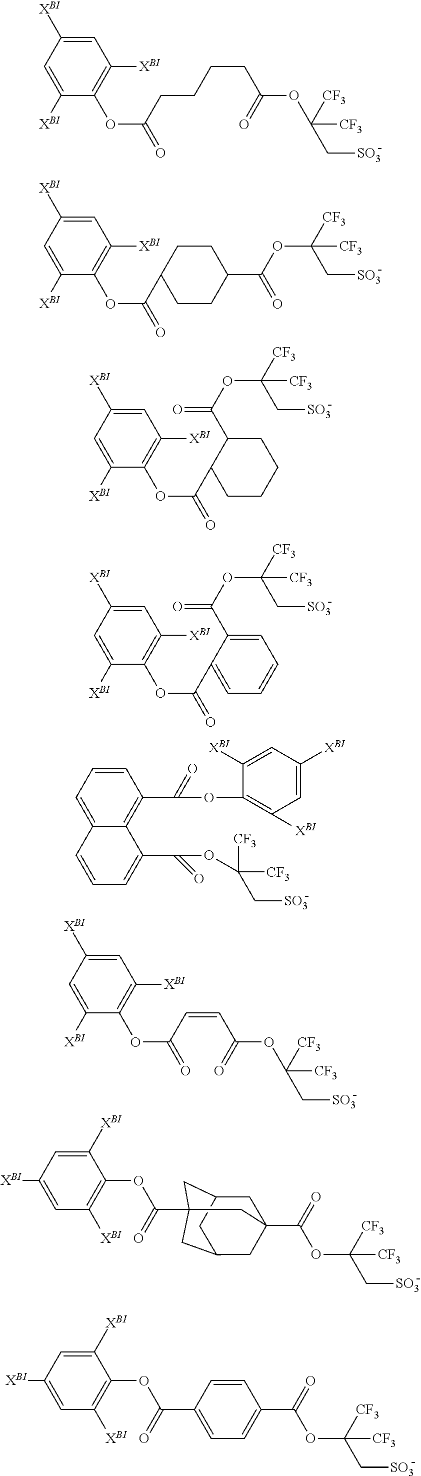

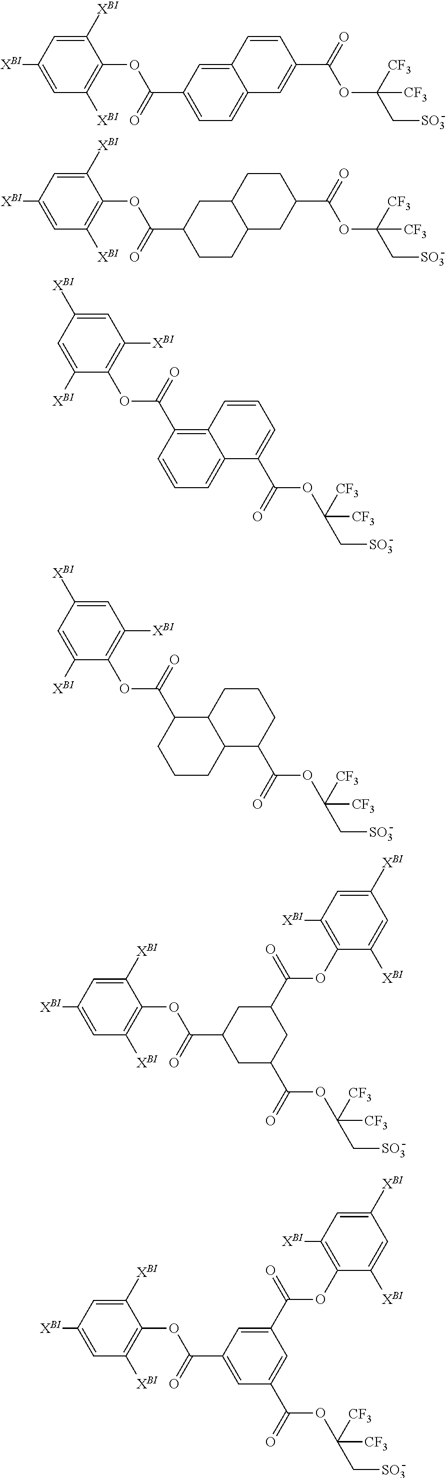

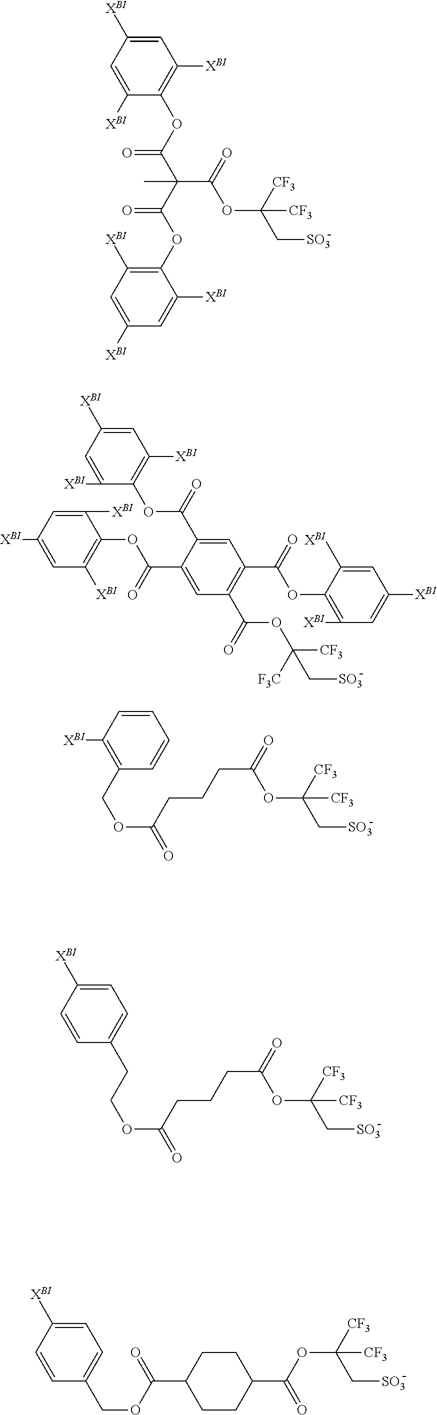

As the non-nucleophilic counter ion, fluorobenzenesulfonic acid anions having an iodized aromatic group bonded thereto as described in JP 6648726, anions having an acid-catalyzed decomposition mechanism as described in WO 2021/200056 and JP-A 2021-070692, anions having a cyclic ether group as described in JP-A 2018-180525 and JP-A 2021-035935, and anions as described in JP-A 2018-092159 can also be used.

Further, as the non-nucleophilic counter ion, bulky fluorine-free benzenesulfonic acid anions as described in JP-A 2006-276759, JP-A 2015-117200, JP-A 2016-065016, and JP-A 2019-202974; fluorine-free benzenesulfonic acid or alkylsulfonic acid anions having an iodized aromatic group bonded thereto as described in JP 6645464 can also be used.

Furthermore, as the non-nucleophilic counter ion, bissulfonic acid anions as described in JP-A 2015-206932, sulfonamide or sulfonimide anions having sulfonic acid side and different side as described in WO 2020/158366, and anions having a sulfonic acid side and a carboxylic acid side as described in JP-A 2015-024989 can also be used.

In formulae (c2) and (c3), d1 and d2 are each independently 0, 1, 2, or 3, but preferably 1.

In formula (c4), e1 is 0 or 1. e2 is 0, 1, 2, 3, or 4. e3 is 0, 1, 2, 3, or 4. It is noted that 0≤e2+e3≤4 in case of e1=0 and 0≤e2+e3≤6 in case of e1=1.

In formulae (c2), (c3) and (c4), L¹ represents a single bond, ether bond, ester bond, carbonyl group, sulfonate ester bond, sulfonamide bond, carbonate bond or carbamate bond. Among them, from the aspect of synthesis, an ether bond, ester bond or carbonyl group is preferred, with the ester bond or carbonyl group being more preferred.

In formula (c2), Rf¹ and Rf² are each independently fluorine or a C₁-C₆ fluorinated saturated hydrocarbyl group. Of these, both Rf¹ and Rf² are preferably fluorine because the generated acid has a higher acid strength. Rf³ and Rf⁴ are each independently hydrogen, fluorine, or a C₁-C₆ fluorinated saturated hydrocarbyl group. Of these, at least one of Rf³ and Rf⁴ is preferably a trifluoromethyl group for improving solvent solubility.

In formula (c3), Rf⁵ and Rf⁶ are each independently hydrogen, fluorine, or a C₁-C₆ fluorinated saturated hydrocarbyl group. It is excluded that all Rf⁵ and Rf⁶ are hydrogen at the same time. Of these, at least one of R^{f} and Rf⁶ is preferably a trifluoromethyl group for improving solvent solubility.

In formula (c4), Rf⁷ is fluorine, a C₁-C₆ fluorinated alkyl group, a C₁-C₆ fluorinated alkoxy group, or a C₁-C₆ fluorinated alkylthio group. As Rf⁷, fluorine, trifluoromethyl, difluoromethyl, trifluoromethoxy, difluoromethoxy, trifluoromethylthio or difluoromethylthio group is preferred, and fluorine, trifluoromethyl or trifluoromethoxy group is more preferred. A plurality of Rf⁷ may be identical or different when f is 2, 3, or 4.

In formula (c4), R³³ is halogen exclusive of fluorine, or a C₁-C₂₀ hydrocarbyl group which may contain a heteroatom. The hydrocarbyl group may be saturated or unsaturated and straight, branched or cyclic. Examples thereof are as exemplified above for the hydrocarbyl group represented by R¹ in formula (1), but not limited thereto. A plurality of R³³ may be identical or different when e3 is 2, 3, or 4.

Also, when e3 is 2, 3, or 4, a plurality of R³³ may bond together to form a ring with the carbon atoms to which they are attached. Examples of the ring thus formed include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

Examples of the anion in repeat unit (c2) are given below, but not limited thereto. In the formulae, R^{A} is as defined above, and Me is methyl.

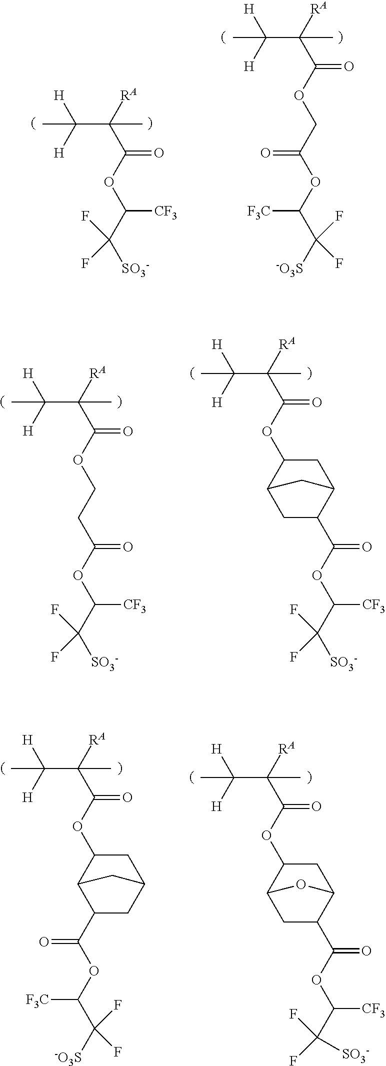

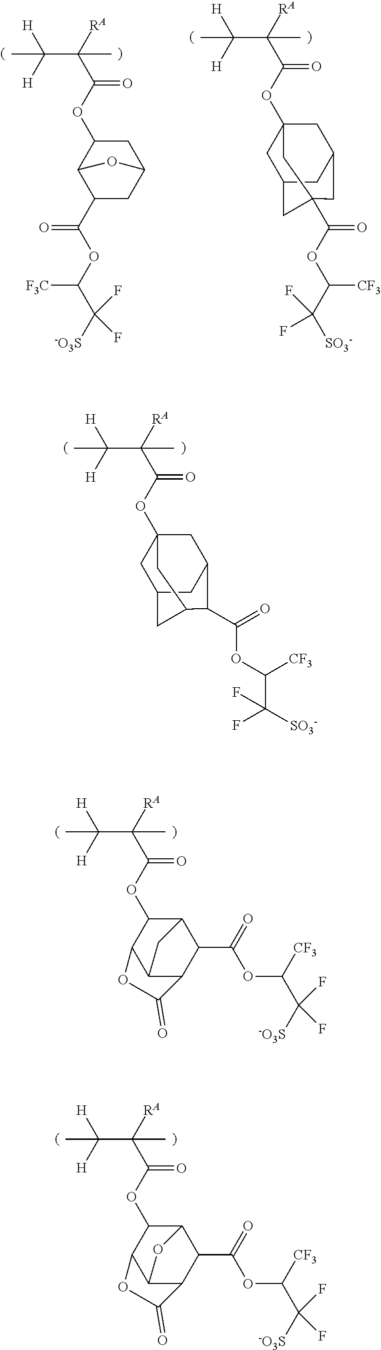

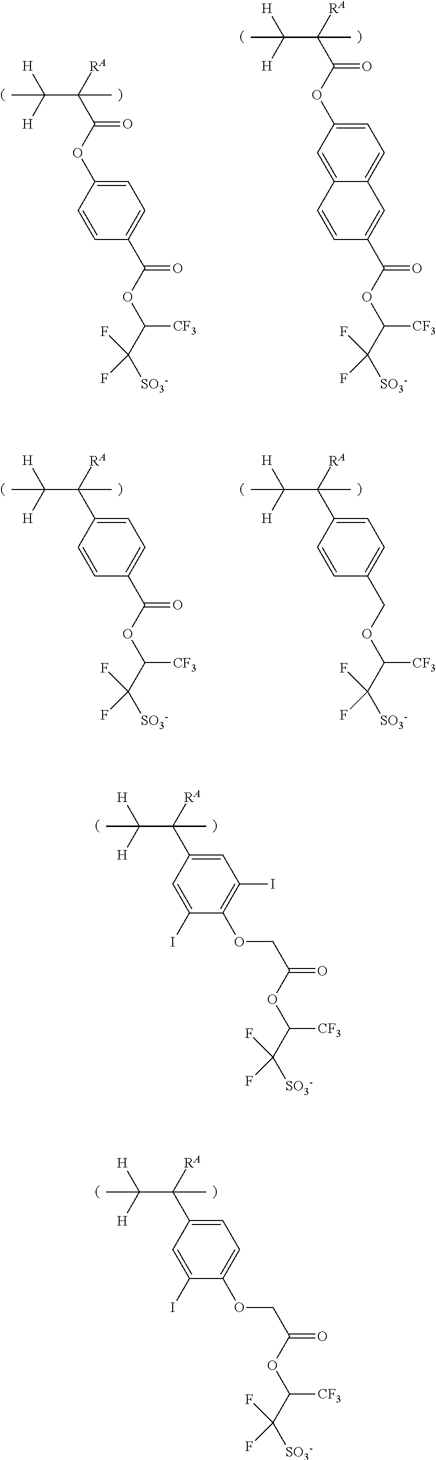

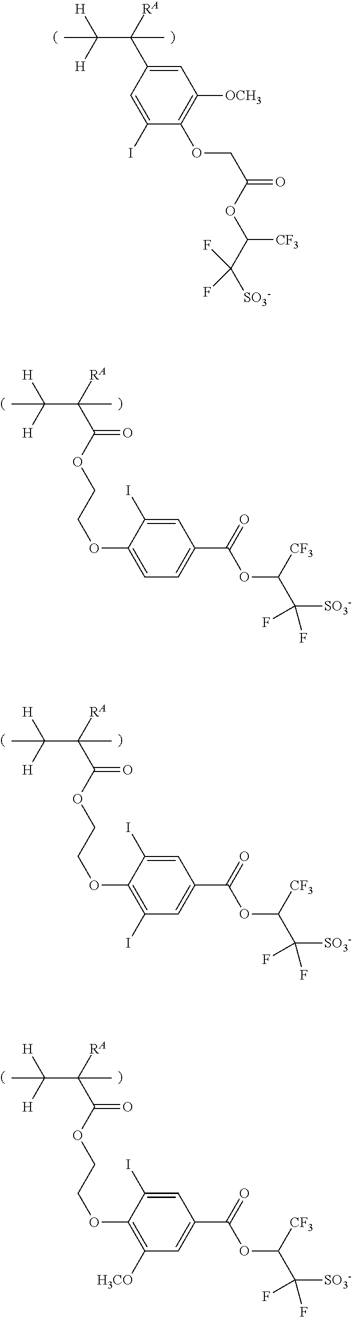

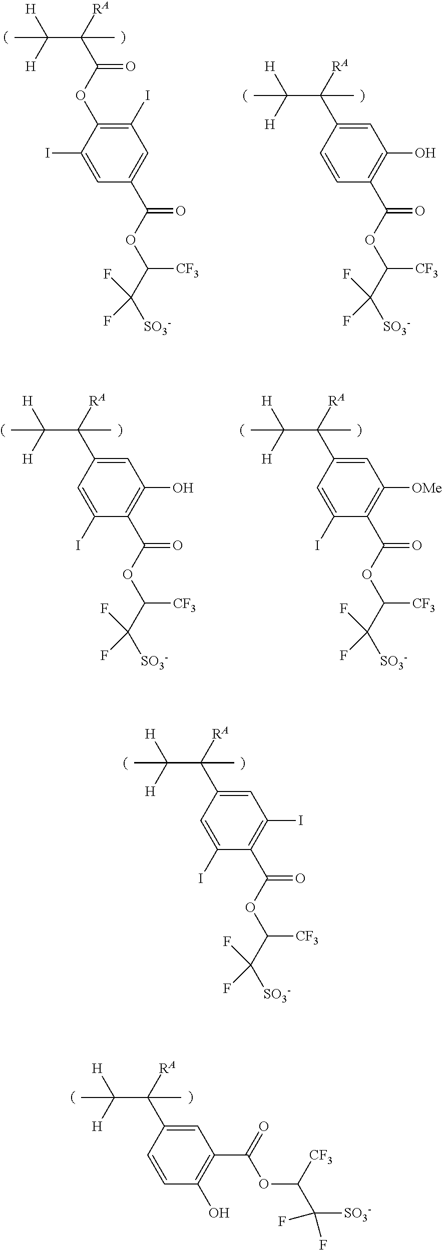

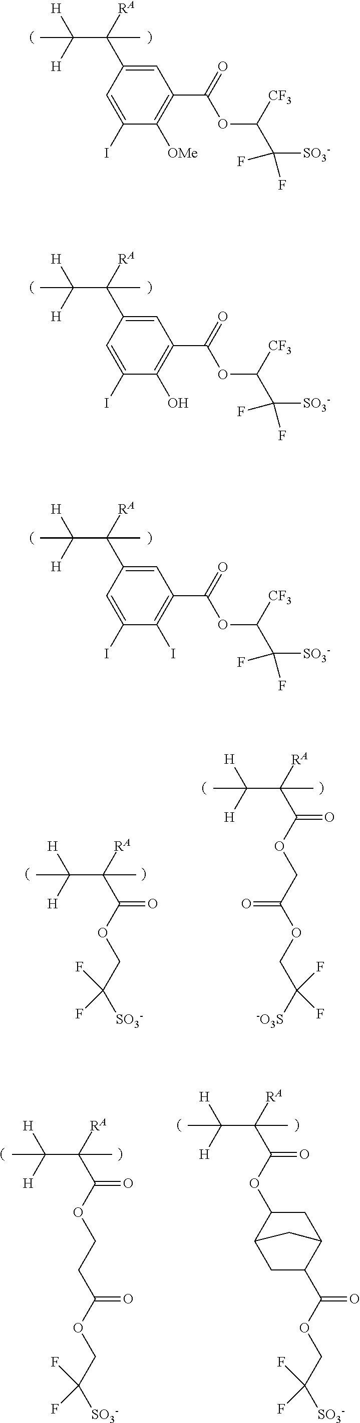

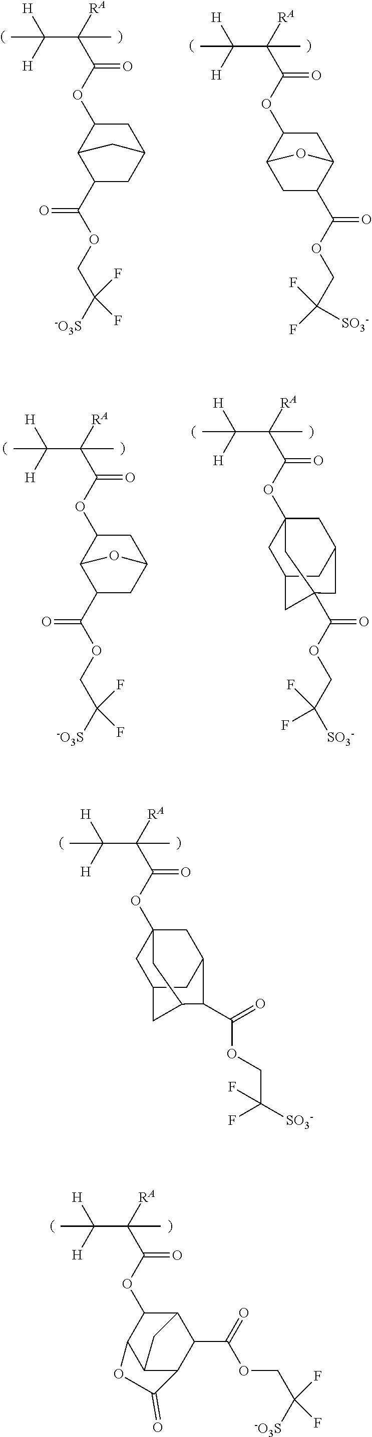

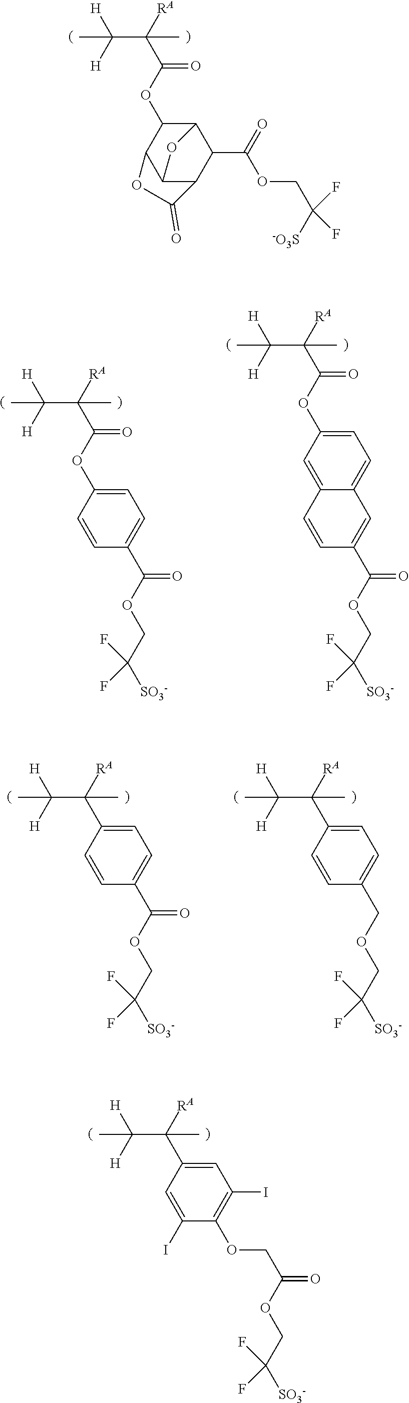

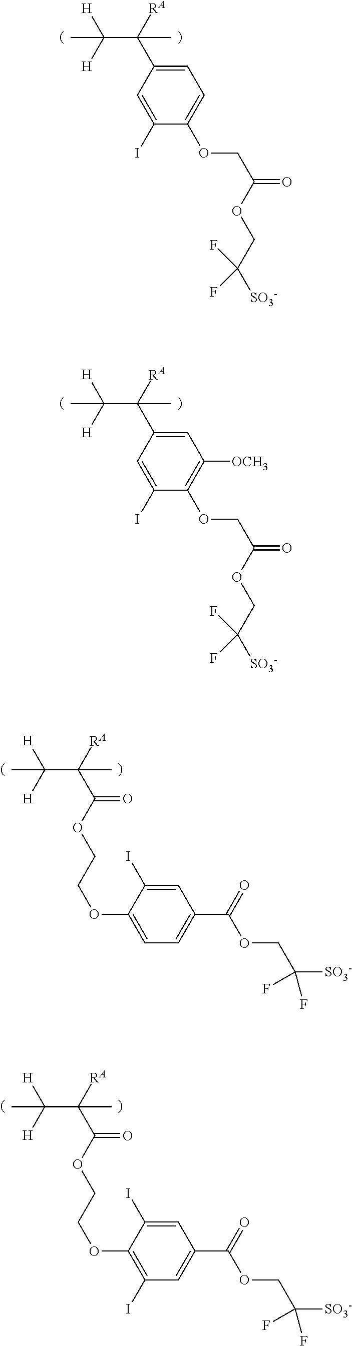

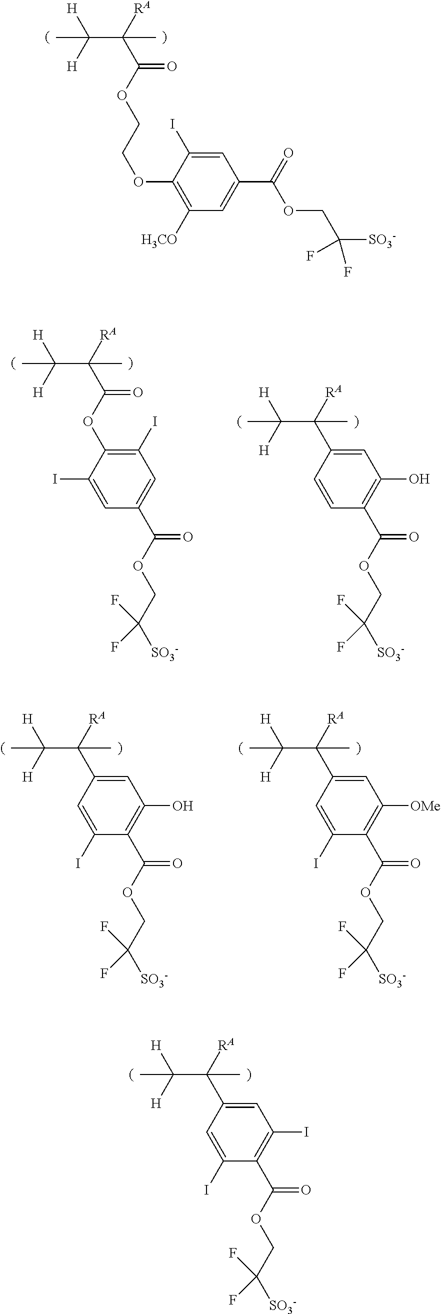

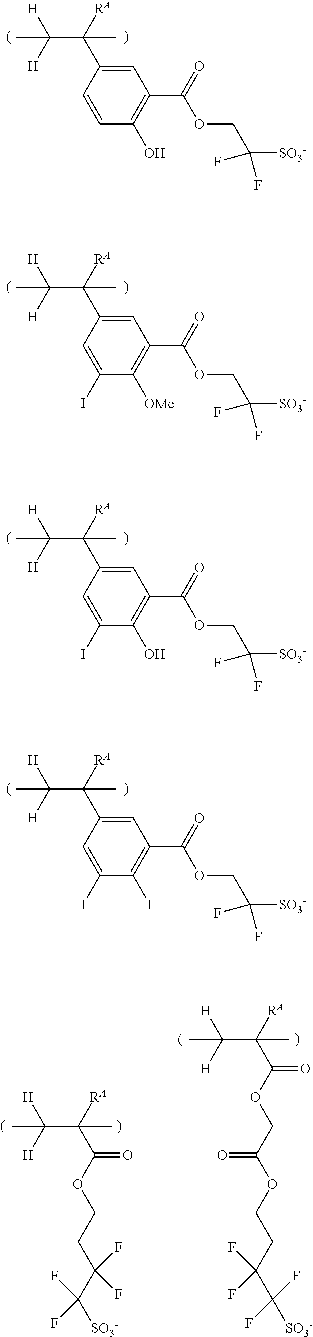

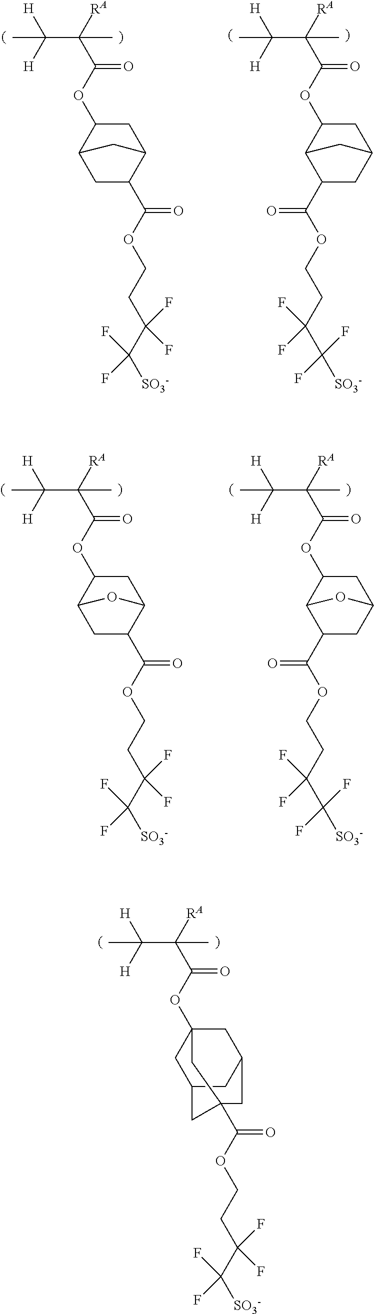

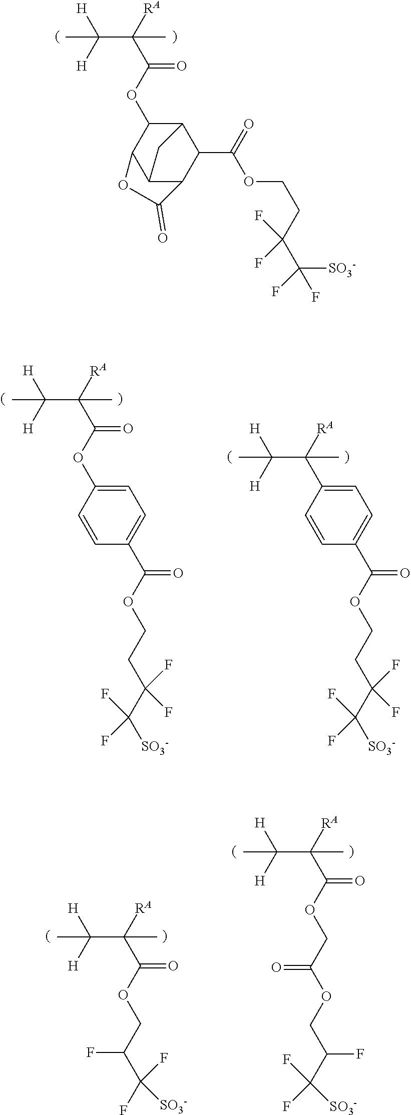

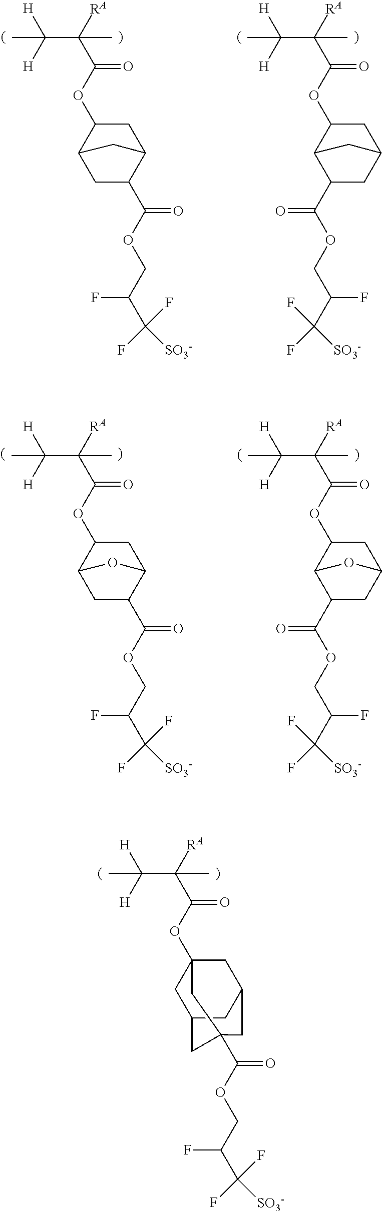

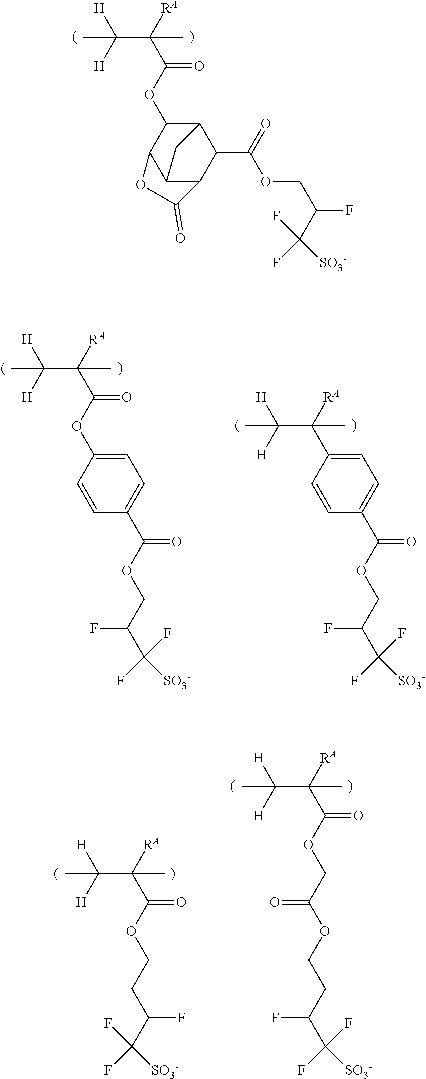

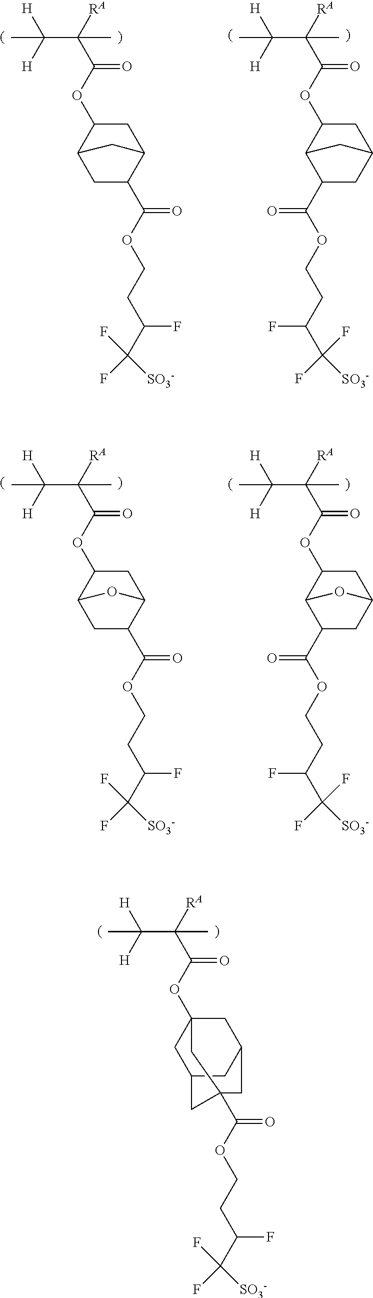

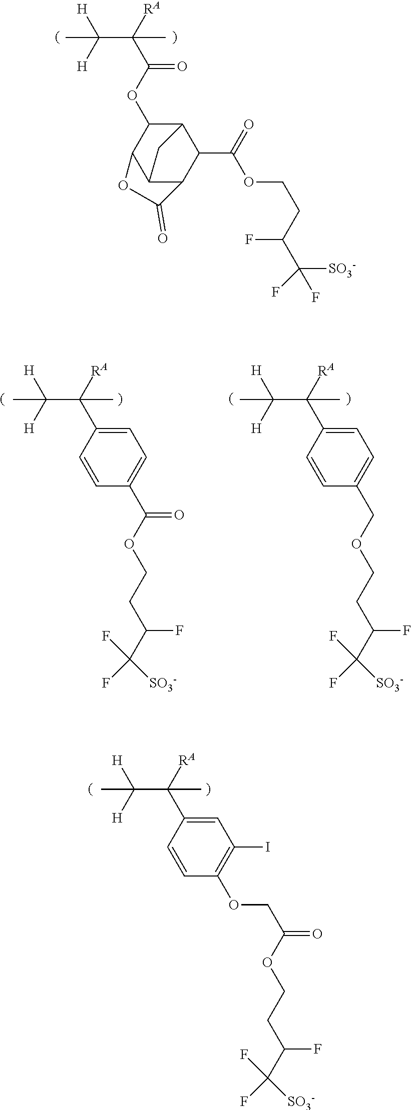

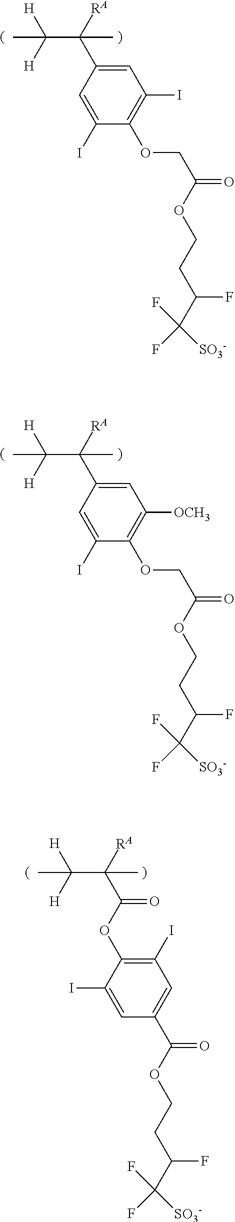

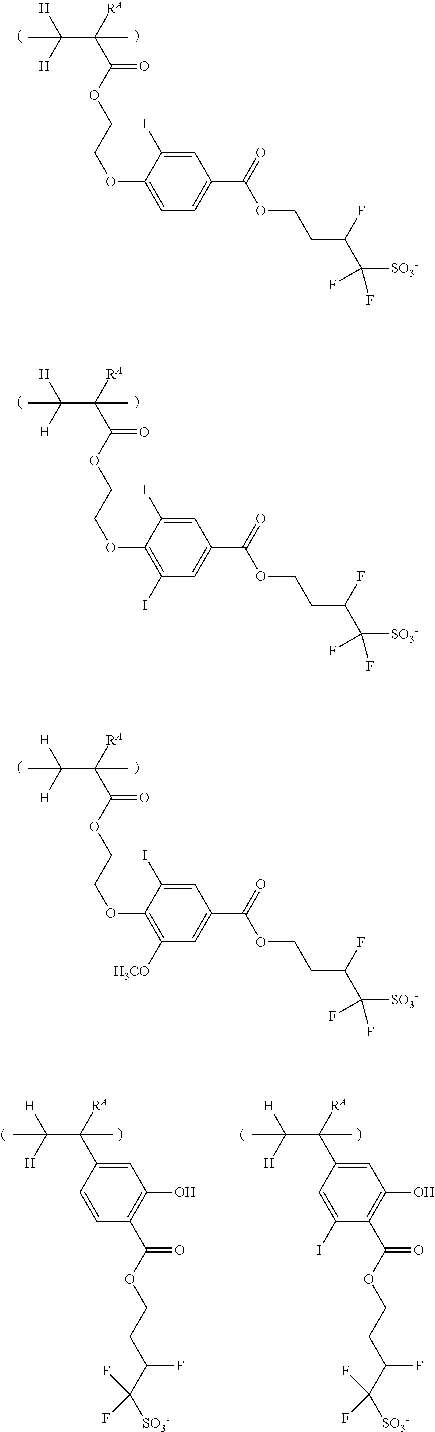

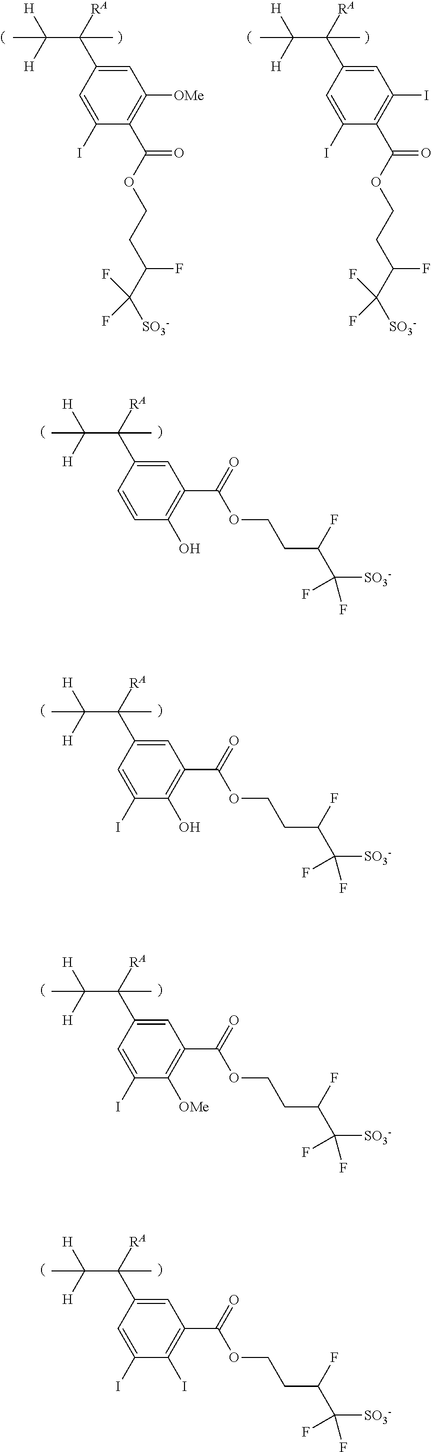

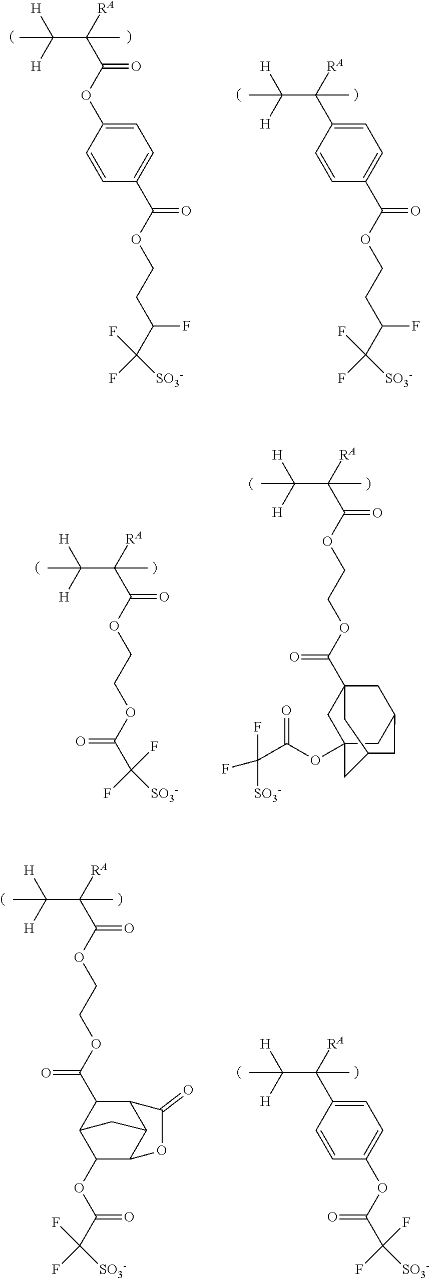

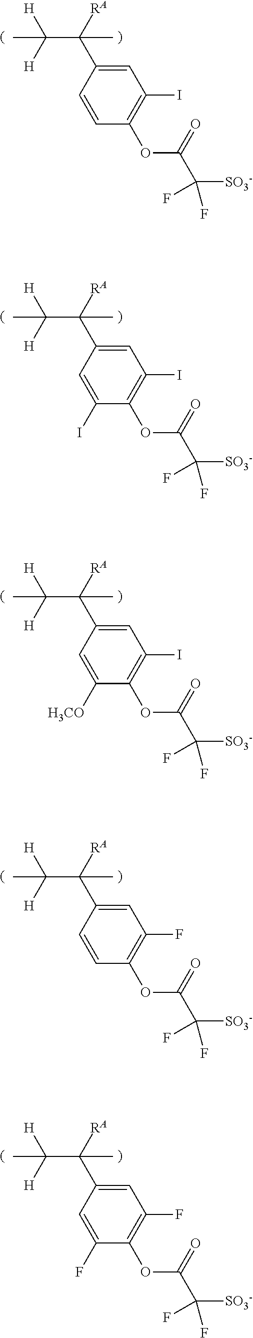

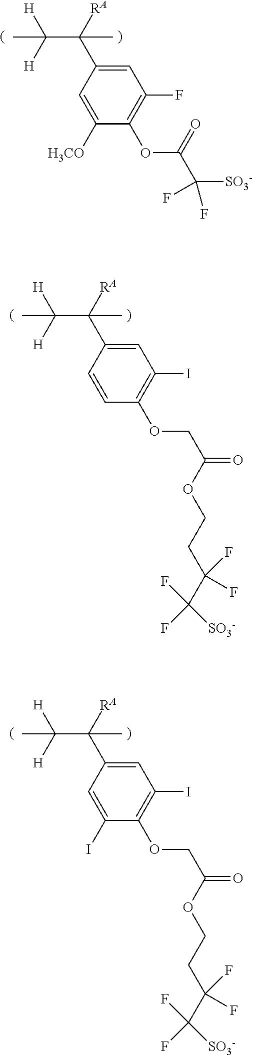

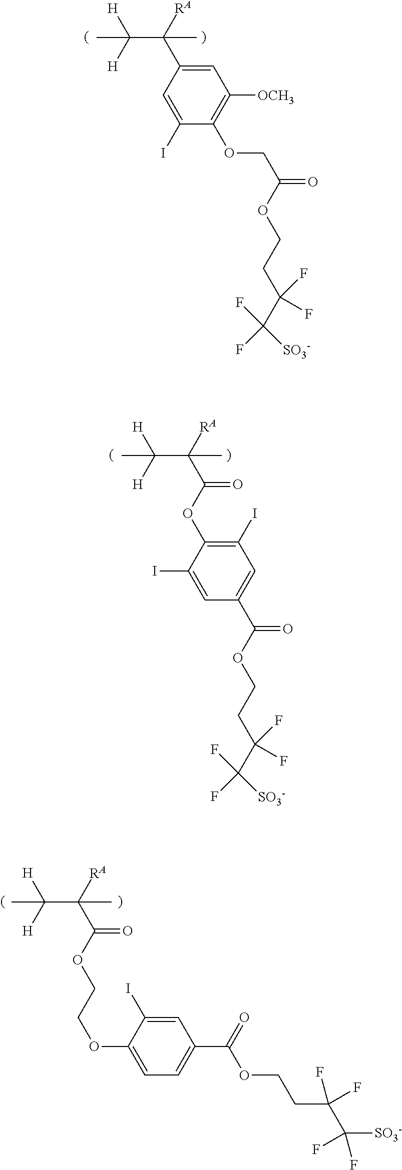

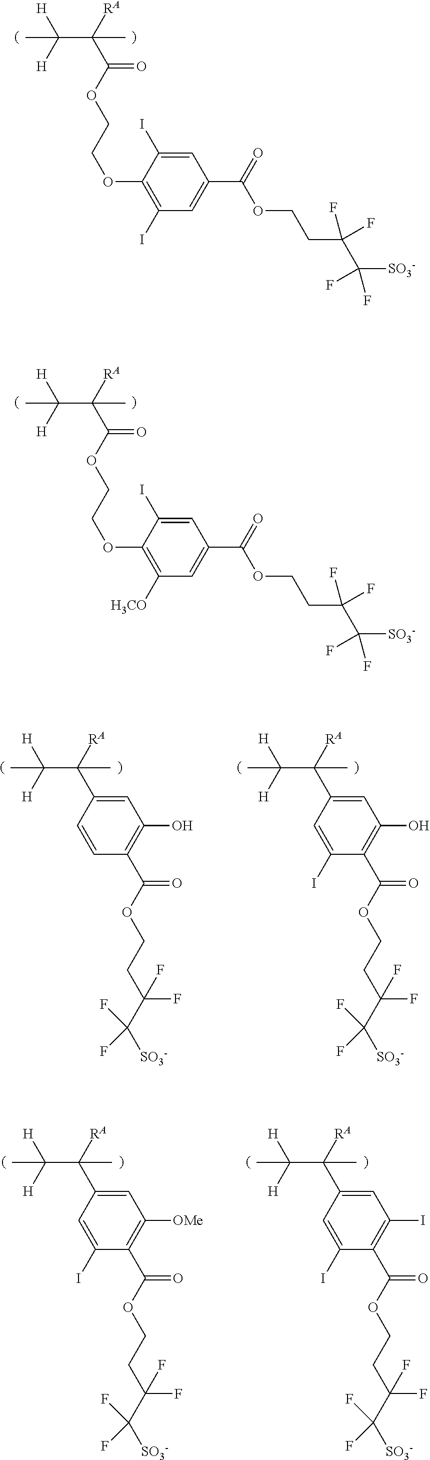

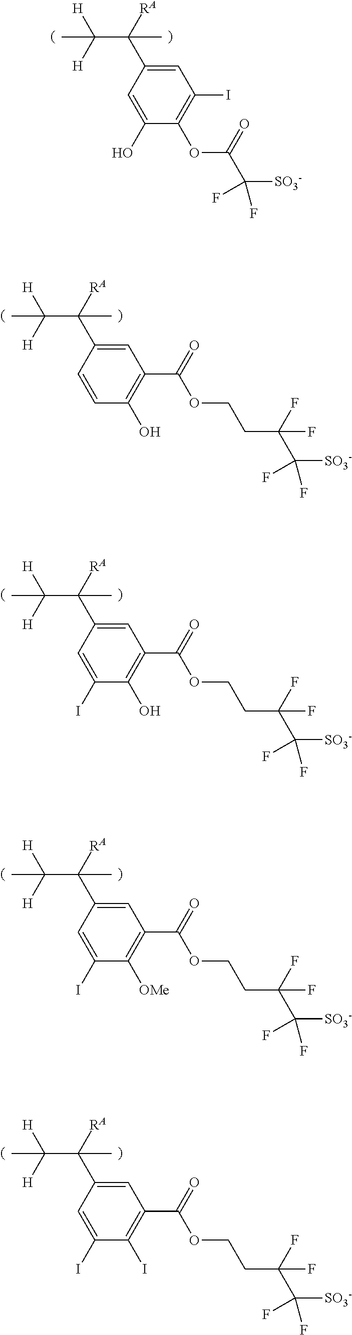

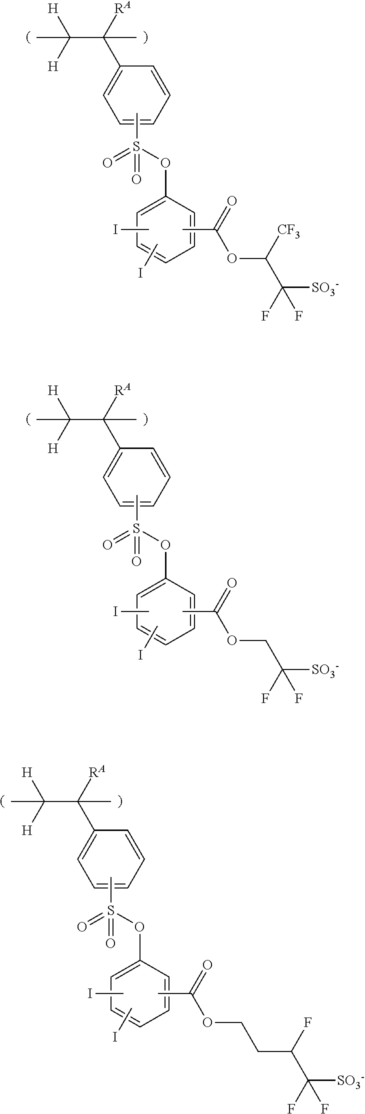

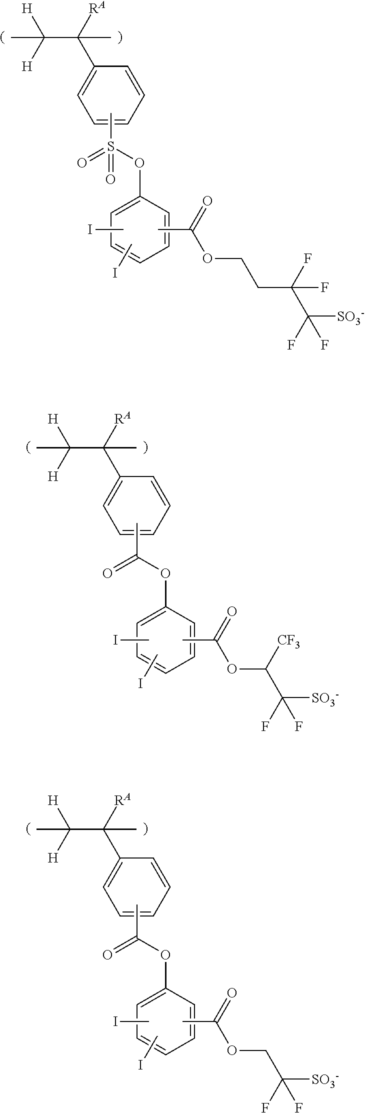

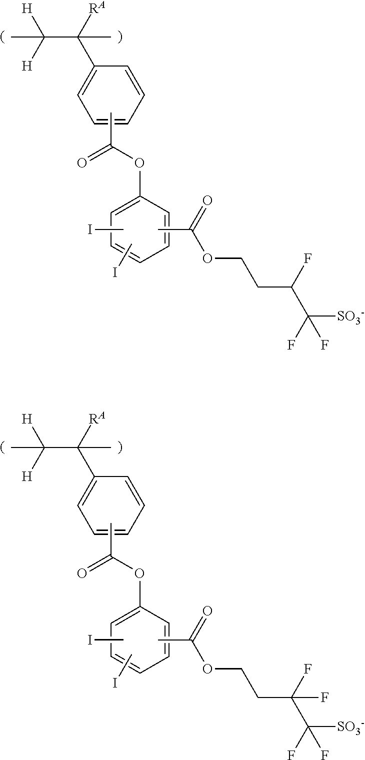

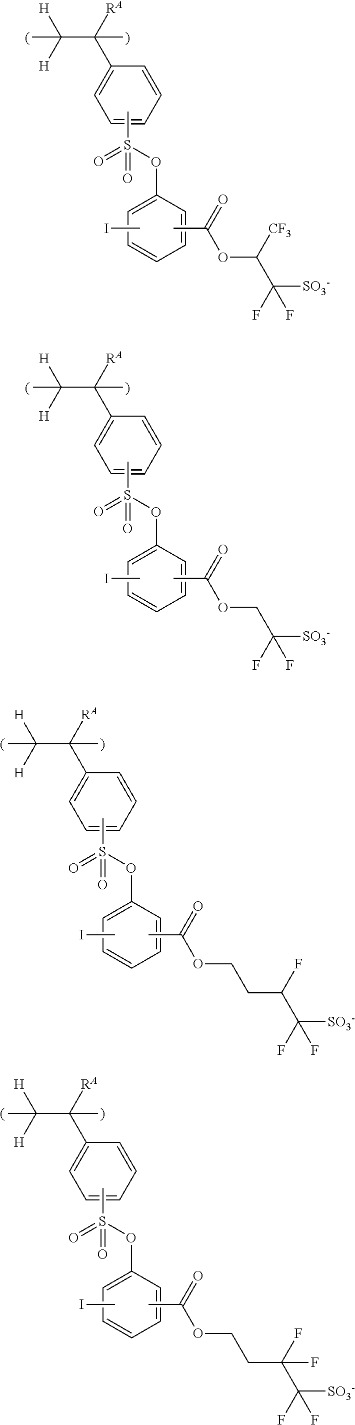

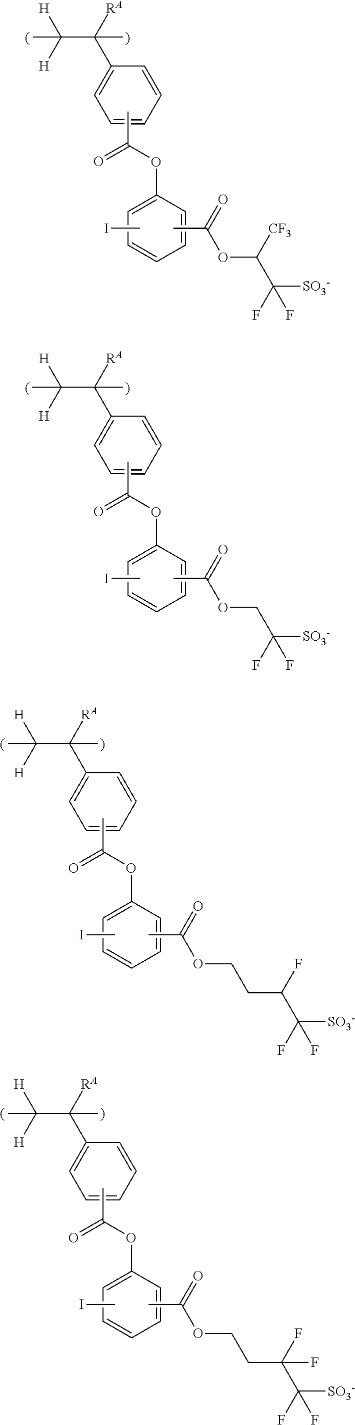

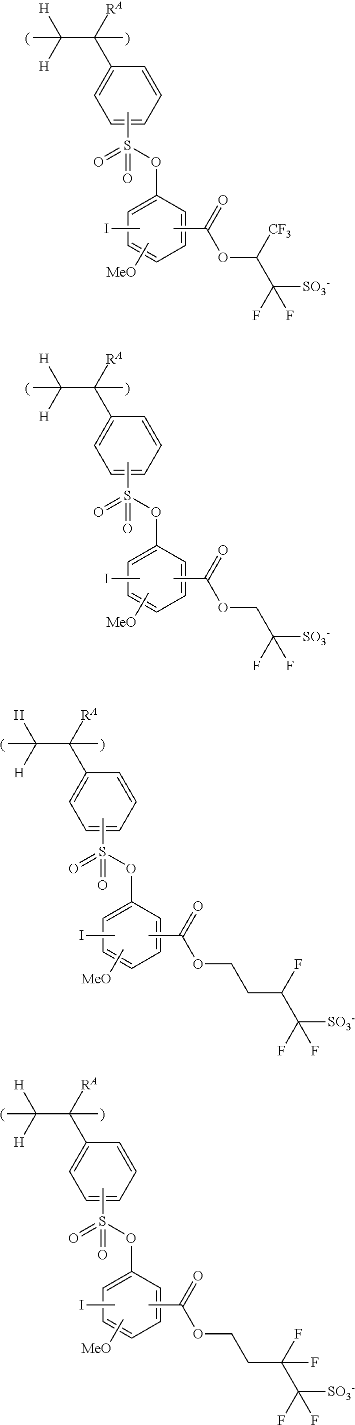

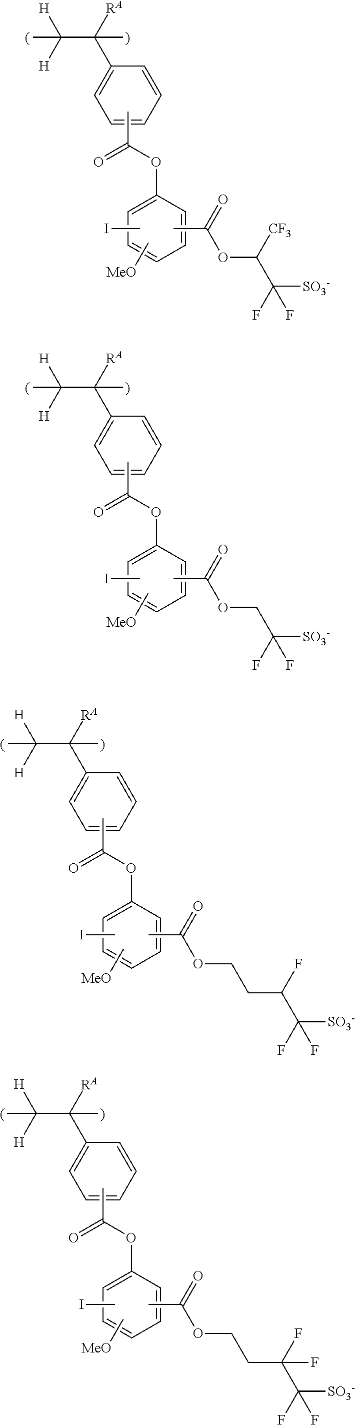

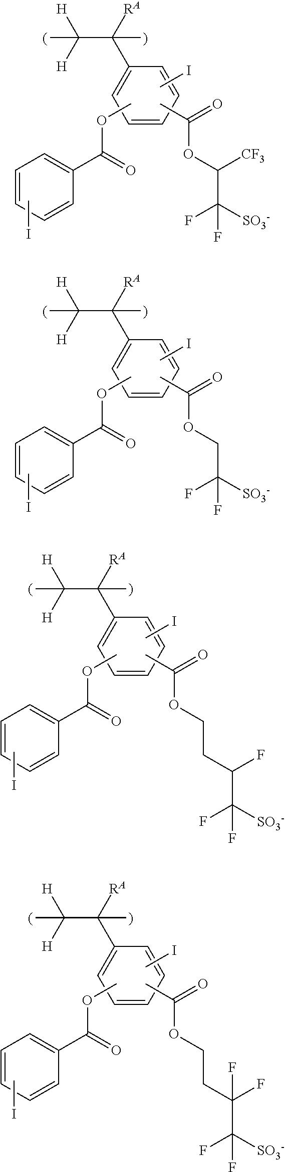

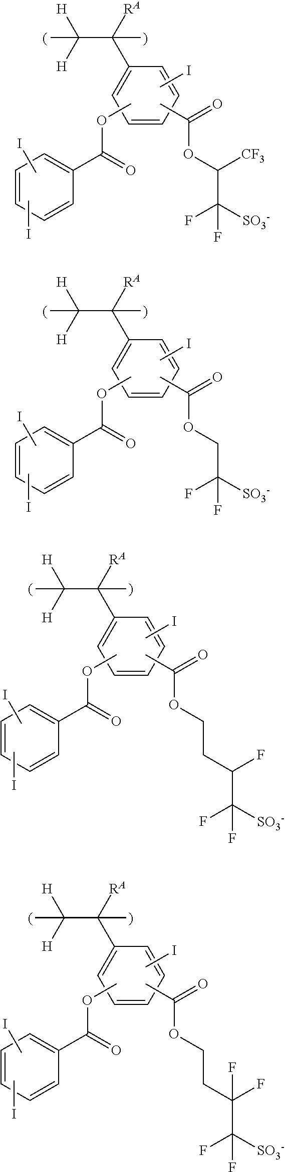

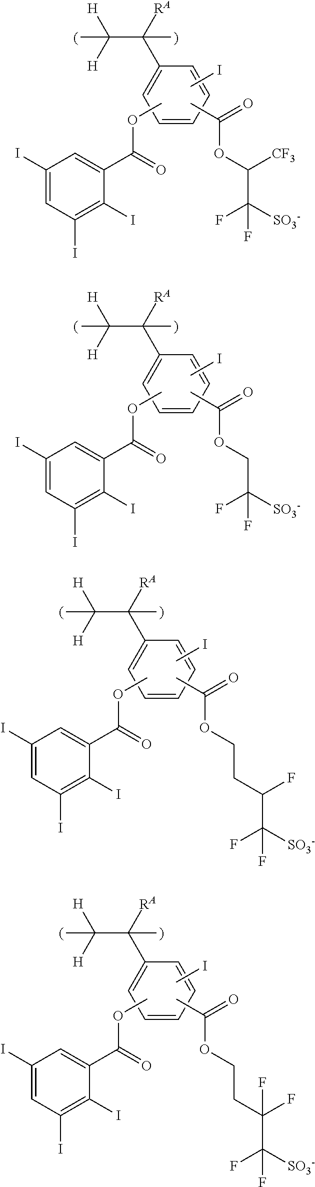

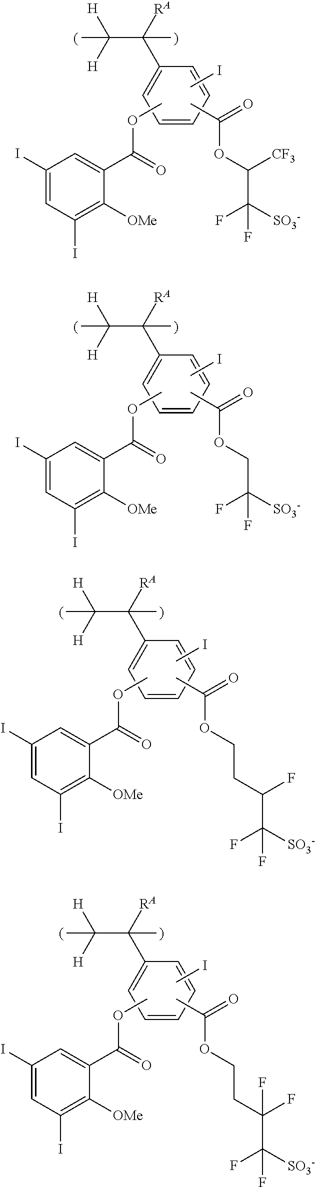

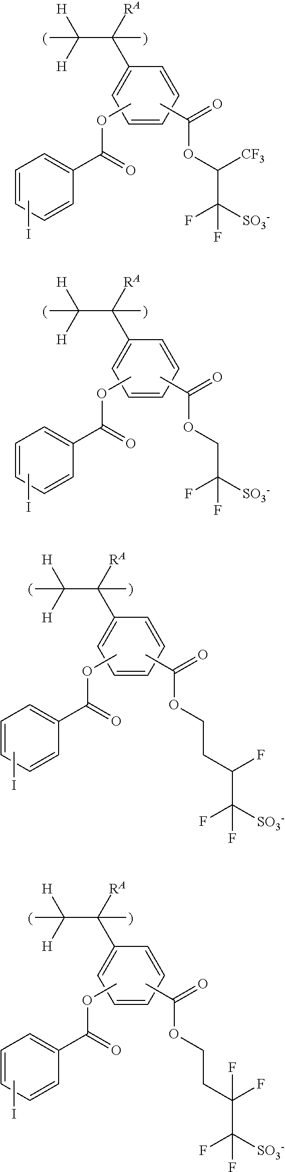

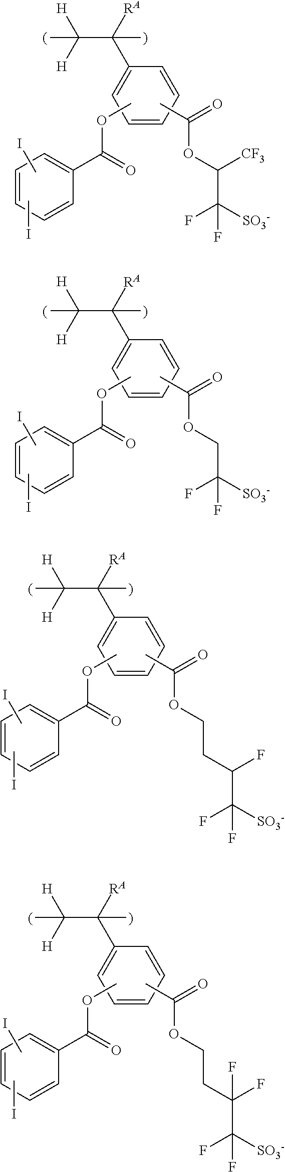

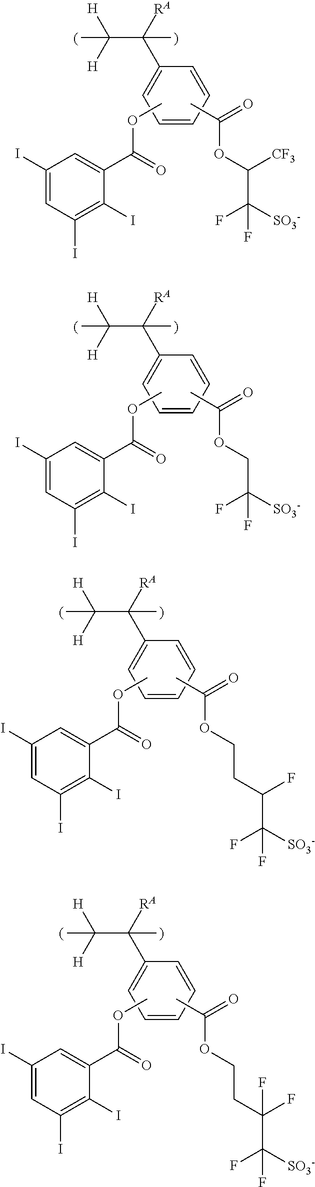

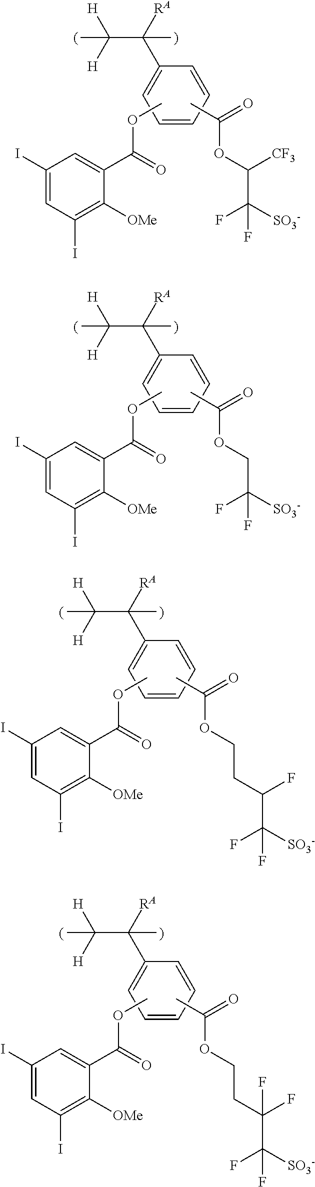

Examples of the anion in repeat unit (6) are given below, but not limited thereto. In the formulae, R^{A} is as defined above.

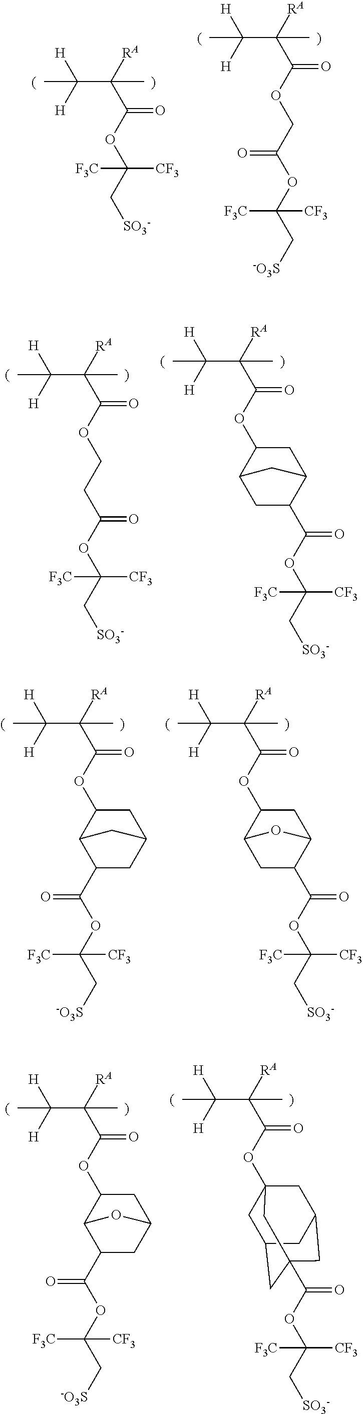

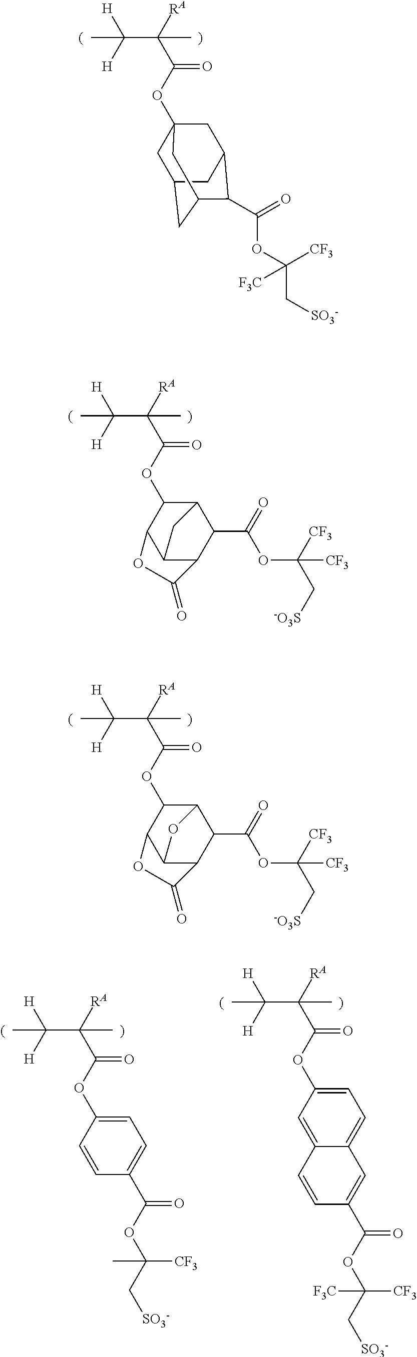

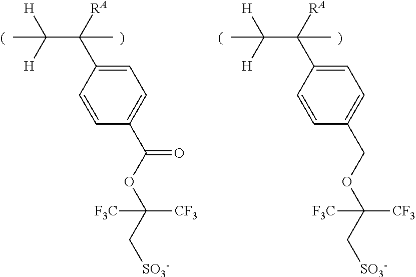

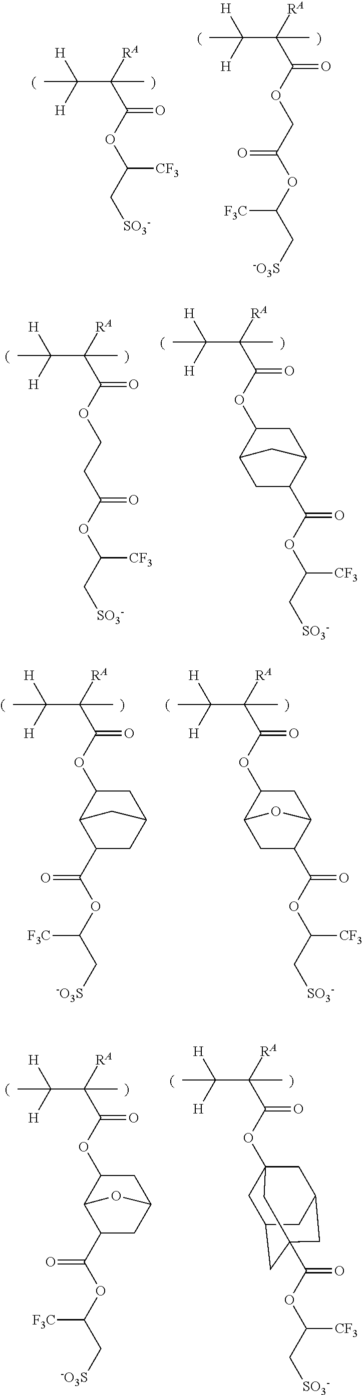

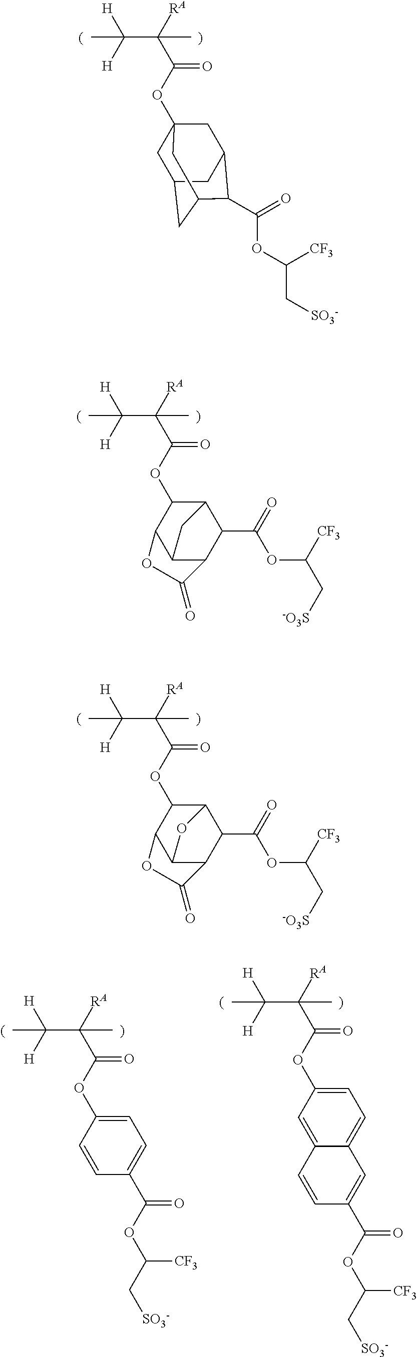

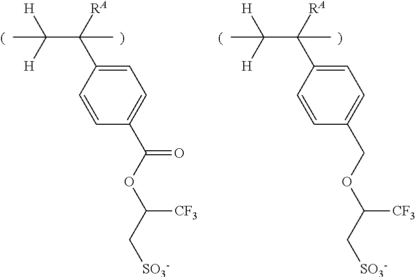

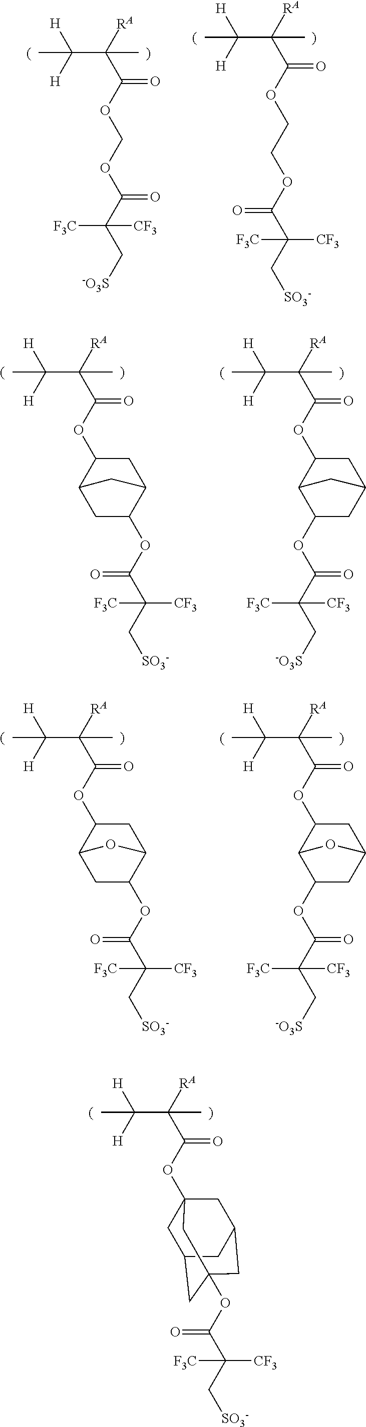

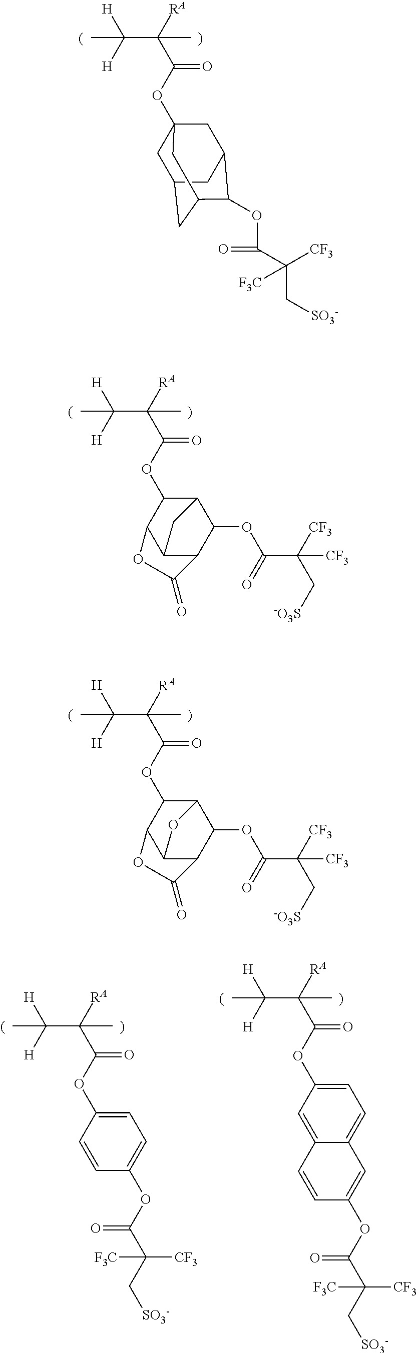

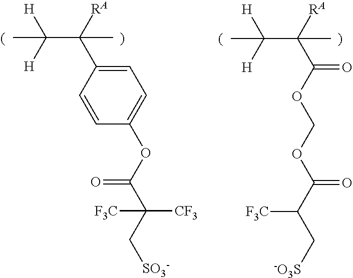

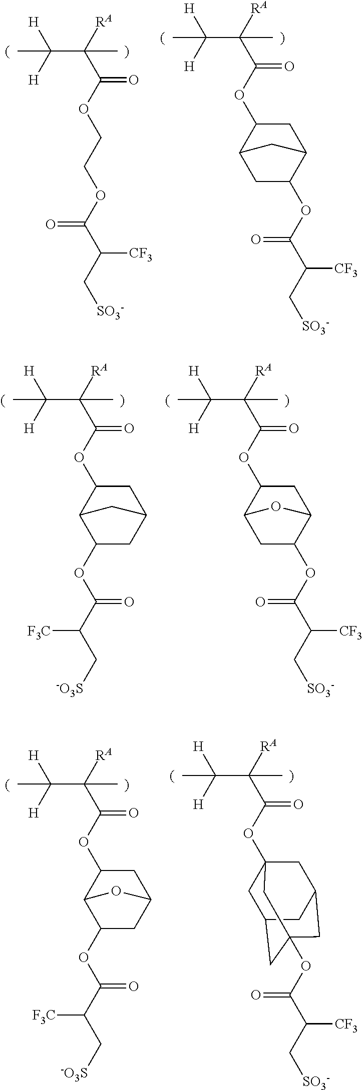

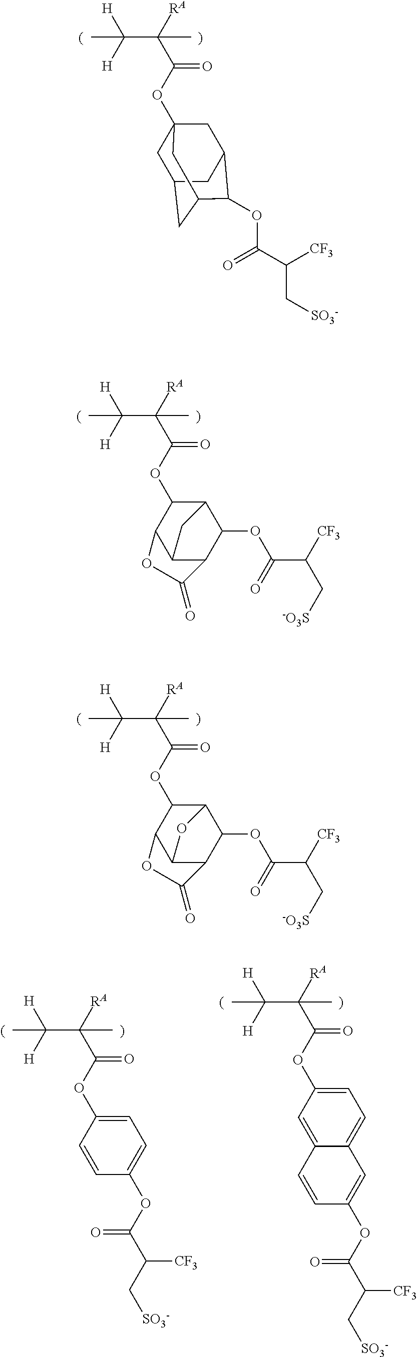

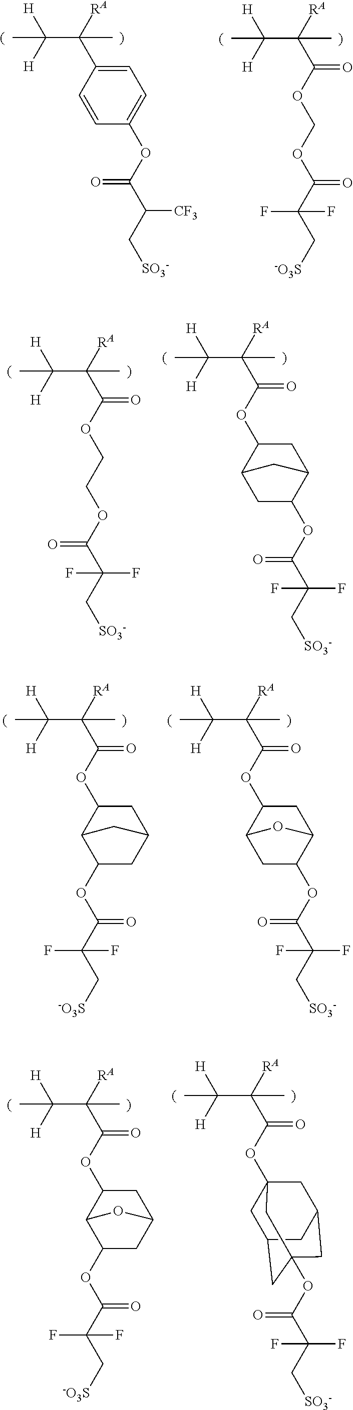

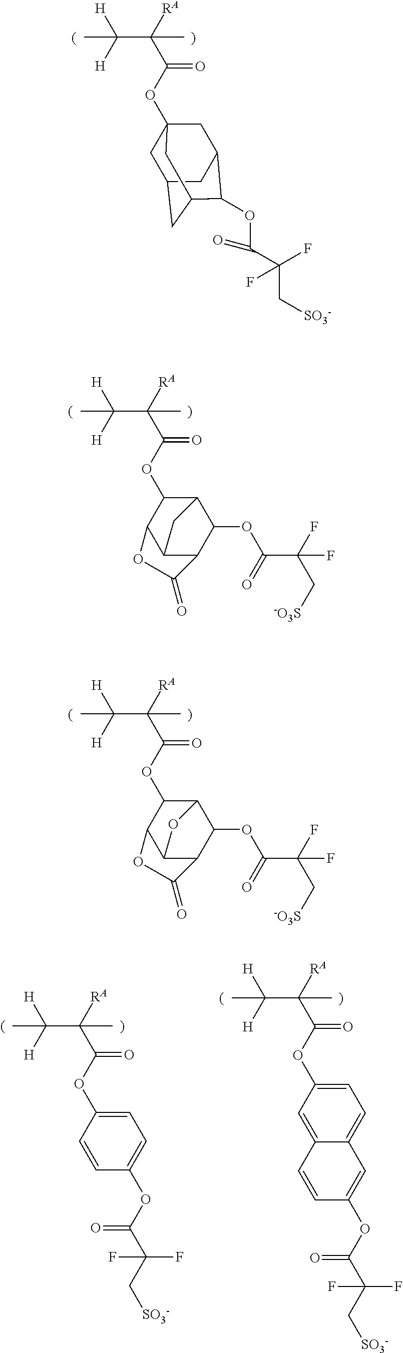

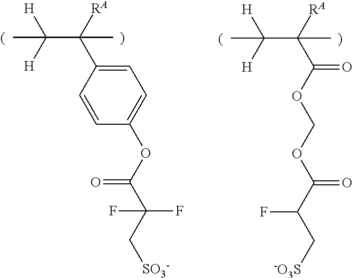

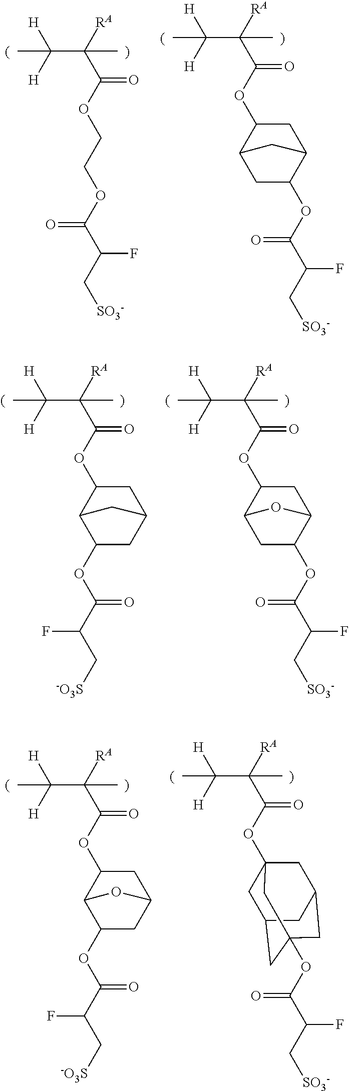

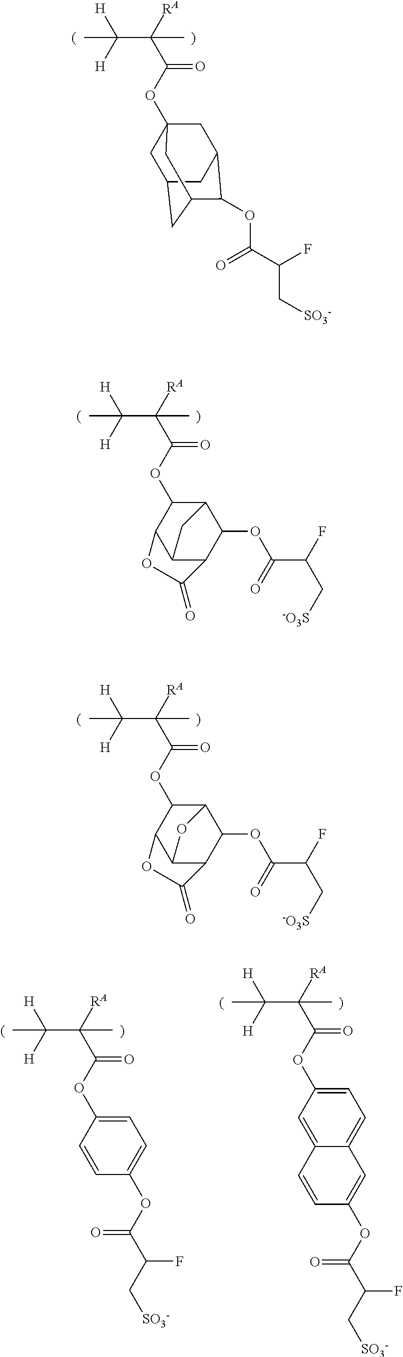

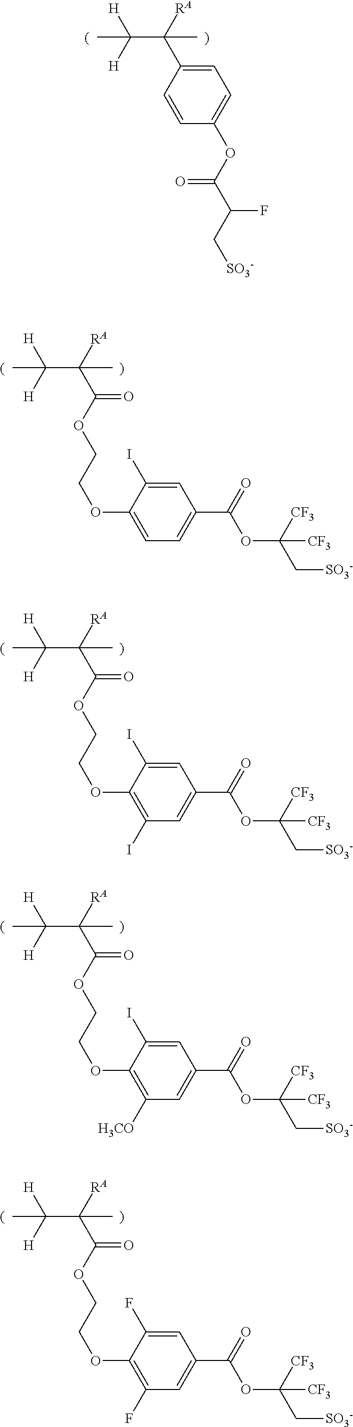

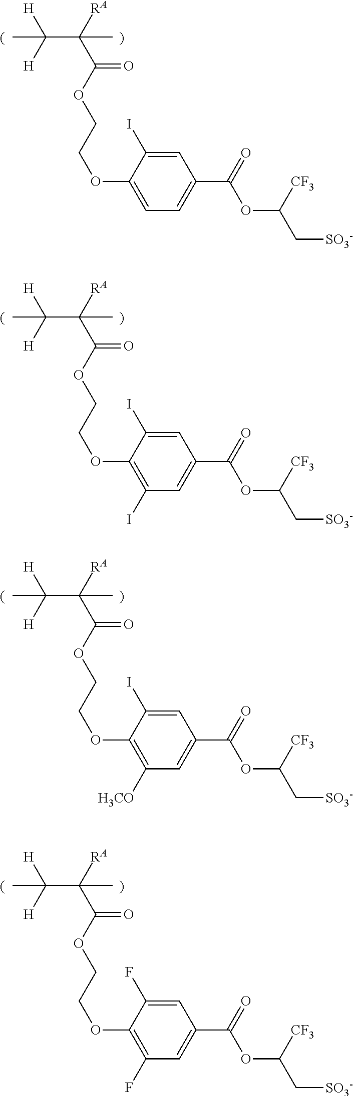

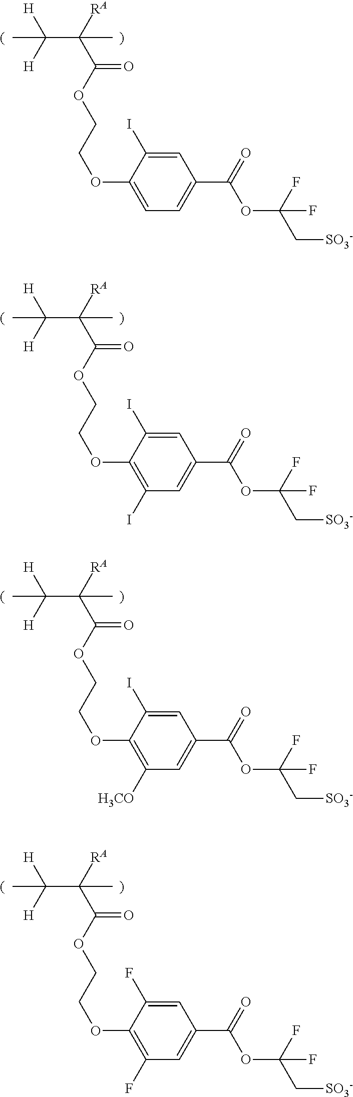

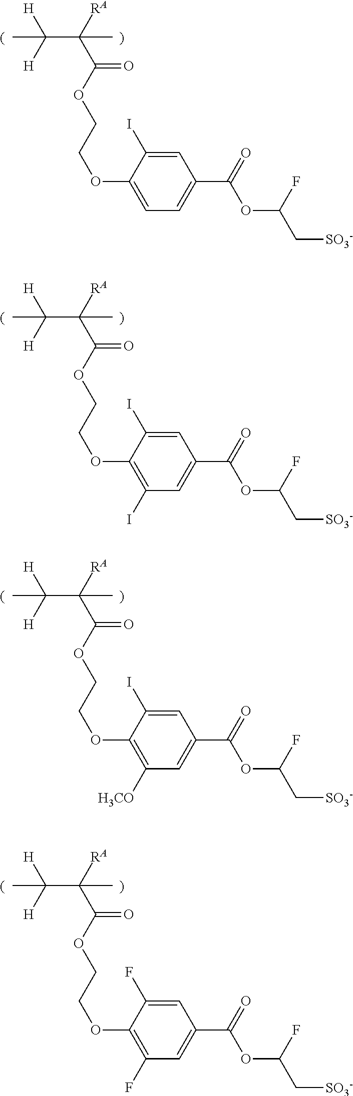

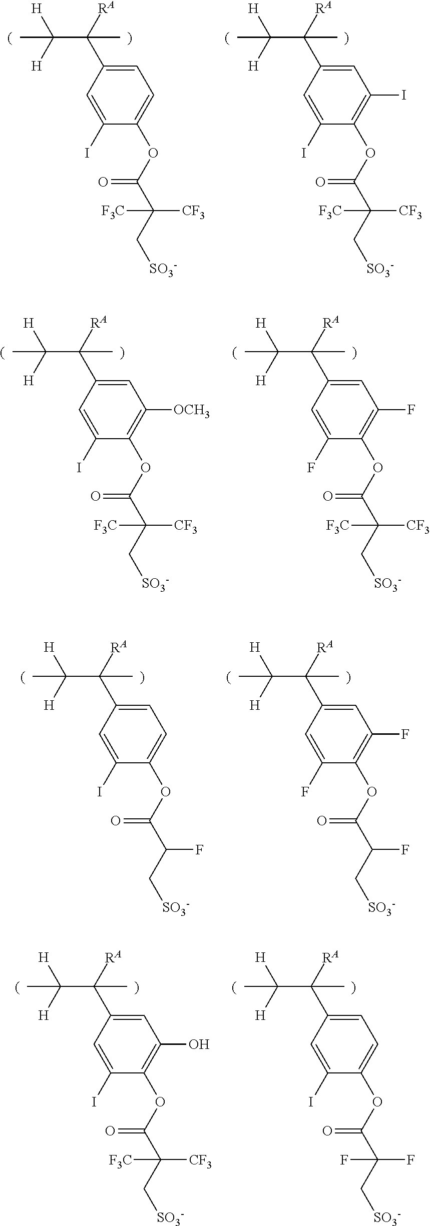

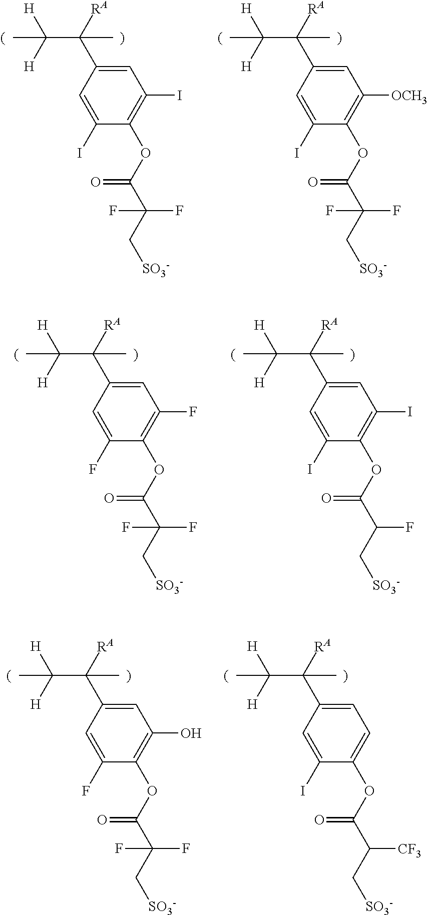

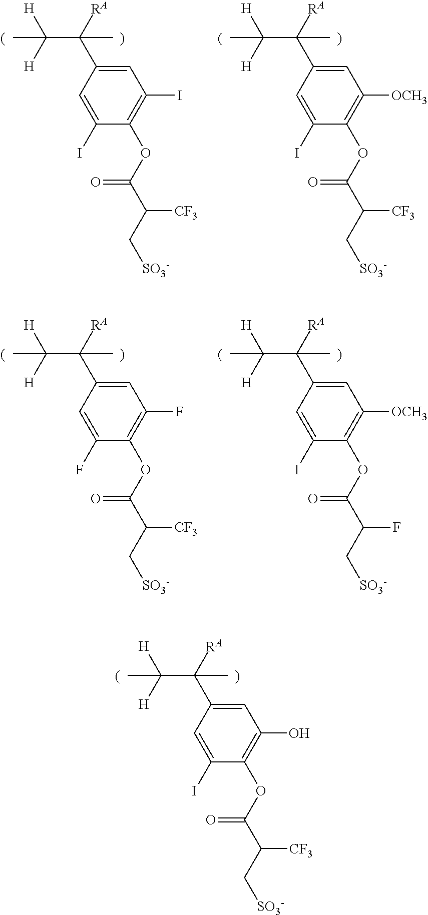

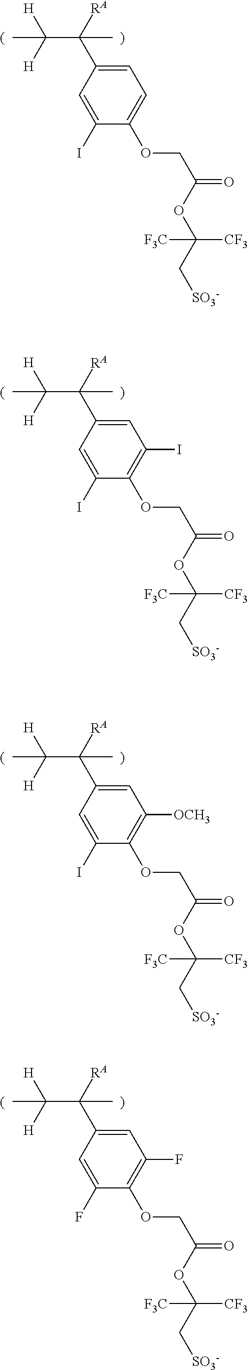

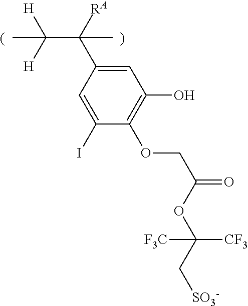

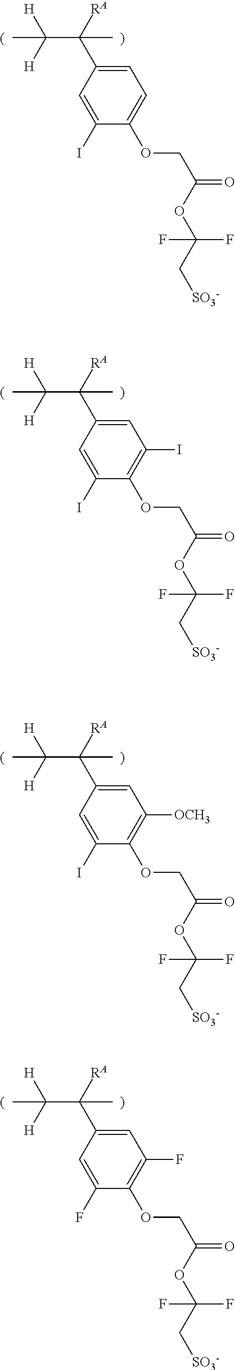

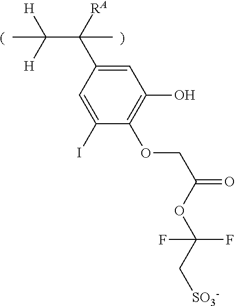

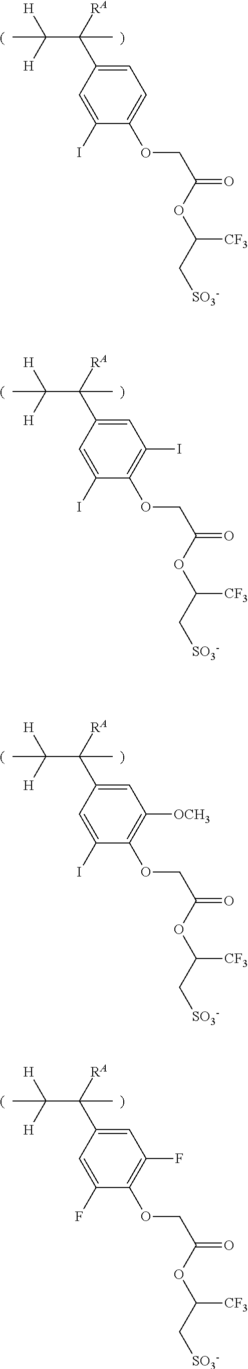

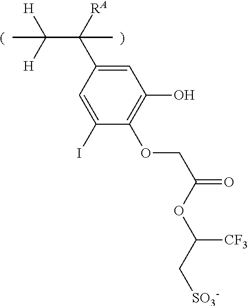

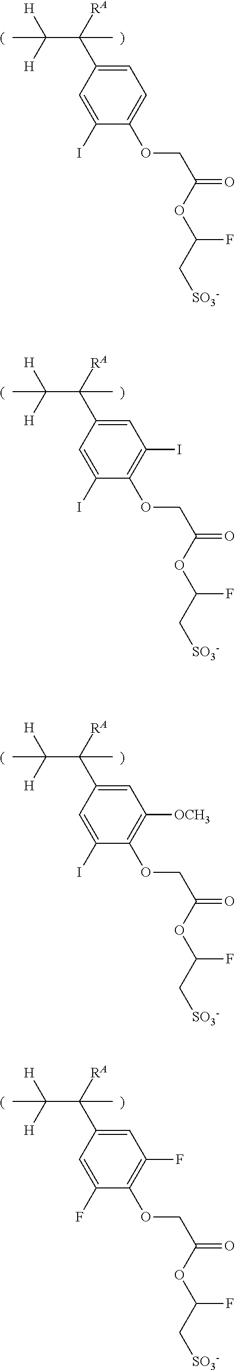

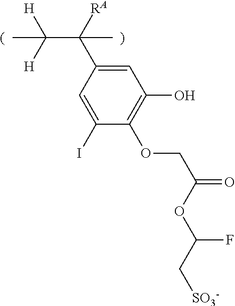

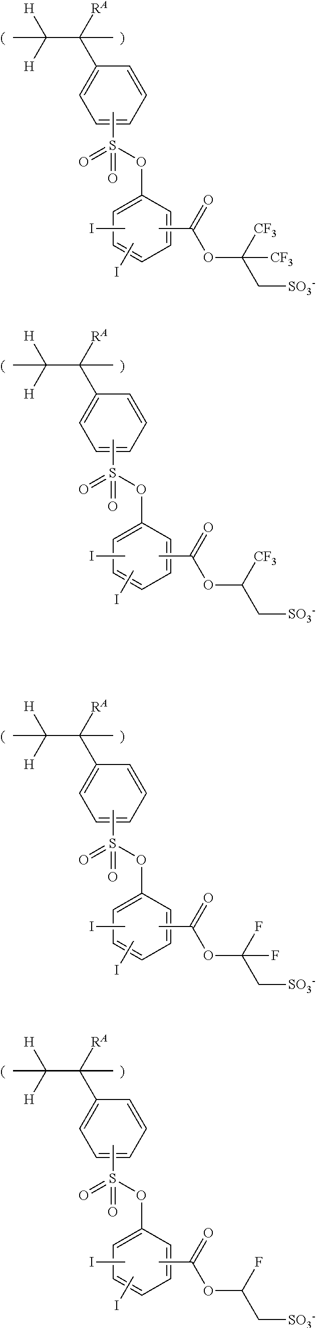

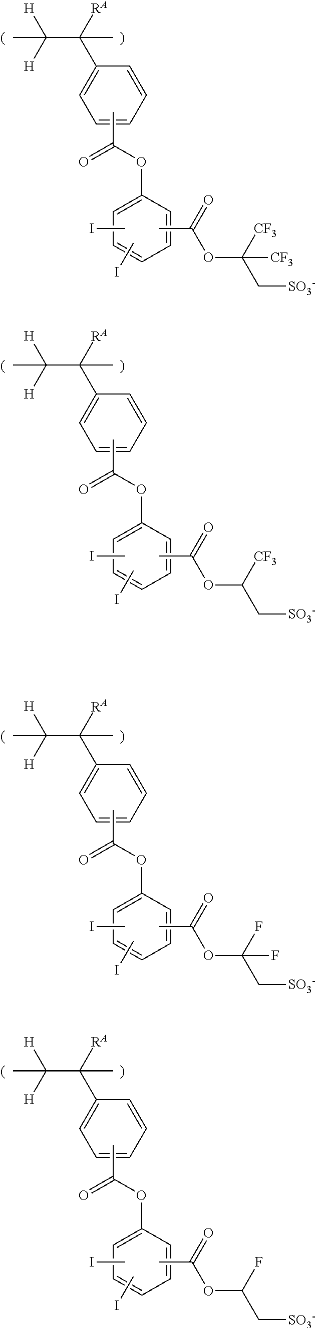

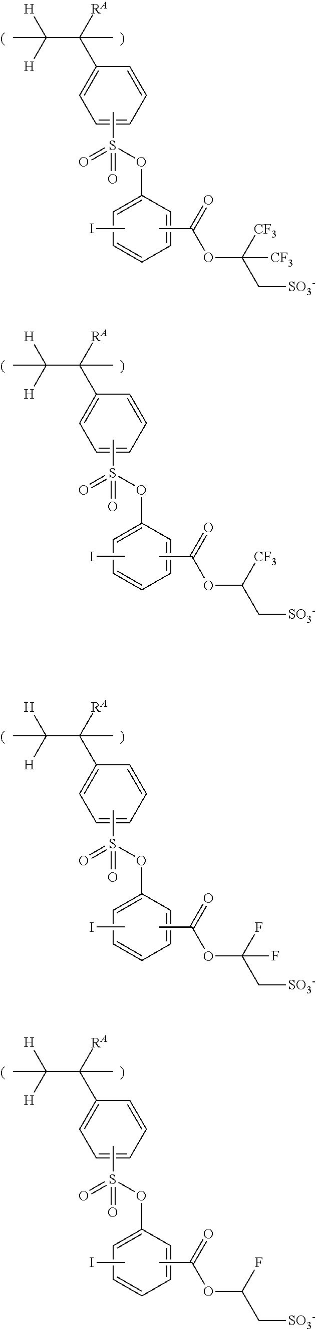

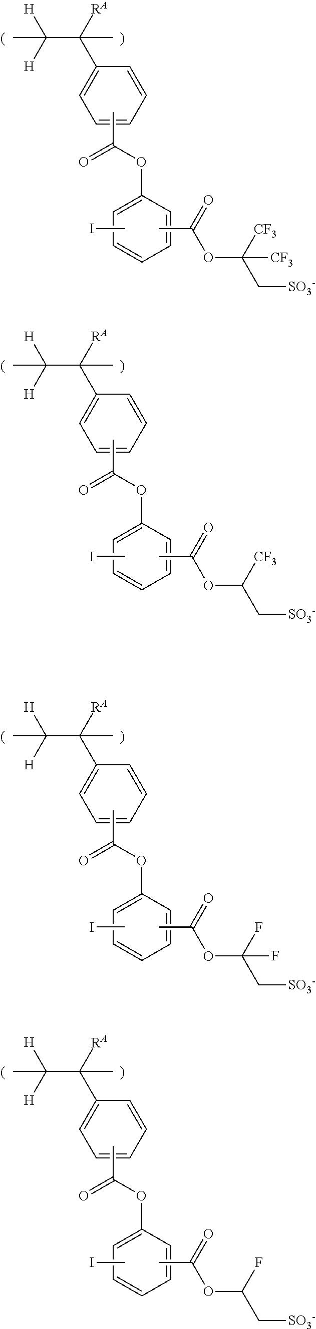

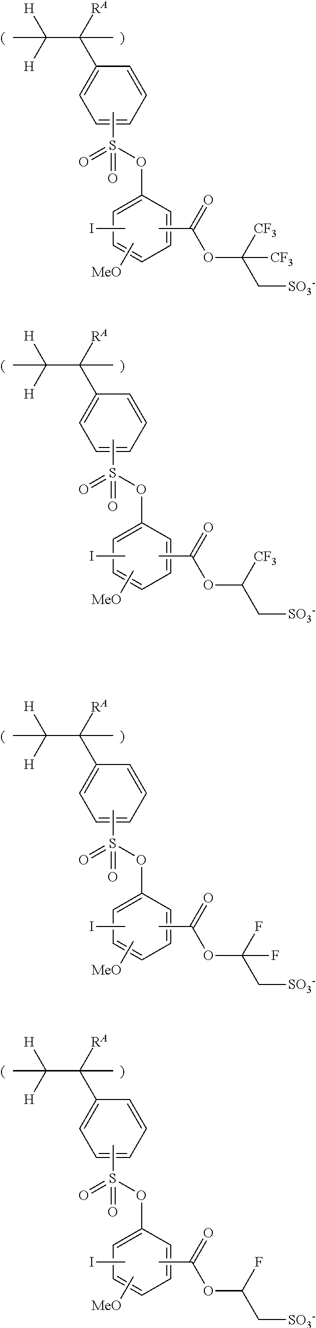

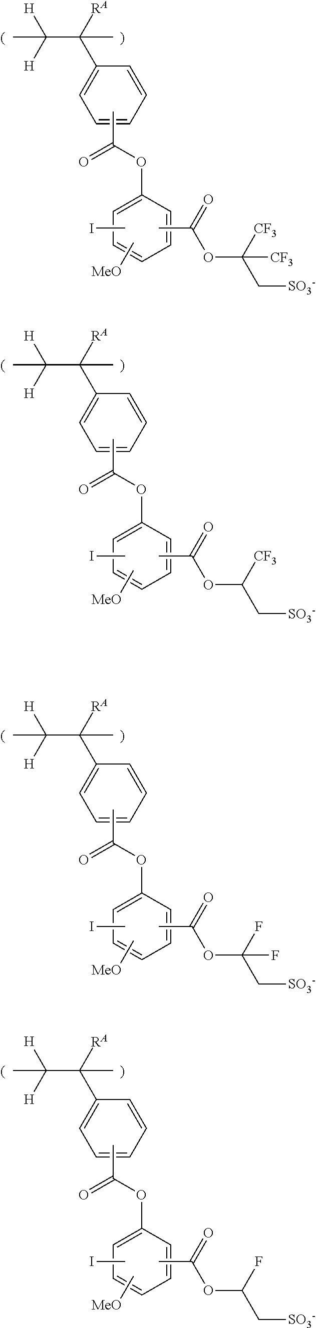

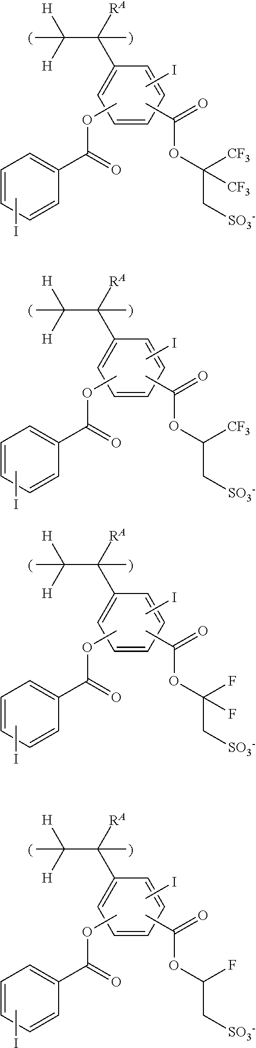

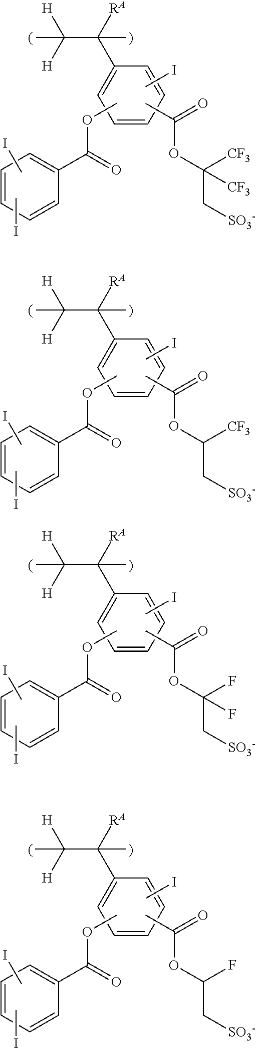

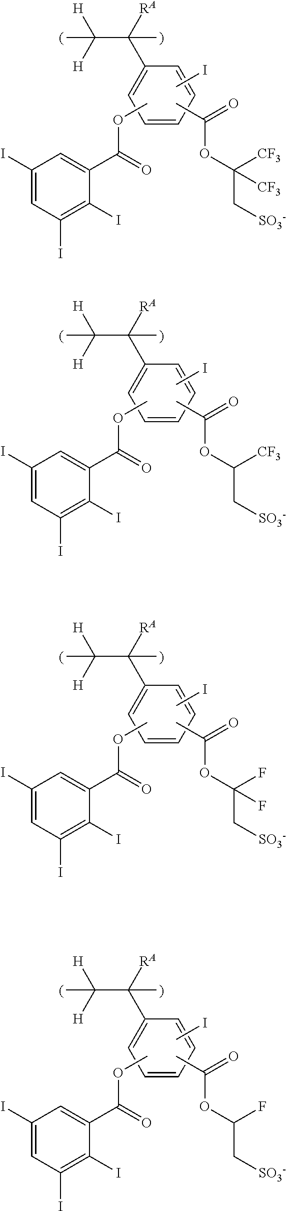

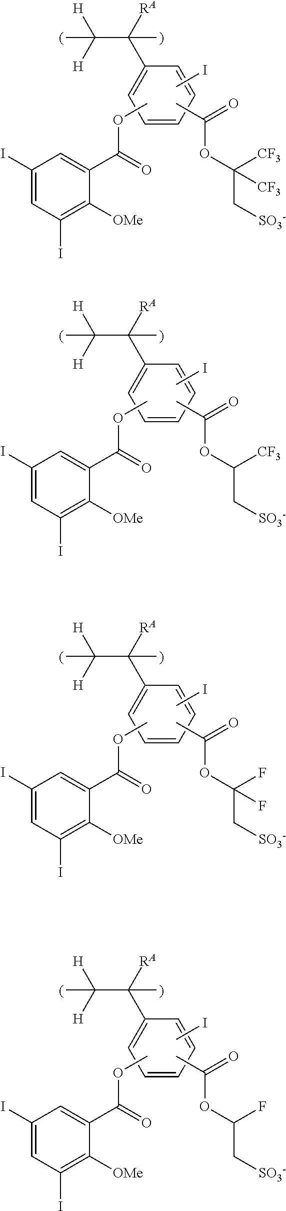

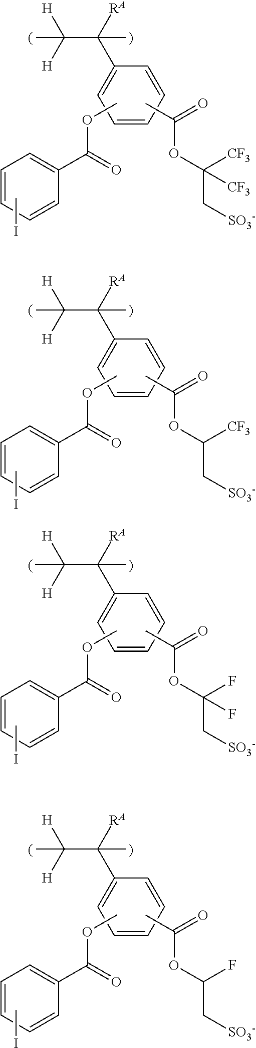

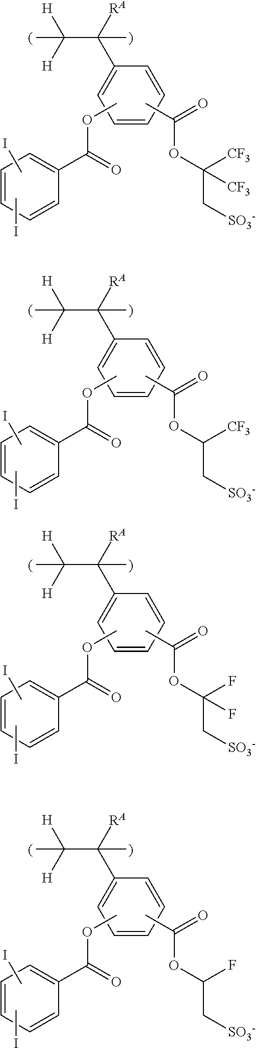

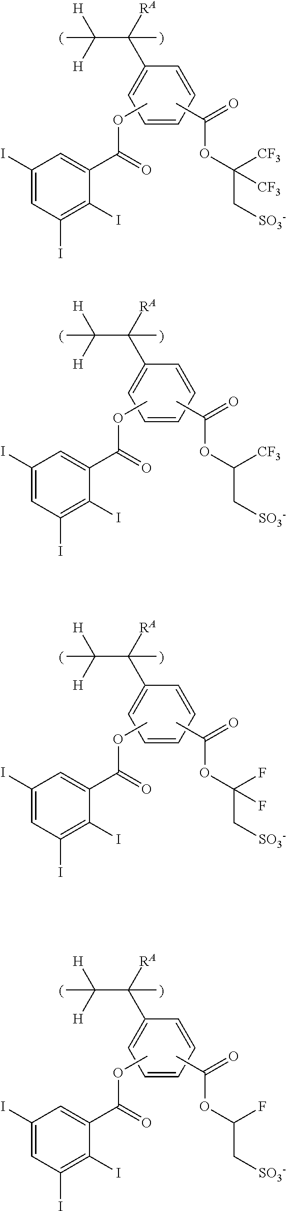

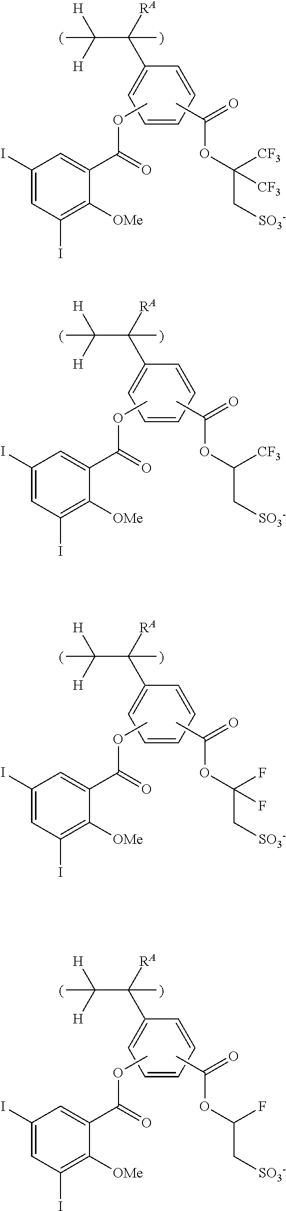

Examples of the anion in repeat unit (c4) are given below, but not limited thereto. In the formulae, R^{A} is as defined above.

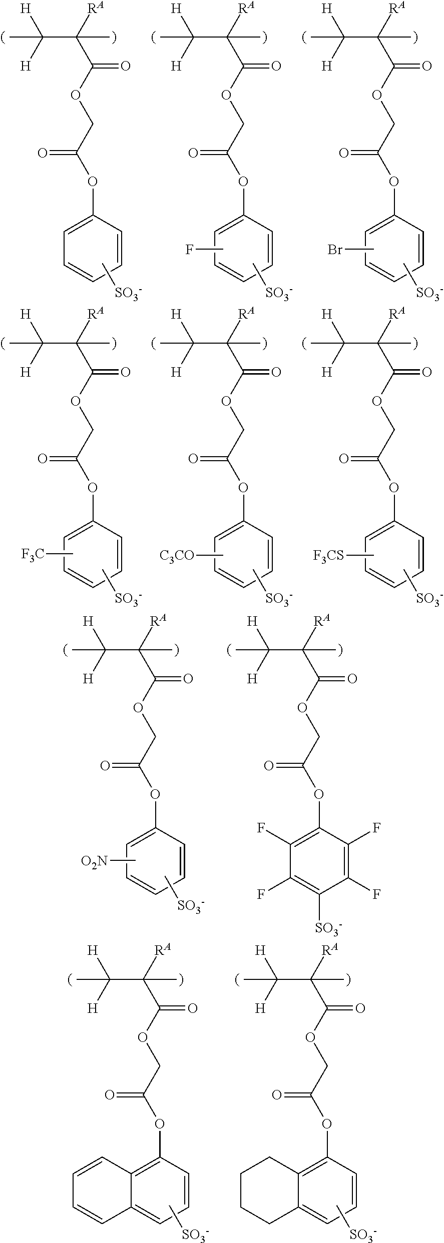

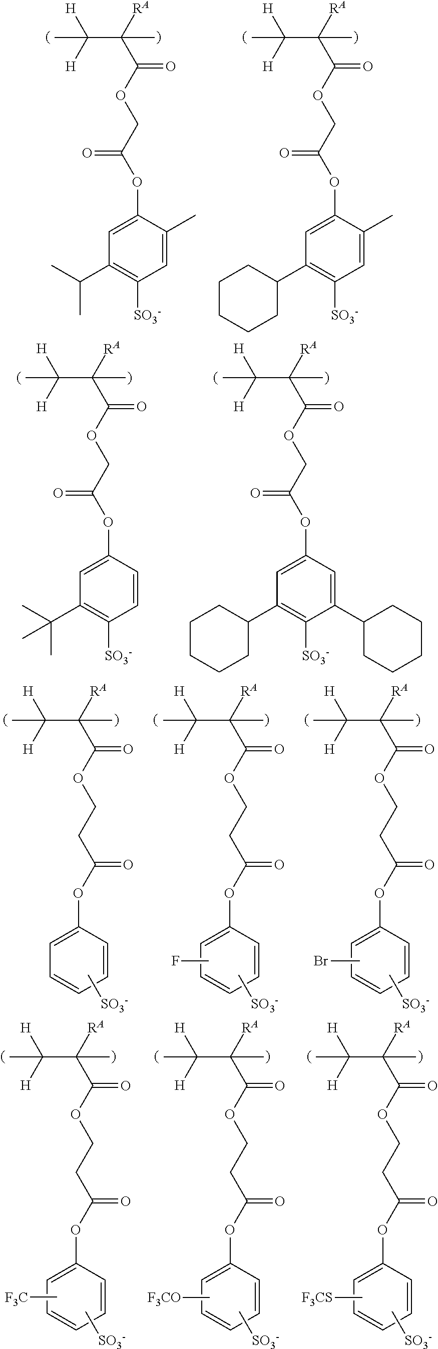

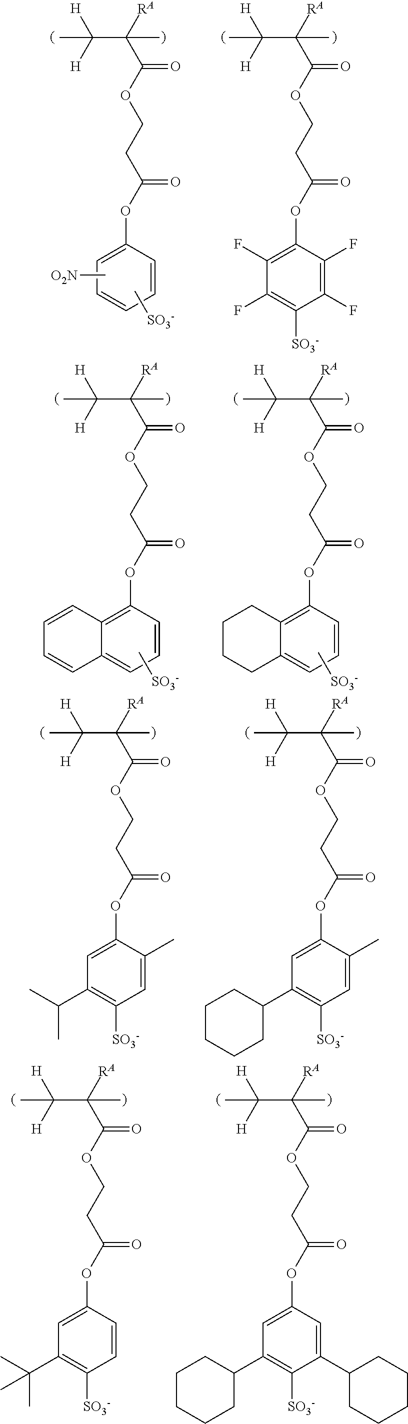

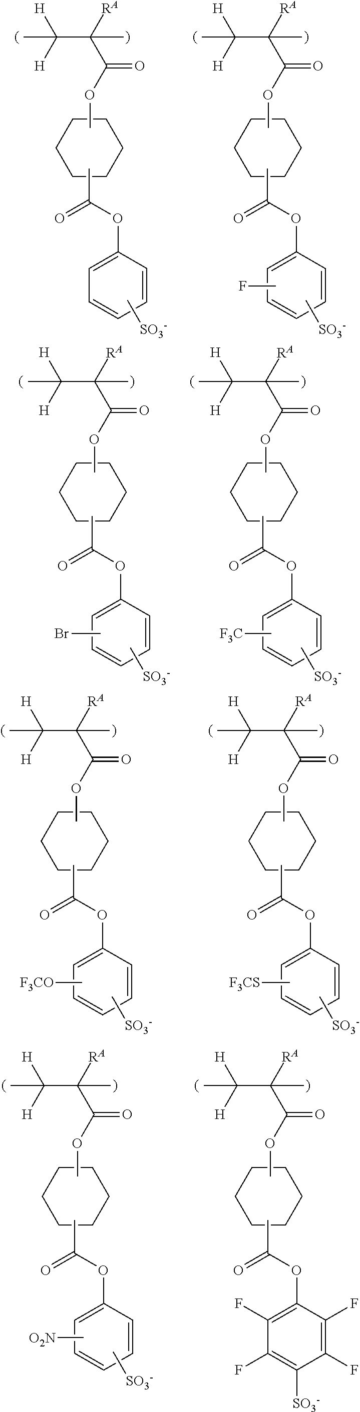

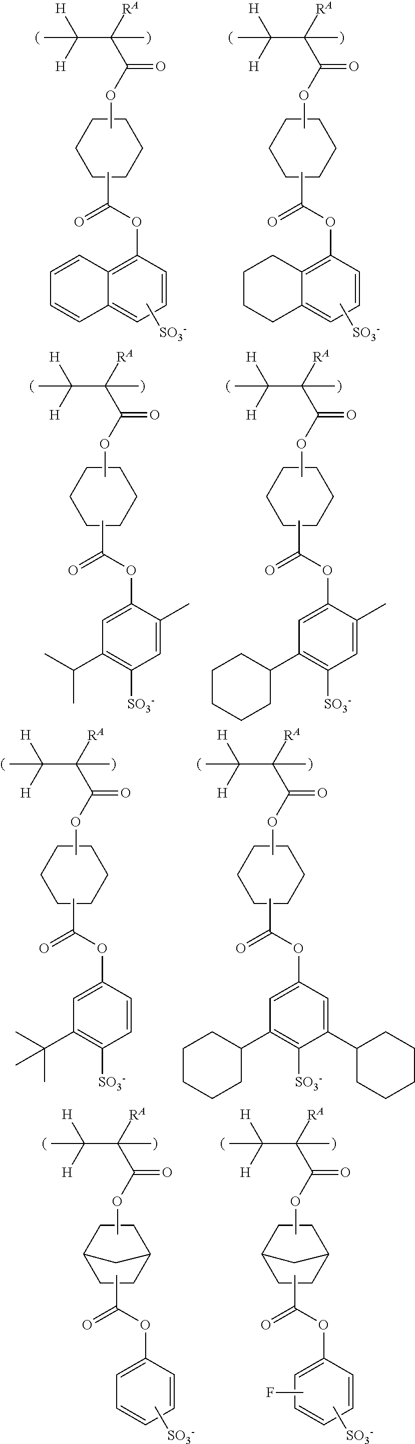

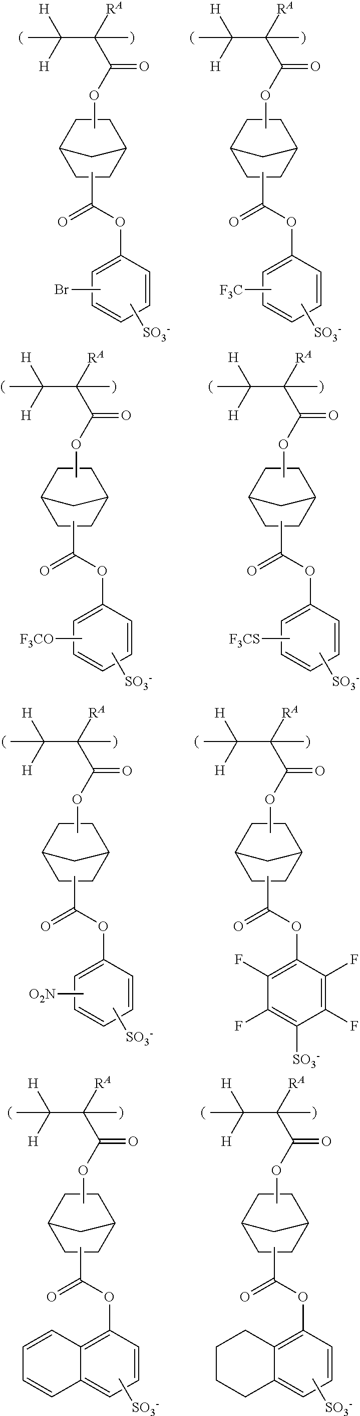

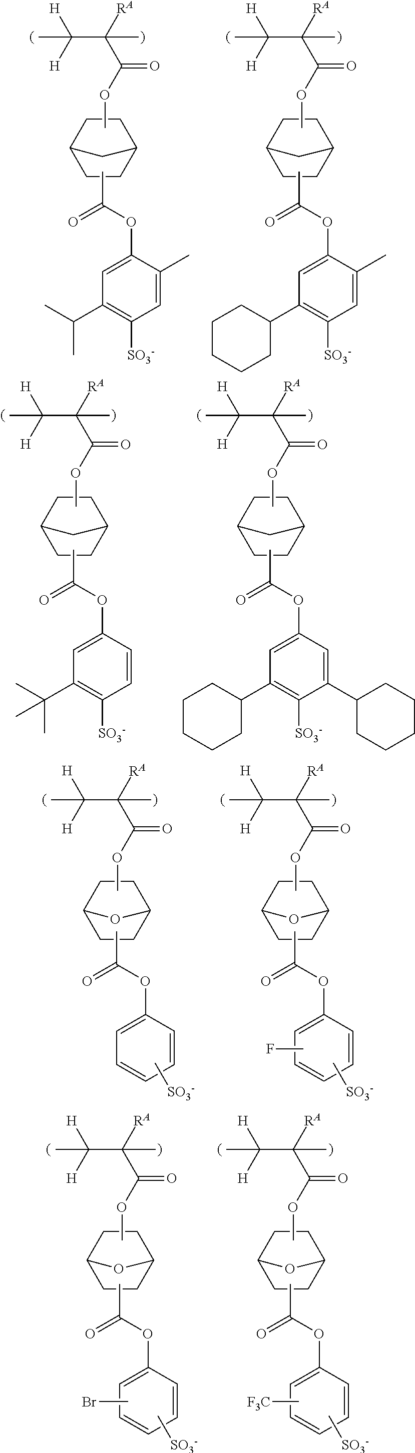

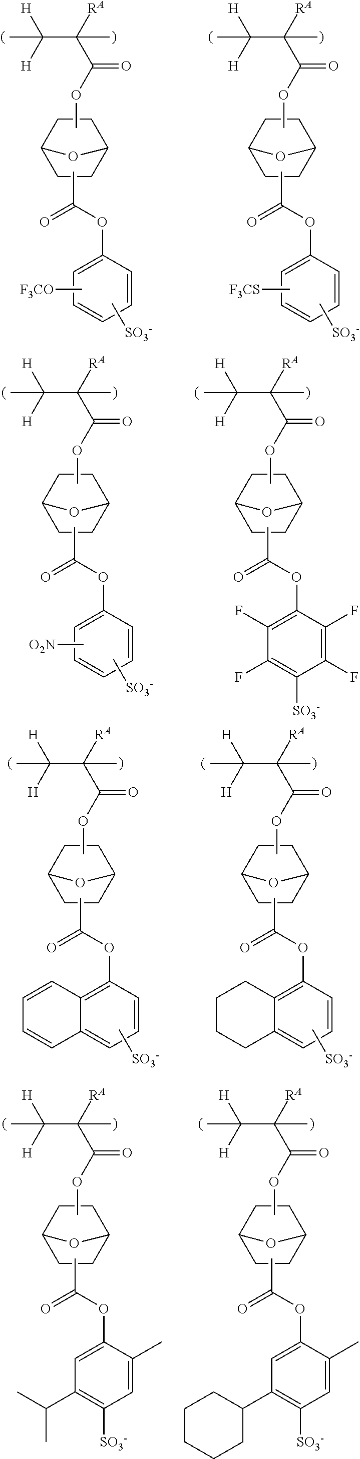

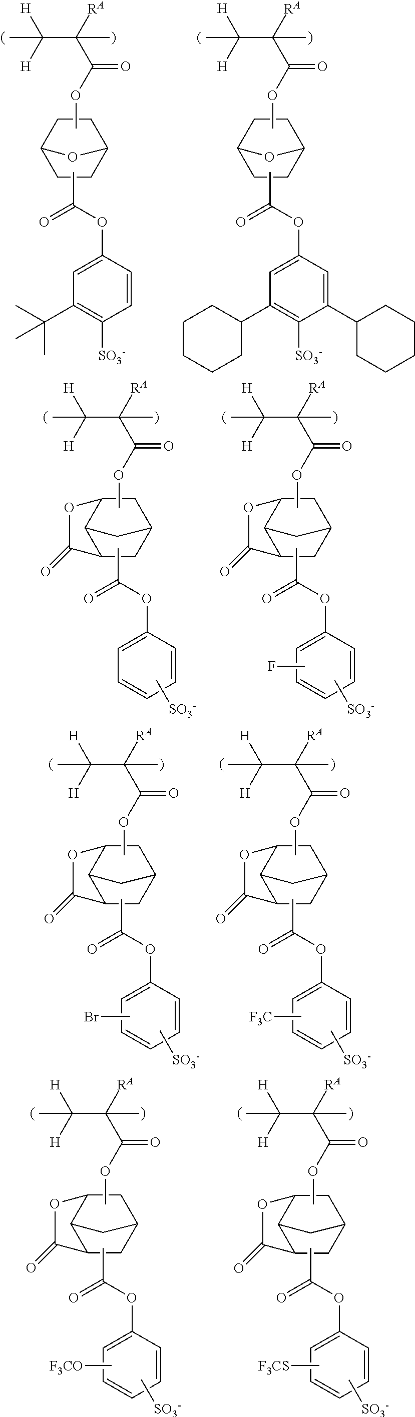

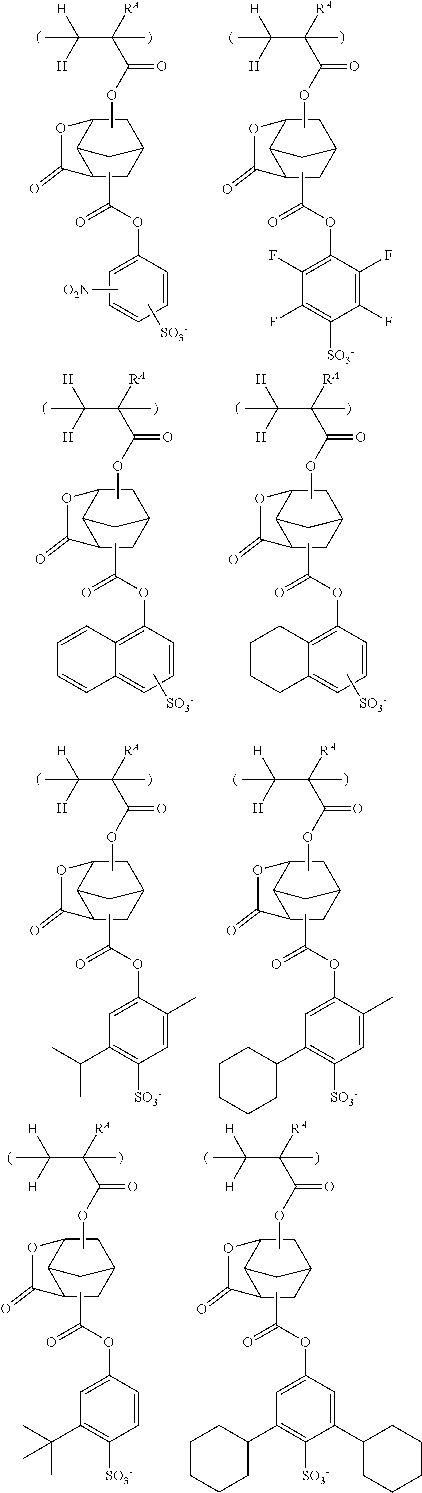

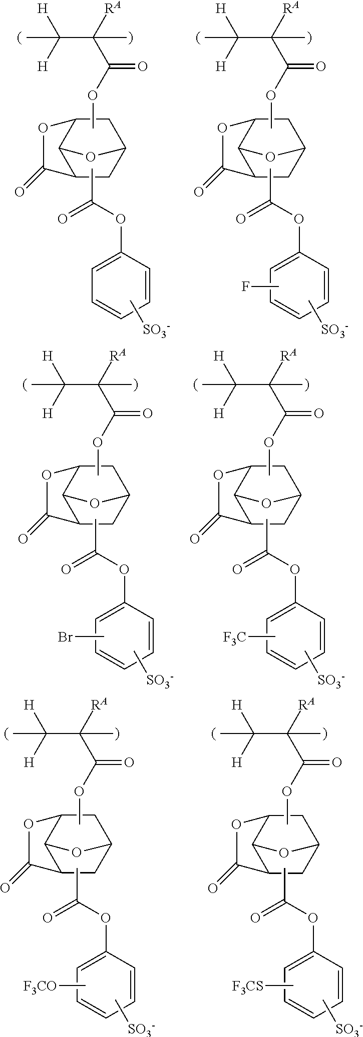

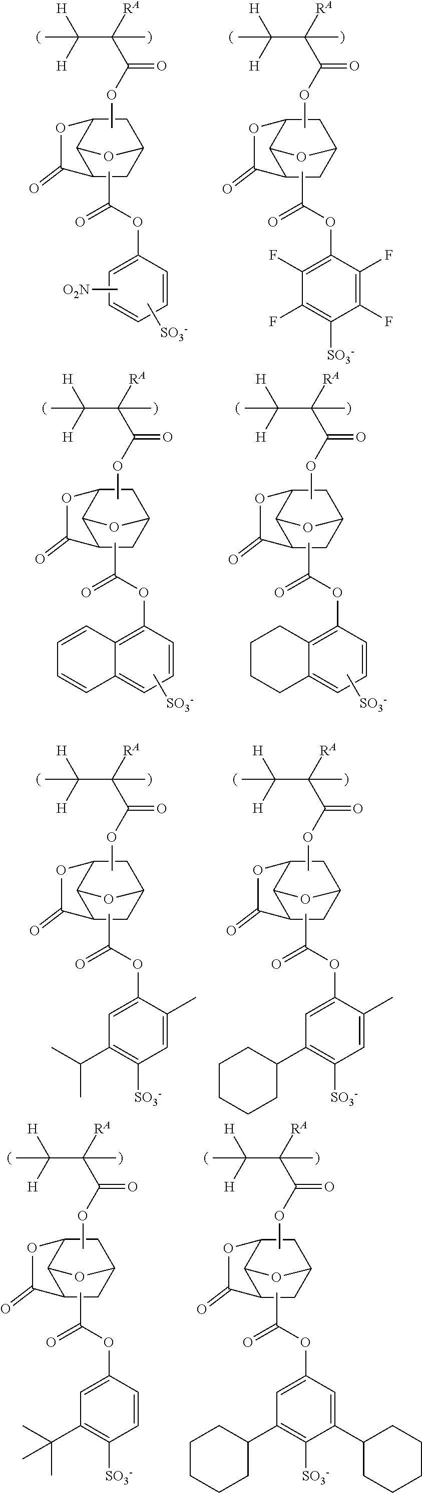

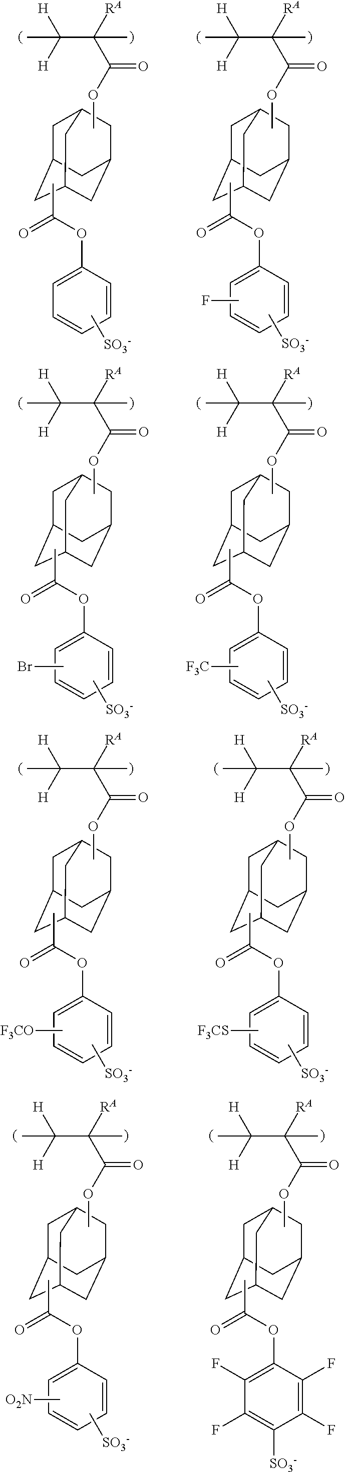

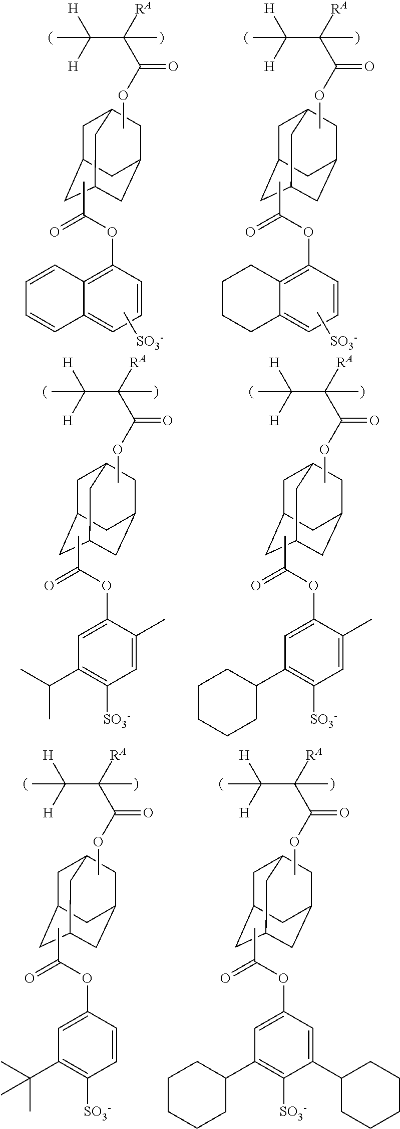

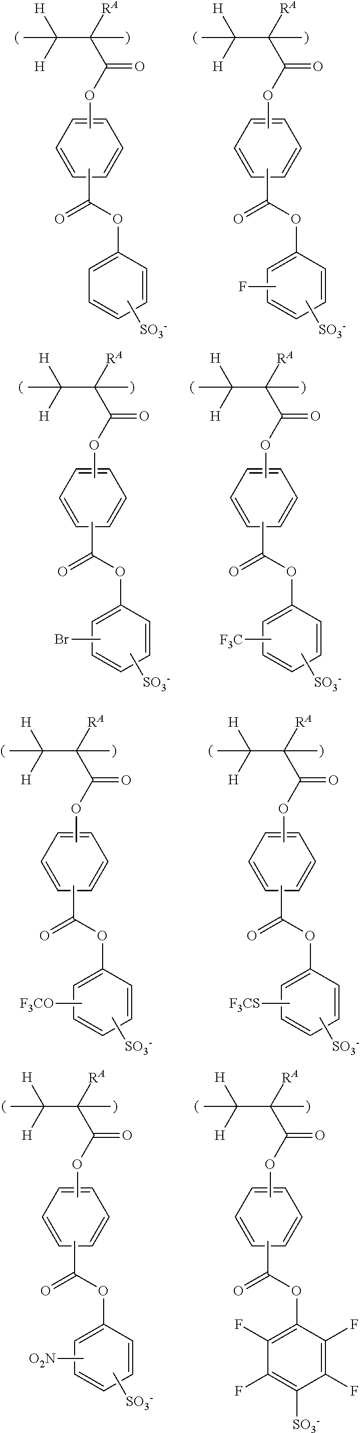

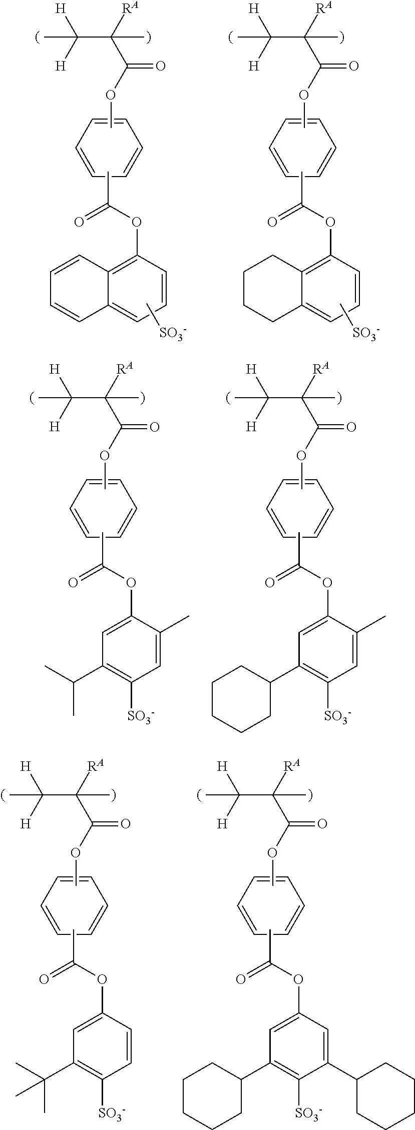

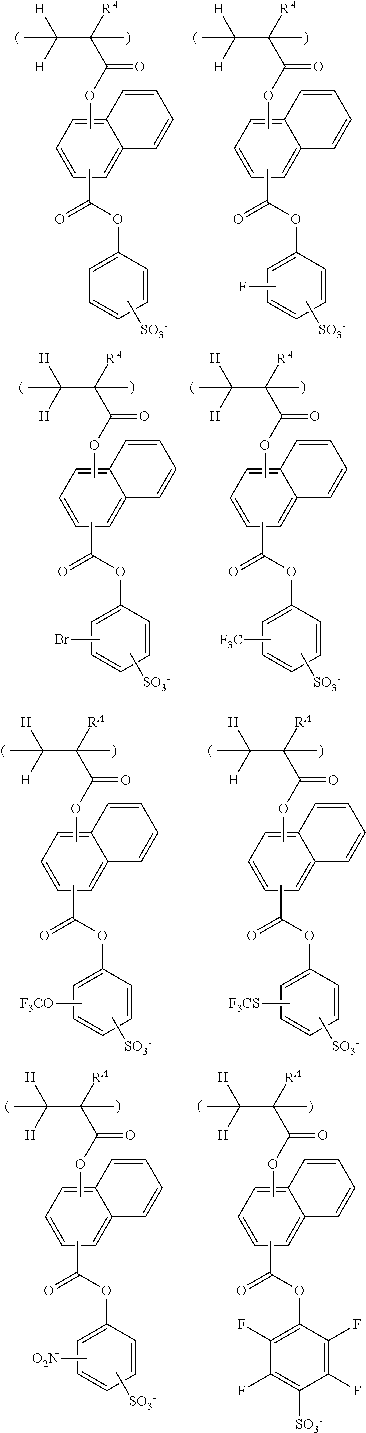

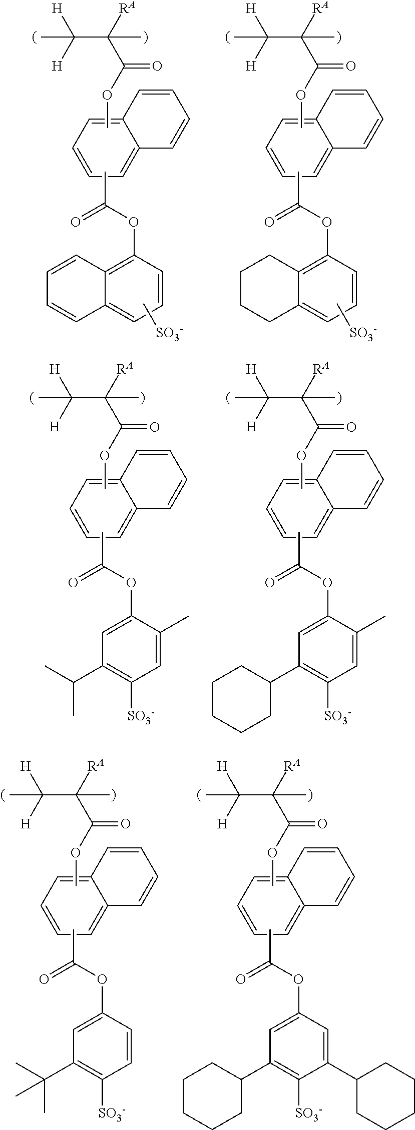

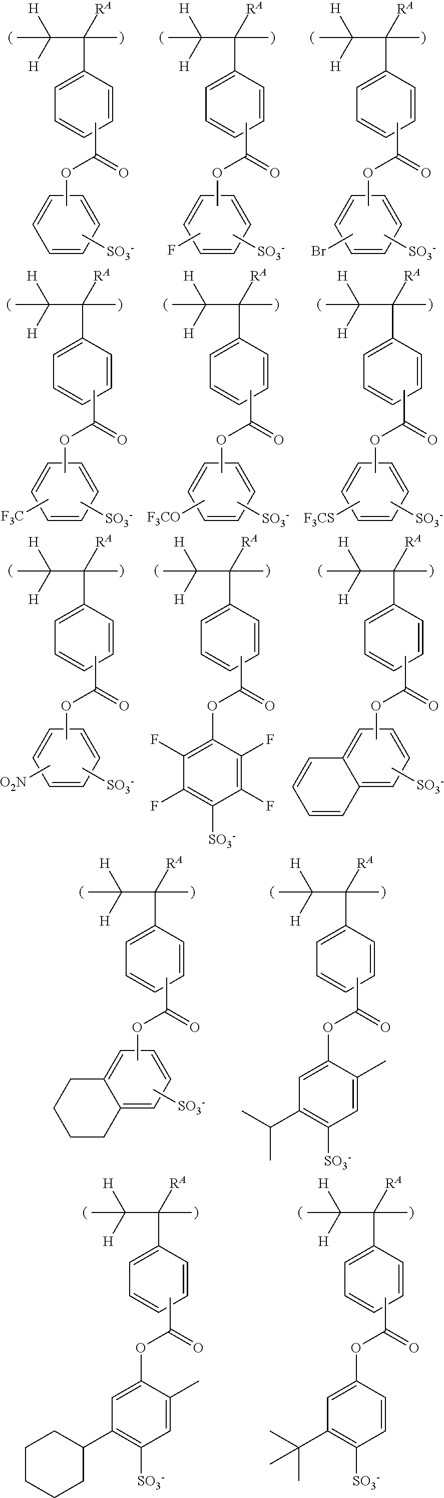

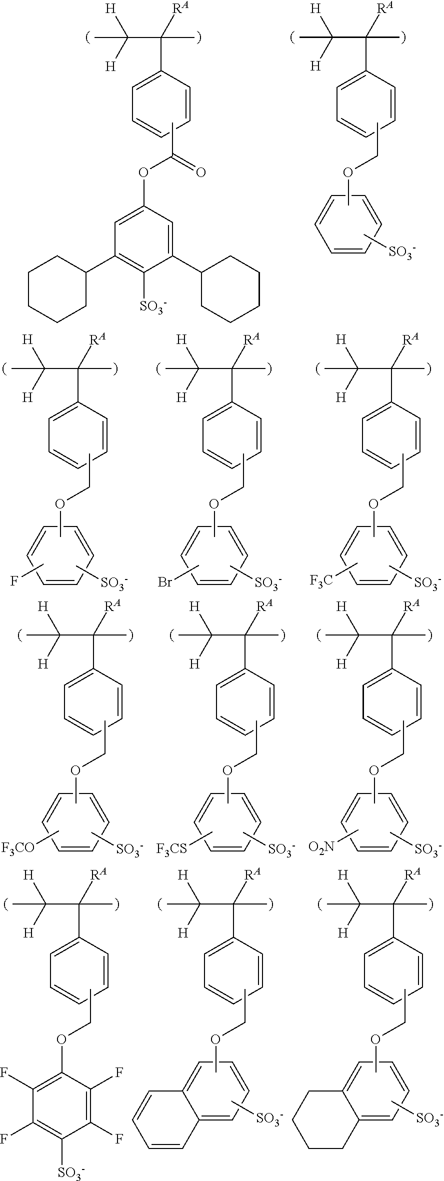

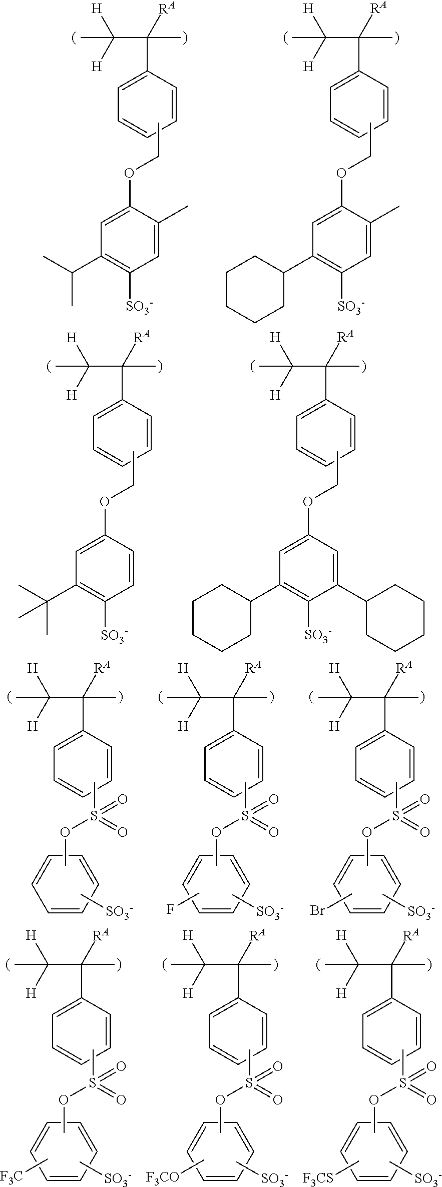

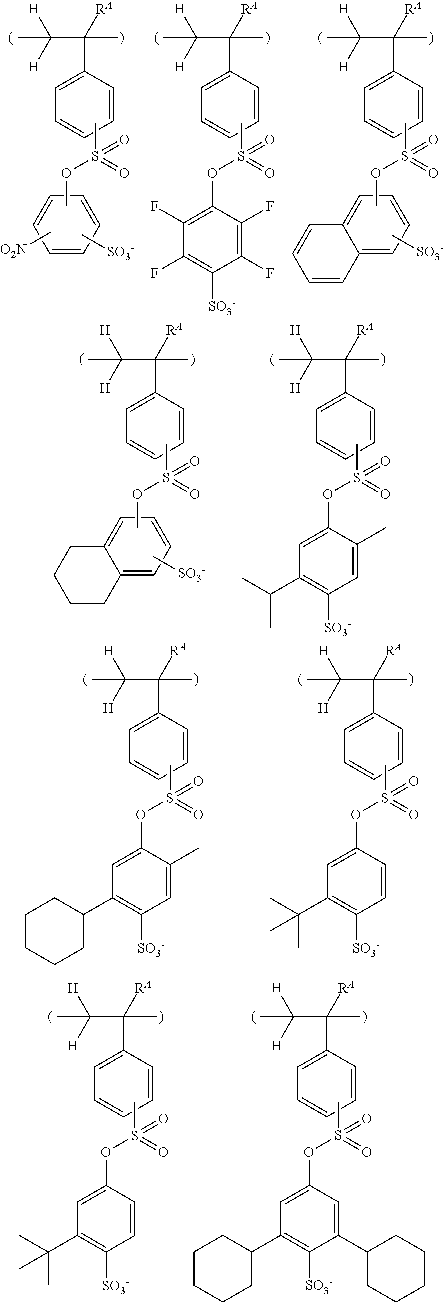

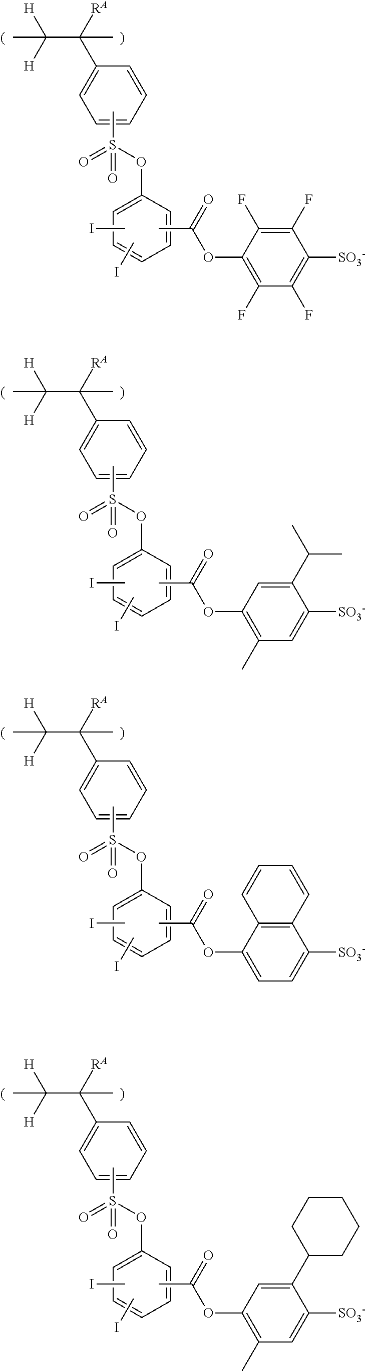

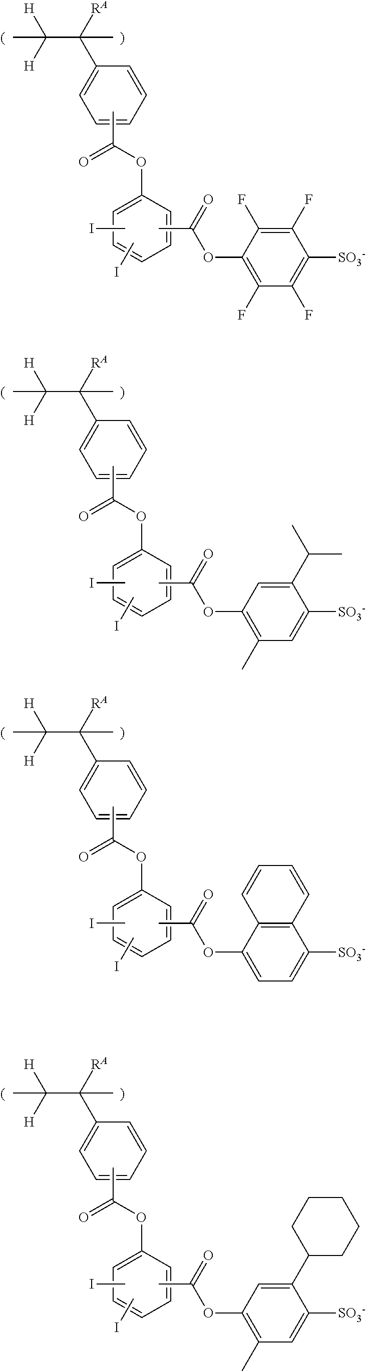

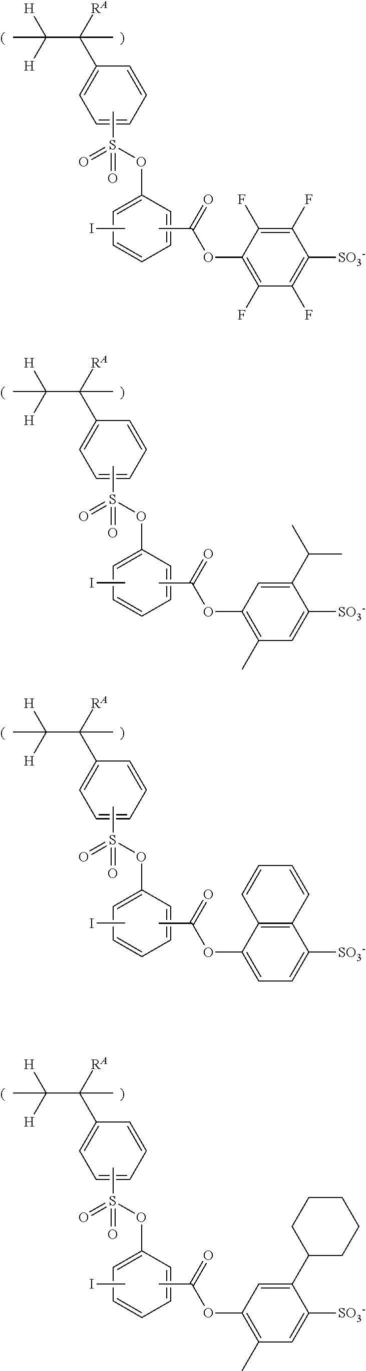

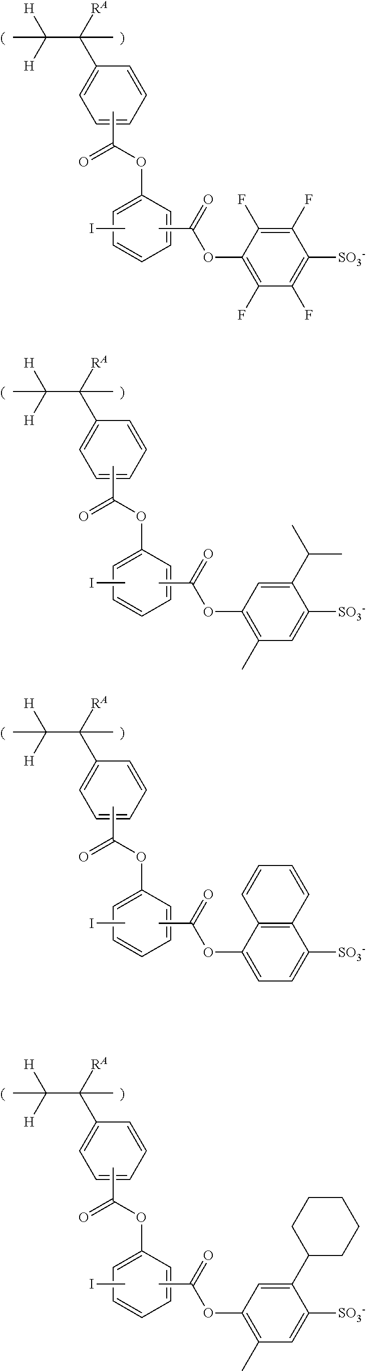

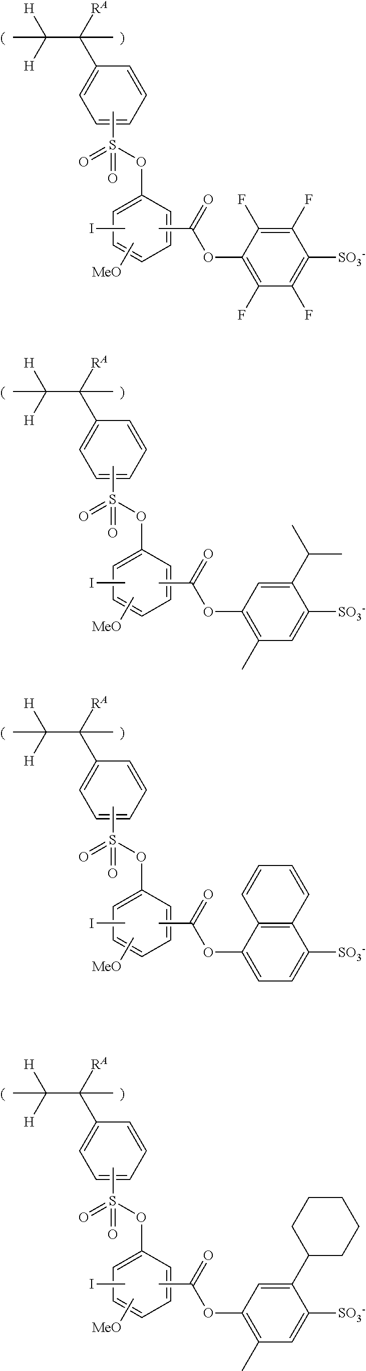

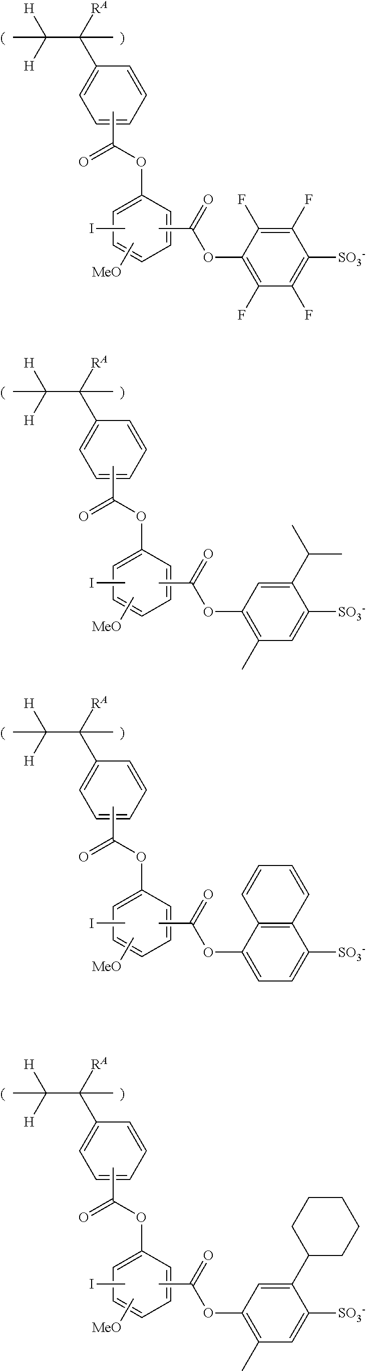

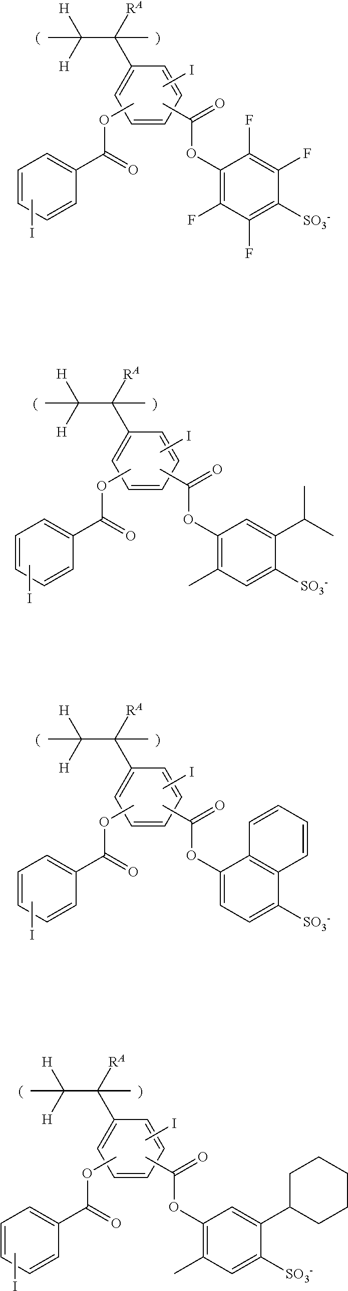

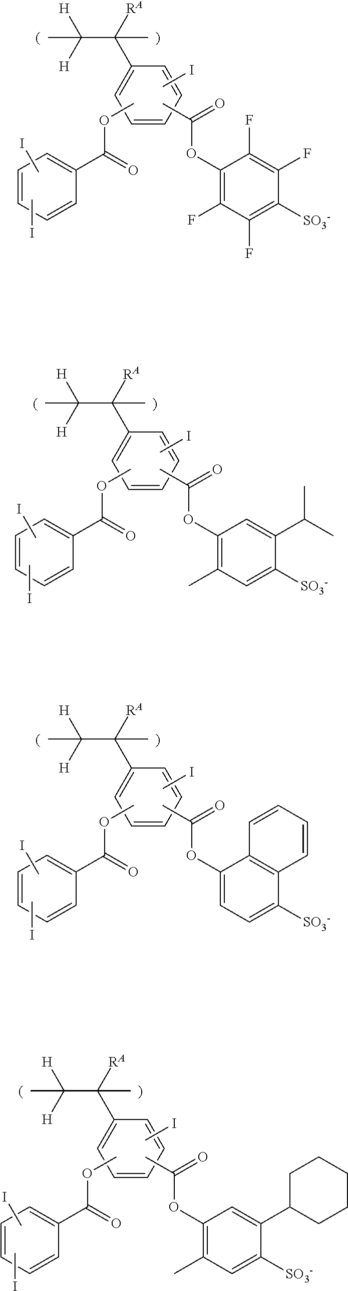

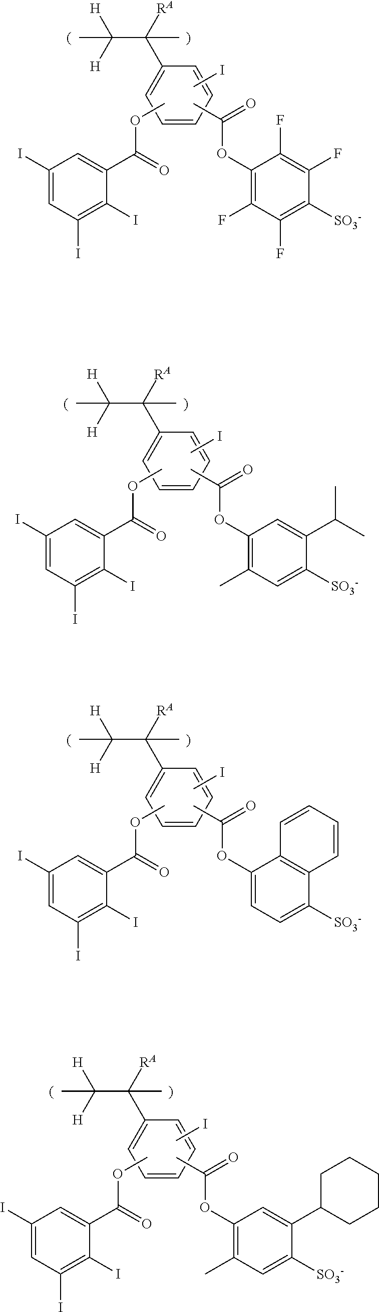

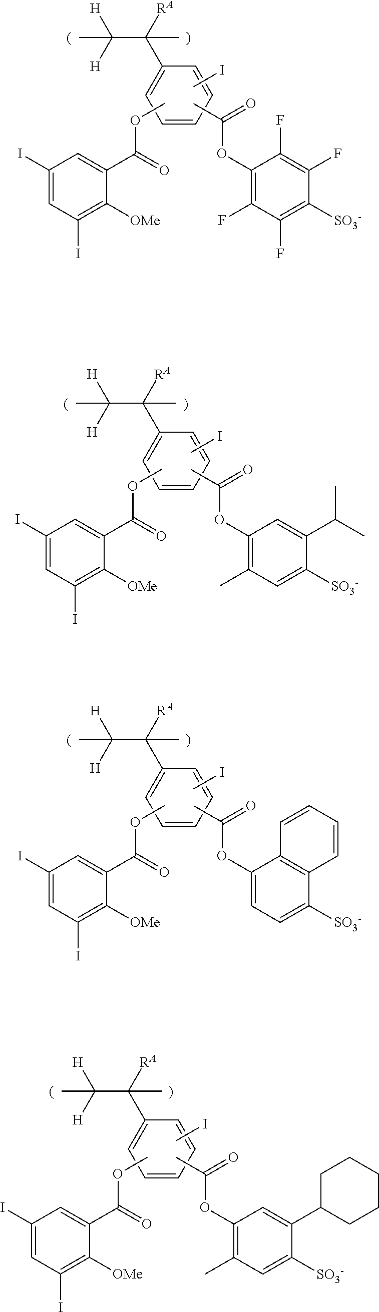

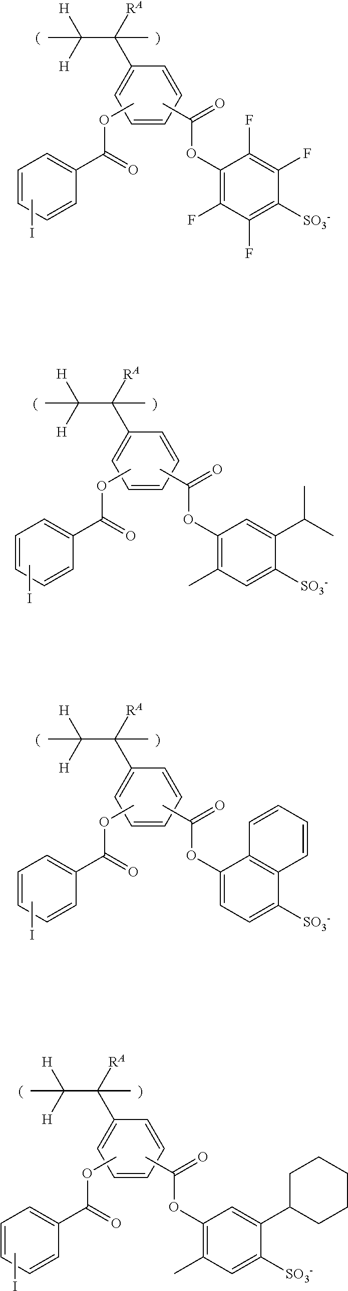

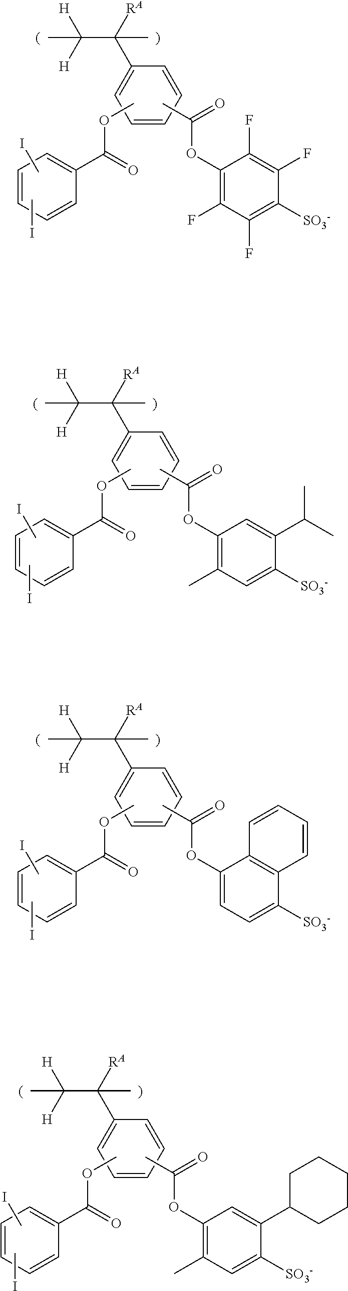

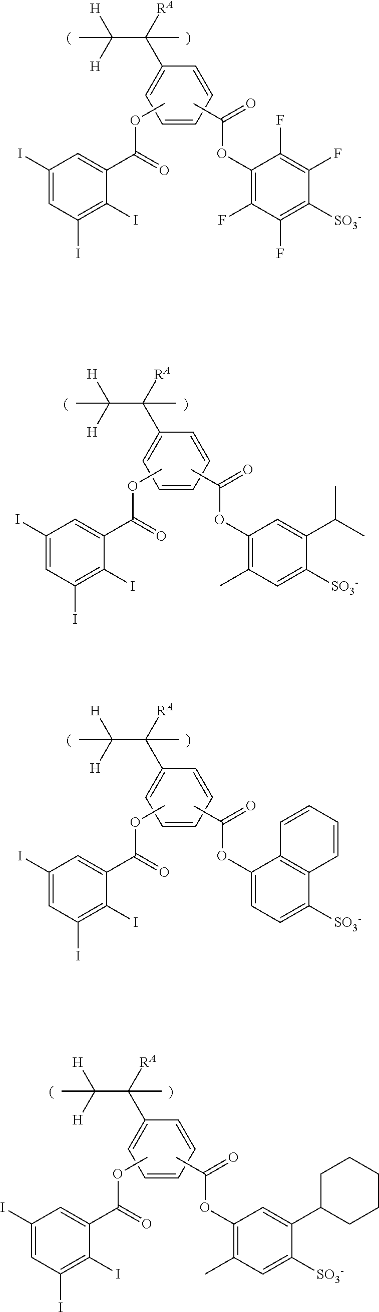

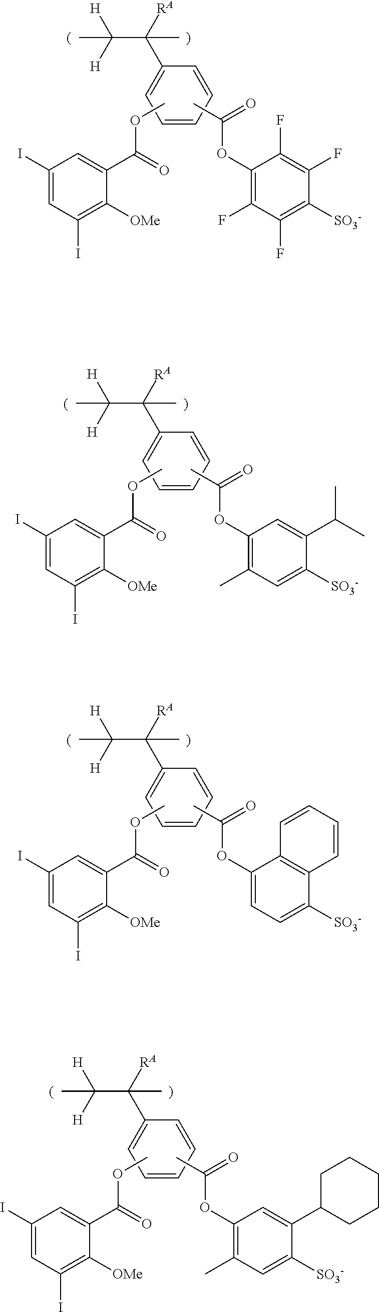

Examples of the anion in repeat unit (c5) are given below, but not limited thereto. In the formulae, R^{A} is as defined above.

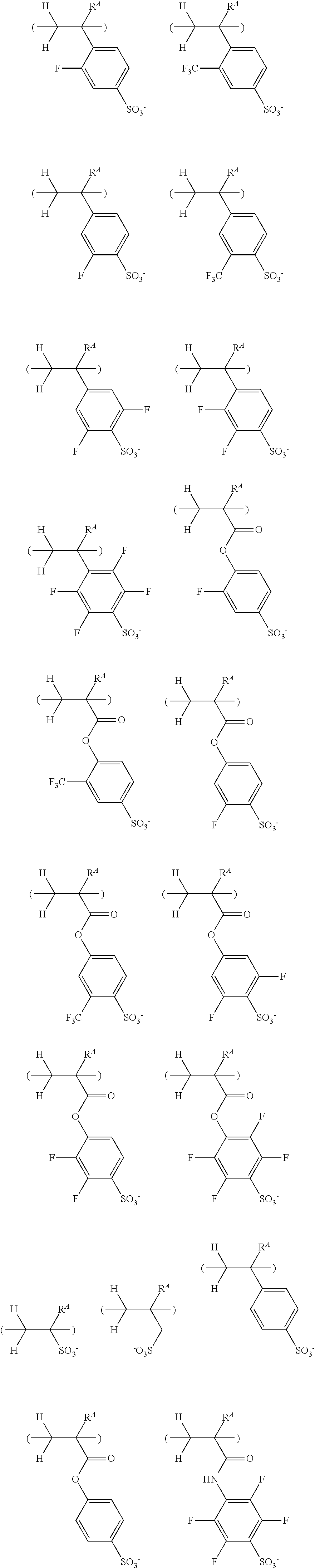

In formulae (c2) to (c5), Z⁺ is an onium cation. The onium cation is preferably a sulfonium cation having the formula (Z-1) or an iodonium cation having the formula (Z-2).

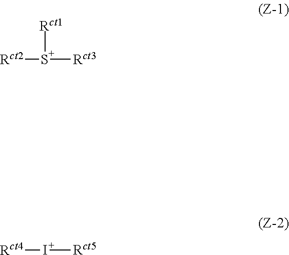

In formulae (Z-1) and (Z-2), R^{ct1} to R^{ct5} are each independently halogen or a C₁-C₃₀ hydrocarbyl group which may contain a heteroatom.

Examples of the halogen represented by R^{ct1} to R^{ct5} include fluorine, chlorine, bromine, and iodine.

The hydrocarbyl group represented by R^{ct1} to R^{ct5} may be saturated or unsaturated and straight, branched or cyclic. Examples thereof include C₁-C₃₀ alkyl groups such as methyl, ethyl, n-propyl, isopropyl, n-butyl, isobutyl, sec-butyl, and tert-butyl; C₃-C₃₀ cyclic saturated hydrocarbyl groups such as cyclopropyl, cyclopentyl, cyclohexyl, cylopropylmethyl, 4-methylcyclohexyl, cyclohexylmethyl, norbornyl, and adamantyl; C₂-C₃₀ alkenyl groups such as vinyl, 1-propenyl, 2-propenyl, butenyl, and hexenyl; C₃-C₃₀ cyclic unsaturated hydrocarbyl groups such as cyclohexenyl; C₆-C₃₀ aryl groups such as phenyl, naphthyl, and thienyl; C₇-C₃₀ aralkyl groups such as benzyl, 1-phenylethyl, and 2-phenylethyl; and combinations thereof. Of these, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

R^{ct1} and R^{ct2} may bond together to form a ring with the sulfur atoms to which they are attached. Examples of the structure of the ring include those having the formulae.

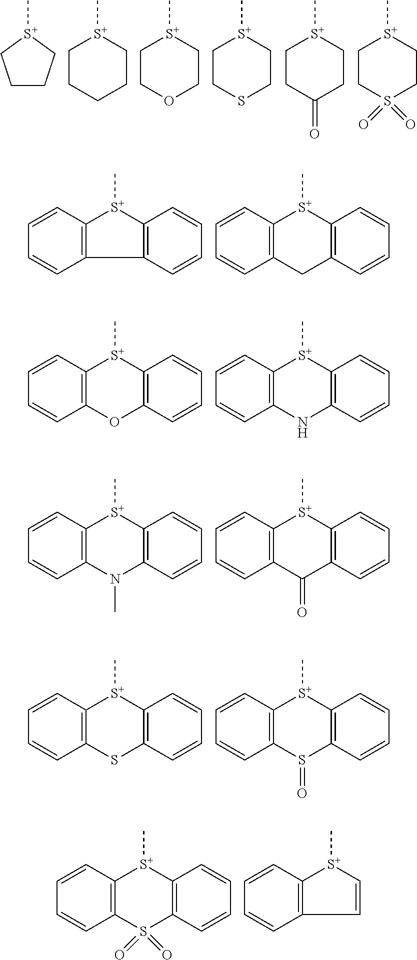

Herein the broken line is a point of attachment to R^{ct3}.

Examples of the sulfonium cation having formula (Z-1) include those described in JP-A 2024-003744, paragraphs [0102]-[0125], but are not limited thereto.

Examples of the iodonium cation having formula (Z-2) include those described in JP-A 2024-000259, paragraph [0181], but are not limited thereto.

The onium cation represented by Z⁺ is also preferably a sulfonium cation having the formula (Z-3).

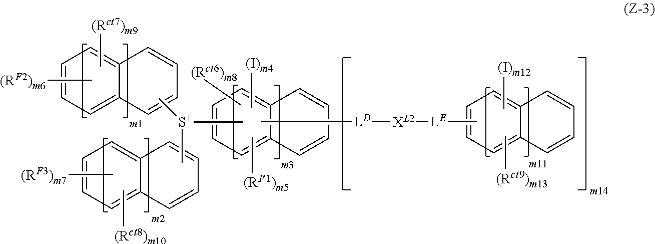

In formula (Z-3), m1 is 0 or 1. The relevant structure is a benzene ring in case of m1=0, and a naphthalene ring in case of m1=1. The benzene corresponding to m1=0 is preferred from the aspect of solvent solubility. m2 is 0 or 1. The relevant structure is a benzene ring in case of m2=0, and a naphthalene ring in case of m2=1. The benzene corresponding to m2=0 is preferred from the aspect of solvent solubility. m3 is 0 or 1. The relevant structure is a benzene ring in case of m3=0, and a naphthalene ring in case of m3=1. The benzene corresponding to m3=0 is preferred from the aspect of solvent solubility.

In formula (Z-3), m4 is 0, 1, 2, 3, or 4. Since a cation structure containing more iodine atoms is more absorptive to EUV, but loses solvent solubility so that it may precipitate in a resist composition, m4 is preferably 0, 1, 2, or 3, more preferably 0, 1, or 2.

In formula (Z-3), m5 is 0, 1, 2, 3, or 4. m5 is preferably 0, 1, 2, or 3, more preferably 0, 1, or 2 from the aspect of availability of reactants. m6 is 0, 1, 2, 3, 4, 5, or 6. m6 is preferably 0, 1, 2, or 3, more preferably 0, 1, or 2 from the aspect of availability of reactants. m7 is 0, 1, 2, 3, 4, 5, or 6. m7 is preferably 0, 1, 2, or 3, more preferably 0, 1, or 2 from the aspect of availability of reactants.

In formula (Z-3), m8 is 0, 1, or 2. m8 is preferably 0 or 1 from the aspect of availability of reactants. m9 is 0, 1, or 2. m9 is preferably 0 or 1 from the aspect of availability of reactants. m10 is 0, 1, or 2. m10 is preferably 0 or 1 from the aspect of availability of reactants.

In formula (Z-3), m11 represents 0 or 1. The relevant structure is a benzene ring in case of m11=0, and a naphthalene ring in case of m11=1. The benzene corresponding to m11=0 is preferred from the aspect of solvent solubility.

In formula (Z-3), m12 is 0, 1, 2, 3, or 4. Since a cation structure containing more iodine atoms is more absorptive to EUV, but loses solvent solubility so that it may precipitate in a resist composition, m12 is preferably 0, 1, 2, or 3, more preferably 0, 1, or 2.

In formula (Z-3), m13 represents 0, 1, or 2. m13 is preferably 0 or 1 from the aspect of availability of reactants. m14 is 0, 1, or 2. m14 is preferably 0 or 1 from the aspect of synthesis.

It is noted that 0 m6+m9≤4 in case of m1=0 and 0≤m6+m9≤6 in case of m1=1; 0≤m7+m10≤4 in case of m2=0 and 0≤m7+m10≤6 in case of m2=1; 1≤m4+m5+m8+m14≤4 in case of m3=0 and 1≤m4+m5+m8m+14≤6 in case of m3=1; 0≤m12+m13≤4 in case of m11=0 and 0≤m12+m13≤6 in case of m11=1; and m4+m12≥1.

In formula (Z-3), R^{F3} to R^{F5} are each independently fluorine, a C₁-C₆ fluorinated saturated hydrocarbyl group, a C₁-C₆ fluorinated saturated hydrocarbyloxy group, or a C₁-C₆ fluorinated saturated hydrocarbylthio group. Among them, R^{F3} to R^{F5} are preferably a trifluoromethyl, trifluoromethoxy or trifluorothiomethoxy group. A plurality of R^{F3} may be identical or different when m5 is 2 or more, a plurality of R^{F4} may be identical or different when m6 is 2 or more, and a plurality of R^{F5} may be identical or different when m7 is 2 or more.

In formula (Z-3), R^{ct6} to R^{ct9} are halogen exclusive of iodine and fluorine, a nitro group, a cyano group, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom. The hydrocarbyl group and hydrocarbyl moiety in the hydrocarbyloxy and hydrocarbylthio groups may be saturated or unsaturated and straight, branched or cyclic. Examples thereof are as exemplified above for the hydrocarbyl group represented by R¹ in formula (1). In the hydrocarbyl group and hydrocarbyl moiety in the hydrocarbyloxy and hydrocarbylthio groups, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

When m8 is 2, two R^{ct6} may be identical or different and two R^{ct6} may bond together to form a ring with the carbon atoms to which they are attached; when m9 is 2, two R^{ct7} may be identical or different and two R^{ct7} may bond together to form a ring with the carbon atoms to which they are attached; when m10 is 2, two R^{ct8} may be identical or different and two R^{ct8} may bond together to form a ring with the carbon atoms to which they are attached; and when m13 is 2, two R^{ct9} may be identical or different and two R^{ct9} may bond together to form a ring with the carbon atoms to which they are attached. Examples of the ring thus formed include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

The aromatic rings directly bonded to S⁺ in the sulfonium cation having formula (Z-3) may bond together to form a ring with S⁺. Examples of the structure of the ring include those having the formulae.

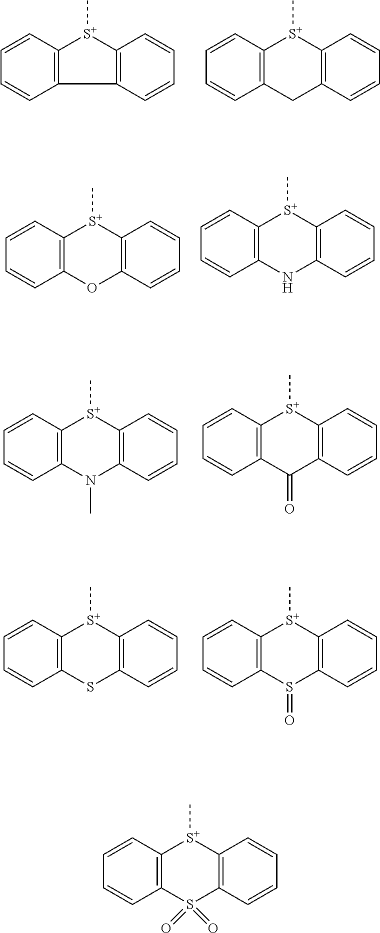

Herein the broken line is a valence bond.

In formula (Z-3), L^{C} and L^{D} are each independently a single bond, ether bond, ester bond, amide bond, sulfonate ester bond, sulfonamide bond, carbonate bond or carbamate bond. Of these, L^{C} is preferably a single bond, ether bond, ester bond or sulfonate ester bond, more preferably an ester bond or sulfonate ester bond. L^{D} is preferably a single bond, ether bond or ester bond, more preferably a single bond.

In formula (Z-3), X^{L2} is a single bond or a C₁-C₄₀ hydrocarbylene group which may contain a heteroatom. The hydrocarbylene group may be straight, branched or cyclic, and examples thereof include alkanediyl, cyclic saturated hydrocarbylene and arylene groups.

Examples of the heteroatom include oxygen, nitrogen and sulfur atoms. Examples of the C₁-C₄₀ hydrocarbylene group which may contain a heteroatom represented by X^{L2} are as exemplified above for the C₁-C₄₀ hydrocarbylene group which may contain a heteroatom represented by X^{L1} in formula (1), but not limited thereto. Of these, X^{L}-0 to X^{L}-58, X^{L2} is preferably X^{L}-0 to X^{L}-22, X^{L}-29 to X^{L}-34, and X^{L}-47 to X^{L}-58.

Preferably the sulfonium cation having formula (Z-3) has the formula (Z-3-1):

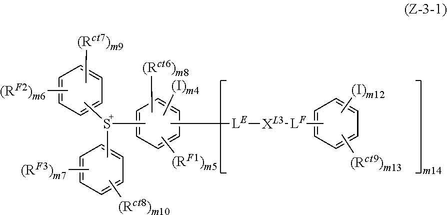

wherein m4 to m10, m12 to m14, R^{F3} to R^{F5}, R^{ct6} to R^{ct9}, L^{C}, L^{D}, and X^{L2} are as defined above.

Preferably the sulfonium cation having formula (Z-3-1) has the formula (Z-3-2):

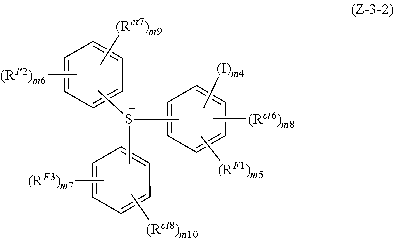

wherein m4 to m10, R^{F3} to R^{F5}, and R^{ct6} to R^{ct8} are as defined above.

Examples of the sulfonium cation having formula (Z-3) include those shown below, but are not limited thereto. In the formulae, Me is methyl.

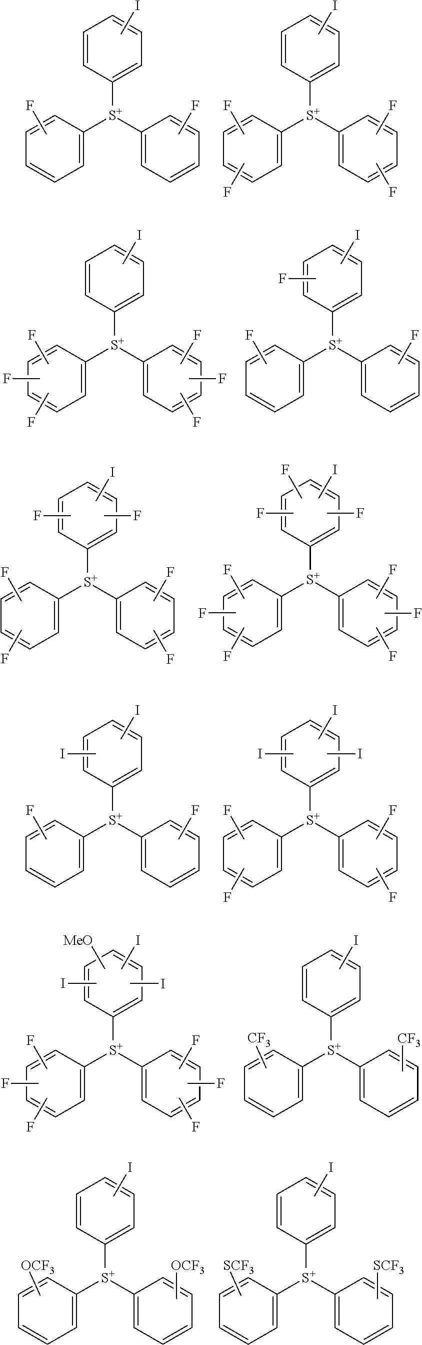

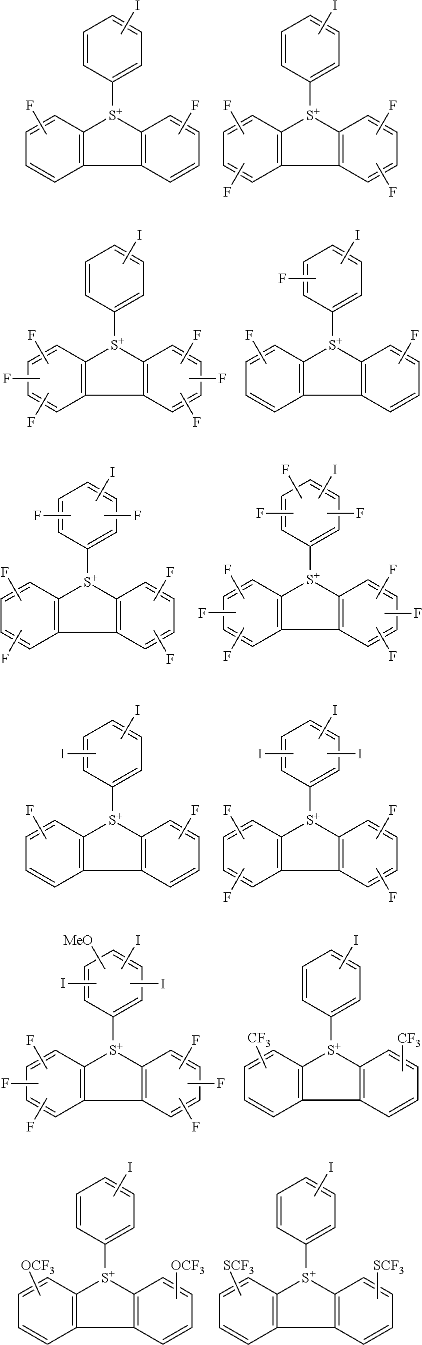

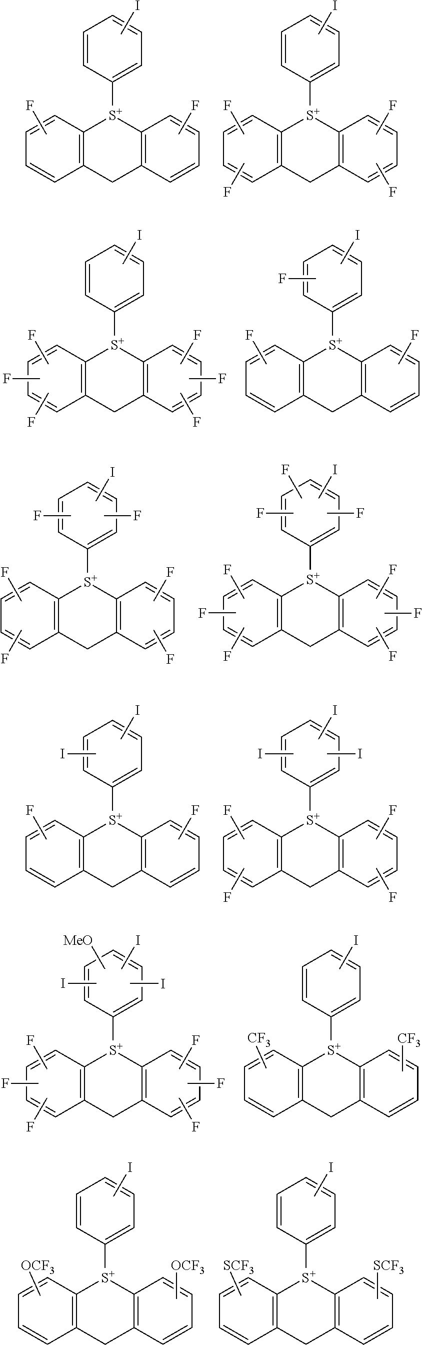

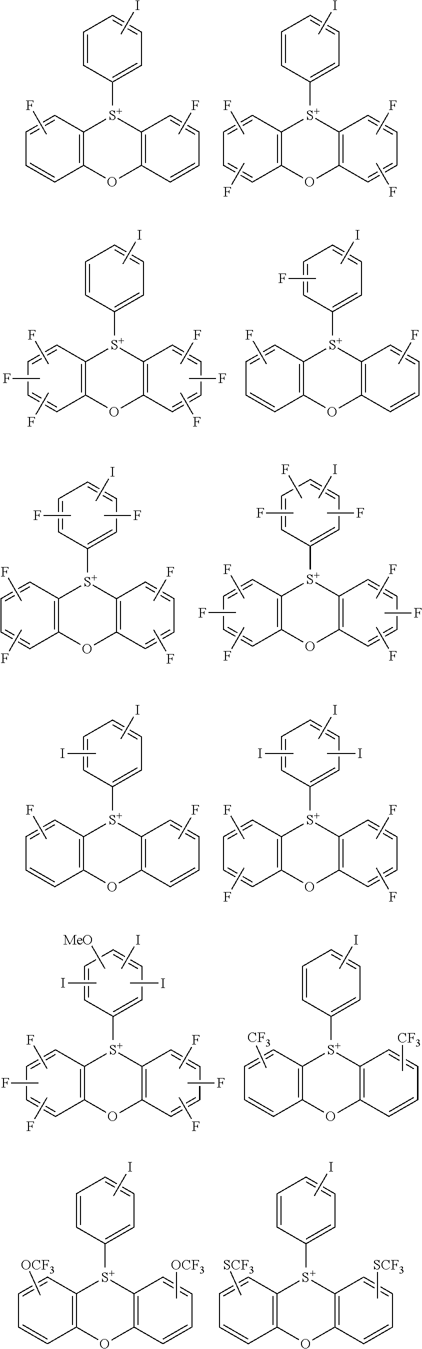

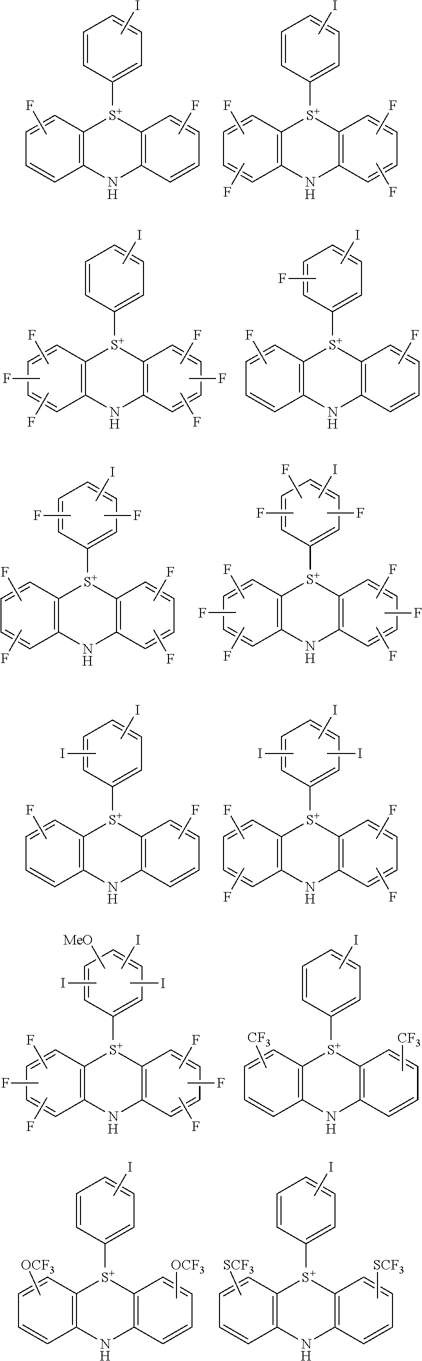

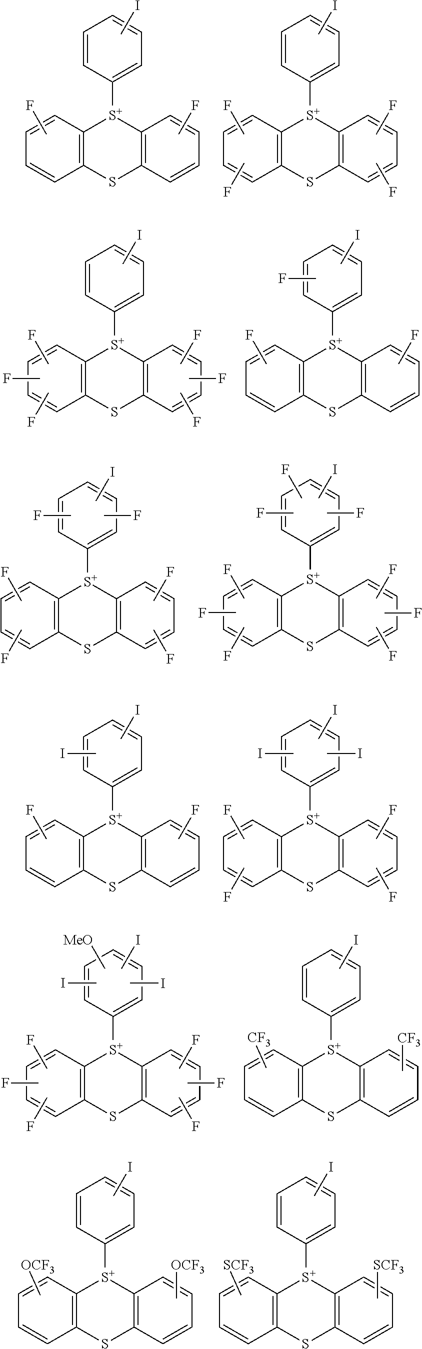

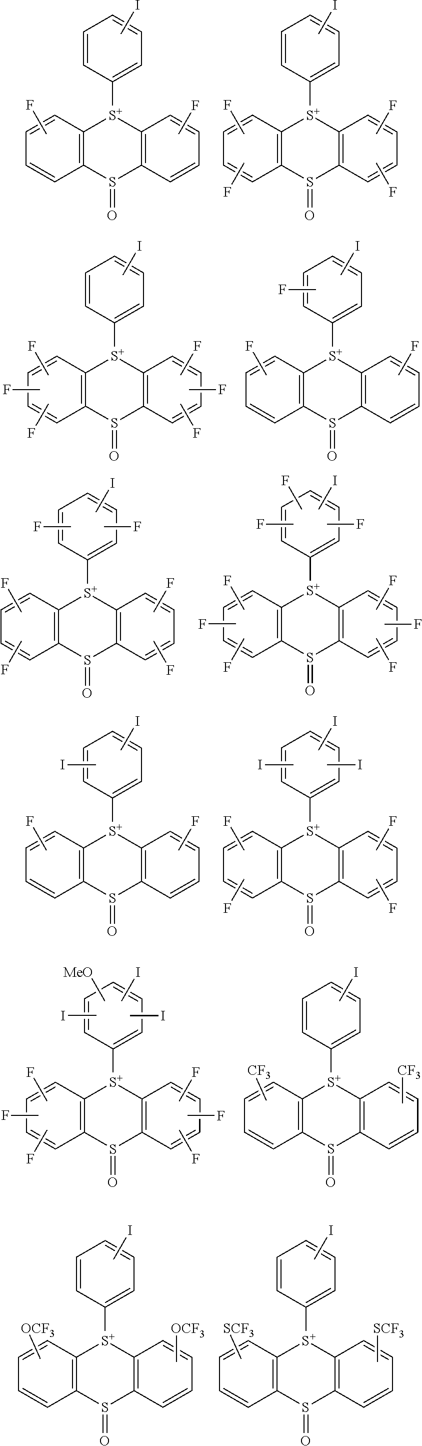

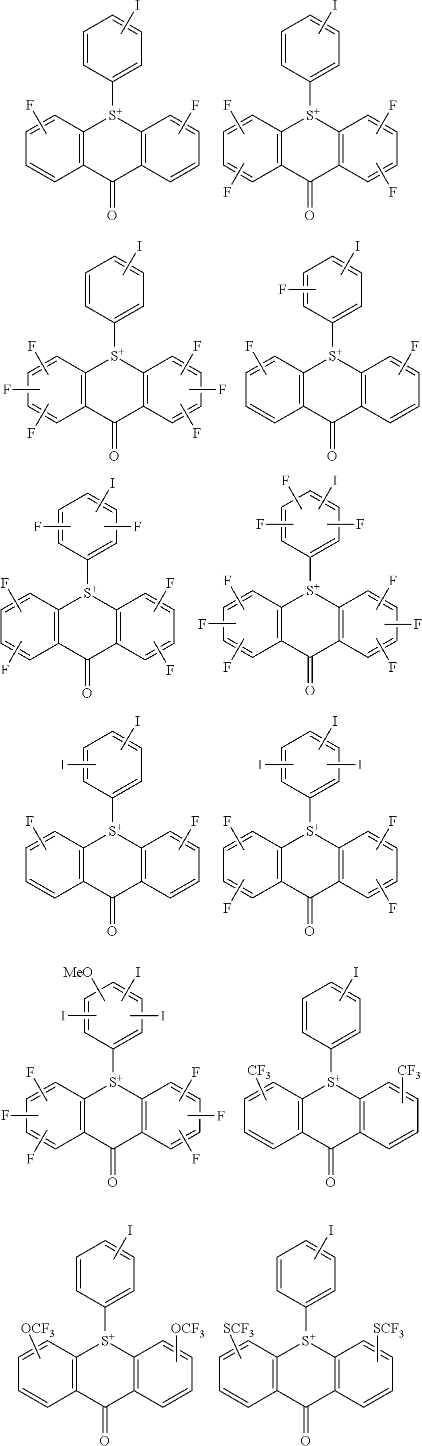

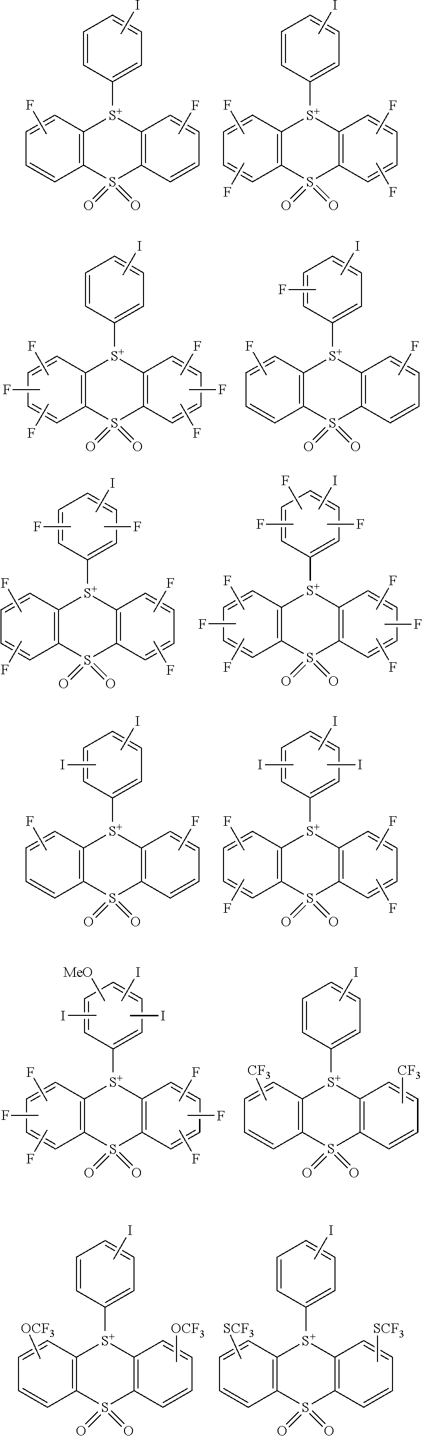

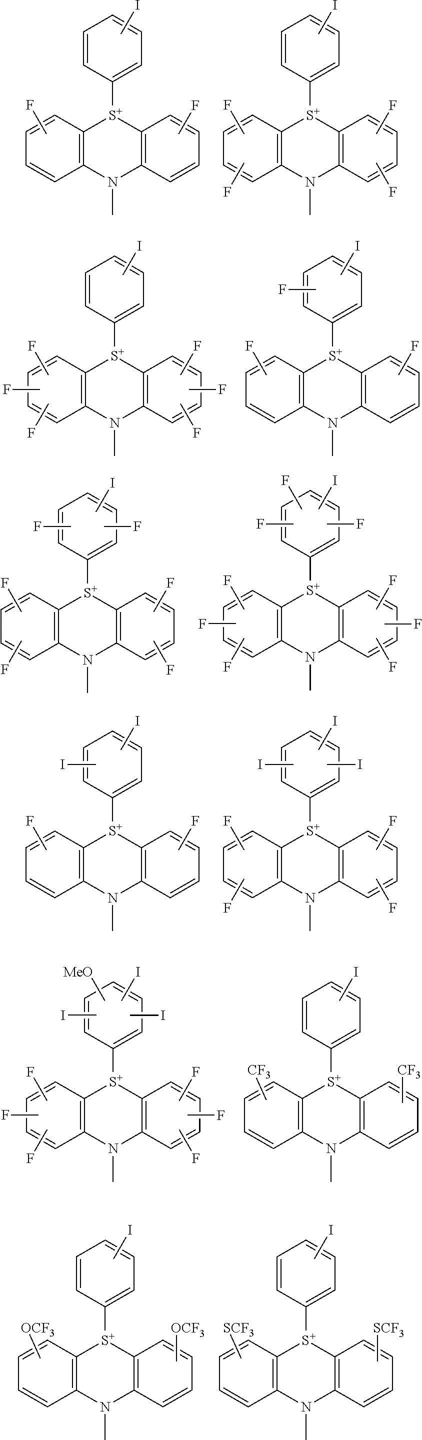

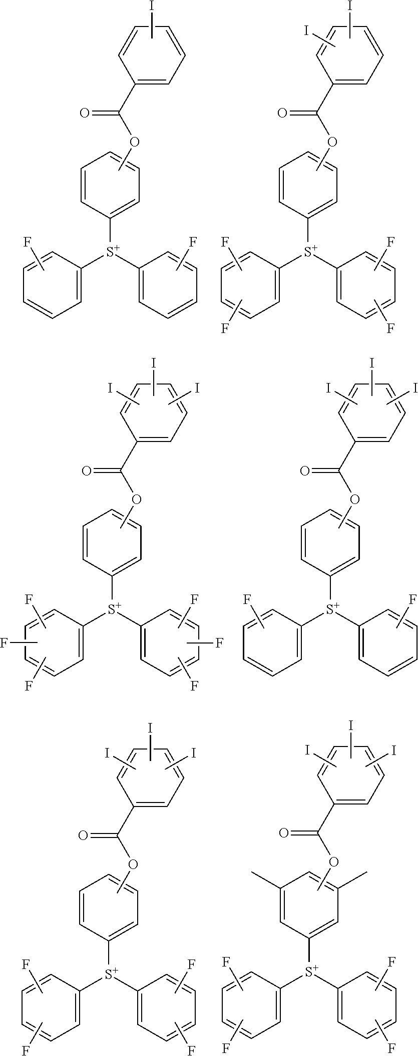

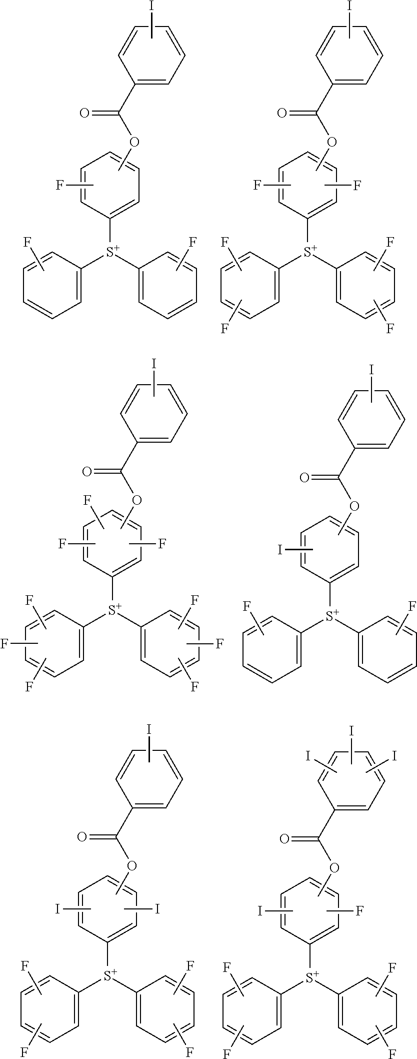

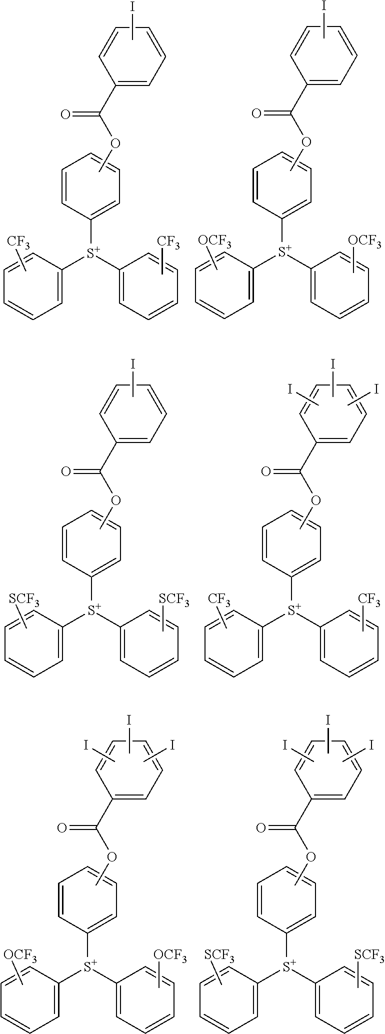

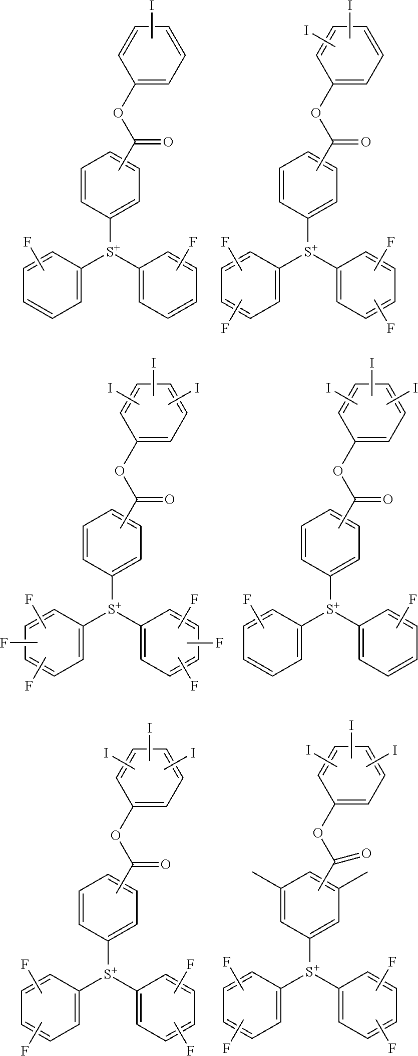

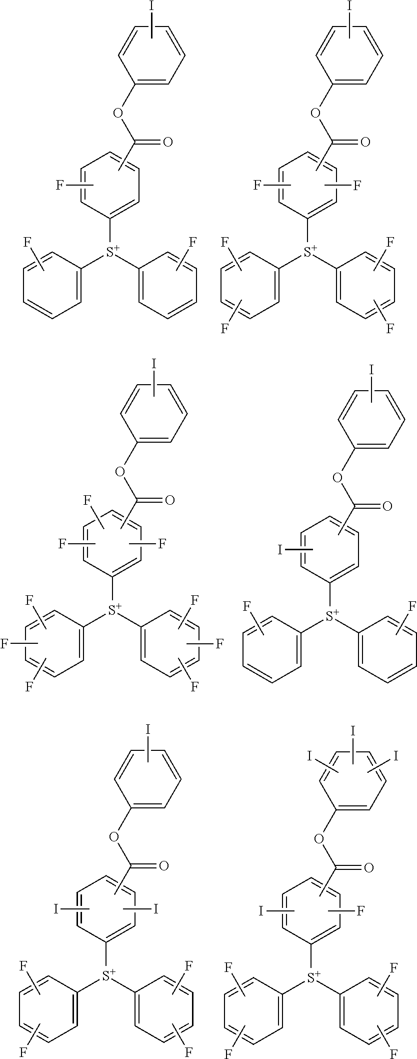

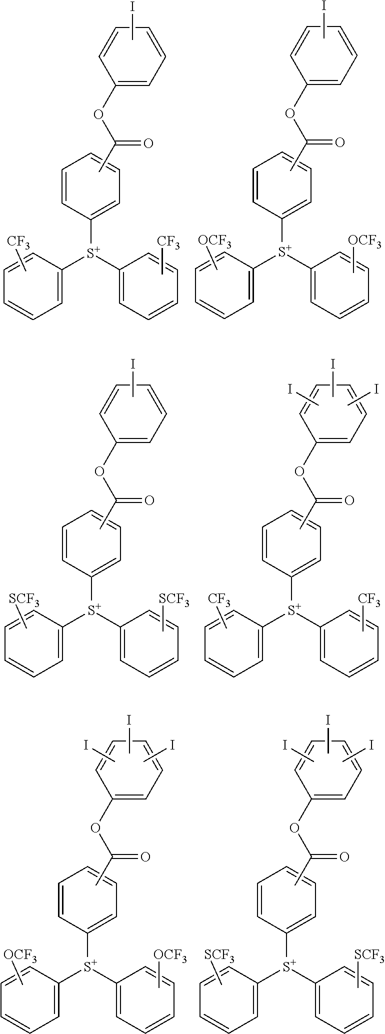

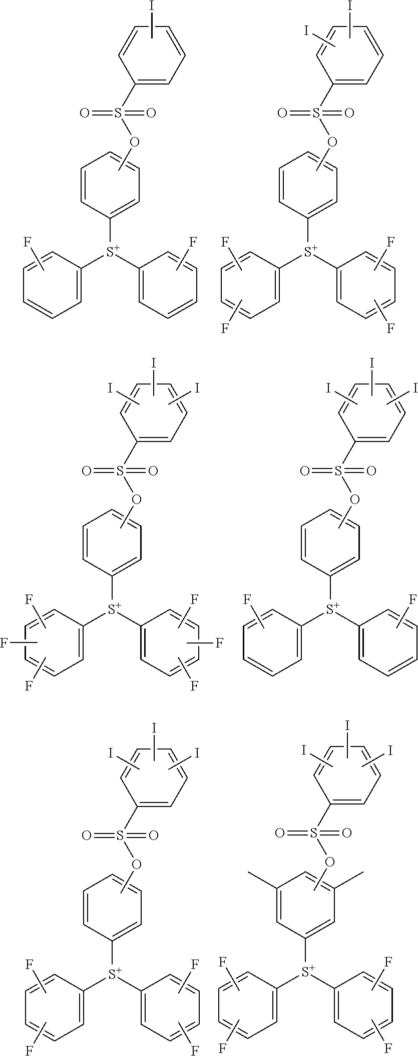

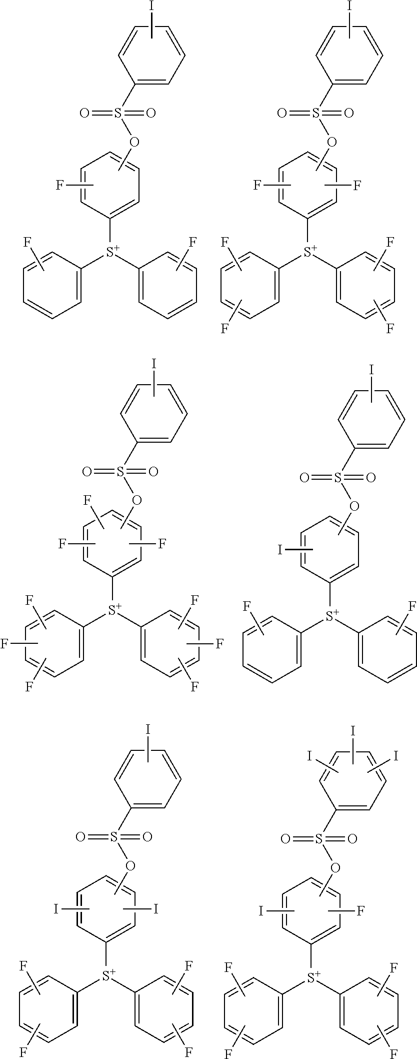

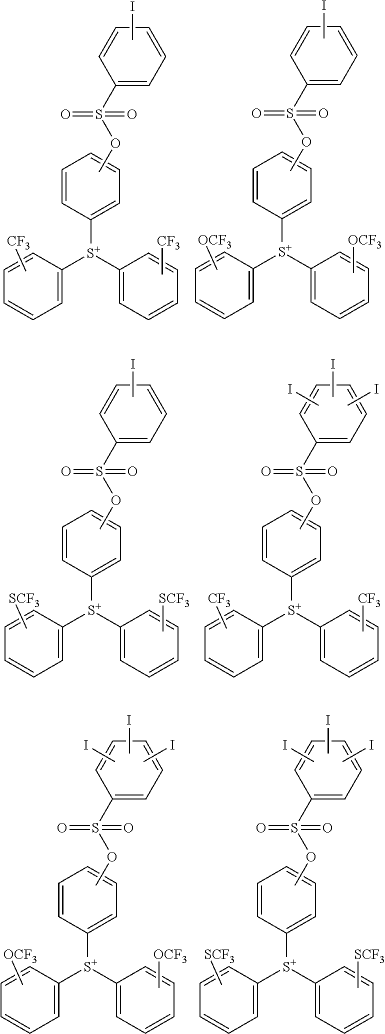

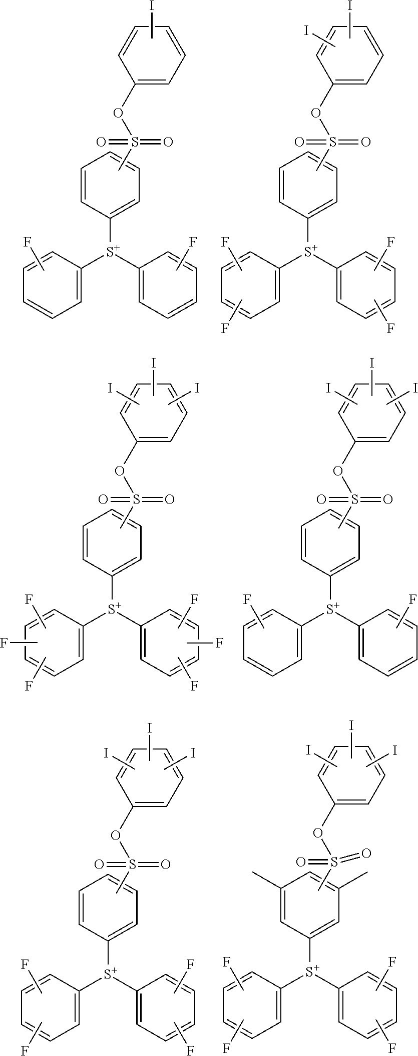

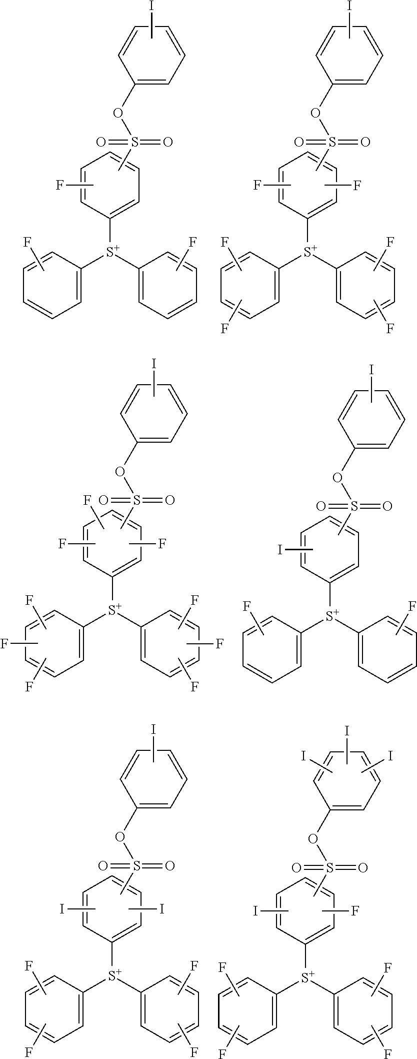

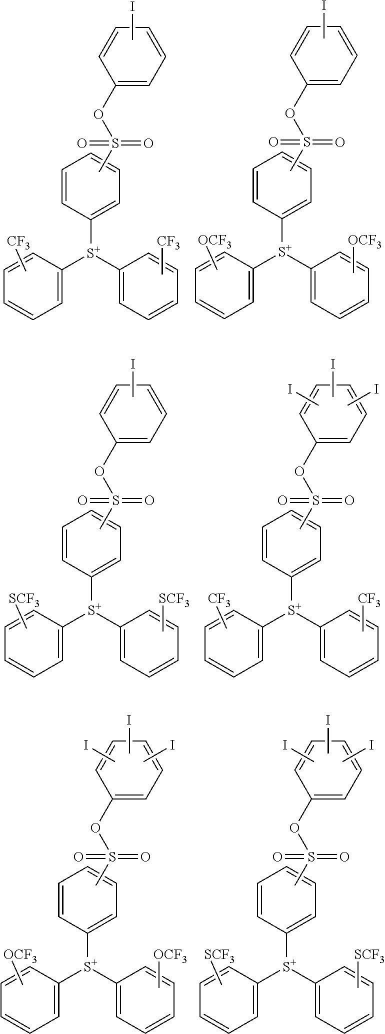

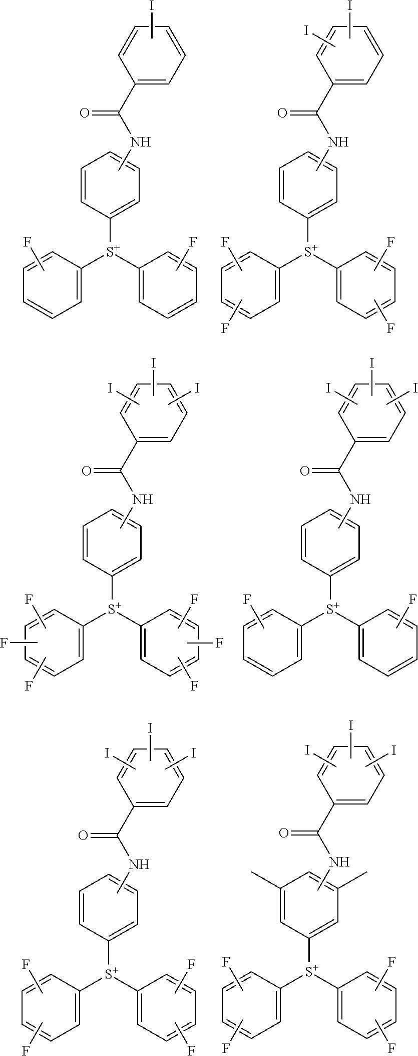

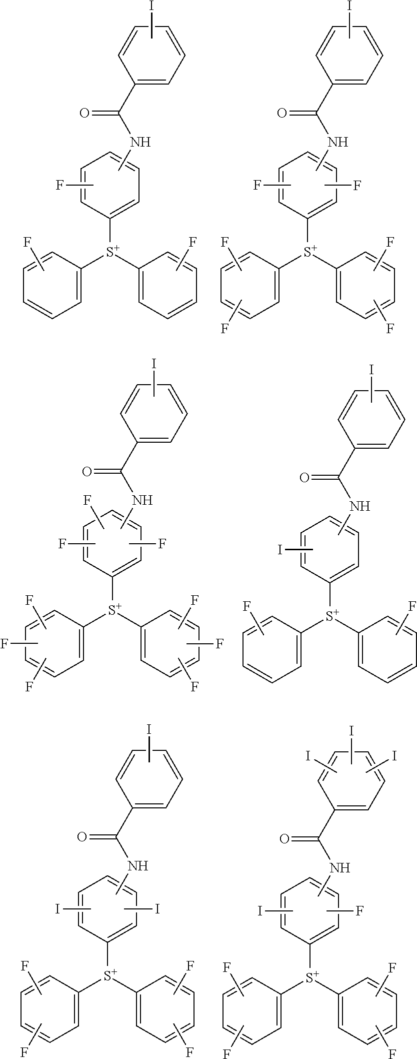

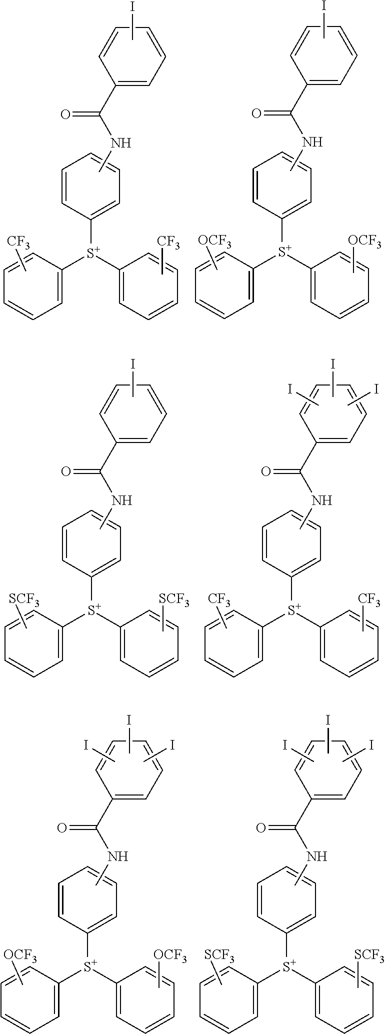

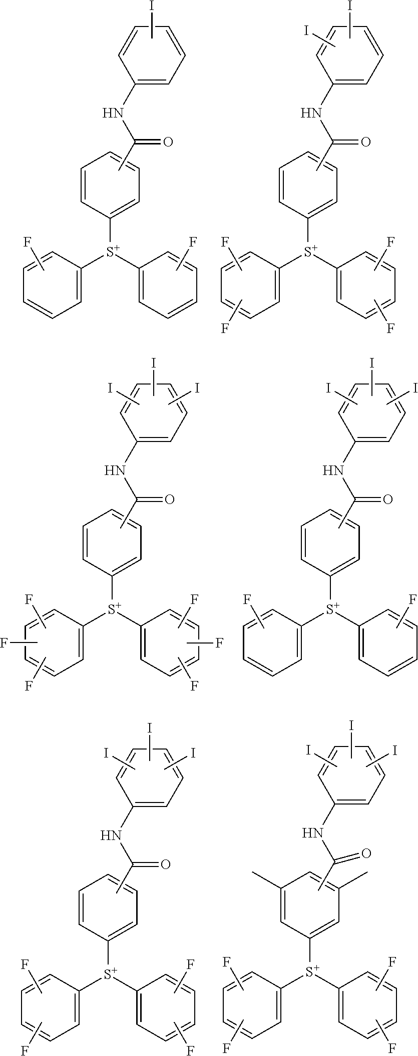

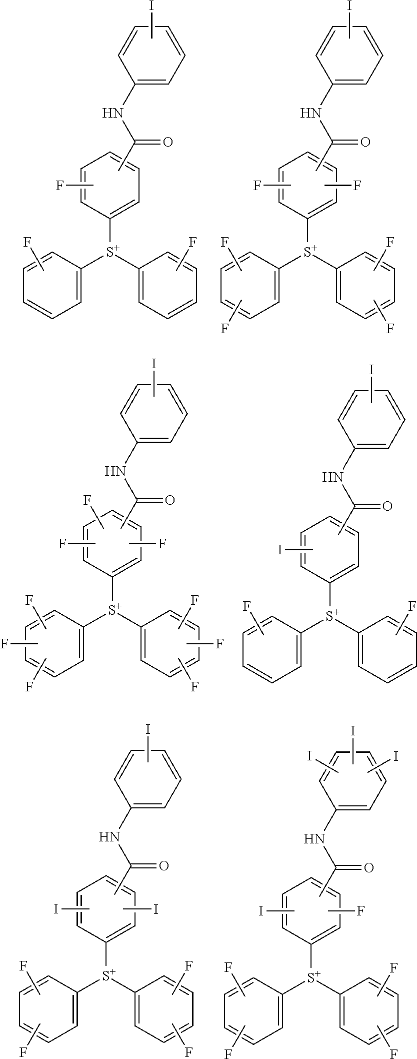

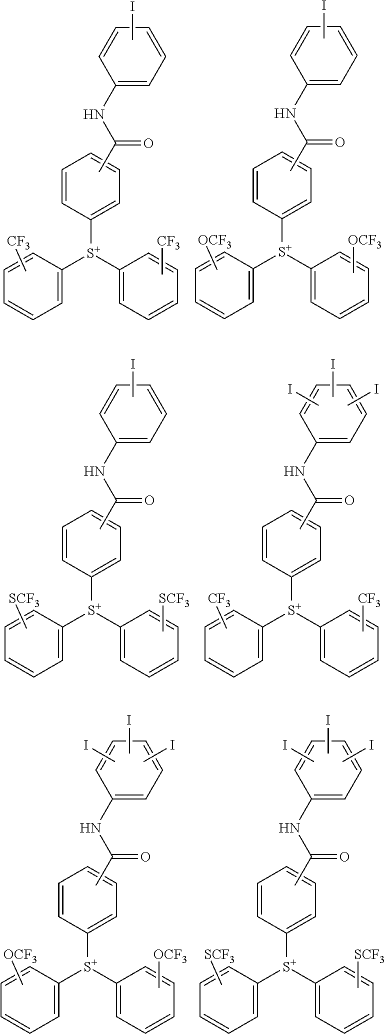

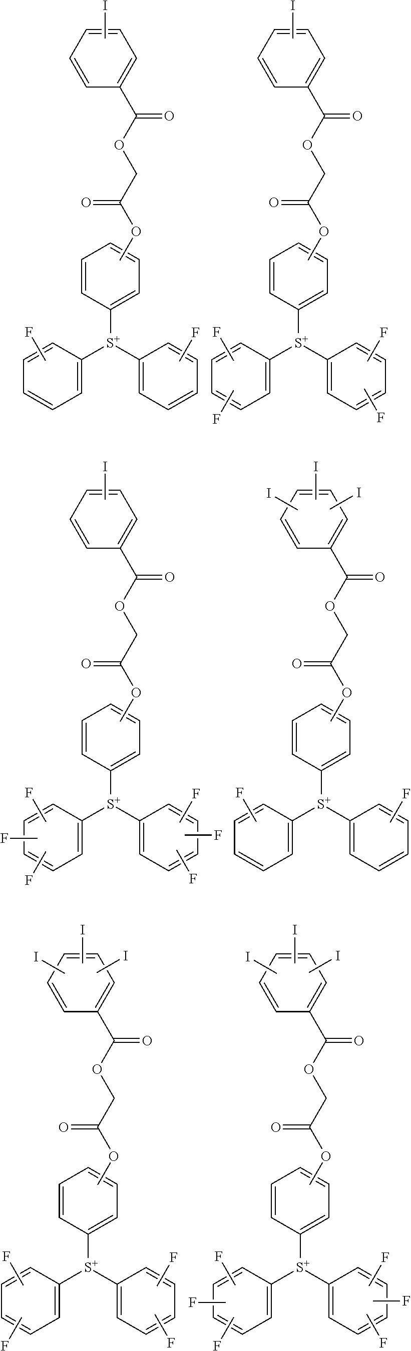

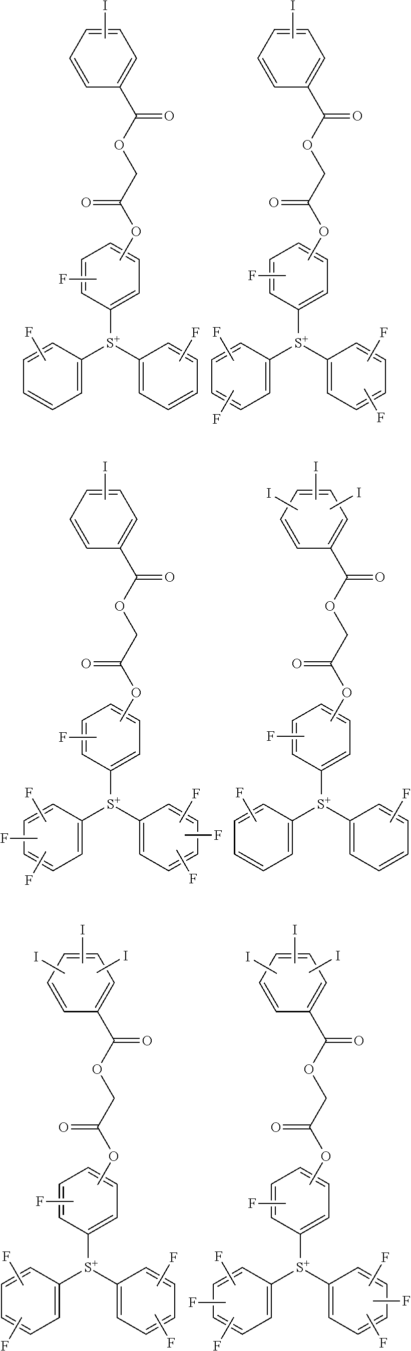

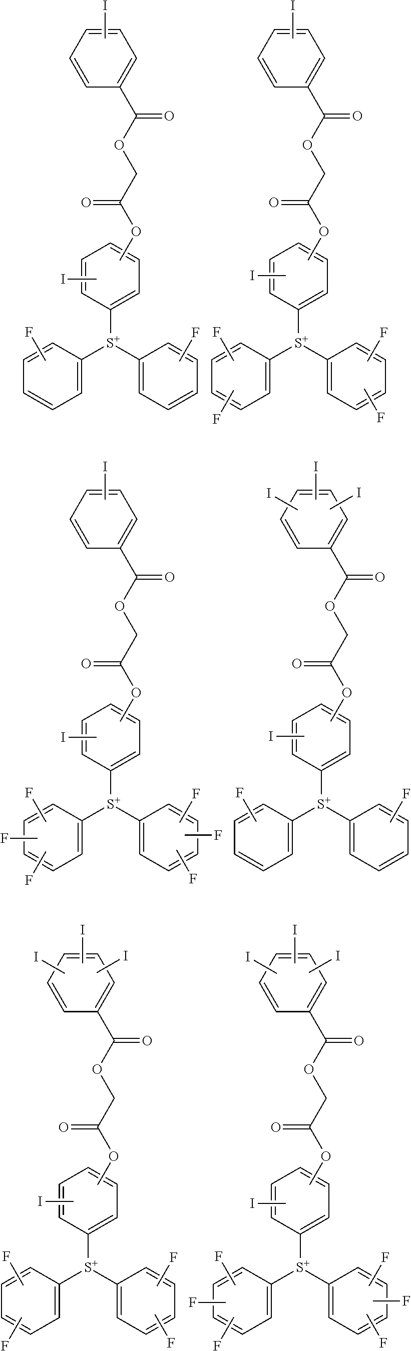

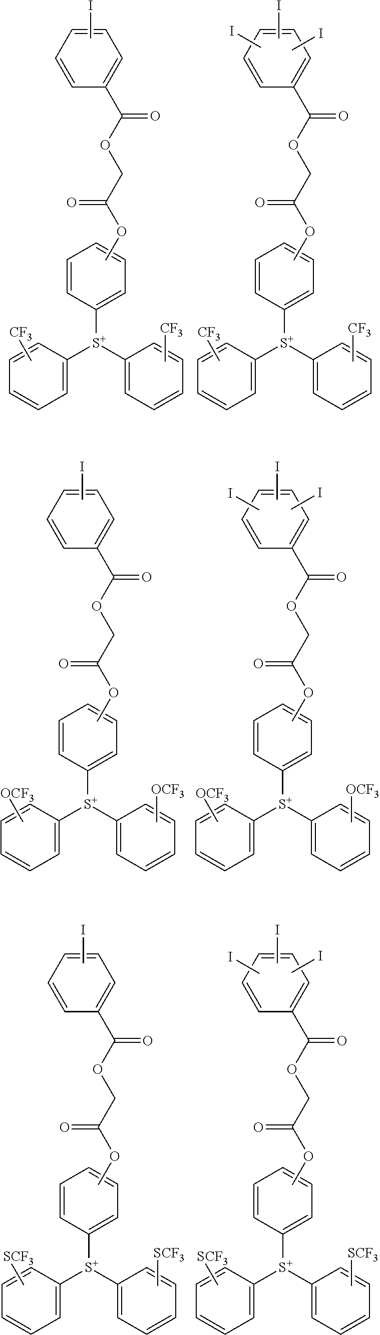

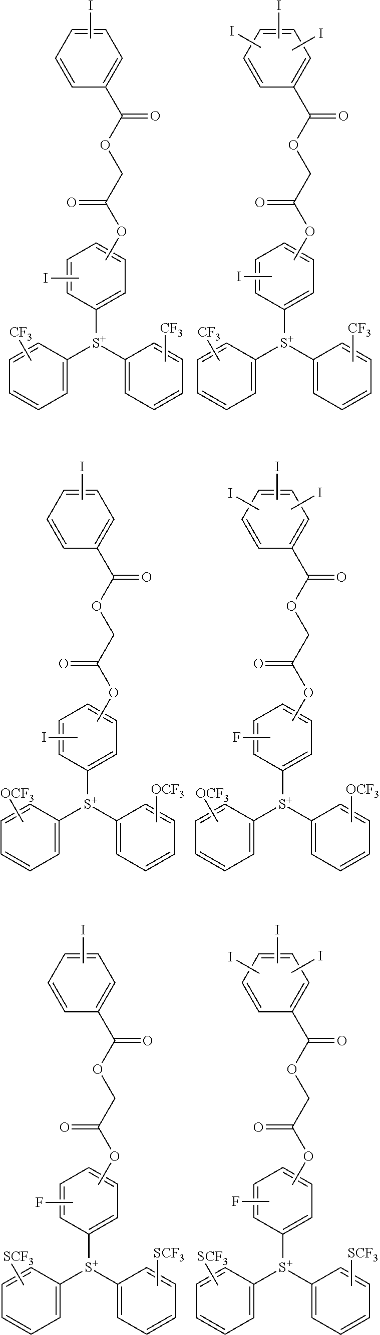

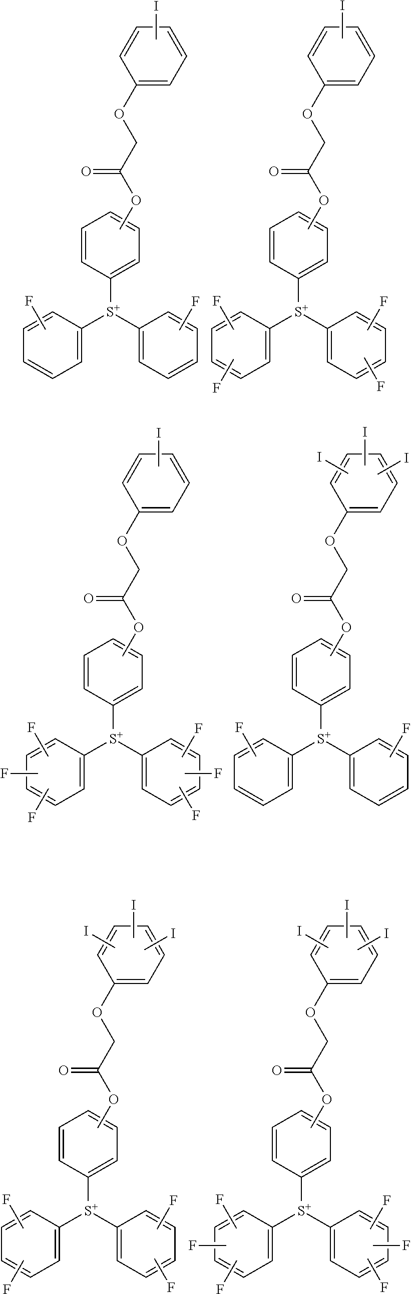

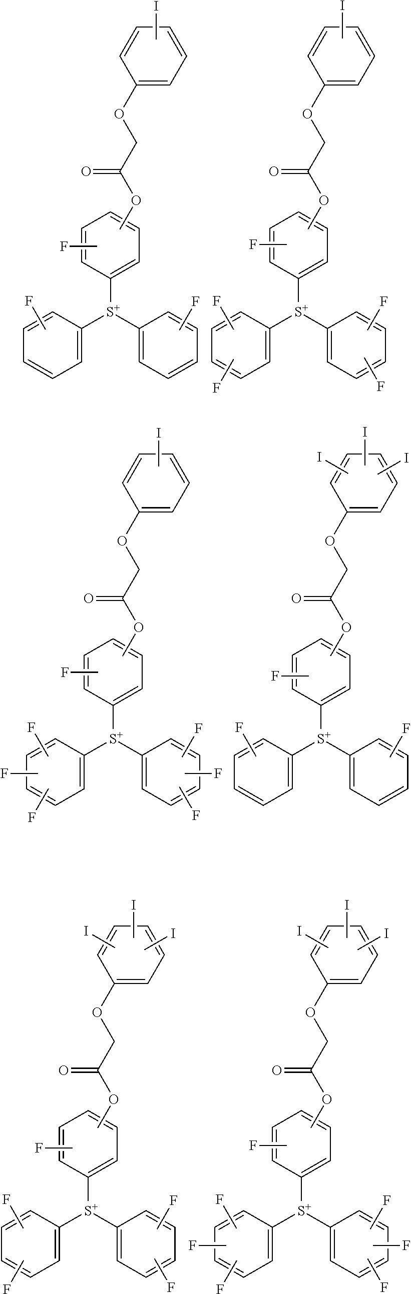

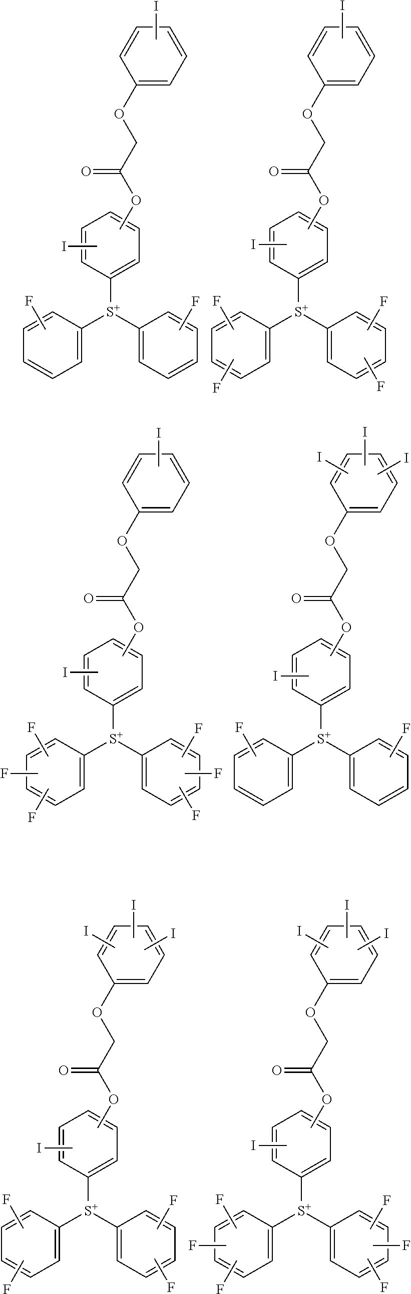

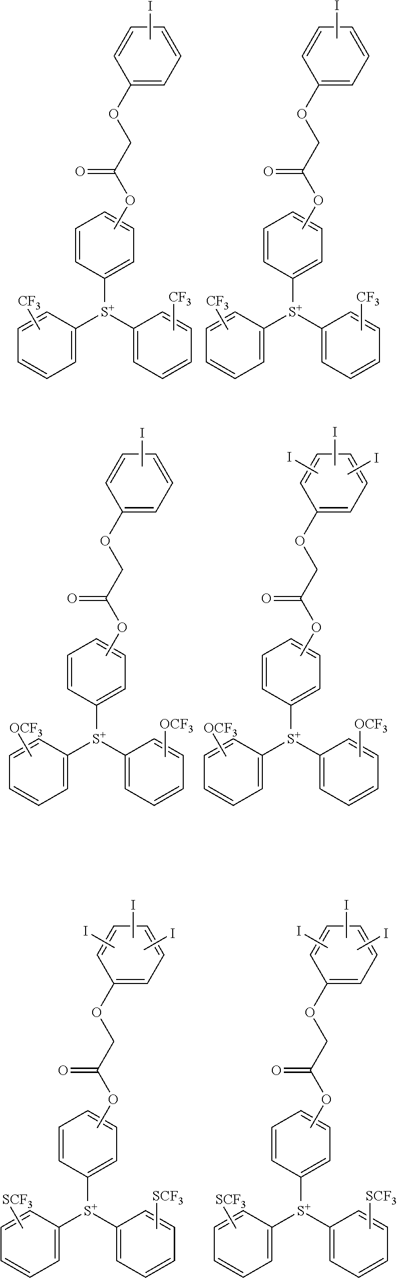

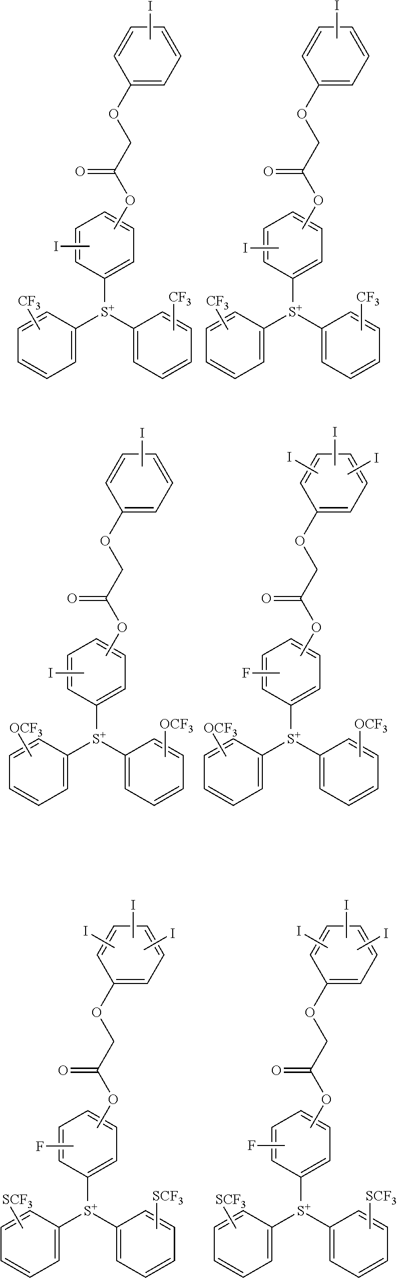

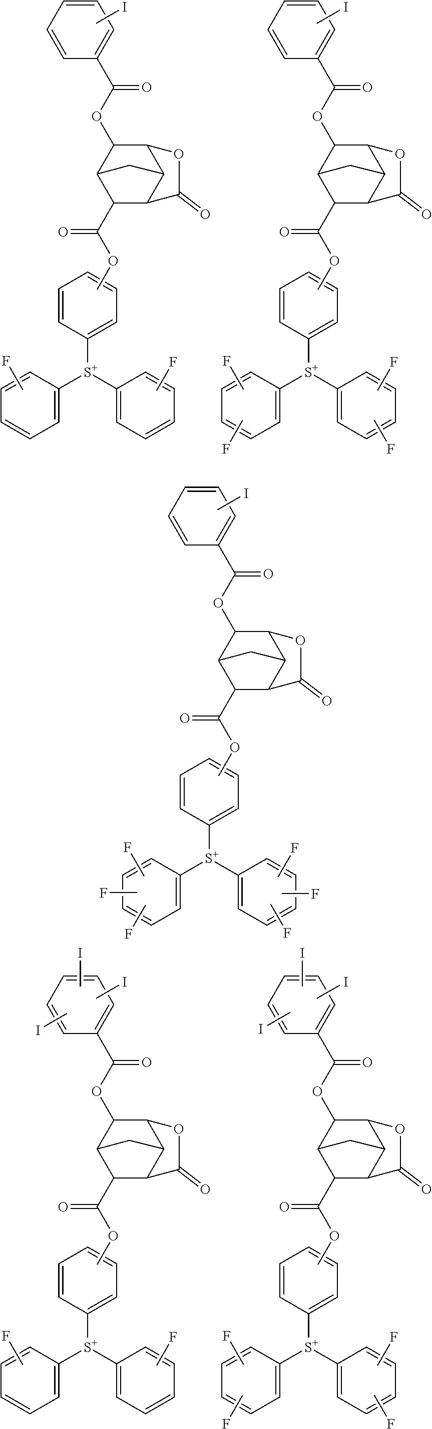

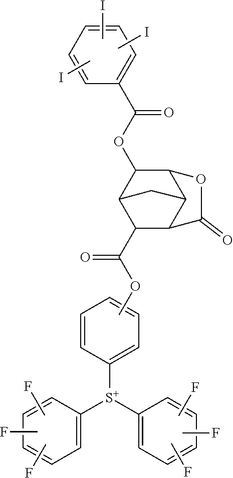

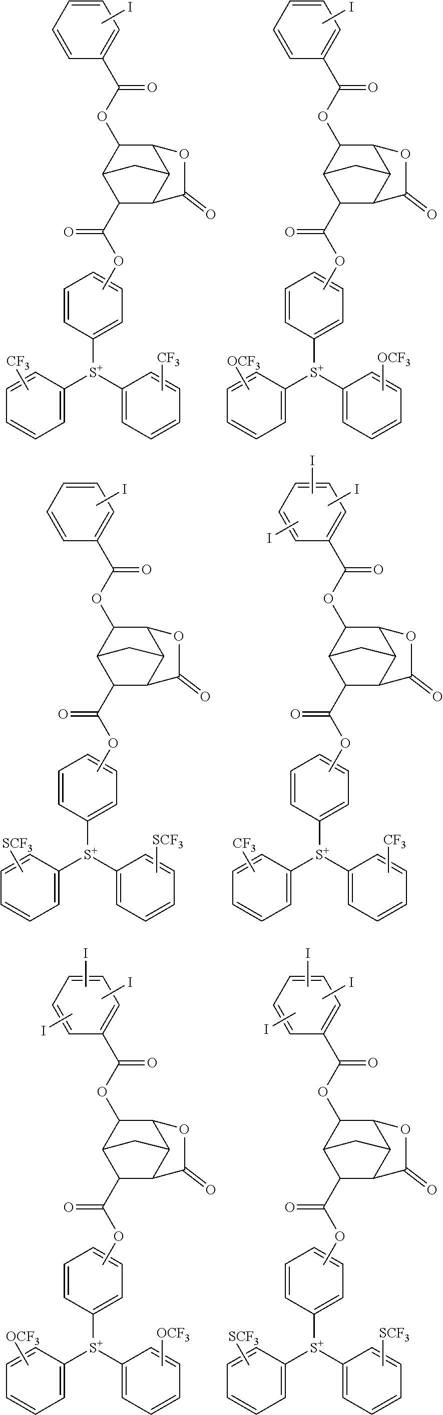

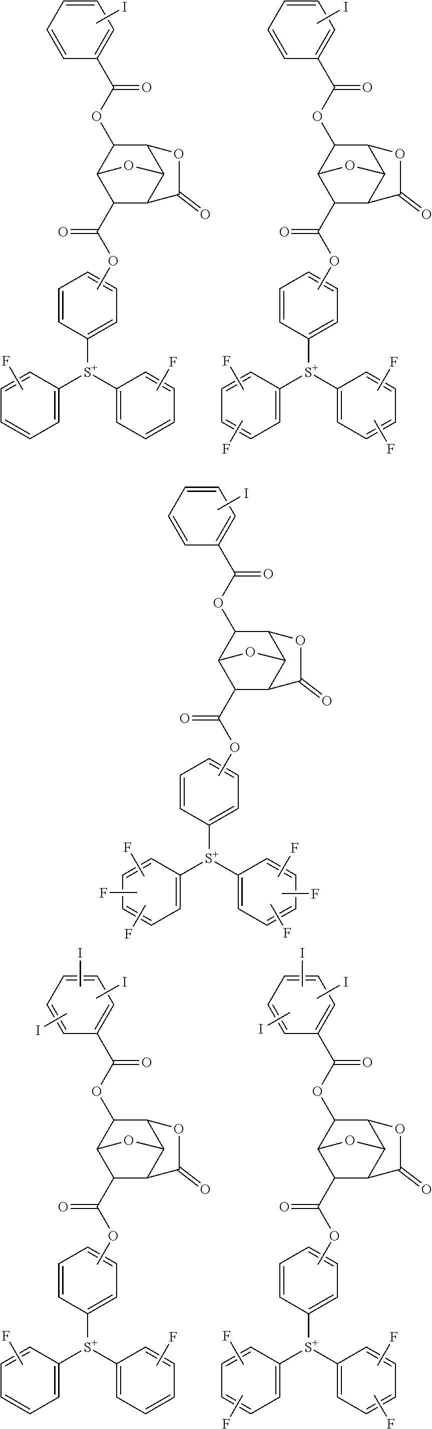

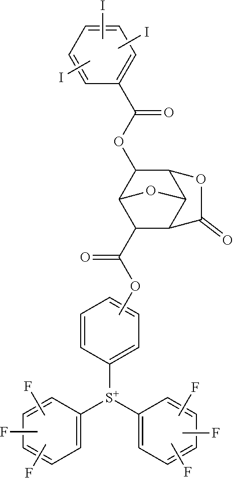

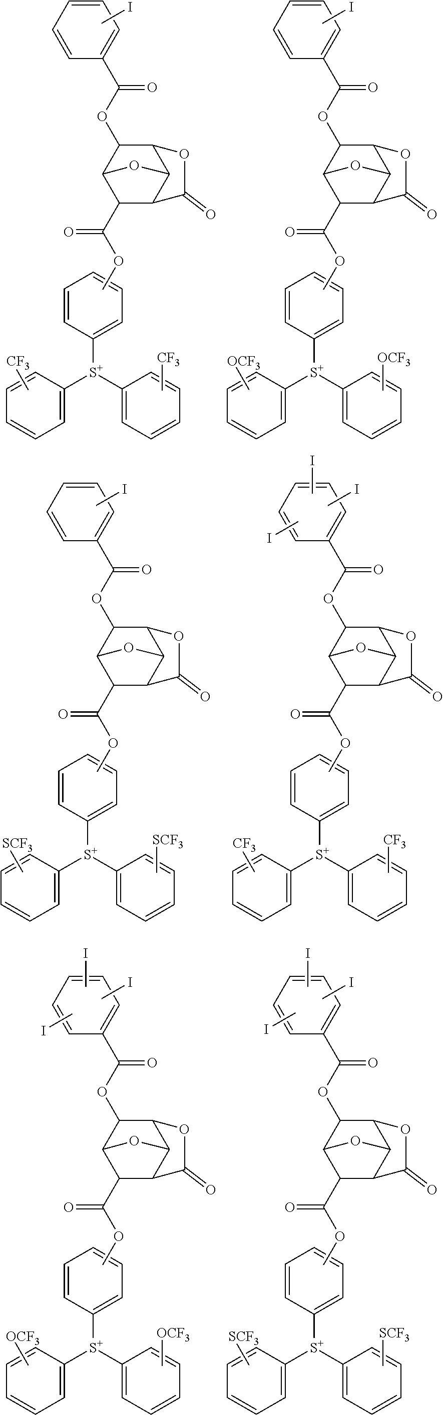

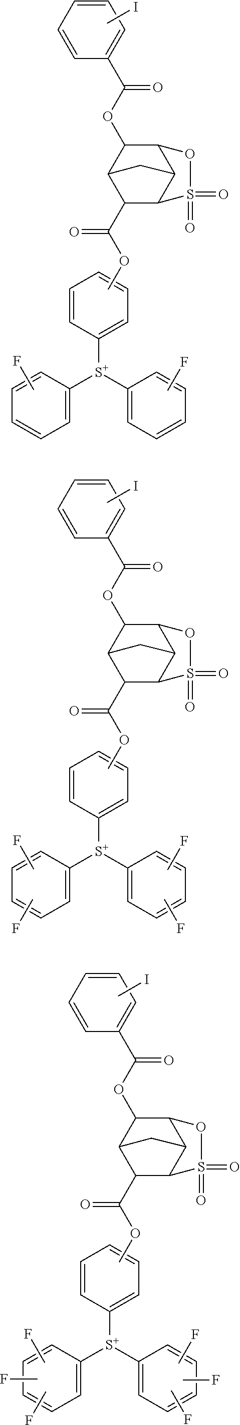

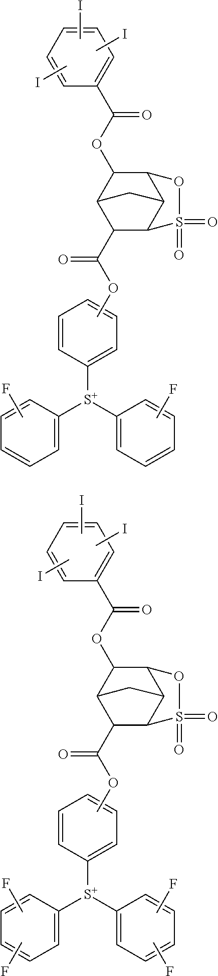

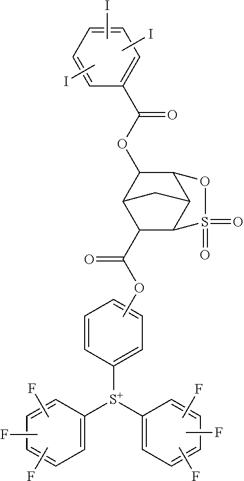

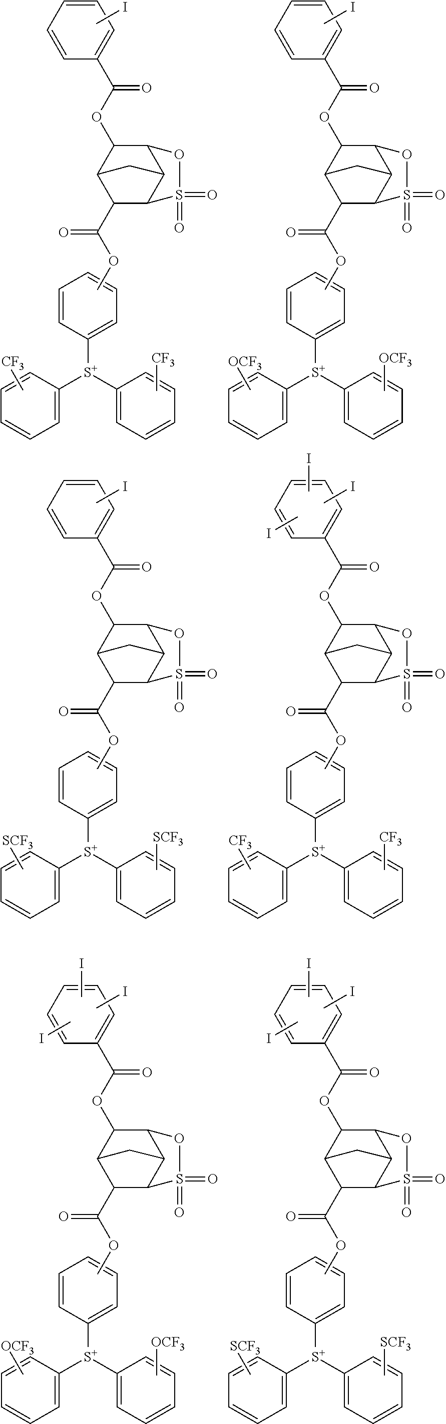

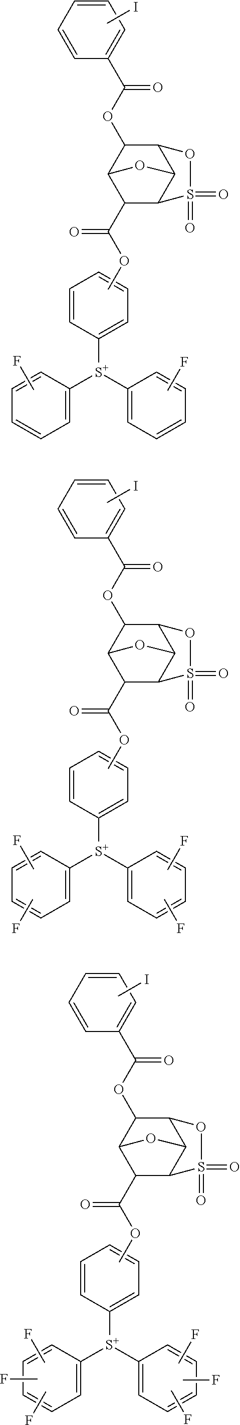

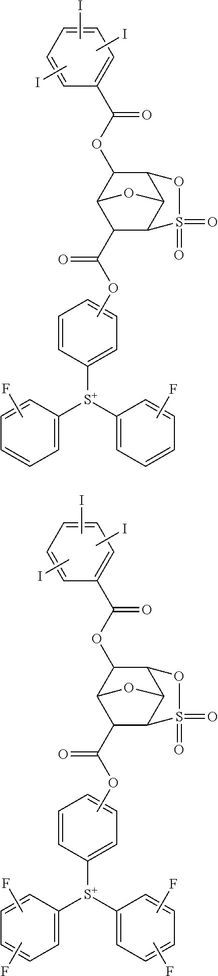

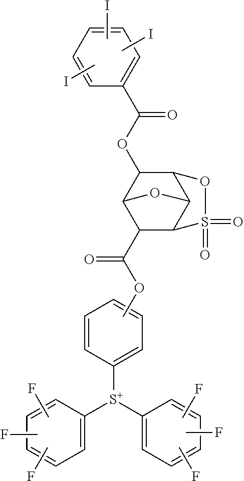

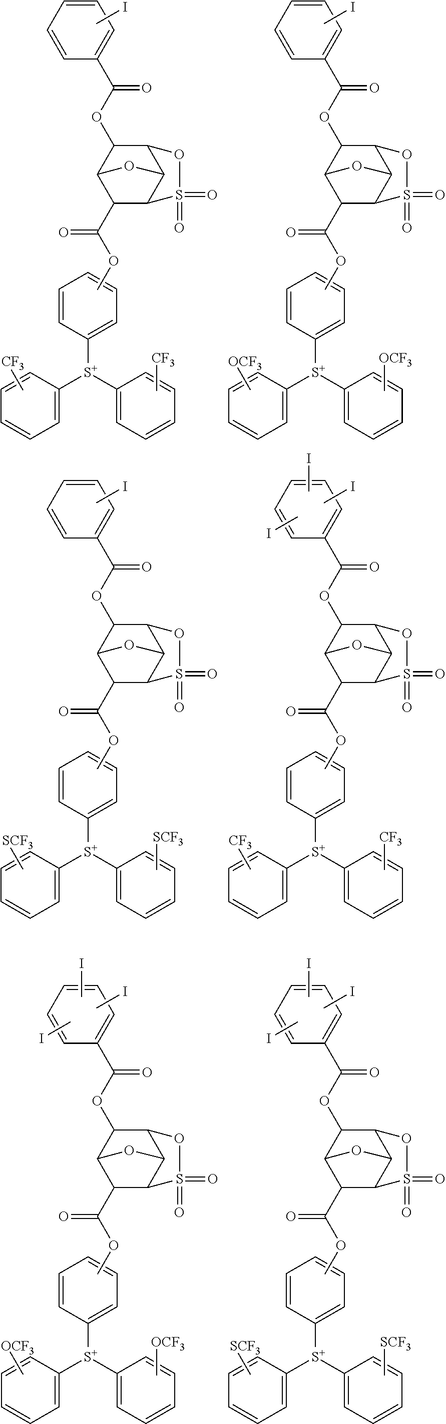

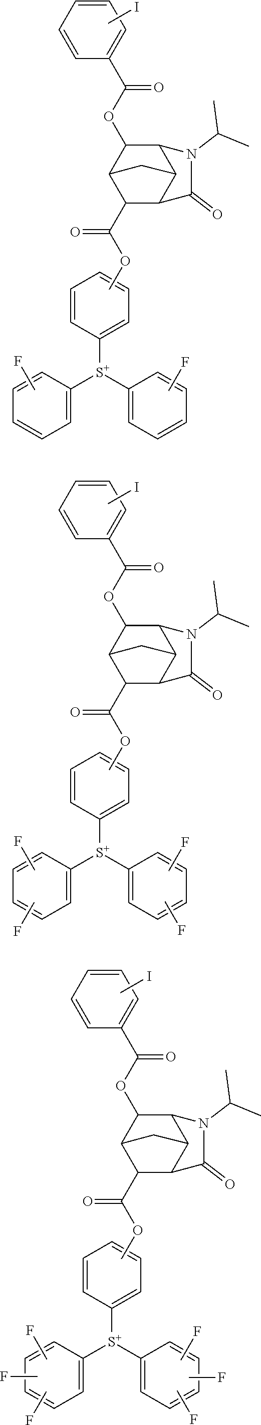

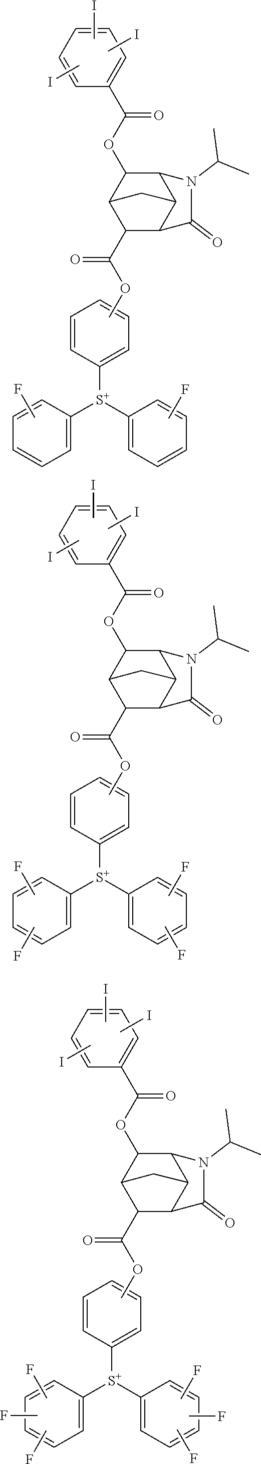

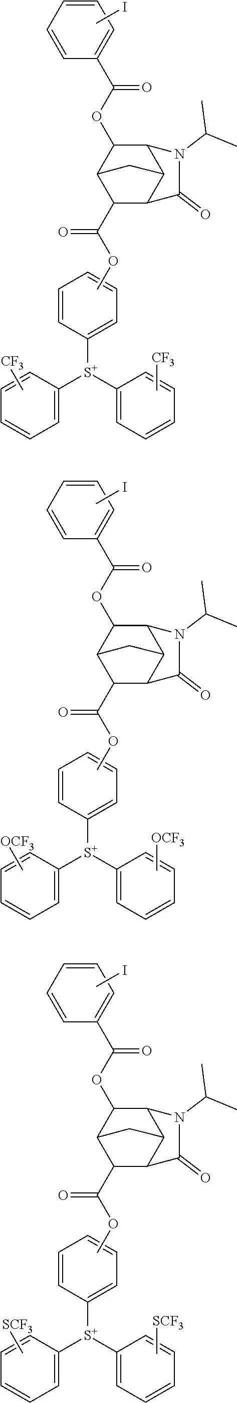

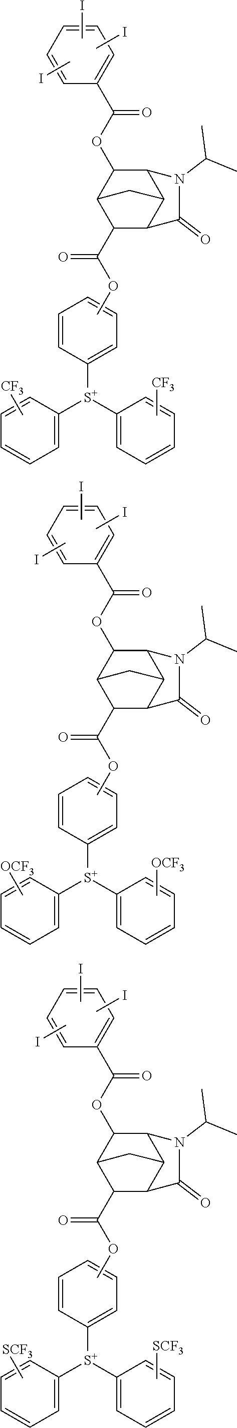

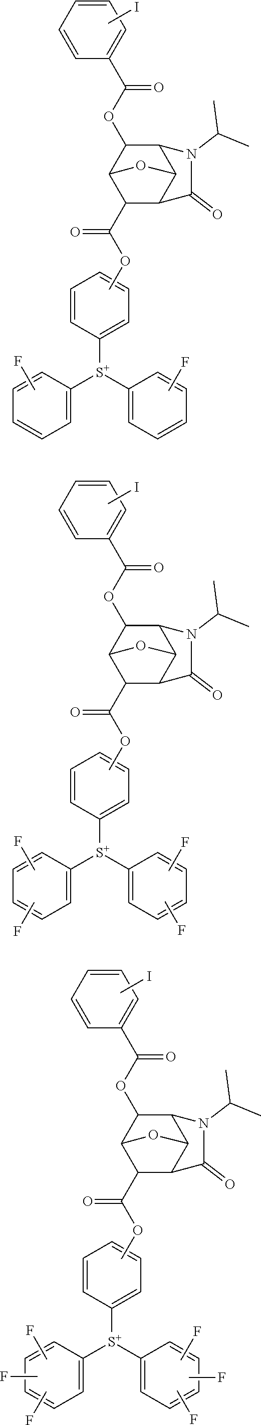

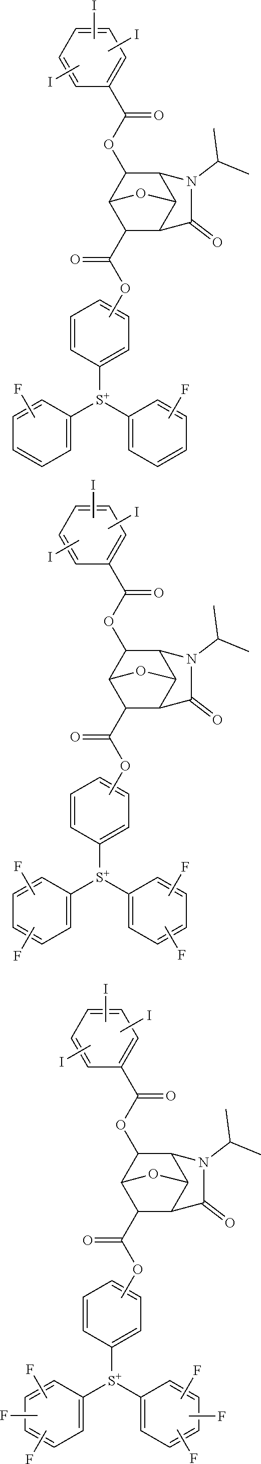

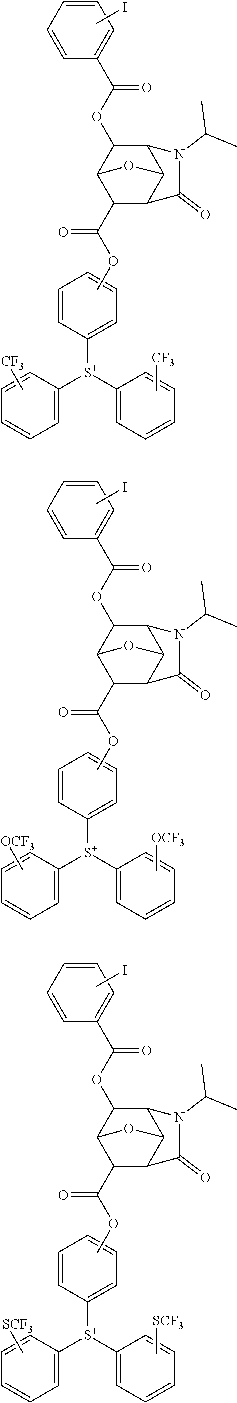

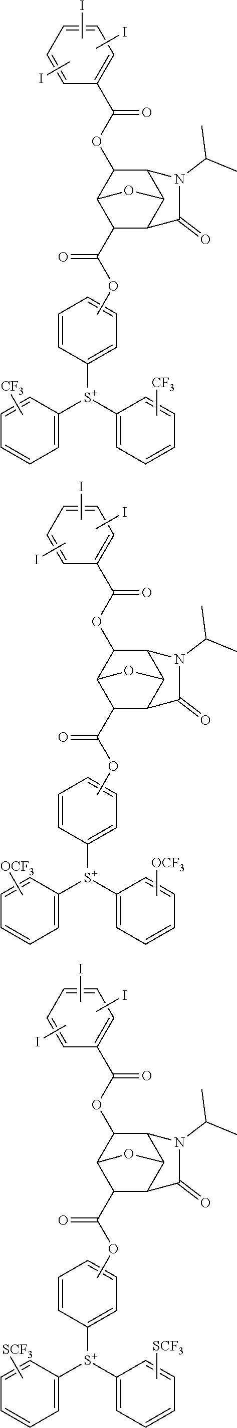

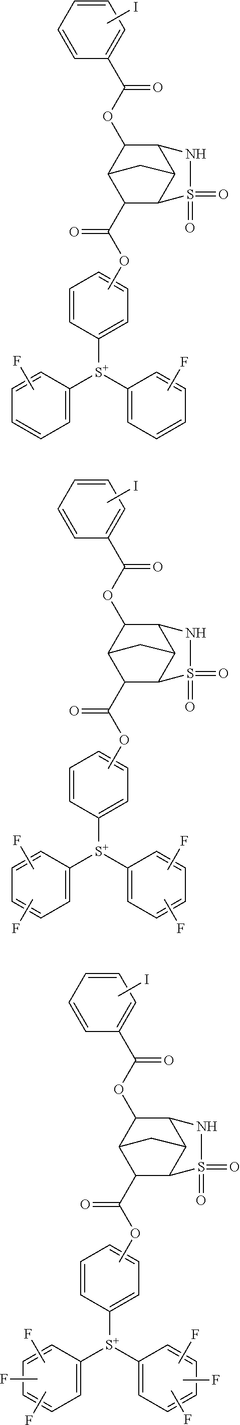

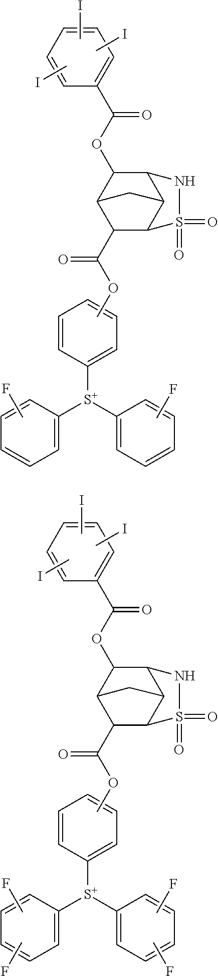

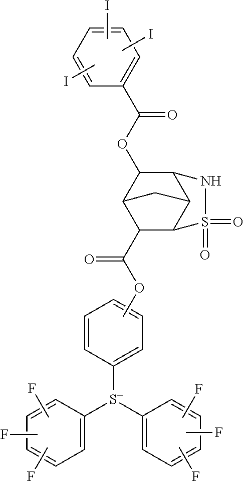

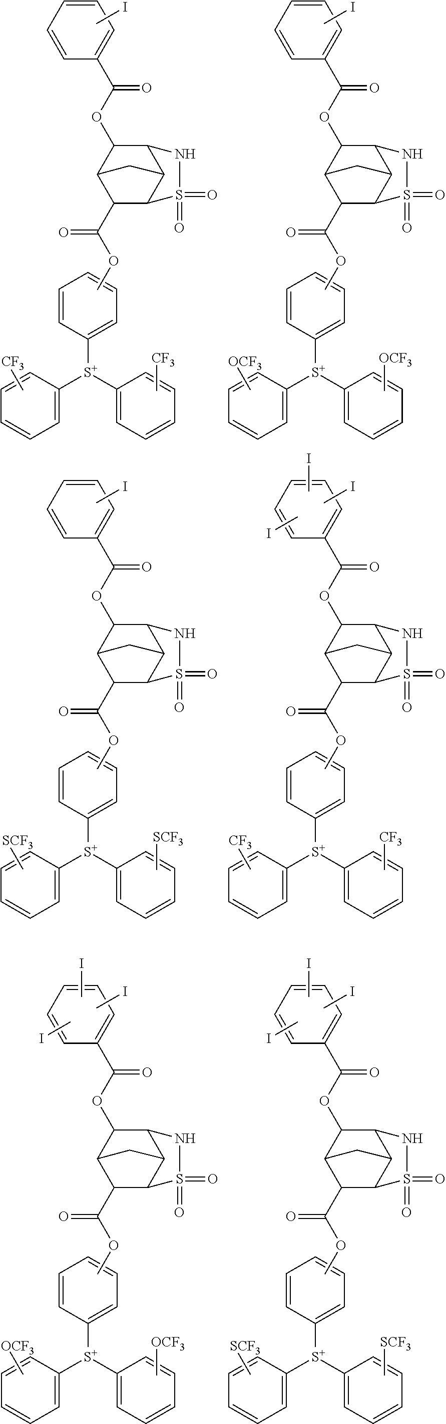

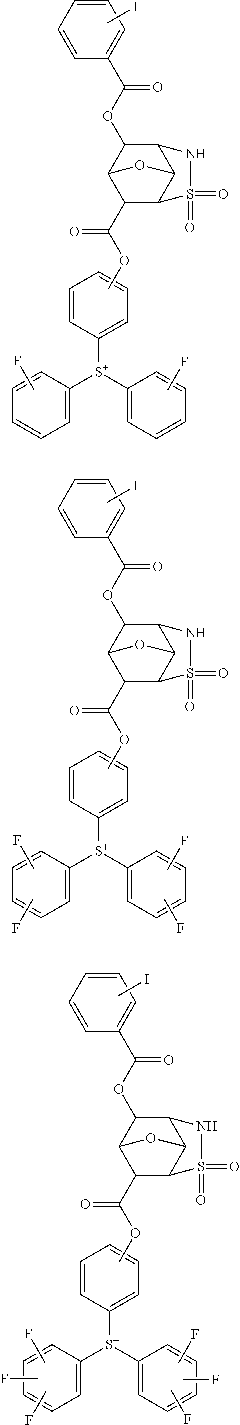

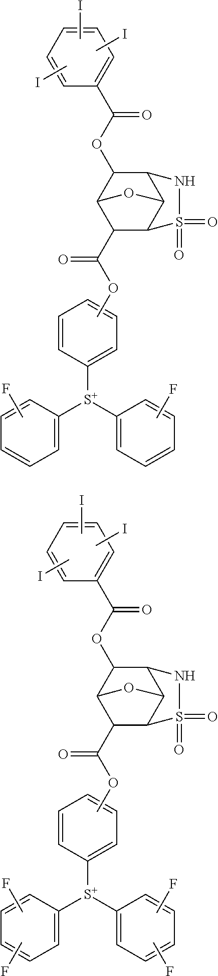

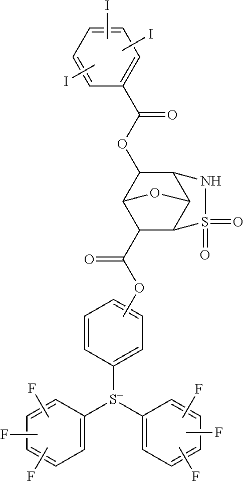

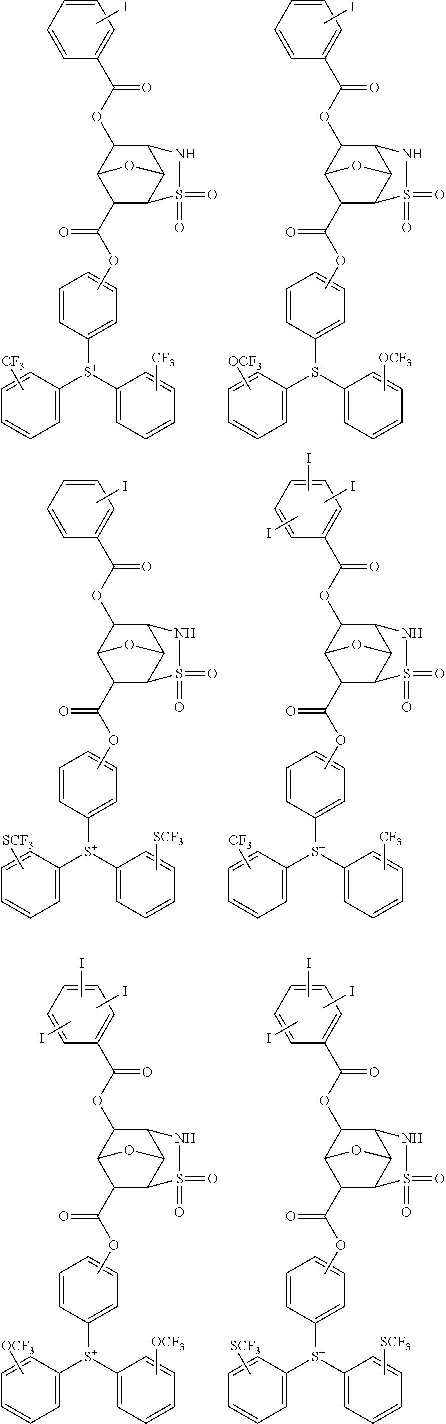

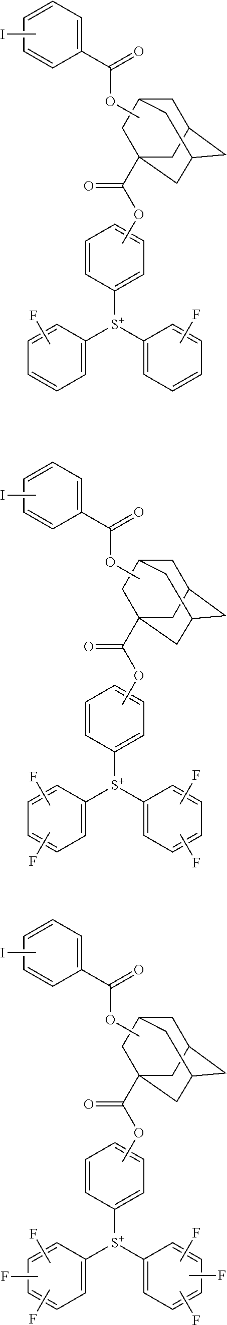

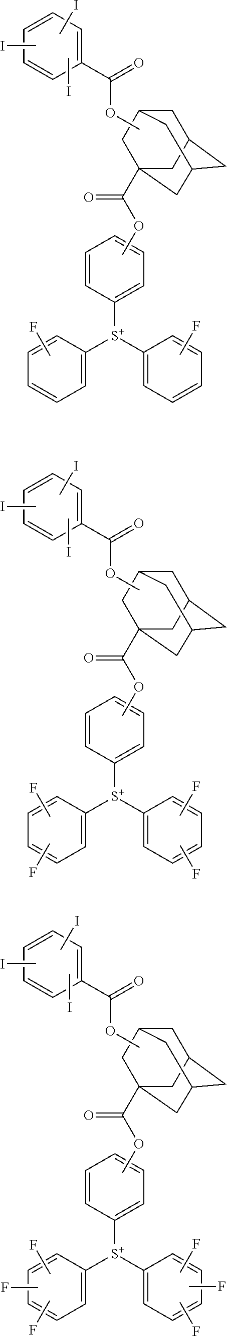

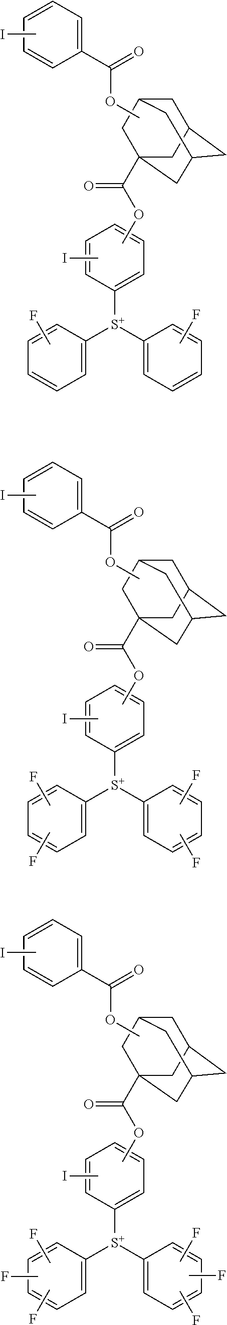

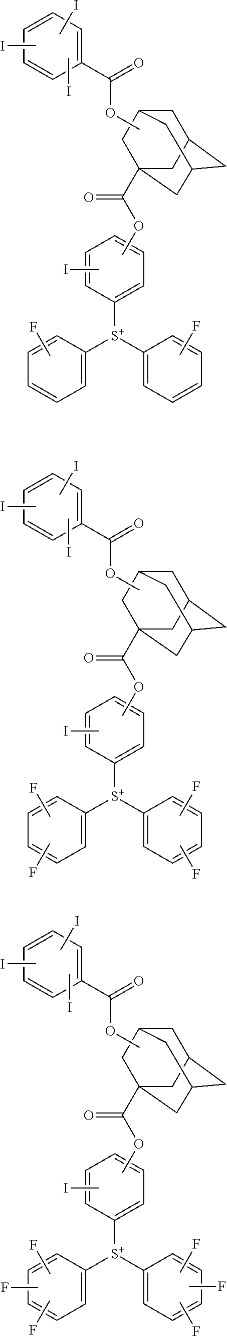

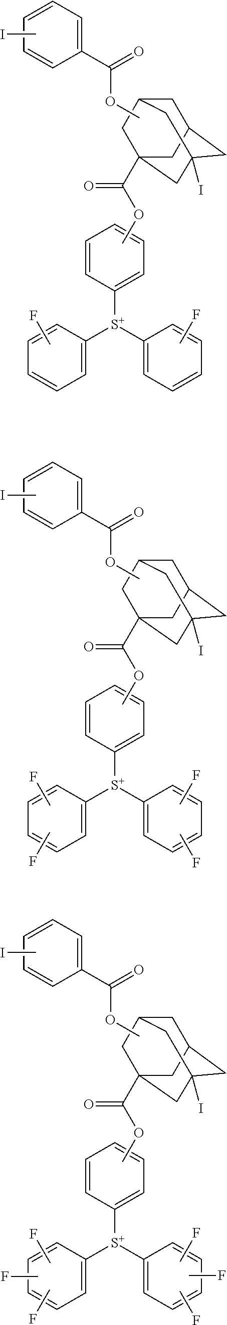

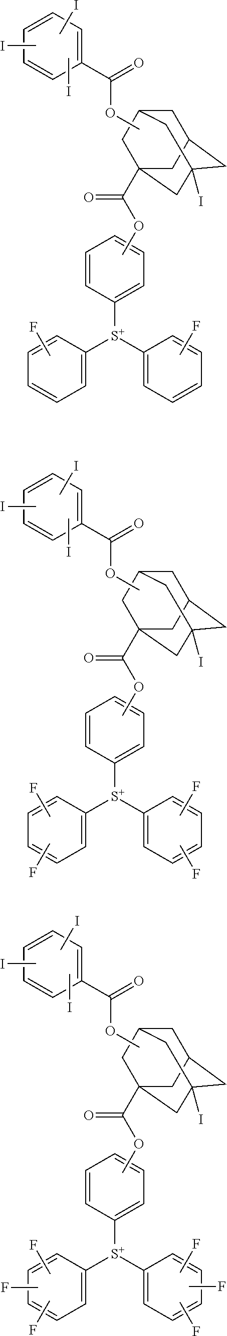

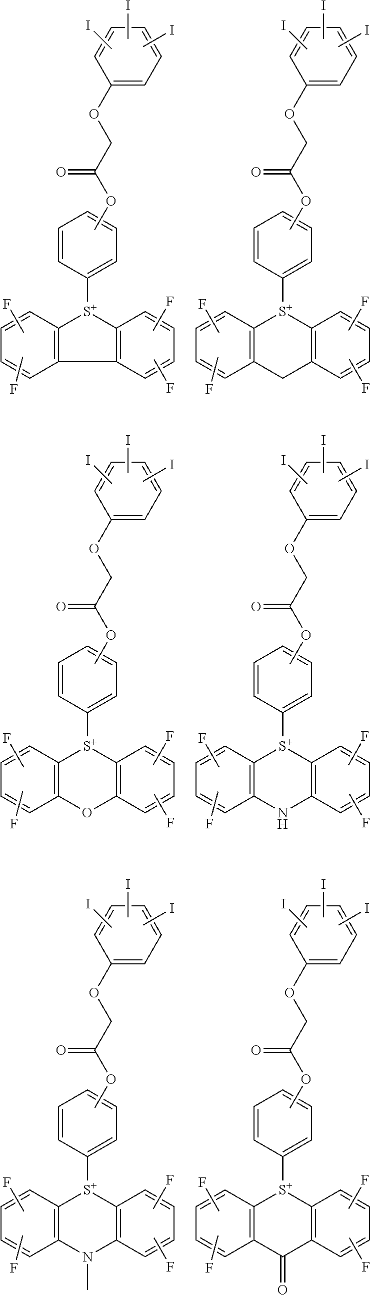

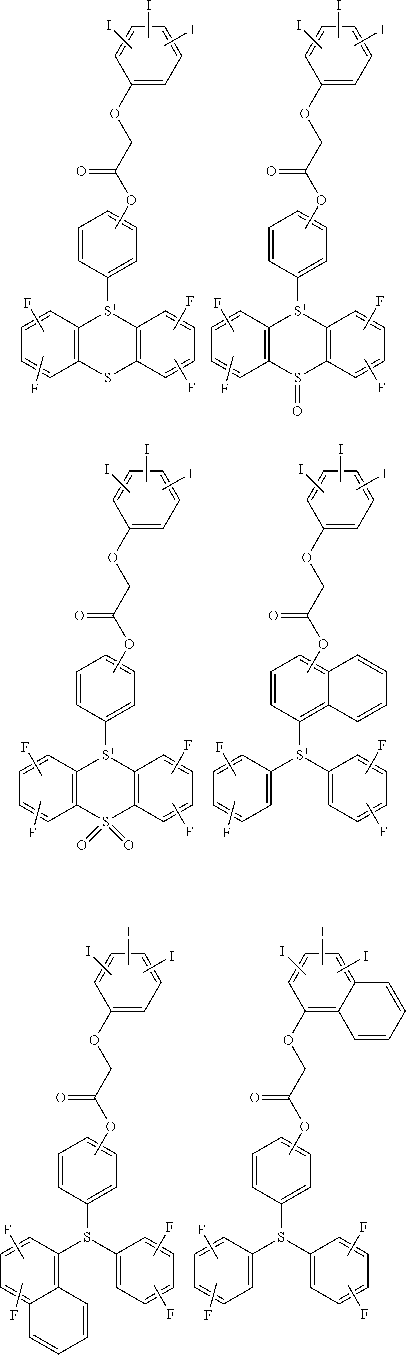

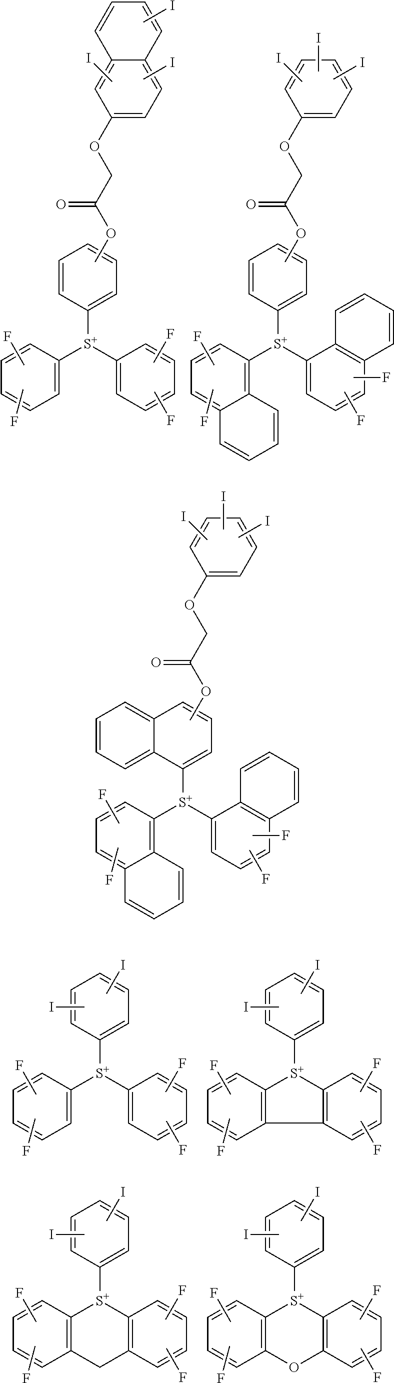

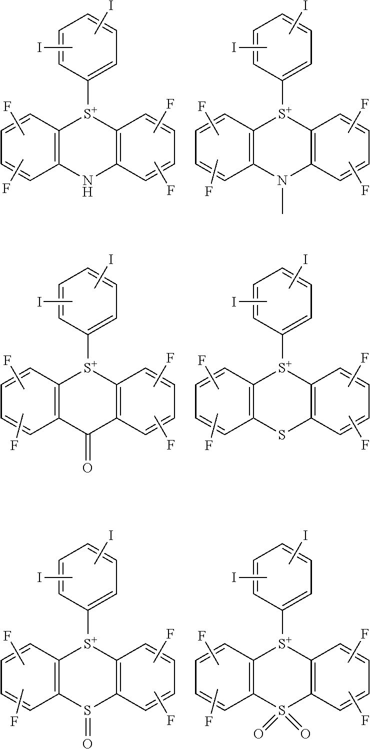

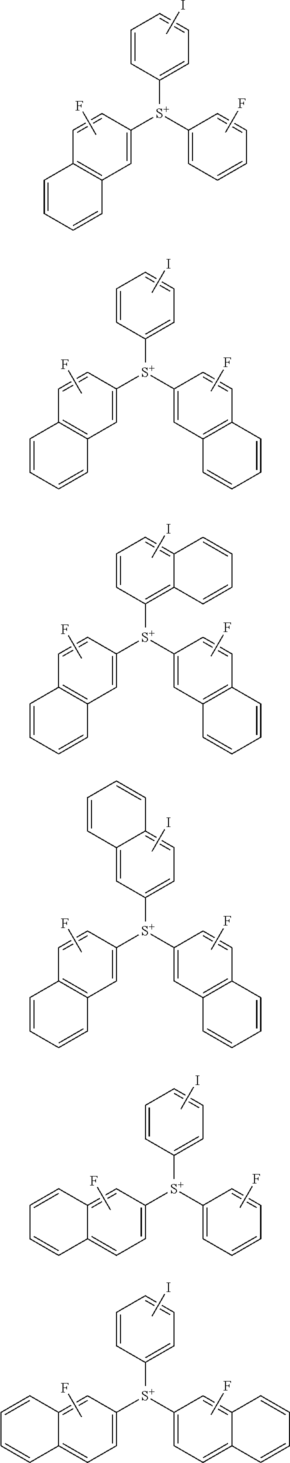

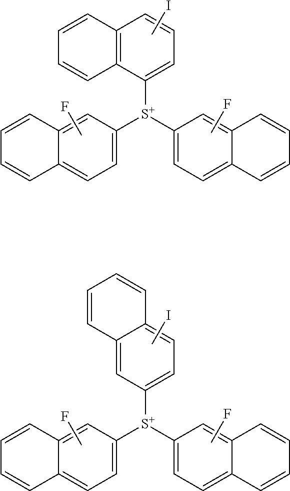

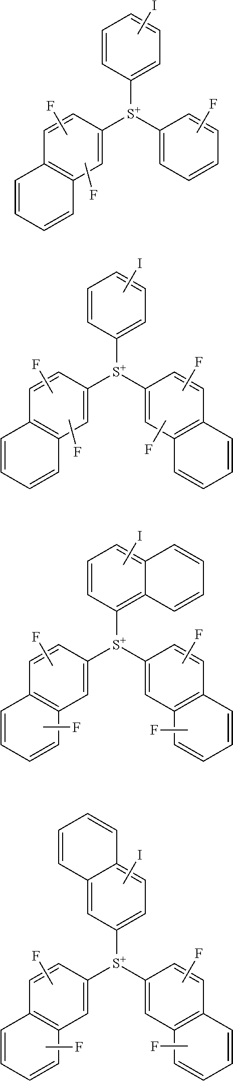

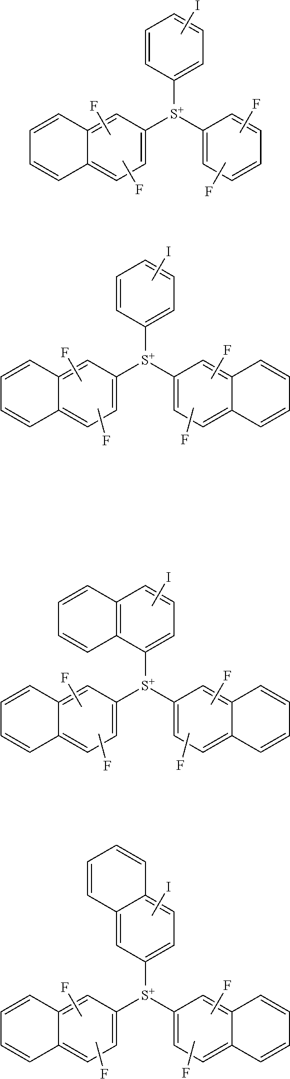

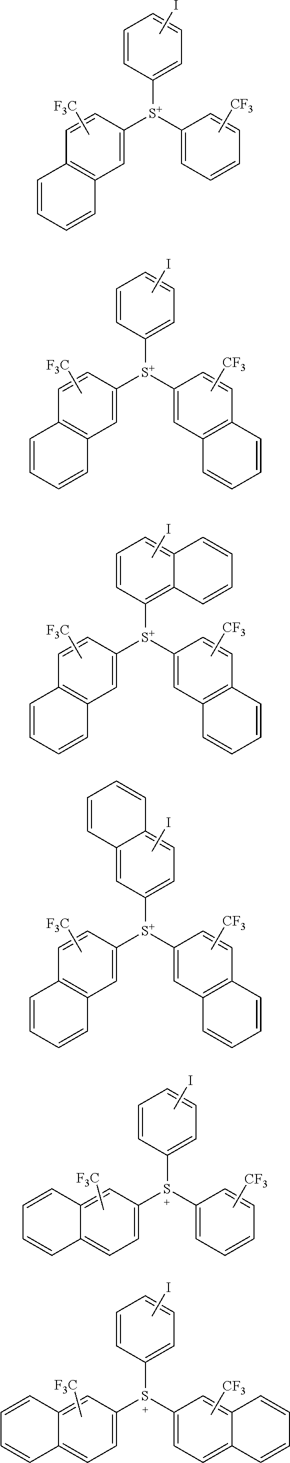

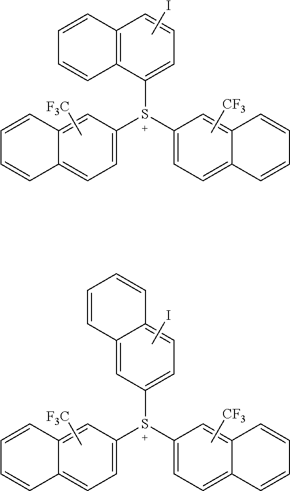

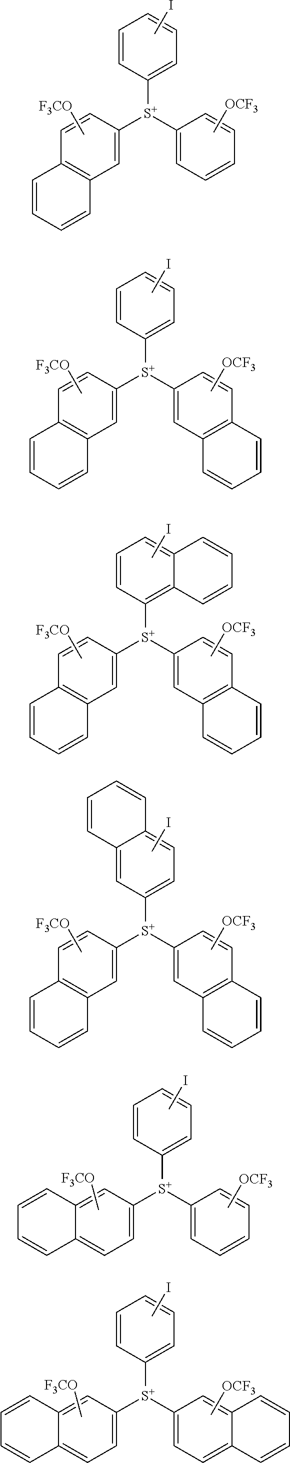

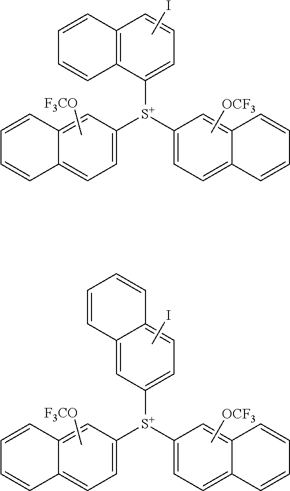

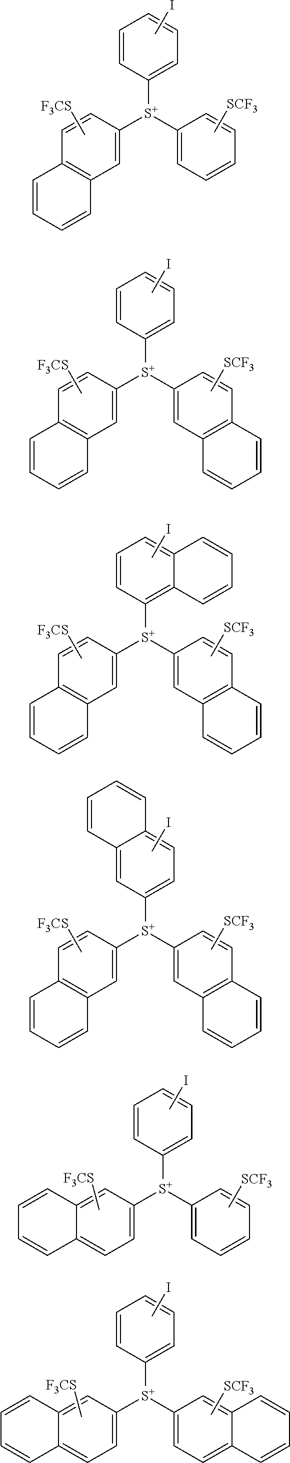

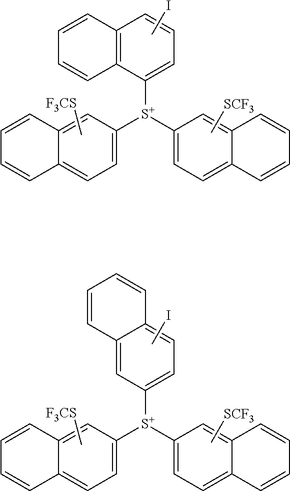

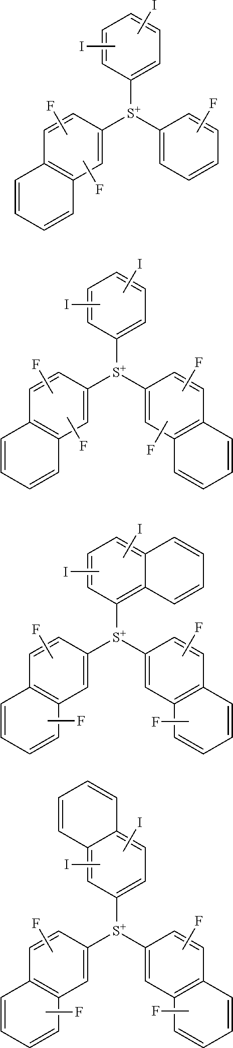

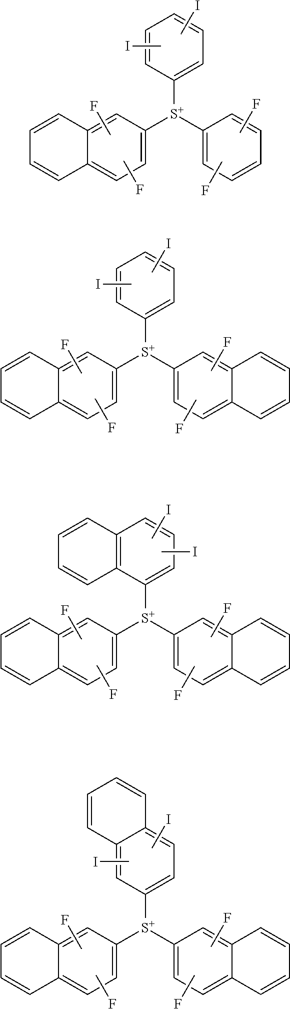

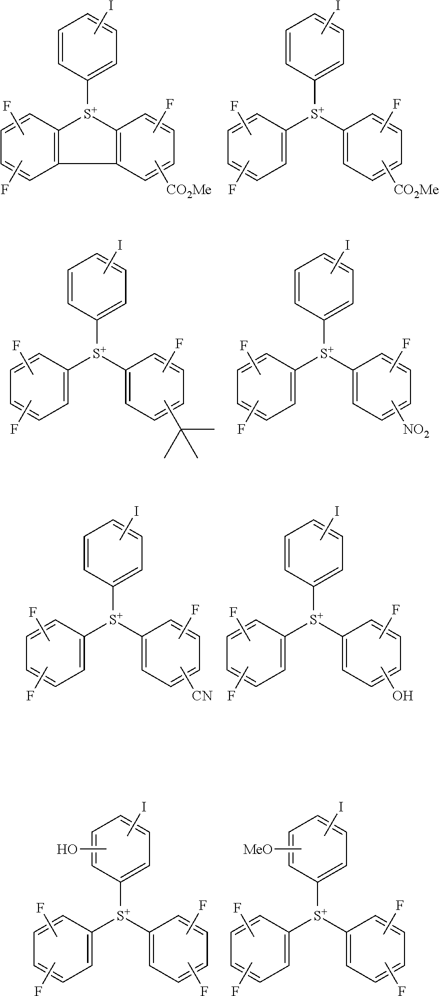

Exemplary structures of the repeat units (c1) to (c5) include arbitrary combinations of anions with cations, both as exemplified above.

Of the repeat units (c1) to (c5), the repeat units (c2) to (c5) are preferred from the aspect of controlling acid diffusion, the repeat units (c2), (c4), and (c5) are more preferred from the aspect of the acid strength of generated acid, and the repeat units (c2) are most preferred from the aspect of solvent solubility.

The base polymer may further comprise repeat units of a structure having a hydroxy group protected with an acid labile group, which are also referred to as repeat units (d). The repeat unit (d) is not particularly limited as long as the unit includes one or more structures having a hydroxy group protected with a protective group such that the protective group is decomposed to generate the hydroxy group under the action of acid, but repeat units having the formula (d1) are preferred.

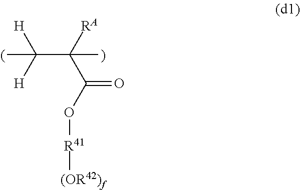

In formula (d1), R^{A} is as defined above. R⁴¹ is a C₁-C₃₀ (f+1)-valent hydrocarbon group which may contain a heteroatom. R⁴² is an acid labile group. f is 1, 2, 3, or 4.

In formula (d1), the acid labile group represented by R⁴² is deprotected under the action of acid so that a hydroxy group is generated. The structure of R⁴² is not particularly limited, but an acetal structure, ketal structure, alkoxycarbonyl group and alkoxymethyl group having the formula (d2) are preferred, with the alkoxymethyl group having the formula (d2) being most preferred.

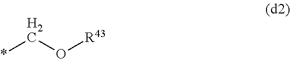

Herein * denotes a valence bond. R⁴³ is a C₁-C₁₅ hydrocarbyl group.

Examples of the acid labile group represented by R⁴², the alkoxymethyl group having formula (d2), and the repeat units (d) are as exemplified for the repeat units (d) in JP-A 2020-111564 (US 20200223796).

The base polymer may further comprise repeat units (e) derived from indene, benzofuran, benzothiophene, acenaphthylene, chromone, coumarin, norbornadiene or a derivative thereof. Examples of the monomer from which repeat units (e) are derived are shown below, but not limited thereto.

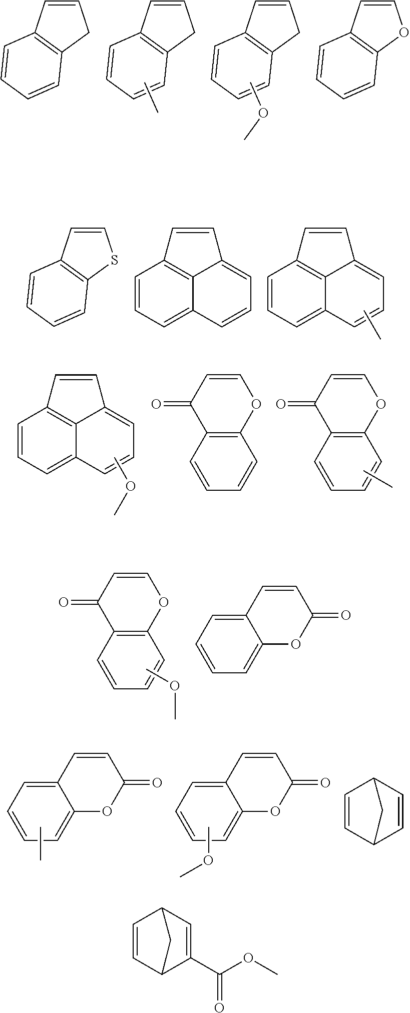

The base polymer may further comprise repeat units (f) derived from indane, vinylpyridine or vinylcarbazole.

In the polymer, repeat units (a1), (a2), (a3), (b1), (b2), (c1) to (c5), (d), (e), and (f) are incorporated in a ratio of preferably 0≤a1≤0.8, 0≤a2≤0.8, 0≤a3≤0.6, 0≤b1≤0.6, 0≤b2≤0.6, 0≤c1≤0.4, 0≤c2≤0.4, 0≤c3≤0.4, 0≤c4≤0.4, 0≤c5≤0.4, 0≤d≤0.5, 0≤e≤0.3, and 0≤f≤0.3; more preferably 0≤a1≤0.7, 0≤a2≤0.7, 0≤a30.5, 0≤b1≤0.5, 0≤b2≤05 0≤c1≤03 0≤c2≤0.3, 0≤c3≤0.3, 0≤c4≤0.3, 0≤c50.3, 0≤d≤0.3, 0≤e≤0.3, and 0≤f≤0.3. It is noted that

$$a 1 + a 2 + a 3 + b 1 + b 2 + c 1 + c 2 + c 3 + c 4 + d + e + f \leq 1.0 .$$

The polymer should preferably have a weight average molecular weight (Mw) in the range of 1,000 to 500,000, more preferably 3,000 to 100,000. A Mw in the range ensures that the resist film has sufficient etch resistance and eliminates the risk of resolution decline by a failure to provide a difference in dissolution rate before and after exposure. In the present invention, Mw is measured by gel permeation chromatography (GPC) versus polystyrene standards using THF or N,N-dimethylformamide (DMF) solvent.

The influence of the molecular weight distribution (Mw/Mn) of the polymer becomes stronger as the pattern rule becomes finer. Therefore, the polymer should preferably have a narrow dispersity (Mw/Mn) of 1.0 to 2.0 in order to provide a resist composition suitable for micropatterning to a small feature size. A Mw/Mn in the range ensures that the contents of lower and higher molecular weight polymer fractions are low and eliminates a possibility that foreign matter is left on the pattern or the pattern profile is degraded.

The polymer may be synthesized, for example, by dissolving a monomer or monomers corresponding to the above-mentioned repeat units in an organic solvent, adding a radical polymerization initiator, and heating for polymerization.

Examples of the organic solvent which can be used in the polymerization include toluene, benzene, THF, diethyl ether, dioxane, cyclohexane, cyclopentane, methyl ethyl ketone (MEK), propylene glycol monomethyl ether acetate (PGMEA), and y-butyrolactone (GBL). Examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of initiator added is preferably 0.01 to 25 mol % based on the total of monomers to be polymerized. The reaction temperature is preferably 50 to 150° C., more preferably 60 to 100° C. The reaction time is preferably 2 to 24 hours, more preferably 2 to 12 hours from the aspect of production efficiency.

The polymerization initiator may be fed to the reactor either by adding the initiator to the monomer solution and feeding the solution to the reactor, or by dissolving the initiator in a solvent to form an initiator solution and feeding the initiator solution and the monomer solution separately to the reactor. Because of a possibility that in the standby duration, the initiator generates a radical which triggers polymerization reaction to form an ultra high molecular-weight polymer, it is preferred from the aspect of quality control to prepare the monomer solution and the initiator solution separately and add them dropwise. The acid labile group that has been incorporated in the monomer may be kept as such, or polymerization may be followed by protection or partial protection. During the polymer synthesis, any known chain transfer agent such as dodecyl mercaptan or 2-mercaptoethanol may be added for molecular weight control purpose. The amount of chain transfer agent added is preferably 0.01 to 20 mol % based on the total of monomers to be polymerized.

When a hydroxy-containing monomer is copolymerized, the hydroxy group may be substituted by an acetal moiety which is susceptible to deprotection with acid, typically ethoxyethoxy, prior to polymerization, and the polymerization may be followed by deprotection with weak acid and water. Alternatively, the hydroxy group may be substituted by an acetyl, formyl or pivaloyl moiety prior to polymerization, and the polymerization may be followed by alkaline hydrolysis.

When hydroxystyrene or hydroxyvinylnaphthalene is copolymerized, one method is dissolving hydroxystyrene or hydroxyvinylnaphthalene and other monomers in an organic solvent, adding a radical polymerization initiator thereto, and heating the solution for polymerization. In an alternative method, acetoxystyrene or acetoxyvinylnaphthalene is used instead, and after polymerization, the acetoxy group is deprotected by alkaline hydrolysis, for thereby converting the polymer product to polyhydroxystyrene or hydroxypolyvinylnaphthalene.

For alkaline hydrolysis, a base such as aqueous ammonia or triethylamine may be used. The reaction temperature is preferably −20 to 100° C., more preferably 0 to 60° C. The reaction time is preferably 0.2 to 100 hours, more preferably 0.5 to 20 hours.

The amounts of monomers in the monomer solution may be determined appropriate so as to provide the preferred fractions of repeat units.

It is now described how to use the polymer obtained by the above production method. The reaction solution resulting from polymerization reaction may be used as the final product. Alternatively, the polymer may be recovered in powder form through a purifying step such as re-precipitation step of adding the polymerization solution to a poor solvent and letting the polymer precipitate as powder, after which the polymer powder is used as the final product. It is preferred from the aspects of operation efficiency and consistent quality to handle a polymer solution which is obtained by dissolving the powder polymer resulting from the purifying step in a solvent, as the final product.

The solvents which can be used herein are described in JP-A 2008-111103, paragraphs [0144]-[0145] (U.S. Pat. No. 7,537,880). Exemplary solvents include ketones such as cyclohexanone and methyl-2-n-pentyl ketone; alcohols such as 3-methoxybutanol, 3-methyl-3-methoxybutanol, 1-methoxy-2-propanol, and 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate (EL), ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; alcohols such as diacetone alcohol (DAA); high-boiling alcohols such as diethylene glycol, propylene glycol, glycerol, 1,4-butanediol, and 1,3-butanediol; and mixtures thereof.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign matter and gel which can cause defects are removed.

Suitable materials of which the filter used for filtration is made include fluorocarbon, cellulose, nylon, polyester, and hydrocarbon base materials. Preferred for the filtration of a resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 nm. A single filter may be used or a plurality of filters may be used in combination. Although the filtering method may be single pass of the solution, preferably the filtering step is repeated by flowing the solution in a circulating manner. In the polymer production process, the filtering step may be carried out any times, in any order and in any stage. The reaction solution as polymerized or the polymer solution may be filtered, preferably both are filtered.

The base polymer (B) may be used alone or as a combination of two or more polymers which differ in compositional ratio, Mw and/or Mw/Mn. The base polymer (B) may also contain a hydrogenated ring-opened metathesis polymer in addition to the polymer. For the ring-opening metathesis polymer, one described in JP-A 2003-066612 can be used.

### (C) Organic Solvent

The chemically amplified resist composition of the invention may comprise an organic solvent as component (C). The organic solvent (C) is not particularly limited as long as the components described above and below are soluble therein. Examples of the organic solvent include ketones such as cyclopentanone, cyclohexanone, and methyl-2-n-pentyl ketone; alcohols such as 3-methoxybutanol, 3-methyl-3-methoxybutanol, 1-methoxy-2-propanol, and 1-ethoxy-2-propanol; keto-alcohols such as DAA; ethers such as PGME, ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, EL, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; and mixtures thereof.

Of the foregoing organic solvents, 1-ethoxy-2-propanol, PGMEA, cyclohexanone, GBL, EL, DAA and mixtures thereof are preferred because the base polymer (B) is most soluble therein.

The amount of the organic solvent (C) in the chemically amplified resist composition of the invention is preferably 200 to 8,000 parts by weight, more preferably 400 to 6,000 parts by weight per 80 parts by weight of the base polymer (B). The organic solvent (C) may be used alone or in admixture of two or more.

### (D) Quencher

The chemically amplified resist composition of the invention may comprise a quencher as component (D). As used herein, the term “quencher” refers to a compound capable of trapping the strong acid generated by a photoacid generator in the chemically amplified resist composition to prevent the acid from diffusing to the unexposed region and to assist in forming the desired pattern.

Examples of the quencher (D) include an onium salt having the formula (2) or (3).

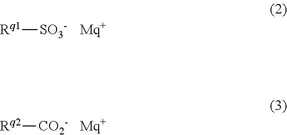

In formula (2), R^{q1} is hydrogen or a C₁-C₄₀ hydrocarbyl group which may contain a heteroatom, exclusive of the group wherein hydrogen bonded to the carbon atom at α-position relative to the sulfo group is substituted by fluorine or fluoroalkyl. In formula (3), R^{q2} is hydrogen or a C₁-C₄₀ hydrocarbyl group which may contain a heteroatom.

Examples of the C₁-C₄₀ hydrocarbyl group represented by R^{q1} include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl; C₆-C₄₀ aryl groups such as phenyl, naphthyl and anthracenyl. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

Examples of the hydrocarbyl group represented by R^{q2} include substituents exemplified above for R^{q1} as well as fluorinated saturated hydrocarbyl groups such as trifluoromethyl and trifluoroethyl, and fluorinated aryl groups such as pentafluorophenyl and 4-trifluoromethylphenyl.

Examples of the anion in the onium salt having formula (2) are shown below, but not limited thereto.

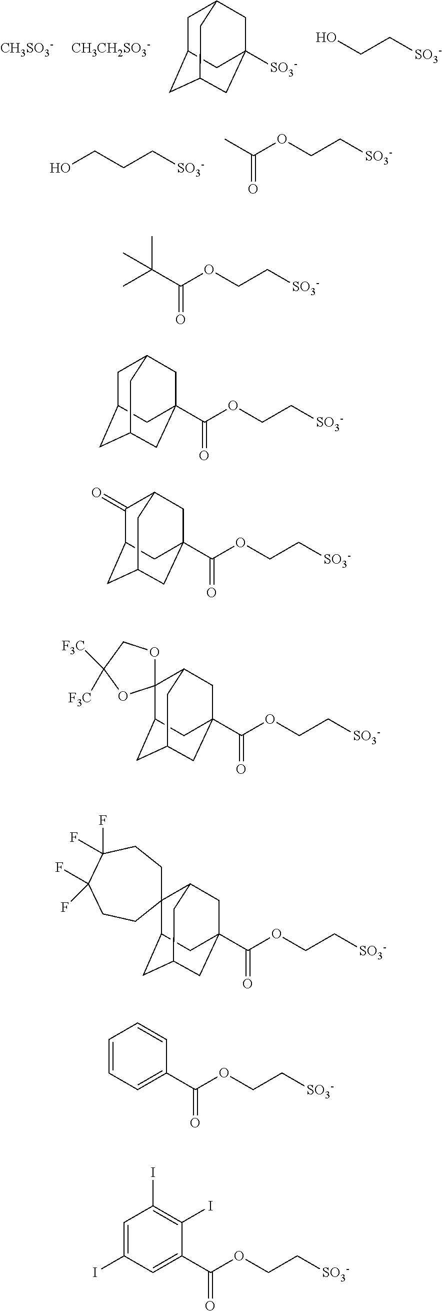

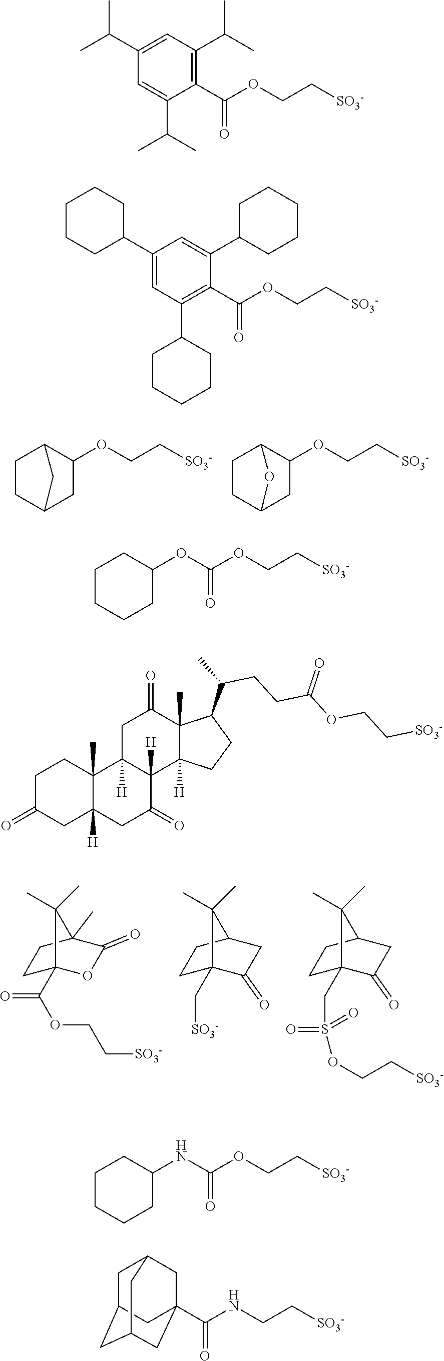

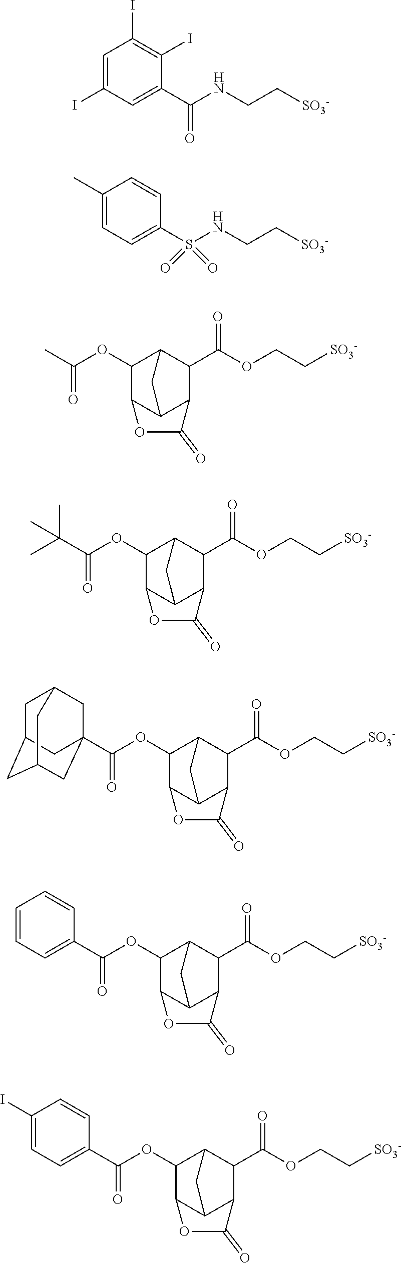

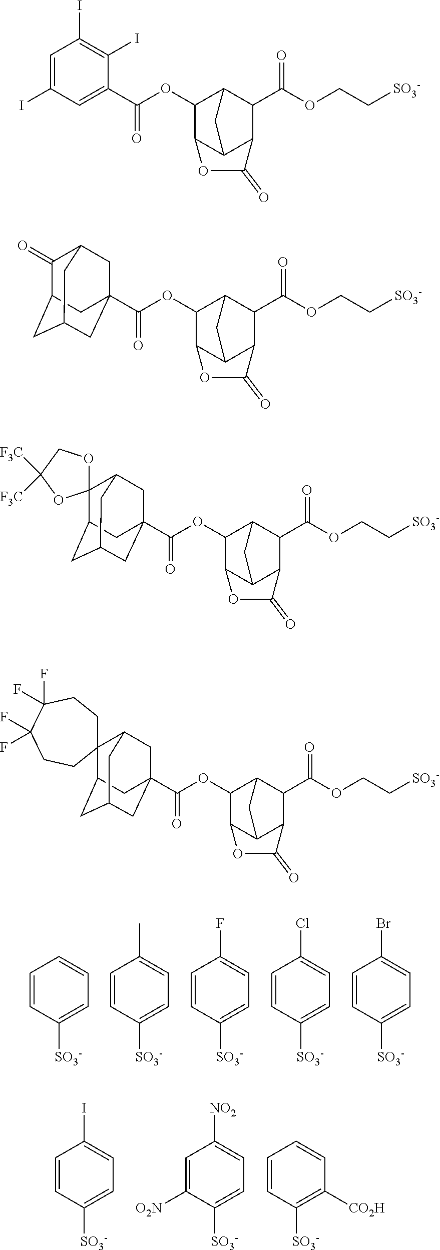

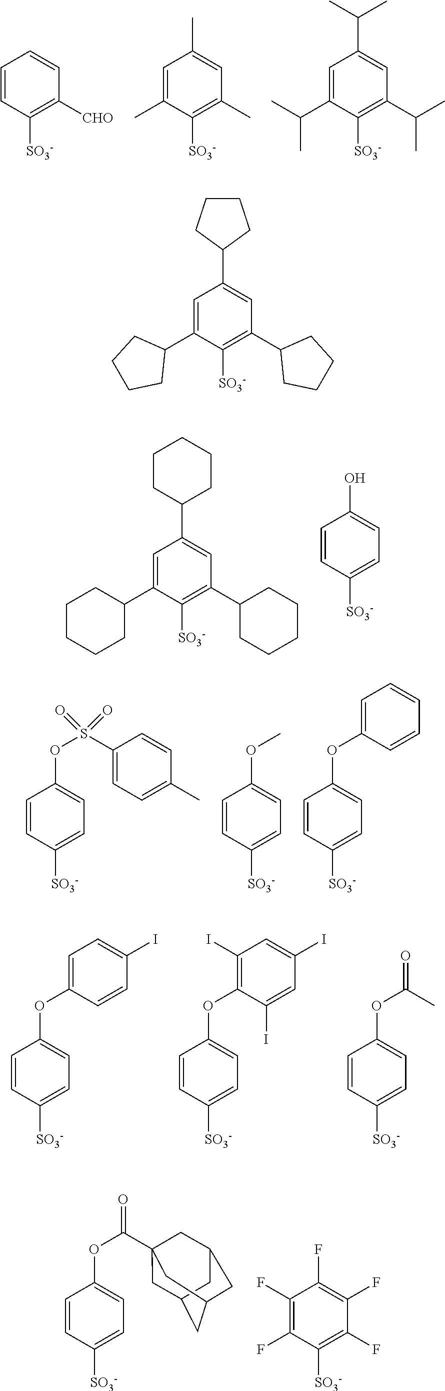

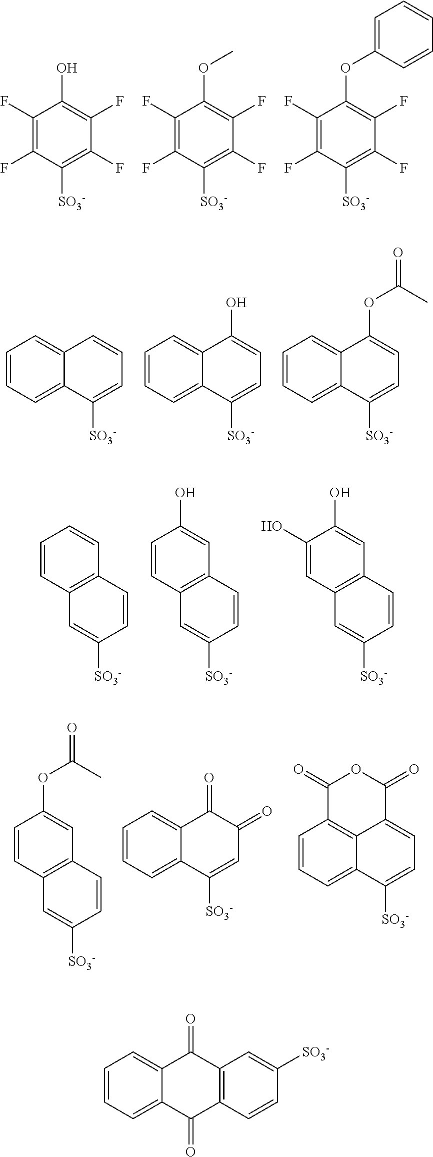

Examples of the anion in the onium salt having formula (3) are shown below, but not limited thereto.

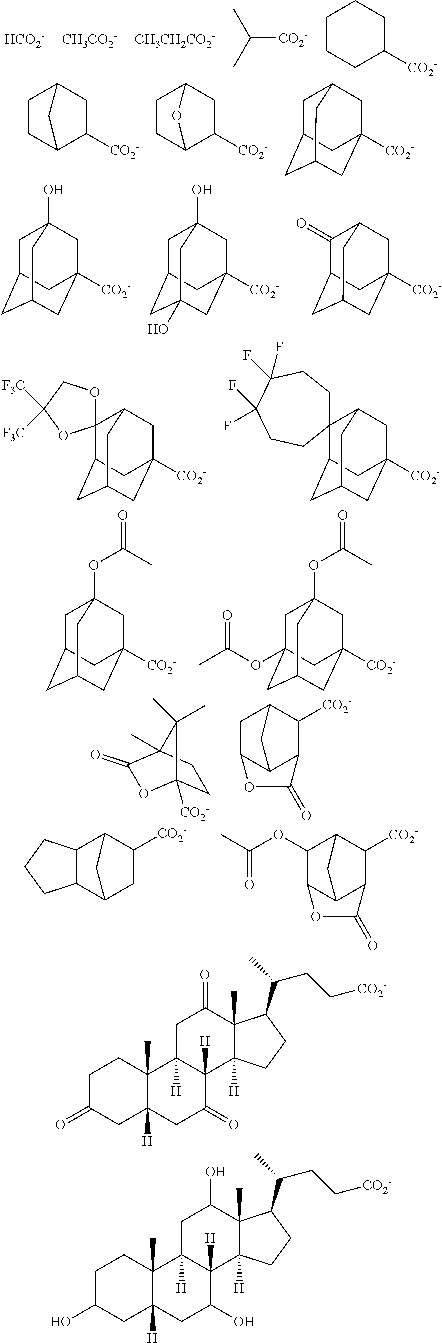

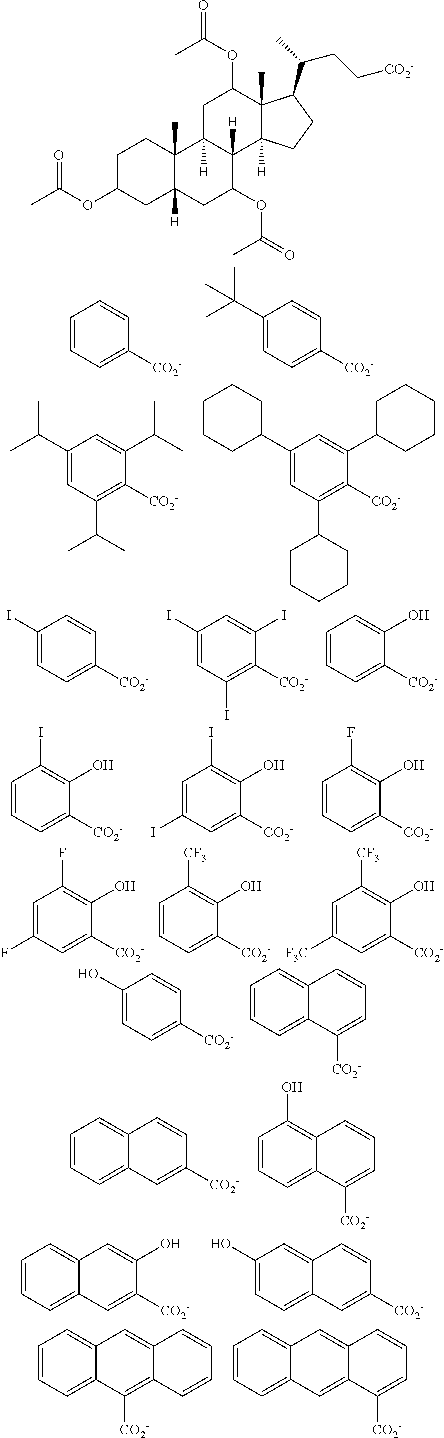

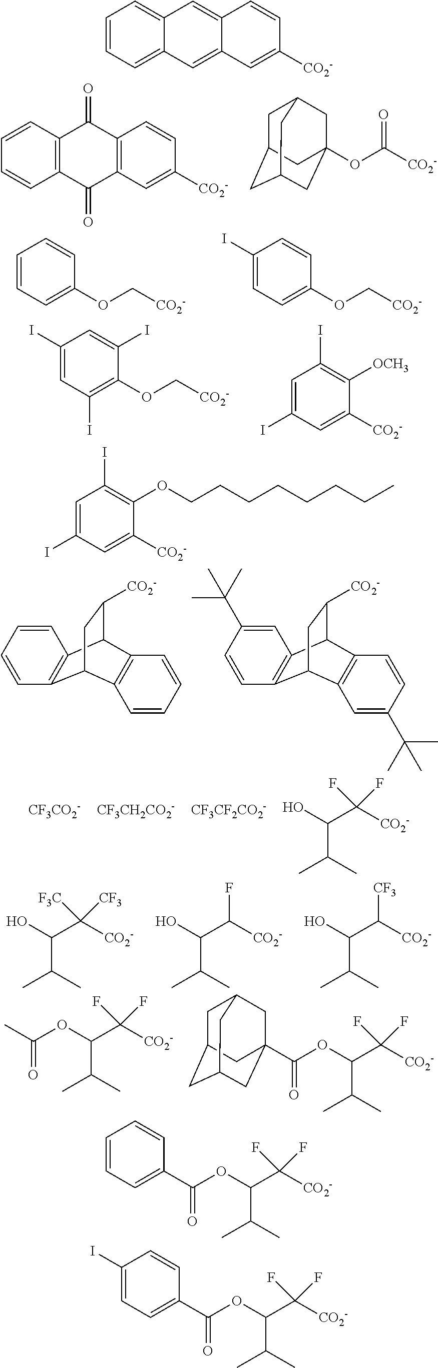

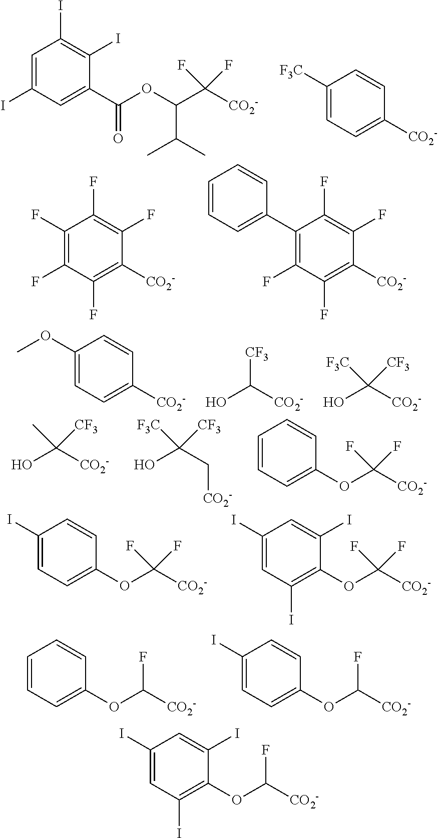

In formulae (2) and (3), Mq⁺ is an onium cation. Examples of the onium cation include sulfonium, iodonium and ammonium cations. Examples of the sulfonium cation and the iodonium cation are as exemplified above for the sulfonium cation and the iodonium cation represented by Z⁺ in formulae (c2) to (c5), but not limited thereto. Examples of the ammonium cation include those having the formula (am-1).

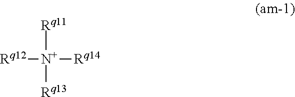

In formula (am-1), R^{q11} to R^{q14} are each independently a C₁-C₄₀ hydrocarbyl group which may contain a heteroatom. R^{q11} and R^{q12} may bond together to form a ring with the nitrogen atoms to which they are attached. Examples of the hydrocarbyl group are as exemplified above for the hydrocarbyl group represented by R¹ in formula (1).

Examples of the ammonium cation having formula (am-1) include those shown below, but are not limited thereto.

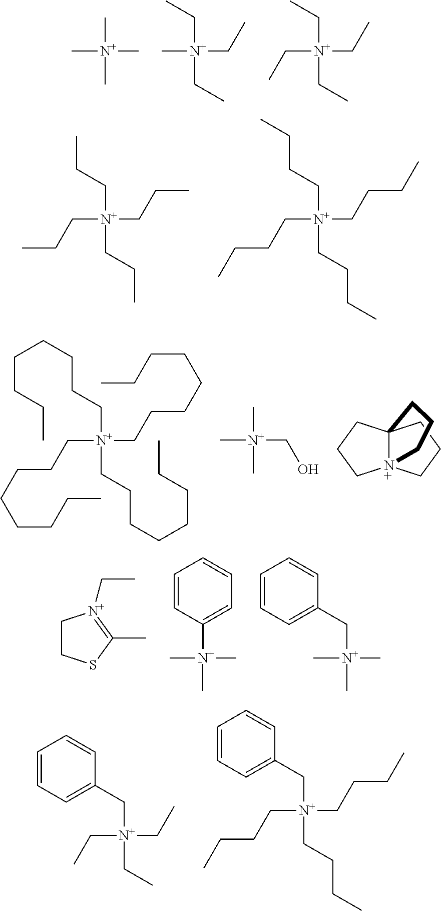

Examples of the onium salt having formula (2) or (3) include arbitrary combinations of anions with cations, both as exemplified above. These onium salts may be readily prepared by ion exchange reaction using any well-known organic chemistry technique. For the ion exchange reaction, reference may be made to JP-A 2007-145797, for example.

The onium salt having formula (2) or (3) functions as a quencher in the chemically amplified resist composition of the invention because the counter anion of the onium salt is a conjugated base of a weak acid. As used herein, the weak acid indicates an acidity insufficient to deprotect an acid labile group from an acid labile group-containing unit in the base polymer. The onium salt having formula (2) or (3) functions as a quencher when used in combination with an onium salt type photoacid generator having a conjugate base of a strong acid (e.g., α-fluorinated sulfonic acid) as the counter anion. In a system using a mixture of an onium salt capable of generating a strong acid (e.g., α-fluorinated sulfonic acid) and an onium salt capable of generating a weak acid (e.g., non-fluorinated sulfonic acid or carboxylic acid), if the strong acid generated from the photoacid generator upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a lower catalysis, incurring apparent deactivation of the acid for enabling to control acid diffusion.

Also, as the quencher (D), onium salts having sulfonium cation and phenoxide anion sites in a common molecule as described in JP 6848776, onium salts having sulfonium cation and carboxylate anion sites in a common molecule as described in JP 6583136 and JP-A 2020-200311, and onium salts having iodonium cation and carboxylate anion sites in a common molecule as described in JP 6274755 can also be used.

If a photoacid generator capable of generating a strong acid is an onium salt, an exchange from the strong acid generated upon exposure to high-energy radiation to a weak acid can take place as mentioned above, but it rarely happens that the weak acid generated upon exposure to high-energy radiation collides with the unreacted onium salt capable of generating a strong acid to induce a salt exchange. This is because of the phenomenon that an onium cation is more likely to form an ion pair with a stronger acid anion.

When the chemically amplified resist composition of the invention comprises the onium salt having formula (2) or (3) as the quencher (D), the amount of the onium salt is preferably 0.1 to 20 parts by weight, more preferably 0.1 to 10 parts by weight per 80 parts by weight of the base polymer (B). As long as the amount of onium salt type quencher (D) is in the range, a satisfactory resolution is available without a substantial lowering of sensitivity. The onium salt having formula (2) or (3) can be used alone or in combination of two or more.

The chemically amplified resist composition of the invention may also comprise a nitrogen-containing compound as the quencher (D). Examples of the nitrogen-containing compound of the component (D) include primary, secondary and tertiary amine compounds, specifically amine compounds having a hydroxy group, ether bond, ester bond, lactone ring, cyano group or sulfonate ester bond, as described in JP-A 2008-111103, paragraphs [0146]-[0164] (U.S. Pat. No. 7,537,880), and primary or secondary amine compounds protected with a carbamate group, as described in JP 3790649.

A sulfonic acid sulfonium salt having a nitrogen-containing substituent may also be used as the nitrogen-containing compound. This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595 and JP-A 2012-046501, for example.

When the chemically amplified resist composition of the invention comprises the nitrogen-containing compound as the quencher (D), the amount of the nitrogen-containing compound is preferably 0.001 to 12 parts by weight, more preferably 0.01 to 8 parts by weight per 80 parts by weight of the base polymer (B). The nitrogen-containing compound may be used alone or in combination of two or more.

### (E) Other Photoacid Generator

The chemically amplified resist composition of the invention may comprise a photoacid generator other than the component (A), which is also referred to as other photoacid generator, as the component (E). The other photoacid generator is not particularly limited as long as it is a compound that generates an acid upon exposure to high-energy radiation. Preferred examples of other photoacid generator include those having the formula (4) or (5).

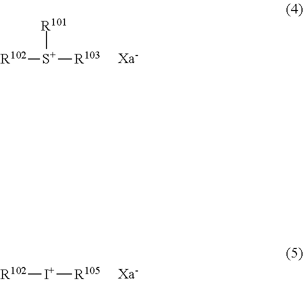

In formula (4), R¹⁰¹ to R¹⁰⁵ are each independently a C₁-C₂₀ hydrocarbyl group which may contain a heteroatom. Any two of R¹⁰¹, R¹⁰² and R¹⁰³ may bond together to form a ring with the sulfur atoms to which they are attached.

Examples of the sulfonium cation in the salt having formula (4) and the iodonium cation in the salt having formula (5) are as exemplified above for the sulfonium cation and the iodonium cation represented by Z⁺ in formulae (c2) to (c5), but not limited thereto.

In formulae (4) and (5), Xa⁻ is an anion of strong acid. Examples of the anion of strong acid include those having any of formulae (c1-1) to (c1-5).

Compounds having the formula (6) are also preferred as the other photoacid generator (E).

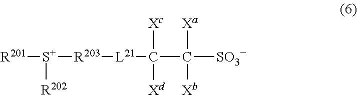

In formula (6), R²⁰¹ and R²⁰² are each independently a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atoms to which they are attached.

The C₁-C₃₀ hydrocarbyl group represented by R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, tert-pentyl, n-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decyl, and adamantyl; C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl; and combinations thereof. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

The C₁-C₃₀ hydrocarbylene group represented by R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl, and adamantanediyl; and arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene. In the hydrocarbylene group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety. Of the heteroatoms, oxygen is preferred.

In formula (6), L²¹ is a single bond, ether bond or a C₁-C₂₀ hydrocarbylene group which may contain a heteroatom. The hydrocarbylene group may be saturated or unsaturated and straight, branched or cyclic. Examples thereof are as exemplified above for the hydrocarbylene group represented by R²⁰³.

In formula (6), X^{a}, X^{b}, X^{c} and X^{d} are each independently hydrogen, fluorine or trifluoromethyl, at least one of X^{a}, X^{b}, X^{c} and X^{d} being fluorine or trifluoromethyl.

Of the photoacid generators having formula (6), those having the formula (6′) are preferred.

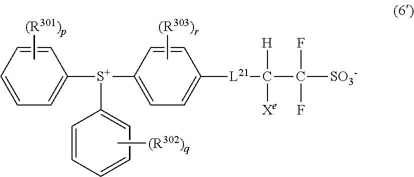

In formula (6′), L²¹ is as defined above. Xe is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for the hydrocarbyl group represented by R¹¹ in formula (c1-1-1). p and q are each independently 0, 1, 2, 3, 4, or 5, and r is 0, 1, 2, 3, or 4.

Examples of the photoacid generator having formula (6) include those exemplified for the photoacid generator having formula (2) in JP-A 2017-026980.

Of the other photoacid generators, those having an anion having formula (c1-1-1) or (c1-4) are especially preferred because of reduced acid diffusion and high solubility in solvents. Also those having formula (6′) are especially preferred because of extremely reduced acid diffusion.

When the chemically amplified resist composition of the invention comprises the other photoacid generator (E), the amount thereof is preferably 0.1 to 40 parts by weight, more preferably 0.5 to 20 parts by weight per 80 parts by weight of the base polymer (B). As long as the amount of the other photoacid generator (E) is in the range, good resolution is achievable and the risk of foreign matter being formed after development or during stripping of resist film is avoided. The other photoacid generator (E) may be used alone or in combination of two or more.

### (F) Surfactant

The chemically amplified resist composition of the invention may further comprise a surfactant as component (F). The surfactant (F) is preferably a surfactant which is insoluble or substantially insoluble in water and soluble in alkaline developer, or a surfactant which is insoluble or substantially insoluble in water and alkaline developer. For the surfactant, reference may be made to those described in JP-A 2010-215608 and JP-A 2011-016746.

Of the surfactants described in the patent documents cited herein, preferred surfactants which are insoluble or substantially insoluble in water and alkaline developer are surfactants FC-4430 (3M), Surflon® 5-381 (AGC Seimi Chemical Co., Ltd.), Olfine® E1004 (Nissin Chemical Co., Ltd.), and KH-20 and KH-30 (AGC Seimi Chemical Co., Ltd.). Oxetane ring-opened polymers having the formula (surf-1) are also preferred.

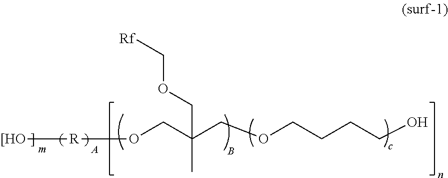

It is provided herein that R, Rf, A, B, C, m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

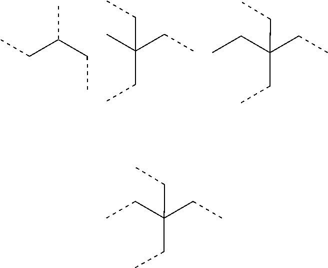

Herein the broken line is a valence bond. These formulae are partial structures derived from glycerol, trimethylol ethane, trimethylol propane, and pentaerythritol, respectively.

Among them, 1,4-butylene and 2,2-dimethyl-1,3-propylene are preferred.

Rf is trifluoromethyl or pentafluoroethyl, and preferably trifluoromethyl. m is an integer of 0 to 3, n is an integer of 1 to 4, and the sum of m and n, which represents the valence of R, is an integer of 2 to 4. A is 1. B is an integer of 2 to 25, preferably an integer of 4 to 20. C is an integer of 0 to 10, preferably an integer of 0 or 1. Note that the formula (surf-1) does not prescribe the arrangement of respective constituent units while they may be arranged either blockwise or randomly. For the production of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the resist surface for achieving a function of minimizing water penetration or leaching. The surfactant is also effective for preventing water-soluble components from being leached out of the resist film for minimizing any damage to the exposure tool. The surfactant becomes solubilized during aqueous alkaline development following exposure or post-exposure bake (PEB), and thus forms few or no foreign matter which become defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Examples of the polymeric surfactant include those containing repeat units having at least one type selected from the formulae (7A) to (7E).

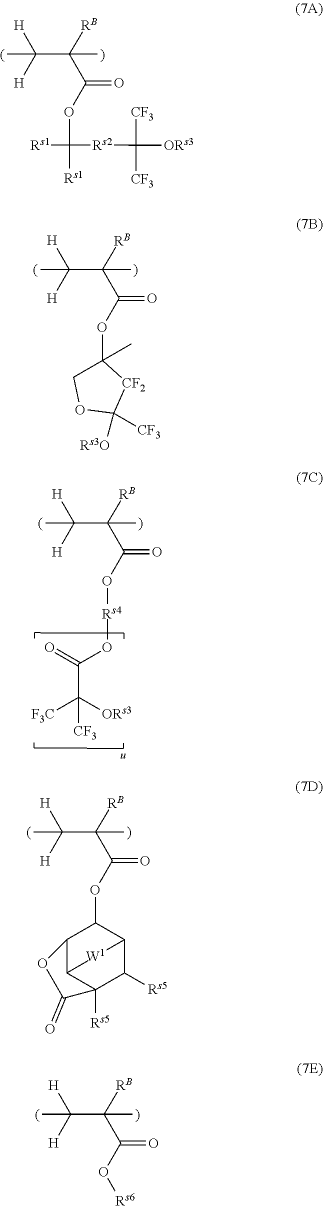

In formulae (7A) to (7E), R^{B} is hydrogen, fluorine, methyl or trifluoromethyl.

W¹ is —CH₂—, —CH₂CH₂—, —O—, or two separate —H. R^{s1} is each independently hydrogen or a C₁-C₁₀ hydrocarbyl group. R^{s2} is a single bond or a C₁-C₅ straight or branched hydrocarbylene group. R^{s3} is each independently hydrogen, a C₁-C₁₅ hydrocarbyl or fluorinated hydrocarbyl group, or an acid labile group. When R^{s3} is a hydrocarbyl or fluorinated hydrocarbyl group, an ether bond or carbonyl moiety may intervene in a carbon-carbon bond. R^{s4} is a C₁-C₂₀ (u+1)-valent hydrocarbon or fluorinated hydrocarbon group, and u is 1, 2, or 3. R^{s5} is each independently hydrogen or a group represented by —C(═O)—O—R^{sa} wherein R^{s5} is a C₁-C₂₀ fluorinated hydrocarbyl group. R^{s6} is a C₁-C₁₅ hydrocarbyl or fluorinated hydrocarbyl group in which an ether bond or carbonyl moiety may intervene in a carbon-carbon bond.

The C₁-C₁₀ hydrocarbyl group represented by R^{s1} is preferably saturated and may be straight, branched or cyclic. Examples thereof include C₁-C₁₀ alkyl groups such as methyl, ethyl, n-propyl, isopropyl, n-butyl, isobutyl, sec-butyl, tert-butyl, n-pentyl, n-hexyl, n-heptyl, n-octyl, n-nonyl, and n-decyl, and C₃-C₁₀ cyclic saturated hydrocarbyl groups such as cyclopropyl, cyclobutyl, cyclopentyl, cyclohexyl, adamantyl, and norbornyl. Of these, C₁-C₆ hydrocarbyl groups are preferred.

The hydrocarbylene group represented by R^{s2} is preferably saturated and may be straight, branched or cyclic. Examples thereof include methylene, ethylene, propylene, butylene, and pentylene.

The hydrocarbyl group represented by R^{s3} or R^{s6} may be saturated or unsaturated and straight, branched or cyclic. Examples thereof include saturated hydrocarbyl groups, and aliphatic unsaturated hydrocarbyl groups such as alkenyl and alkynyl groups, with the saturated hydrocarbyl groups being preferred. Examples of the saturated hydrocarbyl groups include those exemplified for the hydrocarbyl group represented by R^{s1} as well as undecyl, dodecyl, tridecyl, tetradecyl, and pentadecyl. Examples of the fluorinated hydrocarbyl group represented by R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group represented by R^{s3} include groups of the above formulae (AL-3) to (AL-5), trialkylsilyl groups in which each alkyl moiety has 1 to 6 carbon atoms, and C₄-C₂₀ oxoalkyl groups.

The (u+1)-valent hydrocarbon or fluorinated hydrocarbon group represented by R^{s4} may be straight, branched or cyclic, and examples thereof include the foregoing hydrocarbyl or fluorinated hydrocarbyl groups from which “u” number of hydrogen atoms are eliminated.

The fluorinated hydrocarbyl group represented by R^{s8} is preferably saturated and may be straight, branched or cyclic. Examples thereof include the foregoing hydrocarbyl groups in which some or all of the hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl, 2-(perfluorohexyl)ethyl, 2-(perfluorooctyl)ethyl, and 2-(perfluorodecyl)ethyl.

Examples of the repeat units having any of formulae (7A) to (7E) are shown below, but not limited thereto. In the formulae, R^{B} is as defined above.

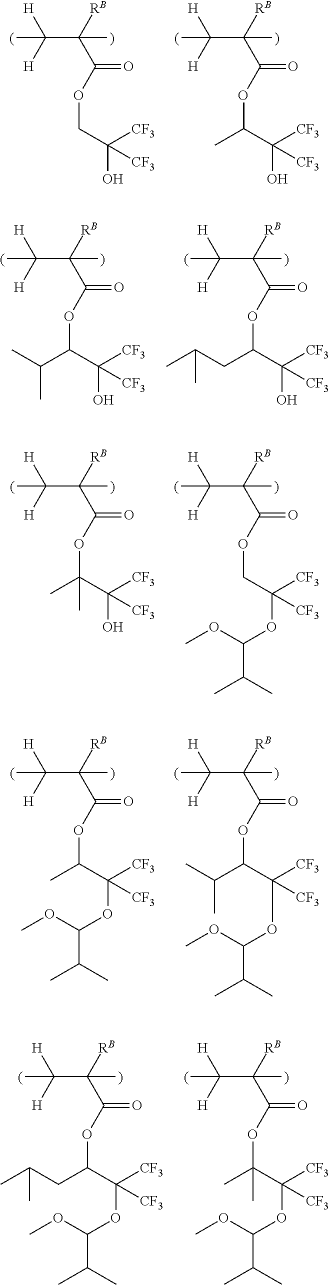

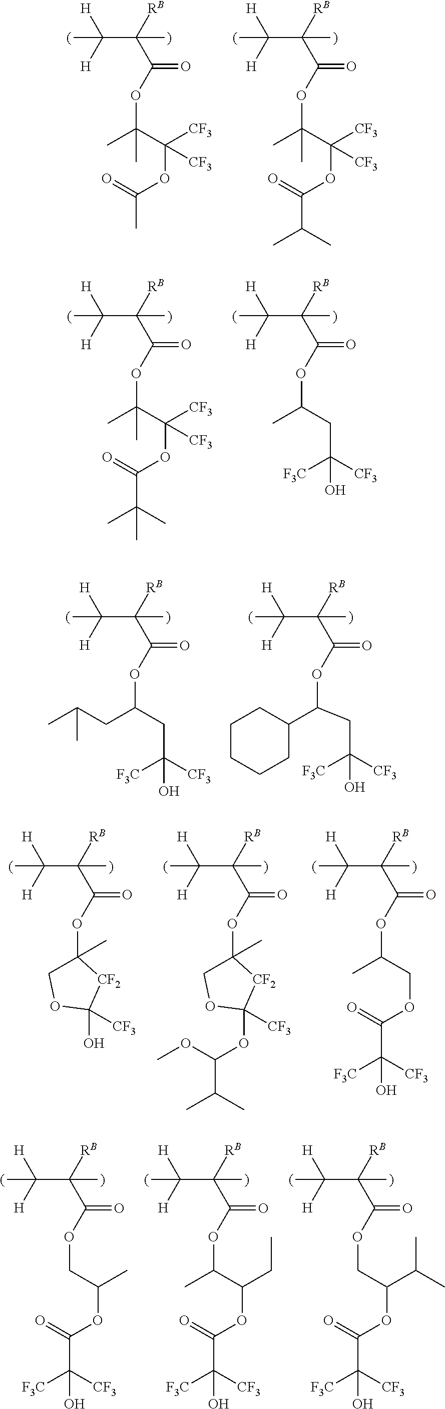

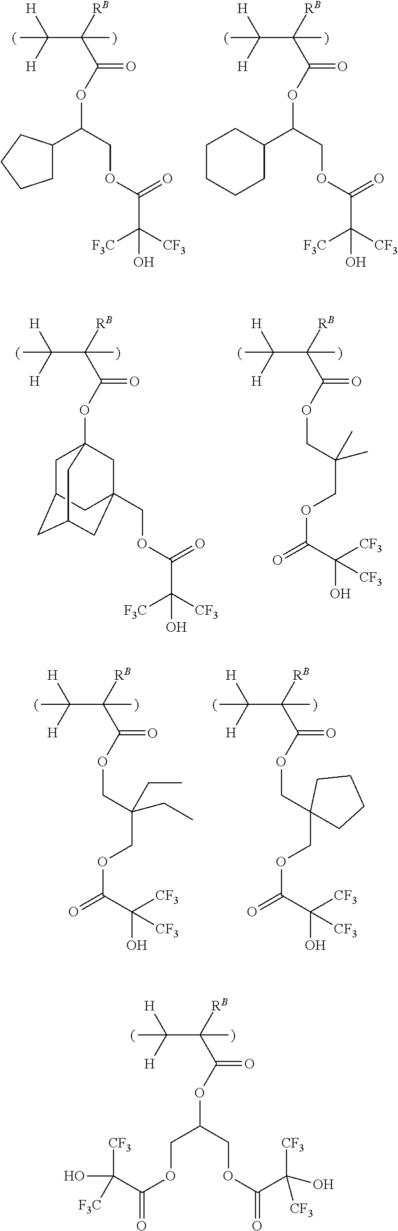

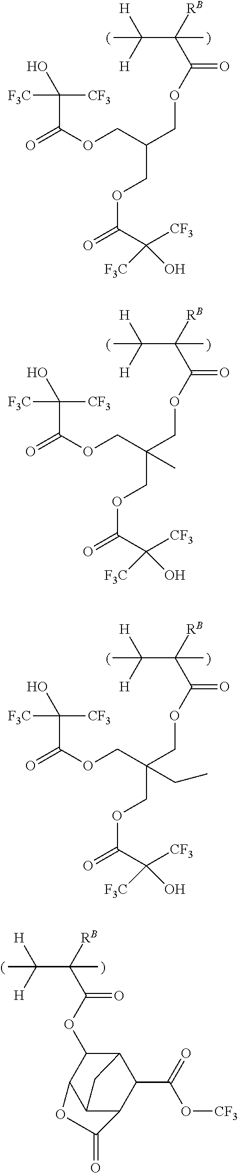

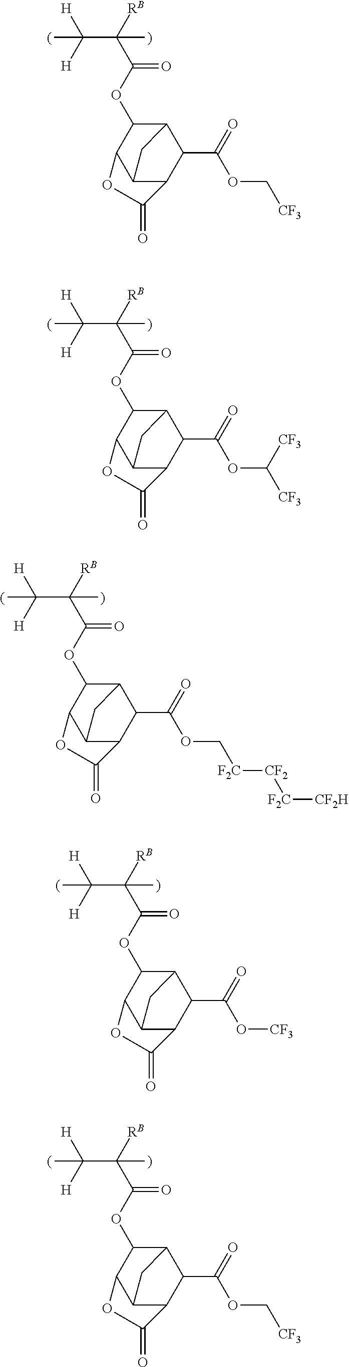

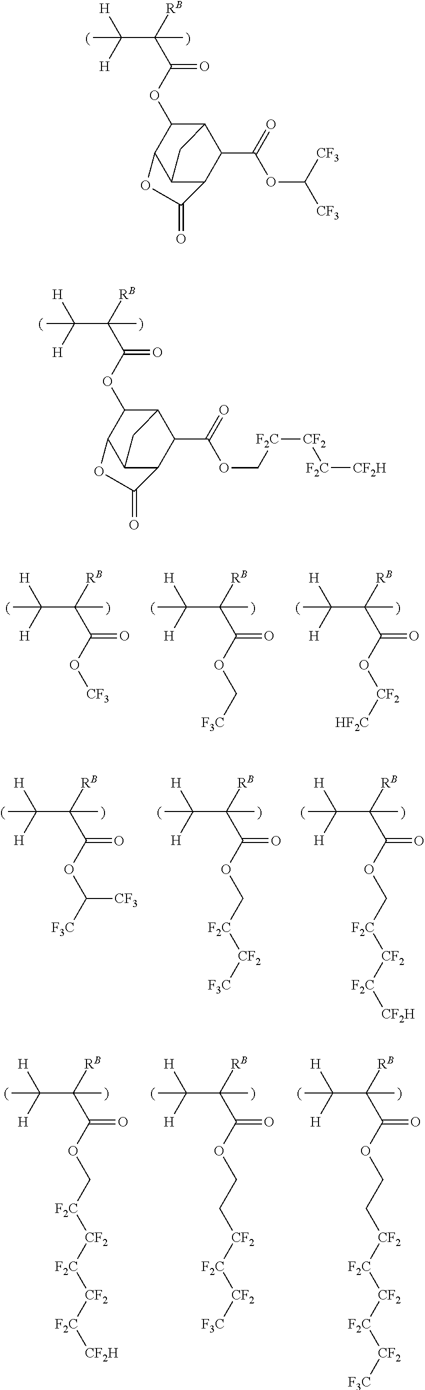

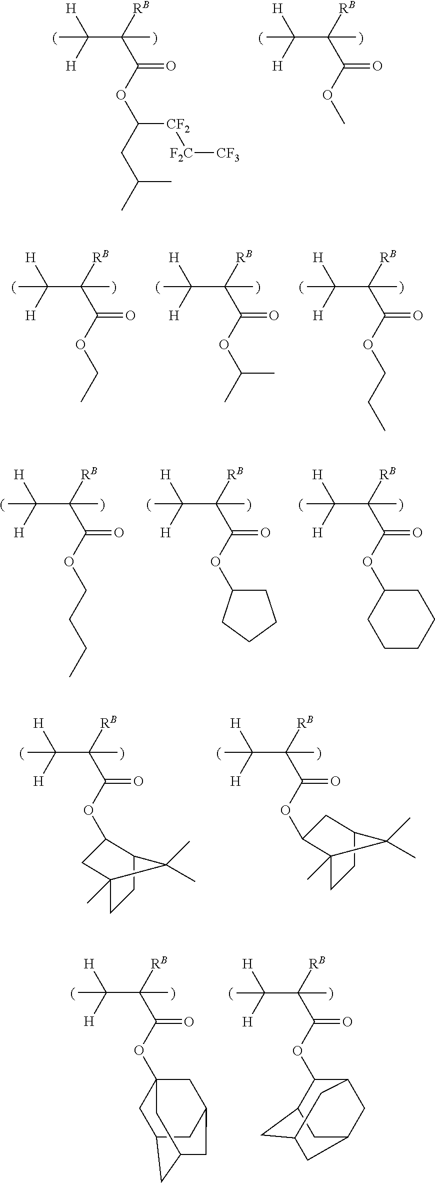

The polymeric surfactant may further contain repeat units other than the repeat units having formulae (7A) to (7E). Examples of the other repeat units include those derived from methacrylic acid and α-trifluoromethylacrylic acid derivatives. In the polymeric surfactant, the content of the repeat units having formulae (7A) to (7E) is preferably at least 20 mol %, more preferably at least 60 mol %, most preferably 100 mol % of the overall repeat units.

The polymeric surfactant preferably has a Mw of 1,000 to 500,000, more preferably 3,000 to 100,000, and a Mw/Mn of 1.0 to 2.0, more preferably 1.0 to 1.6.

The polymeric surfactant may be synthesized, for example, by dissolving an unsaturated bond-containing monomer or monomers providing repeat units having formulae (7A) to (7E) and optionally other repeat units in an organic solvent, adding a radical initiator, and heating for polymerization. Examples of the organic solvents used in the polymerization include toluene, benzene, THF, diethyl ether, and dioxane. Examples of the polymerization initiator include AIBN, 2,2′-azobis(2,4-dimethylvaleronitrile), dimethyl 2,2-azobis(2-methylpropionate), benzoyl peroxide, and lauroyl peroxide. Preferably, the reaction temperature is 50 to 100° C. and the reaction time is 4 to 24 hours. The acid labile group that has been incorporated in the monomer may be kept as such, or polymerization may be followed by protection or partial protection.

During the synthesis of polymeric surfactant, any known chain transfer agent such as dodecyl mercaptan or 2-mercaptoethanol may be added for molecular weight control purpose. The amount of chain transfer agent added is preferably 0.01 to 10 mol % based on the total moles of monomers to be polymerized.

When the chemically amplified resist composition of the invention comprises the surfactant (F), the amount thereof is preferably 0.1 to 50 parts by weight, more preferably 0.5 to 10 parts by weight per 80 parts by weight of the base polymer (B). At least 0.1 part of the surfactant (F) is effective in improving the receding contact angle with water of the resist film at its surface. Up to 50 parts of the surfactant (F) is effective in forming a resist film having a low rate of dissolution in a developer and capable of maintaining the height of a small-size pattern formed therein. The surfactant (F) may be used alone or in combination of two or more.

### (G) Other Components

The chemically amplified resist composition of the invention may further comprise (G) other component, for example, a compound which is decomposed with an acid to generate another acid (i.e., acid amplifier compound), an organic acid derivative, a fluorinated alcohol, and a compound having a Mw of up to 3,000 which changes its solubility in developer under the action of an acid (i.e., dissolution inhibitor). For the acid amplifier compound, reference may be made to compounds described in JP-A 2009-269953 and JP-A 2010-215608. When the chemically amplified resist composition of the invention comprises the acid amplifier compound, the amount thereof is preferably 0 to 5 parts by weight, more preferably 0 to 3 parts by weight per 80 parts by weight of the base polymer (B). An extra amount of the acid amplifier compound can make the acid diffusion control difficult and cause degradations to resolution and pattern profile. For the organic acid derivative, fluorinated alcohol, and dissolution inhibitor, reference should be made to compounds described in JP-A 2009-269953 and JP-A 2010-215608.

### Pattern Forming Process

A pattern forming process of the invention comprises the steps of applying the chemically amplified resist composition defined above onto a substrate to form a resist film thereon, exposing the resist film to high-energy radiation, and developing the exposed resist film in a developer.

The substrate used herein may be a substrate for integrated circuitry fabrication, e.g., Si, SiO₂, SiN, SiON, TiN, WSi, BPSG, SOG, organic antireflective film, etc. or a substrate for mask circuitry fabrication, e.g., Cr, CrO, CrON, MoSi₂, SiO₂, etc.

The chemically amplified resist composition is applied onto a substrate by a suitable coating technique such as spin coating. The coating is prebaked on a hot plate preferably at a temperature of 60 to 150° C. for 1 to 10 minutes, more preferably at 80 to 140° C. for 1 to 5 minutes. The resulting resist film preferably has a thickness of 0.05 to 2 μm.

Examples of the high-energy radiation used for exposure of the resist film include KrF excimer laser radiation, ArF excimer laser radiation, EB and EUV of wavelength 3 to nm. Then the resist film is exposed to a pattern of high-energy radiation, typically KrF or ArF excimer laser, EUV or EB. On use of KrF excimer laser, ArF excimer laser or EUV, the resist film is exposed through a mask having a desired pattern, preferably in a dose of 1 to 200 mJ/cm², more preferably 10 to 100 mJ/cm². On use of EB, a pattern may be written directly or through a mask having the desired pattern, preferably in a dose of 1 to 300 μC/cm², more preferably 10 to 200 μC/cm².

The exposure may be performed by conventional lithography whereas the immersion lithography of holding a liquid having a refractive index of at least 1.0 between the resist film and the projection lens may be employed. In this case, a protective film which is insoluble in water may be also used.

While the water-insoluble protective film serves to prevent any components from being leached out of the resist film and to improve water sliding on the film surface, it is generally divided into two types. The first type is an organic solvent-strippable protective film which must be stripped, prior to aqueous alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate preferably at 60 to 150° C. for 1 to 5 minutes, more preferably at 80 to 140° C. for 1 to 3 minutes.

The resist film is then developed with a developer in the form of an aqueous alkaline solution, for example, preferably 0.1 to 5 wt %, more preferably 2 to 3 wt % aqueous solution of tetramethylammonium hydroxide (TMAH) for preferably 0.1 to 3 minutes, more preferably 0.5 to 2 minutes by conventional techniques such as dip, puddle and spray techniques. In this way, the exposed region of the resist film is dissolved away, and a desired resist pattern is formed on the substate.

Any desired step may be added to the pattern forming process. For example, after the resist film is formed, a step of rinsing with pure water may be introduced to extract the acid generator or the like from the film surface or wash away particles. After exposure, a step of rinsing may be introduced to remove any water remaining on the film after exposure.

Also, a double patterning process may be used for pattern formation. The double patterning process includes a trench process of processing an underlay to a 1:3 trench pattern by a first step of exposure and etching, shifting the position, and forming a 1:3 trench pattern by a second step of exposure, for forming a 1:1 pattern; and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the pattern forming process, negative tone development may also be used. That is, an organic solvent may be used instead of the aqueous alkaline solution as the developer for developing and dissolving away the unexposed region of the resist film.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvent may be used alone or in admixture of two or more.

### EXAMPLES

Synthesis Examples, Examples and Comparative Examples are given below by way of illustration and not by way of limitation. The abbreviation “pbw” is parts by weight.

Analysis is made by time-of-flight mass spectrometry using the instrument as follows.
MALDI TOF-MS: S3000 by JEOL Ltd.

### [1] Synthesis of Onium Salts

### Example 1-1

### Synthesis of PAG-1

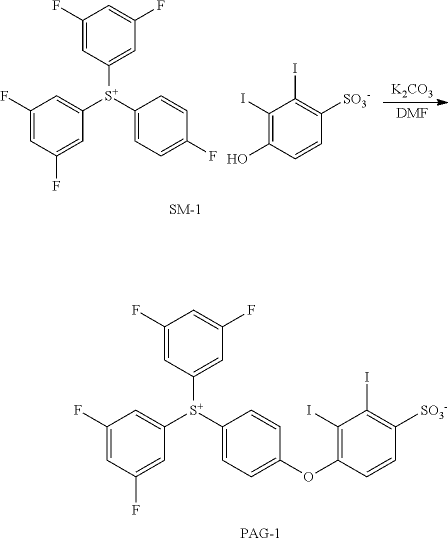

### (1) Synthesis of PAG-1

In a reactor under nitrogen atmosphere, 15.6 g of Reactant SM-1, 3.0 g of potassium carbonate and 30 g of DMF were mixed and stirred at an internal temperature of 60° C. for 6 hours. After stirring, the reaction solution was cooled in an ice bath, and 30 g of water was added to stop the reaction. The mixture was extracted with 100 g of methylene chloride, then washed with water, and concentrated under reduced pressure. Diisopropyl ether was added to the concentrate, followed by recrystallization, obtaining the target PAG-1 as white crystals (amount 13.0 g, yield 86%).

PAG-1 was analyzed by TOF-MS, with the data shown below.

### MALDI TOF-MS:

positive M⁺ 759 (corresponding to C₂₄H₁₃F₄I₂O₄S₂⁺)

### Examples 1-2 to 1-10

### Synthesis of PAG-2 to PAG-10

Various onium salts were synthesized using corresponding reactants and various organic synthesis reactions. The structures of the onium salts used in the chemically amplified resist composition are shown below.

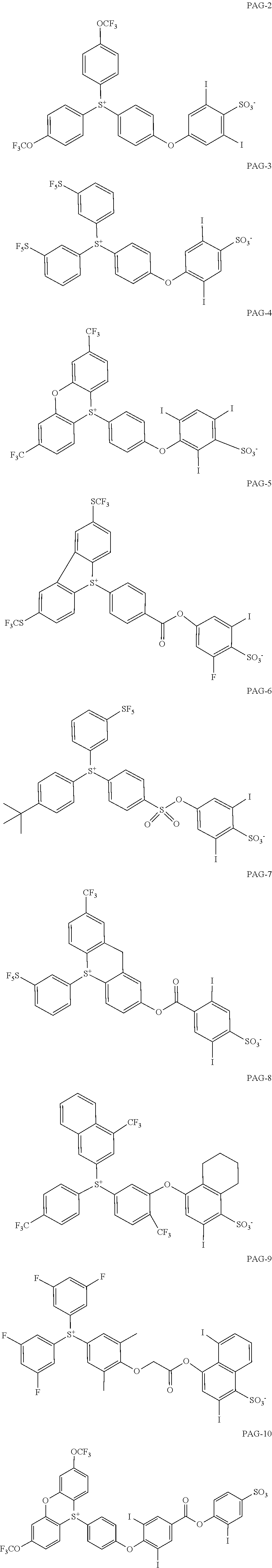

### [2] Synthesis of Base Polymers

### Synthesis Example

### Synthesis of Base Polymers (P-1 to P-5)

Base polymers P-1 to P-5 were synthesized by combining monomers, performing copolymerization reaction in MEK solvent, pouring the reaction solution to hexane for precipitation, washing the solid precipitate with hexane, isolation and drying. The base polymers were analyzed for composition by ¹H-NMR spectroscopy and for Mw and Mw/Mn by GPC versus polystyrene standards using a THF solvent.

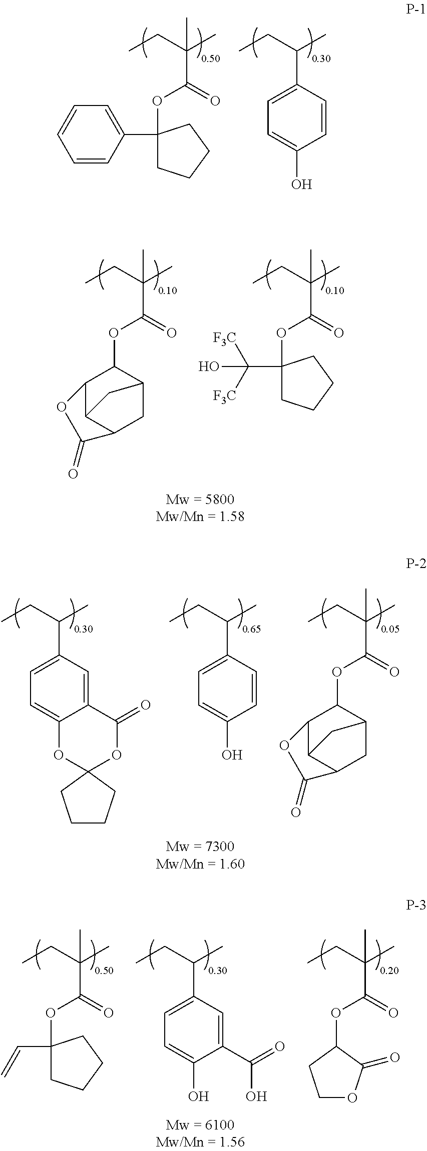

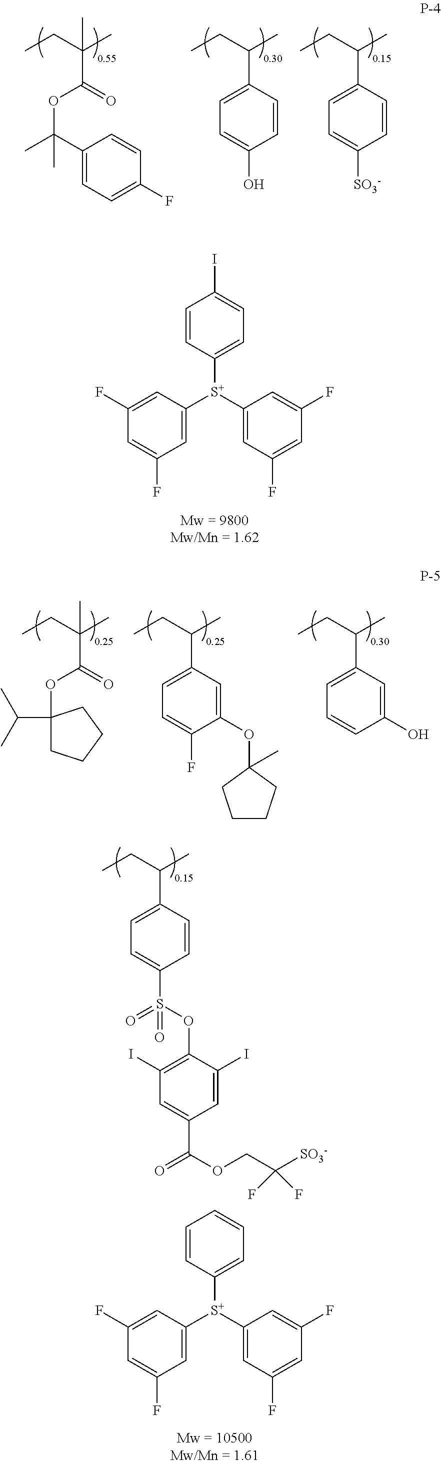

### [3] Preparation of Chemically Amplified Resist Compositions

### Examples 2-1 to 2-35, Comparative Examples 1-1 to 1-21

Chemically amplified resist compositions (R-1 to R-35, CR-1 to CR-21) in solution form were prepared by dissolving the sulfonium salts of the invention (PAG-1 to PAG-10), comparative photoacid generators (PAG-A to PAG-D), other photoacid generators (PAG-X and PAG-Y), base polymers (P-1 to P-5), and quenchers (Q-1 to Q-4) in a solvent containing 0.01 wt % of surfactant A (Omnova Solutions, Inc.) in accordance with the formulation shown in Tables 1 and 2, and filtering through a Teflon® filter with a pore size of 0.2 μm.

TABLE 1

| | | | Base | Photoacid | | Other photoacid | | | |
|---|---|---|---|---|---|---|---|---|---|
| | | Resist | polymer | generator | Quencher | generator | Solvent 1 | Solvent 2 | Solvent 3 |
| | | composition | (pbw) | (pbw) | (pbw) | (pbw) | (pbw) | (pbw) | (pbw) |
| Example | 2-1 | R-1 | P-1 (80) | PAG-1 (24) | Q-1 (8.0) | — | PGMEA (2250) | EL (2800) | DAA (550) |
| | 2-2 | R-2 | P-1 (80) | PAG-2 (24) | Q-1 (8.2) | — | PGMEA (2250) | EL (2800) | DAA (550) |
| | 2-3 | R-3 | P-1 (80) | PAG-3 (24) | Q-1 (8.0) | — | PGMEA (2250) | EL (2800) | DAA (550) |
| | 2-4 | R-4 | P-1 (80) | PAG-4 (24) | Q-1 (7.8) | — | PGMEA (2250) | EL (2800) | DAA (550) |
| | 2-5 | R-5 | P-1 (80) | PAG-5 (24) | Q-1 (8.0) | — | PGMEA (2250) | EL (2800) | DAA (550) |
| | 2-6 | R-6 | P-1 (80) | PAG-6 (24) | Q-1 (8.0) | — | PGMEA (2250) | EL (2800) | DAA (550) |
| | 2-7 | R-7 | P-1 (80) | PAG-7 (24) | Q-1 (8.2) | — | PGMEA (2250) | EL (2800) | DAA (550) |
| | 2-8 | R-8 | P-1 (80) | PAG-8 (24) | Q-1 (8.0) | — | PGMEA (2250) | EL (2800) | DAA (550) |
| | 2-9 | R-9 | P-1 (80) | PAG-9 (24) | Q-1 (7.6) | — | PGMEA (2250) | EL (2800) | DAA (550) |
| | 2-10 | R-10 | P-1 (80) | PAG-10 (24) | Q-1 (8.0) | — | PGMEA (2250) | EL (2800) | DAA (550) |
| | 2-11 | R-11 | P-1 (80) | PAG-1 (24) | Q-2 (8.0) | — | PGMEA (2250) | EL (2800) | DAA (550) |
| | 2-12 | R-12 | P-1 (80) | PAG-1 (24) | Q-3 (8.2) | — | PGMEA (2250) | EL (2800) | DAA (550) |
| | 2-13 | R-13 | P-1 (80) | PAG-1 (24) | Q-1 (4.0) | — | PGMEA (2250) | EL (2800) | DAA (550) |
| | | | | | Q-4 (3.8) | | | | |
| | 2-14 | R-14 | P-1 (80) | PAG-1 (16) | Q-3 (8.0) | PAG-X (6) | PGMEA (2250) | EL (2800) | DAA (550) |
| | 2-15 | R-15 | P-1 (80) | PAG-2 (14) | Q-1 (8.0) | PAG-Y (8) | PGMEA (2250) | EL (2800) | DAA (550) |
| | 2-16 | R-16 | P-2 (80) | PAG-1 (24) | Q-1 (8.2) | — | PGMEA (2250) | EL (2800) | DAA (550) |
| | 2-17 | R-17 | P-2 (80) | PAG-2 (24) | Q-1 (8.0) | — | PGMEA (2250) | EL (2800) | DAA (550) |
| | 2-18 | R-18 | P-2 (80) | PAG-4 (24) | Q-3 (7.8) | — | PGMEA (2250) | EL (2800) | DAA (550) |
| | 2-19 | R-19 | P-2 (80) | PAG-6 (24) | Q-2 (8.0) | — | PGMEA (2250) | EL (2800) | DAA (550) |
| | 2-20 | R-20 | P-2 (80) | PAG-9 (12) | Q-1 (8.0) | PAG-Y (12) | PGMEA (2250) | EL (2800) | DAA (550) |
| | 2-21 | R-21 | P-3 (80) | PAG-1 (24) | Q-1 (7.8) | — | PGMEA (2250) | EL (2800) | DAA (550) |
| | 2-22 | R-22 | P-3 (80) | PAG-3 (24) | Q-2 (8.0) | — | PGMEA (2250) | EL (2800) | DAA (550) |
| | 2-23 | R-23 | P-3 (80) | PAG-5 (24) | Q-3 (7.8) | — | PGMEA (2250) | EL (2800) | DAA (550) |
| | 2-24 | R-24 | P-3 (80) | PAG-7 (12) | Q-3 (4.0) | PAG-X (12) | PGMEA (2250) | EL (2800) | DAA (550) |
| | | | | | Q-4 (3.8) | | | | |
| | 2-25 | R-25 | P-3 (80) | PAG-10 (24) | Q-1 (8.2) | — | PGMEA (2250) | EL (2800) | DAA (550) |
| | 2-26 | R-26 | P-4 (80) | PAG-1 (15) | Q-3 (7.8) | — | PGMEA (2250) | EL (2800) | DAA (550) |
| | 2-27 | R-27 | P-4 (80) | PAG-3 (15) | Q-1 (8.0) | — | PGMEA (2250) | EL (2800) | DAA (550) |
| | 2-28 | R-28 | P-4 (80) | PAG-4 (15) | Q-2 (8.2) | — | PGMEA (2250) | EL (2800) | DAA (550) |
| | 2-29 | R-29 | P-4 (80) | PAG-7 (15) | Q-2 (4.0) | — | PGMEA (2250) | EL (2800) | DAA (550) |
| | | | | | Q-4 (3.8) | | | | |
| | 2-30 | R-30 | P-4 (80) | PAG-9 (14) | Q-3 (7.8) | — | PGMEA (2250) | EL (2800) | DAA (550) |
| | 2-31 | R-31 | P-5 (80) | PAG-1 (10) | Q-1 (8.0) | — | PGMEA (2250) | EL (2800) | DAA (550) |
| | 2-32 | R-32 | P-5 (80) | PAG-2 (12) | Q-3 (7.8) | — | PGMEA (2250) | EL (2800) | DAA (550) |
| | 2-33 | R-33 | P-5 (80) | PAG-5 (10) | Q-1 (8.0) | — | PGMEA (2250) | EL (2800) | DAA (550) |
| | 2-34 | R-34 | P-5 (80) | PAG-8 (12) | Q-2 (8.2) | — | PGMEA (2250) | EL (2800) | DAA (550) |
| | 2-35 | R-35 | P-5 (80) | PAG-10 (24) | Q-1 (8.0) | — | PGMEA (2250) | EL (2800) | DAA (550) |

TABLE 2

| | | | Base | Photoacid | | Other photoacid | | | |
|---|---|---|---|---|---|---|---|---|---|
| | | Resist | polymer | generator | Quencher | generator | Solvent 1 | Solvent 2 | Solvent 3 |
| | | composition | (pbw) | (pbw) | (pbw) | (pbw) | (pbw) | (pbw) | (pbw) |
| Comparative | 1-1 | CR-1 | P-1 (80) | PAG-A (24) | Q-1 (8.0) | — | PGMEA (2250) | EL (2800) | DAA (550) |
| Example | 1-2 | CR-2 | P-1 (80) | PAG-B (24) | Q-1 (8.2) | — | PGMEA (2250) | EL (2800) | DAA (550) |
| | 1-3 | CR-3 | P-1 (80) | PAG-C (24) | Q-1 (8.0) | — | PGMEA (2250) | EL (2800) | DAA (550) |
| | 1-4 | CR-4 | P-1 (80) | PAG-D (24) | Q-1 (7.8) | — | PGMEA (2250) | EL (2800) | DAA (550) |
| | 1-5 | CR-5 | P-1 (80) | PAG-A (24) | Q-2 (8.0) | — | PGMEA (2250) | EL (2800) | DAA (550) |
| | 1-6 | CR-6 | P-1 (80) | PAG-A (24) | Q-3 (8.2) | — | PGMEA (2250) | EL (2800) | DAA (550) |
| | 1-7 | CR-7 | P-1 (80) | PAG-A (24) | Q-1 (4.0) | — | PGMEA (2250) | EL (2800) | DAA (550) |
| | | | | | Q-4 (3.8) | | | | |
| | 1-8 | CR-8 | P-1 (80) | PAG-A (16) | Q-3 (8.0) | PAG-X (6) | PGMEA (2250) | EL (2800) | DAA (550) |
| | 1-9 | CR-9 | P-1 (80) | PAG-B (14) | Q-1 (8.0) | PAG-Y (8) | PGMEA (2250) | EL (2800) | DAA (550) |
| | 1-10 | CR-10 | P-2 (80) | PAG-A (24) | Q-1 (8.2) | — | PGMEA (2250) | EL (2800) | DAA (550) |
| | 1-11 | CR-11 | P-2 (80) | PAG-B (24) | Q-2 (8.0) | — | PGMEA (2250) | EL (2800) | DAA (550) |
| | 1-12 | CR-12 | P-2 (80) | PAG-C (12) | Q-1 (8.0) | PAG-Y (12) | PGMEA (2250) | EL (2800) | DAA (550) |
| | 1-13 | CR-13 | P-3 (80) | PAG-A (24) | Q-1 (7.8) | — | PGMEA (2250) | EL (2800) | DAA (550) |
| | 1-14 | CR-14 | P-3 (80) | PAG-C (24) | Q-3 (7.8) | — | PGMEA (2250) | EL (2800) | DAA (550) |
| | 1-15 | CR-15 | P-3 (80) | PAG-D (12) | Q-3 (4.0) | PAG-X (12) | PGMEA (2250) | EL (2800) | DAA (550) |
| | | | | | Q-4 (3.8) | | | | |
| | 1-16 | CR-16 | P-4 (80) | PAG-A (12) | Q-3 (7.8) | — | PGMEA (2250) | EL (2800) | DAA (550) |
| | 1-17 | CR-17 | P-4 (80) | PAG-B (12) | Q-2 (4.0) | — | PGMEA (2250) | EL (2800) | DAA (550) |
| | | | | | Q-4 (3.8) | | | | |
| | 1-18 | CR-18 | P-4 (80) | PAG-C (12) | Q-3 (7.8) | — | PGMEA (2250) | EL (2800) | DAA (550) |
| | 1-19 | CR-19 | P-5 (80) | PAG-A (12) | Q-1 (8.0) | — | PGMEA (2250) | EL (2800) | DAA (550) |
| | 1-20 | CR-20 | P-5 (80) | PAG-C (12) | Q-3 (7.8) | — | PGMEA (2250) | EL (2800) | DAA (550) |
| | 1-21 | CR-21 | P-5 (80) | PAG-D (12) | Q-1 (8.0) | — | PGMEA (2250) | EL (2800) | DAA (550) |

The solvents, other photoacid generators PAG-X and PAG-Y, comparative photoacid generators PAG-A to PAG-D, and quenchers Q-1 to Q-4 in Tables 1 and 2 are identified below.

### Solvent:

PGMEA (propylene glycol monomethyl ether acetate)
EL (ethyl lactate)
DAA (diacetone alcohol)

Other photoacid generators: PAG-X and PAG-Y

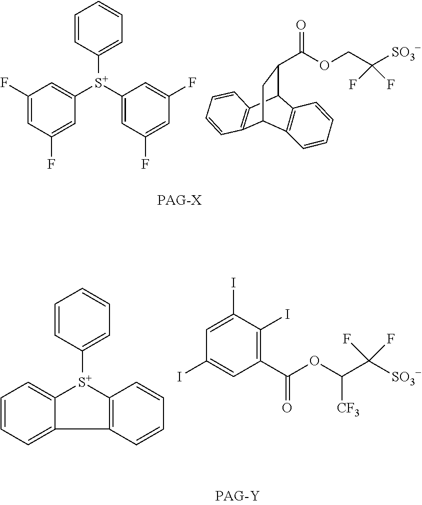

Comparative photoacid generators: PAG-A to PAG-D

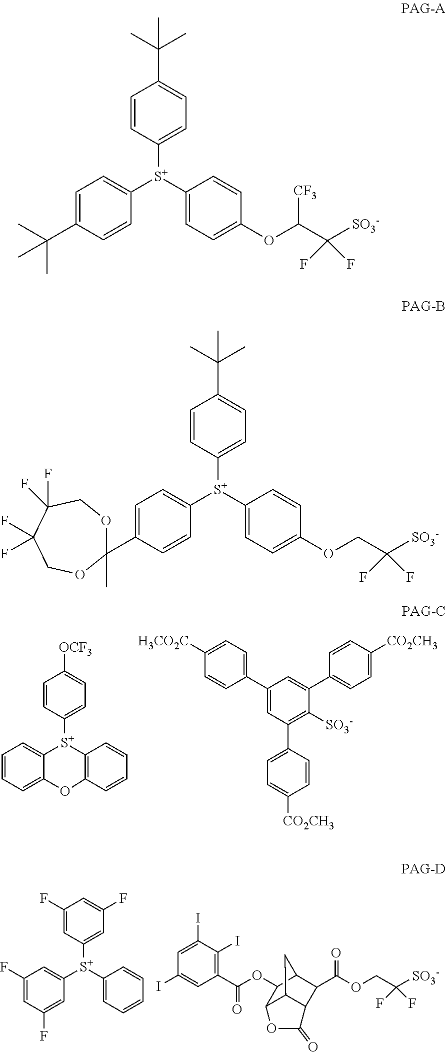

Quenchers: Q-1 to Q-4

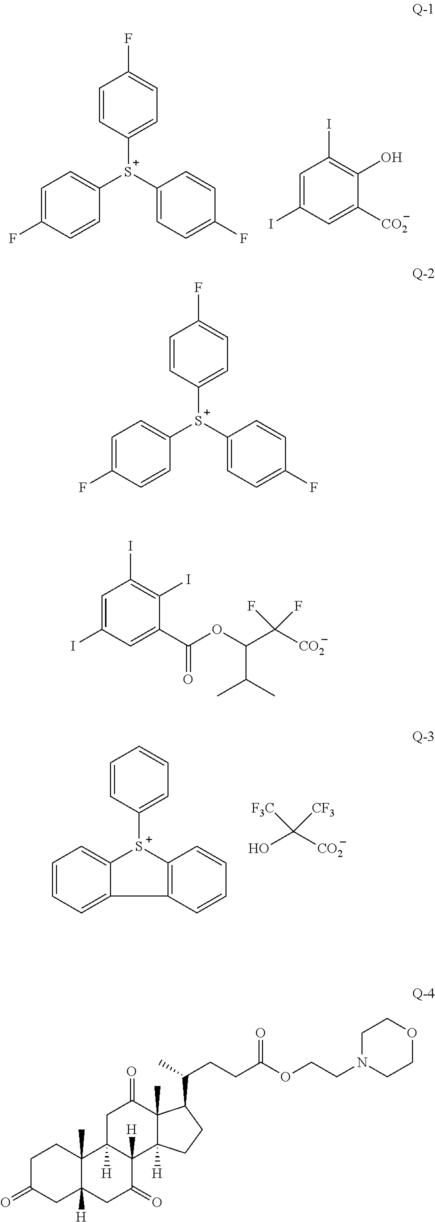

### [4] EUV Lithography Test (1)

### Examples 3-1 to 3-35, Comparative Examples 2-1 to 2-21

Each of the chemically amplified resist compositions (R-1 to R-35, CR-1 to CR-21) shown in Tables 1 and 2 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 100° C. for 60 seconds to form a resist film of 50 nm thick. Using an EUV scanner NXE3400 (ASML, NA 0.33, a 0.9/0.6, dipole illumination), the resist film was exposed to EUV through a mask bearing a LS pattern having a size of 18 nm and a pitch of 36 nm (on-wafer size) while varying the dose and focus (dose pitch: 1 mJ/cm², focus pitch: 0.020 μm). The resist film was baked (PEB) on a hotplate at the temperature shown in Tables 3 and 4 for 60 seconds and puddle developed in a 2.38 wt % TMAH aqueous solution for 30 seconds, rinsed with a rinse fluid containing surfactant, and spin dried to form a positive pattern.

The LS pattern as developed was observed under CD-SEM (CG6300, Hitachi High-Technologies Corp.) whereupon sensitivity, EL, LWR, depth of focus (DOF) and collapse limit were evaluated by the following methods. The results are shown in Tables 3 and 4.

[Evaluation of sensitivity]

The optimum dose Eop (mJ/cm²) which provided a LS pattern with a line width of 18 nm and a pitch of 36 nm was determined as an index of sensitivity. A smaller value indicates a higher sensitivity.

### [Evaluation of EL]

The exposure dose which provided a LS pattern with a space width of 18 nm±10% (i.e., 16.2 to 19.8 nm) was determined. EL (%) is calculated from the exposure doses according to the following equation:

$$EL ( \% ) = ( \vert {E}_{1} - {E}_{2} \vert / Eop ) \times 100$$

wherein E₁ is an optimum exposure dose which provides a LS pattern with a line width of 16.2 nm and a pitch of 36 nm, E₂ is an optimum exposure dose which provides a LS pattern with a line width of 19.8 nm and a pitch of 36 nm, and Eop is an optimum exposure dose which provides a LS pattern with a line width of 18 nm and a pitch of 36 nm. A greater value indicates better performance.

### [Evaluation of LWR]

For the LS pattern formed by exposure at the optimum dose Eop, the line width was measured at 10 longitudinally spaced apart points, from which a 3-fold value (3σ) of the standard deviation (σ) was determined and reported as LWR. A smaller value of 3σ indicates a pattern having small roughness and uniform line width.

### [Evaluation of DOF]

As an index of depth of focus, a range of focus which provided a LS pattern with a size of 18 nm±10% (i.e., 16.2 to 19.8 nm) was determined. A greater value indicates a wider depth of focus.

### [Evaluation of Collapse Limit of Line Pattern]

For the LS pattern formed by exposure at the dose corresponding to the optimum focus, the line width was measured at 10 longitudinally spaced apart points. The minimum line size above which lines could be resolved without collapse was determined and reported as collapse limit. A smaller value indicates better collapse limit.

TABLE 3

| | | Resist | PEB temp. | Eop | EL | LWR | DOF | Collapse limit |
|---|---|---|---|---|---|---|---|---|
| | | composition | (° C.) | (mJ/cm²) | (%) | (nm) | (nm) | (nm) |
| Example | 3-1 | R-1 | 95 | 33 | 18 | 2.3 | 110 | 10.5 |
| | 3-2 | R-2 | 100 | 32 | 19 | 2.2 | 120 | 10.9 |
| | 3-3 | R-3 | 100 | 34 | 17 | 2.3 | 100 | 10.8 |
| | 3-4 | R-4 | 95 | 3 | 18 | 2.4 | 110 | 10.9 |
| | 3-5 | R-5 | 105 | 32 | 17 | 2.4 | 110 | 11.1 |
| | 3-6 | R-6 | 100 | 33 | 18 | 2.3 | 100 | 11.2 |
| | 3-7 | R-7 | 95 | 34 | 18 | 2.3 | 120 | 10.8 |
| | 3-8 | R-8 | 95 | 35 | 17 | 2.3 | 110 | 10.9 |
| | 3-9 | R-9 | 100 | 32 | 16 | 2.2 | 110 | 11.0 |
| | 3-10 | R-10 | 100 | 33 | 19 | 2.5 | 120 | 11.2 |
| | 3-11 | R-11 | 100 | 34 | 17 | 2.3 | 110 | 11.1 |
| | 3-12 | R-12 | 95 | 32 | 18 | 2.5 | 100 | 11.2 |
| | 3-13 | R-13 | 105 | 33 | 17 | 2.3 | 110 | 10.7 |
| | 3-14 | R-14 | 100 | 32 | 18 | 2.3 | 120 | 11.1 |
| | 3-15 | R-15 | 95 | 33 | 18 | 2.2 | 110 | 10.6 |
| | 3-16 | R-16 | 95 | 34 | 17 | 2.2 | 120 | 10.9 |
| | 3-17 | R-17 | 100 | 32 | 19 | 2.4 | 120 | 11.2 |
| | 3-18 | R-18 | 95 | 35 | 16 | 2.5 | 110 | 11.3 |
| | 3-19 | R-19 | 95 | 34 | 17 | 2.4 | 110 | 11.1 |
| | 3-20 | R-20 | 100 | 32 | 18 | 2.5 | 120 | 10.8 |
| | 3-21 | R-21 | 100 | 33 | 17 | 2.3 | 110 | 10.9 |
| | 3-22 | R-22 | 100 | 35 | 19 | 2.2 | 120 | 11.1 |
| | 3-23 | R-23 | 95 | 34 | 18 | 2.5 | 100 | 11.2 |
| | 3-24 | R-24 | 95 | 33 | 18 | 2.4 | 120 | 10.7 |
| | 3-25 | R-25 | 100 | 34 | 17 | 2.3 | 100 | 11.0 |
| | 3-26 | R-26 | 100 | 32 | 17 | 2.4 | 110 | 10.9 |
| | 3-27 | R-27 | 100 | 33 | 18 | 2.5 | 120 | 11.1 |
| | 3-28 | R-28 | 95 | 32 | 17 | 2.3 | 110 | 11.4 |
| | 3-29 | R-29 | 95 | 34 | 19 | 2.5 | 100 | 11.1 |
| | 3-30 | R-30 | 100 | 33 | 18 | 2.4 | 120 | 10.8 |
| | 3-31 | R-31 | 100 | 35 | 18 | 2.4 | 110 | 10.9 |
| | 3-32 | R-32 | 100 | 33 | 18 | 2.3 | 110 | 10.7 |
| | 3-33 | R-33 | 100 | 33 | 18 | 2.4 | 100 | 11.2 |
| | 3-34 | R-34 | 95 | 32 | 19 | 2.3 | 110 | 10.9 |
| | 3-35 | R-35 | 100 | 33 | 18 | 2.3 | 120 | 10.8 |

TABLE 4

| | | Resist | PEB temp. | Eop | EL | LWR | DOF | Collapse limit |
|---|---|---|---|---|---|---|---|---|
| | | composition | (° C.) | (mJ/cm²) | (%) | (nm) | (nm) | (nm) |
| Comparative | 2-1 | CR-1 | 95 | 36 | 14 | 2.8 | 100 | 11.9 |
| Example | 2-2 | CR-2 | 100 | 37 | 13 | 2.9 | 90 | 12 |
| | 2-3 | CR-3 | 100 | 36 | 14 | 3 | 80 | 12.3 |
| | 2-4 | CR-4 | 100 | 37 | 13 | 3.1 | 80 | 12.4 |
| | 2-5 | CR-5 | 95 | 36 | 15 | 2.9 | 90 | 11.8 |
| | 2-6 | CR-6 | 100 | 35 | 14 | 2.8 | 80 | 11.9 |
| | 2-7 | CR-7 | 100 | 37 | 15 | 2.7 | 80 | 11.7 |
| | 2-8 | CR-8 | 100 | 38 | 14 | 2.9 | 90 | 11.6 |
| | 2-9 | CR-9 | 95 | 36 | 13 | 3.1 | 80 | 12 |
| | 2-10 | CR-10 | 100 | 37 | 12 | 2.7 | 70 | 12.1 |
| | 2-11 | CR-11 | 100 | 36 | 15 | 2.8 | 80 | 11.7 |
| | 2-12 | CR-12 | 100 | 37 | 14 | 2.8 | 90 | 11.9 |
| | 2-13 | CR-13 | 95 | 35 | 13 | 2.9 | 80 | 11.6 |
| | 2-14 | CR-14 | 105 | 36 | 14 | 3.1 | 70 | 12.1 |
| | 2-15 | CR-15 | 100 | 37 | 15 | 2.8 | 90 | 11.6 |
| | 2-16 | CR-16 | 95 | 37 | 14 | 2.7 | 90 | 11.5 |
| | 2-17 | CR-17 | 95 | 36 | 13 | 2.9 | 80 | 12.2 |
| | 2-18 | CR-18 | 100 | 37 | 14 | 2.8 | 100 | 12.1 |
| | 2-19 | CR-19 | 95 | 36 | 14 | 2.7 | 90 | 11.8 |
| | 2-20 | CR-20 | 95 | 37 | 13 | 3.1 | 80 | 11.6 |
| | 2-21 | CR-21 | 100 | 37 | 14 | 2.8 | 70 | 11.8 |

It is demonstrated in Tables 3 and 4 that chemically amplified resist compositions comprising the onium salt of the invention exhibit a high sensitivity and improved values of EL, LWR and DOF. Small values of collapse limit attest that in forming a small-size pattern, the pattern is resistant to collapse. The chemically amplified resist compositions of the invention are suitable as materials for EUV lithography.

### [5] EUV Lithography Test (2)

### Examples 4-1 to 4-35, Comparative Examples 3-1 to 3-21

Each of the chemically amplified resist compositions (R-1 to R-35, CR-1 to CR-21) shown in Tables 1 and 2 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105° C. for 60 seconds to form a resist film of 50 nm thick. Using an EUV scanner NXE3400 (ASML, NA 0.33, a 0.9/0.6, quadrupole illumination), the resist film was exposed to EUV through a mask bearing a hole pattern having a pitch of 46 nm+20% bias (on-wafer size). The resist film was baked (PEB) on a hotplate at the temperature shown in Tables 5 and 6 for 60 seconds and developed in a 2.38 wt % TMAH aqueous solution for 30 seconds to form a hole pattern having a size of 23 nm.

The pattern as developed was observed under CD-SEM (CG6300, Hitachi High-Technologies Corp.). The dose at which a pattern with a hole size of 23 nm was printed was determined as an index of sensitivity. The size of 50 holes was measured, from which a 3-fold value (3σ) of the standard deviation (σ) was determined as CDU. The results are shown in Tables 5 and 6.

TABLE 5

| | | Resist | PEB temp. | Eop | CDU |
|---|---|---|---|---|---|
| | | composition | (° C.) | (mJ/cm²) | (nm) |
| Example | 4-1 | R-1 | 90 | 23 | 2.1 |
| | 4-2 | R-2 | 95 | 22 | 2.4 |
| | 4-3 | R-3 | 90 | 24 | 2.3 |
| | 4-4 | R-4 | 90 | 25 | 2.3 |
| | 4-5 | R-5 | 90 | 23 | 2.2 |
| | 4-6 | R-6 | 95 | 22 | 2.3 |
| | 4-7 | R-7 | 95 | 24 | 2.4 |
| | 4-8 | R-8 | 90 | 23 | 2.3 |
| | 4-9 | R-9 | 95 | 23 | 2.2 |
| | 4-10 | R-10 | 95 | 24 | 2.4 |
| | 4-11 | R-11 | 95 | 23 | 2.3 |
| | 4-12 | R-12 | 90 | 25 | 2.5 |
| | 4-13 | R-13 | 90 | 23 | 2.3 |
| | 4-14 | R-14 | 90 | 23 | 2.4 |
| | 4-15 | R-15 | 90 | 24 | 2.3 |
| | 4-16 | R-16 | 85 | 25 | 2.2 |
| | 4-17 | R-17 | 95 | 25 | 2.4 |
| | 4-18 | R-18 | 95 | 23 | 2.4 |
| | 4-19 | R-19 | 90 | 25 | 2.3 |
| | 4-20 | R-20 | 95 | 23 | 2.5 |
| | 4-21 | R-21 | 95 | 22 | 2.2 |
| | 4-22 | R-22 | 95 | 22 | 2.3 |
| | 4-23 | R-23 | 95 | 24 | 2.4 |
| | 4-24 | R-24 | 90 | 23 | 2.3 |
| | 4-25 | R-25 | 95 | 24 | 2.5 |
| | 4-26 | R-26 | 95 | 22 | 2.3 |
| | 4-27 | R-27 | 95 | 25 | 2.2 |
| | 4-28 | R-28 | 95 | 24 | 2.4 |
| | 4-29 | R-29 | 90 | 22 | 2.3 |
| | 4-30 | R-30 | 95 | 23 | 2.2 |
| | 4-31 | R-31 | 95 | 24 | 2.4 |
| | 4-32 | R-32 | 90 | 23 | 2.3 |
| | 4-33 | R-33 | 95 | 24 | 2.3 |
| | 4-34 | R-34 | 95 | 23 | 2.2 |
| | 4-35 | R-35 | 90 | 24 | 2.4 |

TABLE 6

| | | Resist | PEB temp. | Eop | CDU |
|---|---|---|---|---|---|
| | | composition | (° C.) | (mJ/cm²) | (nm) |
| Comparative | 3-1 | CR-1 | 90 | 27 | 2.8 |
| Example | 3-2 | CR-2 | 95 | 26 | 2.7 |
| | 3-3 | CR-3 | 95 | 28 | 2.9 |
| | 3-4 | CR-4 | 90 | 28 | 2.7 |
| | 3-5 | CR-5 | 90 | 26 | 2.6 |
| | 3-6 | CR-6 | 95 | 28 | 2.9 |
| | 3-7 | CR-7 | 90 | 27 | 2.8 |
| | 3-8 | CR-8 | 90 | 27 | 2.8 |
| | 3-9 | CR-9 | 90 | 28 | 2.7 |
| | 3-10 | CR-10 | 95 | 29 | 2.9 |
| | 3-11 | CR-11 | 95 | 27 | 2.8 |
| | 3-12 | CR-12 | 95 | 26 | 2.8 |
| | 3-13 | CR-13 | 90 | 28 | 3.1 |
| | 3-14 | CR-14 | 95 | 27 | 2.7 |
| | 3-15 | CR-15 | 95 | 29 | 2.8 |
| | 3-16 | CR-16 | 95 | 29 | 2.9 |
| | 3-17 | CR-17 | 95 | 28 | 2.8 |
| | 3-18 | CR-18 | 95 | 27 | 2.7 |
| | 3-19 | CR-19 | 90 | 27 | 2.8 |
| | 3-20 | CR-20 | 95 | 28 | 2.9 |
| | 3-21 | CR-21 | 95 | 27 | 2.8 |

It is demonstrated in Tables 5 and 6 that chemically amplified resist compositions comprising the onium salt of the invention exhibit a high sensitivity and satisfactory CDU.

Japanese Patent Application No. 2024-119652 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. An onium salt having the formula (1): 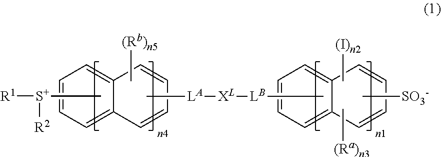
wherein n1 is 0 or 1, n2 is 1, 2, 3, or 4, n3 is 0, 1, or 2, meeting 1≤n2+n3≤4 in case of n1=0 and 1≤n2+n3≤6 in case of n1=1, n4 is 0 or 1, n5 is 0, 1, 2, 3, or 4,
R^{a} is halogen exclusive of iodine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n3 is 2, two R^{a} may be identical or different and two R^{a} may bond together to form a ring with the carbon atoms to which they are attached,
R^{b} is halogen, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n5 is 2, 3, or 4, a plurality of R^{b} may be identical or different and a plurality of R^{b} may bond together to form a ring with the carbon atoms to which they are attached,
R¹ and R² are each independently halogen or a C₁-C₃₀ hydrocarbyl group which may contain a heteroatom, any two of R¹ and R² and the aromatic ring bonded to S⁺ in the formula may bond together to form a ring with the sulfur atoms to which they are attached,
L^{A} and L^{B} are each independently a single bond, ether bond, ester bond, sulfonate ester bond, amide bond, sulfonamide bond, carbonate bond or carbamate bond, and
X^{L1} is a single bond or a C₁-C₄₀ hydrocarbylene group which may contain a heteroatom.

2. The onium salt of claim 1 having the formula (1A): 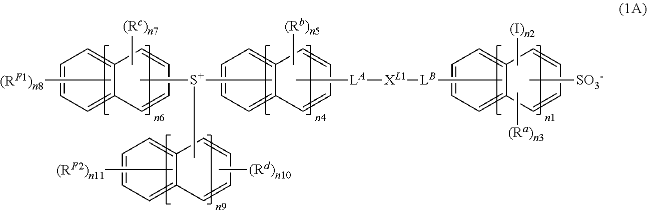
wherein n1 to n5, R^{a}, R^{b}, L^{A}, L^{B}, and X^{L1} are as defined above,
n6 is 0 or 1, n7 is 0, 1, or 2, n8 is 0, 1, 2, 3, or 4, n9 is 0 or 1, n10 is 0, 1, or 2, n11 is 0, 1, 2, 3, or 4, meeting 0≤n7+n8≤5 in case of n6=0 and 0≤n7+n8≤7 in case of n6=1, 0≤n10+n11≤5 in case of n9-0 and 0≤n10+n11≤7 in case of n9=1,
R^{c} is halogen exclusive of fluorine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n7 is 2, two R^{c} may be identical or different and two R^{c} may bond together to form a ring with the carbon atoms to which they are attached,
R^{d} is halogen exclusive of fluorine, nitro, cyano, hydroxy, a C₁-C₂₀ hydrocarbyl group which may contain a heteroatom, a C₁-C₂₀ hydrocarbyloxy group which may contain a heteroatom, or a C₁-C₂₀ hydrocarbylthio group which may contain a heteroatom, when n10 is 2, two R^{d} may be identical or different and two R^{d} may bond together to form a ring with the carbon atoms to which they are attached, and
R^{F1} and R^{F2} are each independently fluorine, pentafluorosulfanyl, a C₁-C₆ fluorinated saturated hydrocarbyl group, a C₁-C₆ fluorinated saturated hydrocarbyloxy group, or a C₁-C₆ fluorinated saturated hydrocarbylthio group, a plurality of R^{F1} may be identical or different when n8 is 2 or more, a plurality of R^{F2} may be identical or different when n11 is 2 or more.

3. The onium salt of claim 2 having the formula (1B): 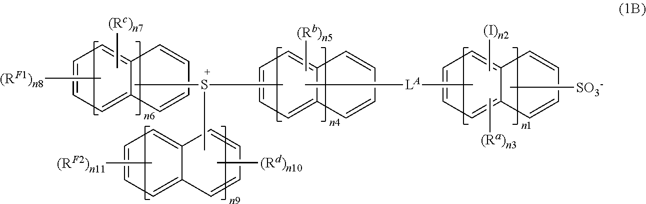
wherein n1 to n11, R^{a}, R^{b}, R^{c}, R^{d}, R^{F1}, R^{F2}, and L^{A} are as defined above.

4. A photoacid generator comprising the onium salt of claim 1.

5. A chemically amplified resist composition comprising the photoacid generator of claim 4.

6. The chemically amplified resist composition of claim 5, further comprising a base polymer comprising at least one selected from repeat units having the formula (a1), repeat units having the formula (a2), and repeat units having the formula (a3): 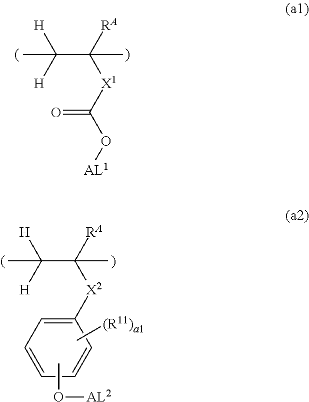
wherein R^{A} is each independently hydrogen, fluorine, methyl or trifluoromethyl,
X¹ is a single bond, phenylene group, naphthylene group, *—C(═O)—O—X¹¹—, or *—C(═O)—NH—X¹¹—, the phenylene or naphthylene group may be substituted by a hydroxy moiety, nitro moiety, cyano moiety, optionally fluorinated C₁-C₁₀ saturated hydrocarbyl group, optionally fluorinated C₁-C₁₀ saturated hydrocarbyloxy group, or halogen, X¹¹ is a C₁-C₁₀ saturated hydrocarbylene group, or phenylene or naphthylene group, the saturated hydrocarbylene group may contain a hydroxy moiety, ether bond, ester bond or lactone ring,
X² is a single bond, *—C(═O)—O—, or *—C(═O)—NH—,
* designates a point of attachment to the carbon atom in the backbone,
R¹¹ is halogen, cyano, hydroxy, nitro, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R¹¹ may be identical or different when a1 is 2, 3, or 4,
AL¹ and AL² are each independently an acid labile group, and
a1 is 0, 1, 2, 3, or 4; 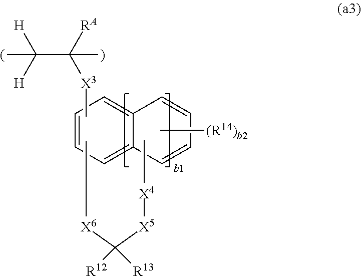
wherein b1 is 0 or 1, b2 is 0, 1, 2, or 3 in case of b1=0, and is 0, 1, 2, 3, 4, or 5 in case of b1=1,
R^{A} is hydrogen, fluorine, methyl or trifluoromethyl,
X³ is a single bond, *—C(═O)—O—, or *—C(═O)—NH—, * designates a point of attachment to the carbon atom in the backbone,
X⁴ is a single bond, a C₁-C₄ aliphatic hydrocarbylene group, carbonyl group, sulfonyl group, or a group obtained by combining the foregoing,
X⁵ and X⁶ are each independently oxygen or sulfur, X⁴ and X⁶ are bonded to vicinal carbon atoms on the aromatic ring,
R¹² and R¹³ are each independently hydrogen or a C₁-C₂₀ hydrocarbyl group which may contain a heteroatom, R¹² and R¹³ may bond together to form a ring with the carbon atoms to which they are attached, and
R¹⁴ is halogen, hydroxy, cyano, nitro, a C₁-C₂₀ hydrocarbyl group which may contain a heteroatom, a C₁-C₂₀ hydrocarbyloxy group which may contain a heteroatom, a C₂-C₂₀ hydrocarbyloxycarbonyl group which may contain a heteroatom, a C₁-C₂₀ hydrocarbylthio group which may contain a heteroatom, or —N(R^{14A})(R^{14B}), R^{14A} and R^{14B} are each independently hydrogen or a C₁-C₆ hydrocarbyl group, when b2 is 2 or more, a plurality of R¹⁴ may be identical or different and a plurality of R¹⁴ may bond together to form a ring with the carbon atoms on the aromatic ring to which they are attached.

7. The chemically amplified resist composition of claim 6 wherein the base polymer comprises at least one selected from repeat units having the formula (b1) and repeat units having the formula (b2): 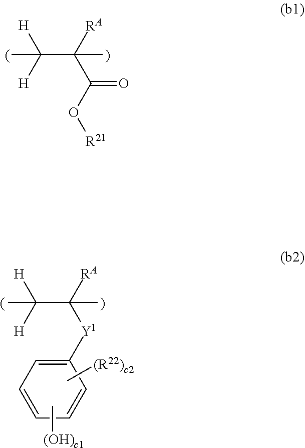
wherein R^{A} is each independently hydrogen, fluorine, methyl or trifluoromethyl,
Y¹ is a single bond or *—C(═O)—O—, * designates a point of attachment to the carbon atom in the backbone,
R²¹ is hydrogen or a C₁-C₂₀ group containing at least one structure selected from among hydroxy exclusive of phenolic hydroxy, cyano, carbonyl, carboxy, ether bond, ester bond, sulfonate ester bond, carbonate bond, lactone ring, sultone ring and carboxylic anhydride (—C(═O)—O—C(═O)—),
R²² is halogen, hydroxy, carboxy, nitro, cyano, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom, a plurality of R²² may be identical or different when c2 is 2, 3, or 4, and
c1 is 1, 2, 3, or 4, c2 is 0, 1, 2, 3, or 4, meeting 1≤c1+c2≤5.

8. The chemically amplified resist composition of claim 6 wherein the base polymer comprises at least one selected from repeat units having the formula (c1), repeat units having the formula (c2), repeat units having the formula (c3), repeat units having the formula (c4), and repeat units having the formula (c5): 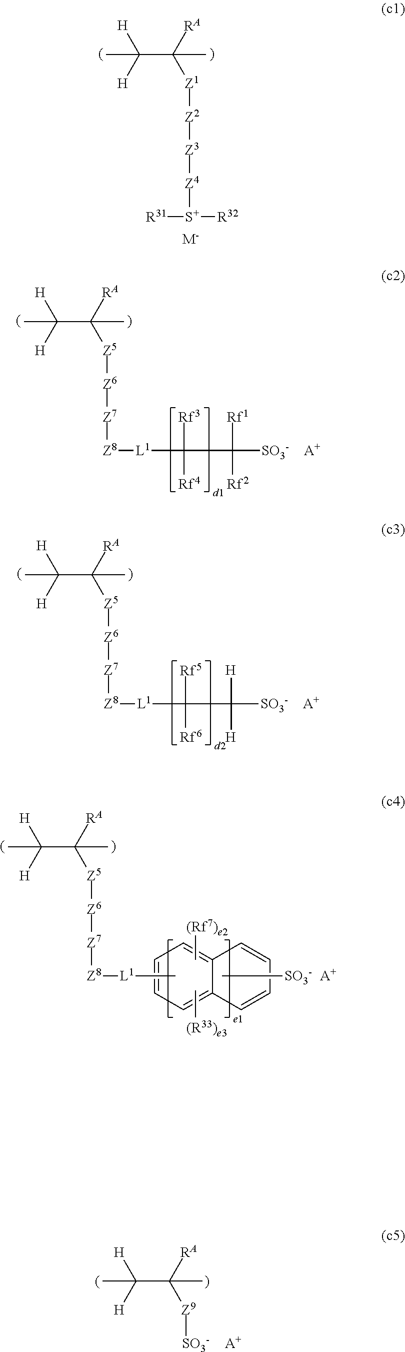
wherein d1 and d2 are each independently 0, 1, 2, or 3, e1 is 0 or 1, e2 is 0, 1, 2, 3, or 4, and e3 is 0, 1, 2, 3, or 4, meeting 0≤e2+e3≤4 in case of e1=0, 0≤e2+e3≤6 in case of e1=1,
R^{A} is each independently hydrogen, fluorine, methyl or trifluoromethyl,
Z¹ is a single bond or optionally substituted phenylene group,
Z² is a single bond, **—C(═O)—O—Z²¹—, **—C(═O)—NH—Z²¹—, or **—O—Z²¹—, Z²¹ is a C₁-C₆ aliphatic hydrocarbylene group, a phenylene group or a divalent group obtained by combining the foregoing, which may contain halogen, a carbonyl moiety, ester bond, ether bond or hydroxy moiety,
Z³ is a single bond, ether bond, ester bond, amide bond, sulfonate ester bond, sulfonamide bond, carbonate bond or carbamate bond,
Z⁴ is a single bond, or a C₁-C₆ aliphatic hydrocarbylene group, a phenylene group or a divalent group obtained by combining the foregoing, which may contain halogen, a carbonyl moiety, ester bond, ether bond or hydroxy moiety,
Z⁵ is each independently a single bond, optionally substituted phenylene group, naphthylene group, or *—C(═O)—O—Z⁵, Z⁵¹ is a C₁-C₁₀ aliphatic hydrocarbylene group, or phenylene or naphthylene group, the aliphatic hydrocarbylene group may contain halogen, a hydroxy moiety, ether bond, ester bond or lactone ring,
Z⁶ is a single bond, ether bond, ester bond, amide bond, sulfonate ester bond, sulfonamide bond, carbonate bond or carbamate bond,
Z⁷ is each independently a single bond, ***—Z⁷¹—C(═O)—O—, ***—C(═O)—NH—Z⁷¹—, or ***—O—Z⁷¹—, Z⁷¹ is a C₁-C₂₀ hydrocarbylene group which may contain a heteroatom,
Z⁸ is each independently a single bond, ****—Z⁸¹—C(═O)—O—, ****—C(═O)—NH—Z⁸¹—, or ****—O—Z⁸, Z⁸¹ is a C₁-C₂₀ hydrocarbylene group which may contain a heteroatom,
Z⁹ is a single bond, methylene, ethylene, phenylene, fluorinated phenylene, trifluoromethyl-substituted phenylene, *—C(═O)—O—Z⁹¹—, *—C(═O)—N(H)—Z⁹¹—, or *—O—Z⁹¹—, Z⁹¹ is a C₁-C₆ aliphatic hydrocarbylene group, phenylene group, fluorinated phenylene group or trifluoromethyl-substituted phenylene group, which may contain a carbonyl moiety, ester bond, ether bond or hydroxy moiety,
* designates a point of attachment to the carbon atom in the backbone, ** designates a point of attachment to Z¹, *** designates a point of attachment to Z⁶, **** designates a point of attachment to Z⁷,
L¹ is a single bond, ether bond, ester bond, carbonyl group, sulfonate ester bond, carbonate bond or carbamate bond,
Rf¹ and Rf² are each independently fluorine or a C₁-C₆ fluorinated saturated hydrocarbyl group,
Rf³ and Rf⁴ are each independently hydrogen, fluorine, or a C₁-C₆ fluorinated saturated hydrocarbyl group,
Rf⁵ and Rf⁶ are each independently hydrogen, fluorine, or a C₁-C₆ fluorinated saturated hydrocarbyl group, excluding that all Rf⁵ and Rf⁶ are hydrogen at the same time,
Rf⁷ is fluorine, a C₁-C₆ fluorinated alkyl group, a C₁-C₆ fluorinated alkoxy group, or a C₁-C₆ fluorinated alkylthio group,
R³¹ and R³² are each independently a C₁-C₂₀ hydrocarbyl group which may contain a heteroatom, R³¹ and R³² may bond together to form a ring with the sulfur atoms to which they are attached,
R³³ is halogen exclusive of fluorine, or a C₁-C₂₀ hydrocarbyl group which may contain a heteroatom, when e3 is 2, 3, or 4, a plurality of R³³ may be identical or different and a plurality of R³³ may bond together to form a ring with the carbon atoms to which they are attached,
M⁻ is a non-nucleophilic counter ion, and
Z⁺ is an onium cation.

9. The chemically amplified resist composition of claim 5, further comprising an organic solvent.

10. The chemically amplified resist composition of claim 5, further comprising a quencher.

11. The chemically amplified resist composition of claim 5, further comprising a photoacid generator other than the photoacid generator.

12. The chemically amplified resist composition of claim 5, further comprising a surfactant.

13. A pattern forming process comprising the steps of applying the chemically amplified resist composition of claim 5 onto a substrate to form a resist film thereon, exposing the resist film to high-energy radiation, and developing the exposed resist film in a developer.

14. The pattern forming process of claim 13 wherein the high-energy radiation is KrF excimer laser radiation, ArF excimer laser radiation, electron beam, or extreme ultraviolet of wavelength 3 to 15 nm.
